(19) United States
(12) Patent Application Publication
(10) Pub. No.: US 2024/0407244 A1
(43) Pub. Date: Dec. 5, 2024

(54) MIXED POWDER FOR AN ORGANIC ELECTROLUMINESCENCE DEVICE AND METHOD FOR PRODUCING THE SAME, METHOD FOR FABRICATING ORGANIC ELECTROLUMINESCENCE DEVICE BY USING THE MIXED POWDER, METHOD FOR SELECTING COMPOUNDS IN THE MIXED POWDER, AND COMPOSITION FOR VACUUM DEPOSITION

(71) Applicant: IDEMITSU KOSAN CO.,LTD., Tokyo (JP)

(72) Inventors: Yukitoshi JINDE, Tokyo (JP); Takushi SHIOMI, Tokyo (JP); Keiichi YASUKAWA, Tokyo (JP); Tetsuya MASUDA, Tokyo (JP); Hiroyuki IWABUCHI, Tokyo (JP); Masato NAKAMURA, Tokyo (JP)

(73) Assignee: IDEMITSU KOSAN CO.,LTD., Tokyo (JP)

(21) Appl. No.: 18/700,407

(22) PCT Filed: Oct. 4, 2022
(86) PCT No.: PCT/JP2022/037082

§ 371 Date: Apr. 11, 2024

(30) Foreign Application Priority Data
Oct. 14, 2021 (JP) 2021-168979

(51) Int. Cl. H10K 71/12; C09K 11/02; C09K 11/06; H10K 85/60; H10K 101/20

(52) U.S. Cl. CPC H10K 71/12; C09K 11/02; C09K 11/06; H10K 85/657; H10K 85/6572; H10K 85/6574; H10K 85/658; C09K 2211/1007; C09K 2211/1018; H10K 2101/20

(57) ABSTRACT

A mixed powder for an organic electroluminescence device, including a first organic compound and a second organic compound, and being solid at ordinary temperatures and pressures, wherein the organic electroluminescence device includes a cathode, an anode, and an emitting layer arranged between the cathode and the anode, and the emitting layer includes a compound C2 having delayed fluorescence, and each of the first organic compound and the second organic compound is a compound selected from the group consisting of a fluorescent emitting compound C1, the compound C2, and a compound C3 different from both the compound C1 and the compound C2, and they have the specific combination, wherein when MOL1 [mol %] is used as the molar concentration of the first organic compound in the mixed powder and MOL2 [mol %] is used as the molar concentration of the second organic compound in the mixed powder, MOL1 [mol %] and MOL2 [mol %] satisfy the following formula (1), wherein when M1 [kg/mol] is used as the molecular weight of the first organic compound, when P1 [Pa] is used as the vapor pressure obtained by ThermoGravimetry-Differential Thermal Analysis of the first organic compound at arbitrary temperature, when M2 [kg/mol] is used as the molecular weight of the second organic compound, and when P2 [Pa] is used as the vapor pressure obtained by ThermoGravimetry-Differential Thermal Analysis of the second organic compound at arbitrary temperature, the temperature T1 [° C.] of the first organic compound in the case of P1/M1^{1/2}=0.04×{MOL1/(MOL1+MOL2)} and the temperature T2 [° C.] of the second organic compound in the case of P2/M2^{1/2}=0.04×{MOL2/(MOL1+MOL2)} satisfy the following formula (2):

$$\begin{matrix}0 < MOL 2 / ( MOL 1 + MOL 2 ) ≦ 0.45 & ( 1 ) \\ - 20 ° C . ≦ T 1 - T 2 ≦ 40 ° C .. & ( 2 )\end{matrix}$$

### TECHNICAL FIELD

The present invention relates to a mixed powder for an organic electroluminescence device and a method for producing the same, a method for fabricating an organic electroluminescence device by using a mixed powder for an organic electroluminescence device, a method for selecting compounds in a mixed powder for an organic electroluminescence device, and a composition for a vacuum deposition.

### BACKGROUND ART

As a method for forming an organic layer constituting an organic electroluminescence device (hereinafter, also referred to as “an organic EL device”), a vacuum deposition method is generally used, and, a co-deposition method has been conventionally used to form a mixed layer composed of a plurality of components, in which each component is vaporized and simultaneously deposited each in different deposition sources (crucibles).

Since it is possible in the co-deposition method to independently control the temperature for each deposition source, it is easy to adjust the mixing proportion in the deposited film by controlling the amount of vaporization of each material, and further, even when deposition is continuously conducted on a plurality of substrates, it is possible to form the film with a fixed mixing proportion. On the other hand, since the fabricating process thereof is complicated due to the use of multiple deposition sources, there is a problem that fabricating burden and costs are increased, and the like.

As a technique for solving the problem, a deposition technique in which a so-called premix material that a plurality of materials (organic compounds) is mixed in advance is vaporized in a single deposition source to form a film is attracting attention. As an example of the premix technique, Patent Document 1 discloses the following inventions.

1. A mixture (hereinafter, also referred to as the “mixture A”) comprising: a first compound; and a second compound, wherein the first compound comprises at least one of a first cyclic structure represented by the general formula (11) or a second cyclic structure represented by the general formula (12), the second compound is a compound represented by the general formula (21) or a compound represented by the general formula (22), and a total mass M_{T} of the first compound and the second compound and a mass M₂ of the second compound in the mixture satisfy the following Numerical formula 1:

$$0.1 ≦ ( {M}_{2} / {M}_{T} ) \times 100 \qquad ( Numerical formula 1 )$$

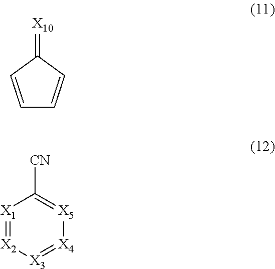

wherein: the first cyclic structure represented by the general formula (11) is fused to at least one cyclic structure of a substituted or unsubstituted aromatic hydrocarbon ring having 6 to 50 ring carbon atoms or a substituted or unsubstituted heterocycle having 5 to 50 ring atoms in a molecule of the first compound, a structure represented by =X₁₀ is represented by the general formula (11a), (11b), (11c), (11d), (11e), (11f), (11g), (11h), (11i), (11j), (11k) or (11m):

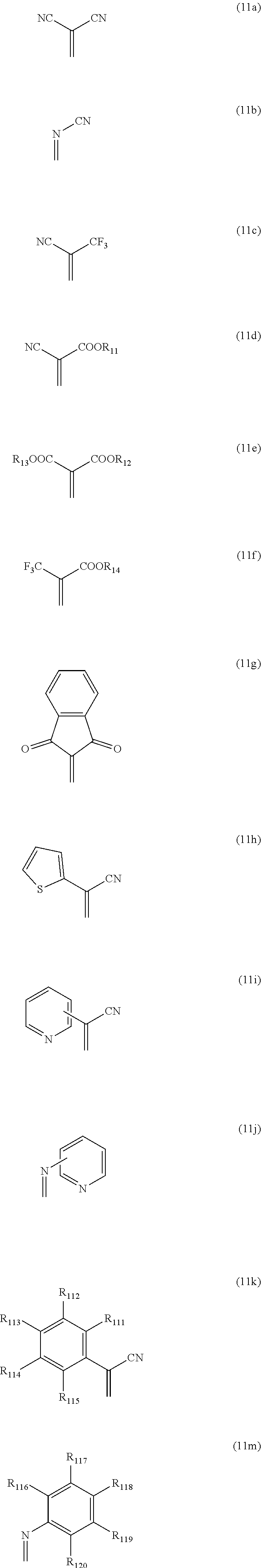

wherein in the general formula (11a), (11b), (11c), (11d), (11e), (11f), (11g), (11h), (11i), (11j), (11k) or (11m): R₁₁ to R₁₄ and R₁₁₁ to R₁₂₀ are each independently a hydrogen atom, a halogen atom, hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms,
in the general formula (12): X₁ to X₅ are each independently a nitrogen atom, a carbon atom to be bonded to R₁₅, or a carbon atom to be bonded to another atom in the molecule of the first compound; at least one of X₁ to X₅ is a carbon atom to be bonded to another atom in the molecule of the first compound; R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and when a plurality of R₁₅ are present, the plurality of R₁₅ are mutually the same or different:

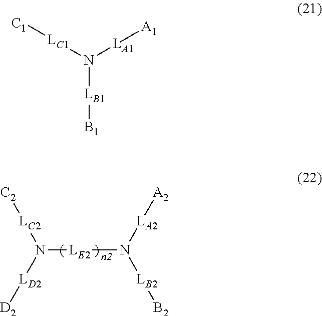

wherein in the general formulas (21) and (22): L_{A1}, L_{B1}, L_{C1}, L_{A2}, L_{B2}, L_{C2} and L_{D2} are each independently a single bond, a substituted or unsubstituted arylene group having 6 to 50 ring carbon atoms, or a substituted or unsubstituted divalent heterocyclic group having 5 to 50 ring atoms; n2 is 1, 2, 3 or 4; when n2 is 1, L_{E2} is a substituted or unsubstituted arylene group having 6 to 50 ring carbon atoms, or a substituted or unsubstituted divalent heterocyclic group having 5 to 50 ring atoms; when n2 is 2, 3 or 4, a plurality of L_{E2} are mutually the same or different; when n2 is 2, 3 or 4, the plurality of L_{E2} are mutually bonded to form a substituted or unsubstituted monocyclic ring, mutually bonded to form a substituted or unsubstituted fused ring, or not mutually bonded; L_{E2} forming neither the monocyclic ring nor the fused ring is a substituted or unsubstituted arylene group having 6 to 50 ring carbon atoms, or a substituted or unsubstituted divalent heterocyclic group having 5 to 50 ring atoms; A₁, B₁, C₁, A₂, B₂, C₂ and D₂ are each independently a substituted or unsubstituted aryl group having 6 to 50 ring carbon atoms, a substituted or unsubstituted heterocyclic group having 5 to 50 ring atoms, or —Si(R′₉₀₁)(R′₉₀₂)(R′₉₀₃); R′₉₀₁, R′₉₀₂ and R′₉₀₃ are each independently a substituted or unsubstituted aryl group having 6 to 50 ring carbon atoms; when a plurality of R′₉₀₁ are present, the plurality of R′₉₀₁ are mutually the same or different; when a plurality of R′₉₀₂ are present, the plurality of R′₉₀₂ are mutually the same or different; when a plurality of R′₉₀₃ are present, the plurality of R′₉₀₃ are mutually the same or different;
in the first compound and the second compound, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; when a plurality of R₉₀₄ are present, the plurality of R₉₀₄ are mutually the same or different; when a plurality of R₉₀₅ are present, the plurality of R₉₀₅ are mutually the same or different; when a plurality of R₉₀₆ are present, the plurality of R₉₀₆ are mutually the same or different; and when a plurality of R₉₀₇ are present, the plurality of R₉₀₇ are mutually the same or different.
   2. An organic electroluminescence device comprising: an anode; a cathode; an organic layer comprising a first compound and a second compound,
wherein the first compound comprises at least one of the first cyclic structure represented by the general formula (11) or the second cyclic structure represented by the general formula (12), the second compound is the compound represented by the general formula (21) or the compound represented by the general formula (22), a total mass W_{T} of the first compound and the second compound and a mass W₂ of the second compound in the organic layer satisfy the following Numerical formula 2:

$$0.1 ≦ ( {W}_{2} / {W}_{T} ) \times 100. \qquad ( Numerical formula 2 )$$

### RELATED ART DOCUMENTS

### Patent Documents

[Patent Document 1] WO 2021/015266 A₁

### SUMMARY OF THE INVENTION

It is an object of the present invention to provide a mixed powder capable of deposition in which the variability of the component proportion is suppressed in the mixed film during the film formation process in the deposition process by using a mixed material in which one component has a certain amount less.

The premix technique can overcome the above-mentioned disadvantages of the co-deposition method, however, there are problems, as compared to the co-deposition method, that it is difficult to form a deposited film with a desired mixing proportion, and further that when a plurality of substrates is continuously subjected to deposition, the mixing proportion thereof is variable depending on the substrate to be difficult to obtain one with consistent quality. The present inventors have found that these problems are more pronounced in, for example, as premix materials of the host compound and the dopant compound, a system that there are differences in the amount proportion of constituent materials, and one proportion is large and the other proportion is small. Since the deposition process is continuously conducted for several weeks to several months in the actual fabrication of organic EL devices, it is essential that mixed films can be formed with stable proportions for a long time. That is, the above-mentioned problems are important problems to be solved in the premix technique.

Since in premix technique in which a plurality of compounds is vaporized in the same deposition source, the mixing proportion of the raw material mixture is reflected in the deposited film, it is considered that compounds having similar amounts of vaporization under predetermined deposition conditions are used in combination. That is, when a premix material formed by mixing compounds with similar deposition characteristics (especially, the evaporation rate at a predetermined temperature and degree of vacuum) is used, it is the idea that even when they are continuously deposited in the same deposition source (that is, at the same temperature), a deposited film mixed in the desired proportion can be obtained over a long period of time.

However, according to the inventors' study, this idea does not necessarily work as expected, and in particular, as the above-mentioned mixed material of a host material and a dopant material, even when the above idea is used for a system where constituent components have different amount proportions, it is difficult that a deposited film having the desired proportion is obtained over a long period of time.

The inventors considered the cause as follows. It will be described below, for simplicity, using an example of a binary system of the host compound and the dopant compound (here, the present invention is not limited to the binary system, but can also be used for a ternary system).

In the above binary system where the mixing proportion of the dopant compound in the premix material is small to a certain extent, when materials having similar deposition characteristics are used as the host compound and dopant compound, these compounds evaporate at similar rates. Therefore, a deposited film in which the dopant compound is contained with a higher amount than desired proportion thereof is formed at the initial of the continuous deposition process. Since the dopant compound is depleted in the premix material before the host material, a deposited film in which the dopant compound is contained with a significantly lower amount than the desired proportion thereof is formed from the middle of the process. As a result, the yield thereof is significantly reduced in the fabricating process, and such a premix material is not available in practical use.

That is, the present inventors have found that in a system where one compound has small mixing proportion to a certain extent as in this example, rather when a premix material in which compounds with similar deposition characteristics are used in combination is used as in the above idea, a deposited film having the desired mixing proportion is hardly obtained over a long period of time.

As a result of further studies based on the above findings, the present inventors found that in a system where the mixing proportion of one compound is smaller than a certain level, a compound with different deposition characteristic to a certain extent is daringly used in combination thereto to be capable of solving the above-mentioned problem. Specifically, the present inventors have found that when a predetermined relationship is satisfied in consideration of the deposition characteristics and mixing proportion of each compound, the deposition in which the variability of the component proportion is suppressed in the film can be achieved during the film formation process, and has completed the present invention.

According to the present invention, the following mixed powder and the like are provided.

1. A mixed powder for an organic electroluminescence device, comprising a first organic compound and a second organic compound, and being solid at ordinary temperatures and pressures,
wherein the organic electroluminescence device comprises a cathode, an anode, and an emitting layer arranged between the cathode and the anode, and the emitting layer comprises a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder and MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$0 < MOL 2 / ( MOL 1 + MOL 2 ) ≦ 0 \text{.45} \qquad ( 1 )$$

$$- 20 ° C . ≦ T 1 - T 2 ≦ 40 ° C . \qquad ( 2 ) .$$

2. A method for fabricating an organic electroluminescence device, wherein the organic electroluminescence device comprises a cathode, an anode, and an emitting layer arranged between the cathode and the anode, and comprising a compound C2 having delayed fluorescence, and
the method comprises: depositing a mixed powder or a mixture obtained by heating and melting the mixed powder by heating and vaporizing the mixed powder or the mixture in a deposition source to form the emitting layer,
wherein the mixed powder comprises a first organic compound and a second organic compound, and is solid at ordinary temperatures and pressures,
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$0 < MOL 2 / ( MOL 1 + MOL 2 ) ≦ 0 \text{.45} \qquad ( 1 )$$

$$- 20 ° C . ≦ T 1 - T 2 ≦ 40 ° C . \qquad ( 2 ) .$$

3. A method for selecting a first organic compound and a second organic compound in a mixed powder for an organic electroluminescence device, which comprises the first organic compound and the second organic compound and which is solid at ordinary temperatures and pressures,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and when P2 [Pa] is used as the vapor pressure obtained by ThermoGravimetry-Differential Thermal Analysis of the second organic compound at arbitrary temperature,
the first organic compound and the second organic compound are selected so that the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$0 < MOL 2 / ( MOL 1 + MOL 2 ) ≦ 0 \text{.45} \qquad ( 1 )$$

$$- 20 ° C . ≦ T 1 - T 2 ≦ 40 ° C . \qquad ( 2 ) .$$

4. A method for producing a mixed powder for an organic electroluminescence device, comprising a first organic compound and a second organic compound, and being solid at ordinary temperatures and pressures,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$0 < MOL 2 / ( MOL 1 + MOL 2 ) ≦ 0 \text{.45} \qquad ( 1 )$$

$$- 20 ° C . ≦ T 1 - T 2 ≦ 40 ° C . \qquad ( 2 ) .$$

5. A composition for a deposition in an organic electroluminescence device, comprising a first organic compound and a second organic compound,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the composition, and
when MOL2 [mol %] is used as the molar concentration of the second organic compound in the composition,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$0 < MOL 2 / ( MOL 1 + MOL 2 ) ≦ 0 \text{.45} \qquad ( 1 )$$

$$- 20 ° C . ≦ T 1 - T 2 ≦ 40 ° C . \qquad ( 2 ) .$$

According to the present invention, there can be provided a mixed powder capable of deposition in which the variability of the component proportion is suppressed in the mixed film during the film formation process in the deposition process by using a mixed material in which one component has a certain amount less.

### BRIEF DESCRIPTION OF THE DRAWINGS

FIG. 1 is a diagram showing a deposition characteristic curve of each component in an example of a mixed powder according to an aspect of the present invention.

FIG. 2 is a schematic diagram of an apparatus for measuring transient PL.

FIG. 3 is a diagram showing an example of attenuation curves of transient PL.

FIG. 4 is a diagram showing a schematic configuration of an example of an organic electroluminescence device.

FIG. 5 is a diagram showing the relationship of energy levels and energy transfers of a compound C1, a compound C2 and a compound C3 in an emitting layer of an example of an organic electroluminescence device.

FIG. 6 is a diagram showing the relationship of energy levels and energy transfers of a compound C1 and a compound C3 in an emitting layer of an example of an organic electroluminescence device.

FIG. 7 is a diagram showing the relationship of energy levels and energy transfers of a compound C2 and a compound C3 in an emitting layer of an example of an organic electroluminescence device.

FIG. 8 is a deposition characteristic curve of temperature and P/M^{1/2} each for TGM-1 and TGH-1 used in Examples 1-1 and 1-2.

FIG. 9 is a deposition characteristic curve of temperature and P/M^{1/2} each for TRM-2 and TRH-1 used in Example 2.

FIG. 10 is a deposition characteristic curve of temperature and P/M^{1/2} each for TGM-3 and TGD-1 used in Example 3.

FIG. 11 is a deposition characteristic curve of temperature and P/M^{1/2} each for TGM-2 and TGH-1 used in Comparative Example 1.

FIG. 12 is a deposition characteristic curve of temperature and P/M^{1/2} each for TGM-2 and TGD-1 used in Comparative Example 2.

### MODE FOR CARRYING OUT THE INVENTION

### Mixed Powder

A mixed powder according to an aspect of the present invention is a mixed powder for an organic electroluminescence device, including a first organic compound (hereinafter, also referred to as a “first component”) and a second organic compound (hereinafter, also referred to as a “second component”), and being solid at ordinary temperatures and pressures.

The organic electroluminescence device includes a cathode, an anode, and an emitting layer arranged between the cathode and the anode, and including a compound C2 having delayed fluorescence (also referred to as “thermally activated delayed fluorescence”).

Each of the first organic compound and the second organic compound is a compound selected from the group consisting of a fluorescent emitting compound C1, the compound C2, and a compound C3 different from both the compound C1 and the compound C2.

The first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3.

When MOL1 [mol %] is used as the molar concentration of the first organic compound in the mixed powder and MOL2 [mol %] is used as the molar concentration of the second organic compound in the mixed powder, MOL2/(MOL1+MOL2) satisfy the following formula (1):

$$0 < MOL 2 / ( MOL 1 + MOL 2 ) ≦ 0 \text{.45} \qquad ( 1 )$$

Further, when M1 [kg/mol] is used as the molecular weight of the first organic compound, when P1 [Pa] is used as the vapor pressure obtained by ThermoGravimetry-Differential Thermal Analysis of the first organic compound at arbitrary temperature, when M2 [kg/mol] is used as the molecular weight of the second organic compound, and when P2 [Pa] is used as the vapor pressure obtained by ThermoGravimetry-Differential Thermal Analysis of the second organic compound at arbitrary temperature, the temperature T1 [° C.] of the first organic compound in the case of P1/M1^{1/2}=0.04×{MOL1/(MOL1+MOL2)} and the temperature T2 [° C.] of the second organic compound in the case of P2/M2^{1/2}=0.04×{MOL2/(MOL1+MOL2)} satisfy the following formula (2):

$$- 20 ° C . ≦ T 1 - T 2 ≦ 40 ° C . \qquad ( 2 ) .$$

When the deposition is conducted using the mixed powder having the above composition, the balance of the vaporization amounts of the first component and the second component can be maintained for a long time. In particular, when materials are continuously heated sequentially to form films on a plurality of substrates, it is possible to form a film with stable component proportion from the initial to the end of the deposition process. As a result, the occurrence of defective products and loss of raw materials can be suppressed to the minimum to increase the yield thereof and to improve the productivity thereof. The above effects are not intended to mean that a film can be formed with a fixed proportion on all substrates used in a continuous deposition process. Even when using the mixed powder according to an aspect of the present invention, it can be concerned that the component proportion is slightly changed, especially in the final stage of the process, but it means that the time length in which films can be formed with stable proportions can be greatly improved.

The technical significance of the formulas (1) and (2) will be described below.

### <Formula (1)>

The formula (1) means a mixed material in which the second component has a certain amount less. The amount of the second component based on the total amount of the first component and the second component MOL2/(MOL1+MOL2) is more than 0 and 0.45 or less, and it may be for example, 0.40 or less, 0.35 or less, or 0.30 or less. Further, MOL2/(MOL1+MOL2) may be for example, 0.001 or more, 0.005 or more, 0.01 or more, 0.05 or more, 0.10 or more, 0.15 or more, 0.20 or more, 0.21 or more, or 0.25 or more. In addition, MOL2/(MOL1+MOL2) may be more than 0.2.

### First Embodiment

In one embodiment, the first organic compound is the compound C3, and the second organic compound is the compound C2. Hereinafter, the present embodiment in which the first organic compound is the compound C3, and the second organic compound is the compound C2 sometimes referred to as a first embodiment.

The mixed powder of the first embodiment may satisfy any of the following formulas.

$$0.2 ≦ MOL 2 / ( MOL 1 + MOL 2 ) ≦ 0.45$$

$$0.2 ≦ MOL 2 / ( MOL 1 + MOL 2 ) ≦ 0.40$$

$$0.2 ≦ MOL 2 / ( MOL 1 + MOL 2 ) ≦ 0.35$$

$$0.2 ≦ MOL 2 / ( MOL 1 + MOL 2 ) ≦ 0.30$$

### Second Embodiment

In one embodiment, the first organic compound is the compound C3, and the second organic compound is the compound C1. Hereinafter, the present embodiment in which the first organic compound is the compound C3, and the second organic compound is the compound C1 sometimes referred to as a second embodiment.

The mixed powder of the second embodiment may satisfy any of the following formulas.

$$0 < MOL 2 / ( MOL 1 + MOL 2 ) ≦ 0.20$$

$$0 < MOL 2 / ( MOL 1 + MOL 2 ) ≦ 0.15$$

$$0 < MOL 2 / ( MOL 1 + MOL 2 ) ≦ 0.10$$

$$0 < MOL 2 / ( MOL 1 + MOL 2 ) ≦ 0.05$$

### Third Embodiment

In one embodiment, the first organic compound is the compound C2, and the second organic compound is the compound C1. Hereinafter, the present embodiment in which the first organic compound is the compound C2, and the second organic compound is the compound C1 sometimes referred to as a third embodiment.

The mixed powder of the third embodiment may satisfy any of the following formulas.

$$0 < MOL 2 / ( MOL 1 + MOL 2 ) ≦ 0.20$$

$$0 < MOL 2 / ( MOL 1 + MOL 2 ) ≦ 0.15$$

$$0 < MOL 2 / ( MOL 1 + MOL 2 ) ≦ 0.10$$

$$0 < MOL 2 / ( MOL 1 + MOL 2 ) ≦ 0.05$$

### Fourth Embodiment

In one embodiment, the first organic compound is the compound C2, and the second organic compound is the compound C3. Hereinafter, the present embodiment in which the first organic compound is the compound C2, and the second organic compound is the compound C3 sometimes referred to as a fourth embodiment.

The mixed powder of the fourth embodiment may satisfy any of the following formulas.

$$0.2 ≦ MOL 2 / ( MOL 1 + MOL 2 ) ≦ 0.45$$

$$0.2 ≦ MOL 2 / ( MOL 1 + MOL 2 ) ≦ 0.40$$

$$0.2 ≦ MOL 2 / ( MOL 1 + MOL 2 ) ≦ 0.35$$

$$0.2 ≦ MOL 2 / ( MOL 1 + MOL 2 ) ≦ 0.30$$

### <Formula (2)>

When thermogravimetric analysis is conducted on one organic compound, the mass change (loss) amount [kg] is shown against temperature change, and then the factor of the time [min] is added thereto to be able to obtain the mass loss rate (rate) [kg/min]. Since the mass loss rate represents the mass vaporized (deposited) per unit time, it can be an indicator of the deposition characteristics of the organic compound, but since it is used in the present invention as the indicator which is further difficult to depend on the molecular weight of the compound, the molar deposition rate [mol/min] is used as an index of deposition characteristics.

Here, it is known that the relationship represented by the following formula (A1) is provided between mass loss rate m, vapor pressure (saturated vapor pressure) P, and molecular weight M of the organic compound, and since the mass loss rate m is proportional to P×M^{1/2}, the molar deposition rate m/M is proportional to P×M^{1/2}/M, that is, P/M^{1/2}. That is, it can be seen that the molar deposition rate can be evaluated by P/M^{1/2}. The unit of P/M^{1/2} is [Pa/(kg/mol)^{1/2}].

$$m = P \sqrt{\frac{M}{2 π R T}} \qquad ( A1 )$$

In the formula (A1), each symbol indicates the following matter.
m: mass loss rate [kg/(s·m²)]
   (The unit (s·m²) means time (s)×deposition area (m²) on substrate surface.)
P: saturated vapor pressure [Pa]
M: molecular weight of the organic compound [kg/mol]
R: gas constant [J/(mol·K)]
T: temperature [K]

P/M^{1/2} obtained based on thermogravimetric analysis and being proportional to molar deposition rate is used as an indicator of deposition characteristics, and in addition thereto, one of the features of the present invention is that the present inventors focus on the relationship between the blending ratio (molar ratio) of two components used in the mixed powder and the ratio of P/M^{1/2}. Specifically, the present invention is based on the technical idea that in the system where the mixing ratio of one compound is smaller than a certain level, when the blending ratio (molar ratio) of the two components in the mixed powder and the ratio of P/M^{1/2} of the two components are approximated, it is possible to maintain the balance of vaporized amounts of two components for a long time in the deposition processes (especially continuous deposition processes). The formula (2) expresses those described above.

The relationship between the above technical idea and the formula (2) will be described below using the specific examples.

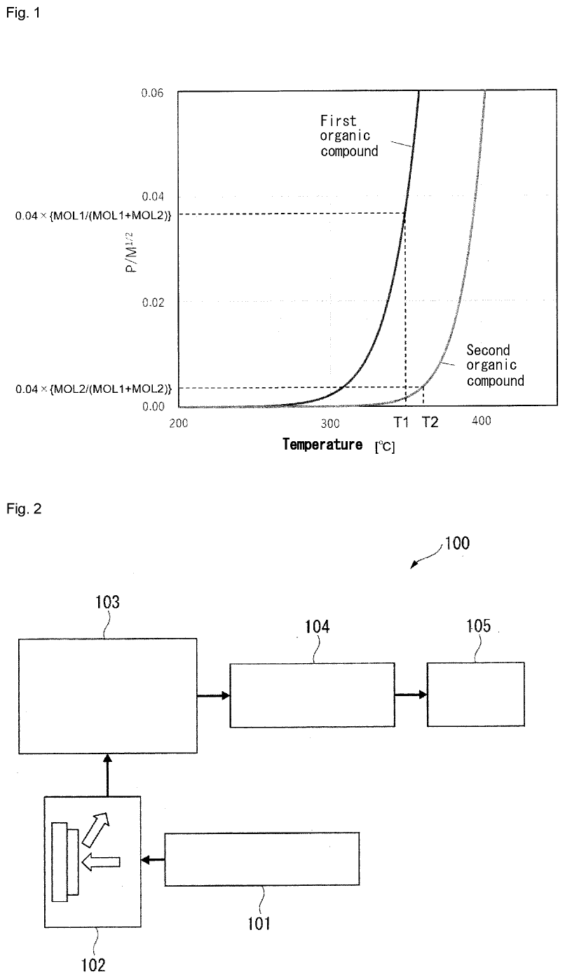

As an example of the mixed powder according to an aspect of the present invention, The mixed powder including the first component (major component) and the second component (minor component) is assumed, and the deposition characteristic curve of temperature and P/M^{1/2} shown in FIG. 1 is assumed as each deposition characteristic. The molar ratio of the two components in this example is 9:1, that is, MOL2/(MOL1+MOL2) is 0.1. Correspondingly, when the ratio of P/M^{1/2} of the two components is close to 9:1, the balance of vaporization amount (deposition amount) is maintained for a long time, and therefore, the formula (2) expresses this condition in terms of a temperature perspective.

That is, the formula (2) indicates that the present inventors focus on the difference of the temperature T1 in the case that P/M^{1/2} of the first component reaches the specific value (0.04×{MOL1/(MOL1+MOL2)}) corresponding to the molar ratio thereof (MOL1/(MOL1+MOL2)) and the temperature T2 in the case that P/M^{1/2} of the second component reaches the specific value (0.04×{MOL2/(MOL1+MOL2)}) corresponding to the molar ratio thereof (MOL2/(MOL1+MOL2)), abd that when the temperature difference (T1-T2) is within a predetermined range, the above-mentioned effects can be fully exhibited (here, when the temperature difference (T1-T2) is 0° C., the present inventors focus on a point that the ratio of the molar deposition rate of the first component at temperature T1=T2 and the molar deposition rate of second component perfectly matches 9:1 which is the molar ratio of the above two components).

In this example, as shown in FIG. 1, since the difference between T1 and T2 (T1-T2) is −10° C. which is within the specified range, the mixed powder is put into the deposition source and then the deposition is conducted to be able to maintain the balance of the vaporized amounts of these two components for a long time.

The value “0.04” is a constant set in consideration of conditions such as the molecular weight and vapor pressure of the compound generally employed in the deposition process of the organic compound.

Here, the reason for using the difference between T1 and T2 (T1-T2) as “−20° C.≤T1-T2≤40° C.” will be described below.

As described above, when T1 and T2 are almost the same or within a certain approximate range, it is possible to maintain the balance of the vaporization amount of the two components for a long time. However, as a result of further studies by the inventors, in particular, when considering reducing the difference in the molar ratio of the two components between the mixed powder and the deposited film, that is, improving the reproducibility of the component ratio, better results can be sometimes obtained in the case where T1 is higher than T2 by a certain degree than when T1 and T2 are the same. The reason for this is not necessarily certain, but it is thought to be related to the fact that the second component (the small amount of component) is exposed to the outside in a small amount and is less likely to vaporize than the first component. This is considered, and then one in which conditions are selected so that the first component side is also slightly difficult to be vaporized and they are modified is the above numerical range.

A different idea from the present invention may be that it is preferable to match the molar deposition rate at arbitrary temperature, regardless of the mixing ratio of the mixed powder. That is, it is the idea that a combination of the compounds in which the deposition characteristic curves overlap or are very close to each other is preferable. In this idea, a combination in which the deposition characteristic curves are deviated as shown in those of the first component and the second component of FIG. 1 is not preferable.

The difference between T1 and T2 (T1-T2) is, for example, −15° C. or more, −10° C. or more, −5° C. or more, 0° C. or more, or 5° C. or more, and is, for example, 35° C. or less, 30° C. or less, 25° C. or less, 20° C. or less, or 15° C. or less.

In one embodiment, the difference between T1 and T2 (T1-T2) is −10° C. or more and 30° C. or less, −5° C. or more and 25° C. or less, or 0° C. or more and 20° C. or less.

In one embodiment, the difference between T1 and T2 (T1-T2) can also be expressed as in the following formulas (2-1) to (2-3).

$$0 ° C . ≦ T 1 - T 2 ≦ 40 ° C . \qquad ( 2 - 1 )$$

$$5 ° C . ≦ T 1 - T 2 ≦ 40 ° C . \qquad ( 2 - 2 )$$

$$- 20 ° C . ≦ T 1 - T 2 ≦ 20 ° C . \qquad ( 2 - 3 )$$

When they are within the above-mentioned range, the difference in the molar ratio of the two components in the mixed powder and the deposited film can be reduced, and the reproducibility of the component ratio can be improved.

### (Method for Measuring and Calculating T1 and T2)

The temperature T1 in the case where P/M^{1/2} of the first component is 0.04×{MOL1/(MOL1+MOL2)} and the temperature T2 in the case where P/M^{1/2} of the second component is 0.04×{MOL2/(MOL1+MOL2)} are determined by reading from the deposition characteristic curve of temperature and P/M^{1/2} of each compound. The specific method is shown below.

The deposition characteristic curve of temperature and P/M^{1/2} of each compound of the first component and the second component is obtained by the following method.

### (ThermoGravimetry-Differential Thermal Analysis)

The amount of weight loss is measured using an apparatus for ThermoGravimetry-Differential Thermal Analysis in the case where the temperature is changed under vacuum. The ThermoGravimetry-Differential Thermal Analysis (TG-DTA) is a method in which the change in mass of a sample is continuously measured when the sample is heated, and is used to detect physical changes which involve mass changes such as sublimation and evaporation.

The measurement is conducted under the following measurement conditions.

### (Measurement Condition)

Apparatus: apparatus for ThermoGravimetry-Differential Thermal Analysis
Sample container: aluminum nitride pan
Mass of sample: 3 to 10 mg
Heating rate: 3° C./min
Measurement range: 35° C. or more, 500° C. or less
Degree of vacuum: 1×10⁻³ Pa or less

### (Conversion to Deposition Characteristic Curve of Temperature and P/M^{1/2}))

P/M^{1/2} at each temperature is calculated from the mass loss rate (kg/s) at each temperature obtained by the ThermoGravimetry-Differential Thermal Analysis using the following conversion formula (A11).

$$\frac{P}{\sqrt{M}} = \frac{\sqrt{2 π RT}}{MA} \cdot \frac{d Δ W}{dT} \cdot \frac{dT}{dt} \qquad ( A 11 )$$

In the formula (A11), each symbol indicates the following matter.
P: saturated vapor pressure [Pa]
A: area of vaporization surface in sample container [m²]
ΔW: mass loss amount of the organic compound in the sample container [kg]
T: temperature of the vaporization surface in the sample container [K]
t: time [s]
M: molecular weight of the organic compound [kg/mol]
R: gas constant [J/(mol·K)]

P/M^{1/2} calculated is used as the vertical axis, the temperature is used as the horizontal axis, and then the deposition characteristic curve of temperature and P/M^{1/2} of the compound being a measurement target is obtained.

Strictly theoretically, the condensation coefficient “a” can affect the saturated vapor pressure P, but since in this measurement, it is thought that diffusion is sufficiently promoted in the measurement temperature range of the material, the condensation coefficient “a” is assumed to be 1. As a result, the condensation coefficient “a” does not described in the formula (A1).

### (Extrapolation of Deposition Characteristic Curve of Temperature and P/M^{1/2})

The deposition characteristic curve of temperature and P/M^{1/2} obtained above is extrapolated in calculating T1 and T2 as necessary using the following method.

The obtained deposition characteristic curve is fitted by using an exponential function of the following formula (A12).

$$\frac{P}{\sqrt{M}} = \frac{1}{\sqrt{M}} \cdot Exp ( {C}_{1} ) \cdot Exp ( - \frac{{C}_{2}}{T} ) \qquad ( A 12 )$$

In the formula (A12), P, M and T is the same as described in those of the formula (A11).

The temperature is used as the horizontal axis, the natural logarithm of the saturated vapor pressure is used as the vertical axis, and then each of the intercept C1 and the slope C2 in the formula (2) is calculated by the least squares method for an arbitrary range where the linearity is highest. The obtained C1 and C2, and formula (A12) are used to be able to obtain P/M^{1/2} at arbitrary temperature.

### <First Organic Compound (First Component) and Second Organic Compound (Second Component)>

Each of the first component and the second component is a compound selected from the group consisting of the fluorescent emitting compound C1, the compound C2 having delayed fluorescence, and the compound C3 different from both the compound C1 and the compound C2, and they are different from each other.

The compound structures of these components are not particularly limited, and any organic compound can be used as long as these are different compounds from each other and the above conditions are satisfied.

The expression “the first component and the second component are different from each other” includes the case where chemical structures (skeletons) are different from each other, and the case where chemical structures (skeletons) are the same and they include the different isotopes. The isotope means a atom having the same atomic number and having the different number of neutorns. For example, a benzene (C₆H₆) and a deuterated benzene (C₆D₆) are different compounds each other.

When chemical structures (skeletons) are the same and they include the different isotopes, and when compounds have the different numbers of or the different configurations of isotopes, the compounds are different from each other, since they have different numbers of isotopes. For example, even when compounds are deuterated benzenes, C₆H₅D₁ and C₆D₆ are different compounds each other. Further, for example, even when compounds are represented by C₆H₄D₂, a compound having deuterium atoms at 1st-position and 2nd-position of benzene ring and a compound having deuterium atoms at 1st-position and 3rd-position of benzene ring are different from each other, since they have different configurations of isotopes.

The compounds C1 to C3 will be described below.

### <Compound C1>

The compound C1 is not particularly limited as long as it is a fluorescent emitting compound.

The compound C1 preferably has emission having a main peak wavelength of 400 nm or more and 700 nm or less.

In the present specification, the main peak wavelength means the peak wavelength of a fluorescence spectrum having the maximum emission intensity in the measured fluorescence spectrum with respect to a toluene solution in which a measurement target compound is dissolved at a concentration of 10⁻⁶ mol/L or more and 10⁻⁵ mol/L or less. A fluorescence spectrophotometer (manufactured by Hitachi High-Tech Science Corporation, F-7000) is used as a measurement apparatus.

The main peak wavelength of light emitted by the organic EL device is measured as follows.

When a voltage is applied to the organic EL device so that the current density thereof became 10 mA/cm², the spectral emission luminance spectrum is measured by using Spectroradiometer CS-2000 (manufactured by KONICA MINOLTA, INC.). A peak wavelength of the emission spectrum with maximum emission intensity is measured in the obtained spectral emission luminance spectrum, and then it is used as the main peak wavelength (unit: nm).

In the present specification, a red emission means an emission in which the main peak wavelength of the fluorescence spectrum is within the range of 600 nm or more and 660 nm or less.

When the compound C1 is a red fluorescent emitting compound, a main peak wavelength of the compound C1 is preferably 600 nm or more and 660 nm or less, more preferably 600 nm or more and 640 nm or less, and still more preferably 610 nm or more and 630 nm or less.

In the present specification, a green emission means an emission in which the main peak wavelength of the fluorescence spectrum is within the range of 500 nm or more and 560 nm or less.

When the compound C1 is a green fluorescent emitting compound, a main peak wavelength of the compound C1 is preferably 500 nm or more and 560 nm or less, more preferably 500 nm or more and 540 nm or less, and still more preferably 510 nm or more and 540 nm or less.

In the present specification, a blue emission means an emission in which the main peak wavelength of the fluorescence spectrum is within the range of 430 nm or more and 480 nm or less.

When the compound C1 is a blue fluorescent emitting compound, a main peak wavelength of the compound C1 is preferably 430 nm or more and 480 nm or less, and more preferably 440 nm or more and 480 nm or less.

In one embodiment, the compound C1 is a compound having a red emission or a green emission.

In one embodiment, the compound C1 is a compound having a green emission.

In one embodiment, the compound C1 is a compound represented by the following general formula (1).

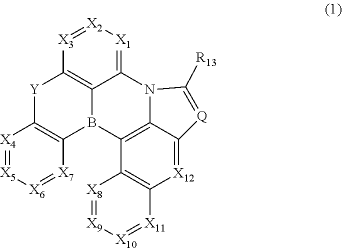

In the general formula (1),
X₁ is CR₁ or a nitrogen atom;
X₂ is CR₂ or a nitrogen atom;
X₃ is CR₃ or a nitrogen atom;
X₄ is CR₄ or a nitrogen atom;
X₅ is CR₅ or a nitrogen atom;
X₆ is CR₆ or a nitrogen atom;
X₇ is CR₇, a nitrogen atom, or a carbon atom with which X₈ is bonded via a single bond;
X₈ is CR₈, a nitrogen atom, or a carbon atom with which X₇ is bonded via a single bond;
X₉ is CR₉ or a nitrogen atom;
X₁₀ is CR₁₀ or a nitrogen atom;
X₁₁ is CR₁₁ or a nitrogen atom;
X₁₂ is CR₁₂ or a nitrogen atom;
Q is CR_{Q} or a nitrogen atom;
Y is NR_{Y1}, an oxygen atom, a sulfur atom, C(R_{Y2})(R_{Y3}) or Si(R_{Y4})(R_{Y5});
one or more sets of the adjacent two or more of R₁ to R₆ and R₉ to R₁₁
form a substituted or unsubstituted single ring by bonding with each other,
form a substituted or unsubstituted fused ring by bonding with each other, or
do not bond with each other;
one or more sets of the adjacent two or more of R₃, R₄ and R_{Y1}
form a substituted or unsubstituted single ring by bonding with each other,
form a substituted or unsubstituted fused ring by bonding with each other, or
do not bond with each other;
in the single ring or the fused ring formed by bonding one or more sets of the adjacent two or more of R₃, R₄ and R_{Y1} with each other, at least one hydrogen is substituted or unsubstituted with at least one substituent selected from the group consisting of
an alkyl group having 1 to 50 carbon atoms,
an aryl group having 6 to 50 ring carbon atoms,
a heterocyclic group having 5 to 50 ring atoms,
a group represented by —O—(R₉₂₀), and
a group represented by —N(R₉₂₁)(R₉₂₂);
at least one hydrogen in the substituent is substituted or unsubstituted with an aryl group having 6 to 50 ring carbon atoms or an alkyl group having 1 to 50 carbon atoms;
R₁ to R₁₁, and R₁₂ to R₁₃, and R_{Q} which do not form the substituted or unsubstituted single ring and which do not form the substituted or unsubstituted fused ring are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a group represented by —Si(R₉₁₁)(R₉₁₂)(R₉₁₃),
a group represented by —O—(R₉₁₄),
a group represented by —S—(R₉₁₅),
a group represented by —N(R₉₁₆)(R₉₁₇),
a substituted or unsubstituted aralkyl group having 7 to 50 carbon atoms,
a group represented by —C(═O)R₉₁₈,
a group represented by —COOR₉₁₉,
a halogen atom,
a cyano group,
a nitro group,
a substituted or unsubstituted aryl group having 6 to 50 ring carbon atoms, or
a substituted or unsubstituted heterocyclic group having 5 to 50 ring atoms;
R_{Y1} which does not form the substituted or unsubstituted single ring and which does not form the substituted or unsubstituted fused ring is
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted heterocyclic group having 5 to 50 ring atoms;
a set of R_{Y2} and R_{Y3}
form a substituted or unsubstituted single ring by bonding with each other,
form a substituted or unsubstituted fused ring by bonding with each other, or
do not bond with each other;
R_{Y2} and R_{Y3}, and R_{Y4} and R_{Y5} which do not form the substituted or unsubstituted single ring and which do not form the substituted or unsubstituted fused ring are independently
a hydrogen atom,
a halogen atom,
a substituted or unsubstituted alkyl group having 1 to 50 carbon atoms,
a substituted or unsubstituted aryl group having 6 to 50 ring carbon atoms, or
a substituted or unsubstituted heterocyclic group having 5 to 50 ring atoms;
R₉₁₁ to R₉₁₂ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted heterocyclic group having 5 to 50 ring atoms;
when a plurality of R₉₁₁'s is present, the plurality of R₉₁₁'s is the same as or different from each other;
when a plurality of R₉₁₂'s is present, the plurality of R₉₁₂'s is the same as or different from each other;
when a plurality of R₉₁₃'s is present, the plurality of R₉₁₃'s is the same as or different from each other;
when a plurality of R₉₁₄'s is present, the plurality of R₉₁₄'s is the same as or different from each other;
when a plurality of R₉₁₅'s is present, the plurality of R₉₁₅'s is the same as or different from each other;
when a plurality of R₉₁₆'s is present, the plurality of R₉₁₆'s is the same as or different from each other;
when a plurality of R₉₁₇'s is present, the plurality of R₉₁₇'s is the same as or different from each other;
when a plurality of R₉₁₈'s is present, the plurality of R₉₁₈'s is the same as or different from each other;
when a plurality of R₉₁₉'s is present, the plurality of R₉₁₉'s is the same as or different from each other;
when a plurality of R₉₂₀'s is present, the plurality of R₉₂₀'s is the same as or different from each other;
when a plurality of R₉₂₁'s is present, the plurality of R₉₂₁'s is the same as or different from each other; and
when a plurality of R₉₂₂'s is present, the plurality of R₉₂₂'s is the same as or different from each other.

In the compound according to the present embodiment, when X₇ is a carbon atom with which X₈ is bonded via a single bond and X₈ is a carbon atom with which X₇ is bonded via a single bond, for example, the general formula (1) is represented by the following general formula (1A).

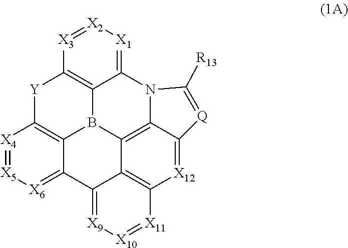

In the general formula (1A), X₁ to X₆, X₉ to X₁₂, Y, Q, and R₁₃ are independently the same as defined in the general formula (1).

The compound according to the present embodiment is also preferably represented by the following general formula (2).

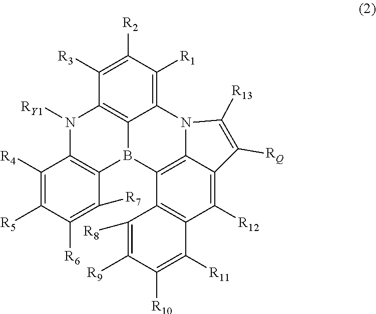

In the general formula (2), R₁ to R₁₅, R_{Y1}, and R_{Q} are independently the same as defined in the general formula (1).

The compound according to the present embodiment is also preferably represented by the following general formula (2A).

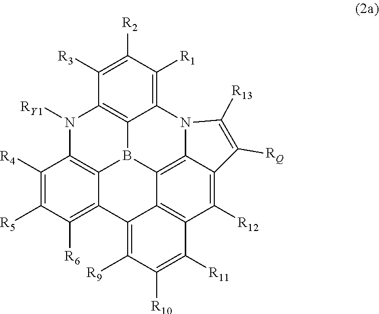

In the general formula (2A), R₁ to R₆, R₉ to R₁₃, R_{Y1}, and R_{Q} are independently the same as defined in the general formula (1).

The compound according to the present embodiment is also preferably represented by the following general formula (3).

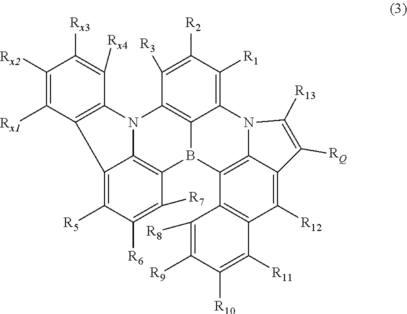

In the general formula (3),
R₁ to R₃, R₅ to R₁₃ and R_{Q} are independently the same as defined in the general formula (1);
one or more sets of the adjacent two or more of Rₓ₁ to Rₓ₄
form a substituted or unsubstituted single ring by bonding with each other,
form a substituted or unsubstituted fused ring by bonding with each other, or
do not bond with each other;
Rₓ₁ to Rₓ₄ which do not form the substituted or unsubstituted single ring and which do not form the substituted or unsubstituted fused ring are independently
a hydrogen atom,
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a substituted or unsubstituted aralkyl group having 7 to 50 carbon atoms,
a group represented by —Si(R₉₃₁)(R₉₃₂)(R₉₃₃),
a group represented by —O—(R₉₃₄),
a group represented by —S—(R₉₃₅),
a group represented by —N(R₉₃₆)(R₉₃₇),
a substituted or unsubstituted aralkyl group having 7 to 50 carbon atoms,
a group represented by —C(═O)R₉₃₈,
a group represented by —COOR₉₃₉,
a halogen atom,
a cyano group,
a nitro group,
a substituted or unsubstituted aryl group having 6 to 50 ring carbon atoms, or
a substituted or unsubstituted heterocyclic group having 5 to 50 ring atoms;
R₉₃₁ to R₉₃₉ are independently
a hydrogen atom,
a substituted or unsubstituted alkyl group having 1 to 50 carbon atoms,
a substituted or unsubstituted aryl group having 6 to 50 ring carbon atoms, or
a substituted or unsubstituted heterocyclic group having 5 to 50 ring atoms;
when a plurality of R₉₃₁'s is present, the plurality of R₉₃₁'s is the same as or different from each other;
when a plurality of R₉₃₂'s is present, the plurality of R₉₃₂'s is the same as or different from each other;
when a plurality of R₉₃₃'s is present, the plurality of R₉₃₃'s is the same as or different from each other;
when a plurality of R₉₃₄'s is present, the plurality of R₉₃₄'s is the same as or different from each other;
when a plurality of R₉₃₅'s is present, the plurality of R₉₃₅'s is the same as or different from each other;
when a plurality of R₉₃₆'s is present, the plurality of R₉₃₆'s is the same as or different from each other;
when a plurality of R₉₃₇'s is present, the plurality of R₉₃₇'s is the same as or different from each other;
when a plurality of R₉₃₈'s is present, the plurality of R₉₃₈'s is the same as or different from each other; and
when a plurality of R₉₃₉'s is present, the plurality of R₉₃₉'s is the same as or different from each other.

In the general formula (3), for example, a set of R₅ and R₆ form a substituted or unsubstituted single ring by bonding with each other, form a substituted or unsubstituted fused ring by bonding with each other, or do not bond with each other.

The compound according to the present embodiment is also preferably represented by the following general formula (3A).

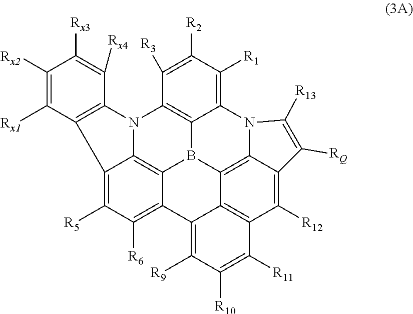

In the general formula (3A), R₁ to R₃, R₅ to R₁₃ and R_{Q} are independently the same as defined in the general formula (1), and Rₓ₁ to Rₓ₄ are independently the same as defined in the general formula (3).

In the compound according to the present embodiment, it is preferable that R₁ to R₁₃, R_{Q} and Rₓ₁ to Rₓ₄ be independently
a hydrogen atom,
a substituted or unsubstituted alkyl group having 1 to 50 carbon atoms,
a substituted or unsubstituted aryl group having 6 to 50 ring carbon atoms, or
a substituted or unsubstituted heteroaryl group having 5 to 50 ring atoms.

In the compound according to the present embodiment, it is preferable that R₁ to R₁₃, R_{Q} and Rₓ₁ to Rₓ₄ be independently
a hydrogen atom,
a substituted or unsubstituted alkyl group having 1 to 25 carbon atoms,
a substituted or unsubstituted aryl group having 6 to 25 ring carbon atoms, or
a substituted or unsubstituted heteroaryl group having 5 to 25 ring atoms.

The compound according to the present embodiment is also preferably represented by the following general formula (4).

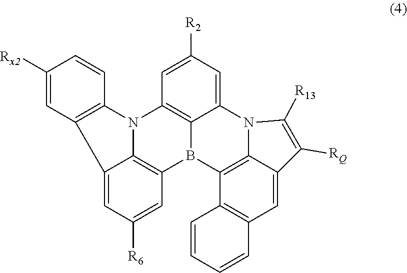

In the general formula (4), R₂, R₆, R₁₃, R_{Q} and Rₓ₂ are independently
a hydrogen atom,
a substituted or unsubstituted alkyl group having 1 to 10 carbon atoms,
a substituted or unsubstituted aryl group having 6 to 12 ring carbon atoms, or
a substituted or unsubstituted heteroaryl group having 5 to 18 ring atoms.

The compound according to the present embodiment is also preferably represented by the following general formula (5).

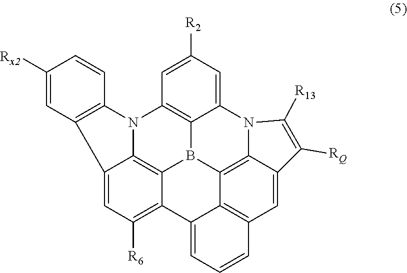

In the general formula (5), R₂, R₆, R₁₃, R_{Q} and Rₓ₂ are independently
a hydrogen atom,
a substituted or unsubstituted alkyl group having 1 to 10 carbon atoms,
a substituted or unsubstituted aryl group having 6 to 12 ring carbon atoms, or
a substituted or unsubstituted heteroaryl group having 5 to 18 ring atoms.

In the compound according to the present embodiment, it is preferable that R₁₃ and R_{Q} be independently
a substituted or unsubstituted alkyl group having 1 to 10 carbon atoms,
a substituted or unsubstituted phenyl group,
a substituted or unsubstituted naphthyl group, or
a substituted or unsubstituted dibenzofuranyl group.

It is preferable that R₆ and Rₓ₂ be independently a hydrogen atom, or a substituted or unsubstituted alkyl group having 1 to 10 carbon atoms.

In the compound according to the present embodiment, it is preferable that the substituent in the case of “substituted or unsubstituted” be
an unsubstituted alkyl group having 1 to 25 carbon atoms,
an unsubstituted alkenyl group having 2 to 25 carbon atoms,
an unsubstituted alkynyl group having 2 to 25 carbon atoms,
an unsubstituted cycloalkyl group having 3 to 25 ring carbon atoms,
a group represented by —Si(R₉₀₁)(R₉₀₂)(R₉₀₃),
a group represented by —O—(R₉₀₄),
a group represented by —S—(R₉₀₅),
a group represented by —N(R₉₀₆)(R₉₀₇),
an unsubstituted aralkyl group having 7 to 50 carbon atoms,
a group represented by —C(═O)R₉₀₆,
a group represented by —COOR₉₀₉,
a group represented by —S(═O)₂R₉₄₁,
a group represented by —P(═O)(R₉₄₂)(R₉₄₃),
a group represented by —Ge(R₉₄₄)(R₉₄₅)(R₉₄₆),
a halogen atom,
a cyano group,
a nitro group,
an unsubstituted aryl group having 6 to 25 ring carbon atoms, or
an unsubstituted heterocyclic group having 5 to 25 ring atoms; and
R₉₀₁ to R₉₀₉, and R₉₄₁ to R₉₄₆ be independently a hydrogen atom,
an unsubstituted alkyl group having 1 to 25 carbon atoms,
an unsubstituted aryl group having 6 to 25 ring carbon atoms, or
an unsubstituted heterocyclic group having 5 to 25 ring atoms.

In the compound according to the present embodiment, the substituent in the case of “substituted or unsubstituted” is preferably
a halogen atom,
an unsubstituted alkyl group having 1 to 25 carbon atoms,
an unsubstituted aryl group having 6 to 25 ring carbon atoms, or
an unsubstituted heterocyclic group having 5 to 25 ring atoms.

In the compound according to the present embodiment, the substituent in the case of “substituted or unsubstituted” is preferably
an unsubstituted alkyl group having 1 to 10 carbon atoms,
an unsubstituted aryl group having 6 to 12 ring carbon atoms, or
an unsubstituted heterocyclic group having 5 to 12 ring atoms.

In the compound according to the present embodiment, all groups described as “substituted or unsubstituted“are also preferably an” unsubstituted” group.

The compound C1 can be synthesized by using known alternative reactions adapted to the target compound, and raw materials.

### <Compound C2>

The compound C2 is not particularly limited as long as it is a compound having delayed fluorescence.

The word “delayed fluorescence” is explained on pages 261 to 268 of “Device Properties of Organic Semiconductors” (edited by Chihaya Adachi, published by Kodansha). In the document, it is described that when the energy difference ΔE₁₃ between the excited singlet state and the excited triplet state of the fluorescent emitting material can be reduced, the reverse energy transfer from the excited triplet state to the excited singlet state, which normally has a low transition probability, is caused with high efficiency, and then the thermally activated delayed fluorescence (Thermally Activated Delayed Fluorescence, TADF) is expressed. Furthermore, the mechanism of generation of delayed fluorescence is explained in FIG. 10. 38 of the document. The compound C2 in the present embodiment is preferably a compound exhibiting the thermally activated delayed fluorescence generated by such a mechanism.

An emission of the delayed fluorescence can be generally confirmed by measuring transient PL (Photo Luminescence).

The behavior of the delayed fluorescence can also be analyzed based on the attenuation curve obtained from the transient PL measurement. The transient PL measurement is a method for irradiating a sample with a pulsed laser to excite it, and measuring the attenuation behavior (transient characteristics) of PL emission after the irradiation is stopped. The PL emission of a TADF material is classified into an emission component from a singlet exciton generated by initial PL excitation and an emission component from a singlet exciton generated via a triplet exciton. The singlet exciton generated by the first PL excitation has a lifetime of the order of nanoseconds, which is very short. Therefore, the emission from the singlet exciton attenuates quickly after irradiation with the pulsed laser.

On the other hand, the delayed fluorescence attenuates slowly because it is emitted from the singlet exciton generated via the triplet exciton having a long lifetime. In this way, there is a large temporal difference between the light emission from the singlet exciton generated by the initial PL excitation and the emission from the singlet exciton generated via the triplet exciton. As a result, the emission intensity derived from the delayed fluorescence can be determined.

FIG. 2 shows a schematic diagram of an exemplary apparatus for measuring the transient PL. A method for measuring the transient PL using FIG. 2 and an example of behavior analysis of the delayed fluorescence will be described.

A transient PL measurement apparatus 100 in FIG. 2 includes a pulsed laser section 101 capable of irradiating light of a predetermined wavelength, a sample chamber 102 accommodating a measurement sample, a spectrometer 103 spectralizing the light emitted from the measurement sample, a streak camera 104 for forming a two-dimensional image, and a personal computer 105 for capturing and analyzing the two-dimensional images. The measurement of the transient PL is not limited to the apparatus shown in FIG. 2.

The sample accommodated in the sample chamber 102 is obtained by forming a thin film doped with a doping material at a concentration of 12% by mass based on the matrix material on a quartz substrate.

The thin film sample accommodated in the sample chamber 102 is irradiated with the pulsed laser from the pulsed laser section 101 to excite the doping material. The emission is extracted in a direction of 90° with respect to the irradiation direction of the excitation light, the extracted light is separated into spectra by the spectrometer 103, and the two-dimensional image is formed within the streak camera 104. As a result, the two-dimensional image can be obtained in which the vertical axis corresponds to time, the horizontal axis corresponds to wavelength, and the bright spot corresponds to emission intensity. When this two-dimensional image is cut out in a predetermined time axis, an emission spectrum can be obtained in which the vertical axis is the emission intensity and the horizontal axis is the wavelength. Further, when the two-dimensional image is cut out in the wavelength axis, an attenuation curve (transient PL) can be obtained in which the vertical axis is the logarithm of the emission intensity and the horizontal axis is the time.

For example, the following reference compound H₁ was used as the matrix material, the following reference compound D₁ was used as the doping material, the thin film sample A was prepared as described above, and the transient PL measurement was conducted.

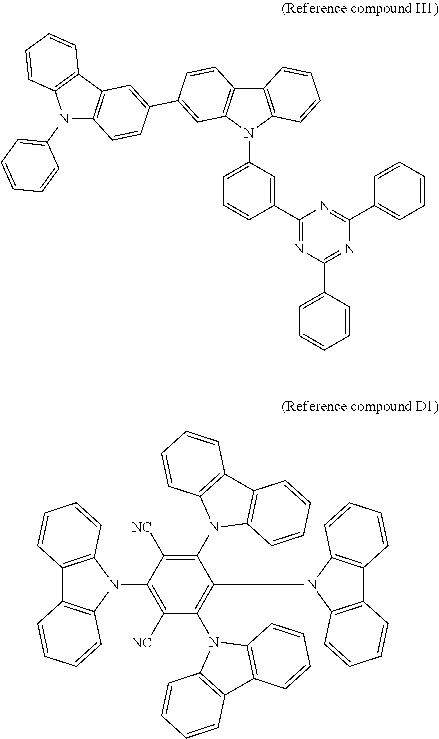 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

Here, the attenuation curve was analyzed using the thin film sample A and the thin film sample B. In the thin film sample B, the following reference compound H₂ was used as the matrix material, the reference compound D₁ was used as the doping material, and the thin film sample was prepared as described above.

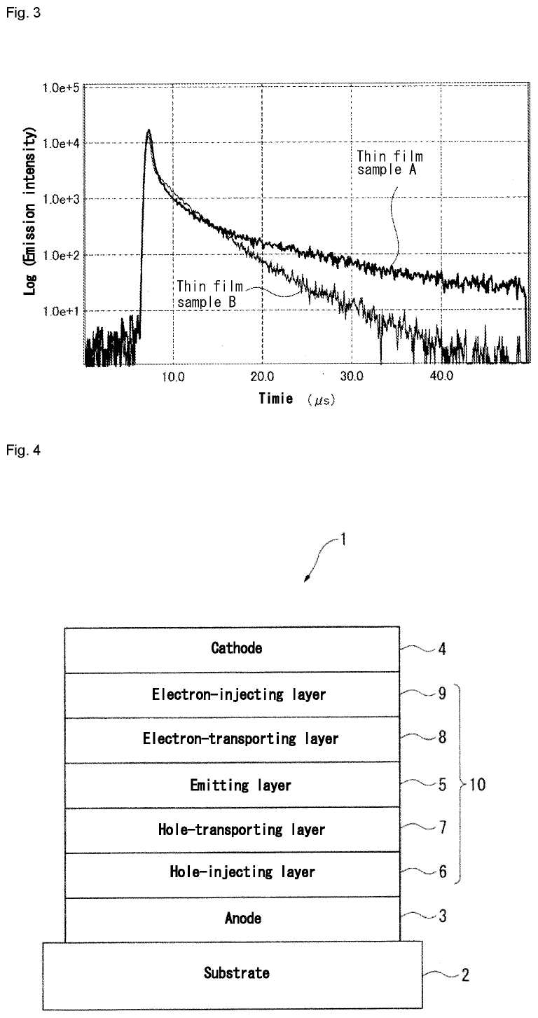

FIG. 3 shows the attenuation curve obtained from the transient PL measured for thin film sample A and thin film sample B.

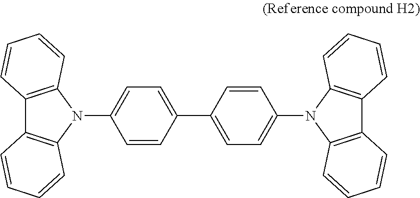 [SMILES: c1ccc2c(c1)c1ccccc1n2-c1ccc(-c2ccc(-n3c4ccccc4c4ccccc43)cc2)cc1]

As described above, when the transient PL measurement is conducted, the emission attenuation curve can be obtained in which the vertical axis is the emission intensity and the horizontal axis is the time. The fluorescence intensity ratio of the fluorescence emitted from the singlet excited state generated by photoexcitation and the delayed fluorescence emitted from the singlet excited state generated by reverse energy transfer via the triplet excited state can be estimated Based on this emission attenuation curve. In the material with delayed fluorescence, the ratio of the intensity of delayed fluorescence which attenuates slowly to the intensity of fluorescence which attenuates quickly is relatively large.

Specifically, there are Prompt emission (immediate emission) and Delay emission (delayed emission) as the emission from the material with delayed fluorescence. The Prompt emission (immediate emission) is an emission observed immediately from the excited state after it is excited by the pulsed light (light irradiated from a pulsed laser) having a wavelength which the material with delayed fluorescence absorbs. The Delay emission (delayed emission) is an emission not observed immediately but observed later after excitation by the pulsed light.

The amounts of Prompt emission and Delay emission and the ratio thereof can be determined in the same manner as that described in “Nature 492, 234-238, 2012” (reference document 1). An apparatus used to calculate the amounts of Prompt emission and Delay emission is not limited to the apparatus described in the reference document 1 or the apparatus described in FIG. 2.

Further, in the present embodiment, a sample prepared in the following method is used to measure the delayed fluorescence of the compound C2. For example, the compound C2 is dissolved in toluene to prepare a dilute solution having an absorbance of 0.05 or less at the excitation wavelength in order to eliminate the contribution of self-absorption. Furthermore, in order to prevent quenching by oxygen, the sample solution is frozen and degassed and then sealed in a cell with a lid under an argon atmosphere, thereby obtaining the sample solution saturated with argon and being oxygen-free.

The fluorescence spectrum of the above sample solution is measured using the Fluorescence Spectrophotometer FP-8600 (manufactured by JASCO Corporation), and the fluorescence spectrum of an ethanol solution of 9,10-diphenylanthracene is also measured under the same conditions. The total fluorescence quantum yield is calculated using the fluorescence area intensity of both spectra and using the formula (1) in Morris et al. J. Phys. Chem. 80(1976) 969.

The amounts of Prompt emission and Delay emission and the ratio thereof can be determined in the same manner as that described in “Nature 492, 234-238, 2012” (reference document 1). An apparatus used to calculate the amounts of Prompt emission and Delay emission is not limited to the apparatus described in the reference document 1 or the apparatus described in FIG. 2.

In the present embodiment, when the amount of Prompt emission (immediate emission) of the measurement target compound (compound C2) is defined as XP, and when the amount of Delay emission (delayed emission) thereof is defined as XD, the value of XD/XP is preferably 0.05 or more.

In the present specification, the measurement of the amounts of Prompt emission and Delay emission and the ratio thereof of a compound other than the first compound is also the same as the measurement of the amounts of Prompt emission and Delay emission and the ratio thereof of the first compound.

In one embodiment, the singlet energy of the compound C2 is greater than the singlet energy of the compound C1.

In one embodiment, the compound C2 is a compound represented by the following formula (1).

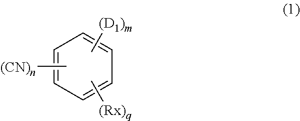

In the general formula (1), n is an integer of 1 or more and 4 or less; m is an integer of 1 or more and 4 or less; q is an integer of 0 or more and 4 or less; m+n+q=6;
CN is a cyano group;
D₁ is a group represented by the following general formula (2), the following general formula (3) or the following general formula (3x); a plurality of D₁'s is present, the plurality of D₁'s is the same as or different from each other;
Rx is a hydrogen atom or a substituent, or a set of the adjacent Rx's forms a ring by bonding with each other; a plurality of Rx's is present, the plurality of Rx's is the same as or different from each other;
Rx as the substituent is independently
a halogen atom,
a substituted or unsubstituted aryl group having 6 to 30 ring carbon atoms,
a substituted or unsubstituted heterocyclic group having 5 to 30 ring atoms,
a substituted or unsubstituted amino group,
a substituted or unsubstituted carbonyl group,
a substituted or unsubstituted alkyl group having 1 to 30 carbon atoms,
a substituted or unsubstituted halogenated alkyl group having 1 to 30 carbon atoms,
a substituted or unsubstituted alkylsilyl group having 3 to 30 carbon atoms, or
a substituted or unsubstituted arylsilyl group having 6 to 60 ring carbon atoms; and
each of CN, D₁ and Rx is bonded with the carbon atom in the six-membered ring.

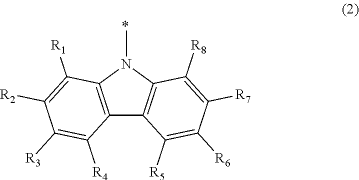

In the general formula (2), R₁ to R₈ are independently a hydrogen atom or a substituent, or any one or more sets of a set of R₁ and R₂, a set of R₂ and R₃, a set of R₃ and R₄, a set of R₅ and R₆, a set of R₆ and R₇, and a set of R₇ and R₈ form a ring by bonding with each other;
R₁ to R₈ as the substituent are independently
a halogen atom,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkylsilyl group having 3 to 30 carbon atoms,
a substituted or unsubstituted arylsilyl group having 6 to 60 ring carbon atoms,
a hydroxy group,
a substituted or unsubstituted alkoxy group having 1 to 30 carbon atoms,
a substituted or unsubstituted halogenated alkoxy group having 1 to 30 carbon atoms,
a substituted or unsubstituted aryloxy group having 6 to 30 ring carbon atoms,
a substituted or unsubstituted alkylamino group having 2 to 30 carbon atoms,
a substituted or unsubstituted arylamino group having 6 to 60 ring carbon atoms,
a thiol group,
a substituted or unsubstituted alkylthio group having 1 to 30 carbon atoms, or
a substituted or unsubstituted arylthio group having 6 to 30 ring carbon atoms; and
* represents a binding site with the carbon atom of the benzene ring in the general formula (1).

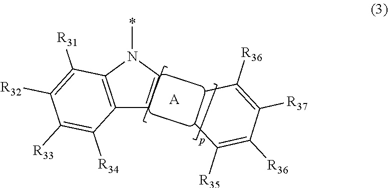

In the general formula (3), R₃₁ to R₃₈ are independently a hydrogen atom or a substituent, or any one or more sets of a set of R₃₁ and R₃₂, a set of R₃₂ and R₃₃, a set of R₃₃ and R₃₄, a set of R₃₅ and R₃₆, a set of R₃₆ and R₃₇, and a set of R₃₇ and R₃₈ form a ring by bonding with each other;
R₃₁ to R₃₈ as the substituent are independently the same as those defined for R₁ to R₈ in the general formula (2);
A represents a ring structure represented by the following general formula (131) or the following general formula (132); the ring structure A is fused with the adjacent ring structure at an arbitrary position; p is an integer of 1 or more and 4 or less; when p is an integer of 2 or more, the plurality of ring structures A is the same as or different from each other; and * represents a binding site with the carbon atom of the benzene ring in the general formula (1).

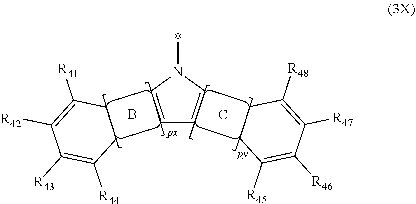

In the general formula (3X), R₄₁ to R₄₈ are independently a hydrogen atom or a substituent, or any one or more sets of a set of R₄₁ and R₄₂, a set of R₄₂ and R₄₃, a set of R₄₃ and R₄₄, a set of R₄₅ and R₄₆, a set of R₄₆ and R₄₇, and a set of R₄₇ and R₄₈ form a ring by bonding with each other;
R₄₁ to R₄₈ as the substituent are independently the same as those defined for R₃₁ to R₃₈ as the substituent in the general formula (3);
B represents a ring structure represented by the following general formula (131) or the following general formula (132); the ring structure B is fused with the adjacent ring structure at an arbitrary position; px is an integer of 1 or more and 4 or less; when px is an integer of 2 or more, the plurality of ring structures B is the same as or different from each other;
C represents a ring structure represented by the following general formula (131) or the following general formula (132); the ring structure C is fused with the adjacent ring structure at an arbitrary position; py is an integer of 1 or more and 4 or less; when py is an integer of 2 or more, the plurality of ring structures C is the same as or different from each other; and * represents a binding site with the carbon atom of the benzene ring in the general formula (1).

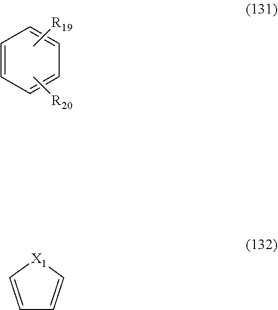

In the general formula (131), R₁ and R₂₀ are independently a hydrogen atom or a substituent, or form a ring by bonding with a part of the adjacent ring structure, or a set of R₁₉ and R₂₀ forms a ring by bonding with each other;
in the general formula (132), X₁ is CR₅₀R₅₁, NR₅₂, a sulfur atom, or an oxygen atom; R₅₀, R₅₁ and R₅₂ are independently a hydrogen atom or a substituent, or R₅₀ and R₅₁ form a ring by bonding with each other; and
R₁₉, R₂₀, R₅₀, R₅₁ and R₅₂ as the substituent are independently the same as those defined for R₁ to R₈ as the substituent in the general formula (2).

In the general formula (131), the expression “R₁₉ and R₂₀ are independently form a ring by bonding with a part of the adjacent ring structure” specifically means any of the following (I) to (IV).

Further, in the general formula (131), the expression “a set of R₁₉ and R₂₀ forms a ring by bonding with each other” specifically means the following (V). (I) When ring structures represented by the general formula (131) are adjacent, any one or more sets of a set of R₁₉ of one ring and R₁₉ of the other ring, a set of R₁₉ of one ring and R₂₀ of the other ring, and a set of R₂₀ of one ring and R₂₀ of the other ring in the adjacent two rings form a ring by bonding with each other.

(II) When the ring structure represented by the general formula (131) and the benzene ring having R₃₅ to R₃₈ in the general formula (3) are adjacent, any one or more sets of a set of R₁₉ of one ring and R₃₅ of the other ring, a set of R₁₉ of one ring and R₃₈ of the other ring, a set of R₂₀ of one ring and R₃₅ of the other ring, and a set of R₂₀ of one ring and R₃₈ of the other ring in the adjacent two rings form a ring by bonding with each other.
(III) When the ring structure represented by the general formula (131) and the benzene ring having R₄₁ to R₄₄ in the general formula (3X) are adjacent, any one or more sets of a set of R₁₉ of one ring and R₄₁ of the other ring, a set of R₁₉ of one ring and R₄₄ of the other ring, a set of R₂₀ of one ring and R₄₁ of the other ring, and a set of R₂₀ of one ring and R₄₄ of the other ring in the adjacent two rings form a ring by bonding with each other.
(IV) When the ring structure represented by the general formula (131) and the benzene ring having R₄₅ to R₄₈ in the general formula (3X) are adjacent, any one or more sets of a set of R₁₉ of one ring and R₄₅ of the other ring, a set of R₁₉ of one ring and R₄₈ of the other ring, a set of R₂₀ of one ring and R₄₅ of the other ring, and a set of R₂₀ of one ring and R₄₈ of the other ring in the adjacent two rings form a ring by bonding with each other.
(V) A set of R₁₉ and R₂₀ of the ring structure represented by the general formula (131) forms a ring by bonding with each other. That is, the case (V) means that a set of R₁₉ and R₂₀ bonding to the same ring forms a ring by bonding with each other.

In the compound C2 of the present embodiment, Rx is independently
a hydrogen atom,
an unsubstituted aryl group having 6 to 30 ring carbon atoms,
an unsubstituted heterocyclic group having 5 to 30 ring atoms, or
an unsubstituted alkyl group having 1 to 30 carbon atoms, and
when Rx is an unsubstituted heterocyclic group having 5 to 30 ring atoms, Rx for the unsubstituted heterocyclic group having 5 to 30 ring atoms is preferably a pyridyl group, a pyrimidinyl group, a triazinyl group, a dibenzofuranyl group, or a dibenzothienyl group.

In the present specification, the triazinyl group means a group formed by removing one hydrogen atom from 1,3,5-triazine, 1,2,4-triazine, or 1,2,3-triazine.

The triazinyl group is preferably a group formed by removing one hydrogen atom from 1,3,5-triazine.

In the compound C2 of the present embodiment, it is more preferable that Rx be independently
a hydrogen atom,
an unsubstituted aryl group having 6 to 30 ring carbon atoms, or
an unsubstituted a dibenzofuranyl group, or
an unsubstituted a dibenzothienyl group.

In the compound C2 of the present embodiment, Rx is still more preferably a hydrogen atom.

In the compound C2 of the present embodiment, it is preferable that R₁ to R₈, R₃₁ to R₃₈, R₁₉ to R₂₀, R₄₁ to R₄₈, and R₅₀ and R₅₂ as the substituent be independently
an unsubstituted aryl group having 6 to 30 ring carbon atoms,
an unsubstituted heterocyclic group having 5 to 30 ring atoms, or
an unsubstituted alkyl group having 1 to 30 carbon atoms.

The compound C2 of the present embodiment is preferably a compound represented by any one of the following general formulas (1-1) to (1-47).

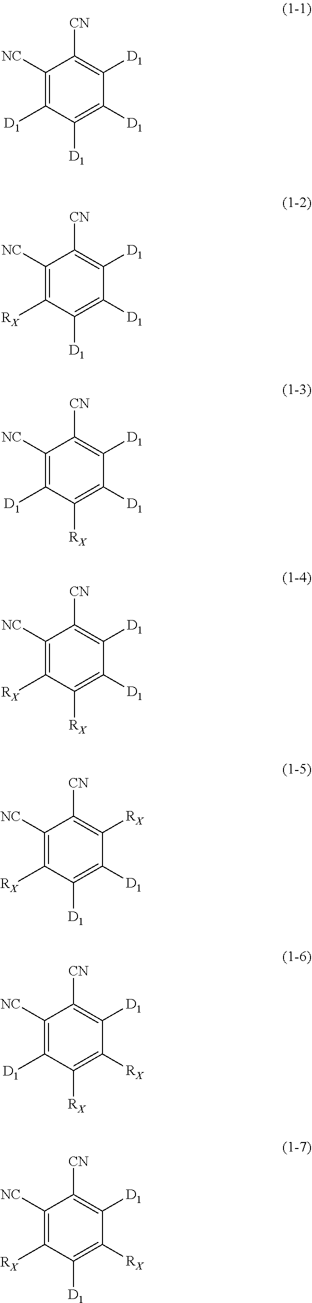

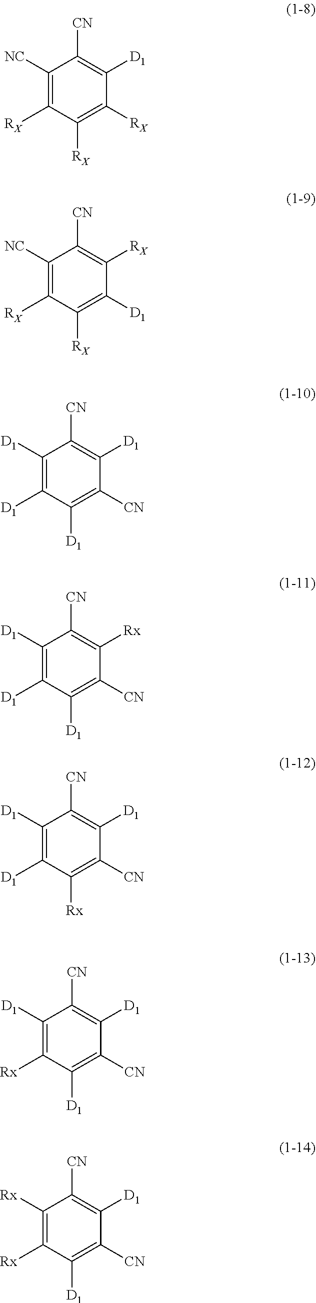

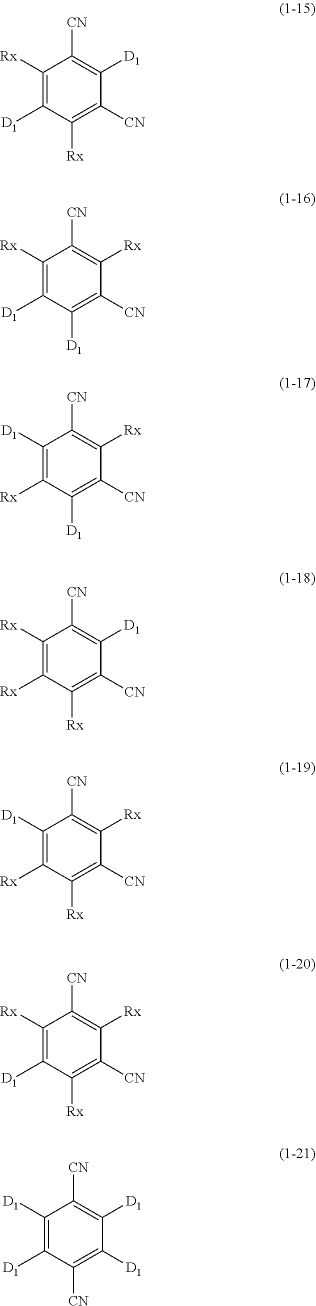

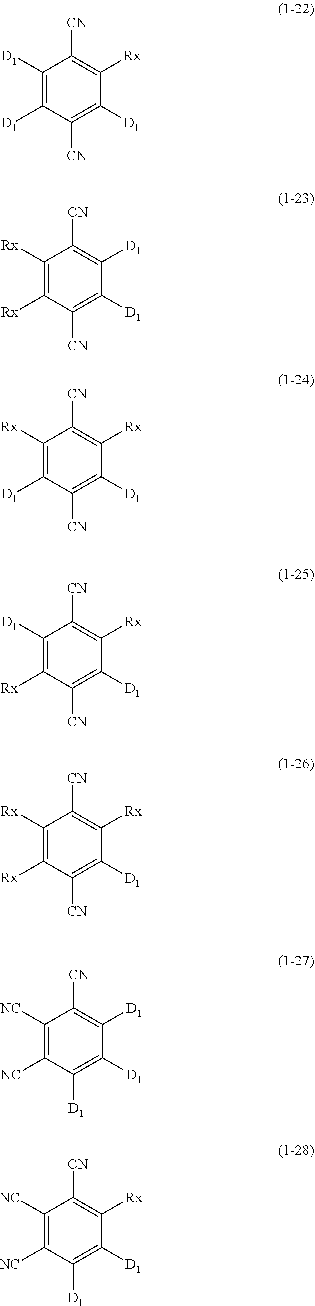

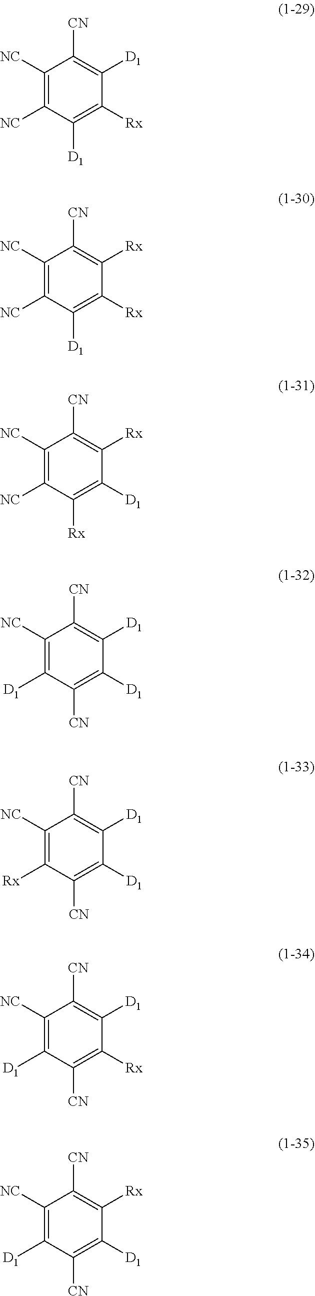

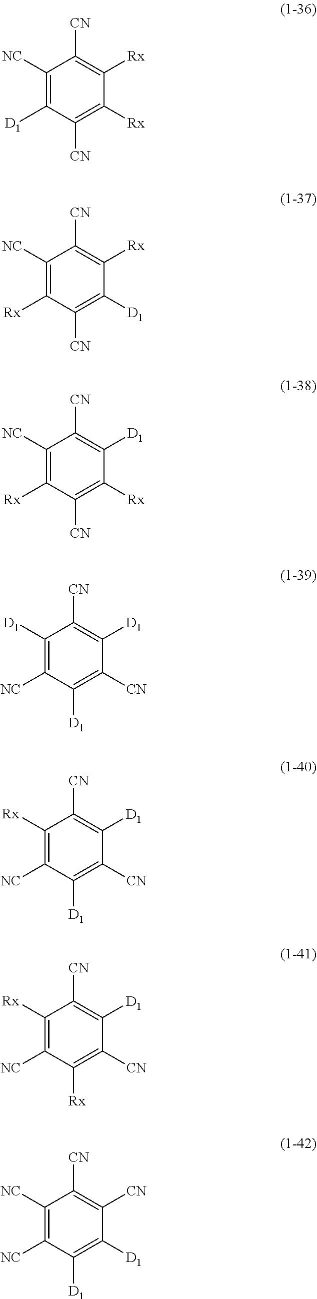

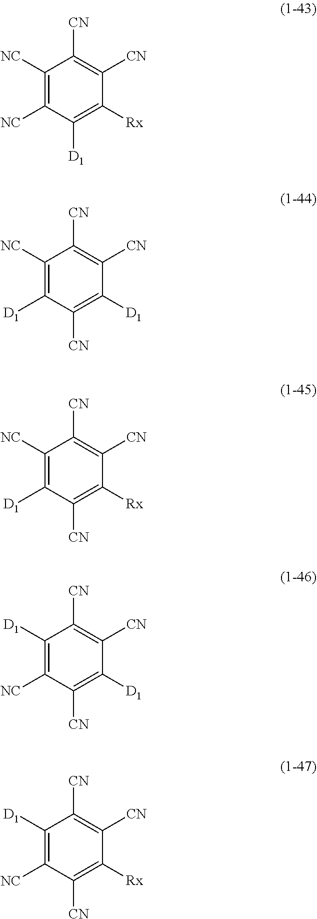

D₁ in the general formulas (1-1) to (1-47) is independently the same as defined for D₁ in the general formula (1), and Rx is independently the same as defined for Rx in the general formula (1).

The compound C2 of the present embodiment is preferably a compound represented by any one of the general formulas (1-4) to (1-7), (1-14) to (1-17) and (1-23) to (1-25).

The compound C2 of the present embodiment is more preferably a compound represented by the general formula (1-6), (1-23) or (1-24).

The compound C2 of the present embodiment is still more preferably a compound represented by the following general formula (1-6A), (1-23A) or (1-24A).

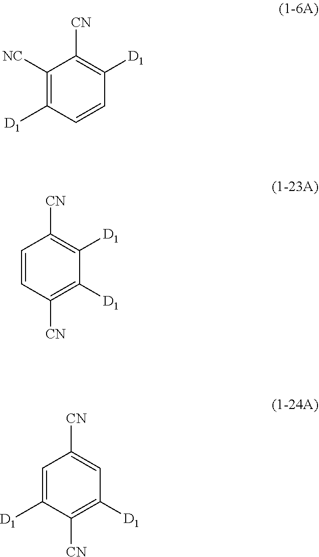

D₁ in the general formulas (1-6A), (1-23A) and (1-24A) is independently the same as defined for D₁ in the general formula (1).

The compound C2 of the present embodiment is also preferably the compound represented by the general formula (1-6).

The compound C2 of the present embodiment is also preferably the compound represented by the general formula (1-23).

The compound C2 of the present embodiment is also preferably the compound represented by the general formula (1-24).

The compound C2 of the present embodiment is also preferably the compound represented by the general formula (1-1), (1-10) or (1-21).

In the compound C2 of the present embodiment, D₁ is preferably a group represented by any one of the following general formulas (3-1) to (3-12).

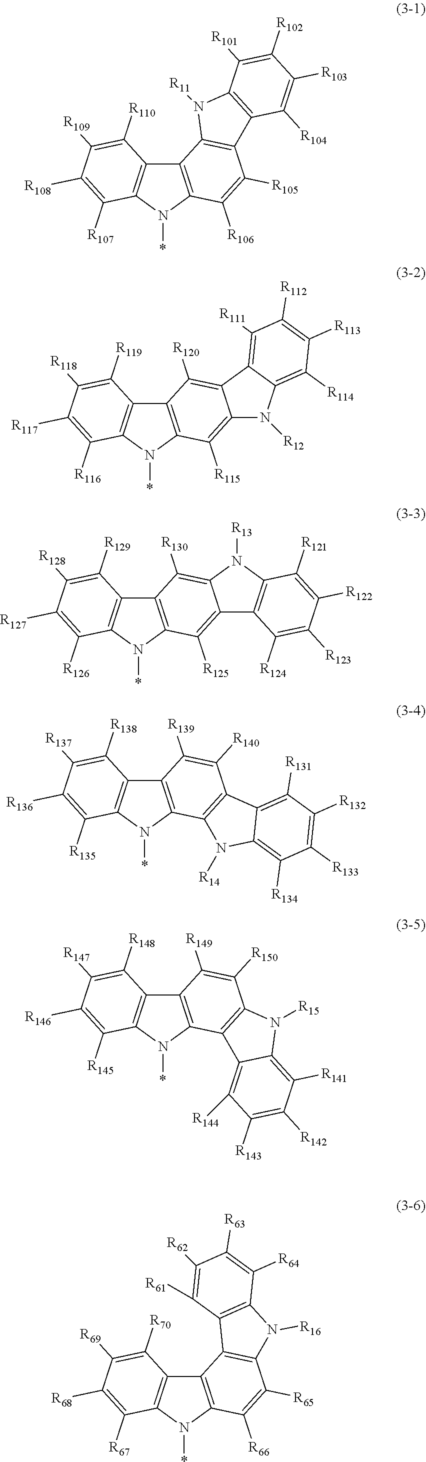

In the general formulas (3-1) to (3-6), R₁₁ to R₁₆ are a substituent; R₁₀₁ to R₁₅₀ and R₆₁ to R₇₀ are independently a hydrogen atom or a substituent;
R₁₀₁ to R₁₅₀ to and R₆₁ to R₇₀ as the substituent are independently
a substituted or unsubstituted aryl group having 6 to 14 ring carbon atoms,
a substituted or unsubstituted heterocyclic group having 5 to 14 ring atoms,
a substituted or unsubstituted alkyl group having 1 to 6 carbon atoms,
a substituted or unsubstituted alkylsilyl group having 3 to 6 carbon atoms,
a hydroxy group,
a substituted or unsubstituted alkoxy group having 1 to 6 carbon atoms,
a substituted or unsubstituted aryloxy group having 6 to 14 ring carbon atoms,
a substituted or unsubstituted arylamino group having 6 to 28 ring carbon atoms,
a substituted or unsubstituted alkylamino group having 2 to 12 carbon atoms,
a thiol group,
a substituted or unsubstituted alkylthio group having 1 to 6 carbon atoms, or
a substituted or unsubstituted arylthio group having 6 to 14 ring carbon atoms;
R₁₁ to R₁₆ as the substituent are independently
a substituted or unsubstituted alkyl group having 1 to 6 carbon atoms
a substituted or unsubstituted aryl group having 6 to 14 ring carbon atoms,
a substituted or unsubstituted heterocyclic group having 5 to 14 ring atoms,
a substituted or unsubstituted alkylsilyl group having 3 to 6 carbon atoms,
a substituted or unsubstituted aryloxy group having 6 to 14 ring carbon atoms,
a substituted or unsubstituted alkylamino group having 2 to 12 carbon atoms,
a substituted or unsubstituted alkylthio group having 1 to 6 carbon atoms, or
a substituted or unsubstituted arylthio group having 6 to 14 ring carbon atoms; and
* represents a binding site with the carbon atom of the benzene ring in the general formula (1).

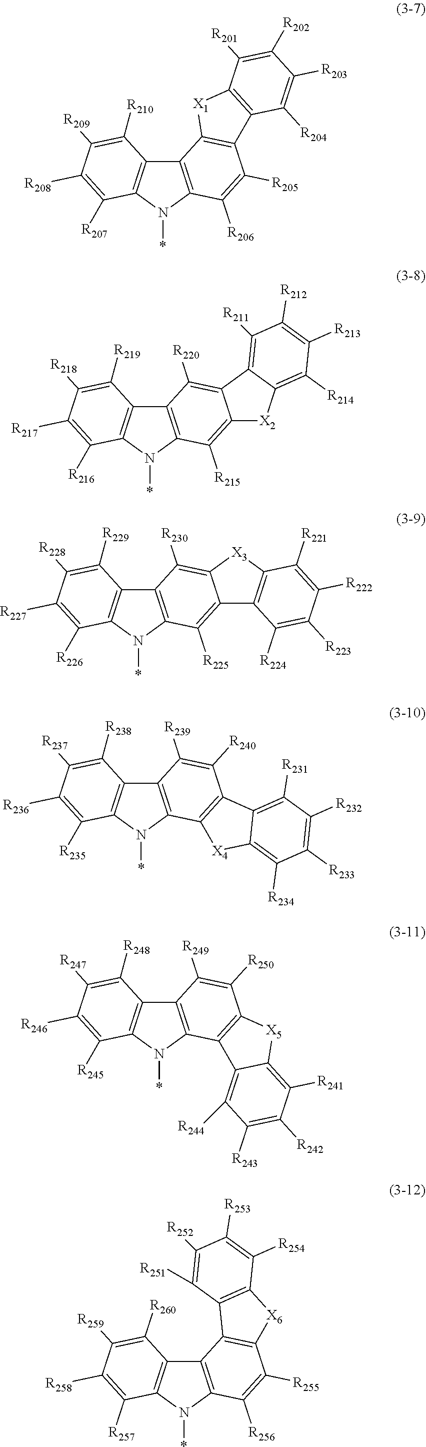

In the general formulas (3-7) to (3-12), X₁ to X₆ are independently an oxygen atom, a sulfur atom, or CR₁₅₁R₁₅₂; R₂₀₁ to R₂₆₀ are independently a hydrogen atom or a substituent; R₁₅₁ and R₁₅₂ are independently a hydrogen atom or a substituent, or R₁₅₁ and R₁₅₂ form a ring by bonding with each other;
R₂₀₁ to R₂₆₀, R₁₅₁ and R₁₅₂ as the substituent are independently
a halogen atom,
a substituted or unsubstituted aryl group having 6 to 14 ring carbon atoms,
a substituted or unsubstituted heterocyclic group having 5 to 14 ring atoms,
a substituted or unsubstituted alkyl group having 1 to 6 carbon atoms,
a substituted or unsubstituted halogenated alkyl group having 1 to 6 carbon atoms,
a substituted or unsubstituted alkylsilyl group having 3 to 6 carbon atoms,
a hydroxy group,
a substituted or unsubstituted alkoxy group having 1 to 6 carbon atoms,
a substituted or unsubstituted halogenated alkoxy group having 1 to 6 carbon atoms,
a substituted or unsubstituted aryloxy group having 6 to 14 ring carbon atoms,
a substituted or unsubstituted arylamino group having 6 to 28 ring carbon atoms,
a substituted or unsubstituted alkylamino group having 2 to 12 carbon atoms,
a thiol group,
a substituted or unsubstituted alkylthio group having 1 to 6 carbon atoms, or
a substituted or unsubstituted arylthio group having 6 to 14 ring carbon atoms; and
* represents a binding site with the carbon atom of the benzene ring in the general formula (1).

In the compound C2 of the present embodiment, D₁ is also preferably a group represented by any one of the general formulas (3-7) to (3-12), and X₁ to X₆ is also preferably a sulfur atom in the general formulas (3-7) to (3-12).

In the compound C2 of the present embodiment, D₁ is also preferably a group represented by the general formula (3-12), and X₆ is also preferably a sulfur atom in the general formula (3-12).

In the compound C2 of the present embodiment, it is also preferable that D₁ be a group represented by any one of the general formulas (3-7) to (3-12), and X₁ to X₆ be an oxygen atom in the general formulas (3-7) to (3-12).

In the compound C2 of the present embodiment, it is also preferable that D₁ be a group represented by any one of the general formulas (3-7) to (3-12), and X₁ to X₆ be CR₁₅₁R₁₅₂ in the general formulas (3-7) to (3-12).

In the compound C2 of the present embodiment, D₁ is also preferably a group represented by any one of the general formulas (3-1) to (3-6).

It is also preferable that the compound C2 of the present embodiment be a compound represented by any one of the general formulas (1-4) to (1-7), (1-14) to (1-17) and (1-23) to (1-25), and D₁ be a group represented by any one of the general formulas (3-1) to (3-12).

It is also preferable that the compound C2 of the present embodiment be a compound represented by any one of the general formulas (1-4) to (1-7), (1-14) to (1-17) and (1-23) to (1-25), D₁ be a group represented by any one of the general formulas (3-7) to (3-12), and X₁ to X₆ be a sulfur atom in the general formulas (3-7) to (3-12).

It is also preferable that the compound C2 of the present embodiment be a compound represented by the general formula (1-6), (1-23) or (1-24), D₁ be a group represented by any one of the general formulas (3-7) to (3-12), and X₁ to X₆ be a sulfur atom in the general formulas (3-7) to (3-12).

It is also preferable that the compound C2 of the present embodiment be a compound represented by any one of the general formulas (1-4) to (1-7), (1-14) to (1-17) and (1-23) to (1-25), D₁ be a group represented by any one of the general formulas (3-7) to (3-12), and X₁ to X₆ be an oxygen atom in the general formulas (3-7) to (3-12).

It is also preferable that the compound C2 of the present embodiment be a compound represented by the general formula (1-6), (1-23) or (1-24), D₁ be a group represented by any one of the general formulas (3-7) to (3-12), and X₁ to X₆ be an oxygen atom in the general formulas (3-7) to (3-12).

It is also preferable that the compound C2 of the present embodiment be a compound represented by any one of the general formulas (1-4) to (1-7), (1-14) to (1-17) and (1-23) to (1-25), D₁ be a group represented by any one of the general formulas (3-7) to (3-12), and X₁ to X₆ be CR₁₅₁R₁₅₂ in the general formulas (3-7) to (3-12).

It is also preferable that the compound C2 of the present embodiment be a compound represented by the general formula (1-6), (1-23) or (1-24), D₁ be a group represented by any one of the general formulas (3-7) to (3-12), and X₁ to X₆ be CR₁₅₁R₁₅₂ in the general formulas (3-7) to (3-12).

It is also preferable that the compound C2 of the present embodiment be a compound represented by any one of the general formulas (1-4) to (1-7), (1-14) to (1-17) and (1-23) to (1-25), and D₁ be a group represented by any one of the general formulas (3-1) to (3-6).

It is also preferable that the compound C2 of the present embodiment be a compound represented by the general formula (1-6), (1-23) or (1-24), and D₁ be a group represented by any one of the general formulas (3-1) to (3-6).

In the compound C2 of the present embodiment, it is preferable that R₁₀₁ to R₁₅₀ and R₆₁ to R₇₀ as the substituent be independently
an unsubstituted aryl group having 6 to 14 ring carbon atoms,
an unsubstituted heterocyclic group having 5 to 14 ring atoms, or
an unsubstituted alkyl group having 1 to 6 carbon atoms, and
R₁₁ to R₁₆ as the substituent be independently
an unsubstituted aryl group having 6 to 14 ring carbon atoms, or
an unsubstituted heterocyclic group having 5 to 14 ring atoms.

In the compound C2 of the present embodiment, it is also preferable that R₁₀₁ to R₁₅₀ and R₆₁ to R₇₀ be hydrogen atoms, and
R₁₁ to R₁₆ as the substituent be independently
an unsubstituted aryl group having 6 to 14 ring carbon atoms, or
an unsubstituted heterocyclic group having 5 to 14 ring atoms.

In the compound C2 of the present embodiment, it is preferable that R₂₀₁ to R₂₆₀ as the substituent be independently
a halogen atom,
an unsubstituted aryl group having 6 to 14 ring carbon atoms,
an unsubstituted heterocyclic group having 5 to 14 ring atoms,
an unsubstituted alkyl group having 1 to 6 carbon atoms, and
R₁₅₁ and R₁₅₂ as the substituent be independently
an unsubstituted aryl group having 6 to 14 ring carbon atoms, or
an unsubstituted alkyl group having 1 to 6 carbon atoms.

Further, in the compound C2 of the present embodiment, it is more preferable that R₂₀₁ to R₂₆₀ as the substituent be independently
an unsubstituted aryl group having 6 to 14 ring carbon atoms,
an unsubstituted heterocyclic group having 5 to 14 ring atoms,
an unsubstituted alkyl group having 1 to 6 carbon atoms, and
R₁₅₁ and R₁₅₂ as the substituent be independently
an unsubstituted aryl group having 6 to 14 ring carbon atoms, or
an unsubstituted alkyl group having 1 to 6 carbon atoms.

In the compound C2 of the present embodiment, it is also preferable that R₂₀₁ to R₂₆₀ be hydrogen atoms, and
R₁₅₁ and R₁₅₂ as the substituent be independently
an unsubstituted aryl group having 6 to 14 ring carbon atoms, or
an unsubstituted alkyl group having 1 to 6 carbon atoms.

In the compound C2 of the present embodiment, D₁ is also preferably a group represented by the following general formula (2-1), (2-2), (2-3) or (2-4).

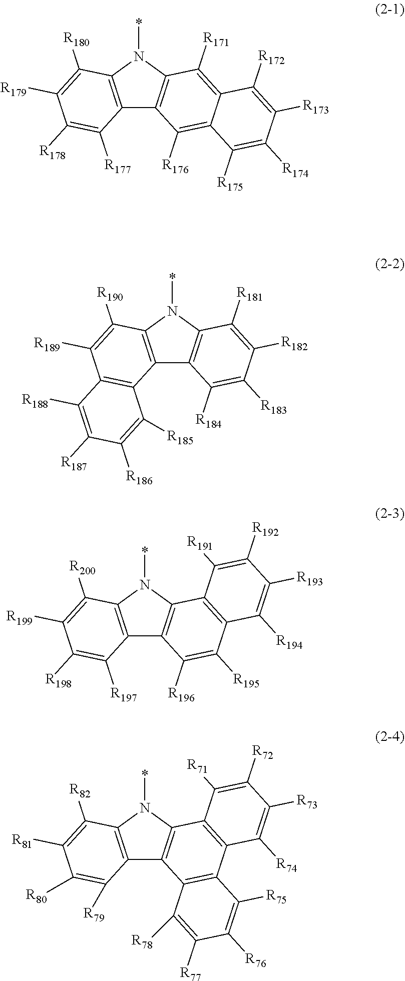

In the general formulas (2-1) to (2-4), R₁₇₁ to R₂₀₀ and R₇₁ to R₈₂ are independently a hydrogen atom or a substituent, or any one or more sets of a set of R₁₇₁ and R₁₇₂, a set of R₁₇₂ and R₁₇₃, a set of R₁₇₃ and R₁₇₄, a set of R₁₇₄ and R₁₇₅, a set of R₁₇₅ and R₁₇₆, a set of R₁₇₇ and R₁₇₈, a set of R₁₇₈ and R₁₇₉, a set of R₁₇₉ and R₁₈₀, a set of R₁₈₁ and R₁₈₂, a set of R₁₈₂ and R₁₈₃, a set of R₁₈₃ and R₁₈₄, a set of R₁₈₅ and R₁₈₆, a set of R₁₈₆ and R₁₈₇, a set of R₁₈₇ and R₁₈₈, a set of R₁₈₈ and R₁₈₉, a set of R₁₈₉ and R₁₉₀, a set of R₁₉₁ and R₁₉₂, a set of R₁₉₂ and R₁₉₃, a set of R₁₉₃ and R₁₉₄, a set of R₁₉₄ and R₁₉₅, a set of R₁₉₅ and R₁₉₆, a set of R₁₉₇ and R₁₉₈, a set of R₁₉₈ and R₁₉₉, a set of R₁₉₉ and R₂₀₀, a set of R₇₁ and R₇₂, a set of R₇₂ and R₇₃, a set of R₇₃ and R₇₄, a set of R₇₅ and R₇₆, a set of R₇₆ and R₇₇, a set of R₇₇ and R₇₈, a set of R₇₉ and Rao, a set of Rao and R₈₁, and a set of R₈₁ and R₈₂ form a ring by bonding with each other;
R₁₇₁ to R₂₀₀ and R₇₁ to R₈₂ as the substituent are independently
a halogen atom,
a substituted or unsubstituted aryl group having 6 to 14 ring carbon atoms,
a substituted or unsubstituted heterocyclic group having 5 to 14 ring atoms,
a substituted or unsubstituted alkyl group having 1 to 6 carbon atoms,
a substituted or unsubstituted halogenated alkyl group having 1 to 30 carbon atoms,
a substituted or unsubstituted alkylsilyl group having 3 to 6 carbon atoms,
a hydroxy group,
a substituted or unsubstituted alkoxy group having 1 to 6 carbon atoms,
a substituted or unsubstituted halogenated alkoxy group having 1 to 6 carbon atoms,
a substituted or unsubstituted aryloxy group having 6 to 14 ring carbon atoms,
a substituted or unsubstituted alkylamino group having 2 to 12 carbon atoms,
a thiol group,
a substituted or unsubstituted alkylthio group having 1 to 6 carbon atoms, or
a substituted or unsubstituted arylthio group having 6 to 14 ring carbon atoms; and
* represents a binding site with the carbon atom of the benzene ring in the general formula (1).

In the compound C2 of the present embodiment, D₁ is also more preferably a group represented by the general formula (2-1), (2-3) or (2-4).

In the compound C2 of the present embodiment, D₁ is also still more preferably a group represented by the general formula (2-1) or (2-3).

It is also preferable that the compound C2 of the present embodiment be a compound represented by any one of the general formulas (1-1), (1-4) to (1-7), (1-10), (1-14) to (1-17), (1-21) and (1-23) to (1-25), and D₁ be a group represented by the general formula (2-1), (2-2), (2-3), or (2-4).

It is also preferable that the compound C2 of the present embodiment be a compound represented by the general formula (1-6), (1-23) or (1-24), and D₁ be a group represented by the general formula (2-1), (2-2), (2-3), or (2-4).

It is also preferable that the compound C2 of the present embodiment be a compound represented by the general formula (1-1), (1-10) or (1-21), and D₁ be a group represented by the general formula (2-1), (2-2), (2-3), or (2-4), and also more preferably the general formula (2-1), (2-3) or (2-4).

In the compound C2 of the present embodiment, it is preferable that R₁₇₁ to R₂₀₀ and R₇₁ to R₈₂ as the substituent be independently
an unsubstituted aryl group having 6 to 14 ring carbon atoms,
an unsubstituted heterocyclic group having 5 to 14 ring atoms, or
an unsubstituted alkyl group having 1 to 6 carbon atoms.

In the compound C2 of the present embodiment, R₁₇₁ to R₂₀₀ and R₇₁ to R₈₂ is also preferably a hydrogen atom.

In one embodiment, a phosphorescent compound which emits phosphorescence can be used as the compound C2. The phosphorescent compound is a compound which can emit from a triplet excited state, but it may also have delayed fluorescence, so it can be used as the compound C2 in the present invention. As a blue phosphorescent emitting material, metal complexes such as iridium complexes, osmium complexes and platinum complexes can be given. As a green phosphorescent emitting material, iridium complexes and the like can be given. As a red phosphorescent emitting material, metal complexes such as iridium complexes, platinum complexes, terbium complexes and europium complexes can be given.

The compound C2 can be synthesized by using known alternative reactions adapted to the target compound, and raw materials.

### <Compound C3>

The compound C3 is not particularly limited as long as it is a compound different from both the compound C1 and the compound C2.

In one embodiment, the compound C3 is a compound having a singlet energy greater than the singlet energy of the compound C2.

The compound C3 may be a compound having delayed fluorescence, or may be a compound not having delayed fluorescence.

The compound C3 is not particularly limited, but it is preferably a compound other than an amine compound. Further, for example, a carbazole derivative, a dibenzofuran derivative, a dibenzothiophene derivative can be used as the compound C3, but it is not limited to these derivatives.

In one embodiment, the compound C3 is a compound containing at least one of a structure of moiety represented by the following general formula (31), a structure of moiety represented by the following general formula (32), a structure of moiety represented by the following general formula (33), and a structure of moiety represented by the following general formula (34) in one molecule.

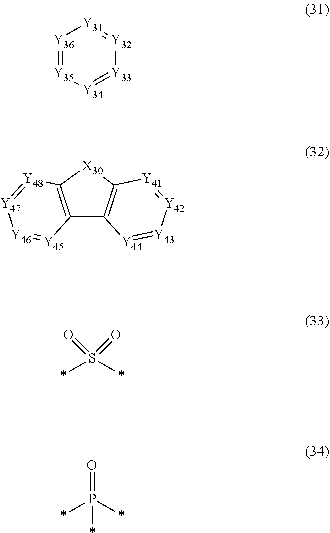

In the general formula (31),
Y₃₁ to Y₃₆ are independently a nitrogen atom, or a carbon atom to be bonded to another atom in the molecule of the compound C3;
provided that at least one of Y₃₁ to Y₃₆ is a carbon atom to be bonded to another atom in the molecule of the compound C3;
in the general formula (32),
Y₄₁ to Y₄₈ are independently a nitrogen atom, or a carbon atom to be bonded to another atom in the molecule of the compound C3;
provided that at least one of Y₄₁ to Y₄₈ is a carbon atom to be bonded to another atom in the molecule of the compound C3;
X₃₀ is a nitrogen atom to be bonded to another atom in the molecule of the compound C3, an oxygen atom, or a sulfur atom; and
in the general formulas (33) to (34), *'s independently represent a binding site with another atom or another structure in the molecule of the compound C3.

In the general formula (32), it is also preferable that at least two of Y₄₁ to Y₄₈ be carbon atoms to be bonded to another atom in the molecule of the compound C3, and a ring structure including the carbon atoms be formed.

For example, the structure of moiety represented by the general formula (32) is preferably any one structure of moiety selected from the group consisting of structures of moieties represented by the following general formula (321), the following general formula (322), the following general formula (323), the following general formula (324), the following general formula (325), and the following general formula (326).

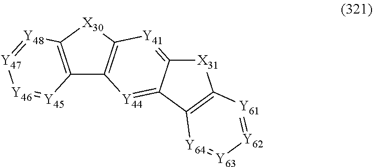

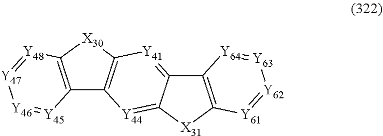

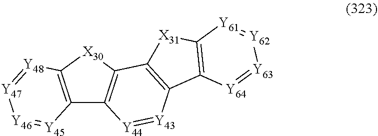

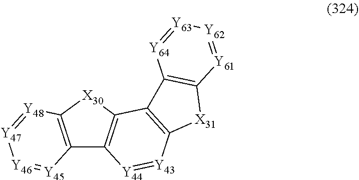

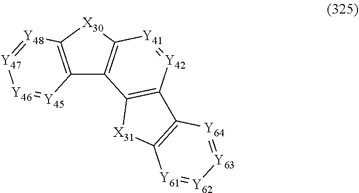

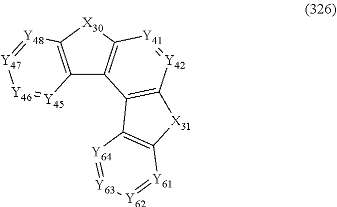

In the general formulas (321) to (326),
X₃₀ is independently a nitrogen atom to be bonded to another atom in the molecule of the compound C3, an oxygen atom, or a sulfur atom;
Y₄₁ to Y₄₈ are independently a nitrogen atom, or a carbon atom to be bonded to another atom in the molecule of the compound C3;
X₃₁ is independently a nitrogen atom to be bonded to another atom in the molecule of the compound C3, an oxygen atom, a sulfur atom, or a carbon atom to be bonded to another atom in the molecule of the compound C3; and
Y₆₁ to Y₆₄ are independently a nitrogen atom, or a carbon atom to be bonded to another atom in the molecule of the compound C3.

In the present embodiment, the compound C3 preferably has the structure of moiety represented by the general formula (323) in the general formulas (321) to (326).

The structure of moiety represented by the general formula (31) is preferably included in the compound C3 as at least one group selected from the group consisting of a group represented by the following general formula (33), and a group represented by the following general formula (34).

The compound of the present embodiment also preferably has at least one structure of moiety in structures of moieties represented by the following general formula (33), and the following general formula (34). Since binding sites are located at meta positions as in structures of moieties represented by the following general formula (33), and the following general formula (34), the energy gap T_{77K} (Mat3) of the compound C3 at 77 [K] can be kept high.

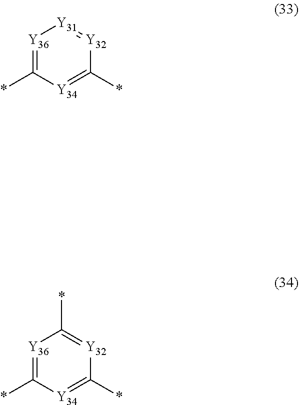

In the general formula (33), Y₃₁, Y₃₂, Y₃₄, and Y₃₆ are independently a nitrogen atom, or CR₃₁;
in the general formula (34), Y₃₂, Y₃₄, and Y₃₆ are independently a nitrogen atom, or CR₃₁;
in the general formulas (33), and (34),
R₃₁ is independently a hydrogen atom or a substituent;
R₃₁ as the substituent is independently selected from the group consisting of
a substituted or unsubstituted aryl group having 6 to 30 ring carbon atoms,
a substituted or unsubstituted heteroaryl group having 5 to 30 ring atoms,
a substituted or unsubstituted alkyl group having 1 to 30 carbon atoms,
a substituted or unsubstituted fluoroalkyl group having 1 to 30 carbon atoms,
a substituted or unsubstituted cycloalkyl group having 3 to 30 ring carbon atoms,
a substituted or unsubstituted aralkyl group having 7 to 30 carbon atoms,
a substituted or unsubstituted silyl group,
a substituted germanium group,
a substituted phosphine oxide group,
a halogen atom,
a cyano group,
a nitro group, and
a substituted or unsubstituted carboxy group;
provided that the substituted or unsubstituted aryl group having 6 to 30 ring carbon atoms for R₃₁ is preferably non-fused ring; and
in the general formula (33), and the general formula (34), *'s independently represent a binding site with another atom or another structure in the molecule of the compound C3.

In the general formula (33), it is preferable that Y₃₁, Y₃₂, Y₃₄, and Y₃₆ be independently CR₃₁, and the plurality of R₃₁'s is the same as or different from each other.

Further, in the general formula (34), it is preferable that Y₃₂, Y₃₄, and Y₃₆ are independently CR₃₁, and the plurality of R₃₁'s is the same as or different from each other.

The substituted germanium group is preferably represented by —Ge(R₃₀₁)₃. R₃₀₁'s are independently a substituent. The substituent R₃₀₁ is preferably a substituted or unsubstituted alkyl group having 1 to 30 carbon atoms, or a substituted or unsubstituted aryl group having 6 to 30 ring carbon atoms. The plurality of R₃₀₁'s is the same as or different from each other.

The structure of moiety represented by the general formula (32) is preferably included in the compound C3 as at least one group selected from the group consisting of groups represented by the following general formulas (35) to (39), and the following general formula (30a).

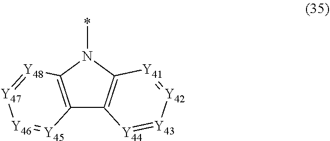

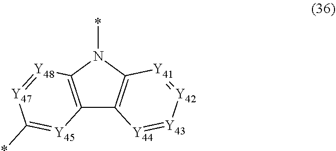

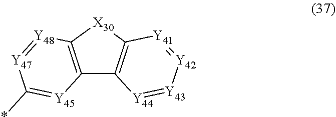

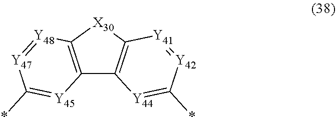

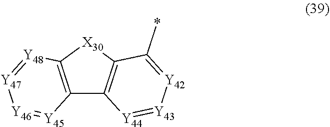

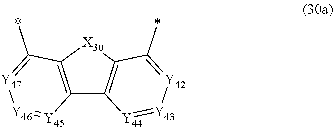

In the general formula (35), Y₄₁ to Y₄₈ are independently a nitrogen atom, or CR₃₂;
in the general formulas (36), and (37), Y₄₁ to Y₄₅, Y₄₇, and Y₄₈ are independently a nitrogen atom, or CR₃₂;
in the general formula (38), Y₄₁, Y₄₂, Y₄₄, Y₄₅, Y₄₇, and Y₄₈ are independently a nitrogen atom, or CR₃₂;
in the general formula (39), Y₄₂ to Y₄₈ are independently a nitrogen atom, or CR₃₂;
in the general formula (30a), Y₄₂ to Y₄₇ are independently a nitrogen atom, or CR₃₂;
in the general formulas (35) to (39), and (30a),
R₃₂ is independently a hydrogen atom or a substituent;
R₃₂ as the substituent is selected from the group consisting of
a substituted or unsubstituted aryl group having 6 to 30 ring carbon atoms,
a substituted or unsubstituted heteroaryl group having 5 to 30 ring atoms,
a substituted or unsubstituted alkyl group having 1 to 30 carbon atoms,
a substituted or unsubstituted fluoroalkyl group having 1 to 30 carbon atoms,
a substituted or unsubstituted cycloalkyl group having 3 to 30 ring carbon atoms,
a substituted or unsubstituted aralkyl group having 7 to 30 carbon atoms,
a substituted or unsubstituted silyl group,
a substituted germanium group,
a substituted phosphine oxide group,
a halogen atom,
a cyano group,
a nitro group, and
a substituted or unsubstituted carboxy group;
the plurality of R₃₂'s is the same as or different from each other;
in the general formulas (37) to (39), and (30a),
X₃₀ is NR₃₃, an oxygen atom, or a sulfur atom;
R₃₃ is selected from the group consisting of
a substituted or unsubstituted aryl group having 6 to 30 ring carbon atoms,
a substituted or unsubstituted heteroaryl group having 5 to 30 ring atoms,
a substituted or unsubstituted alkyl group having 1 to 30 carbon atoms,
a substituted or unsubstituted fluoroalkyl group having 1 to 30 carbon atoms,
a substituted or unsubstituted cycloalkyl group having 3 to 30 ring carbon atoms,
a substituted or unsubstituted aralkyl group having 7 to 30 carbon atoms,
a substituted or unsubstituted silyl group,
a substituted germanium group,
a substituted phosphine oxide group,
a fluorine atom,
a cyano group,
a nitro group, and
a substituted or unsubstituted carboxy group;
the plurality of R₃₃'s is the same as or different from each other;
provided that the substituted or unsubstituted aryl group having 6 to 30 ring carbon atoms for R₃₃ is preferably non-fused ring; and
in the general formulas (35) to (39), and (30a), *'s independently represent a binding site with another atom or another structure in the molecule of the compound C3.

In the general formula (35), it is preferable that Y₄₁ to Y₄₈ be independently CR₃₂, in the general formula (36), and the general formula (37), it is preferable that Y₄₁ to Y₄₅, Y₄₇, and Y₄₈ are independently CR₃₂, in the general formula (38), it is preferable that Y₄₁, Y₄₂, Y₄₄, Y₄₅, Y₄₇, and Y₄₈ are independently CR₃₂, in the general formula (39), it is preferable that Y₄₂ to Y₄₈ are independently CR₃₂, in the general formula (30a), it is preferable that Y₄₂ to Y₄₇ are independently CR₃₂, and the plurality of R₃₂'s is the same as or different from each other.

In the compound of the present embodiment, X₃₀ is preferably an oxygen atom or a sulfur atom, and more preferably an oxygen atom.

In the compound of the present embodiment, it is preferable that R₃₁, and R₃₂ be independently a hydrogen atom or a substituent, and R₃₁ as the substituent, and R₃₂ as the substituent be independently any one group selected from the group consisting of a fluorine atom, a cyano group, a substituted or unsubstituted alkyl group having 1 to 30 carbon atoms, a substituted or unsubstituted aryl group having 6 to 30 ring carbon atoms, and a substituted or unsubstituted heteroaryl group having 5 to 30 ring atoms. R₃₁, and R₃₂ is more preferably a hydrogen atom, a cyano group, a substituted or unsubstituted aryl group having 6 to 30 ring carbon atoms, or a substituted or unsubstituted heteroaryl group having 5 to 30 ring atoms. Provided that R₃₁ as the substituent, and R₃₂ as the substituent is a substituted or unsubstituted aryl group having 6 to 30 ring carbon atoms, the aryl group is preferably non-fused ring.

The compound of the present embodiment is also preferably an aromatic hydrocarbon compound, or an aromatic heterocyclic compound.

Examples the substituent is the compound of the present embodiment include those as follows, and the present invention is not limited to these examples.

Specific examples of the aryl group (sometimes referred to as an aromatic hydrocarbon group) include a phenyl group, a tolyl group, a xylyl group, a naphthyl group, a phenanthryl group, a pyrenyl group, a chrysenyl group, a benzo[c]phenanthryl group, a benzo[g]chrysenyl group, a benzanthryl group, a triphenylenyl group, a fluorenyl group, a 9,9-dimethylfluorenyl group, a benzofluorenyl group, a dibenzofluorenyl group, a biphenyl group, a terphenyl group, a quaterphenyl group, a fluoranthenyl group, and the like, and preferably a phenyl group, a biphenyl group, a terphenyl group, a quaterphenyl group, a naphthyl group, a triphenylenyl group, a fluorenyl group, and the like.

As the aryl group having a substituent, a tolyl group, a xylyl group, a 9,9-dimethylfluorenyl group, and the like can be given.

As shown in the specific examples, the aryl group includes both of a fused aryl group, and non-fused aryl group.

The aryl group is preferably a phenyl group, a biphenyl group, a terphenyl group, a quaterphenyl group, a naphthyl group, a triphenylenyl group, or a fluorenyl group.

Specific examples of the heteroaryl group (sometimes referred to as a heterocyclic group, a heteroaromatic ring group, or an aromatic heterocyclic group) include a pyrrolyl group, a pyrazolyl group, a pyrazinyl group, a pyrimidinyl group, a pyridazinyl group, a pyridyl group, a triazinyl group, an indolyl group, an isoindolyl group, an imidazolyl group, a benzimidazolyl group, an indazolyl group, imidazo[1,2-a]pyridinyl group, a furyl group, a benzofuranyl group, an isobenzofuranyl group, a dibenzofuranyl group, an azadibenzofuranyl group, a thiophenyl group, a benzothienyl group, a dibenzothienyl group, an azadibenzothienyl group, a quinolyl group, an isoquinolyl group, a quinoxalinyl group, a quinazolinyl group, a naphthyridinyl group, a carbazolyl group, an azacarbazolyl group, a phenanthridinyl group, an acridinyl group, a phenanthrolinyl group, a phenazinyl group, a phenothiazinyl group, a phenoxazinyl group, an oxazolyl group, an oxadiazolyl group, a furazanyl group, a benzoxazolyl group, a thienyl group, a thiazolyl group, a thiadiazolyl group, a benzothiazolyl group, a triazolyl group, a tetrazolyl group, and the like, and preferably a dibenzofuranyl group, a dibenzothienyl group, a carbazolyl group, a pyridyl group, a pyrimidinyl group, a triazinyl group, an azadibenzofuranyl group, an azadibenzothienyl group, and the like.

The heteroaryl group is preferably a dibenzofuranyl group, a dibenzothienyl group, a carbazolyl group, a pyridyl group, a pyrimidinyl group, a triazinyl group, an azadibenzofuranyl group, or an azadibenzothienyl group, and more preferably a dibenzofuranyl group, a dibenzothienyl group, an azadibenzofuranyl group, or an azadibenzothienyl group.

In the compound of the present embodiment, a substituted silyl group is also preferably selected from the group consisting of a substituted or unsubstituted trialkylsilyl group, a substituted or unsubstituted arylalkylsilyl group, and a substituted or unsubstituted triarylsilyl group.

As specific examples of the substituted or unsubstituted trialkylsilyl group, a trimethylsilyl group, and a triethylsilyl group can be given.

As specific examples of the substituted or unsubstituted arylalkylsilyl group, a diphenylmethylsilyl group, a ditolylmethylsilyl group, a phenyldimethylsilyl group, and the like can be given.

As specific examples of the substituted or unsubstituted triarylsilyl group, a triphenylsilyl group, a tritolylsilyl group, and the like can be given.

In the compound of the present embodiment, the substituted phosphine oxide group is also preferably a substituted or unsubstituted diarylphosphine oxide group.

As specific examples of the substituted or unsubstituted diarylphosphine oxide group, a diphenylphosphine oxide group, a ditolylphosphine oxide group, and the like can be given.

In the compound of the present embodiment, examples of the substituted carboxy group include a benzyloxy group, and the like.

In one embodiment, the compound C3 is a compound represented by the following general formula (3).

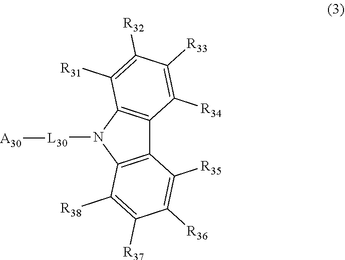

In the general formula (3), A₃₀ is a group represented by the following general formula (3a), the following general formula (3b), the following general formula (3c), the following general formula (3d), the following general formula (3e) or the following general formula (3f.

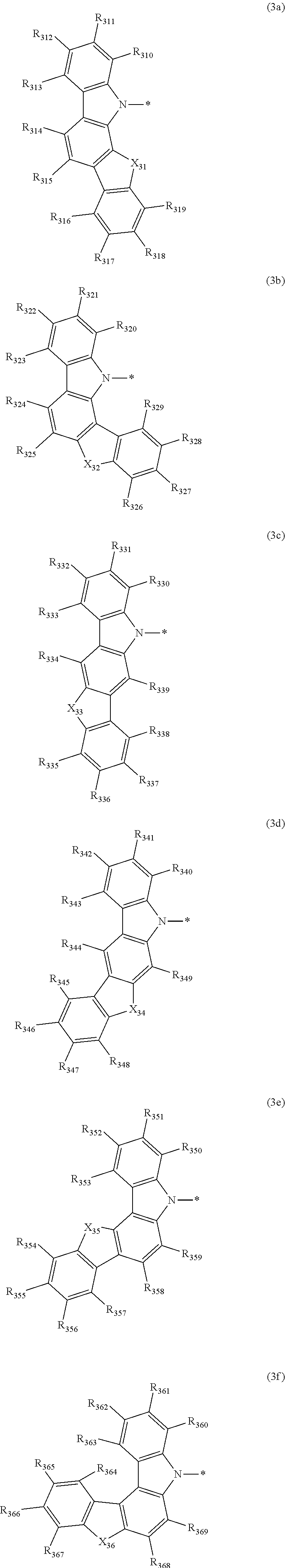

In the general formula (3a), the general formula (3b), the general formula (3c), the general formula (3d), the general formula (3e) and the general formula (3f),
X₃₁, X₃₂, X₃₃, X₃₄, X₃₅ and X₃₆ are independently an oxygen atom, a sulfur atom, NR₃₇₁ or SiR₃₇₂R₃₇₃;
R₃₇₁, R₃₇₂ and R₃₇₃ are independently a hydrogen atom or a substituent;
R₃₁₀ to R₃₁₉ are independently a hydrogen atom or a substituent, or any one or more sets of a set of R₃₁₀ and R₃₁₁, a set of R₃₁₁ and R₃₁₂, a set of R₃₁₂ and R₃₁₃, a set of R₃₁₄ and R₃₁₅, a set of R₃₁₆ and R₃₁₇, a set of R₃₁₇ and R₃₁₈, and a set of R₃₁₈ and R₃₁₉ form a ring by bonding with each other;
R₃₂₀ to R₃₂₉ are independently a hydrogen atom or a substituent, or any one or more sets of a set of R₃₂₀ and R₃₂₁, a set of R₃₂₁ and R₃₂₂, a set of R₃₂₂ and R₃₂₃, a set of R₃₂₄ and R₃₂₅, a set of R₃₂₆ and R₃₂₇, a set of R₃₂₇ and R₃₂₈, and a set of R₃₂₈ and R₃₂₉ form a ring by bonding with each other;
R₃₃₀ to R₃₃₉ are independently a hydrogen atom or a substituent, or any one or more sets of a set of R₃₃₀ and R₃₃₁, a set of R₃₃₁ and R₃₃₂, a set of R₃₃₂ and R₃₃₃, a set of R₃₃₅ and R₃₃₆, a set of R₃₃₆ and R₃₃₇, and a set of R₃₃₇ and R₃₃₈ form a ring by bonding with each other;
R₃₄₀ to R₃₄₉ are independently a hydrogen atom or a substituent, or any one or more sets of a set of R₃₄₀ and R₃₄₁, a set of R₃₄₁ and R₃₄₂, a set of R₃₄₂ and R₃₄₃, a set of R₃₄₅ and R₃₄₆, a set of R₃₄₆ and R₃₄₇, and a set of R₃₄₇ and R₃₄₈ form a ring by bonding with each other;
R₃₅₀ to R₃₅₉ are independently a hydrogen atom or a substituent, or any one or more sets of a set of R₃₅₀ and R₃₅₁, a set of R₃₅₁ and R₃₅₂, a set of R₃₅₂ and R₃₅₃, a set of R₃₅₄ and R₃₅₅, a set of R₃₅₅ and R₃₅₆, a set of R₃₅₆ and R₃₅₇, and a set of R₃₅₈ and R₃₅₉ form a ring by bonding with each other;
R₃₆₀ to R₃₆₉ are independently a hydrogen atom or a substituent, or any one or more sets of a set of R₃₆₀ and R₃₆₁, a set of R₃₆₁ and R₃₆₂, a set of R₃₆₂ and R₃₆₃, a set of R₃₆₄ and R₃₆₅, a set of R₃₆₅ and R₃₆₆, a set of R₃₆₆ and R₃₆₇, and a set of R₃₆₈ and R₃₆₉ form a ring by bonding with each other;
R₃₇₁, R₃₇₂ and R₃₇₃ as the substituent, and R₃₁₀ to R₃₁₉, R₃₂₀ to R₃₂₉, R₃₃₀ to R₃₃₉, R₃₄₀ to R₃₄₉, R₃₅₀ to R₃₅₉ and R₃₆₀ to R₃₆₉ as the substituent are independently
a halogen atom,
a cyano group,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkenyl group having 2 to 30 carbon atoms,
a substituted or unsubstituted alkynyl group having 2 to 30 carbon atoms,
a substituted or unsubstituted alkylsilyl group having 3 to 30 carbon atoms,
a substituted or unsubstituted arylsilyl group having 6 to 60 ring carbon atoms,
a substituted or unsubstituted arylphosphoryl group having 6 to 60 ring carbon atoms,
a hydroxy group,
a substituted or unsubstituted alkoxy group having 1 to 30 carbon atoms,
a substituted or unsubstituted aryloxy group having 6 to 30 ring carbon atoms, an amino group,
a substituted or unsubstituted alkylamino group having 2 to 30 carbon atoms,
a substituted or unsubstituted arylamino group having 6 to 60 ring carbon atoms, a thiol group,
a substituted or unsubstituted alkylthio group having 1 to 30 carbon atoms, or
a substituted or unsubstituted arylthio group having 6 to 30 ring carbon atoms;
* represents a bonding position with L₃₀; in the general formula (3),
L₃₀ is
a substituted or unsubstituted arylene group having 6 to 22 ring carbon atoms,
a group formed by bonding two substituted or unsubstituted arylene groups having 6 to 22 ring carbon atoms, or
a group formed by bonding three substituted or unsubstituted arylene groups having 6 to 22 ring carbon atoms;
R₃₁ to R₃₈ are independently a hydrogen atom or a substituent, or any one or more sets of a set of R₃₁ and R₃₂, a set of R₃₂ and R₃₃, a set of R₃₃ and R₃₄, a set of R₃₅ and R₃₆, a set of R₃₆ and R₃₇, and a set of R₃₇ and R₃₈ form a ring by bonding with each other; and
the substituent in the case where L₃₀ has the substituent, and R₃₁ to R₃₈ as the substituent are independently
a halogen atom,
a cyano group,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkenyl group having 2 to 30 carbon atoms,
a substituted or unsubstituted alkynyl group having 2 to 30 carbon atoms,
a substituted or unsubstituted alkylsilyl group having 3 to 30 carbon atoms,
a substituted or unsubstituted arylsilyl group having 6 to 60 ring carbon atoms,
a substituted or unsubstituted arylphosphoryl group having 6 to 60 ring carbon atoms,
a hydroxy group,
a substituted or unsubstituted alkoxy group having 1 to 30 carbon atoms,
a substituted or unsubstituted aryloxy group having 6 to 30 ring carbon atoms,
an amino group,
a substituted or unsubstituted alkylamino group having 2 to 30 carbon atoms,
a substituted or unsubstituted arylamino group having 6 to 60 ring carbon atoms,
a thiol group,
a substituted or unsubstituted alkylthio group having 1 to 30 carbon atoms, or
a substituted or unsubstituted arylthio group having 6 to 30 ring carbon atoms.

In the compound of the present embodiment, A₃₀ is preferably a group represented by the general formula (3a) or the general formula (3d).

In the compound of the present embodiment, A₃₀ is more preferably a group represented by the general formula (3a). When A₃₀ is a group represented by the general formula (3a), the compound of the present embodiment is represented by the following general formula (3A).

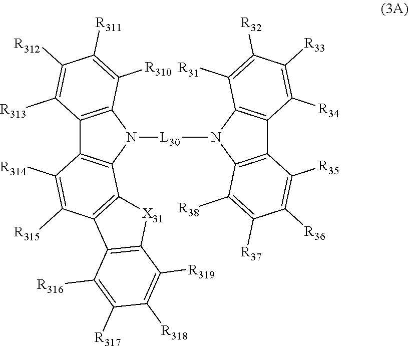

In the general formula (3A), R₃₁ to R₃₈, L₃₀, X₃₁ and R₃₁₀ to R₃₁₉ are independently the same as defined for R₃₁ to R₃₈, L₃₀, X₃₁ and R₃₁₀ to R₃₁₉ in the general formula (3) or the general formula (3a).

In the compound of the present embodiment, a set of R₃₁ and R₃₂, a set of R₃₂ and R₃₃, a set of R₃₃ and R₃₄, a set of R₃₅ and R₃₆, a set of R₃₆ and R₃₇, and a set of R₃₇ and R₃₈ do not also preferably bond with each other. That is, in the compound of the present embodiment, it is also preferable that R₃₁ to R₃₈ be independently a hydrogen atom or a substituent.

In the compound of the present embodiment, at least one set of a set of R₃₁ and R₃₂, a set of R₃₂ and R₃₃, a set of R₃₃ and R₃₄, a set of R₃₅ and R₃₆, a set of R₃₆ and R₃₇, and a set of R₃₇ and R₃₈ also preferably forms a ring by bonding with each other.

The compound of the present embodiment is also preferably represented by the following general formula (31), the following general formula (32), the following general formula (33), the following general formula (34), the following general formula (35) or the following general formula (36).

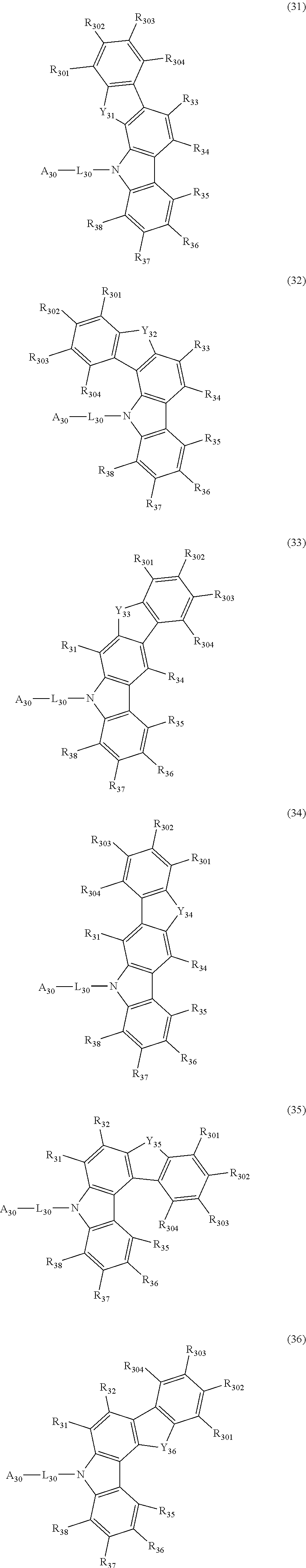

In the general formulas (31) to (36),
Y₃₁, Y₃₂, Y₃₃, Y₃₄, Y₃₅ and Y₃₆ are independently an oxygen atom, a sulfur atom, NR₃₇₄ or SiR₃₇₅R₃₇₆;
R₃₇₄, R₃₇₅ and R₃₇₆ are independently a hydrogen atom or a substituent;
A₃₀, L₃₀ and R₃₁ to R₃₈ are independently the same as defined for A₃₀, L₃₀ and R₃₁ to R₃₈ in the general formula (3);
R₃₀₁ to R₃₀₄ are independently a hydrogen atom or a substituent, or any one or more sets of a set of R₃₀₁ and R₃₀₂, a set of R₃₀₂ and R₃₀₃, and a set of R₃₀₃ and R₃₀₄ form a ring by bonding with each other; and
R₃₀₁ to R₃₀₄ as the substituent, and R₃₇₄, R₃₇₅ and R₃₇₆ as the substituent are independently
a halogen atom,
a cyano group,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkenyl group having 2 to 30 carbon atoms,
a substituted or unsubstituted alkynyl group having 2 to 30 carbon atoms,
a substituted or unsubstituted alkylsilyl group having 3 to 30 carbon atoms,
a substituted or unsubstituted arylsilyl group having 6 to 60 ring carbon atoms,
a substituted or unsubstituted arylphosphoryl group having 6 to 60 ring carbon atoms,
a hydroxy group,
a substituted or unsubstituted alkoxy group having 1 to 30 carbon atoms,
a substituted or unsubstituted aryloxy group having 6 to 30 ring carbon atoms,
an amino group,
a substituted or unsubstituted alkylamino group having 2 to 30 carbon atoms,
a substituted or unsubstituted arylamino group having 6 to 60 ring carbon atoms,
a thiol group,
a substituted or unsubstituted alkylthio group having 1 to 30 carbon atoms, or
a substituted or unsubstituted arylthio group having 6 to 30 ring carbon atoms.

In the compound of the present embodiment, all of a set of R₃₀₁ and R₃₀₂, a set of R₃₀₂ and R₃₀₃, and a set of R₃₀₃ and R₃₀₄ do not preferably bond with each other.

In the compound of the present embodiment, it is preferable that R₃₀₁ to R₃₀₄ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the compound of the present embodiment, it is more preferable that R₃₀₁ to R₃₀₄ be independently a hydrogen atom, a substituted or unsubstituted aryl group having 6 to 30 ring carbon atoms, or a substituted or unsubstituted heterocyclic group having 5 to 30 ring atoms.

In the compound of the present embodiment, it is still more preferable that R₃₀₁ to R₃₀₄ be independently a hydrogen atom, or a substituted or unsubstituted aryl group having 6 to 30 ring carbon atoms.

In the compound of the present embodiment, R₃₀₁ to R₃₀₄ are still more preferably hydrogen atoms.

In the compound of the present embodiment, it is preferable that Y₃₁, Y₃₂, Y₃₃, Y₃₄, Y₃₅ and Y₃₆ are independently an oxygen atom or a sulfur atom.

In the compound of the present embodiment, it is preferable that R₃₁ to R₃₈ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the compound of the present embodiment, it is more preferable that R₃₁ to R₃₈ be independently a hydrogen atom, a substituted or unsubstituted aryl group having 6 to 30 ring carbon atoms, or a substituted or unsubstituted heterocyclic group having 5 to 30 ring atoms.

In the compound of the present embodiment, it is still more preferable that R₃₁ to R₃₈ be independently a hydrogen atom, or a substituted or unsubstituted aryl group having 6 to 30 ring carbon atoms.

In the compound of the present embodiment, R₃₁ to R₃₈ are still more preferably hydrogen atoms.

In the compound of the present embodiment, it is preferable that R₃₁ to R₃₈, and R₃₀₁ to R₃₀₄ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the compound of the present embodiment, it is more preferable that R₃₁ to R₃₈, and R₃₀₁ to R₃₀₄ be independently a hydrogen atom, a substituted or unsubstituted aryl group having 6 to 30 ring carbon atoms, or a substituted or unsubstituted heterocyclic group having 5 to 30 ring atoms.

In the compound of the present embodiment, it is still more preferable that R₃₁ to R₃₈, and R₃₀₁ to R₃₀₄ be independently a hydrogen atom, or a substituted or unsubstituted aryl group having 6 to 30 ring carbon atoms.

In the compound of the present embodiment, R₃₁ to R₃₈, and R₃₀₁ to R₃₀₄ are still more preferably hydrogen atoms.

In the compound of the present embodiment, L₃₀ is preferably a substituted or unsubstituted phenylene group, a substituted or unsubstituted biphenylene group, or a substituted or unsubstituted terphenylene group.

In the compound of the present embodiment, L₃₀ is more preferably a substituted or unsubstituted biphenylene group.

In the compound of the present embodiment, the substituent (the substituent is sometimes referred to as a substituent FL) in the case where L₃₀ has the substituent is preferably a substituted or unsubstituted aryl group having 6 to 30 ring carbon atoms, or a substituted or unsubstituted alkyl group having 1 to 30 carbon atoms.

In the compound of the present embodiment, L₃₀ is also preferably at least one group selected from the group consisting of groups represented by the following general formulas (L30-1) to (L30-4), (L30-4-2) and (L30-5) to (L30-11).

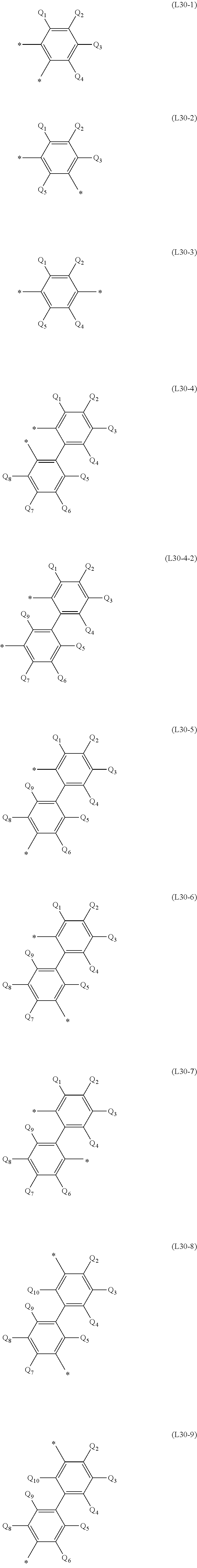

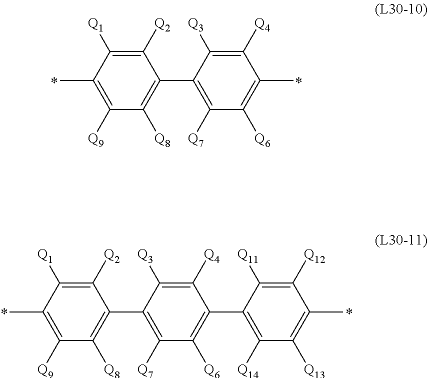

In the general formulas (L30-1) to (L30-4), (L30-4-2) and (L30-5) to (L30-11), Q₁ to Q₁₄ are independently a hydrogen atom, or a substituent; and Q₁ to Q₁₄ as the substituent are independently
a halogen atom,
a cyano group,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkenyl group having 2 to 30 carbon atoms,
a substituted or unsubstituted alkynyl group having 2 to 30 carbon atoms,
a substituted or unsubstituted alkylsilyl group having 3 to 30 carbon atoms,
a substituted or unsubstituted arylsilyl group having 6 to 60 ring carbon atoms,
a substituted or unsubstituted arylphosphoryl group having 6 to 60 ring carbon atoms,
a hydroxy group,
a substituted or unsubstituted alkoxy group having 1 to 30 carbon atoms,
a substituted or unsubstituted aryloxy group having 6 to 30 ring carbon atoms,
an amino group,
a substituted or unsubstituted alkylamino group having 2 to 30 carbon atoms,
a substituted or unsubstituted arylamino group having 6 to 60 ring carbon atoms,
a thiol group,
a substituted or unsubstituted alkylthio group having 1 to 30 carbon atoms, or
a substituted or unsubstituted arylthio group having 6 to 30 ring carbon atoms.

It is preferable that Q₁ to Q₁₄ as the substituent be independently a hydrogen atom, a substituted or unsubstituted aryl group having 6 to 30 ring carbon atoms, or a substituted or unsubstituted alkyl group having 1 to 30 carbon atoms.

In the compound of the present embodiment, it is also preferable that X₃₁, X₃₂, X₃₃, X₃₄, X₃₅ and X₃₆ be independently an oxygen atom, NR₃₀₁ or SiR₃₀₂R₃₀₃.

In the compound of the present embodiment, it is also preferable that X₃₁, X₃₂, X₃₃, X₃₄, X₃₅ and X₃₆ be independently an oxygen atom or a sulfur atom.

In the compound of the present embodiment, X₃₁, X₃₂, X₃₃, X₃₄, X₃₅ and X₃₆ are also preferably oxygen atoms.

In the compound of the present embodiment, when X₃₁ is an oxygen atom, for example, the general formula (3a) is represented by the following general formula (3a-1), when X₃₁ is a sulfur atom, for example, the general formula (3a) is represented by the following general formula (3a-2), when X₃₁ is NR₃₇₁, for example, the general formula (3a) is represented by the following general formula (3a-3), and when X₃₁ is SiR₃₇₂R₃₇₃, for example, the general formula (3a) is represented by the following general formula (3a-4).

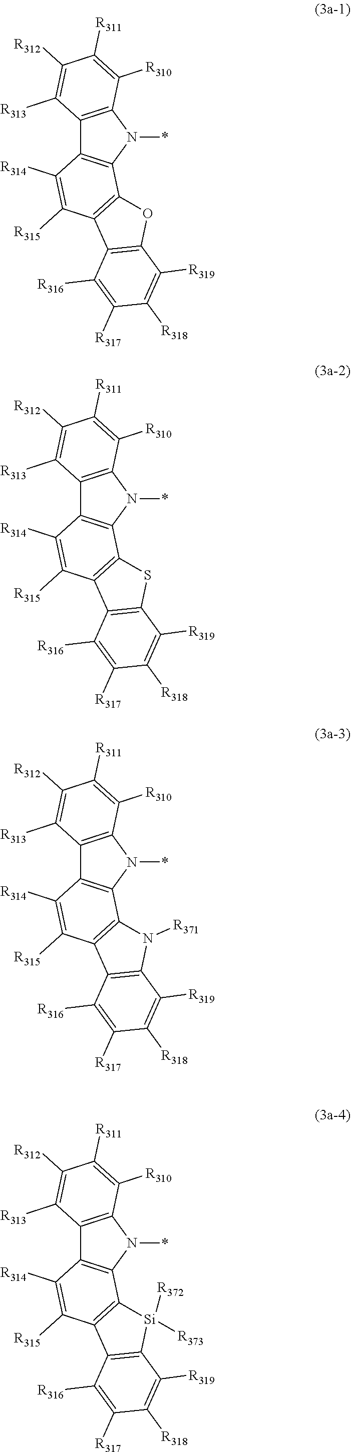

In the compound of the present embodiment, it is preferable that
a set of R₃₁₀ and R₃₁₁, a set of R₃₁₁ and R₃₁₂, a set of R₃₁₂ and R₃₁₃, a set of R₃₁₄ and R₃₁₅, a set of R₃₁₆ and R₃₁₇, a set of R₃₁₇ and R₃₁₈, and a set of R₃₁₈ and R₃₁₉ do not bond with each other;
a set of R₃₂₀ and R₃₂₁, a set of R₃₂₁ and R₃₂₂, a set of R₃₂₂ and R₃₂₃, a set of R₃₂₄ and R₃₂₅, a set of R₃₂₆ and R₃₂₇, a set of R₃₂₇ and R₃₂₈, and a set of R₃₂₈ and R₃₂₉ do not bond with each other;
a set of R₃₃₀ and R₃₃₁, a set of R₃₃₁ and R₃₃₂, a set of R₃₃₂ and R₃₃₃, a set of R₃₃₅ and R₃₃₆, a set of R₃₃₆ and R₃₃₇, and a set of R₃₃₇ and R₃₃₈ do not bond with each other;
a set of R₃₄₀ and R₃₄₁, a set of R₃₄₁ and R₃₄₂, a set of R₃₄₂ and R₃₄₃, a set of R₃₄₅ and R₃₄₆, a set of R₃₄₆ and R₃₄₇, and a set of R₃₄₇ and R₃₄₈ do not bond with each other;
a set of R₃₅₀ and R₃₅₁, a set of R₃₅₁ and R₃₅₂, a set of R₃₅₂ and R₃₅₃, a set of R₃₅₄ and R₃₅₅, a set of R₃₅₅ and R₃₅₆, a set of R₃₅₆ and R₃₅₇, and a set of R₃₅₈ and R₃₅₉ do not bond with each other; and
a set of R₃₆₀ and R₃₆₁, a set of R₃₆₁ and R₃₆₂, a set of R₃₆₂ and R₃₆₃, a set of R₃₆₄ and R₃₆₅, a set of R₃₆₅ and R₃₆₆, a set of R₃₆₆ and R₃₆₇, and a set of R₃₆₈ and R₃₆₉ do not bond with each other.

In the compound of the present embodiment, it is preferable that R₃₁₀ to R₃₁₉, R₃₂₀ to R₃₂₉, R₃₃₀ to R₃₃₉, R₃₄₀ to R₃₄₉, R₃₅₀ to R₃₅₉ and R₃₆₀ to R₃₆₉ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the compound of the present embodiment, it is more preferable that R₃₁₀ to R₃₁₉, R₃₂₀ to R₃₂₉, R₃₃₀ to R₃₃₉, R₃₄₀ to R₃₄₉, R₃₅₀ to R₃₅₉ and R₃₆₀ to R₃₆₉ be independently a hydrogen atom, a substituted or unsubstituted aryl group having 6 to 30 ring carbon atoms, or a substituted or unsubstituted heterocyclic group having 5 to 30 ring atoms.

In the compound of the present embodiment, it is still more preferable that R₃₁₀ to R₃₁₉, R₃₂₀ to R₃₂₉, R₃₃₀ to R₃₃₉, R₃₄₀ to R₃₄₉, R₃₅₀ to R₃₅₉ and R₃₆₀ to R₃₆₉ be independently a hydrogen atom, or a substituted or unsubstituted aryl group having 6 to 30 ring carbon atoms.

In the compound of the present embodiment, R₃₁₀ to R₃₁₉, R₃₂₀ to R₃₂₉, R₃₃₀ to R₃₃₉, R₃₄₀ to R₃₄₉, R₃₅₀ to R₃₅₉ and R₃₆₀ to R₃₆₉ are still more preferably hydrogen atoms.

In one embodiment, the compound C3 is a compound represented by the following general formula (100).

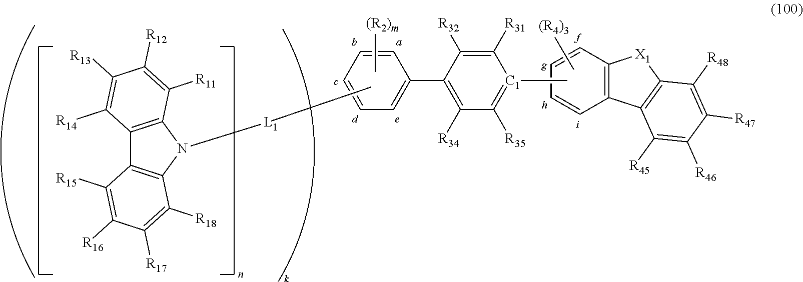

In the general formula (100), X₁ is an oxygen atom or a sulfur atom; C1 is a carbon atom;
n is 1, 2, or 3; k is 1, 2, or 3;
m is 2, 3, or 4; k+m=5;
R₁₁ to R₁₈ are independently a hydrogen atom or a substituent, or any one or more sets of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ form a ring by bonding with each other; when at least one of n and k is 2 or more, the plurality of R₁₁'s is the same as or different from each other, the plurality of R₁₂'s is the same as or different from each other, the plurality of R₁₃'s is the same as or different from each other, the plurality of R₁₄'s is the same as or different from each other, the plurality of R₁₅'s is the same as or different from each other, the plurality of R₁₆'s is the same as or different from each other, the plurality of R₁₇'s is the same as or different from each other, and the plurality of R₁₈'s is the same as or different from each other;
L₁ is a single bond or a linking group; provided that when L₁ is a single bond, n is 1;
when k is 2 or more, the plurality of L₁'s is the same as or different from each other;
L₁ as the linking group is
a group derived from a substituted or unsubstituted aryl group having 6 to 30 ring carbon atoms,
a group derived from a substituted or unsubstituted heterocyclic group having 5 to 30 ring atoms, or
a group formed by bonding two groups selected from the group consisting of a group derived from a substituted or unsubstituted aryl group having 6 to 30 ring carbon atoms, and a group derived from a substituted or unsubstituted heterocyclic group having 5 to 30 ring atoms;
when k is 1 and m is 4, four R₂'s are independently bonded with any of carbon atoms at positions of a, b, c, d and e shown in the general formula (100), and one L₁ is bonded with a carbon atom at a position of a, b, c, d or e which are not bonded with R₂;
when k is 2 and m is 3, three R₂'s are independently bonded with any of carbon atoms at positions of a, b, c, d and e shown in the general formula (100), and two L₁'s are independently bonded with any of carbon atoms at positions of a, b, c, d and e which are not bonded with R₂;
when k is 3 and m is 2, two R₂'s are independently bonded with any of carbon atoms at positions of a, b, c, d and e shown in the general formula (100), and three L₁'s are independently bonded with any of carbon atoms at positions of a, b, c, d and e which are not bonded with R₂;
R₂, R₃₁, R₃₂, R₃₄ and R₃₅ are independently a hydrogen atom or a substituent; when m is 2 or more, the plurality of R₂'s is the same as or different from each other;
R₄ and R₄₅ to R₄₈ are independently a hydrogen atom or a substituent, or any one or more sets of a set of R₄₅ and R₄₆, a set of R₄₆ and R₄₇, and a set of R₄₇ and R₄₈ form a ring by bonding with each other, or any one or more sets of two or more of the plurality of R₄'s form a ring by bonding with each other; provided that three R₄'s are the same as or different from each other, three R₄'s are independently bonded with any of carbon atoms at positions of f, g, h and i shown in the general formula (100), and C₁ is bonded with any of carbon atoms at positions of f, g, h and i which are not bonded with R₄;
R₁₁ to R₁₈, R₂, R₃₁, R₃₂, R₃₄, R₃₅, R₄ and R₄₅ to R₄₈ as the substituent are independently
a halogen atom,
a cyano group,
a substituted or unsubstituted aryl group having 6 to 30 ring carbon atoms,
a substituted or unsubstituted heterocyclic group having 5 to 30 ring atoms,
a substituted or unsubstituted alkyl group having 1 to 30 carbon atoms,
a substituted or unsubstituted halogenated alkyl group having 1 to 30 carbon atoms,
a substituted or unsubstituted alkenyl group having 2 to 30 carbon atoms,
a substituted or unsubstituted alkynyl group having 2 to 30 carbon atoms,
a substituted or unsubstituted alkylsilyl group having 3 to 30 carbon atoms,
a substituted or unsubstituted arylsilyl group having 6 to 60 ring carbon atoms,
a substituted or unsubstituted arylphosphoryl group having 6 to 60 ring carbon atoms,
a hydroxy group,
a substituted or unsubstituted alkoxy group having 1 to 30 carbon atoms,
a substituted or unsubstituted aryloxy group having 6 to 30 ring carbon atoms,
an amino group,
a substituted or unsubstituted alkylamino group having 2 to 30 carbon atoms,
a substituted or unsubstituted arylamino group having 6 to 60 ring carbon atoms,
a thiol group,
a substituted or unsubstituted alkylthio group having 1 to 30 carbon atoms, or
a substituted or unsubstituted arylthio group having 6 to 30 ring carbon atoms.

In the general formula (100), the specific bonding aspects of R₂ and L₁, and the carbon atoms at positions of a, b, c, d, and e shown in the general formula (100) are shown as follows.

When n is 1, L₁ is a divalent linking group, k is 1 and m is 4, four R₂'s are independently bonded with any of the carbon atoms at positions of a, b, c, d and e shown in the general formula (100), and one L₁ is bonded with a carbon atom at a position of a, b, c, d or e which are not bonded with R₂. Provided that the plurality of R₂'s is not bonded with a carbon atom at the same position.

When n is 1, L₁ is a divalent linking group, k is 2 and m is 3, three R₂'s are independently bonded with any of the carbon atoms at positions of a, b, c, d and e shown in the general formula (100), and two L₁'s are independently bonded with any of the carbon atoms at positions of a, b, c, d and e which are not bonded with R₂. Provided that the plurality of R₂'s is not bonded with a carbon atom at the same position.

When n is 1, L₁ is a divalent linking group, k is 3 and m is 2, two R₂'s are independently bonded with any of the carbon atoms at positions of a, b, c, d and e shown in the general formula (100), and three L₁'s are independently bonded with any of the carbon atoms at positions of a, b, c, d and e which are not bonded with R₂. Provided that the plurality of R₂'s is not bonded with a carbon atom at the same position.

For example, in the case where n is 1, L₁ is a divalent linking group, k is 1 and m is 4, when four R₂'s are independently bonded with the carbon atoms at positions of a, b, d, and e shown in the general formula (100), and one L₁ is bonded with a carbon atom at a position of c shown in the general formula (100), the bonding aspect thereof is represented by the following general formula (B1).

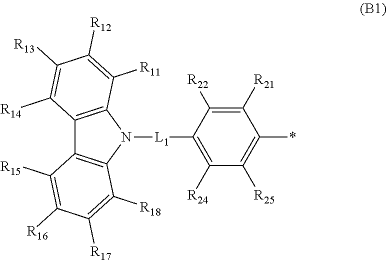

In the general formula (B1), R₁₁ to R₁₈ are independently the same as defined for R₁₁ to R₁₈ in the general formula (100); R₂₁, R₂₂, R₂₄, and R₂₅ are independently the same as those defined for R₂ in the general formula (100); and in the general formula (B1), * represents a bonding position with the carbon atom between the carbon atom of the benzene ring bonding to R₃₂, and the carbon atom of the benzene ring bonding to R₃₄ in the general formula (100).

When n is 2, L₁ is a trivalent linking group, k is 1 and m is 4, four R₂'s are independently bonded with any of the carbon atoms at positions of a, b, c, d and e shown in the general formula (100), and one L₁ is bonded with a carbon atom at a position of a, b, c, d or e which are not bonded with R₂. Provided that the plurality of R₂'s is not bonded with a carbon atom at the same position.

When n is 2, L₁ is a trivalent linking group, k is 2 and m is 3, three R₂'s are independently bonded with any of the carbon atoms at positions of a, b, c, d and e shown in the general formula (100), and two L₁'s are independently bonded with any of the carbon atoms at positions of a, b, c, d and e which are not bonded with R₂. Provided that the plurality of R₂'s is not bonded with a carbon atom at the same position.

When n is 2, L₁ is a trivalent linking group, k is 3 and m is 2, two R₂'s are independently bonded with any of the carbon atoms at positions of a, b, c, d and e shown in the general formula (100), and three L₁'s are independently bonded with any of the carbon atoms at positions of a, b, c, d and e which are not bonded with R₂. Provided that the plurality of R₂'s is not bonded with a carbon atom at the same position.

For example, in the case where n is 2, L₁ is a trivalent linking group, k is 1 and m is 4, when four R₂'s are independently bonded with the carbon atoms at positions of a, b, d, and e shown in the general formula (100), and one L₁ is bonded with a carbon atom at a position of c shown in the general formula (100), the bonding aspect thereof is represented by the following general formula (B2).

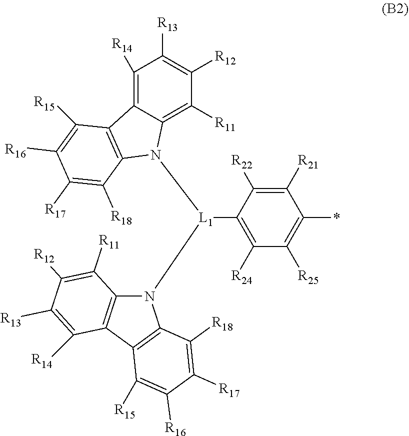

In the general formula (B2), R₁₁ to R₁₈ are independently the same as defined for R₁₁ to R₁₈ in the general formula (100); R₂₁, R₂₂, R₂₄, and R₂₅ are independently the same as those defined for R₂ in the general formula (100); and in the general formula (B2), * represents a bonding position with the carbon atom between the carbon atom of the benzene ring bonding to R₃₂, and the carbon atom of the benzene ring bonding to R₃₄ in the general formula (100).

In the general formula (B2), two R₁₁'s are the same as or different from each other, two R₁₂'s are the same as or different from each other, two R₁₃'s are the same as or different from each other, two R₁₄'s are the same as or different from each other, two R₁₅'s are the same as or different from each other, two R₁₆'s are the same as or different from each other, two R₁₇'s are the same as or different from each other, and two R₁₈'s are the same as or different from each other.

When n is 3, L₁ is a tetravalent linking group, k is 1 and m is 4, four R₂'s are independently bonded with any of the carbon atoms at positions of a, b, c, d and e shown in the general formula (100), and one L₁ is bonded with a carbon atom at a position of a, b, c, d or e which are not bonded with R₂. Provided that the plurality of R₂'s is not bonded with a carbon atom at the same position.

When n is 3, L₁ is a tetravalent linking group, k is 2 and m is 3, three R₂'s are independently bonded with any of the carbon atoms at positions of a, b, c, d and e shown in the general formula (100), and two L₁'s are independently bonded with any of the carbon atoms at positions of a, b, c, d and e which are not bonded with R₂. Provided that the plurality of R₂'s is not bonded with a carbon atom at the same position.

When n is 3, L₁ is a tetravalent linking group, k is 3 and m is 2, two R₂'s are independently bonded with any of the carbon atoms at positions of a, b, c, d and e shown in the general formula (100), and three L₁'s are independently bonded with any of the carbon atoms at positions of a, b, c, d and e which are not bonded with R₂. Provided that the plurality of R₂'s is not bonded with a carbon atom at the same position.

In the general formula (100), the specific bonding aspects of R₂ and the nitrogen atom at 9th-position of the carbazole ring shown in the general formula (100), and the carbon atoms at positions of a, b, c, d, and e shown in the general formula (100) are shown as follows.

When n is 1, L₁ is a single bond, k is 1 and m is 4, four R₂'s are independently bonded with any of the carbon atoms at positions of a, b, c, d and e shown in the general formula (100), and the nitrogen atom at 9th-position of one carbazole ring shown in the general formula (100) is bonded with a carbon atom at a position of a, b, c, d or e which are not bonded with R₂. Provided that the plurality of R₂'s is not bonded with a carbon atom at the same position.

When n is 1, L₁ is a single bond, k is 2 and m is 3, three R₂'s are independently bonded with any of the carbon atoms at positions of a, b, c, d and e shown in the general formula (100), and the nitrogen atoms at 9th-positions of two carbazole rings shown in the general formula (100) are independently bonded with any of the carbon atoms at positions of a, b, c, d and e which are not bonded with R₂. Provided that the plurality of R₂'s is not bonded with a carbon atom at the same position.

When n is 1, L₁ is a single bond, k is 3 and m is 2, two R₂'s are independently bonded with any of the carbon atoms at positions of a, b, c, d and e shown in the general formula (100), and the nitrogen atoms at 9th-positions of three carbazole rings shown in the general formula (100) are independently bonded with any of the carbon atoms at positions of a, b, c, d and e which are not bonded with R₂. Provided that the plurality of R₂'s is not bonded with a carbon atom at the same position.

For example, in the case where n is 1, L₁ is a single bond, k is 1 and m is 4, when four R₂'s are independently bonded with the carbon atoms at positions of a, b, d, and e shown in the general formula (100), and the nitrogen atom at 9th-position of one carbazole ring shown in the general formula (100) is bonded with a carbon atom at a position of c shown in the general formula (100), the bonding aspect thereof is represented by the following general formula (B3).

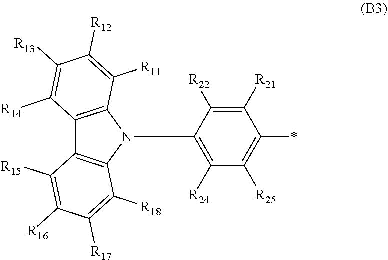

In the general formula (B3), R₁₁ to R₁₈, R₂₁, R₂₂, R₂₄, and R₂₅ are independently the same as defined for R₁₁ to R₁₈, R₂₁, R₂₂, R₂₄, and R₂₅ in the general formula (B1); and in the general formula (B3), * represents a bonding position with the carbon atom between the carbon atom of the benzene ring bonding to R₃₂, and the carbon atom of the benzene ring bonding to R₃₄ in the general formula (100).

For example, in the case where n is 1, L₁ is a single bond, k is 2 and m is 3, when three R₂'s are independently bonded with the carbon atoms at positions of a, c, and e shown in the general formula (100), and the nitrogen atoms at 9th-positions of two carbazole rings shown in the general formula (100) are independently with the carbon atoms at positions of b, and d shown in the general formula (100), the bonding aspect thereof is represented by the following general formula (B4).

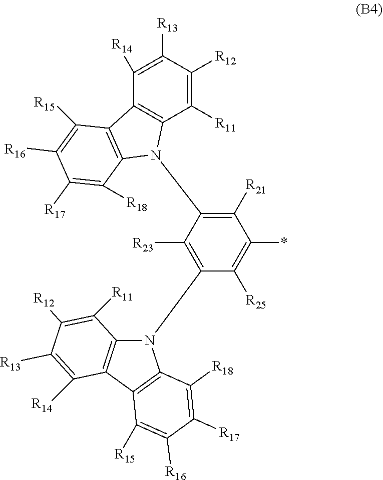

In the general formula (B4), R₁₁ to R₁₈ are independently the same as defined for R₁₁ to R₁₈ in the general formula (B2); R₂₁, R₂₃, and R₂₅ are independently the same as those defined for R₂₁, R₂₂, R₂₄, and R₂₅ in the general formula (B2); and in the general formula (B4), * represents a bonding position with the carbon atom between the carbon atom of the benzene ring bonding to R₃₂, and the carbon atom of the benzene ring bonding to R₃₄ in the general formula (100).

Preferable aspects of the compound of the present embodiment will be described.

In the following description, when the compound of the present embodiment is represented by a general formula, positions corresponding to a, b, c, d, e, f, g, h, and i in the general formula (100) are independently used as a, b, c, d, e, f, g, h, and i in each general formula. The symbols of a, b, c, d, e, f, g, h, and i are frequently abbreviated in each general formula.

In the compound of the present embodiment, any one or more sets of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ preferably forms a ring by bonding with each other.

In the compound of the present embodiment, any one or more sets of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ form a ring by bonding with each other, and a set of R₄₅ and R₄₆, a set of R₄₆ and R₄₇, a set of R₄₇ and R₄₈, and a set of two or more of the plurality of R₄'s do not preferably bond with each other.

In the compound of the present embodiment, any one set of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ preferably forms a ring by bonding with each other.

In the compound of the present embodiment, it is preferable that any one set of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ forms a ring by bonding with each other, and a set of R₄₅ and R₄₆, a set of R₄₆ and R₄₇, a set of R₄₇ and R₄₈, and a set of two or more of the plurality of R₄'s do not bond with each other.

In the compound of the present embodiment, when any one or more sets of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ form a ring by bonding with each other, the ring preferably has a ring structure represented by the following general formula (400).

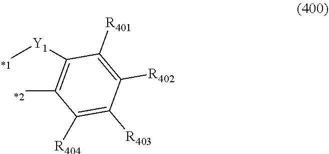

In the general formula (400), Y₁ is an oxygen atom or a sulfur atom; R₄₀₁ to R₄₀₄ are independently the same as those defined for R₁₁ to R₁₈ in the general formula (100); provided that any one or more sets of a set of R₄₀₁ and R₄₀₂, a set of R₄₀₂ and R₄₀₃, and a set of R₄₀₃ and R₄₀₄ form or do not form a ring by bonding with each other.

In the general formula (100), when two or more sets of a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ form the ring structure represented by the general formula (400) by bonding with each other, the plurality of Y₁'s is the same as or different from each other, the plurality of R₄₀₁'s is the same as or different from each other, the plurality of R₄₀₂'s is the same as or different from each other, the plurality of R₄₀₃'s is the same as or different from each other, and the plurality of R₄₀₄'s is the same as or different from each other.

In the general formula (100), when at least one of n and k is 2 or more, the plurality of Y₁'s is the same as or different from each other, the plurality of R₄₀₁'s is the same as or different from each other, the plurality of R₄₀₂'s is the same as or different from each other, the plurality of R₄₀₃'s is the same as or different from each other, and the plurality of R₄₀₄'s is the same as or different from each other.

*1 and *2 in the ring structure represented by the general formula (400) represent at least one carbon atom set of a set of two carbon atoms with which R₁₁ and R₁₂ are independently bonded, a set of two carbon atoms with which R₁₂ and R₁₃ are independently bonded, a set of two carbon atoms with which R₁₃ and R₁₄ are independently bonded, a set of two carbon atoms with which R₁₅ and R₁₆ are independently bonded, a set of two carbon atoms with which R₁₆ and R₁₇ are independently bonded, and a set of two carbon atoms with which R₁₇ and R₁₈ are independently bonded, in the general formula (100).

In the general formula (400), a set of R₄₀₁ and R₄₀₂, a set of R₄₀₂ and R₄₀₃, and a set of R₄₀₃ and R₄₀₄ do not preferably bond with each other.

In the general formula (400), Y₁ is preferably an oxygen atom.

In the general formula (400), Y₁ is also preferably a sulfur atom.

In the compound of the present embodiment, for example, when any one set of a set of R₁₁ and R₁₂, a set of R₁₂ and R₁₃, and a set of R₁₃ and R₁₄ forms the ring structure represented by the general formula (400) by bonding with each other, the ring structure having R₁₁ to R₁₈ is represented by any one of the following general formulas (400-1) to (400-6) in the general formula (100).

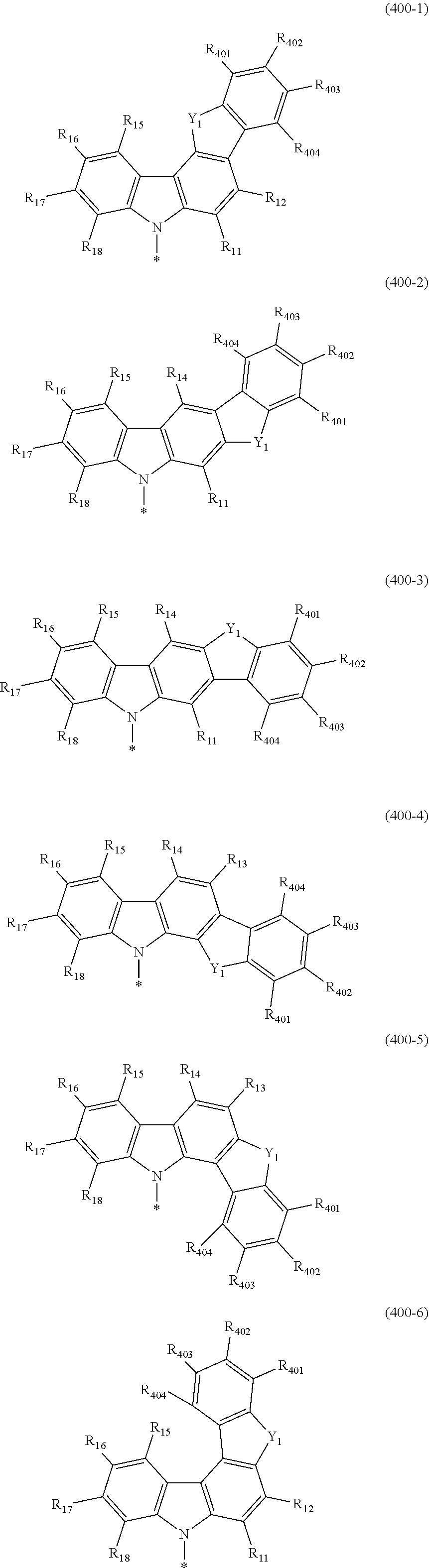

In the general formulas (400-1) to (400-6), Y₁ and R₄₀₁ to R₄₀₄ are independently the same as defined for Y₁ and R₄₀₁ to R₄₀₄ in the general formula (400); and R₁₁ to R₁₈ are independently the same as defined for R₁₁ to R₁₈ in the general formula (100).

When L₁ is a linking group in the general formula (100), * represents a binding site with L₁.

When L₁ is a single bond, n is 1, k is 1 and m is 4 in the general formula (100), * is bonded with a carbon atom at a position of a, b, c, d or e which are not bonded with four R₂'s.

When L₁ is a single bond, n is 1, k is 2 and m is 3 in the general formula (100), * is bonded with any of the carbon atoms at positions of a, b, c, d and e which are not bonded with three R₂'s.

When L₁ is a single bond, n is 1, k is 3 and m is 2 in the general formula (100), * is bonded with any of the carbon atoms at positions of a, b, c, d and e which are not bonded with two R₂'s.

In the general formulas (400-1) to (400-6), a set of R₁₁ and R₁₂, a set of R₁₃ and R₁₄, a set of R₁₅ and R₁₆, a set of R₁₆ and R₁₇, a set of R₁₇ and R₁₈, a set of R₄₀₁ and R₄₀₂, a set of R₄₀₂ and R₄₀₃, and a set of R₄₀₃ and R₄₀₄ do not preferably bond with each other.

In the general formulas (400-1) to (400-6), Y₁ is preferably an oxygen atom.

In the general formulas (400-1) to (400-6), Y₁ is also preferably a sulfur atom.

In the general formula (100), for example, when one set of a set of R₁₁ and R₁₂, a set of R₁₂ and R₁₃, and a set of R₁₃ and R₁₄ forms the ring structure represented by the general formula (400) by bonding with each other, the compound of the present embodiment is represented by any one of the following general formulas (401) to (406).

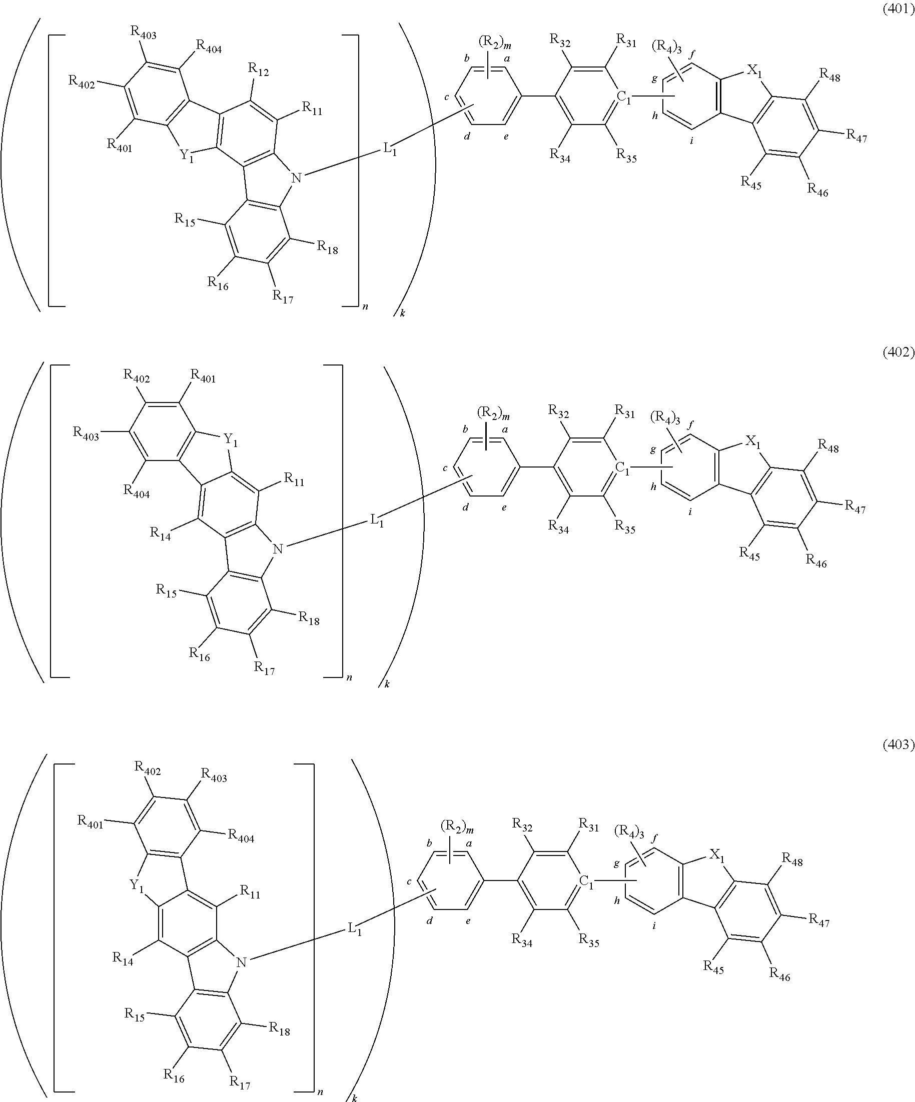

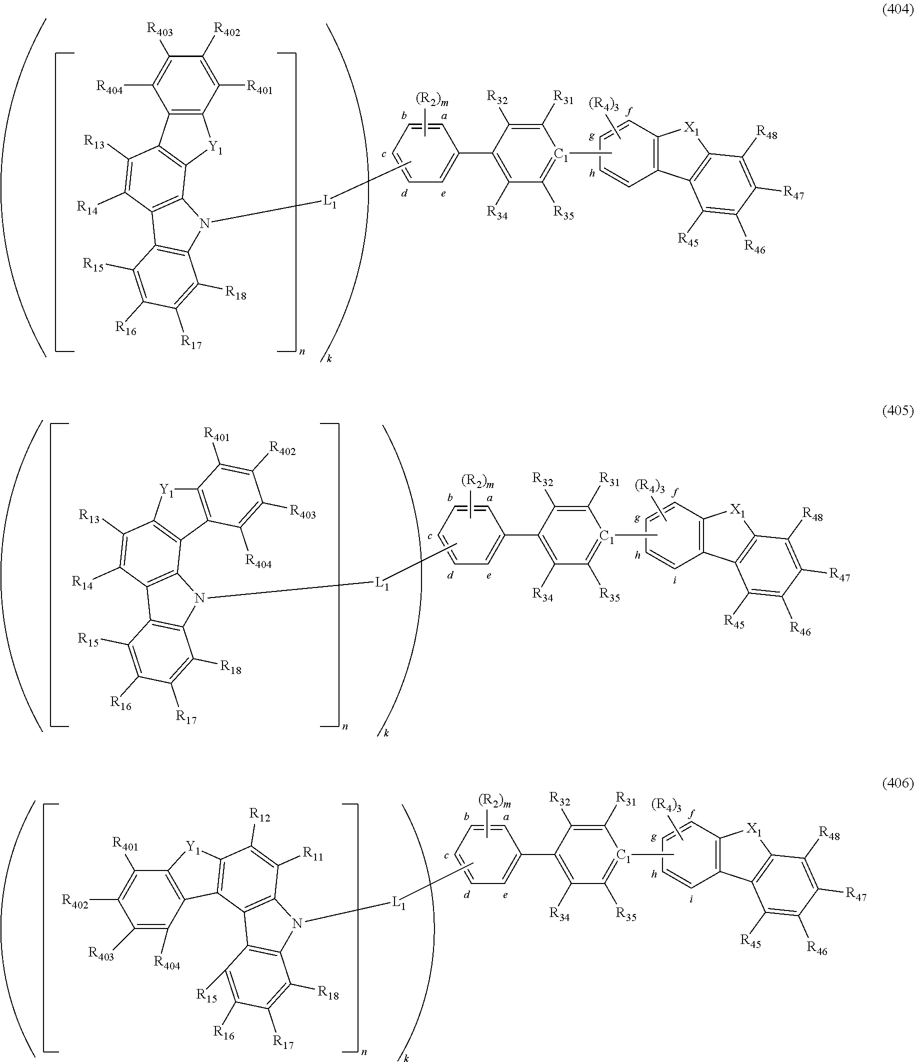

In the general formulas (401) to (406), X₁, R₄, R₄₅ to R₄₈, C1, R₃₁ to R₃₂, R₃₄ to R₃₅, R₂, L₁, R₁₁ to R₁₈, m, n, and k are independently the same as defined for X₁, R₄, R₄₅ to R₄₈, C1, R₃₁ to R₃₂, R₃₄ to R₃₅, R₂, L₁, R₁₁ to R₁₈, m, n, and k in the general formula (100); Y₁ is an oxygen atom or a sulfur atom; R₄₀₁ to R₄₀₄ are independently the same as those defined for R₁₁ to R₁₈ in the general formula (100); provided that any one or more sets of a set of R₄₀₁ and R₄₀₂, a set of R₄₀₂ and R₄₀₃, and a set of R₄₀₃ and R₄₀₄ form or do not form a ring by bonding with each other.

In the general formulas (401) to (406), a set of R₁₁ and R₁₂, a set of R₁₃ and R₁₄, a set of R₄₀₁ and R₄₀₂, a set of R₄₀₂ and R₄₀₃, and a set of R₄₀₃ and R₄₀₄ do not preferably bond with each other.

The compound of the present embodiment is preferably represented by any one of the following general formulas (401A) to (406A).

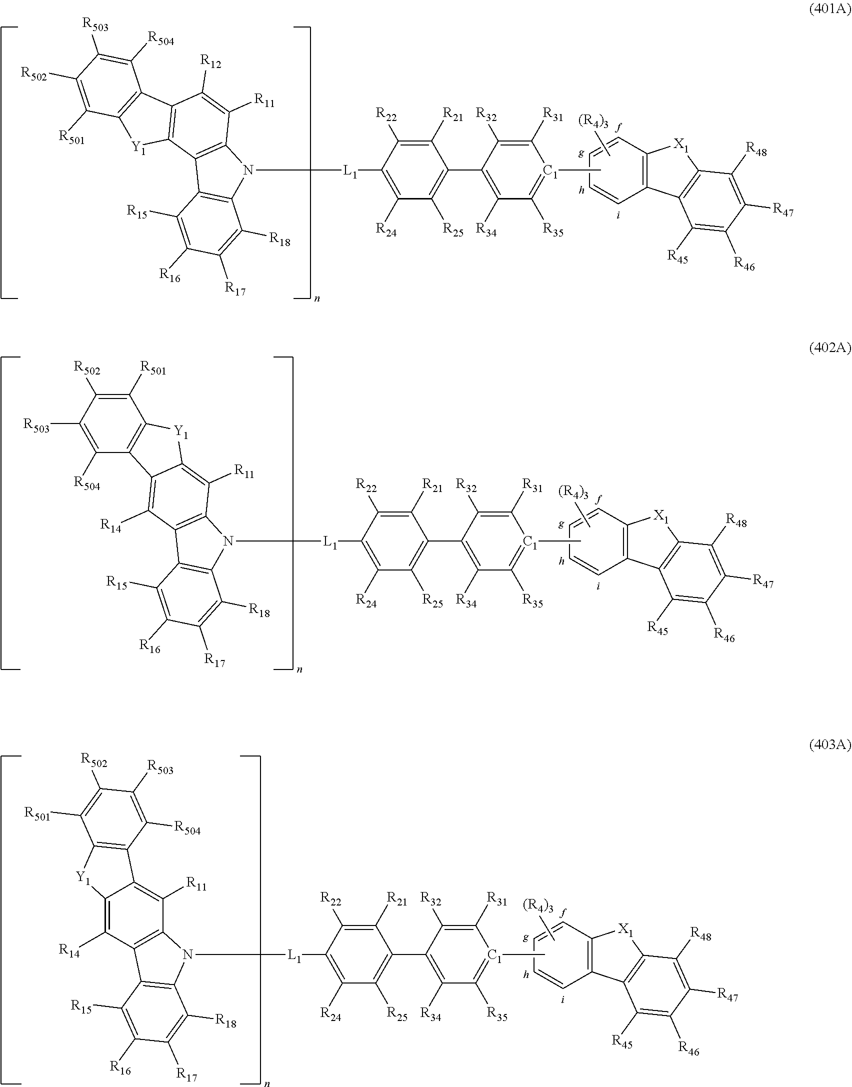

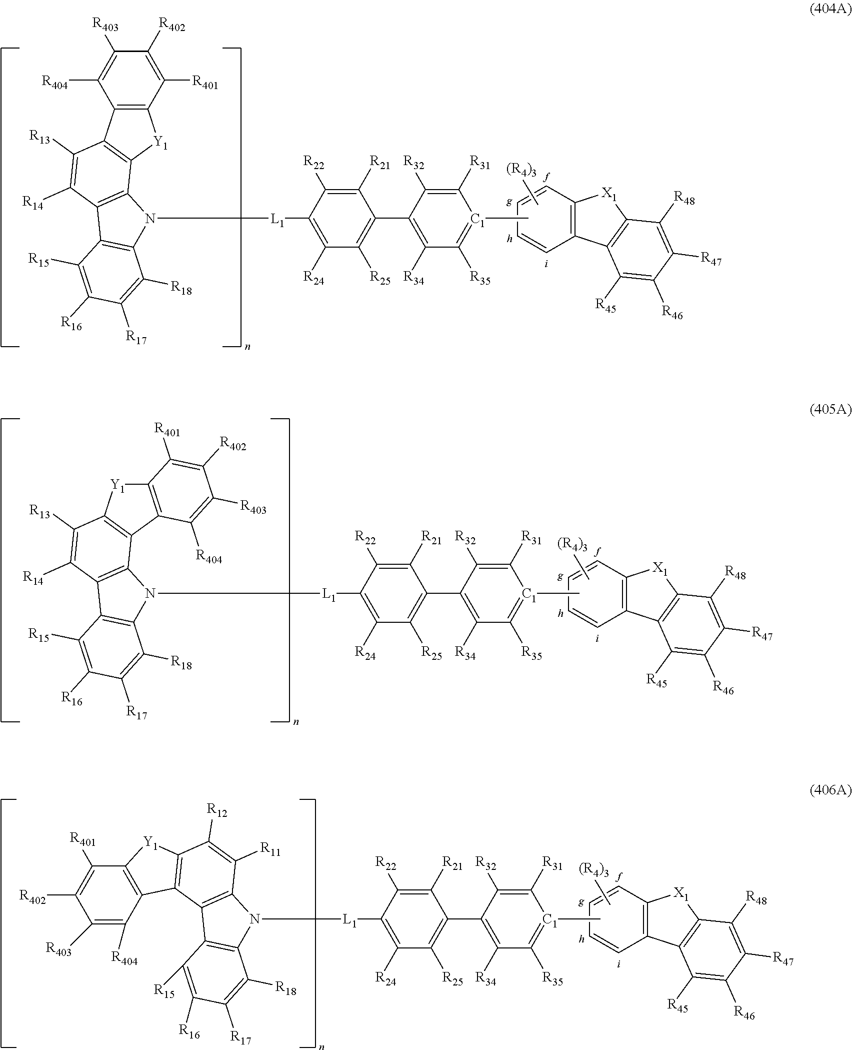

In the general formulas (401A) to (406A), X₁, R₄, R₄₅ to R₄₈, C1, R₃₁ to R₃₂, R₃₄ to R₃₅, L₁, R₁₁ to R₁₈, and n are independently the same as defined for X₁, R₄, R₄₅ to R₄₈, C1, R₃₁ to R₃₂, R₃₄ to R₃₅, L₁, R₁₁ to R₁₈, and n in the general formula (100); R₂₁ to R₂₂ and R₂₄ to R₂₅ are independently the same as those defined for R₂ in the general formula (100); Y₁ is an oxygen atom or a sulfur atom; R₄₀₁ to R₄₀₄ are independently the same as those defined for R₁₁ to R₁₈ in the general formula (100); provided that any one or more sets of a set of R₄₀₁ and R₄₀₂, a set of R₄₀₂ and R₄₀₃, and a set of R₄₀₃ and R₄₀₄ form or do not form a ring by bonding with each other.

In the general formulas (401A) to (406A), a set of R₁₁ and R₁₂, a set of R₁₃ and R₁₄, a set of R₄₀₁ and R₄₀₂, a set of R₄₀₂ and R₄₀₃, and a set of R₄₀₃ and R₄₀₄ do not preferably bond with each other.

The compound of the present embodiment is also preferably represented by any one of the following general formulas (401B) to (406B).

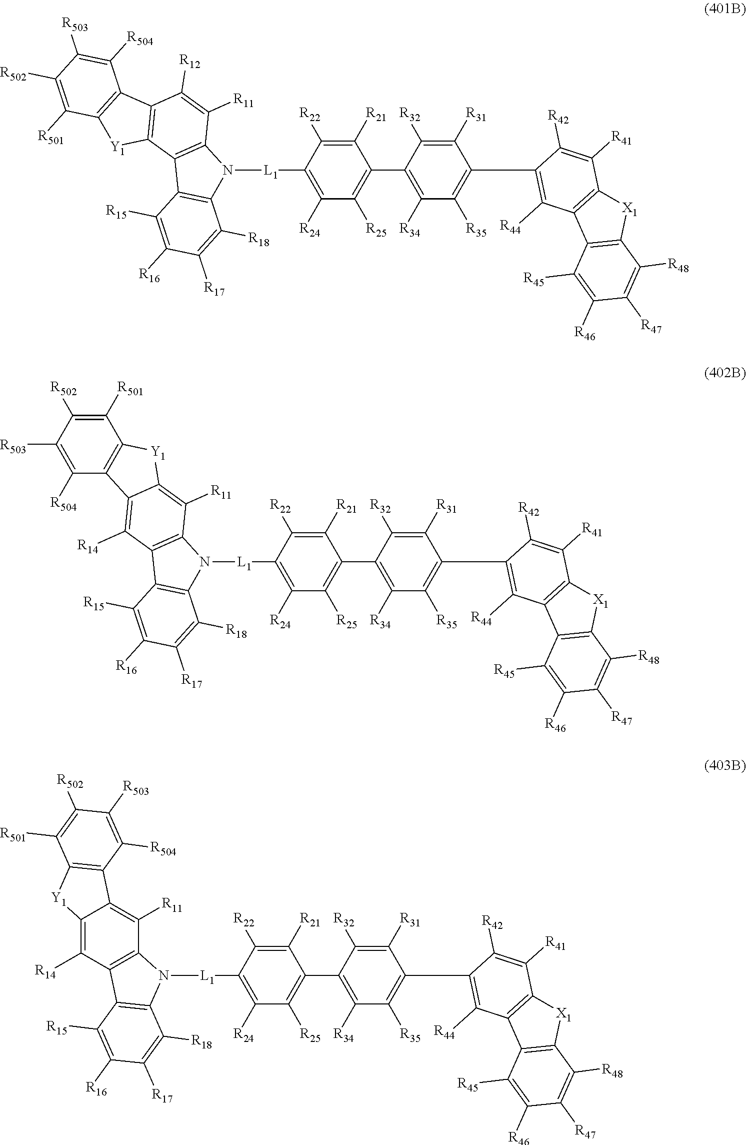

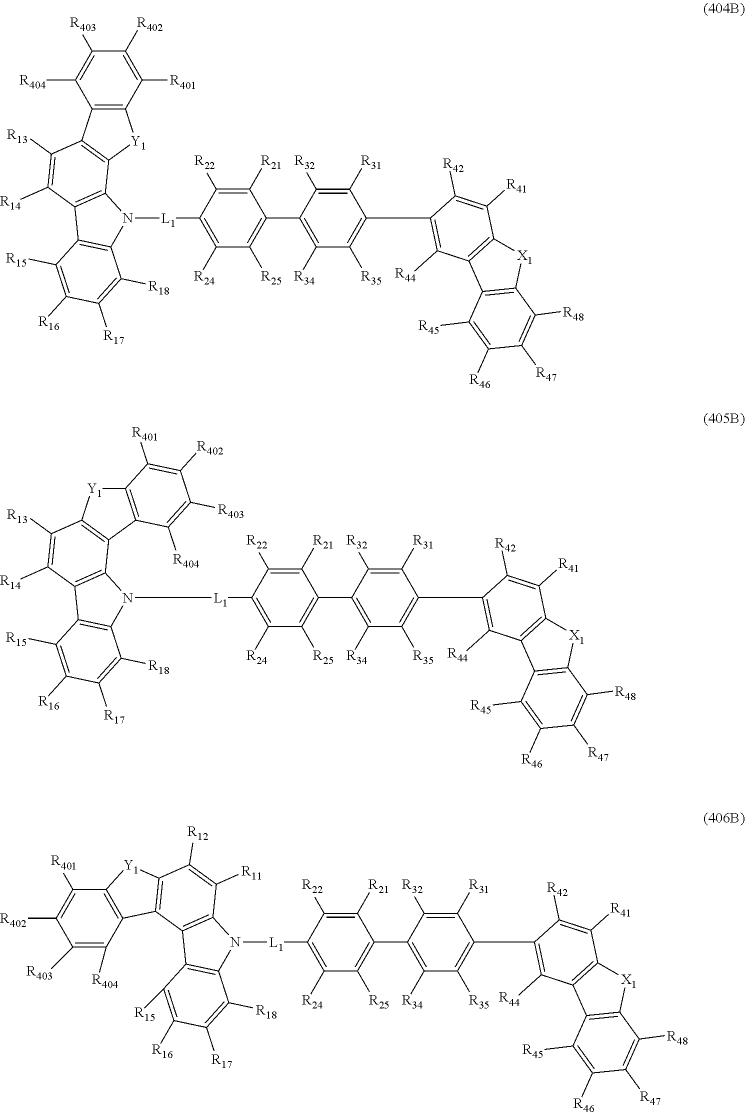

In the general formulas (401B) to (406B), X₁, R₄₅ to R₄₈, R₃₁ to R₃₂, R₃₄ to R₃₅, L₁ and R₁₁ to R₁₈ are independently the same as defined for X₁, R₄₅ to R₄₈, R₃₁ to R₃₂, R₃₄ to R₃₅, L₁ and R₁₁ to R₁₈ in the general formula (100); R₄₁, R₄₂ and R₄₄ are independently the same as those defined for R₄ in the general formula (100); R₂₁ to R₂₂ and R₂₄ to R₂₅ are independently the same as those defined for R₂ in the general formula (100); Y₁ is an oxygen atom or a sulfur atom; R₄₀₁ to R₄₀₄ are independently the same as those defined for R₁₁ to R₁₈ in the general formula (100); provided that any one or more sets of a set of R₄₀₁ and R₄₀₂, a set of R₄₀₂ and R₄₀₃, and a set of R₄₀₃ and R₄₀₄ form or do not form a ring by bonding with each other.

In the general formulas (401B) to (406B), a set of R₁₁ and R₁₂, a set of R₁₃ and R₁₄, a set of R₄₀₁ and R₄₀₂, a set of R₄₀₂ and R₄₀₃, and a set of R₄₀₃ and R₄₀₄ do not preferably bond with each other.

In the compound of the present embodiment, a set of R₁₁ and R₁₂, a set of R₁₂ and R₁₃, a set of R₁₃ and R₁₄, a set of R₁₅ and R₁₆, a set of R₁₆ and R₁₇, a set of R₁₇ and R₁₈, a set of R₄₅ and R₄₆, a set of R₄₆ and R₄₇, a set of R₄₇ and R₄₈, and a set of two or more of the plurality of R₄'s do not also preferably bond with each other.

In the compound of the present embodiment, R₂, R₃₁, R₃₂, R₃₄ and R₃₅ are preferably hydrogen atoms.

When the compound of the present embodiment is the compound represented by any one of the general formulas (401) to (406), the general formulas (401A) to (406A) and the general formulas (401B) to (406B), R₂, R₂₁ to R₂₂, R₂₄ to R₂₅, R₃₁ to R₃₂ and R₃₄ to R₃₅ are preferably hydrogen atoms.

In the compound of the present embodiment, it is preferable that R₂, R₃₁, R₃₂, R₃₄ and R₃₅ be hydrogen atoms, and L₁ be a single bond, a group derived from an unsubstituted aryl group having 6 to 30 ring carbon atoms, or a group derived from an unsubstituted heterocyclic group having 5 to 30 ring atoms.

When the compound of the present embodiment is the compound represented by any one of the general formulas (401) to (406), the general formulas (401A) to (406A) and the general formulas (401B) to (406B), it is preferable that R₂, R₂₁ to R₂₂, R₂₄ to R₂₅, R₃₁ to R₃₂ and R₃₄ to R₃₅ be hydrogen atoms, and L₁ be a single bond, a group derived from an unsubstituted aryl group having 6 to 30 ring carbon atoms, or a group derived from an unsubstituted heterocyclic group having 5 to 30 ring atoms.

The compound in the aspect is specifically represented by the following general formula (100X).

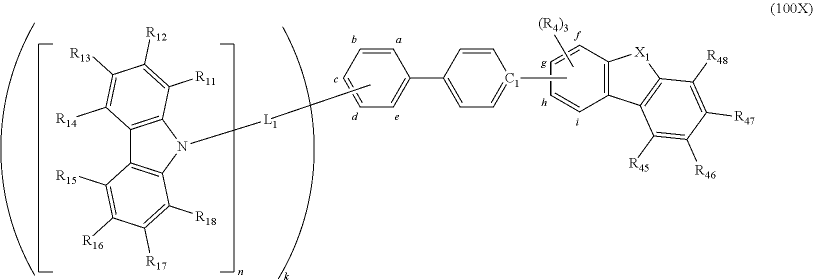

In the general formula (100X), X₁, R₄, R₄₅ to R₄₈, C1, R₁₁ to R₁₈, n, and k are independently the same as defined for X₁, R₄, R₄₅ to R₄₈, C1, R₁₁ to R₁₈, n, and k in the general formula (100); L₁ is a single bond, a group derived from an unsubstituted aryl group having 6 to 30 ring carbon atoms, or a group derived from an unsubstituted heterocyclic group having 5 to 30 ring atoms; provided that when L₁ is a single bond, n is 1; and
when k is 2 or more, the plurality of L₁'s is the same as or different from each other.

In the general formula (100X), the ring structure having R₁₁ to R₁₈ is also preferably represented by any one of the general formulas (400-1) to (400-6).

In the compound of the present embodiment, n is preferably 1 or 2, and n is more preferably 1.

In the compound of the present embodiment, k is preferably 1 or 2.

In the compound of the present embodiment, it is also more preferable that n be 1 or 2, and k be 1 or 2.

In the compound of the present embodiment, it is also more preferable that n be 1, and k be 1 or 2.

In the compound of the present embodiment, it is also more preferable that n be 2, and k be 1 or 2.

Specifically, when n is 2, the compound of the present embodiment is represented by the following general formula (100Y). When n is 1, the compound of the present embodiment is represented by the following general formula (100Z).

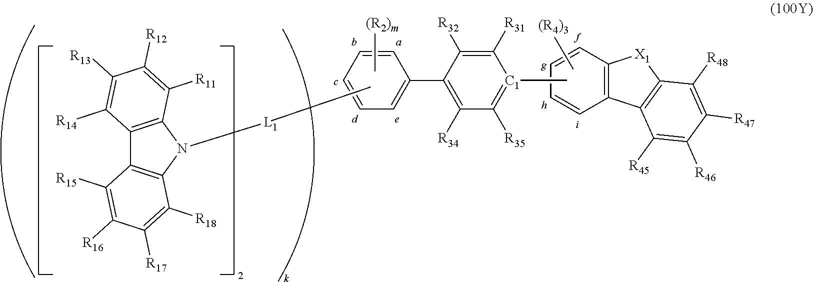

In the general formula (10Y), X₁, R₄, R₄₅ to R₄₈, C₁, R₂, R₃₂, R₃₂, R₃₄, R₃₅, L₁, R₁ to R₁₈, m, and k are independently the same as defined for X₁, R₄, R₄₅ to R₄₈, C1, R₂, R₃₁, R₃₂, R₃₄, R₃₅, L₁, R₁₁ to R₁₈, m, and k in the general formula (100).

In the general formula (100Y), k is preferably 1 or 2.

In the general formula (100Y), the ring structure having R₁₁ to R₁₈ is also preferably represented by any one of the general formulas (400-1) to (400-6).

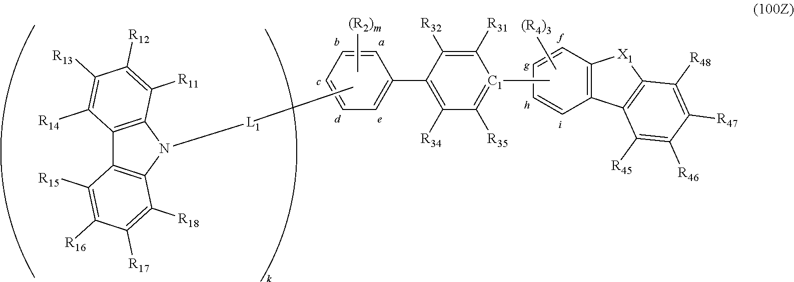

In the general formula (100Z), X₁, R₄, R₄₅ to R₄₈, C1, R₂, R₃₁, R₃₂, R₃₄, R₃₅, L₁, R₁₁ to R₁₈, m, and k are independently the same as defined for X₁, R₄, R₄₅ to R₄₈, C1, R₂, R₃₁, R₃₂, R₃₄, R₃₅, L₁, R₁₁ to R₁₈, m, and k in the general formula (100).

In the general formula (100Z), k is preferably 1 or 2.

In the general formula (100Z), the ring structure having R₁₁ to R₁₈ is also preferably represented by any one of the general formulas (400-1) to (400-6).

In the compound of the present embodiment, it is preferable that R₁₁ to R₁₈, R₄ and R₄₅ to R₄₈ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the compound of the present embodiment, it is more preferable that R₁₁ to R₁₈, R₄ and R₄₅ to R₄₈ be independently a hydrogen atom, a substituted or unsubstituted aryl group having 6 to 30 ring carbon atoms, or a substituted or unsubstituted heterocyclic group having 5 to 30 ring atoms.

In the compound of the present embodiment, it is still more preferable that R₁₁ to R₁₈, R₄ and R₄₅ to R₄₈ be independently a hydrogen atom, or a substituted or unsubstituted aryl group having 6 to 30 ring carbon atoms.

In the compound of the present embodiment, it is still more preferable that R₁₁ to R₁₈, R₄ and R₄₅ to R₄₈ be independently a hydrogen atom, or a substituted or unsubstituted phenyl group.

In the compound of the present embodiment, it is preferable that R₁₁ to R₁₈ be independently a hydrogen atom, or a substituted or unsubstituted phenyl group, and R₄ and R₄₅ to R₄₈ be independently a hydrogen atom.

When the compound of the present embodiment is the compound represented by any one of the general formulas (401) to (406), the general formulas (401A) to (406A) and the general formulas (401B) to (406B), it is preferable that R₁₁ to R₁₈, R₄₀₁ to R₄₀₄, R₄, R₄₁, R₄₂ and R₄₄ to R₄₈ be independently a hydrogen atom, a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms,
more preferably a hydrogen atom, a substituted or unsubstituted aryl group having 6 to 30 ring carbon atoms, or a substituted or unsubstituted heterocyclic group having 5 to 30 ring atoms,
still more preferably a hydrogen atom, or a substituted or unsubstituted aryl group having 6 to 30 ring carbon atoms, and
still more preferably a hydrogen atom, or a substituted or unsubstituted phenyl group.

When the compound of the present embodiment is the compound represented by any one of the general formulas (401) to (406), the general formulas (401A) to (406A) and the general formulas (401B) to (406B), it is preferable that R₁₁ to R₁₈ and R₄₀₁ to R₄₀₄ be independently a hydrogen atom, or a substituted or unsubstituted phenyl group, and R₄, R₄₁, R₄₂ and R₄₄ to R₄₈ be independently a hydrogen atom.

In the compound of the present embodiment, L₁ is preferably a single bond, or a group derived from an unsubstituted aryl group having 6 to 30 ring carbon atoms.

In the compound of the present embodiment, L₁ is more preferably a single bond, or a group derived from an unsubstituted benzene ring.

In the compound of the present embodiment, L₁ is preferably a single bond.

The compound of the present embodiment is also preferably a compound represented by the following general formula (100A) or the following general formula (100B).

The compound of the present embodiment is also more preferably a compound represented by the following general formula (100A).

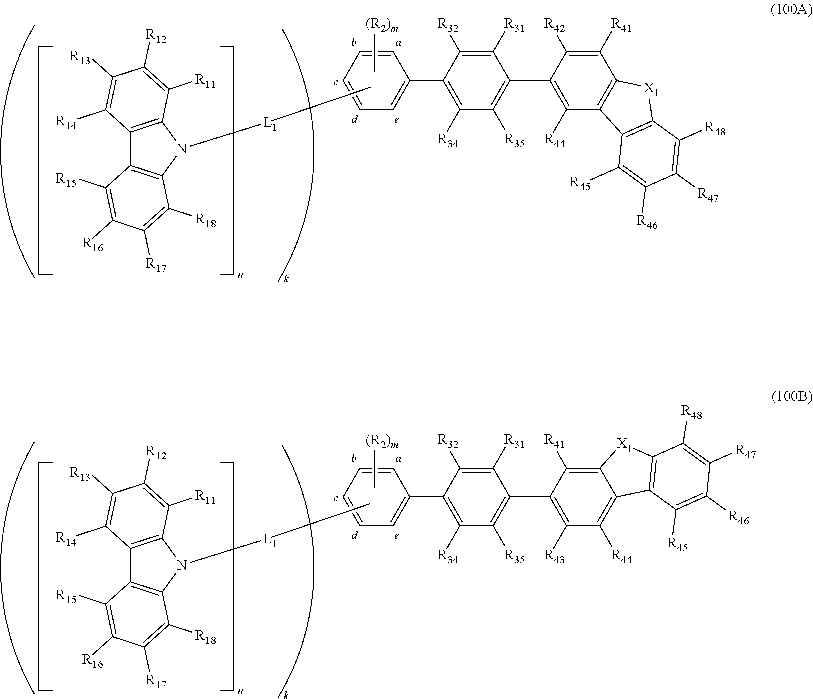

In the general formula (100A) and the general formula (100B), X₁, R₁₁ to R₁₈, n, k, m, L₁, R₂, R₃₁, R₃₂, R₃₄, R₃₅, and R₄₅ to R₄₈ are independently the same as defined for X₁, R₁₁ to R₁₈, n, k, m, L₁, R₂, R₃₁, R₃₂, R₃₄, R₃₅, and R₄₅ to R₄₈ in the general formula (100); and R₄₁ to R₄₄ are independently the same as those defined for R₄ in the general formula (100).

In the general formula (100A), the ring structure having R₁₁ to R₁₈ is also preferably represented by any one of the general formulas (400-1) to (400-6).

In the general formula (100B), the ring structure having R₁₁ to R₁₈ is also preferably represented by any one of the general formulas (400-1) to (400-6).

In the compound of the present embodiment, when L₁ is a linking group, L₁ is preferably bonded with a carbon atom at a position of b, c, or d shown in the general formula (100).

In the compound of the present embodiment, when L₁ is a divalent linking group, n is 1 and k is 1, L₁ is preferably bonded with a carbon atom at a position of c shown in the general formula (100).

In the compound of the present embodiment, when L₁ is a trivalent linking group, n is 2 and k is 1, L₁ is preferably bonded with a carbon atom at a position of c shown in the general formula (100).

In the compound of the present embodiment, when L₁ is a single bond, n is 1 and k is 1, the nitrogen atom at 9th-position of the carbazole ring shown in the general formula (100) is preferably bonded with a carbon atom at a position of c shown in the general formula (100).

In the compound of the present embodiment, when L₁ is a single bond, n is 2 and k is 2, the nitrogen atoms at 9th-positions of two carbazole rings shown in the general formula (100) are independently preferably bonded with the carbon atoms at positions of b and d shown in the general formula (100).

In the compound of the present embodiment, when L₁ is a single bond, n is 3 and k is 3, the nitrogen atoms at 9th-positions of three carbazole rings shown in the general formula (100) are independently preferably bonded with the carbon atoms at positions of b, c and d shown in the general formula (100).

The compound of the present embodiment is also preferably a compound represented by the following general formula (100C).

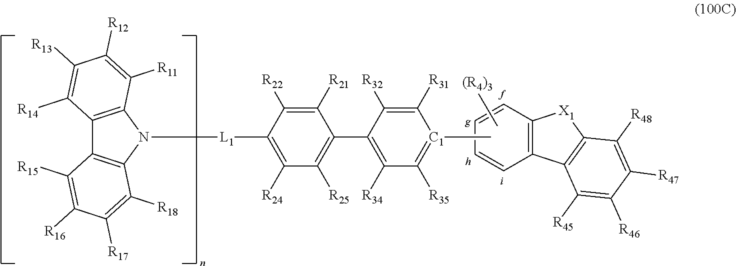

In the general formula (1000), X₁, C1, R₁₁ to R₁₈, n, L₁, R₃₁, R₃₂, R₃₄, R₃₅, R₄, and R₄₅ to R₄₈ are independently the same as defined for X₁, C1, R₁₁ to R₁₈, n, L₁, R₃₁, R₃₂, R₃₄, R₃₅, R₄, and R₄₅ to R₄₈ in the general formula (100); and R₂₁, R₂₂, R₂₄, and R₂₅ are independently the same as those defined for R₂ in the general formula (100).

In the general formula (1000), the ring structure having R₁₁ to R₁₈ is also preferably represented by any one of the general formulas (400-1) to (400-6).

The compound of the present embodiment is also preferably a compound represented by the following general formula (100D).

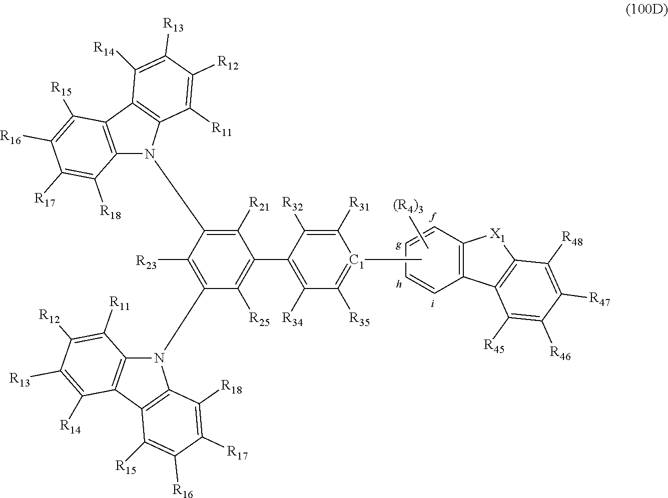

In the general formula (100D), X₁, C1, R₁₁ to R₁₈, R₃₁, R₃₂, R₃₄, R₃₅, R₄, and R₄₅ to R₄₈ are independently the same as defined for X₁, C1, R₁₁ to R₁₈, R₃₁, R₃₂, R₃₄, R₃₅, R₄, and R₄₅ to R₄₈ in the general formula (100); and R₂₁, R₂₃, and R₂₅ are independently the same as those defined for R₂ in the general formula (100).

In the general formula (100D), two R₁₁'s are the same as or different from each other, two R₁₂'s are the same as or different from each other, two R₁₃'s are the same as or different from each other, two R₁₄'s are the same as or different from each other, two R₁₅'s are the same as or different from each other, two R₁₆'s are the same as or different from each other, two R₁₇'s are the same as or different from each other, and two R₁₈'s are the same as or different from each other.

In the general formula (100D), it is also preferable that two ring structures having R₁₁ to R₁₈ be independently represented by any one of the general formulas (400-1) to (400-6).

The compound of the present embodiment is also preferably a compound represented by the following general formula (100E).

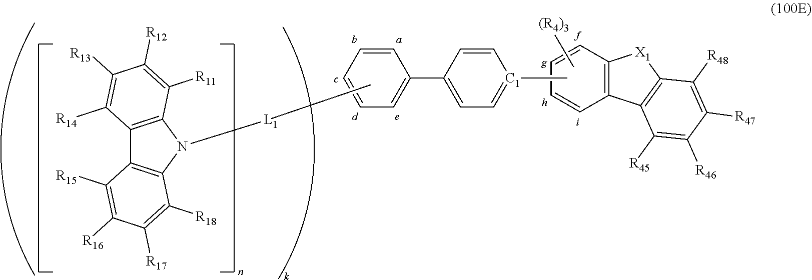

In the general formula (100E), X₁ and C1 are independently the same as defined for X₁ and C1 in the general formula (100); n is 1 or 2; k is 1 or 2; R₁₁ to R₁₈, R₄ and R₄₅ to R₄₈ are independently a hydrogen atom, or a substituted or unsubstituted aryl group having 6 to 30 ring carbon atoms; when at least one of n and k is 2, the plurality of R₁₁'s is the same as or different from each other, the plurality of R₁₂'s is the same as or different from each other, the plurality of R₁₃'s is the same as or different from each other, the plurality of R₁₄'s is the same as or different from each other, the plurality of R₁₅'s is the same as or different from each other, the plurality of R₁₆'s is the same as or different from each other, the plurality of R₁₇'s is the same as or different from each other, and the plurality of R₁₈'s is the same as or different from each other;
provided that a set of R₁₁ and R₁₂, a set of R₁₂ and R₁₃, a set of R₁₃ and R₁₄, a set of R₁₅ and R₁₆, a set of R₁₆ and R₁₇, a set of R₁₇ and R₁₈, a set of R₄₅ and R₄₆, a set of R₄₆ and R₄₇, a set of R₄₇ and R₄₈, and a set of two or more of the plurality of R₄'s do not bond with each other;
L₁ is a single bond, or a group derived from an unsubstituted aryl group having 6 to 30 ring carbon atoms; provided that when L₁ is a single bond, n is 1;
when k is 2, the plurality of L₁'s is the same as or different from each other;
when L₁ is a linking group and k is 1, one L₁ is bonded with a carbon atom at a position of a, b, c, d or e;
when L₁ is a linking group and k is 2, two L₁'s are independently bonded with any of the carbon atoms at positions of a, b, c, d and e; provided that the plurality of L₁'s is not bonded with a carbon atom at the same position;
when L₁ is a single bond and k is 1, the nitrogen atom at 9th-position of one carbazole ring shown in the general formula (100E) is bonded with a carbon atom at a position of a, b, c, d or e shown in the general formula (100E);
when L₁ is a single bond and k is 2, the nitrogen atoms at 9th-positions of two carbazole rings shown in the general formula (100E) are independently bonded with any of the carbon atoms at positions of a, b, c, d and e shown in the general formula (100E); provided that the nitrogen atom at 9th-position of the plurality of carbazole rings is not bonded with a carbon atom at the same position.

The compound of the present embodiment is also preferably a compound represented by the following general formula (100F).

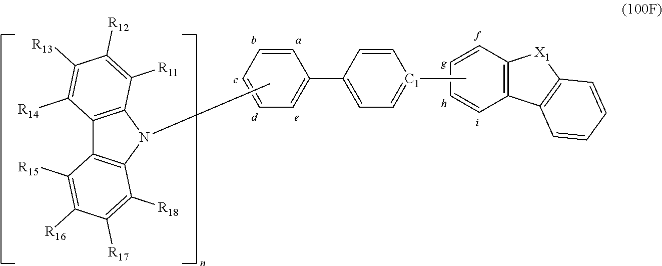

In the general formula (100F), X₁ and C1 are independently the same as defined for X₁ and C1 in the general formula (100); n is 1 or 2;
when n is 1, the nitrogen atom at 9th-position of one carbazole ring shown in the general formula (100F) is bonded with a carbon atom at a position of a, b, c, d or e shown in the general formula (100F);
when n is 2, the nitrogen atoms at 9th-positions of two carbazole rings shown in the general formula (100F) are independently bonded with any of the carbon atoms at positions of a, b, c, d and e; provided that the nitrogen atom at 9th-position of the plurality of carbazole rings is not bonded with a carbon atom at the same position; R₁₁ to R₁₈ is independently a hydrogen atom, or a substituted or unsubstituted phenyl group; when n is 2, the plurality of R₁₁'s is the same as or different from each other, the plurality of R₁₂'s is the same as or different from each other, the plurality of R₁₃'s is the same as or different from each other, the plurality of R₁₄'s is the same as or different from each other, the plurality of R₁₅'s is the same as or different from each other, the plurality of R₁₆'s is the same as or different from each other, the plurality of R₁₇'s is the same as or different from each other, and the plurality of R₁₈'s is the same as or different from each other;
provided that a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other.

In the compound of the present embodiment, X₁ is preferably an oxygen atom.

In the compound of the present embodiment, it is also preferable that C1 in the general formula (100) be bonded with a carbon atom at a position of “h” shown in the general formula (100),
a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other, and at least one or more od R₁₁ to R₁₈ be an unsubstituted aryl group having 6 to 30 ring carbon atoms.

The compound in the aspect is represented by the following general formula (201A).

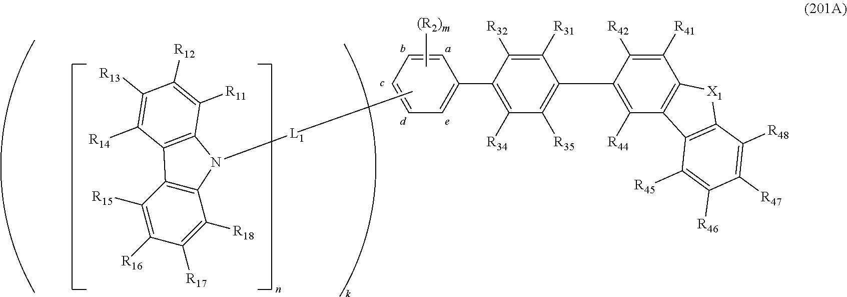

In the general formula (201A), X₁, R₁₁ to R₁₈, n, k, m, L₁, R₂, R₃₁, R₃₂, R₃₄, R₃₅, and R₄₅ to R₄₈ are independently the same as defined for X₁, R₁₁ to R₁₈, n, k, m, L₁, R₂, R₃₁, R₃₂, R₃₄, R₃₅, and R₄₅ to R₄₈ in the general formula (100); R₄₁, R₄₂ and R₄₄ are independently the same as those defined for R₄ in the general formula (100); provided that a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other in the general formula (201A); and at least one or more od R₁₁ to R₁₈ are an unsubstituted aryl group having 6 to 30 ring carbon atoms.

In the compound of the present embodiment, it is also preferable that C1 in the general formula (100) be bonded with a carbon atom at a position of “g” shown in the general formula (100),
a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other, and at least one or more od R₁₁ to R₁₈ be an unsubstituted aryl group having 6 to 30 ring carbon atoms.

The compound in the aspect is represented by the following general formula (202A).

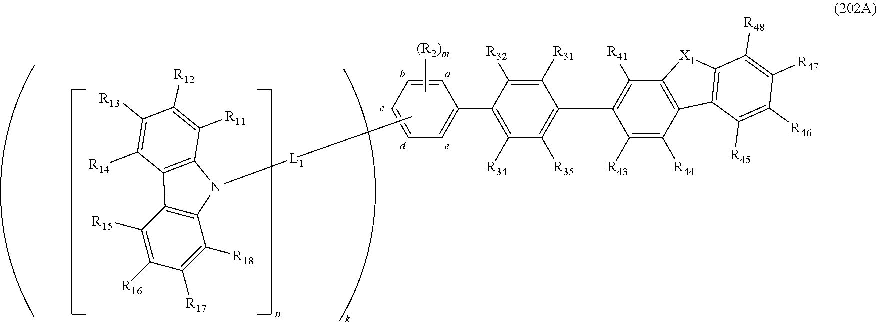

In the general formula (202A), X₁, R₁₁ to R₁₈, n, k, m, L₁, R₂, R₃₁, R₃₂, R₃₄, R₃₅, and R₄₅ to R₄₈ are independently the same as defined for X₁, R₁₁ to R₁₈, n, k, m, L₁, R₂, R₃₁, R₃₂, R₃₄, R₃₅, and R₄₅ to R₄₈ in the general formula (100); R₄₁, R₄₃ and R₄₄ are independently the same as those defined for R₄ in the general formula (100); provided that a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other in the general formula (202A); and at least one or more od R₁₁ to R₁₈ are an unsubstituted aryl group having 6 to 30 ring carbon atoms.

In the compound of the present embodiment, it is also preferable that C1 in the general formula (100) be bonded with a carbon atom at a position of “f” shown in the general formula (100),
a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other, and at least one or more od R₁₁ to R₁₈ be an unsubstituted aryl group having 6 to 30 ring carbon atoms.

The compound in the aspect is represented by the following general formula (203A).

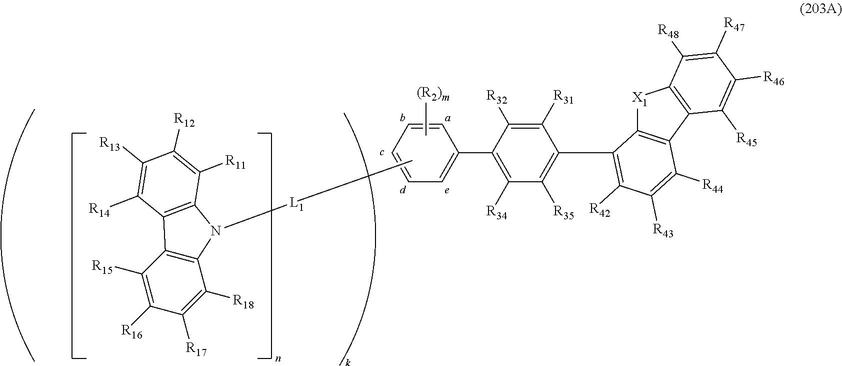

In the general formula (203A), X₁, R₁₁ to R₁₈, n, k, m, L₁, R₂, R₃₁, R₃₂, R₃₄, R₃₅, and R₄₅ to R₄₈ are independently the same as defined for X₁, R₁₁ to R₁₈, n, k, m, L₁, R₂, R₃₁, R₃₂, R₃₄, R₃₅, and R₄₅ to R₄₈ in the general formula (100); R₄₂ to R₄₄ are independently the same as those defined for R₄ in the general formula (100); provided that a set of R₁₁ and R₁₂, a set of R₁₂ and R₁₃, a set of R₁₃ and R₁₄, a set of R₁₅ and R₁₆, a set of R₁₆ and R₁₇, and a set of R₁₇ and R₁₈ do not bond with each other in the general formula (203A); and at least one or more od R₁₁ to R₁₈ are an unsubstituted aryl group having 6 to 30 ring carbon atoms.

In the compound of the present embodiment, C1 in the general formula (100) is also preferably bonded with a carbon atom at a position of “i” shown in the general formula (100).

The compound in the aspect is represented by the following general formula (300A).

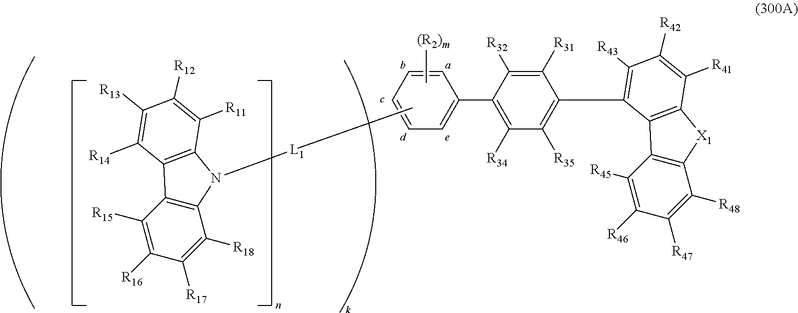

In the general formula (300A), X₁, R₁₁ to R₁₈, n, k, m, L₁, R₂, R₃₁, R₃₂, R₃₄, R₃₅, and R₄₅ to R₄₈ are independently the same as defined for X₁, R₁₁ to R₁₈, n, k, m, L₁, R₂, R₃₁, R₃₂, R₃₄, R₃₅, and R₄₅ to R₄₈ in the general formula (100); and R₄₁ to R₄₃ are independently the same as those defined for R₄ in the general formula (100).

In the general formula (300A), the ring structure having R₁₁ to R₁₈ is also preferably represented by any one of the general formulas (400-1) to (400-6).

The compound C3 can be synthesized by using known alternative reactions adapted to the target compound, and raw materials.

The first component may be a compound represented by the following formula (BD-1), or may not be a compound represented by the following formula (BD-1). The second component may be a compound represented by the following formula (BD-1), or may not be a compound represented by the following formula (BD-1). The compound represented by the formula (BD-1) is a blue emitting compound.

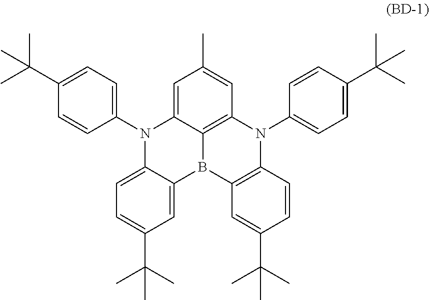 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

In one embodiment, one, two or three compounds selected from the group consisting of the compound C1, the compound C2 and the compound C3 are a compound represented by the following formula (41),
the compound C1, the compound C2 or the compound C3 is not a compound represented by the following formula (41),
all of the compound C1, the compound C2 and the compound C3 are not a compound represented by the following formula (41), or
the compound C2 included in the mixed powder is not a compound represented by the following formula (41).

When two or three compounds selected from the group consisting of the compound C1, the compound C2 and the compound C3 are a compound represented by the following formula (41), the two or three compounds are different from each other within the range satisfying the following formula (41).

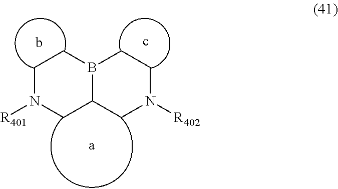

In the formula (41),
a ring a, a ring b and a ring c are independently
a substituted or unsubstituted aromatic hydrocarbon ring having 6 to 50 ring carbon atoms, or
a substituted or unsubstituted heterocycle having 5 to 50 ring atoms;
R₄₀₁ and R₄₀₂ independently form a substituted or unsubstituted heterocycle by bonding with the ring a, the ring b or the ring c, or do not form the substituted or unsubstituted heterocycle; and
R₄₀₁ and R₄₀₂ which do not form the substituted or unsubstituted heterocycle are independently
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms.

In one embodiment, one or two members selected from the group consisting of R₄₀₁ and R₄₀₂ independently form a substituted or unsubstituted heterocycle by bonding with the ring a, the ring b or the ring c in the formula (41).

In one embodiment, two members selected from the group consisting of R₄₀₁ and R₄₀₂ independently form a substituted or unsubstituted heterocycle by bonding with the ring a, the ring b or the ring c in the formula (41).

In one embodiment, all of R₄₀₁ and R₄₀₂ do not bond with the ring a, the ring b or the ring c not to form a substituted or unsubstituted heterocycle in the formula (41).

In one embodiment, as the first organic compound and the second organic compound, one or more compounds corresponding to the compounds C1 to C3 in compounds selected from compounds included in each group of the following (Group 2A) to (Group 35A) can be independently used. The first organic compound and the second organic compound in the present specification are not particularly limited independently to one or more compounds selected from compounds included in each group of the following (Group 2A) to (Group 35A), and they may not be these.

### (Group 2A)

bis(phenylamino)biphenyl; rubrene; bis(phenylamino)biphenyl; TBP; OP31; tris(quinolinolato)aluminum; coumarinC545T

### (Group 4A)

Alq3; NPB; TBADN; DCJTP; rubrene; OP31; DPQA; DBzR

### (Group 5A)

tris(methylphenylphenylamino)triphenylamine; tetrafluorotetracyanoquinodimethane; bathophenanthroline; tris(carbazolyl)triphenylamine; fac-tris(phenylpyridine)iridium; zinc phthalocyanine; fullerene C60

### (Group 6A)

tris(methylphenylphenylamino)triphenylamine; tetrafluorotetracyanoquinodimethane; bathophenanthroline; tris(carbazolyl)triphenylamine; fac-tris(phenylpyridine)iridium; zinc phthalocyanine; fullerene C60

### (Group 9A)

quaternaphthalene; (binaphthalenyl(naphthyl)benzene; ternaphthalene; (binaphthalenyl(naphthyl)benzene; (binaphthalenyl(naphthyl)benzene; quaternaphthalene; quaternaphthalene; quaternaphthalene; quaternaphthalene; (ternaphthalenyl(naphthyl)benzene; [bis(isopropylnaphthalenyl)]biphenyl; [(ternaphthalenyl)]biphenyl; (ternaphthalenyl(naphthyl)benzene; (ternaphthalenyl(naphthyl)benzene; diphenylphenanthrene; tetraphenylphenanthrene; dimethylbis(methylphenyl)phenanthrene; bis(trifluoromethylbis(trifluoromethylphenyl)phenanthrene; dimethoxybis(methoxyphenyl)phenanthrene; diphenylbis(biphenylyl)phenanthrene; diphenylbis(methylphenyl)phenanthrene; dimethyl(biphenylyl)phenanthrene; methylphenylmethylphenyl(biphenylyl)phenanthrene; di(naphthyl)phenanthrene; di(pyridyl)phenanthrene; di(tertbutyldiphenylphenanthrene; distyrylphenanthrene; cyanophenanthrene; bis(diphenylvinyl)phenanthrene; (binaphthalenyl(phenanthrenyl)benzene; di(phenanthrenyl)naphthalene; bis(diphenylphenanthrenyl)naphthalene; [di(phenanthrenyl)]binaphthalene; (binaphthalenyl)phenanthrene; di(phenanthrenyl)benzene; di(phenanthrenyl)naphthalene; (naphthyl(phenanthrenylphenanthrene; (naphthyl(phenanthrenylphenanthrene; diphenyl(naphthyl(phenanthrenylphenanthrene; (naphthyl(phenanthrenyldiphenylphenanthrene; phenyl(phenanthrenyl)naphthalene; diphenyldi(phenanthrenyl)naphthalene; naphthyl(phenanthrenylphenylphenanthrene; [di(phenanthrenyl)]biphenyl; (naphthyldi(phenanthrenyl)benzene; (naphthyldi(phenanthrenyl)benzene; tris(phenanthrenyl)naphthalene; [(phenyl)naphthalenyl]phenylphenanthrene; [(phenyl)naphthalenyl](naphthylphenanthrene; (binaphthalenyl(naphthylphenanthrene; (binaphthalenyl(phenanthrenylphenanthrene; [di(naphthyl)]biphenanthrene; [(naphthyl)]terphenanthrene; [(phenylphenanthrenyl](phenanthrenyl)benzene; (diphenylbinaphthalenyl(naphthyl)phenanthrene; [di(naphthyldiphenyl]biphenanthrene; [di(naphthyldiphenyl]biphenanthrene; (binaphthalenyl(naphthyl)phenanthrene; [(naphthyl)phenyl](naphthyl)phenanthrene; [(binaphthalenyl(phenanthrenyl)biphenyl; [(phenanthrenyl)phenyl](naphthylphenylphenanthrene; bis[(phenanthrenyl)phenyl]naphthalene; bis[(phenanthrenyl)phenyl]naphthalene; bis[(phenanthrenyl)phenyl]naphthalene; bis[(phenanthrenyl)phenyl]naphthalene; bis[(phenanthrenyl)phenyl]phenanthrene; bis[(phenanthrenyl)phenyl]naphthalene; bis[(phenanthrenyl)phenyl]naphthalene; bis[(phenanthrenyl)phenyl]naphthalene; (binaphthalenyl[(biphenylyl)phenanthrenyl]benzene; (naphthyl[(phenanthrenyl)naphthalenyl]benzene; [(phenanthrenyl)naphthalenyl](phenanthrenyl)benzene; (binaphthalenyl(phenanthrenyl)benzene; (binaphthalenyl(phenanthrenyl)benzene; [(phenanthrenylnaphthalenyl](phenanthrenyl)benzene; (binaphthalenyl(phenanthrenyl)benzene; (binaphthalenyl(phenanthrenyl)benzene; [(phenanthrenylnaphthalenyl](phenanthrenyl)benzene; (binaphthalenyl(phenanthrenyl)benzene; (binaphthalenyl(phenanthrenyl)benzene; (binaphthalenyl)(phenanthrenyl)benzene; [(phenanthrenylnaphthalenyl](phenanthrenyl)benzene; [(phenylnaphthalenyl](phenanthrenyl)benzene; ethyl[ethyl(binaphthalenyl)](phenanthrenyl)benzene; [(phenyl)binaphthalenyl]phenanthrene; [bis(phenanthrenyl)]binaphthalene; (benzophenanthrenyl(phenanthrenyl)binaphthalene; (benzochrysenyl){[(tertbutyldimethylsilyl)phenanthrenyl]naphthalenyl}benzene; [phenyl(phenanthrenyl)]binaphthalene; (phenanthrenylphenyl)binaphthalene; (ternaphthalenyl)phenanthrene; [bis(phenanthrenyl)]binaphthalene; [bis(phenanthrenyl)]binaphthalene; [(phenanthrenyl)(phenanthrenyl)]binaphthalene; [bis(phenanthrenyl)]binaphthalene; (ternaphthalenyl)phenanthrene; (ternaphthalenyl)phenanthrene; (ternaphthalenyl)phenanthrene; [bis(phenanthrenyl)]binaphthalene; {bis[(trimethylsilyl)phenanthrenyl]}binaphthalene; [bis(phenanthrenyl)]biphenyl; [(naphthyl)(phenanthrenyl)]biphenyl; [(phenanthrenyl)(phenanthrenyl)]biphenyl; [bis(phenanthrenyl)]biphenyl; [bis(phenanthrenyl)]biphenyl; [(phenanthrenyl)(naphthyl)]biphenyl; [dimethylbis(phenanthrenyl)]biphenyl; [(dimethylphenanthrenyl(methylphenanthrenyl)]biphenyl; [bis(diisopropylphenanthrenyl)]biphenyl; [(phenanthrenyl)(trimethylsilylnaphthalenyl)]biphenyl; [difluorobis(phenanthrenyl)]biphenyl; [dicyanobis(phenanthrenyl)]biphenyl; [(phenanthrenyl[(naphthyl)phenyl]]binaphthalene; [(biphenylyl(phenanthrenyl)]binaphthalene; {[(phenanthrenyl)phenyl](phenanthrenyl]binaphthalene; {[(phenanthrenyl)phenyl](phenanthrenyl]binaphthalene; {[(phenanthrenyl)phenyl]phenyl]binaphthalene; di(naphthyl)chrysene; di(naphthyl)chrysene; (naphthyl)(naphthyl)chrysene; di(phenanthrenyl)chrysene; (naphthyl)(phenanthrenyl)chrysene; (naphthyl)(phenanthrenyl)chrysene; bis[(naphthyl)phenyl]chrysene; bis[(naphthyl)phenyl]chrysene; [(naphthyl)phenyl][(naphthyl)phenyl]chrysene; (naphthyl[(naphthyl)phenyl]chrysene; [(naphthyl)phenyl](phenylnaphthalenyl)chrysene; [(naphthyl)phenyl](naphthyl)chrysene; bis(phenylnaphthalenyl)chrysene; bis[(biphenylyl)phenyl]chrysene; bis(phenylnaphthalenyl)chrysene; (phenylnaphthalenyl[(phenylnaphthalenyl)phenyl]chrysene; bis[(benzophenanthrenyl)phenyl]chrysene; [(naphthyl)phenyl][(naphthyl)phenyl]chrysene; bis[(naphthyl)phenyl]chrysene; bis[(naphthyl)phenyl]chrysene; phenyl[(phenanthrenyl)naphthalenyl]chrysene; bis(phenylchrysenyl)naphthalene; di(naphthyl)chrysene; (naphthyl(naphthyl)chrysene; di(naphthyl)chrysene; (naphthyl(phenanthrenyl)chrysene; di(phenanthrenyl)chrysene; (naphthyl(phenanthrenyl); diphenyldi(naphthyl)chrysene; phenyl(naphthyl(naphthyl)chrysene; phenyldi(naphthyl)chrysene; phenyl(phenanthrenyl(naphthyl)chrysene; isopropyldi(phenanthrenyl)chrysene; di(naphthyl(phenanthrenyl)chrysene; phenyldi(phenanthrenyl)chrysene; (phenanthrenyl(naphthyl)picene; [(biphenylylnaphthalenyl]chrysene; (chrysenyl[(phenanthrenyl)naphthalenyl]benzene; [(chrysenyl(phenanthrenyl)]binaphthalene; bis(chrysenyl)biphenyl; {phenyl[(cyclohexylchrysenyl)phenyl]binaphthalene; {phenyl[(chrysenyl)phenyl]binaphthalene; (picenyl){(phenanthrenyl)phenyl}naphthalene; diphenylbenzophenanthrene; di(naphthyl)benzophenanthrene; bis(phenylnaphthalenyl)benzophenanthrene; bis(phenylnaphthalenyl)benzophenanthrene; (phenylnaphthalenyl(naphthyl)benzophenanthrene; [(naphthyl)phenyl](naphthyl)benzophenanthrene; bis[(naphthyl)phenyl]benzophenanthrene; bis[(naphthyl)phenyl]benzophenanthrene; (benzophenanthrenyl(phenanthrenyl)benzene; [(naphthyl)phenyl][(naphthyl)phenyl]benzophenanthrene; (benzophenanthrenyl(phenanthrenyl)benzene; diphenylbenzophenanthrene; di(naphthyl)benzophenanthrene; (benzophenanthrenyl(phenanthrenyl)biphenyl; di(naphthyl)benzophenanthrene; (naphthylphenyl(phenanthrenyl)benzophenanthrene; di(naphthyl)benzochrysene; di(naphthyl)benzochrysene; (benzophenanthrenyl(naphthylphenanthrenyl)benzene; (benzochrysenyl(phenylnaphthalenyl)benzene; [(benzochrysenyl(benzophenanthrenyl)]binaphthalene; [(benzophenanthrenyl(naphthyl)]biphenyl; [(benzophenanthrenyl(benzophenanthrenyl)]biphenyl; [(phenanthrenyl)phenyl](benzophenanthrenyl)naphthalene; [(phenanthrenyl(benzochrysenyl)]binaphthalene; [di(benzochrysenyl)]biphenyl; diphenylbenzochrysene; bis[(naphthyl)phenyl]benzochrysene; bis[(naphthyl)phenyl]benzochrysene; di(naphthyl)benzochrysene; bis(phenylnaphthalenyl)benzochrysene; diphenylhelicene; di(naphthyl)helicene; di(naphthyl)helicene; di(naphthyl(fluoranthenyl)benzene; diphenyl[(naphthyl)phenyl]fluoranthene; bis[(naphthyl)phenyl]fluoranthene; phenyl(phenanthrenyl)fluoranthene; naphthyltetraphenylfluoranthene; phenanthrenyltetraphenylfluoranthene; diphenyl[(naphthyl)phenyl]fluoranthene; diisopropyldiphenyl[(naphthyl)phenyl]fluoranthene; diphenyl[(phenanthrenyl)phenyl]fluoranthene; di(naphthyl)fluoranthene; (naphthyl((naphthyl)phenyl)fluoranthene; (naphthylbis[(naphthyl)phenyl]fluoranthene; (naphthyl(phenanthrenyl)fluoranthene; (naphthyl(naphthyl)fluoranthene; (biphenylyl(naphthyl)fluoranthene; [(phenylbiphenylyl](naphthyl)fluoranthene; [(phenylbiphenylyl](naphthyl)fluoranthene; (biphenylyl(terbenzenyl)fluoranthene; di(fluoranthenyl)naphthalene; [(benzofluoranthenyl)naphthalenyl][(naphthyl)phenyl]phenanthrene; diphenyldi(fluoranthenyl)naphthalene; {[(benzofluoranthenyl)biphenylyl]}[(benzofluoranthenyl)phenyl]naphthalene; [(benzofluoranthenyl(phenanthrenyl)]biphenyl; [di(fluoranthenyl)]binaphthalene; [(fluoranthenyl)phenyl](phenanthrenyl)naphthalene; [(phenanthrenyl)phenyl](fluoranthenyl)naphthalene; [di(fluoranthenyl)]biphenyl; {[(phenanthrenyl)phenyl](fluoranthenyl)}binaphthalene; (benzofluoranthenyl(phenanthrenyl)benzene; (benzofluoranthenyl(phenanthrenyl)triphenylene; di(naphthyl(benzofluoranthenyl)benzene; (benzofluoranthenyl(naphthyl)benzene; bis[(naphthyl)phenyl]benzofluoranthene; (phenanthrenyl)benzofluoranthene; tetraphenylbenzofluoranthene; tetraphenyldibenzofluoranthene; diphenyl[(naphthyl)phenyl]benzofluoranthene; diphenyl[(naphthyl)phenyl]benzofluoranthene; diphenyl[(phenanthrenyl)phenyl]benzofluoranthene; diphenylbenzofluoranthene; bis[(phenyl)biphenylyl]diphenylbenzofluoranthene; (phenyldiphenylbenzofluoranthene; (diphenylbenzofluoranthenylphenylnaphthalene; di(naphthyldiphenylbenzofluoranthene; (biphenylyldiphenyl[(naphthyl)phenyl]benzofluoranthene; bis(biphenylyldiphenylbenzofluoranthene; di(methylstyryl)triphenylene; distyryltriphenylene; tri(methylstyryl)triphenylene; tristyryltriphenylene; diphenyltriphenylene; (naphthylphenyltriphenylene; diphenyltriphenylene; hexaphenyltriphenylene; triphenyltriphenylene; tris(biphenylyl)triphenylene; tetraphenyltriphenylene; (triphenylenyl(phenanthrenyldiphenylphenanthrene; naphthyl(phenanthrenyl)triphenylene; (biphenanthrenyl)triphenylene; bis(triphenylenyl)binaphthalene; [(triphenylenyl)phenyl](phenanthrenyl)naphthalene; [bis(triphenylenyl)]biphenyl; [bis(triphenylenyl)]biphenyl; {[(triphenylenyl)]phenylphenyl}binaphthalene; [(naphthyl)phenyl][(naphthyl)phenyl]naphthoquinoline; bis(naphthylazabenzochrysene; diphenyldiazodibenzophenanthrene; bis(phenylnaphthalenyl)acenaphthopyrazine; bis(phenylnaphthalenyldiazabenzofluoranthene; diphenylazabenzofluoranthene; iridium(III)bis(phenylquinolyl)acetylacetonate; iridium(III)tris(phenylisoquinolyl)iridium(III)bis((tertbutylphenyl)isoquinolyl)acetylacetonate; iridium(III)bis(diphenylquinoxalyl)acetylacetonate; iridium(III)bis(diphenyltetrahydroquinoxalyl)acetylacetonate; iridium(III)bis(diphenylpyrazine)acetylacetonate; osmium(IV)bis[(triphenylmethyltriazolylmethylpyridyl]bis(methyldiphenylphosphonate); ruthenium(V)bis[dipyridyl](phenylpyridyl); platinum(II)bis[(thienyl)pyridyl]; iridium(III)bis[(benzothiophenyl]pyridine]acetylacetonate; iridium(III)bis(phenylbenzothiazole)acetylacetonate; iridium(III)tris(diphenylquinoxalyl); iridium(III)bis(phenylphenantridyl)acetylacetonate; iridium(II)bis((biphenylyl)pyridine)acetylacetonate; iridium(III)bis(phenylisoquinolyl)(acetylhydroxycyclohexenone); platinum(II)bis[phenylenebis(ditertbutylsalicylideneamino]; iridium(III)tris(difluorodibenzoquinolyl)acetylacetonate; platinum(II)(octaethylporphyrin); iridium(III)tris[(fluoro)phenylpyridyl]; iridium(III)bis[(fluoro)phenylpyridyl]acetylacetonate; iridium(III)tris[(difluorophenyl)pyridyl]; iridium(III)tris[(fluorophenylmethoxypyridyl]; iridium(III)bis[(fluorophenyl)pyridyl][(difluorophenyl)pyridyl]; iridium(III)tris[(difluorophenylmethoxypyridyl]; iridium(III)tris[(fluorophenyldiphenylaminopyridyl]; iridium(II)tris[(fluorophenyldimethylaminopyridyl]acetylacetonate; iridium(III)tris[(difluorophenylmethylpyridyl]; platinum(II)[di(pyridyl)benzil](biphenylone]; iridium(III)tris[(methylphenylpyridyl]; iridium(III)tris[(methylphenylpyridyl]; iridium(III)bis[phenylisoquinolyl]acetylacetonate; iridium(III)bis[phenylpyridyl]acetylacetonate; iridium(III)bis[(bis(trifluoromethyl)phenyl)pyridyl)(carboxylatepyridiniu); iridium(III)bis[(difluorophenyl)pyridyl)(carboxylatepyridiniu); iridium(III)bis[(difluorophenyl)pyridyl)[(trifluoromethyl(pyridinyltriazole); iridium(III)tris[phenylpyridyl); iridium(II)bis[phenylisoquinolyl]acetylacetonate; iridium(III)bis[(difluorophenyl)pyridyl)[tetrakis(Hpyrazolyl)boron]; iridium(III)tris[phenylmethyldihydrobenzimidazole]; iridium(III)tris[(dibenzofuranylmethylimidazoline]; iridium(III)tris[(dimethylfluorenylpyrazole]; platinum(II)bis(phenylpyridine); iridium(III)tris[(trifluorophenyl)pyridyl]; iridium(III)bis[(thienyl)pyridyl]acetylacetonate; iridium(II)bis(phenylbenzoxazole)acetylacetonate; iridium(III)bis[(naphthyl)benzoxazole]acetylacetonate; iridium(II)bis[(benzothiazolyldimethylaminocoumaryl]acetylacetonate; iridium(II)bis[(naphthyl)isoquinolyl]acetylacetonate; iridium(II)bis[(naphthyl)isoquinolyl]acetylacetonate; iridium(II)bis[(pyridyl)isoquinolyl]acetylacetonate; iridium(III)bis(phenylisoquinolyl)(phenylpyridyl); iridium(III)tris[(thienyl)isoquinolyl]

### (Group 10A)

[di(carbazolyl)]biphenyl; [dimethyldi(carbazolyl)]biphenyl; [diphenyldi(carbazolyl)]biphenyl; di(carbazolyl)benzene; tri(carbazolyl)benzene; di(carbazolyl)triphenylsilylbenzene; tris[(carbazolyl)phenyl]amine; tris[(carbazolyl)phenyl]benzene; tris{[methylphenyl(phenyl)amino]phenyl}amine; tris{[naphthyl(phenyl)amino]phenyl}amine; [bis(tribenzazepinyl)]biphenyl; [dimethylbis(tribenzazepinyl)]biphenyl; bis(tribenzazepinyl)benzene; tris(tribenzazepinyl)benzene; tris[(tribenzazepinyl)phenyl]amine; tris[(tribenzazepinyl)phenyl]benzene; diphenylbis[(carbazolyl)phenyl]silane; diphenylbis[(carbazolyl)phenyl]methane; di(carbazolyl)quaterbenzene; di(carbazolyl)quaterbenzene; di(carbazolyl)quaterbenzene; bis[(carbazolyl)phenyl]tetraphenylbenzene; bis[(carbazolyl)phenyl]tetraphenylbenzene; [di(carbazolyl)]biphenyl; bis(tertbutylindole-d₅)benzene-d₄; di(carbazolyl-d₈)benzene-d₄; [di(carbazolyl-d₈)]biphenyl; diphenylbis{[bis(methylphenyl)amino]phenyl}biphenyldiamine; tris[(naphthylphenylamino)phenyl]amine; diphenyldi(naphthyl)biphenyldiamine; tris(phenylbenzimidazolyl)benzene; tris(phenylimidazopyridinyl)benzene; tris((methylphenyl)imidazopyridinyl)benzene; tris((biphenyl)imidazopyridinyl)benzene; tris(methylbenzimidazolyl)triazine; tris(phenylbenzimidazolyl)triazine; aluminum(III)tris(quinolineolate); aluminum(III)bis(methylquinolineolate)(biphenylol); aluminum(III)bis(methylquinolineolate)(phenylnaphthalenol); aluminum(III)bis(methylquinolineolate)(triphenylsilanol); aluminum(III)tris[(hydroxyphenyl)phenylimidazopyridinol]; gallium(III)tris[(hydroxyphenyl)phenylimidazopyridinol]; aluminum(III)tris[(triphenylimidazolyl)phenol]; palladium(II)bis(phenylpyridyl); platinum(II)bis(phenylpyridyl); iridium(III)tris(phenylpyrazolyl); iridium(III)bis(phenylpyrazolyl)(phenylpyridyl); palladium(II)bis(phenylpyrazolyl); platinum(II)[diphenylbis(phenylpyridinyl)methane]; platinum(II){diphenylbis[(difluorophenyl)pyridinyl)methane]; palladium(II)[bis(phenylpyridinyl)propane]; palladium(II)[diphenylbis(phenylpyridinyl)methane]; platinum(II)[bis(phenylpyridinyl)methane]; platinum(II){bis[(isoquinolinyl)naphthalenyl)]methane}; platinum(II){bis[(isoquinolinyl)benzene]one}; platinum(II)[bis(phenylpyridinyl)methane]; platinum(II)[bis(bipyridinyl)one}; platinum(II)(diphenylquinoquinoline)}; platinum(II)[phenyl(phenylpyridinyl)quinoline]; platinum(II){bis[(benzothiophenyl)pyridinyl]methylene]; platinum(II){{bis[(methyl)indolyl]pyridinyl}methane]; platinum(II)[bis(phenylisoquinolinyl)methane]; platinum(II){bis[(methoxyphenyl)isoquinolinyl]methane]; platinum(II)[bis(phenacylpyridine)]; platinum(II)[bis((hydroxyphenyl)pyridine)]; platinum(II){bis[(hydroxybenzylidene)]benzene}; platinum(II)[(diphenylphenanthrolinediyl)bis(phenol)]; platinum(II)[[(phenylpropyl)isoquinolinediyl](phenylpropyl)isoquinoline]; platinum(II)[[(phenylpropyl)isoquinolinediyl](phenylpropyl)isoquinoline]; platinum(II)[(methylenebispyridinediyl)methylenebispyridine]; platinum(II)[[(pyridylpropyl)pyridine)diyl](phenylpropyl)benzene]; platinum(II)[[(isoquinolylpropyl)isoquinoline)diyl]((naphthalene)propyl)naphthalene]; platinum(II)[(quinoquinolinediyl)(phenylpropyl)benzene]; platinum(II)[tetraazahexacyclodotriacontapentadecene]; platinum(II)[[((pyrazyl)propyl)pyrazine)diyl](phenylpropyl)benzene]; platinum(II)[bis(phenylpyridinyl)aniline]; platinum(II){[(naphthyl)pyridinyl](phenylpyridinyl)propane}; platinum(II){(phenylpyridinyl)[(benzimidazolyl)pyridinyl]propane}; platinum(II)[bis(phenylisoquinolinyl)aniline]; platinum(II)[bis(phenylbiisoquinolinyl)aniline]; platinum(II)[bis((naphthyl)pyridinyl)aniline]; platinum(II)[bis((thienyl)pyridinyl)aniline]; platinum(II)[bis(phenylpyridinyl)ethene]; platinum(II)[bis(phenylpyridinyl)one]; platinum(II)[bis((pyridyl)phenyl)aniline]; platinum(II)[bis(difluorobipyridinatoyl)propane]; platinum(II)[(difluorobipyridinatoyl){(trifluoromethylpyrazolyl)pyridinatoyl}propane]platinum(II){bis[(cyanophenyl)pyridinyl]propane]; platinum(II)[(difluorobipyridinatoyl)(pyridinecarboxylic acidyl)propane]; platinum(II){[(phenylpyrazolyl)[(dibenzofuranyl)pyrazolyl]propane]; platinum(II)[bis(phenylpyridinyl)propane]; platinum(II){[bis(biphenylyl)pyridinyl]propane}; iridium(II)bis[(dimethylphenyl)isobutylquinoline]acetylacetonate; iridium(III)bis[(quinolyl)isobutylbenzene]acetylacetonate; iridium(III)bis[(quinolyl)diisobutylbenzene]acetylacetonate; iridium(III)bis[(quinolyl)dimethylbenzene]acetylacetonate; iridium(III)tris[phenylisoquinoline]; iridium(III)bis[phenylisoquinoline]acetylacetonate; iridium(III)bis[(naphthyl)quinoline](tetramethyloxylatoheptenone); iridium(III)bis[(naphthyl)quinoline](phenylpyridine); iridium(III)bis(phenylpyridine) [(naphthyl)quinoline]; iridium(III)bis((thienyl)quinoline) (phenyloxylatobuteneone); iridium(III)bis[(pyridinyl)quinoline](phenylpyrazine); iridium(III)bis(biquinoline)acetylacetonate; iridium(II)bis(phenylbenzoquinoline)acetylacetonate; iridium(III)bis[(naphthyl)quinoline](phenylbenzoxazole); iridium(II)bis(phenylquinoline)acetylacetonate; iridium(II)bis[(methylphenyl)quinoline]acetylacetonate; iridium(II)bis(benzacridine)acetylacetonate; iridium(II)bis[(naphthyl)quinoline)acetylacetonate; iridium(II)bis[(pyrenyl)quinoline]acetylacetonate; iridium(IIII)bis[(biphenylyl)quinoline]acetylacetonate; iridium(III)bis[(phenanthrenyl)quinoline]acetylacetonate; iridium(II)bis[(methylphenyl)quinoline]acetylacetonate; iridium(III)bis[phenylquinoline]acetylacetonate; iridium(III)tris(phenylquinoline); iridium(III)bis(phenylisoquinoline)acetylacetonate; iridium(III)bis[(naphthyl)isoquinoline]acetylacetonate; iridium(III)tris{[(trifluoromethyl)phenyl]pyrazole}; iridium(III)tris[(difluorophenyl)pyridine]; iridium(III)tris[(tertbutylphenyl)pyridine]; iridium(III)tris[(thienyl)pyridine]; iridium(III)tris[(pyridyl)benzothiophene]; iridium(III)tris[(tertbutylphenyl)isoquinoline]; iridium(III)tris[(thienyl)isoquinoline]; iridium(III)tris[(dimethylfluorenyl)isoquinoline]; iridium(III)bis[(difluorophenyl)pyridine][tetra(pyrazolyl)borane]; iridium(III)bis[(difluorotrifluoromethylphenyl)pyridine](pyridinecarboxylate); iridium(III)bis(phenylpyridine)acetylacetonate; iridium(III)tris(phenylbenzoxazole); iridium(III)bis(phenylquinoline)acetylacetonate; iridium(III)bis[(pyridyl)benzothiophene]acetylacetonate; iridium(III)bis(phenylisoquinoline)acetylacetonate; iridium(III)bis[(pyridyl)naphthalene]acetylacetonate; europium(IV)tris[(thienyl)trifluorooxylatobuteneone](phenanthroline); iridium(III)tris[(naphthyl)isoquinoline]; terbium(IV)trisacetylacetonate(phenanthroline); dysprosium(IV)tris[trifluorooxylatophenylbuteneone](benzo[h]quinoline); platinum(II)[bis(phenylpyridinyl)propane]; platinum(II){bis[(difluorophenyl)pyridinyl]propane}; platinum(II){bis[(trifluoromethylpyrazolyl)pyridinyl]propane}; platinum(II){bis[(trifluoromethylpyrazolyl)pyridinyl]fluorene}; bis(diphenylethenyl)biphenyl; diphenylanthracene; di(naphthyl)anthracene; tetrakis(biphenylyl)pyrene; octakis(methylphenyl)pyrenetetraamine; dimethylquinacridone; rubrene; coumarin; {[(tetrahydrobenzoquinolizine)yl]ethenylmethylpyranylidene}propanedinitrile

### (Group 12A)

diphenyl(triphenylenyl)triazine; diphenyl(triphenylenyl)pyridine; (triphenylenyl)diphenylpyrimidine; (pyridinyl)(triphenylenyl)biphenyl; di(pyridinyl)(triphenylenyl)benzene; (pyridinyl)(pyridinyl)(triphenylenyl)benzene; di(pyridinyl)(triphenylenyl)benzene; (pyridinyl)phenyl(triphenylenyl)triazine; (pyridinyl)(triphenylenyl)pyrimidine; phenyl(triphenylenyl)pyrimidine; (pyridinyl)(triphenylenyl)benzene; phenyl(triphenylenyl)triazine; (diphenylpyridinyl)(triphenylenyl)benzene; (diphenylpyridinyl)(triphenylenyl)benzene; (diphenyltriazinyl)(triphenylenyl)benzene; di(pyridinyl)(triphenylenyl)biphenyl; di(pyridinyl)(triphenylenyl)biphenyl; (pyridinyl)(pyridinyl)(triphenylenyl)biphenyl; [di(pyridinyl)triazinyl](triphenylenyl)benzene; phenyl[(triphenylenyl)phenyl]pyrimidine; phenyl[(triphenylenyl)phenyl]triazine; (diphenylpyridinyl)(triphenylenyl)benzene; [(triphenylenyl)phenyl]diphenylpyrimidine; [(triphenylenyl)phenyl]diphenyltriazine; di(pyridinyl)(triphenylenyl)biphenyl; di(pyridinyl)(triphenylenyl)biphenyl; (pyridinyl)(pyridinyl)(triphenylenyl)biphenyl; [di(pyridinyl)triazinyl](triphenylenyl)benzene; phenyl[(triphenylenyl)phenyl]pyrimidine; phenyl[(triphenylenyl)phenyl]triazine; (triphenylenyl)(diphenylpyridinyl)biphenyl; (triphenylenyl)(diphenylpyrimidinyl)biphenyl; (triphenylenyl)(diphenyltriazinyl)biphenyl; (triphenylenyl)(pyridinyl)terbenzene; (triphenylenyl)(pyridinyl)terbenzene; (triphenylenyl)(pyridinyl)(pyridinyl)terbenzene; (triphenylenyl)[di(pyridinyl)triazinyl]biphenyl; (triphenylenyl)(phenylpyrimidinyl)biphenyl; (triphenylenyl)(phenyltriazinyl)biphenyl; (triphenylenyl)(diphenylpyridinyl)biphenyl; (triphenylenyl)(diphenylpyrimidinyl)biphenyl; (triphenylenyl)(diphenyltriazinyl)biphenyl; (triphenylenyl)di(pyridinyl)terbenzene; (triphenylenyl)di(pyridinyl)terbenzene; (triphenylenyl)(pyridinyl)(pyridinyl)terbenzene; (triphenylenyl)[di(pyridinyl)triazinyl]biphenyl; (triphenylenyl)(phenylpyrimidinyl)biphenyl; (triphenylenyl)(phenyltriazinyl)biphenyl; (diphenylpyridinyl)(triphenylenyl)biphenyl; (diphenylpyrimidinyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; [di(pyridinyl)triazinyl](triphenylenyl)biphenyl; (phenylpyrimidinyl)(triphenylenyl)biphenyl; (phenyltriazinyl)(triphenylenyl)biphenyl; (diphenylpyridinyl)(triphenylenyl)biphenyl; (diphenylpyrimidinyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; (di(pyridinyl)triazinyl)(triphenylenyl)biphenyl; (phenylpyrimidinyl)(triphenylenyl)biphenyl; (phenyltriazinyl)(triphenylenyl)biphenyl; (diphenylpyridinyl)(triphenylenyl)biphenyl; (diphenylpyrimidinyl)(triphenylenyl)biphenyl; (diphenyltriazinyl)(triphenylenyl)biphenyl; di(pyridinyl)(triphenylenyl)terbenzene; di(pyridinyl)(triphenylenyl)terbenzene; (pyridinyl)(pyridinyl)(triphenylenyl)terbenzene; [di(pyridinyl)triazinyl](triphenylenyl)biphenyl; (phenylpyrimidinyl)(triphenylenyl)biphenyl; (phenyltriazinyl)(triphenylenyl)biphenyl; (diphenylpyridinyl)(triphenylenyl)terbenzene; (diphenylpyrimidinyl)(triphenylenyl)terbenzene; (diphenyltriazinyl)(triphenylenyl)terbenzene; di(pyridinyl)(triphenylenyl)quaterbenzene; di(pyridinyl)(triphenylenyl)quaterbenzene; (pyridinyl)(pyridinyl)(triphenylenyl)quaterbenzene; [di(pyridinyl)triazinyl](triphenylenyl)terbenzene; (phenylpyrimidinyl)(triphenylenyl)terbenzene; (phenyltriazinyl)(triphenylenyl)terbenzene; (diphenylpyridinyl)(triphenylenyl)terbenzene; (diphenylpyrimidinyl)(triphenylenyl)terbenzene; (diphenyltriazinyl)(triphenylenyl)terbenzene; di(pyridinyl)(triphenylenyl)quaterbenzene; di(pyridinyl)(triphenylenyl)quaterbenzene; (pyridinyl)(pyridinyl)(triphenylenyl)quaterbenzene; [di(pyridinyl)triazinyl](triphenylenyl)terbenzene; (phenylpyrimidinyl)(triphenylenyl)terbenzene; (phenyltriazinyl)(triphenylenyl)terbenzene; (diphenylpyridinyl)(phenyltriphenylenyl)biphenyl; (diphenylpyrimidinyl)(triphenylenyl)terbenzene; (triphenylenyl)(diphenyltriazinyl)terbenzene; [di(pyridinyl)triazinyl](triphenylenyl)terbenzene; [(triphenylenyl)biphenylyl)terpyridine; [(triphenylenyl)biphenylyl)terpyridine; (phenyltriphenylenyl)diphenyltriazine; (methyltriphenylenyl)diphenyltriazine; (phenyltriphenylenyl)(pyridinyl)biphenyl; (phenyltriphenylenyl)di(pyridinyl)benzene; (methyltriphenylenyl)(pyridinyl)(pyridinyl)benzene; (diphenyltriphenylenyl)(pyridinyl)phenyltriazine; (pyridinyl)(phenyltriphenylenyl)pyrimidine; phenyl(phenyltriphenylenyl)pyrimidine; (diphenylpyridinyl)(methyltriphenylenyl)benzene; (diphenylpyrimidinyl)(diphenyltriphenylenyl)benzene; di(pyridinyl)(phenyltriphenylenyl)biphenyl; (pyridinyl)(pyridinyl)(methyltriphenylenyl)biphenyl; (diphenylpyridinyl)(phenyltriphenylenyl)benzene; di(pyridinyl)(triphenylenyl)biphenyl; [di(pyridinyl)triazinyl](phenyltriphenylenyl)benzene; di(pyridinyl)(phenyltriphenylenyl)terbenzene; [di(pyridinyl)triazinyl](phenyltriphenylenyl)biphenyl; (phenyltriphenylenyl)di(pyridinyl)terbenzene; [di(pyridinyl)triazinyl](dimethyltriphenylenyl)biphenyl; (diphenylpyridinyl)(phenyltriphenylenyl)biphenyl; (diphenylpyrimidinyl)(methyltriphenylenyl)biphenyl; (diphenyltriazinyl)(phenyltriphenylenyl)biphenyl; (diphenyltriazinyl)(dimethyltriphenylenyl)terbenzene; (diphenyltriazinyl)(methyltriphenylenyl)terbenzene; di(pyridinyl)(phenyltriphenylenyl)terbenzene; (diphenyltriazinyl)(phenyltriphenylenyl)biphenyl; (diphenyltriazinyl)(phenyltriphenylenyl)biphenyl; phenyl(diphenylpyridinyl)bi(carbazole)phenyl(diphenylpyridinyl)bi(carbazole)(biphenylyl)(diphenylpyridinyl)bi(c arbazole)(terphenylyl)(diphenylpyridinyl)bi(carbazole); (terphenylyl)(diphenylpyridinyl)bi(carbazole); (naphthalenyl)(diphenylpyridinyl)bi(carbazole); (naphthalenyl)(diphenylpyridinyl)bi(carbazole); (triphenylenyl)(diphenylpyridinyl)bi(carbazole); (triphenylenyl)(diphenylpyridinyl)bi(carbazole); bi[(diphenylpyridinyl)carbazole]; (diphenylpyridinyl)(diphenylpyridinyl)bi(carbazole); bi[(diphenylpyridinyl)carbazole]; (dimethylfluorenyl)phenylbi(carbazole); (dimethylfluorenyl)(biphenylyl)bi(carbazole); (dimethylfluorenyl)(terphenylyl)bi(carbazole); (dibenzofuranyl)phenylbi(carbazole); (dibenzofuranyl)(biphenylyl)bi(carbazole); (dibenzofuranyl)(terphenylyl)bi(carbazole); (dibenzothiophenyl)phenylbi(carbazole); (dibenzothiophenyl)(biphenylyl)bi(carbazole); (dibenzothiophenyl)(terphenylyl)bi(carbazole); bi[phenylcarbazole]; bi[(pyridinyl)carbazole]; bi[(pyrimidinyl)carbazole]; (triphenylenyl)phenylbi(carbazole); (triphenylenyl)(pyridinyl)bi(carbazole); (triphenylenyl)phenylbi(carbazole); (triphenylenyl)(pyridinyl)bi(carbazole); phenyl(triphenylenyl)bi(carbazole); (pyridinyl)(triphenylenyl)bi(carbazole); (biphenylyl)(biphenylyl)bi(carbazole); (biphenylyl)(terphenylyl)bi(carbazole); (biphenylyl)(terphenylyl)bi(carbazole); (dimethylfluorenyl)phenylbi(carbazole); (dimethylfluorenyl)(biphenylyl)bi(carbazole); (dimethylfluorenyl)(biphenylyl)bi(carbazole); (dimethylfluorenyl)(terphenylyl)bi(carbazole); (dibenzofuranyl)(biphenylyl)bi(carbazole); (dibenzothiophenyl)(biphenylyl)bi(carbazole); (phenylcarbazolyl)phenylbi(carbazole); (dibenzofuranyl)phenylbi(carbazole); (dibenzofuranyl)(biphenylyl)bi(carbazole); (dibenzofuranyl)(terphenylyl)bi(carbazole); (dibenzofuranyl)(biphenylyl)bi(carbazole); (dibenzothiophenyl)phenylbi(carbazole); (dibenzothiophenyl)(biphenylyl)bi(carbazole); (dibenzothiophenyl)(terphenylyl)bi(carbazole); (dibenzothiophenyl)(biphenylyl)bi(carbazole); (diphenylpyridinyl)(dimethylfluorenyl)bi(carbazole); (diphenylpyridinyl)(dimethylfluorenyl)bi(carbazole); [(pyridinyl)biphenylyl](dimethylfluorenyl)bi(carbazole); [(pyridinyl)biphenylyl](dimethylfluorenyl)bi(carbazole); [(pyridinyl)biphenylyl](dimethylfluorenyl)bi(carbazole); (diphenylpyridinyl)(dibenzofuranyl)bi(carbazole); (dibenzofuranyl)[(pyridinyl)biphenylyl]bi(carbazole); (dibenzofuranyl)[(pyridinyl)biphenylyl]bi(carbazole); (dibenzofuranyl)[(pyridinyl)biphenylyl]bi(carbazole); (dibenzothiophenyl)(diphenylpyridinyl)bi(carbazole); (dibenzothiophenyl)[(pyridinyl)biphenylyl]bi(carbazole); (dibenzothiophenyl)[(pyridinyl)biphenylyl]bi(carbazole); (dibenzothiophenyl)[(pyridinyl)biphenylyl]bi(carbazole); phenyl(diphenylpyridinyl)bi(carbazole); phenyl[(pyridinyl)biphenylyl]bi(carbazole); phenyl(diphenylpyridinyl)bi(carbazole); (biphenylyl)(diphenylpyridinyl)bi(carbazole); (biphenylyl)[(pyridinyl)biphenylyl]bi(carbazole); (biphenylyl)(diphenylpyridinyl)bi(carbazole); (biphenylyl)(diphenylpyridinyl)bi(carbazole); (biphenylyl)(diphenylpyridinyl)bi(carbazole); (biphenylyl)[(pyridinyl)biphenylyl]bi(carbazole); (diphenylpyridinyl)phenylbi(carbazole); (diphenylpyridinyl)phenylbi(carbazole); [(pyridinyl)biphenylyl]phenylbi(carbazole); (diphenylpyridinyl)(biphenylyl)bi(carbazole); (diphenylpyridinyl)(biphenylyl)bi(carbazole); [(pyridinyl)biphenylyl](biphenylyl)bi(carbazole); (diphenylpyridinyl)(biphenylyl)bi(carbazole); (diphenylpyridinyl)(biphenylyl)bi(carbazole); [(pyridinyl)biphenylyl](biphenylyl)bi(carbazole); (dibenzofuranyl)(terphenylyl)bi(carbazole); (dibenzofuranyl)(biphenylyl)bi(carbazole); (dibenzofuranyl)phenylbi(carbazole); (dibenzofuranyl)(biphenylyl)bi(carbazole); (dibenzothiophenyl)(terphenylyl)bi(carbazole); (dibenzothiophenyl)(biphenylyl)bi(carbazole); (dibenzothiophenyl)phenylbi(carbazole); (dibenzothiophenyl)(biphenylyl)bi(carbazole); (biphenylyl)(diphenylpyridinyl)bi(carbazole); (diphenylpyridinyl)(biphenylyl)bi(carbazole); phenyl(diphenylpyridinyl)bi(carbazole); (diphenylpyridinyl)phenylbi(carbazole); phenyl(diphenylpyridinyl)bi(carbazole); phenyl(diphenylpyridinyl)bi(carbazole); phenyl(diphenylpyridinyl)bi(carbazole); (diphenylpyridinyl)phenylbi(carbazole); (diphenylpyridinyl)phenylbi(carbazole); (biphenylyl)(diphenylpyridinyl)bi(carbazole); phenyl(diphenylpyridinyl)bi(carbazole); bi[(biphenylyl)carbazole]; bi[(biphenylyl)carbazole]; (biphenylyl)phenylbi(carbazole)

### (Group 13A)

(carbazolyl)(triphenylenyl)biphenyl; (carbazolyl)(triphenylenyl)biphenyl; (carbazolyl)(triphenylenyl)biphenyl; (carbazolyl)(triphenylenyl)biphenyl; (carbazolyl)(triphenylenyl)terbenzene; (carbazolyl)(triphenylenyl)terbenzene; (carbazolyl)(triphenylenyl)terbenzene; (carbazolyl)(triphenylenyl)terbenzene; (carbazolyl)(triphenylenyl)quaterbenzene; (triphenylenyl)(carbazolyl)terbenzene; (phenylcarbazolyl)(triphenylenyl)biphenyl; (diphenylcarbazolyl)(triphenylenyl)biphenyl; (carbazolyl)(phenyltriphenylenyl)biphenyl; (carbazolyl)(triphenylenyl)terbenzene; (triphenylenyl)(carbazolyl)terbenzene; (carbazolyl)[(triphenylenyl)phenyl]terbenzene; (phenylcarbazolyl)(triphenylenyl)terbenzene; (diphenylcarbazolyl)(triphenylenyl)terbenzene; (carbazolyl)[(triphenylenyl)phenyl]pyridine; (carbazolyl)[(triphenylenyl)phenyl]pyridine; (carbazolyl)[(triphenylenyl)phenyl]pyridine; (carbazolyl)[(triphenylenyl)phenyl]pyridine; [(carbazolyl)pyridinyl](triphenylenyl)biphenyl; [(carbazolyl)pyridinyl](triphenylenyl)biphenyl; [(carbazolyl)pyridinyl](triphenylenyl)biphenyl; [(carbazolyl)pyridinyl](triphenylenyl)biphenyl; [(carbazolyl)pyridinyl](triphenylenyl)terbenzene; (carbazolyl)phenyl[(triphenylenyl)phenyl]pyridine; (phenylcarbazolyl)[(triphenylenyl)phenyl]pyridine; (diphenylcarbazolyl)[(triphenylenyl)phenyl]pyridine; (carbazolyl)[(phenyltriphenylenyl)phenyl]pyridine; [(carbazolyl)pyridinyl](triphenylenyl)biphenyl; (carbazolyl)phenyl[(triphenylenyl)phenyl]pyridine; (triphenylenyl)[(carbazolyl)pyridinyl]terbenzene; [(phenylcarbazolyl)pyridinyl](triphenylenyl)biphenyl; [(diphenylcarbazolyl)pyridinyl](triphenylenyl)biphenyl; [(carbazolyl)phenyl][(triphenylenyl)phenyl]pyridine; [(carbazolyl)phenyl][(triphenylenyl)biphenylyl]pyridine; (carbazolyl)[(triphenylenyl)phenyl]pyrimidine; (carbazolyl)[(triphenylenyl)phenyl]pyrimidine; (carbazolyl)[(triphenylenyl)phenyl]pyrimidine; (carbazolyl)[(triphenylenyl)phenyl]pyridine; [(triphenylenyl)phenyl](carbazolyl)pyridine; [(triphenylenyl)phenyl](carbazolyl)pyridine; (carbazolyl)[(triphenylenyl)phenyl]pyridine; [(carbazolyl)pyridinyl](triphenylenyl)biphenyl; (carbazolyl)(phenyltriphenylenyl)biphenyl; (carbazolyl)(diphenyltriphenylenyl)biphenyl; [(carbazolyl)biphenylyl][(carbazolyl)phenyl]triphenylene; bis[(carbazolyl)biphenylyl]triphenylene; bis[(carbazolyl)biphenylyl]triphenylene; [(carbazolyl)biphenylyl][(carbazolyl)phenyl]triphenylene; (carbazolyl)[(triphenylenyl)phenyl]pyridine; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [di(biphenylyl)triazinyl]phenylindolocarbazole; [(biphenylyl)phenyltriazinyl](biphenylyl)indolocarbazole; [di(biphenylyl)triazinyl](biphenylyl)indolocarbazole; [(biphenylyl)phenyltriazinyl](terphenylyl)indolocarbazole; [di(biphenylyl)triazinyl](terphenylyl)indolocarbazole; [(biphenylyl)phenyltriazinyl]thiaazaindenofluorene; [di(biphenylyl)triazinyl]thiaazaindenofluorene; [bis(dimethylfluorenyl)triazinyl]phenylindolocarbazole; [(biphenylyl)phenyltriazinyl]oxazaindenofluorene; [di(biphenylyl)triazinyl]oxazaindenofluorene; [bis(dimethylfluorenyl)triazinyl]thiaazaindenofluorene; (diphenyltriazinyl)phenylindolocarbazole; (diphenyltriazinyl)(biphenylyl)indolocarbazole; [phenyl(biphenylyl)triazinyl]phenylindolocarbazole; [di(biphenylyl)triazinyl]phenylindolocarbazole; [phenyl(biphenylyl)triazinyl]thiaazaindenofluorene; [di(biphenylyl)triazinyl]thiaazaindenofluorene; [phenyl(biphenylyl)triazinyl]azaoxaindenofluorene; [di(biphenylyl)triazinyl]azaoxaindenofluorene; [bis(dimethylfluorenyl)triazinyl]thiaazaindenofluorene;[bis(dimethylfluorenyl)triazinyl]azaoxaindenofluorene; [bis(dimethylfluorenyl)triazinyl]phenylindolocarbazole; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [di(biphenylyl)triazinyl]phenylindolocarbazole; [di(biphenylyl)triazinyl](biphenylyl)indolocarbazole; [di(dimethylfluorenyl)triazinyl]phenylindolocarbazole; [(biphenylyl)phenyltriazinyl]thiaazaindenofluorene; [di(biphenylyl)triazinyl]thiaazaindenofluorene; [bis(dimethylfluorenyl)triazinyl]thiaazaindenofluorene; [(biphenylyl)phenyltriazinyl]oxaindenofluorene; [di(biphenylyl)triazinyl]azaoxaindenofluorene; [bis(dimethylfluorenyl)triazinyl]azaoxaindenofluorene; [(biphenylyl)phenyltriazinyl]dimethylindenocarbazole; [di(biphenylyl)triazinyl]dimethylindenocarbazole; [bis(dimethylfluorenyl)triazinyl]dimethylindenocarbazole; (diphenyltriazinyl)(biphenylyl)indolocarbazole; (diphenyltriazinyl)(terphenylyl)indolocarbazole; [(biphenylyl)phenyltriazinyl](biphenylyl)indolocarbazole; [bis(dimethylfluorenyl)triazinyl]phenylindolocarbazole; [bis(dimethylfluorenyl)triazinyl](biphenylyl)indolocarbazole; [(biphenylyl)phenyltriazinyl]azathiaindenofluorene; [di(biphenylyl)triazinyl]azathiaindenofluorene; [bis(dimethylfluorenyl)triazinyl]azathiaindenofluorene; [(biphenylyl)phenyltriazinyl]azaoxaindenofluorene; [di(biphenylyl)triazinyl]azaoxaindenofluorene; [bis(dimethylfluorenyl)triazinyl]azaoxaindenofluorene; (biphenylyl)[(diphenyltriazinyl)phenyl]indolocarbazole; (terphenylyl)[(diphenyltriazinyl)phenyl]indolocarbazole; phenyl{[phenyl(biphenylyl)triazinyl]phenyl}indolocarbazole; phenyl{[di(biphenylyl)triazinyl]phenyl}indolocarbazole; phenyl{[bis(dimethylfluorenyl)triazinyl]phenyl}indolocarbazole; (biphenylyl){[(biphenylyl)phenyltriazinyl]phenyl}indolocarbazole; (biphenylyl){[di(biphenylyl)triazinyl]phenyl}indolocarbazole; (terphenylyl){[(biphenylyl)phenyltriazinyl]phenyl}indolocarbazole; [(diphenyltriazinyl)phenyl]thiaazaindenofluorene; {[phenyl(biphenylyl)triazinyl]phenyl}thiaazaindenofluorene; {[di(biphenylyl)triazinyl]phenyl}thiaazaindenofluorene; {[bis(dimethylfluorenyl)triazinyl]phenyl}thiaazaindenofluorene; [(diphenyltriazinyl)phenyl]oxazaindenofluorene; {[phenyl(biphenylyl)triazinyl]phenyl}oxazaindenofluorene; {[di(biphenylyl)triazinyl]phenyl}oxazaindenofluorene; {[bis(dimethylfluorenyl)triazinyl]phenyl}oxazaindenofluorene; [(phenylpyridinyl)phenyl](diphenyltriazinyl)indolocarbazole; (terphenylyl)(diphenyltriazinyl)indolocarbazole; (terphenylyl)[(biphenylyl)phenyltriazinyl]indolocarbazole; phenyl(diphenyltriazinyl)dimethyldiazadiindenofluorene; (biphenylyl)(diphenyltriazinyl)dimethyldiazaindenofluorene; (biphenylyl)[(biphenylyl)phenyltriazinyl]dimethyldiazaindenofluorene; tetramethyl[(biphenylyl)phenyltriazinyl]azadiindenofluorene; tetramethyl[di(biphenylyl)triazinyl]azadiindenofluorene; [(biphenylyl)phenyltriazinyl]azadithiadiindenofluorene; [di(biphenylyl)triazinyl]azadithiadiindenofluorene; [(biphenylyl)phenyltriazinyl]azadithiadiindenofluorene; [(biphenylyl)phenyltriazinyl]azadioxydiindenofluorene; [di(biphenylyl)triazinyl]azadithiadiindenofluorene; [di(biphenylyl)triazinyl]azadioxydiindenofluorene

### (Group 14A)

(biphenylyl)(diphenyltriazinyl)carbazole; iridium(III)bis[(dimethylphenyl)isobutylquinoline](acetylacetonate); phenyl(diphenyltriazinyl)indolocarbazole; iridium(III)bis(phenylmethyl-d₃pyridine)(diphenylmethyl-d₃pyridine); (biphenylyl)(diphenyltriazinyl)carbazole; (terphenylyl)(diphenyltriazinyl)carbazole; triphenyl(diphenyltriazinyl)carbazole; (biphenylyl)[phenyl(biphenylyl)triazinyl]carbazole; diphenyl[phenyl(biphenylyl)triazinyl]carbazole; (biphenylyl)[(diphenyltriazinyl)phenyl]carbazole; phenyl[di(biphenylyl)triazinyl]carbazole; diphenyl[(diphenyltriazinyl)phenyl]carbazole; diphenyl[di(biphenylyl)triazinyl]carbazole; phenyl{[di(biphenylyl)triazinyl]phenyl}carbazole; di(biphenylyl)(diphenyltriazinyl)carbazole; (dimethylfluorenyl)(diphenyltriazinyl)carbazole; [(dimethylfluorenyl)phenyl](diphenyltriazinyl)carbazole; (dimethylfluorenyl)[phenyl(biphenylyl)triazinyl]carbazole; [(dimethylfluorenyl)phenyl][phenyl(biphenylyl)triazinyl]carbazole; (dimethylfluorenyl)[di(biphenylyl)triazinyl]carbazole; (phenylcarbazolyl)(diphenyltriazinyl)carbazole; (triphenylenyl)[phenyl(biphenylyl)triazinyl]carbazole; (phenylcarbazolyl)[phenyl(biphenylyl)triazinyl]carbazole; phenyl[phenyl(dimethylfluorenyl)triazinyl]carbazole; (triphenylenyl)(diphenyltriazinyl)carbazole; (biphenylyl)[phenyl(dimethylfluorenyl)triazinyl]carbazole; (terphenylyl)[phenyl(dimethylfluorenyl)triazinyl]carbazole; (quaterphenylyl)[phenyl(biphenylyl)triazinyl]carbazole; phenyl[(biphenylyl)(dimethylfluorenyl)triazinyl]carbazole; [(terphenylyl)phenyl](diphenyltriazinyl)carbazole; phenyl[bis(dimethylfluorenyl)triazinyl]carbazole; [(terphenylyl)phenyl][phenyl(biphenylyl)triazinyl]carbazole; (terphenylyl)(diphenyltriazinyl)carbazole; (biphenylyl)(diphenyltriazinyl)carbazole; (biphenylyl)[phenyl(biphenylyl)triazinyl]carbazole; (biphenylyl)[di(biphenylyl)triazinyl]carbazole; (terphenylyl)(diphenyltriazinyl)carbazole; (terphenylyl)(diphenyltriazinyl)carbazole; (biphenylyl)(diphenyltriazinyl)carbazole; (terphenylyl)[phenyl(biphenylyl)triazinyl]carbazole; (biphenylyl)[phenyl(biphenylyl)triazinyl]carbazole; (terphenylyl)[di(biphenylyl)triazinyl]carbazole; (terphenylyl)(diphenyltriazinyl)carbazole; (terphenylyl)[phenyl(biphenylyl)triazinyl]carbazole; (terphenylyl)[phenyl(biphenylyl)triazinyl]carbazole; phenyl[(biphenylyl)(biphenylyl)triazinyl]carbazole; phenyl[(biphenylyl)phenyltriazinyl]carbazole; (biphenylyl)[phenyl(biphenylyl)triazinyl]carbazole; (biphenylyl)[(biphenylyl)(biphenylyl)triazinyl]carbazole; phenyl[di(biphenylyl)triazinyl]carbazole; (biphenylyl)[phenyl(dimethylfluorenyl)triazinyl]carbazole; (dimethylfluorenyl)[(biphenylyl)phenyltriazinyl]carbazole; (biphenylyl){phenyl[(dimethylfluorenyl)phenyl]triazinyl}carbazole; [(dimethylfluorenyl)phenyl][phenyl(biphenylyl)triazinyl]carbazole; iridium(III)bis[(dimethylphenyl)quinoline](acetylacetonate); iridium(III)bis[(dimethylphenyl)quinoline](diethylnonanedionate); iridium(III)bis[(dimethylphenyl)quinoline](dimethylheptanedionate); iridium(III)bis[(dimethylphenyl)isobutylquinoline](dimethylheptanedionate); iridium(III)bis[(dimethylphenyl)quinoline](dimethylnonanedionate); iridium(III)bis[(dimethylphenyl)isobutylquinoline](dimethylnonanedionate); iridium(III)bis[(dimethylphenyl)isobutylquinoline](acetylacetonate); iridium(III)bis[(dimethylphenyl)isobutylquinoline](acetylacetonate); iridium(III)bis[(dimethylphenyl)isobutylquinoline](diethylnonanedionate); iridium(III)bis[(dimethylphenyl)isobutylquinoline](diethylnonanedionate); iridium(III)bis[(dimethylphenyl)isobutylquinoline](dimethylheptanedionate); iridium(III)bis[(dimethylphenyl)isobutylquinoline](diethylnonanedionate); iridium(III)bis[(dimethylphenyl)isobutylquinoline](dimethylnonanedionate); iridium(III)bis[(dimethylphenyl)isobutylquinoline](dimethylheptanedionate); iridium(III)bis[(dimethylphenyl)isobutylquinoline](acetylacetonate); iridium(III)bis[(dimethylphenyl)isobutylquinoline](dimethylnonanedionate); iridium(III)bis[(dimethylphenyl)cyclopentylquinoline](acetylacetonate); iridium(III)bis[(dimethylphenyl)cyclopentylquinoline](acetylacetonate); iridium(III)bis[(dimethylphenyl)cyclopentylquinoline](diethylnonanedionate); iridium(III)bis[(dimethylphenyl)cyclopentylquinoline](diethylnonanedionate); iridium(III)bis[(dimethylphenyl)cyclopentylquinoline](dimethylheptanedionate); iridium(III)bis[(dimethylphenyl)cyclopentylquinoline](dimethylheptanedionate); iridium(III)bis[(dimethylphenyl)cyclopentylquinoline](dimethylnonanedionate); iridium(III)bis[(dimethylphenyl)cyclopentylquinoline](dimethylnonanedionate); iridium(III)bis[(dimethylphenyl)cyclopentylquinoline](acetylacetonate); iridium(III)bis[(dimethylphenyl)cyclopentylquinoline](dimethylnonanedionate); iridium(III)bis[(dimethylphenyl)cyclopentylquinoline](diethylnonanedionate); iridium(III)bis[(dimethylphenyl)isopropylquinoline](acetylacetonate); iridium(III)bis[(dimethylphenyl)isopropylquinoline](diethylnonanedionate); iridium(III)bis[(dimethylphenyl)cyclopentylquinoline](dimethylheptanedionate); iridium(III)bis[(dimethylphenyl)isopropylquinoline](dimethylheptanedionate); iridium(III)bis[(dimethylphenyl)isopropylquinoline](dimethylnonanedionate); iridium(III)bis[(dimethylphenyl)isopropylquinoline](dimethylnonanedionate); iridium(III)bis[(dimethylphenyl)isopropylquinoline](acetylacetonate); iridium(III)bis[(dimethylphenyl)isopropylquinoline](acetylacetonate); iridium(III)bis[(dimethylphenyl)isopropylquinoline](diethylnonanedionate); iridium(III)bis[(dimethylphenyl)isopropylquinoline](diethylnonanedionate); iridium(III)bis[(dimethylphenyl)isopropylquinoline](diethylpentanedionate); iridium(III)bis[(dimethylphenyl)isopropylquinoline](diethylpentanedionate); iridium(III)bis[(dimethylphenyl)isopropylquinoline](diethylnonanedionate); iridium(III)bis(phenylpyridine)(diphenylpyridine); iridium(III)bis(phenylpyridine)[phenyl(methylphenyl)pyridine); iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(ethylfluorophenyl)pyridine]; iridium(III)bis(phenylpyridine)[phenyl(fluorophenyl)pyridine]; iridium(III)bis(phenylpyridine)[phenyl(isopropylfluorophenyl)pyridine]; iridium(III)bis(phenylpyridine)[phenyl(methylfluorophenyl)pyridine]; iridium(III)bis(phenylpyridine)[phenyl(isobutylfluorophenyl)pyridine]; iridium(III)bis(phenylpyridine)(diphenylpyridine); iridium(III)bis(phenylpyridine)[phenyl(isobutylphenyl)pyridine]; iridium(III)bis(phenylpyridine)[phenyl(methylphenyl)pyridine]; iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(isobutylphenyl)pyridine]; iridium(III)bis(phenylpyridine)[phenyl(isopropylfluorophenyl)pyridine]iridium(III)bis(phenylpyridine)[phenyl(fluor ophenyl)pyridine]; iridium(III)bis(phenylpyridine)[phenyl(isobutylfluorophenyl)pyridine]iridium(III)bis(phenylpyridine)[phenyl(methy lfluorophenyl)pyridine]; iridium(III)bis(phenylpyridine)[diphenylpyridine]iridium(III)bis(phenylpyridine)[phenyl(ethylfluorophenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(methylfluorophenyl)pyridine]; iridium(III)bis(phenylmethylpyridine)[phenyl(isopropylphenyl)pyridine]; iridium(III)bis(phenylmethylpyridine)[phenyl(ethylfluorophenyl)pyridine]; iridium(III)bis(phenylmethylpyridine)[phenyl(fluorophenyl)pyridine]; iridium(III)bis(phenylmethylpyridine)[phenyl(isopropylfluorophenyl)pyridine]; iridium(III)bis(phenylmethylpyridine)[phenyl(isobutylfluorophenyl)pyridine]; iridium(III)bis(phenylmethylpyridine)[phenyl(isopropylphenyl)pyridine]; iridium(III)bis(phenylmethylpyridine)[diphenylpyridine]; iridium(III)bis(phenylmethylpyridine)[phenyl(isobutylphenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(isopropylphenyl)pyridine]; iridium(III)bis(phenylmethylpyridine)[phenyl(ethylfluorophenyl)pyridine]; iridium(II)bis(phenylmethylpyridine)[phenyl(isobutylphenyl)pyridine]; iridium(III)bis(phenylmethylpyridine)[phenyl(isopropylfluorophenyl)pyridine]; iridium(III)bis(phenylmethylpyridine)[phenyl(fluorophenyl)pyridine]; iridium(II)bis(phenylmethylpyridine)[phenyl(isobutylfluorophenyl)pyridine]; iridium(III)bis(phenylmethylpyridine)[phenyl(methylfluorophenyl)pyridine]; iridium(III)bis(phenylpyridine)[phenyl((methyl-d₃)phenyl)pyridine]; iridium(III)bis(phenylpyridine)[phenyl((ethyl-d₅)phenyl)pyridine]; iridium(III)bis(phenylpyridine)[phenyl((ethyl-d₅)fluorophenyl)pyridine]; iridium(III)bis(phenylpyridine)[phenyl((isopropyl-d₇)phenyl)pyridine]; iridium(III)bis(phenylpyridine)[phenyl((isopropyl-d₇)fluorophenyl)pyridine]; iridium(III)bis(phenylpyridine)[phenyl((methyl-d₃)fluorophenyl)pyridine]; iridium(III)bis(phenylpyridine)[phenyl((isobutyl-d₉)fluorophenyl)pyridine]; iridium(III)bis(phenylpyridine)[phenyl(dimethyl-d₆)phenyl)pyridine]; iridium(III)bis(phenylpyridine)[phenyl((isobutyl-d₉)phenyl)pyridine]; iridium(III)bis(phenylpyridine)[phenyl((methyl-d₃)phenyl)pyridine]; iridium(III)bis(phenylpyridine)[phenyl((ethyl-d₆)phenyl)pyridine]; iridium(III)bis(phenylpyridine)[phenyl((isopropyl-d₇)phenyl)pyridine]; iridium(III)bis(phenylpyridine)[phenyl((isobutyl-d₉)phenyl)pyridine]; iridium(III)bis(phenylpyridine)[phenyl((isobutyl-d₉)fluorophenyl)pyridine]; iridium(III)bis(phenylpyridine)[phenyl((methyl-d₃)fluorophenyl)pyridine]; iridium(III)bis(phenyl(methyl-d₃)pyridine)[diphenylpyridine]; iridium(III)bis(phenylpyridine)[phenyl((ethyl-d₅)fluorophenyl)pyridine]; iridium(III)bis(phenyl(methyl-d₃)pyridine)[phenyl((methyl-d₃)phenyl)pyridine]; iridium(III)bis(phenylpyridine)[phenyl((isopropyl-d₇)fluorophenyl)pyridine]; iridium(III)bis(phenyl(methyl-d₃)pyridine)[phenyl((ethyl-d₅)phenyl)pyridine]; iridium(III)bis(phenyl(methyl-d₃)pyridine)[phenyl((isopropyl-d₇)phenyl)pyridine]; iridium(III)bis(phenyl(methyl-d₃)pyridine)[phenyl((isopropyl-d₇)fluorophenyl)pyridine]; iridium(III)bis(phenyl(methyl-d₃)pyridine)[phenyl((methyl-d₃)fluorophenyl)pyridine]; iridium(III)bis(phenyl(methyl-d₃)pyridine)[phenyl((isobutyl-d₉)fluorophenyl)pyridine]; iridium(II)bis(phenyl(methyl-d₃)pyridine)[phenyl((ethyl-d₅)fluorophenyl)pyridine]; iridium(III)bis(phenyl(methyl-d₃)pyridine)[phenyl(fluorophenyl)pyridine]; iridium(III)bis(phenyl(methyl-d₃)pyridine)[diphenylpyridine]; iridium(III)bis(phenyl(methyl-d₃)pyridine)[phenyl((isobutyl-d₉)phenyl)pyridine]; iridium(III)bis(phenyl(methyl-d₃)pyridine)[phenyl((methyl-d₃)phenyl)pyridine]; iridium(III)bis(phenyl(methyl-d₃)pyridine)[phenyl((ethyl-d₅)phenyl)pyridine]; iridium(III)bis(phenyl(methyl-d₃)pyridine)[phenyl((isopropyl-d₇)phenyl)pyridine]; iridium(III)bis(phenyl(methyl-d₃)pyridine)[phenyl((isobutyl-de)phenyl)pyridine]; iridium(III)bis(phenyl(methyl-d₃)pyridine)[phenyl((isopropyl-d₇)fluorophenyl)pyridine]; iridium(III)bis(phenyl(methyl-d₃)pyridine)[phenyl(fluorophenyl)pyridine]; iridium(III)bis(phenyl(methyl-d₃)pyridine)[phenyl((isobutyl-d₉)fluorophenyl)pyridine]; iridium(III)bis(phenyl(methyl-d₃)pyridine)[phenyl((methyl-d₃)fluorophenyl)pyridine]; iridium(III)bis(phenylpyridine)[phenylbipyridine]; iridium(III)bis(phenyl(methyl-d₃)pyridine)[phenyl((ethyl-d₅)fluorophenyl)pyridine]; iridium(III)bis(phenylpyridine)[phenylbipyridine]; iridium(III)bis(phenylpyridine)[phenylbipyridine]; iridium(II)bis(phenylpyridine)[isobutylphenylbipyridine]; iridium(III)bis(phenylpyridine)[methylphenylbipyridine]; iridium(III)bis(phenylpyridine)[(phenylpyridinyl)pyrimidine]; iridium(III)bis(phenylpyridine)[ethylphenylbipyridine]; iridium(III)bis(phenylpyridine)[(phenylpyridinyl)pyrazine]; iridium(III)bis(phenylpyridine)[isopropylphenylbipyridine]; iridium(III)bis(phenylpyridine)[(phenylpyridinyl)pyrimidine]; iridium(III)bis(phenylpyridine)[(phenylpyridinyl)pyrimidine]; iridium(III)bis(phenylpyridine)[(phenylpyridinyl)dimethyltriazine]; iridium(III)bis(phenylpyridine)[(phenylpyridinyl)triazine]; iridium(III)bis(phenylpyridine)[phenylbipyridine]; iridium(III)bis(phenylpyridine)[methyl(phenylpyridinyl)pyrimidine]; iridium(III)bis(phenylpyridine)[phenylbipyridine]; iridium(III)bis(phenylpyridine)[methyl(phenylpyridinyl)pyrimidine]; iridium(III)bis(phenylpyridine)[phenylbipyridine]; iridium(III)bis(phenylpyridine)[methylphenylbipyridine]; iridium(III)bis(phenylpyridine)[(phenylpyridinyl)pyrimidine]; iridium(III)bis(phenylpyridine)[ethylphenylbipyridine]; iridium(III)bis(phenylpyridine)[(phenylpyridinyl)pyrazine]; iridium(III)bis(phenylpyridine)[isopropylphenylbipyridine]; iridium(III)bis(phenylpyridine)[(phenylpyridinyl)pyrimidine]; iridium(III)bis(phenylpyridine)[isobutylphenylbipyridine]; iridium(III)bis(phenylpyridine)[(phenylpyridinyl)pyrimidine]; iridium(III)bis(phenylpyridine)[(phenylpyridinyl)triazine]; iridium(III)bis(phenylpyridine)[(methyl-d₃)phenylbipyridine]; iridium(III)bis(phenylpyridine)[methyl(phenylpyridinyl)pyrimidine]; iridium(III)bis(phenylpyridine)[(ethyl-d₅)phenylbipyridine]; iridium(III)bis(phenylpyridine)[methyl(phenylpyridinyl)pyrimidine]; iridium(III)bis(phenylpyridine)[dimethyl(phenylpyridinyl)triazine]; iridium(III)bis(phenylpyridine)[(isopropyl-d₇)phenylbipyridine]; iridium(III)bis(phenylpyridine)[(isobutyl-d₉)phenylbipyridine]; iridium(III)bis(phenylpyridine)[(dimethyl-d₆)(phenylpyridinyl)triazine]; iridium(III)bis(phenylpyridine)[(methyl-d₃)(phenylpyridinyl)pyrimidine]; iridium(III)bis(phenylpyridine)[(methyl-d₃)phenylbipyridine]; iridium(III)bis(phenylpyridine)[(ethyl-d₅)phenylbipyridine]; iridium(III)bis(phenylpyridine)[(methyl-d₃)(phenylpyridinyl)pyrimidine]; iridium(III)bis(phenylpyridine)[(isopropyl-d₇)phenylbipyridine]; iridium(III)bis(phenylpyridine)[(isobutyl-d₉)phenylbipyridine]; iridium(III)bis(phenylmethylpyridine)(phenylbipyridine); iridium(III)bis(phenylpyridine)[(methyl-d₃)(phenylpyridinyl)pyrimidine]; iridium(III)bis(phenylmethylpyridine)(phenylbipyridine); iridium(III)bis(phenylpyridine)[(methyl-d₃)(phenylpyridinyl)pyrimidine]; iridium(III)bis(phenylmethylpyridine)(phenylbipyridine); iridium(III)bis(phenylpyridine)[(dimethyl-d₆)(phenylpyridinyl)triazine]; iridium(III)bis(phenylmethylpyridine)(methylphenylbipyridine); iridium(III)bis(phenylmethylpyridine)(ethylphenylbipyridine); iridium(III)bis(phenylmethylpyridine)[(phenylpyridinyl)pyrimidine]; iridium(III)bis(phenylmethylpyridine)(isopropylphenylbipyridine); iridium(III)bis(phenylmethylpyridine)[(phenylpyridinyl)pyrazine]; iridium(III)bis(phenylmethylpyridine)[(phenylpyridinyl)pyrimidine]; iridium(III)bis(phenylmethylpyridine)(isobutylphenylbipyridine); iridium(III)bis(phenylmethylpyridine)[(phenylpyridinyl)pyrimidine]; iridium(III)bis(phenylmethylpyridine)[(phenylpyridinyl)triazine]; iridium(III)bis(phenylmethylpyridine)(phenylbipyridine); iridium(III)bis(phenylmethylpyridine)[methyl(phenylpyridinyl)pyrimidine]; iridium(III)bis(phenylmethylpyridine)(phenylbipyridine); iridium(III)bis(phenylmethylpyridine)[methyl(phenylpyridinyl)pyrimidine]; iridium(III)bis(phenylmethylpyridine)(phenylbipyridine); iridium(III)bis(phenylpyridine)[dimethyl(phenylpyridinyl)triazine]; iridium(III)bis(phenylmethylpyridine)(methylphenylbipyridine); iridium(III)bis(phenylmethylpyridine)(ethylphenylbipyridine); iridium(III)bis(phenylmethylpyridine)[(phenylpyridinyl)pyrazine]; iridium(III)bis(phenylmethylpyridine)(isopropylphenylbipyridine); iridium(III)bis(phenylmethylpyridine)[(phenylpyridinyl)pyrimidine]; iridium(III)bis(phenylmethylpyridine)(isobutylphenylbipyridine); iridium(III)bis(phenylmethylpyridine)[(phenylpyridinyl)pyrimidine]; iridium(III)bis(phenylmethylpyridine)[(phenylpyridinyl)pyrimidine]; iridium(III)bis(phenylmethylpyridine)[(phenylpyridinyl)triazine]; iridium(III)bis(phenylmethylpyridine)[methyl(phenylpyridinyl)pyrimidine]; iridium(III)bis(phenylmethylpyridine)[(methyl-d₃)phenylbipyridine]; iridium(III)bis(phenylmethylpyridine)[methyl(phenylpyridinyl)pyrimidine]; iridium(III)bis(phenyl(methyl-d₃)pyridine)[(ethyl-d₅)phenylbipyridine]; iridium(III)bis(phenylmethylpyridine)[dimethyl(phenylpyridinyl)triazine]; iridium(III)bis[phenyl(methyl-d₃)pyridine][phenylbipyridine]; iridium(III)bis[phenyl(methyl-d₃)pyridine][(isopropyl-d₇)phenylbipyridine]; iridium(III)bis[phenyl(methyl-d₃)pyridine][(isobutyl-d₉)phenylbipyridine]; iridium(III)bis(phenyl(methyl-d₃)pyridine)[(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(phenylpyridinyl)triazine]; iridium(III)bis(phenyl(methyl-d₃)pyridine)[(phenylpyridinyl)pyrazine]; iridium(III)bis(phenyl(methyl-d₃)pyridine)[(methyl-d₃)(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(methyl-d₃)(phenylpyridinyl)pyrimidine]; iridium(III)bis(phenyl(methyl-d₃)pyridine)[(dimethyl-d₆)(phenylpyridinyl)triazine]; iridium(III)bis[phenyl(methyl-d₃)pyridine][(isopropyl-d₉)phenylbipyridine]; iridium(III)bis[phenyl(methyl-d₃)pyridine][phenylbipyridine]; iridium(III)bis[phenyl(methyl-d₃)pyridine][(isobutyl-de)phenylbipyridine]; iridium(III)bis[phenyl(methyl-d₃)pyridine][(methyl-d₃)phenylbipyridine]; iridium(III)bis(phenyl(methyl-d₃)pyridine)[(phenylpyridinyl)pyrimidine]; iridium(III)bis[phenyl(methyl-d₃)pyridine][(ethyl-d₇)phenylbipyridine]; iridium(III)bis(phenyl(methyl-d₃)pyridine)[(phenylpyridinyl)pyrazine]; iridium(III)bis(phenyl(methyl-d₃)pyridine)[(phenylpyridinyl)pyrimidine]; iridium(III)bis(phenyl(methyl-d₃)pyridine)[(phenylpyridinyl)pyrimidine]; iridium(III)bis(phenyl(methyl-d₃)pyridine)[(phenylpyridinyl)triazine]; iridium(III)bis(phenyl(methyl-d₃)pyridine)[(methyl-d₃)(phenylpyridinyl)pyrimidine]; iridium(III)bis(phenyl(methyl-d₃)pyridine)[(methyl-d₃)(phenylpyridinyl)pyrimidine]; iridium(III)bis(phenyl(methyl-d₃)pyridine)[(dimethyl-d₆)(phenylpyridinyl)triazine]; (biphenylyl)(diphenyltriazinyl)indolocarbazole; phenyl[(biphenylyl)phenyltriazinyl]indolocarbazole; [(biphenylyl)phenyltriazinyl]oxazaindenofluorene; [(biphenylyl)phenyltriazinyl]thiaazaindenofluorene; [(dimethylfluorenyl)phenyltriazinyl]thiaazaindenofluorene; [diphenyltriazinyl]thiaazaindenofluorene; phenyl[(dimethylfluorenyl)phenyltriazinyl]indolocarbazole; phenyl(dimethyltriazinyl)indolocarbazole; phenyl[phenyl(terphenylyl)triazinyl]indolocarbazole; (diphenyltriazinyl)azaoxaindenofluorene; [(biphenylyl)phenyltriazinyl)azaoxaindenofluorene; (diphenyltriazinyl)thiaazaindenofluorene; [(dimethylfluorenyl)phenyltriazinyl]thiaazaindenofluorene; [(biphenylyl)phenyltriazinyl]thiaazaindenofluorene; [(dimethylfluorenyl)phenyltriazinyl]azaoxaindenofluorene; phenyl[(dimethylfluorenyl)phenyltriazinyl]indolocarbazole; phenyl[(biphenylyl)phenyltriazinyl]indolocarbazole; phenyl(diphenyltriazinyl)indolocarbazole; phenyl[(dimethylfluorenyl)phenyltriazinyl]indolocarbazole; (biphenylyl)(diphenyltriazinyl)indolocarbazole; (diphenyltriazinyl)thiaazaindenofluorene; [(biphenylyl)phenyltriazinyl]thiaazaindenofluorene; [(biphenylyl)phenyltriazinyl]azaoxaindenofluorene; [(dimethylfluorenyl)phenyltriazinyl]thiaazaindenofluorene; [(dimethylfluorenyl)phenyltriazinyl]azaoxaindenofluorene; (diphenyltriazinyl)azaoxaindenofluorene; (diphenyltriazinyl)dimethylazaindenofluorene; [(biphenylyl)phenyltriazinyl]dimethylazaindenofluorene; (diphenyltriazinyl)phenylindolocarbazole; [(dimethylfluorenyl)phenyltriazinyl]dimethylazaindenofluorene; [(biphenylyl)phenyltriazinyl]phenylindolocarbazole; (diphenyltriazinyl)phenylindolocarbazole; (dimethylfluorenyl)phenylindolocarbazole; (diphenyltriazinyl)azathiaindenofluorene; (diphenyltriazinyl)azaoxaindenofluorene; [(biphenylyl)phenyltriazinyl]azathiaindenofluorene; [(biphenylyl)phenyltriazinyl]azaoxaindenofluorene; [(dimethylfluorenyl)phenyltriazinyl]azathiaindenofluorene; [(dimethylfluorenyl)phenyltriazinyl]azaoxaindenofluorene; phenyl(diphenyltriazinyl)indolocarbazole; [(biphenylyl)phenyltriazinyl]azathiaindenofluorene; phenyl[(biphenylyl)phenyltriazinyl]indolocarbazole; [(dimethylfluorenyl)phenyltriazinyl]azathiaindenofluorene; phenyl[(dimethylfluorenyl)phenyltriazinyl]indolocarbazole; (diphenyltriazinyl)azathiaindenofluorene; (diphenyltriazinyl)azathiaindenofluorene; [(biphenylyl)phenyltriazinyl]azaoxaindenofluorene; [(dimethylfluorenyl)phenyltriazinyl]azaoxaindenofluorene; [(diphenyltriazinyl)phenyl]thiaazaindenofluorene; phenyl[(diphenyltriazinyl)phenyl]indolocarbazole; [(diphenyltriazinyl)phenyl]oxazaindenofluorene; phenyl{[(dimethylfluorenyl)phenyltriazinyl]phenyl}indolocarbazole; phenyl[(diphenyltriazinyl)phenyl]dimethyldiazaindenofluorene; iridium(III)bis(phenylpyridine)(diphenylmethylpyridine); iridium(III)bis(phenylpyridine)(diphenylethylpyridine); iridium(III)bis(phenylpyridine)(diphenylisopropylpyridine); iridium(III)bis(phenylpyridine)[phenylmethyl(fluorophenyl)pyridine]; iridium(III)bis(phenylpyridine)[phenylethyl(fluorophenyl)pyridine]; iridium(III)bis(phenylpyridine)[phenylisopropyl(fluorophenyl)pyridine]; iridium(III)bis(phenylpyridine)[phenyl(methylphenyl)pyridine]; iridium(III)bis(phenylpyridine)[phenyl(ethylphenyl)pyridine]; iridium(III)bis(phenylpyridine)[phenyl(isopropylphenyl)pyridine]; iridium(III)bis(phenylpyridine)[phenyl(methylfluorophenyl)pyridine]; iridium(III)bis(phenylmethylpyridine)(diphenylmethylpyridine); iridium(III)bis(phenylmethylpyridine)(diphenylethylpyridine); iridium(III)bis(phenylmethylpyridine)(diphenylisopropylpyridine); iridium(III)bis(phenylmethylpyridine)[phenylmethyl(fluorophenyl)pyridine]; iridium(III)bis(phenylmethylpyridine)[phenylethyl(fluorophenyl)pyridine]; iridium(III)bis(phenylmethylpyridine)[phenylisopropyl(fluorophenyl)pyridine]; iridium(III)bis(phenylmethylpyridine)[phenyl(methylphenyl)pyridine]; iridium(III)bis(phenylmethylpyridine)[phenyl(ethylphenyl)pyridine]; iridium(III)bis(phenylmethylpyridine)[phenyl(isopropylphenyl)pyridine]; iridium(III)bis(phenylmethylpyridine)[phenyl(methylfluorophenyl)pyridine]; iridium(III)bis(phenylmethylpyridine)[diphenyl(methyl-d₃)pyridine]; iridium(III)bis(phenylpyridine)[diphenyl(ethyl-d₅)pyridine]; iridium(III)bis(phenylpyridine)[diphenyl(isopropyl-d₇)pyridine]; iridium(III)bis(phenylpyridine)[phenyl(methyl-d₃)(fluorophenyl)pyridine]; iridium(III)bis(phenylpyridine)[phenyl(ethyl-d₅)(fluorophenyl)pyridine]; iridium(III)bis(phenylpyridine)[phenyl(isopropyl-d₇)(fluorophenyl)pyridine]; iridium(III)bis(phenylpyridine){phenyl[(methyl-d₃)phenyl]pyridine}; iridium(III)bis(phenylpyridine){phenyl[(ethyl-d₅)phenyl]pyridine}; iridium(III)bis(phenylpyridine){phenyl[(isopropyl-d₇)phenyl]pyridine}; iridium(III)bis(phenylpyridine){phenyl[(methyl-d₃)fluorophenyl]pyridine}; iridium(III)bis[phenyl(methyl-d₃)pyridine][diphenyl(methyl-d₃)pyridine]; iridium(III)bis[phenyl(methyl-d₃)pyridine][diphenyl(ethyl-d₅)pyridine]; iridium(III)bis[phenyl(methyl-d₃)pyridine][diphenyl(isopropyl-d₇)pyridine]; iridium(III)bis[phenyl(methyl-d₃)pyridine][phenyl(methyl-d₃)(fluorophenyl)pyridine]; iridium(III)bis[phenyl(methyl-d₃)pyridine][phenyl(ethyl-d₅)(fluorophenyl)pyridine]; iridium(III)bis[phenyl(methyl-d₃)pyridine][phenyl(isopropyl-d₇)(fluorophenyl)pyridine]; iridium(III)bis[phenyl(methyl-d₃)pyridine]{phenyl[(methyl-d₃)phenyl]pyridine}; iridium(III)bis[phenyl(methyl-d₃)pyridine]{phenyl[(ethyl-d₅)phenyl]pyridine}; iridium(III)bis[phenyl(methyl-d₃)pyridine]{phenyl[(isopropyl-d₇)phenyl]pyridine}; iridium(III)bis[phenyl(methyl-d₃)pyridine]{phenyl[(methyl-d₃)fluorophenyl]pyridine}

### (Group 15A)

(diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (diphenyltriazinyl)[(biphenylyl)dibenzofuranyl]biphenyl; (diphenyltriazinyl)[(biphenylyl)dibenzoselenophenyl]biphenyl; (diphenyltriazinyl)[(biphenylyl)dibenzoselenophenyl]biphenyl; (diphenyltriazinyl)(phenyldibenzofuranyl)terbenzene; (diphenyltriazinyl)(phenyldibenzothiophenyl)terbenzene; (diphenyltriazinyl)(phenyldibenzoselenophenyl)terbenzene; (diphenyltriazinyl)(phenyldibenzofuranyl)terbenzene; (diphenyltriazinyl)(phenyldibenzothiophenyl)terbenzene; (diphenyltriazinyl)(phenyldibenzoselenophenyl)terbenzene; (diphenyltriazinyl)[(biphenylyl)dibenzofuranyl]terbenzene; (diphenyltriazinyl)[(biphenylyl)dibenzothiophenyl]terbenzene; (diphenyltriazinyl)[(biphenylyl)dibenzoselenophenyl]terbenzene; [(biphenylyl)phenyltriazinyl](dibenzofuranyl)biphenyl; [(biphenylyl)phenyltriazinyl](dibenzothiophenyl)biphenyl; [(biphenylyl)phenyltriazinyl](dibenzoselenophenyl)biphenyl; [(biphenylyl)phenyltriazinyl](dibenzofuranyl)biphenyl; [(biphenylyl)phenyltriazinyl](dibenzothiophenyl)biphenyl; [(biphenylyl)phenyltriazinyl](dibenzoselenophenyl)biphenyl; [di(biphenylyl)triazinyl](dibenzofuranyl)biphenyl; [di(biphenylyl)triazinyl](dibenzothiophenyl)biphenyl; [di(biphenylyl)triazinyl](dibenzoselenophenyl)biphenyl; [(dimethylfluorenyl)phenyltriazinyl](dibenzofuranyl)biphenyl; [(dimethylfluorenyl)phenyltriazinyl](dibenzothiophenyl)biphenyl; [(dimethylfluorenyl)phenyltriazinyl](dibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(dimethylfluorenyl)phenyltriazinyl](phenyldibenzofuranyl)biphenyl; [(dimethylfluorenyl)phenyltriazinyl](phenyldibenzofuranyl)biphenyl; [(dimethylfluorenyl)phenyltriazinyl](phenyldibenzofuranyl)biphenyl; [(biphenylyl)phenyltriazinyl](dibenzofuranyl)terbenzene; [(biphenylyl)phenyltriazinyl](dibenzothiophenyl)terbenzene; [(biphenylyl)phenyltriazinyl](dibenzoselenophenyl)terbenzene; [(biphenylyl)phenyltriazinyl](dibenzofuranyl)terbenzene; [(biphenylyl)phenyltriazinyl](dibenzothiophenyl)terbenzene; [(biphenylyl)phenyltriazinyl](dibenzoselenophenyl)terbenzene; [(dimethylfluorenyl)phenyltriazinyl](dibenzofuranyl)terbenzene; [(dimethylfluorenyl)phenyltriazinyl](dibenzofuranyl)terbenzene; [(dimethylfluorenyl)phenyltriazinyl](dibenzofuranyl)terbenzene; [(biphenylyl)phenyltriazinyl][(biphenylyl)dibenzofuranyl]biphenyl; [(biphenylyl)phenyltriazinyl][(biphenylyl)dibenzothiophenyl]biphenyl; [(biphenylyl)phenyltriazinyl][(biphenylyl)dibenzoselenophenyl]biphenyl; [(biphenylyl)phenyltriazinyl][(biphenylyl)dibenzofuranyl]biphenyl; [(biphenylyl)phenyltriazinyl][(biphenylyl)dibenzothiophenyl]biphenyl; [(biphenylyl)phenyltriazinyl][(biphenylyl)dibenzoselenophenyl]biphenyl; [(dimethylfluorenyl)phenyltriazinyl][(biphenylyl)dibenzofuranyl]biphenyl; [(dimethylfluorenyl)phenyltriazinyl][(biphenylyl)dibenzothiophenyl]biphenyl; [(dimethylfluorenyl)phenyltriazinyl][(biphenylyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (diphenyltriazinyl)(dibenzoselenophenyl)terbenzene; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(pyridinyl)(phenyldibenzofuranyl)benzene; (diphenyltriazinyl)(pyridinyl)(phenyldibenzothiophenyl)benzene; (diphenyltriazinyl)(pyridinyl)(phenyldibenzoselenophenyl)benzene; (diphenyltriazinyl)(pyridinyl)(phenyldibenzofuranyl)benzene; (diphenyltriazinyl)(pyridinyl)(phenyldibenzothiophenyl)benzene; (diphenyltriazinyl)(pyridinyl)(phenyldibenzoselenophenyl)benzene; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)[spiro(cyclopentanefluorenyl)]biphenyl; (diphenyltriazinyl)(dimethylfluorenyl)terbenzene; (diphenyltriazinyl)(diphenylfluorenyl)biphenyl; [(diphenylyl)phenyltriazinyl](dimethylfluorenyl)biphenyl; [(dimethylfluorenyl)phenyltriazinyl](dimethylfluorenyl)terbenzene; (diphenyltriazinyl)di(dimethylfluorenyl)benzene; (diphenyltriazinyl)(dimethylfluorenyl)terbenzene; (diphenyltriazinyl)phenyldibenzofuran; (diphenyltriazinyl)phenyldibenzothiophene; (diphenyltriazinyl)phenyldibenzoselenophene; [(biphenylyl)phenyltriazinyl]phenyldibenzofuran; [(biphenylyl)phenyltriazinyl]phenyldibenzothiophene; [(biphenylyl)phenyltriazinyl]phenyldibenzoselenophene; [(biphenylyl)phenyltriazinyl]phenyldibenzofuran; [(biphenylyl)phenyltriazinyl]phenyldibenzothiophene; [(biphenylyl)phenyltriazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; [di(biphenylyl)triazinyl]phenyldibenzofuran; [di(biphenylyl)triazinyl]phenyldibenzothiophene; [di(biphenylyl)triazinyl]phenyldibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [(biphenylyl)phenyltriazinyl](phenyldibenzofuranyl)benzene; [(biphenylyl)phenyltriazinyl](phenyldibenzothiophenyl)benzene; [(biphenylyl)phenyltriazinyl](phenyldibenzoselenophenyl)benzene; [(biphenylyl)phenyltriazinyl](phenyldibenzofuranyl)benzene; [(biphenylyl)phenyltriazinyl](phenyldibenzothiophenyl)benzene; [(biphenylyl)phenyltriazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; [(biphenylyl)phenyltriazinyl](phenyldibenzofuranyl)biphenyl; [(biphenylyl)phenyltriazinyl](phenyldibenzothiophenyl)biphenyl; [(biphenylyl)phenyltriazinyl](phenyldibenzoselenophenyl)biphenyl; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(biphenylyl)phenyltriazinyl]dibenzofuran; (biphenylyl)[(biphenylyl)phenyltriazinyl]dibenzothiophene; (biphenylyl)[(biphenylyl)phenyltriazinyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[phenyl(biphenylyl)triazinyl]phenyl}dibenzofuran; (biphenylyl){[phenyl(biphenylyl)triazinyl]phenyl}dibenzothiophene; (biphenylyl){[phenyl(biphenylyl)triazinyl]phenyl}dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; (biphenylyl){[(biphenylyl)phenyltriazinyl]phenyl}dibenzofuran; (biphenylyl){[(biphenylyl)phenyltriazinyl]phenyl}dibenzothiophene; (biphenylyl){[(biphenylyl)phenyltriazinyl]phenyl}dibenzoselenophene; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; (biphenylyl)(dimethylfluorenyl)(phenyldibenzofuranyl)triazine; (biphenylyl)(dimethylfluorenyl)(phenyldibenzothiophenyl)triazine; (biphenylyl)(dimethylfluorenyl)(phenyldibenzoselenophenyl)triazine; (biphenylyl)(dimethylfluorenyl)(phenyldibenzofuranyl)triazine; (biphenylyl)(dimethylfluorenyl)(phenyldibenzothiophenyl)triazine; (biphenylyl)(dimethylfluorenyl)(phenyldibenzoselenophenyl)triazine; phenyl(dimethylfluorenyl)[(phenyldibenzofuranyl)phenyl]triazine; phenyl(dimethylfluorenyl)[(phenyldibenzothiophenyl)phenyl]triazine; phenyl(dimethylfluorenyl)[(phenyldibenzoselenophenyl)phenyl]triazine; bis(dimethylfluorenyl)[(phenyldibenzofuranyl)phenyl]triazine; bis(dimethylfluorenyl)[(phenyldibenzothiophenyl)phenyl]triazine; bis(dimethylfluorenyl)[(phenyldibenzoselenophenyl)phenyl]triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzoselenophenyl](dimethylfluorenyl)triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzoselenophenyl](dimethylfluorenyl)triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl[(dimethylfluorenyl)phenyl](phenyldibenzofuranyl)triazine; phenyl[(dimethylfluorenyl)phenyl](phenyldibenzothiophenyl)triazine; phenyl[(dimethylfluorenyl)phenyl](phenyldibenzoselenophenyl)triazine; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)dibenzofuranyl](dimethylfluorenyl)triazine; phenyl(dimethylfluorenyl){[(biphenylyl)dibenzofuranyl]phenyl}triazine; phenyl(dimethylfluorenyl){[(biphenylyl)dibenzothiophenyl]phenyl}triazine; phenyl(dimethylfluorenyl){[(biphenylyl)dibenzoselenophenyl]phenyl}triazine; phenyl[(dimethylfluorenyl)phenyl](phenyldibenzofuranyl)triazine; phenyl[(dimethylfluorenyl)phenyl](phenyldibenzothiophenyl)triazine; phenyl[(dimethylfluorenyl)phenyl](phenyldibenzoselenophenyl)triazine; phenyl(dimethylfluorenyl)(phenyldibenzofuranyl)triazine; phenyl(dimethylfluorenyl)(phenyldibenzothiophenyl)triazine; phenyl(dimethylfluorenyl)(phenyldibenzoselenophenyl)triazine; phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (diphenyltriazinyl)phenyldibenzofuran; (diphenyltriazinyl)phenyldibenzothiophene; (diphenyltriazinyl)phenyldibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; [(diphenyltriazinyl)phenyl](biphenylyl)dibenzofuran; [(diphenyltriazinyl)phenyl](biphenylyl)dibenzothiophene; [(diphenyltriazinyl)phenyl](biphenylyl)dibenzoselenophene; [(diphenyltriazinyl)phenyl](biphenylyl)dibenzofuran; [(diphenyltriazinyl)phenyl](biphenylyl)dibenzothiophene; [(diphenyltriazinyl)phenyl](biphenylyl)dibenzoselenophene; [(diphenyltriazinyl)phenyl]phenyldibenzofuran; [(diphenyltriazinyl)phenyl]phenyldibenzothiophene; [(diphenyltriazinyl)phenyl]phenyldibenzoselenophene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; {[phenyl(phenylpyridinyl)triazinyl]phenyl}phenyldibenzofuran; {[phenyl(phenylpyridinyl)triazinyl]phenyl}phenyldibenzothiophene; {[phenyl(phenylpyridinyl)triazinyl]phenyl}phenyldibenzoselenophene; (diphenyltriazinyl)[(biphenylyl)dibenzofuranyl]pyridine; (diphenyltriazinyl)[(biphenylyl)dibenzothiophenyl]pyridine; (diphenyltriazinyl)[(biphenylyl)dibenzoselenophenyl]pyridine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenyldibenzoselenophenyl)triazine; (biphenylyl)(dimethylindenopyridinyl)(phenyldibenzofuranyl)triazine; (biphenylyl)(dimethylindenopyridinyl)(phenyldibenzothiophenyl)triazine; (biphenylyl)(dimethylindenopyridinyl)(phenyldibenzoselenophenyl)triazine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenyldibenzoselenophenyl)triazine; phenyl(spiro[cyclohexanefluorene]yl)(phenyldibenzofuranyl)triazine; phenyl(spiro[cyclohexanefluorene]yl)(phenyldibenzothiophenyl)triazine; phenyl(spiro[cyclohexanefluorene]yl)(phenyldibenzoselenophenyl)triazine; phenyl(spirobi[fluorene]yl)(phenyldibenzofuranyl)triazine; phenyl(spirobi[fluorene]yl)(phenyldibenzothiophenyl)triazine; phenyl(spirobi[fluorene]yl)(phenyldibenzoselenophenyl)triazine; (diphenyl-d₁₀)[(phenyldibenzofuranyl)phenyl-d₁₄]triazine; (diphenyl-d₁₀)[(phenyldibenzothiophenyl)phenyl-d₁₄]triazine; (diphenyl-d₁₀)[(phenyldibenzoselenophenyl)phenyl-d₁₄]triazine(diphenyl-d₁₀){[(biphenylyl)dibenzofuranyl]phenyl-d₁₈}triazine; (diphenyl-d₁₀){[(biphenylyl)dibenzothiophenyl]phenyl-d₁₈}triazine; (diphenyl-d₁₀){[(biphenylyl)dibenzoselenophenyl]phenyl-d₁₈}triazinephenyl[(dimethyl-d₆)fluorenyl](phenyldibenzofuranyl)triazine; phenyl[(dimethyl-d₆)fluorenyl](phenyldibenzothiophenyl)triazine; phenyl[(dimethyl-d₆)fluorenyl](phenyldibenzoselenophenyl)triazine; (diphenyl-d₁₀){[(biphenylyl)dibenzofuranyl]phenyl-d₁₈}triazine; (diphenyl-d₁₀){[(biphenylyl)dibenzothiophenyl]phenyl-d₁₈}triazine; (diphenyl-d₁₀){[(biphenylyl)dibenzoselenophenyl]phenyl-d₁₈}triazine(diphenyl-d₁₀){[(biphenylyl)dibenzofuranyl]phenyl}triazine; (diphenyl-d₁₀){[(biphenylyl)dibenzothiophenyl]phenyl}triazine; (diphenyl-d₁₀){[(biphenylyl)dibenzoselenophenyl]phenyl}triazine; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; [di(fluorophenyl)triazinyl][(biphenylyl)dibenzofuranyl]phenyl; [di(fluorophenyl)triazinyl][(biphenylyl)dibenzothiophenyl]phenyl; [di(fluorophenyl)triazinyl][(biphenylyl)dibenzoselenophenyl]phenyl; (dibenzothiophenyl)(diphenyltriazinyl)biphenyl; (diphenyltriazinyl)(dibenzothiophenyl)biphenyl; (diphenyltriazinyl)(dibenzothiophenyl)biphenyl; (dibenzofuranyl)triphenylene; (dibenzothiophenyl)triphenylene; (dibenzoselenophenyl)triphenylene; (dibenzofuranyl)(triphenylenyl)benzene; (dibenzothiophenyl)(triphenylenyl)benzene; (dibenzoselenophenyl)(triphenylenyl)benzene; (phenyldibenzofuranyl)(triphenylenyl)benzene; (phenyldibenzothiophenyl)(triphenylenyl)benzene; (phenyldibenzoselenophenyl)(triphenylenyl)benzene; (dibenzofuranyl)(triphenylenyl)biphenyl; (dibenzothiophenyl)(triphenylenyl)biphenyl; (dibenzoselenophenyl)(triphenylenyl)biphenyl; phenyl(triphenylenyl)dibenzofuran; phenyl(triphenylenyl)dibenzothiophene; phenyl(triphenylenyl)dibenzoselenophene; (biphenylyl)(triphenylenyl)dibenzofuran; (biphenylyl)(triphenylenyl)dibenzothiophene; (biphenylyl)(triphenylenyl)dibenzoselenophene; (terbenzenyl)(triphenylenyl)dibenzofuran; (terbenzenyl)(triphenylenyl)dibenzothiophene; (terbenzenyl)(triphenylenyl)dibenzoselenophene; (biphenylyl)[(triphenylenyl)phenyl]dibenzofuran; (biphenylyl)[(triphenylenyl)phenyl]dibenzothiophene; (biphenylyl)[(triphenylenyl)phenyl]dibenzoselenophene; (carbazolyl)(triphenylenyl)dibenzofuran; (carbazolyl)(triphenylenyl)dibenzothiophene; (carbazolyl)(triphenylenyl)dibenzoselenophene; (carbazolyl)(triphenylenyl)biphenyl; (triphenylenyl)(carbazolyl)biphenyl; (carbazolyl)[(triphenylenyl)phenyl]pyridine; tri(terbenzenyl)triazine; di(terbenzenyl)(biphenylyl)triazine; di(terbenzenyl)(biphenylyl)triazine; di(terbenzenyl)(dimethylfluorenyl)triazine; (dimethylfluorenyl)(terbenzenyl)(biphenylyl)triazine; phenyl(dibenzofuranyl)(terbenzenyl)triazine; phenyl(dibenzothiophenyl)(terbenzenyl)triazine; phenyl(dibenzoselenophenyl)(terbenzenyl)triazine; (biphenylyl)(dibenzofuranyl)(terbenzenyl)triazine; (biphenylyl)(dibenzothiophenyl)(terbenzenyl)triazine; (biphenylyl)(dibenzoselenophenyl)(terbenzenyl)triazine; (dibenzofuranyl)(dimethylfluorenyl)(terbenzenyl)triazine; (dibenzothiophenyl)(dimethylfluorenyl)(terbenzenyl)triazine; (dibenzoselenophenyl)(dimethylfluorenyl)(terbenzenyl)triazine; [(carbazolyl)phenyl](terphenylyl)carbazole; [(carbazolyl)phenyl](terphenylyl)carbazole; [(carbazolyl)pyridinyl](terphenylyl)carbazole; [(carbazolyl)pyridinyl](terphenylyl)carbazole; [(carbazolyl)pyridinyl](terphenylyl)carbazole; (terphenylyl)bicarbazole; (terphenylyl)bicarbazole; [(carbazolyl)phenyl](triphenylenyl)carbazole; [(carbazolyl)phenyl](triphenylenyl)carbazole; [(carbazolyl)pyridinyl](triphenylenyl)carbazole; [(carbazolyl)pyridinyl](triphenylenyl)carbazole; [(carbazolyl)phenyl](triphenylenyl)carbazole; (triphenylenyl)bicarbazole; (triphenylenyl)bicarbazole; [(triphenylenyl)phenyl]bicarbazole; [(triphenylenyl)phenyl]bicarbazole; [(carbazolyl)phenyl](dimethylfluorenyl)carbazole; [(carbazolyl)phenyl](dimethylfluorenyl)carbazole; [(carbazolyl)pyridinyl](dimethylfluorenyl)carbazole; [(carbazolyl)pyridinyl](dimethylfluorenyl)carbazole; (dimethylfluorenyl)bicarbazole; (dimethylfluorenyl)bicarbazole; [c-(dimethylfluorenyl)phenyl]bicarbazole; [c-(dimethylfluorenyl)phenyl]bicarbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; [(carbazolyl)phenyl](dibenzofuranyl)carbazole; [(carbazolyl)phenyl](dibenzothiophenyl)carbazole; [(carbazolyl)phenyl](dibenzoselenophenyl)carbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)bicarbazole; (dibenzothiophenyl)bicarbazole; (dibenzoselenophenyl)bicarbazole; (dibenzofuranyl)phenylbicarbazole; (dibenzothiophenyl)phenylbicarbazole; (dibenzoselenophenyl)phenylbicarbazole; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)phenylbicarbazole; (dibenzothiophenyl)phenylbicarbazole; (dibenzoselenophenyl)phenylbicarbazole; (dibenzofuranyl)(bicarbazolyl)biphenyl; (dibenzothiophenyl)(bicarbazolyl)biphenyl; (dibenzoselenophenyl)(bicarbazolyl)biphenyl; (dibenzofuranyl)(bicarbazolyl)biphenyl; (dibenzothiophenyl)(bicarbazolyl)biphenyl; (dibenzoselenophenyl)(bicarbazolyl)biphenyl

### (Group 16A)

diphenylindolocarbazole; phenyl(biphenyl)indolocarbazole; di(biphenyl)indolocarbazole; phenyl(terphenyl)indolocarbazole; phenyl(quaterphenyl)indolocarbazole; phenyl(quinquephenyl)indolocarbazole; phenyl(naphthalenyl)indolocarbazole; phenyl(binaphthalenyl)indolocarbazole; phenyl(acenaphthenyl)indolocarbazole; phenyl(acenaphthenyl)indolocarbazole; phenyl(azulenylphenyl)indolocarbazole; phenyl[(phenylanthracenyl)phenyl]indolocarbazole; phenyl(methylphenyl)indolocarbazole; phenyl[(diphenylamino)phenyl]indolocarbazole; phenyl[[bis(trimethylphenyl)borane]phenyl]indolocarbazole; di(biphenyl)indolocarbazole; biphenyl(pyridinylphenyl)indolocarbazole; phenyl(triphenylenyl)indolocarbazole; phenyl(terphenyl)indolocarbazole; phenyl(chrysenyl)indolocarbazole; phenyl(pyrenyl)indolocarbazole; phenyl(phenanthrenyl)indolocarbazole; phenyl(coronenyl)indolocarbazole; phenyl[(diphenylpyrimidinyl)phenyl]indolocarbazole; phenyl[(diphenyltriazinyl)phenyl]indolocarbazole; phenyl[(bithiophenyl)phenyl]indolocarbazole; phenyl[(isothiazolyl)phenyl]indolocarbazole; phenyl(dicyanophenyl)indolocarbazole; phenyl(dicyanophenyl)indolocarbazole; bis(ethylphenyl)indolocarbazole; bis(isopropylphenyl)indolocarbazole; bis(tert-butylphenyl)indolocarbazole; phenyl[[phenyl(naphthalenyl)amino]phenyl]indolocarbazole; phenyl[[di(naphthalenyl)amino]phenyl]indolocarbazole; phenyl[[di(naphthalenyl)borane]phenyl]indolocarbazole; phenyl(terphenyl)indolocarbazole; di(naphthalenyl)indolocarbazole; phenyl(anthracenyl)indolocarbazole; phenyl(tetracenyl)indolocarbazole; phenyl(perylenyl)indolocarbazole; phenyl(fluorenyl)indolocarbazole; phenyl[(n-butyl)phenyl]indolocarbazole; [(n-octyl)phenyl][(n-butyl)phenyl]indolocarbazole; phenyl[[phenyl(anthracenyl)amino]phenyl]indolocarbazole; phenyl[[di(anthracenyl)borane]phenyl]indolocarbazole; naphthalene(biphenyl)indolocarbazole; phenyl[(phenylcarbazolyl)phenyl]indolocarbazole; phenyl[(carbazolyl)phenyl]indolocarbazole; phenyl[(dibenzothiophenyl)phenyl]indolocarbazole; phenyl[(phenylfenadinyl)phenyl]indolocarbazole; tetraphenylindolocarbazole; (dipyridine)(diphenyl)indolocarbazole; diphenyl(carbazolyl)indolocarbazole; phenyl(biphenyl)indolocarbazole; tetraphenylindolocarbazole; di(naphthalenyl)indolocarbazole; phenyl[(phenyldibenzofuranyl)phenyl]indolocarbazole; phenyl(dibenzothiophenyl)indolocarbazole; phenyl(dibenzofuranyl)indolocarbazole; dimethyl(diphenyl)indolocarbazole; diphenyl[bis(diphenylamino)]indolocarbazole; diphenyl[bis(trimethylphenyl)boranyl]indolocarbazole; diphenyldicyanoindolocarbazole; dipyridinylindolocarbazole; bis(phenylcarbazolyl)indolocarbazole; bis[phenylindolocarbazolyl]benzene; bis[phenylindolocarbazolyl]benzene; bis[phenylindolocarbazolyl]biphenyl; bis[phenylindolocarbazolyl]naphthalene; bis[phenylindolocarbazolyl]anthracene; bis[phenylindolocarbazolyl]pyrene; bis[phenylindolocarbazolyl](cyano)benzene; (phenylindolocarbazolyl)[(carbazolyl)indolocarbazolyl]benzene; (phenylindolocarbazolyl)[(dibenzoselenophenyl)indolocarbazolyl]benzene; phenyl(phenylpyridinyl)indolocarbazole; phenyl(diphenylpyrimidinyl)indolocarbazole; phenyl(diphenyltriazinyl)indolocarbazole; phenyl(phenylpyrazinyl)indolocarbazole; phenyl(quinolinyl)indolocarbazole; phenyl(quinalizonyl)indolocarbazole; phenyl(phenylbenzimidazolyl)indolocarbazole; phenyl(cinnolinyl)indolocarbazole; phenyl(phenylcarbazolyl)indolocarbazole; methylbiphenyl(phenylpyridinyl)indolocarbazole; phenyl(carbazolylpyridinyl)indolocarbazole; phenyl[phenyl(carbazolyl)pyrimidinyl]indolocarbazole; phenyl[phenyl(biphenyl)triazinyl]indolocarbazole; biphenyl(diphenyltriazinyl)indolocarbazole; phenyl[phenyl(biphenyl)triazinyl]indolocarbazole; phenyl[di(biphenyl)triazinyl]indolocarbazole; naphthalenyl(quinolinyl)indolocarbazole; phenyl(biphenylquinazolinyl)indolocarbazole; phenyl(biphenylindolyl)indolocarbazole; terphenyl(phenylpyridinyl)indolocarbazole; phenyl[di(biphenyl)triazinyl]indolocarbazole; tetraphenyl(quinolinyl)indolocarbazole; phenyl(carbazolyl)(phenylcarbazolyl)indolocarbazole; diphenylaminophenyl(phenylquinazolinyl)indolocarbazole; phenyl{phenyl[(carbazolyl)methylphenyl]triazinyl}indolocarbazole; phenyl(naphthalenylcarbazolyl)indolocarbazole; phenyl(quinolinylcarbazolyl)indolocarbazole; phenyl(phenylpyridinyl)indolocarbazole; phenyl(phenylpyridinyl)indolocarbazole; biphenyl(phenylpyridinyl)indolocarbazole; terphenyl(phenylpyridinyl)indolocarbazole; phenyl(diphenylpyrimidinyl)indolocarbazole; (dibenzothiophenylphenyl)(diphenylpyrimidinyl)indolocarbazole phenyl(diphenyltriazinyl)indolocarbazole; phenyl[phenyl(biphenyl)triazinyl]indolocarbazole; biphenyl[phenyl(biphenyl)triazinyl]indolocarbazole; phenyl[biphenyl(naphthalenyl)triazinyl]indolocarbazole; dibenzothiophenyl(diphenyltriazinyl)indolocarbazole; phenyl(quinolinyl)indolocarbazole; biphenyl(quinazolinyl)indolocarbazole; phenyl(quinoxalinyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; phenyl(dibenzothiophenylcarbazolyl)indolocarbazole; phenyl(phenylpyridoindolyl)indolocarbazole; phenyl(phenylpyridinyl)indolocarbazole; phenyl(phenylpyridinyl)indolocarbazole; phenyl(diphenylpyrimidinyl)indolocarbazole; phenyl(diphenyltriazinyl)indolocarbazole; naphthalene(diphenyltriazinyl)indolocarbazole; phenyl(diphenyltriazinyl)indolocarbazole; phenyl[di(cyanophenyl)triazinyl]indolocarbazole; phenyl(phenylbipyridinyl)indolocarbazole; tert-butylphenyl(quinolinyl)indolocarbazole; phenyl(phenylquinazolinyl)indolocarbazole; phenyl(quinoxalinyl)indolocarbazole; phenyl(carbazolepyridinyl)indolocarbazole; phenyl(phenylcarbazolylpyridinyl)indolocarbazole; phenyl(phenylcarbazolylpyridinyl)indolocarbazole; phenyl(triphenylenylpyridinyl)indolocarbazole; methylpyridinyl(triphenylenyl)indolocarbazole; phenylpyridinyl(phenanthrenyl)indolocarbazole; phenylpyridinyl(pyrenyl)indolocarbazole; phenylpyridinyl(terphenyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; biphenyl(phenylcarbazolyl)indolocarbazole; phenyl(biphenylcarbazolyl)indolocarbazole; phenyl(phenylpyridoindolyl)indolocarbazole; phenyl(phenylpyridinyl)indolocarbazole; phenyl(diphenylpyrimidinyl)indolocarbazole; phenyl(diphenyltriazinyl)indolocarbazole; phenyl(quinolinyl)indolocarbazole; phenyl(phenylquinazolinyl)indolocarbazole; phenyl(phenylindolyl)indolocarbazole; phenyl(phenylbenzoindolyl)indolocarbazole; phenyl[phenyl(naphthalenyl)triazinyl]indolocarbazole; phenyl[phenyl(phenanthrenyl)triazinyl]indolocarbazole; phenyl[phenyl(fluorenyl)triazinyl]indolocarbazole; phenylpyridinyl(triphenylenyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; benzothiophenyl(phenylcarbazolyl)indolocarbazole; phenyl(naphthalenylcarbazolyl)indolocarbazole; phenyl(phenylazaoxaindenofluorenyl)indolocarbazole; phenyl(pyridinyl)indolocarbazole; phenyl(diphenylpyridinyl)indolocarbazole; phenyl(diphenylpyrimidinyl)indolocarbazole; phenyl[phenyl(dibenzofuranyl)pyrimidinyl]indolocarbazole; phenyl(diphenyltriazinyl)indolocarbazole; phenyl[phenyl(phenylanthracenyl)triazinyl]indolocarbazole; phenylpyridinyl(anthracenyl)indolocarbazole; phenyl(quinolinyl)indolocarbazole; phenyl(isoquinolinyl)indolocarbazole; phenyl(acridinyl)indolocarbazole; phenyl[(phenylanthracenyl)pyridinyl]indolocarbazole; phenyl(naphthalenylpyridinyl)indolocarbazole; phenyl(isoquinolinylpyridinyl)indolocarbazole; phenyl(phenylcarbazolyl)indolocarbazole; phenyl(phenylcarbazolyl)indolocarbazole; phenyl(phenylcarbazolyl)indolocarbazole; phenyl(phenylcarbazolyl)indolocarbazole; phenyl(methylphenylcarbazolyl)indolocarbazole; phenyl(terphenylcarbazolyl)indolocarbazole; bis[phenylindolocarbazolyl]pyridazine; bis[phenylindolocarbazolyl]pyridine; bis[phenylindolocarbazolyl]cyanopyridine; bis[phenylindolocarbazolyl]pyrazine; bis[phenylindolocarbazolyl]phenylpyrimidine; bis[phenylindolocarbazolyl]phenylcarbazole; tris[phenylindolocarbazolyl]triazine

### (Group 17A)

(diphenyl-d₁₀)[(biphenyldibenzothiophenyl)phenyl]triazine; (phenyl-d₅)(triphenylenylphenyl)dibenzothiophene; (dicarbazolyl-d₁₆)dibenzothiophened₆; [(dimethyl-d₆)fluorenyl][(diphenyltriazinyl)phenyl]dibenzothiophene

### (Group 18A)

phenyl(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; bis(terphenylyl)indolocarbazole; bis(terphenylyl)indolocarbazole; bis(terphenylyl)indolocarbazole; (terphenylyl)(triphenylenyl)indolocarbazole; (terphenyl)(dimethylfluorenyl)indolocarbazole; (terphenylyl)(spiro[cyclopentanefluorene]yl)indolocarbazole; (terphenylyl)(spiro[cyclohexanefluorene]yl)indolocarbazole; (terphenylyl)(dimethylfluorenyl)indolocarbazole; (terphenylyl)(spirobi[fluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(dibenzoselenophenyl)indolocarbazole; (terphenylyl)(dibenzoselenophenyl)indolocarbazole; (terphenylyl)dibenzoselenophene-indolocarbazole; (terphenylyl)phenylcarbazole-indolocarbazole; (terphenylyl)(carbazolylphenyl)indolocarbazole; (terphenylyl)(benzothienopyridinyl)indolocarbazole; (terphenylyl)(benzothienopyrimidinyl)indolocarbazole; (terphenylyl)(benzothienopyrimidinyl)indolocarbazole; (terphenylyl)phenylbenzothienopyrimidinyl)indolocarbazole; (terphenylyl)(diphenyltriazinyl)indolocarbazole; (terphenylyl)(phenylquinazolinyl)indolocarbazole; (terphenylyl)(dibenzoquinazolinyl)indolocarbazole; (terphenylyl)(dibenzoquinoxalinyl)indolocarbazole; [(phenyl-d₅)biphenylyl](biphenylyl)indolocarbazole; [(phenyl-d₅)biphenyl](phenyl-d₅)indolocarbazole; (terphenylyl)[(dimethyl-d₆)fluorene]indolocarbazole; (terphenylyl)(dibenzofuranylphenyl)indolocarbazole; (terphenylyl)(dibenzothiophenylphenyl)indolocarbazole; (terphenylyl)(triphenylenylphenyl)indolocarbazole; (terphenylyl)[(diphenyltriazinyl)phenyl]-indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(triphenylenyl)indolocarbazole; (terphenylyl)(dimethylfluorenyl)indolocarbazole; (terphenylyl)(spiro[cyclohexanefluorene]yl)indolocarbazole; (terphenylyl)(spiro[cyclopentanefluorene]yl)indolocarbazole; (terphenylyl)(spirobi[fluorene]yl)indolocarbazole; (terphenylyl)(dimethylfluorenyl)-indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(dibenzoselenophenyl)indolocarbazole; (terphenylyl)(dibenzoselenophenyl)indolocarbazole; (terphenylyl)(dibenzoselenophenyl)indolocarbazole; (terphenylyl)(phenylcarbazolyl)indolocarbazole; (terphenylyl)[(carbazolyl)phenyl]indolocarbazole; (terphenylyl)(benzothienopyridinyl)indolocarbazole; (terphenylyl)(benzothienopyrimidinyl)indolocarbazole; (terphenylyl)(benzothienopyrimidinyl)indolocarbazole; (terphenylyl)(phenylbenzothienopyrimidinyl)indolocarbazole; (terphenylyl)(diphenylbenzothienopyrimidinyl)indolocarbazole; (terphenylyl)(diphenylbenzothienopyrimidinyl)indolocarbazole; (terphenylyl)(diphenyltriazinyl)indolocarbazole (terphenylyl)(phenylquinazolinyl)indolocarbazole; (terphenylyl)(dibenzoquinazolinyl)indolocarbazole; (terphenylyl)(dibenzoquinoxalinyl)indolocarbazole; (terphenylyl)[(dimethyl-d₆)fluorenyl]indolocarbazole; (terphenylyl)[(diphenyltriazinyl)phenyl]indolocarbazole; [(phenyl-d₅)biphenylyl](biphenylyl)indolocarbazole; [(phenyl-d₅)biphenylyl](phenyl-d₅)indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(triphenylenyl)indolocarbazole; (terphenylyl)(dimethylfluorenyl)indolocarbazole; (terphenylyl)(spirobi[fluorene]yl)-indolocarbazole; (terphenylyl)(spiro[cyclopentanefluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(diphenyltriazinyl)indolocarbazole; (terphenylyl)(phenylquinazolinyl)indolocarbazole; (terphenylyl)(benzothienopyrimidinyl)indolocarbazole; (terphenylyl)(phenyl)indolocarbazole; (terphenylyl)(biphenyl)indolocarbazole; (terphenylyl)(biphenylyl)indolocarbazole; di(terphenylyl)indolocarbazole; di(terphenylyl)indolocarbazole; (terphenylyl)(triphenylenyl)indolocarbazole; (terphenylyl)(dimethylfluorenyl)indolocarbazole; (terphenylyl)(spirobi[fluorene]yl)-indolocarbazole; (terphenylyl)(spiro[cyclopentanefluorene]yl)indolocarbazole; (terphenylyl)(dibenzofuranyl)indolocarbazole; (terphenylyl)(dibenzofuranyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(dibenzothiophenyl)indolocarbazole; (terphenylyl)(diphenyltriazinyl)indolocarbazole; (terphenylyl)(phenylquinazolinyl)indolocarbazole; (terphenylyl)(benzothienopyrimidinyl)indolocarbazole; (terphenylyl)(phenyl)indolocarbazole; (terphenylyl)(biphenylyl)indolocarbazole; (terphenylyl)(biphenylyl)indolocarbazole; di(terphenylyl)indolocarbazole; di(terphenylyl)indolocarbazole; (terphenylyl)(dimethylfluorenyl)indolocarbazole; (terphenylyl)(dibenzofuranyl)indolocarbazole; (terphenylyl)(dibenzothiophenyl)indolocarbazole; (terphenylyl)(dibenzothiophenyl)indolocarbazole; (terphenylyl)(benzothienopyridinyl)indolocarbazole; (terphenylyl)(benzothienopyrimidinyl)indolocarbazole; (terphenylyl)(diphenyltriazinyl)indolocarbazole; (terphenylyl)(phenylquinazolinyl)indolocarbazole; [(phenyl-d₅)biphenylyl](biphenylyl)indolocarbazole; [(phenyl-d₅)biphenylyl](phenyl-d₅)indolocarbazole; (terphenylyl)(phenyl)indolocarbazole; (terphenylyl)(biphenylyl)indolocarbazole; (terphenylyl)(biphenylyl)indolocarbazole; (terphenylyl)(dibenzothiophenyl)indolocarbazole; (terphenylyl)(dibenzothiophenyl)indolocarbazole; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)phenyldibenzothiophenyl](diphenyltriazinyl)biphenyl; [(biphenylyl)phenyldibenzoselenophenyl](diphenyltriazinyl)biphenyl; [(biphenylyl)dibenzofuranyl](diphenyltriazinyl)biphenyl; [(biphenylyl)phenyldibenzothiophenyl](diphenyltriazinyl)biphenyl; [(biphenylyl)phenyldibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [biphenylyl(dibenzofuranyl)](diphenyltriazinyl)terbenzene; [biphenylyl(dibenzothiophenyl)](diphenyltriazinyl)terbenzene; [biphenylyl(dibenzoselenophenyl)](diphenyltriazinyl)terbenzene; dibenzofuranyl[phenyl(biphenylyl)triazinyl]biphenyl; dibenzothiophenyl[phenyl(biphenylyl)triazinyl]biphenyl; dibenzoselenophenyl[phenyl(biphenylyl)triazinyl]biphenyl; dibenzofuranyl[phenyl(biphenylyl)triazinyl]biphenyl; dibenzothiophenyl[phenyl(biphenylyl)triazinyl]biphenyl; dibenzoselenophenyl[phenyl(biphenylyl)triazinyl]biphenyl; dibenzofuranyl[bis(biphenylyl)triazinyl]biphenyl; dibenzothiophenyl[bis(biphenylyl)triazinyl]biphenyl; dibenzoselenophenyl[bis(biphenylyl)triazinyl]biphenyl; dibenzofuranyl[dimethylfluorenyl(biphenylyl)triazinyl]biphenyl; dibenzothiophenyl[dimethylfluorenyl(biphenylyl)triazinyl]biphenyl; dibenzoselenophenyl[dimethylfluorenyl(biphenylyl)triazinyl]biphenyl; phenyldibenzofuranyl[phenyl(biphenylyl)triazinyl]biphenyl; phenyldibenzothiophenyl[phenyl(biphenylyl)triazinyl]biphenyl; phenyldibenzoselenophenyl[phenyl(biphenylyl)triazinyl]biphenyl; phenyldibenzofuranyl[phenyl(biphenylyl)triazinyl]biphenyl; phenyldibenzothiophenyl[phenyl(biphenylyl)triazinyl]biphenyl; phenyldibenzoselenophenyl[phenyl(biphenylyl)triazinyl]biphenyl; phenyldibenzofuranyl[dimethylfluorenyl(biphenylyl)triazinyl]biphenyl; phenyldibenzothiophenyl[dimethylfluorenyl(biphenylyl)triazinyl]biphenyl; phenyldibenzoselenophenyl[dimethylfluorenyl(biphenylyl)triazinyl]biphenyl; dibenzofuranyl[phenyl(biphenylyl)triazinyl]terbenzene; dibenzothiophenyl[phenyl(biphenylyl)triazinyl]terbenzene; dibenzoselenophenyl[phenyl(biphenylyl)triazinyl]terbenzene; dibenzofuranyl[phenyl(biphenylyl)triazinyl]terbenzene; dibenzothiophenyl[phenyl(biphenylyl)triazinyl]terbenzene; dibenzoselenophenyl[phenyl(biphenylyl)triazinyl]terbenzene; dibenzofuranyl[dimethylfluorenyl(biphenylyl)triazinyl]terbenzene; dibenzothiophenyl[dimethylfluorenyl(biphenylyl)triazinyl]terbenzene; dibenzoselenophenyl[dimethylfluorenyl(biphenylyl)triazinyl]terbenzene; (biphenylyl)dibenzofuranyl[phenyl(biphenylyl)triazinyl]biphenyl; (biphenylyl)dibenzothiophenyl[phenyl(biphenylyl)triazinyl]biphenyl; (biphenylyl)dibenzoselenophenyl[phenyl(biphenylyl)triazinyl]biphenyl; (biphenylyl)dibenzofuranyl[phenyl(biphenylyl)triazinyl]biphenyl; (biphenylyl)dibenzothiophenyl[phenyl(biphenylyl)triazinyl]biphenyl; (biphenylyl)dibenzoselenophenyl[phenyl(biphenylyl)triazinyl]biphenyl; (biphenylyl)dibenzofuranyl[dimethylfluorenyl(biphenylyl)triazinyl]biphenyl; (biphenylyl)dibenzothiophenyl[dimethylfluorenyl(biphenylyl)triazinyl]biphenyl; (biphenylyl)dibenzoselenophenyl[dimethylfluorenyl(biphenylyl)triazinyl]biphenyl; diphenyltriazinyl(dibenzofuranyl)terbenzene; diphenyltriazinyl(dibenzothiophenyl)]terbenzene; diphenyltriazinyl(dibenzoselenophenyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)biphenyl; dibenzothiophenyl(diphenyltriazinyl)biphenyl; dibenzoselenophenyl(diphenyltriazinyl)biphenyl; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; diphenyldibenzofuranyl(diphenyltriazinyl)biphenyl; diphenyldibenzothiophenyl(diphenyltriazinyl)biphenyl; diphenyldibenzoselenophenyl(diphenyltriazinyl)biphenyl; diphenyldibenzofuranyl(diphenyltriazinyl)biphenyl; diphenyldibenzothiophenyl(diphenyltriazinyl)biphenyl; diphenyldibenzoselenophenyl(diphenyltriazinyl)biphenyl; phenyldibenzofuranyl(diphenyltriazinyl)biphenyl; phenyldibenzothiophenyl(diphenyltriazinyl)biphenyl; phenyldibenzoselenophenyl(diphenyltriazinyl)biphenyl; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; [(pyridinyl)dibenzofuranyl](diphenyltriazinyl)biphenyl; [(pyridinyl)dibenzothiophenyl](diphenyltriazinyl)biphenyl; [(pyridinyl)phenyldibenzoselenophenyl](diphenyltriazinyl)biphenyl; diphenyltriazinyl(dibenzofuranyl)terbenzene; diphenyltriazinyl(dibenzothiophenyl)terbenzene; diphenyltriazinyl(dibenzoselenophenyl)terbenzene; dibenzofuranyl(diphenyltriazinyl)terbenzene; dibenzothiophenyl(diphenyltriazinyl)terbenzene; dibenzoselenophenyl(diphenyltriazinyl)terbenzene; (dibenzofuranyl)(dimethylfluorenyl)(diphenyltriazinyl)benzene; (dibenzothiophenyl)(dimethylfluorenyl)(diphenyltriazinyl)benzene; (dibenzoselenophenyl)(dimethylfluorenyl)(diphenyltriazinyl)benzene; diphenyltriazinyl(dimethylfluorenyl)biphenyl; diphenyltriazinyl(spiro[cyclopentanefluorene]yl)biphenyl; diphenyltriazinyl(dimethylfluorenyl)terbenzene; diphenylfluorenyl(diphenyltriazinyl)biphenyl; dimethylfluorenyl[phenyl(biphenylyl)triazinyl]biphenyl; dimethylfluorenyl[phenyl(biphenylyl)triazinyl]biphenyl; dimethylfluorenyl[phenyl(dimethylfluorenyl)triazinyl]terbenzene; diphenyl[bis(dimethylfluorenyl)phenyl]triazine; phenyl(diphenyltriazinyl)dibenzofuran; phenyl(diphenyltriazinyl)dibenzothiophene; phenyl(diphenyltriazinyl)dibenzoselenophene; phenyl[phenyl(biphenyl)triazinyl]dibenzofuran; phenyl[phenyl(biphenyl)triazinyl]dibenzothiophene; phenyl[phenyl(biphenyl)triazinyl]dibenzoselenophene; phenyl[phenyl(biphenyl)triazinyl]dibenzofuran; phenyl[phenyl(biphenyl)triazinyl]dibenzothiophene; phenyl[phenyl(biphenyl)triazinyl]dibenzoselenophene; phenyl[bis(biphenyl)triazinyl]dibenzofuran; phenyl[bis(biphenyl)triazinyl]dibenzothiophene; phenyl[bis(biphenyl)triazinyl]benzselenophene; phenyl[bis(biphenyl)triazinyl]dibenzofuran; phenyl[bis(biphenyl)triazinyl]dibenzothiophene; phenyl[bis(biphenyl)triazinyl]benzselenophene; phenyl[bis(biphenyl)triazinyl]dibenzofuran; phenyl[bis(biphenyl)triazinyl]dibenzothiophene; phenyl[bis(biphenyl)triazinyl]benzselenophene; phenyl[(diphenyltriazinyl)phenyl]dibenzofuran; phenyl[(diphenyltriazinyl)phenyl]dibenzothiophene; phenyl[(diphenyltriazinyl)phenyl]benzselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzselenophene; phenyl[(diphenyltriazinyl)phenyl]dibenzofuran; phenyl[(diphenyltriazinyl)phenyl]dibenzothiophene; phenyl[(diphenyltriazinyl)phenyl]benzselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzselenophene; phenyl{[phenyl(biphenylyl)triazinyl]phenyl}dibenzofuran; phenyl{[phenyl(biphenylyl)triazinyl]phenyl}dibenzothiophene; phenyl{[phenyl(biphenylyl)triazinyl]phenyl}benzselenophene; phenyldibenzofuran(diphenyltriazinyl)biphenyl; phenyldibenzothiophene(diphenyltriazinyl)biphenyl; phenylbenzselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; phenyldibenzofuran(diphenyltriazinyl)biphenyl; phenyldibenzothiophene(diphenyltriazinyl)biphenyl; phenylbenzselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; phenyldibenzofuran(diphenyltriazinyl)biphenyl; phenyldibenzothiophene(diphenyltriazinyl)biphenyl; phenylbenzselenophene(diphenyltriazinyl)biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; phenyldibenzofuran[phenyl(biphenylyl)triazinyl]biphenyl; phenyldibenzothiophene[phenyl(biphenylyl)triazinyl]biphenyl; phenylbenzselenophene[phenyl(biphenylyl)triazinyl]biphenyl; biphenylyl(diphenyltriazinyl)dibenzofuran; biphenylyl(diphenyltriazinyl)dibenzothiophene; biphenylyl(diphenyltriazinyl)benzselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzselenophene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; biphenylyl(diphenyltriazinyl)dibenzofuran biphenylyl(diphenyltriazinyl)dibenzothiophene; biphenylyl(diphenyltriazinyl)benzselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzselenophene; biphenylyl[phenyl(biphenylyl)triazinyl]dibenzofuran; biphenylyl[phenyl(biphenylyl)triazinyl]dibenzothiophene; biphenylyl[phenyl(biphenylyl)triazinyl]benzselenophene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; biphenylyl[(diphenyltriazinyl)phenyl]dibenzofuran; biphenylyl[(diphenyltriazinyl)phenyl]dibenzothiophene; biphenylyl[(diphenyltriazinyl)phenyl]benzselenophene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; [(biphenylyl)dibenzofuranyl][phenyl(biphenylyl)triazinyl]benzene; [(biphenylyl)dibenzothiophenyl][phenyl(biphenylyl)triazinyl]benzene; [(biphenylyl)benzselenophenyl][phenyl(biphenylyl)triazinyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]benzselenophene; phenyl[biphenylyl(dimethylfluorenyl)triazinyl]dibenzofuran; phenyl[biphenylyl(dimethylfluorenyl)triazinyl]dibenzothiophene; phenyl[biphenylyl(dimethylfluorenyl)triazinyl]benzselenophene; phenyl[biphenylyl(dimethylfluorenyl)triazinyl]dibenzofuran; phenyl[biphenylyl(dimethylfluorenyl)triazinyl]dibenzothiophene; phenyl[biphenylyl(dimethylfluorenyl)triazinyl]benzselenophene; phenyldibenzofuranyl[phenyl(dimethylfluorenyl)triazinyl]benzene; phenyldibenzothiophenyl[phenyl(dimethylfluorenyl)triazinyl]benzene; phenylbenzselenophenyl[phenyl(dimethylfluorenyl)triazinyl]benzene; phenyldibenzofuranyl[bis(dimethylfluorenyl)triazinyl]benzene; phenyldibenzothiophenyl[bis(dimethylfluorenyl)triazinyl]benzene; phenylbenzselenophenyl[bis(dimethylfluorenyl)triazinyl]benzene; biphenylyl[phenyl(dimethylfluorenyl)triazinyl]dibenzofuran; biphenylyl[phenyl(dimethylfluorenyl)triazinyl]dibenzothiophene; biphenylyl[phenyl(dimethylfluorenyl)triazinyl]benzselenophene; biphenylyl[phenyl(dimethylfluorenyl)triazinyl]dibenzofuran; biphenylyl[phenyl(dimethylfluorenyl)triazinyl]dibenzothiophene; biphenylyl[phenyl(dimethylfluorenyl)triazinyl]benzselenophene; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzselenophenyl][phenyl(dimethylfluorenyl)triazinyl]benzene; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzselenophenyl][phenyl(dimethylfluorenyl)triazinyl]benzene; phenyl[phenyl(dimethylfluorenylphenyl)triazinyl]dibenzofuran; phenyl[phenyl(dimethylfluorenylphenyl)triazinyl]dibenzothiophene; phenyl[phenyl(dimethylfluorenylphenyl)triazinyl]benzselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]benzselenophene; phenyl[(biphenylyl)dibenzofuranyl](dimethylfluorenyl)triazine; phenyl[(biphenylyl)dibenzothiophenyl](dimethylfluorenyl)triazine; phenyl[(biphenylyl)benzselenophenyl](dimethylfluorenyl)triazine; [(biphenylyl)dibenzofuranyl][phenyl(dimethylfluorenyl)triazinyl]benzene; [(biphenylyl)dibenzothiophenyl][phenyl(dimethylfluorenyl)triazinyl]benzene; [(biphenylyl)benzselenophenyl][phenyl(dimethylfluorenyl)triazinyl]benzene; phenyl(phenyldibenzofuranyl)(phenyldimethylfluorenyl)triazine; phenyl(phenyldibenzothiophenyl)(phenyldimethylfluorenyl)triazine; phenyl(phenylbenzselenophenyl)(phenyldimethylfluorenyl)triazine; phenyl(phenyldibenzofuranyl)(dimethylfluorenyl)triazine; phenyl(phenyldibenzothiophenyl)(dimethylfluorenyl)triazine; phenyl(phenylbenzselenophenyl)(dimethylfluorenyl)triazine; diphenyl(phenyldibenzofuranyl)triazine; diphenyl(phenyldibenzothiophenyl)triazine; diphenyl(phenylbenzselenophenyl)triazine; diphenyltriazinyl(phenyldibenzofuranyl)benzene; diphenyltriazinyl(phenyldibenzothiophenyl)benzene; diphenyltriazinyl(phenylbenzselenophenyl)benzene; diphenyltriazinyl[(biphenylyl)dibenzofuranyl]benzene; diphenyltriazinyl[(biphenylyl)dibenzothiophenyl]benzene; diphenyltriazinyl[(biphenylyl)benzselenophenyl]benzene; diphenyltriazinyl(diphenyldibenzofuranyl)benzene; diphenyltriazinyl(diphenyldibenzothiophenyl)benzene; diphenyltriazinyl(diphenylbenzselenophenyl)benzene; diphenyl(phenyldibenzofuranyl)triazine; diphenyl(phenyldibenzothiophenyl)triazine; diphenyl(phenylbenzselenophenyl)triazine; diphenyl[(biphenylyl)dibenzofuranyl]triazine; diphenyl[(biphenylyl)dibenzothiophenyl]triazine; diphenyl[(biphenylyl)benzselenophenyl]triazine; diphenyl[(biphenylyl)dibenzofuranyl]triazine; diphenyl[(biphenylyl)dibenzothiophenyl]triazine; diphenyl[(biphenylyl)benzselenophenyl]triazine; diphenyltriazinyl(diphenyldibenzofuranyl)benzene; diphenyltriazinyl(diphenyldibenzothiophenyl)benzene; diphenyltriazinyl(diphenylbenzselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzselenophenyl)benzene; diphenyl[phenyldibenzofuranyl]triazine; diphenyl[phenyldibenzothiophenyl]triazine; diphenyl[phenylbenzselenophenyl]triazine; diphenyltriazinyl(phenyldibenzofuranyl)benzene; diphenyltriazinyl(phenyldibenzothiophenyl)benzene; diphenyltriazinyl(phenylbenzselenophenyl)benzene; diphenyltriazinyl(phenyldibenzofuranyl)benzene; diphenyltriazinyl(phenyldibenzothiophenyl)benzene; diphenyltriazinyl(phenylbenzselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzselenophenyl)benzene; diphenyltriazinyl(biphenylyldibenzofuranyl)benzene; diphenyltriazinyl(biphenylyldibenzothiophenyl)benzene; diphenyltriazinyl(biphenylylbenzselenophenyl)benzene; diphenyltriazinyl(phenyldibenzofuranyl)benzene; diphenyltriazinyl(phenyldibenzothiophenyl)benzene; diphenyltriazinyl(phenylbenzselenophenyl)benzene; diphenyltriazinyl(phenyldibenzofuranyl)pyridine; diphenyltriazinyl(phenyldibenzothiophenyl)pyridine; diphenyltriazinyl(phenylbenzselenophenyl)pyridine; phenyl(phenylpyridinyl)triazinyl(phenyldibenzofuranyl)pyridine; phenyl(phenylpyridinyl)triazinyl(phenyldibenzothiophenyl)pyridine; phenyl(phenylpyridinyl)triazinyl(phenylbenzselenophenyl)pyridine; phenyl(phenylpyridinyl)triazinyl(phenyldibenzofuranyl)benzene; phenyl(phenylpyridinyl)triazinyl(phenyldibenzothiophenyl)benzene; phenyl(phenylpyridinyl)triazinyl(phenylbenzselenophenyl)benzene; diphenyltriazinyl(biphenylyldibenzofuranyl)pyridine; diphenyltriazinyl(biphenylyldibenzothiophenyl)pyridine; diphenyltriazinyl(biphenylylbenzselenophenyl)pyridine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenylbenzselenophenyl)triazine; (biphenylyl)(dimethylindenopyridinyl)(phenyldibenzofuranyl)triazine; (biphenylyl)(dimethylindenopyridinyl)(phenyldibenzothiophenyl)triazine; (biphenylyl)(dimethylindenopyridinyl)(phenylbenzselenophenyl)triazine; phenyl(dimethylindenopyridinyl)(phenyldibenzofuranyl)triazine; phenyl(dimethylindenopyridinyl)(phenyldibenzothiophenyl)triazine; phenyl(dimethylindenopyridinyl)(phenylbenzselenophenyl)triazine; phenyl(spiro[cyclohexaneindenopyridine]yl)(phenyldibenzofuranyl)triazine; phenyl(spiro[cyclohexaneindenopyridine]yl)(phenyldibenzothiophenyl)triazine; phenyl(spiro[cyclohexaneindenopyridine]yl)(phenylbenzselenophenyl)triazine; phenyl(spirobi[fluorene]yl)(phenyldibenzofuranyl)triazine; phenyl(spirobi[fluorene]yl)(phenyldibenzothiophenyl)triazine; phenyl(spirobi[fluorene]yl)(phenylbenzselenophenyl)triazine; benzene-d₃[(diphenyl-d₁₀)triazinyl][(phenyl-d₅)dibenzofuranyl-d₆]; benzene-d₃[(diphenyl-d₁₀)triazinyl][(phenyl-d₅)dibenzothiophenyl-d₆]; benzene-d₃[(diphenyl-d₁₀)triazinyl][(phenyl-d₅)benzselenophenyl-d₆]; benzene-d₃[(diphenyl-d₁₀)triazinyl][(biphenylyl-d₈)dibenzofuranyl-d₆]; benzene-d₃[(diphenyl-d₁₀)triazinyl][(biphenylyl-d₈)dibenzothiophenyl-d₆]; benzene-d₃[(diphenyl-d₁₀)triazinyl][(biphenylyl-d₈)benzselenophenyl-d₆]; phenyl[(dimethyl-d₆)fluorene][phenyldibenzofuranyl]triazine; phenyl[(dimethyl-d₆)fluorene][phenyldibenzothiophenyl]triazine; phenyl[(dimethyl-d₆)fluorene][phenylbenzselenophenyl]triazine; benzene-d₃[(diphenyl-d₁₀)triazinyl][(biphenylyl-d₈)dibenzofuranyl-d₆]; benzene-d₃[(diphenyl-d₁₀)triazinyl][(biphenylyl-d₈)dibenzothiophenyl-d₆]; benzene-d₃[(diphenyl-d₁₀)triazinyl][(biphenylyl-d₈)benzselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)benzselenophenyl]benzene; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)benzselenophenyl]biphenyl; [bis(fluorophenyl)triazinyl][(biphenylyl)dibenzofuranyl]benzene; [bis(fluorophenyl)triazinyl][(biphenylyl)dibenzothiophenyl]benzene; [bis(fluorophenyl)triazinyl][(biphenylyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzselenophenyl]biphenyl; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzselenophenyl]biphenyl; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzselenophenyl]biphenyl; diphenyltriazinyl[(dimethylfluorenyl)dibenzofuranyl]pyridine; diphenyltriazinyl[(dimethylfluorenyl)dibenzothiophenyl]pyridine; diphenyltriazinyl[(dimethylfluorenyl)benzselenophenyl]pyridine; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]biphenyl; diphenyltriazinyl[(dimethylfluorenyl)dibenzothiophenyl]biphenyl; diphenyltriazinyl[(dimethylfluorenyl)benzselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)benzselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)benzselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[bis(dimethylfluorenyl)dibenzofuranyl]benzene; diphenyltriazinyl[bis(dimethylfluorenyl)dibenzothiophenyl]benzene; diphenyltriazinyl[bis(dimethylfluorenyl)benzselenophenyl]benzene; [phenyl(terphenylyl)triazinyl][(dimethylfluorenyl)dibenzofuranyl]benzene; [phenyl(terphenylyl)triazinyl]triazinyl[(dimethylfluorenyl)dibenzothiophenyl]benzene; [phenyl(terphenylyl)triazinyl][(dimethylfluorenyl)benzselenophenyl]benzene; diphenyltriazinyl[(spiro[cyclopentanefluorene]yl)dibenzofuranyl]benzene; diphenyltriazinyl[(spiro[cyclopentanefluorene]yl)dibenzothiophenyl]benzene; diphenyltriazinyl[(spiro[cyclopentanefluorene]yl)benzselenophenyl]benzene; diphenyltriazinyl[(diphenylfluorenyl)dibenzofuranyl]benzene; diphenyltriazinyl[(diphenylfluorenyl)dibenzothiophenyl]benzene; diphenyltriazinyl[(diphenylfluorenyl)benzselenophenyl]benzene; diphenyltriazinyl[(spirobi[fluorene]yl)dibenzofuranyl]benzene; diphenyltriazinyl[(spirobi[fluorene]yl)dibenzothiophenyl]benzene; diphenyltriazinyl[(spirobi[fluorene]yl)benzselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzselenophenyl]benzene; [(diphenyltriazinyl)phenyl](phenyldimethylfluorenyl)dibenzofuran; [(diphenyltriazinyl)phenyl](phenyldimethylfluorenyl)dibenzothiophene; [(diphenyltriazinyl)phenyl](phenyldimethylfluorenyl)benzselenophene; diphenyltriazinyl{[(dimethyl-d₆)fluorenyl]dibenzofuranyl}benzene; diphenyltriazinyl{[(dimethyl-d₆)fluorenyl]dibenzothiophenyl}benzene; diphenyltriazinyl{[(dimethyl-d₆)fluorenyl]benzselenophenyl}benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzselenophenyl]benzene; diphenyltriazinyl[phenyl(dimethylfluorenyl)dibenzofuranyl]benzene; diphenyltriazinyl[phenyl(dimethylfluorenyl)dibenzothiophenyl]benzene; diphenyltriazinyl[phenyl(dimethylfluorenyl)benzselenophenyl]benzene; diphenyltriazinyl[(dimethylfluorenyl)dibenzofuranyl]benzene; diphenyltriazinyl[(dimethylfluorenyl)dibenzothiophenyl]benzene; diphenyltriazinyl[(dimethylfluorenyl)benzselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)benzselenophenyl]benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)benzselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]benzselenophenyl}benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)benzselenophenyl]

### (Group 19A)

phenyl[phenyl(biphenylyl)triazinyl]indenocarbazole; biphenylyl[phenyl(biphenylyl)triazinyl]indenocarbazole; biphenylyl[phenyl(biphenylyl)triazinyl]indenocarbazole; (dimethyl)(phenyl)[phenyl(biphenylyl)triazinyl]indenocarbazole; triphenyl[phenyl(biphenylyl)triazinyl]indenocarbazole; phenyl(dipyridinyl)[phenyl(biphenylyl)triazinyl]indenocarbazole; biphenylyl[phenyl(biphenylyl)triazinyl]indenocarbazole; phenyl[phenyl(biphenylyl)triazinyl]indenocarbazole; biphenylyl[phenyl(biphenylyl)triazinyl]indenocarbazole; terphenylyl[phenyl(biphenylyl)triazinyl]indenocarbazole; terphenylyl[phenyl(biphenylyl)triazinyl]indenocarbazole; [di(n-hexyl)](phenyl)[phenyl(biphenylyl)triazinyl]indenocarbazole; (dinaphthalenyl)(phenyl)[phenyl(biphenylyl)triazinyl]indenocarbazole; (diquinolinyl)(phenyl)[phenyl(biphenylyl)triazinyl]indenocarbazole; phenyl[phenyl(biphenylyl)triazinyl]indenocarbazole; biphenylyl[phenyl(biphenylyl)triazinyl]indenocarbazole; biphenylyl[phenyl(biphenylyl)triazinyl]indenocarbazole; phenyl[bis(dibenzofuranyl)][phenyl(biphenylyl)triazinyl]indenocarbazole; phenyl[bis(carbazolyl)][phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[bis(biphenylyl)triazinyl]indenocarbazole; phenyl[bis(biphenylyl)triazinyl]indenocarbazole; (biphenylyl)[bis(biphenylyl)triazinyl]indenocarbazole; (biphenylyl)[bis(biphenylyl)triazinyl]indenocarbazole; phenyl[phenyl(terphenylyl)triazinyl]indenocarbazole; phenyl[bis(terphenylyl)triazinyl]indenocarbazole; phenyl[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; (dimethyl)(phenyl)[phenyl(biphenylyl)triazinyl]indenocarbazole; phenyl[phenyl(biphenylyl)triazinyl]indenocarbazole; phenyl[bis(biphenylyl)triazinyl]indenocarbazole; (biphenylyl)[phenyl(biphenylyl)triazinyl]indenocarbazole; (terphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; (terphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[bis(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[phenyl(terphenylyl)triazinyl]indenocarbazole; (biphenylyl)[phenyl(biphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; phenyl[phenyl(biphenylyl)triazinyl]indenocarbazole; phenyl[phenyl(biphenylyl)triazinyl]indenocarbazole; phenyl[phenyl(terphenylyl)triazinyl]indenocarbazole; phenyl[(biphenylyl)(terphenylyl)triazinyl]indenocarbazole; (biphenylyl)[phenyl(biphenylyl)triazinyl]indenocarbazole; phenyl[bis(biphenylyl)triazinyl]indenocarbazole; phenyl[bis(biphenylyl)triazinyl]indenocarbazole; (biphenylyl)[phenyl(biphenylyl)triazinyl]indenocarbazole; phenyl(naphthalenyl)bi(carbazole); bi[(naphthalenyl)carbazole]; (biphenylyl)(naphthalenyl)bi(carbazole); (biphenylyl)(naphthalenyl)bi(carbazole); (terphenylyl)(naphthalenyl)bi(carbazole); [(naphthalenyl)phenyl](naphthalenyl)bi(carbazole); bi[(naphthalenyl)carbazole]; (phenanthrenyl)(naphthalenyl)bi(carbazole); (phenylanthracenyl)(naphthalenyl)bi(carbazole); phenyl(naphthalenyl)bi(carbazole); bi[(naphthalenyl)carbazole]; (biphenylyl)(naphthalenyl)bi(carbazole); (biphenylyl)(naphthalenyl)bi(carbazole); (terphenylyl)(naphthalenyl)bi(carbazole); [(naphthalenyl)phenyl](naphthalenyl)bi(carbazole); bi[(naphthalenyl)carbazole]; (phenanthrenyl)(naphthalenyl)bi(carbazole); (phenylanthracenyl)(naphthalenyl)bi(carbazole); phenyl(phenanthrenyl)bi(carbazole); (phenanthrenyl)(biphenylyl)bi(carbazole); (phenanthrenyl)(biphenylyl)bi(carbazole); (terphenylyl)(phenanthrenyl)bi(carbazole); (phenanthrenyl)[(naphthalenyl)phenyl]bi(carbazole); bi[(phenanthrenyl)carbazole]; (phenylanthracenyl)(phenanthrenyl)bi(carbazole); phenyl(naphthalenyl)bi(carbazole); bi[(naphthalenyl)carbazole]; phenyl(naphthalenyl)bi(carbazole); bi[(naphthalenyl)carbazole]; phenyl(phenanthrenyl)bi(carbazole); bi[(phenanthrenyl)carbazole]; phenyl(anthracenyl)bi(carbazole); bi[(anthracenyl)carbazole]; phenyl(naphthalenyl)bi(carbazole); bi[(naphthalenyl)carbazole]; phenyl(naphthalenyl)bi(carbazole); bi[(naphthalenyl)carbazole]; phenyl(phenanthrenyl)bi(carbazole); bi[(phenanthrenyl)carbazole]; phenyl(anthracenyl)bi(carbazole); bi[(anthracenyl)carbazole]; phenyl(naphthalenyl)bi(carbazole); bi[(naphthalenyl)carbazole]; phenyl(naphthalenyl)bi(carbazole); bi[(naphthalenyl)carbazole]; phenyl(phenanthrenyl)bi(carbazole); bi[(phenanthrenyl)carbazole]; phenyl(naphthalenyl)bi(carbazole); bi[(naphthalenyl)carbazole]; phenyl(naphthalenyl)bi(carbazole); phenyl(naphthalenyl)bi(carbazole); bi[(naphthalenyl)carbazole]; phenyl(naphthalenyl)bi(carbazole); phenyl(phenanthrenyl)bi(carbazole); bi[(phenanthrenyl)carbazole]; phenyl(phenanthrenyl)bi(carbazole); phenyl(anthracenyl)bi(carbazole); phenyl(naphthalenyl)bi(carbazole); phenyl(naphthalenyl)bi(carbazole); bi[(naphthalenyl)carbazole]; phenyl(naphthalenyl)bi(carbazole); phenyl(phenanthrenyl)bi(carbazole); phenyl(anthracenyl)bi(carbazole); phenyl(naphthalenyl)bi(carbazole); phenyl(naphthalenyl)bi(carbazole); bi[(naphthalenyl)carbazole]; phenyl(naphthalenyl)bi(carbazole); phenyl(naphthalenyl)bi(carbazole); bi[(naphthalenyl)carbazole]; phenyl(phenanthrenyl)bi(carbazole); phenyl(phenanthrenyl)bi(carbazole); bi[(phenanthrenyl)carbazole]; phenyl(anthracenyl)bi(carbazole); phenyl(anthracenyl)bi(carbazole); bi[(anthracenyl)carbazole]

### (Group 20A)

(dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [(biphenylyl)dibenzofuranyl](diphenyltriazinyl)terbenzene; [(biphenylyl)dibenzothiophenyl](diphenyltriazinyl)terbenzene; [(biphenylyl)dibenzoselenophenyl](diphenyltriazinyl)terbenzene; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[bis(biphenylyl)triazinyl]biphenyl; (dibenzothiophenyl)[bis(biphenylyl)triazinyl]biphenyl; (dibenzoselenophenyl)[bis(biphenylyl)triazinyl]biphenyl; (dibenzofuranyl)[phenyl(dimethylfluorenyl)triazinyl]biphenyl; (dibenzothiophenyl)[phenyl(dimethylfluorenyl)triazinyl]biphenyl; (dibenzoselenophenyl)[phenyl(dimethylfluorenyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(dimethylfluorenyl)triazinyl]biphenyl; (phenyldibenzothiophenyl)[phenyl(dimethylfluorenyl)triazinyl]biphenyl; (phenyldibenzoselenophenyl)[phenyl(dimethylfluorenyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]terbenzene; (dibenzothiophenyl)[phenyl(biphenylyl)triazinyl]terbenzene; (dibenzoselenophenyl)[phenyl(biphenylyl)triazinyl]terbenzene; (dibenzofuranyl)[phenyl(dimethylfluorenyl)triazinyl]terbenzene; (dibenzothiophenyl)[phenyl(dimethylfluorenyl)triazinyl]terbenzene; (dibenzoselenophenyl)[phenyl(dimethylfluorenyl)triazinyl]terbenzene; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(dimethylfluorenyl)triazinyl]biphenyl; [(biphenylyl)dibenzothiophenyl][phenyl(dimethylfluorenyl)triazinyl]biphenyl; [(biphenylyl)dibenzoselenophenyl][phenyl(dimethylfluorenyl)triazinyl]biphenyl; (diphenyltriazinyl)[(biphenylyl)dibenzofuranyl]terbenzene; (diphenyltriazinyl)[(biphenylyl)dibenzothiophenyl]terbenzene; (diphenyltriazinyl)[(biphenylyl)dibenzoselenophenyl]terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyldibenzofuranyl)(diphenyltriazinyl)biphenyl; (diphenyldibenzothiophenyl)(diphenyltriazinyl)biphenyl; (diphenyldibenzoselenophenyl)(diphenyltriazinyl)biphenyl; (diphenyldibenzofuranyl)(diphenyltriazinyl)biphenyl; (diphenyldibenzothiophenyl)(diphenyltriazinyl)biphenyl; (diphenyldibenzoselenophenyl)(diphenyltriazinyl)biphenyl; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; (phenyldibenzofuranyl)(diphenyltriazinyl)(pyridinyl)benzene; (phenyldibenzothiophenyl)(diphenyltriazinyl)(pyridinyl)benzene; (phenyldibenzoselenophenyl)(diphenyltriazinyl)(pyridinyl)benzene; [(pyridinyl)dibenzofuranyl](diphenyltriazinyl)biphenyl; [(pyridinyl)dibenzothiophenyl](diphenyltriazinyl)biphenyl; [(pyridinyl)dibenzoselenophenyl](diphenyltriazinyl)biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)(dimethylfluorenyl)benzene; (dibenzothiophenyl)(diphenyltriazinyl)(dimethylfluorenyl)benzene; (dibenzoselenophenyl)(diphenyltriazinyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terbenzene; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terbenzene; (diphenyltriazinyl)[bis(dimethylfluorenyl)]benzene; (diphenyltriazinyl)(dimethylfluorenyl)terbenzene; (diphenyltriazinyl)phenyldibenzofuran; (diphenyltriazinyl)phenyldibenzothiophene; (diphenyltriazinyl)phenyldibenzoselenophene; [phenyl(biphenylyl)triazinyl]phenyldibenzofuran; [phenyl(biphenylyl)triazinyl]phenyldibenzothiophene; [phenyl(biphenylyl)triazinyl]phenyldibenzoselenophene; [phenyl(biphenylyl)triazinyl]phenyldibenzofuran; [phenyl(biphenylyl)triazinyl]phenyldibenzothiophene; [phenyl(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; [bis(biphenylyl)triazinyl]phenyldibenzofuran; [bis(biphenylyl)triazinyl]phenyldibenzothiophene; [bis(biphenylyl)triazinyl]phenyldibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(biphenylyl)dibenzofuran (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophene]benzene; [phenyl(biphenylyl)triazinyl][(biphenylyl)dibenzoselenophene]benzene; [phenyl(biphenylyl)triazinyl][(biphenylyl)dibenzofuranyl]benzene; [phenyl(biphenylyl)triazinyl][(biphenylyl)dibenzothiophene]benzene; [phenyl(biphenylyl)triazinyl][(biphenylyl)dibenzoselenophene]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(dimethylfluorenyl)triazinyl](phenyldibenzofuran); [phenyl(dimethylfluorenyl)triazinyl](phenyldibenzothiophene); [phenyl(dimethylfluorenyl)triazinyl](phenyldibenzoselenophene); [(biphenylyl)(dimethylfluorenyl)triazinyl](phenyldibenzofuran); [(biphenylyl)(dimethylfluorenyl)triazinyl](phenyldibenzothiophene); [(biphenylyl)(dimethylfluorenyl)triazinyl](phenyldibenzoselenophene); [(biphenylyl)(dimethylfluorenyl)triazinyl](phenyldibenzofuran); [(biphenylyl)(dimethylfluorenyl)triazinyl](phenyldibenzothiophene); [(biphenylyl)(dimethylfluorenyl)triazinyl](phenyldibenzoselenophene); [phenyl(dimethylfluorenyl)triazinyl](phenyldibenzofuranyl)benzene; [phenyl(dimethylfluorenyl)triazinyl](phenyldibenzothiophenyl)benzene; [phenyl(dimethylfluorenyl)triazinyl](phenyldibenzoselenophenyl)benzene; [bis(dimethylfluorenyl)triazinyl](phenyldibenzofuranyl)benzene; [bis(dimethylfluorenyl)triazinyl](phenyldibenzothiophenyl)benzene; [bis(dimethylfluorenyl)triazinyl](phenyldibenzoselenophenyl)benzene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenylphenyl)triazinyl](phenyldibenzofuranyl)benzene; [phenyl(dimethylfluorenylphenyl)triazinyl](phenyldibenzothiophenyl)benzene; [phenyl(dimethylfluorenylphenyl)triazinyl](phenyldibenzoselenophenyl)benzene; [phenyl(dimethylfluorenyl)triazinyl]phenyldibenzofuran; [phenyl(dimethylfluorenyl)triazinyl]phenyldibenzothiophene; [phenyl(dimethylfluorenyl)triazinyl]phenyldibenzoselenophene; [phenyl(dimethylfluorenyl)triazinyl](biphenylyl)dibenzofuran; [phenyl(dimethylfluorenyl)triazinyl](biphenylyl)dibenzothiophene; [phenyl(dimethylfluorenyl)triazinyl](biphenylyl)dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenylphenyl)triazinyl](phenyldibenzofuranyl)benzene; [phenyl(dimethylfluorenylphenyl)triazinyl](phenyldibenzothiophenyl)benzene; [phenyl(dimethylfluorenylphenyl)triazinyl](phenyldibenzoselenophenyl)benzene; [phenyl(dimethylfluorenyl)triazinyl](phenyldibenzofuran); [phenyl(dimethylfluorenyl)triazinyl](phenyldibenzothiophene); [phenyl(dimethylfluorenyl)triazinyl](phenyldibenzoselenophene); phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; diphenyl[(diphenyltriazinyl)phenyl]dibenzofuran; diphenyl[(diphenyltriazinyl)phenyl]dibenzothiophene; diphenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; phenyl(diphenyltriazinyl)dibenzofuran; phenyl(diphenyltriazinyl)dibenzothiophene; phenyl(diphenyltriazinyl)dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; (biphenylyl)[(diphenyltriazinyl)phenyl]dibenzofuran; (biphenylyl)[(diphenyltriazinyl)phenyl]dibenzothiophene; (biphenylyl)[(diphenyltriazinyl)phenyl]dibenzoselenophene; phenyl[(diphenyltriazinyl)phenyl]dibenzofuran; phenyl[(diphenyltriazinyl)phenyl]dibenzothiophene; phenyl[(diphenyltriazinyl)phenyl]dibenzoselenophene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; [phenyl(phenylpyridinyl)triazinyl](phenyldibenzofuranyl)benzene; [phenyl(phenylpyridinyl)triazinyl](phenyldibenzothiophenyl)benzene; [phenyl(phenylpyridinyl)triazinyl](phenyldibenzoselenophenyl)benzene; (diphenyltriazinyl)[(biphenylyl)dibenzofuranyl)]pyridine; (diphenyltriazinyl)[(biphenylyl)dibenzothiophenyl)]pyridine; (diphenyltriazinyl)[(biphenylyl)dibenzoselenophenyl)]pyridine; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[phenyl(spiro[cyclohexanefluorene]yl)triazinyl]dibenzofuran; phenyl[phenyl(spiro[cyclohexanefluorene]yl)triazinyl]dibenzothiophene; phenyl[phenyl(spiro[cyclohexanefluorene]yl)triazinyl]dibenzoselenophene; phenyl[phenyl(spirobi[9H-fluorene]yl)triazinyl]dibenzofuran; phenyl[phenyl(spirobi[9H-fluorene]yl)triazinyl]dibenzothiophene; phenyl[phenyl(spirobi[9H-fluorene]yl)triazinyl]dibenzoselenophene; benzene-d₃[(diphenyl-d₁₀)triazinyl][(phenyl-d₅)dibenzofuranyl-d₆]; benzene-d₃[(diphenyl-d₁₀)triazinyl][(phenyl-d₅)dibenzothiophenyl-d₆]; benzene-d₃[(diphenyl-d₁₀)triazinyl][(phenyl-d₅)dibenzoselenophenyl-d₆]; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-de)dibenzothiophenyl-d₆]; benzene-d₃[(diphenyl-d₁₀)triazinyl][(biphenylyl-d₉)dibenzoselenophenyl-d₆]; phenyl{phenyl[(dimethyl-d₆)fluorenyl]triazinyl}dibenzofuran; phenyl{phenyl[(dimethyl-d₆)fluorenyl]triazinyl}dibenzothiophene; phenyl{phenyl[(dimethyl-d₆)fluorenyl]triazinyl}dibenzoselenophene; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-de)dibenzoselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (difluorophenyltriazinyl)[(biphenylyl)dibenzofuranyl]benzene; (difluorophenyltriazinyl)[(biphenylyl)dibenzothiophenyl]benzene; (difluorophenyltriazinyl)[(biphenylyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]pyridine; (diphenyltriazinyl)[(dimethylfluorenyl)dibenzothiophenyl]pyridine; (diphenyltriazinyl)[(dimethylfluorenyl)dibenzoselenophenyl]pyridine; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[bis(dimethylfluorenyl)dibenzofuranyl]benzene; (diphenyltriazinyl)[bis(dimethylfluorenyl)dibenzothiophenyl]benzene; (diphenyltriazinyl)[bis(dimethylfluorenyl)dibenzoselenophenyl]benzene; [phenyl(terphenyl)triazinyl][(dimethylfluorenyl)dibenzofuranyl]benzene; [phenyl(terphenyl)triazinyl][(dimethylfluorenyl)dibenzothiophenyl]benzene; [phenyl(terphenyl)triazinyl][(dimethylfluorenyl)dibenzoselenophenyl]benzene; (diphenyltriazinyl)[(spiro[cyclopentanefluorene]yl)dibenzofuranyl]benzene; (diphenyltriazinyl)[(spiro[cyclopentanefluorene]yl)dibenzothiophenyl]benzene; (diphenyltriazinyl)[(spiro[cyclopentanefluorene]yl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(phenyldimethylfluorenyl)dibenzofuranyl]benzene; (diphenyltriazinyl)[(phenyldimethylfluorenyl)dibenzothiophenyl]benzene; (diphenyltriazinyl)[(phenyldimethylfluorenyl)dibenzoselenophenyl]benzene; (diphenyltriazinyl){[(dimethyl-d₆)fluorenyl]dibenzofuranyl}benzene; (diphenyltriazinyl){[(dimethyl-d₆)fluorenyl]dibenzothiophenyl}benzene; (diphenyltriazinyl){[(dimethyl-d₆)fluorenyl]benzselenophenyl}benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)dibenzoselenophenyl]benzene; benzene-d₃[(diphenyl-d₁₀)triazinyl][(dimethylfluorenyl)dibenzofuranyl]; benzene-d₃[(diphenyl-d₁₀)triazinyl][(dimethylfluorenyl)dibenzothiophenyl]; benzene-d₃[(diphenyl-d₁₀)triazinyl][(dimethylfluorenyl)dibenzoselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]dibenzoselenophenyl}benzene; benzene-d₄[(diphenyl-d₁₀)triazinyl][(dimethylfluorenyl)dibenzofuranyl]; benzene-d₄(diphenyl-d₁₀)triazinyl][(dimethylfluorenyl)dibenzothiophenyl]; benzene-d₄[(diphenyl-d₁₀)triazinyl][(dimethylfluorenyl)dibenzoselenophenyl]; phenyl(triphenylenyl)bi[carbazole]; phenyl(triphenylenyl)bi[carbazole]; phenyl(triphenylenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; (biphenylyl)(dimethylfluorenyl)bi[carbazole]; (biphenylyl)(dimethylfluorenyl)bi[carbazole]; (terphenylyl)(dimethylfluorenyl)bi[carbazole]; diphenylter[carbazole]; diphenylter[carbazole]diphenylter[carbazole]phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; phenyl(phenyldibenzofuranyl)bi[carbazole]; phenyl(phenyldibenzothiophenyl)bi[carbazole]; phenyl(phenyldibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(benzofuropyridinyl)bi[carbazole]; phenyl(benzothienopyridinyl)bi[carbazole]; phenyl(benzselenopyridinyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; bi[phenylcarbazole];phenyl(biphenylyl)bi[carbazole]; phenyl(biphenylyl)bi[carbazole]; bi[(biphenylyl)carbazole];bi[(biphenylyl)carbazole];triphenylbi[carbazole]; bi[diphenylcarbazole]; phenyl[phenyl(biphenylyl)]bi[carbazole]; bi[phenylcarbazole];phenyl(biphenylyl)bi[carbazole]; phenyl(biphenylyl)bi[carbazole]; bi[(biphenylyl)carbazole];bi[(biphenylyl)carbazole]; bi[(biphenylyl)carbazole];triphenylbi[carbazole]; bi[diphenylcarbazole]; phenyl[phenyl(biphenylyl)]bi[carbazole]; phenyl(terphenylyl)bi[carbazole]; phenyl(terphenylyl)bi[carbazole]; phenyl(terphenylyl)bi[carbazole]; phenyl(diphenylpyridinyl)bi[carbazole]

### (Group 21A)

(dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; (phenyldibenzofuranyl)(diphenyltriazinyl)terbenzene; (phenyldibenzothiophenyl)(diphenyltriazinyl)terbenzene; (phenyldibenzoselenophenyl)(diphenyltriazinyl)terbenzene; [(biphenylyl)dibenzofuranyl](diphenyltriazinyl)terbenzene; [(biphenylyl)dibenzothiophenyl](diphenyltriazinyl)terbenzene; [(biphenylyl)dibenzoselenophenyl](diphenyltriazinyl)terbenzene; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[phenyl(biphenylyl)triazinyl]biphenyl; (dibenzothiophenyl)[phenyl(biphenylyl)triazinyl]biphenyl; (dibenzoselenophenyl)[phenyl(biphenylyl)triazinyl]biphenyl; (dibenzofuranyl)[bis(biphenylyl)triazinyl]biphenyl; (dibenzothiophenyl)[bis(biphenylyl)triazinyl]biphenyl; (dibenzoselenophenyl)[bis(biphenylyl)triazinyl]biphenyl; (dibenzofuranyl)[phenyl(dimethylfluorenyl)triazinyl]biphenyl; (dibenzothiophenyl)[phenyl(dimethylfluorenyl)triazinyl]biphenyl; (dibenzoselenophenyl)[phenyl(dimethylfluorenyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(biphenylyl)triazinyl]biphenyl; (phenyldibenzothiophenyl)[phenyl(biphenylyl)triazinyl]biphenyl; (phenyldibenzoselenophenyl)[phenyl(biphenylyl)triazinyl]biphenyl; (phenyldibenzofuranyl)[phenyl(dimethylfluorenyl)triazinyl]biphenyl; (phenyldibenzothiophenyl)[phenyl(dimethylfluorenyl)triazinyl]biphenyl; (phenyldibenzoselenophenyl)[phenyl(dimethylfluorenyl)triazinyl]biphenyl; (phenyldibenzofuranyl)[phenyl(biphenylyl)triazinyl]terbenzene; (phenyldibenzothiophenyl)[phenyl(biphenylyl)triazinyl]terbenzene; (phenyldibenzoselenophenyl)[phenyl(biphenylyl)triazinyl]terbenzene; (phenyldibenzofuranyl)[phenyl(biphenylyl)triazinyl]terbenzene; (phenyldibenzothiophenyl)[phenyl(biphenylyl)triazinyl]terbenzene; (phenyldibenzoselenophenyl)[phenyl(biphenylyl)triazinyl]terbenzene; (phenyldibenzofuranyl)[phenyl(dimethylfluorenyl)triazinyl]terbenzene; (phenyldibenzothiophenyl)[phenyl(dimethylfluorenyl)triazinyl]terbenzene; (phenyldibenzoselenophenyl)[phenyl(dimethylfluorenyl)triazinyl]terbenzene; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(biphenylyl)triazinyl]biphenyl; [(biphenylyl)dibenzothiophenyl][phenyl(biphenylyl)triazinyl]biphenyl; [(biphenylyl)dibenzoselenophenyl][phenyl(biphenylyl)triazinyl]biphenyl; [(biphenylyl)dibenzofuranyl][phenyl(dimethylfluorenyl)triazinyl]biphenyl; [(biphenylyl)dibenzothiophenyl][phenyl(dimethylfluorenyl)triazinyl]biphenyl; [(biphenylyl)dibenzoselenophenyl][phenyl(dimethylfluorenyl)triazinyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(phenyldibenzofuranyl)(pyridinyl)benzene; (diphenyltriazinyl)(phenyldibenzothiophenyl)(pyridinyl)benzene; (diphenyltriazinyl)(phenyldibenzoselenophenyl)(pyridinyl)benzene; (diphenyltriazinyl)(phenyldibenzofuranyl)(pyridinyl)benzene; (diphenyltriazinyl)(phenyldibenzothiophenyl)(pyridinyl)benzene; (diphenyltriazinyl)(phenyldibenzoselenophenyl)(pyridinyl)benzene; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terbenzene; (diphenyltriazinyl)(dibenzothiophenyl)terbenzene; (diphenyltriazinyl)(dibenzoselenophenyl)terbenzene; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terbenzene; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terbenzene; (diphenyltriazinyl)[bis(dimethylfluorenyl)]benzene; (diphenyltriazinyl)(dimethylfluorenyl)terbenzene; phenyl(diphenyltriazinyl)dibenzofuran; phenyl(diphenyltriazinyl)dibenzothiophene; phenyl(diphenyltriazinyl)dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[phenyl(biphenylyl)triazinyl]dibenzofuran; phenyl[phenyl(biphenylyl)triazinyl]dibenzothiophene; phenyl[phenyl(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; phenyl[bis(biphenylyl)triazinyl]dibenzofuran; phenyl[bis(biphenylyl)triazinyl]dibenzothiophene; phenyl[bis(biphenylyl)triazinyl]dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; [phenyl(biphenylyl)triazinyl](phenyldibenzofuranyl)benzene; [phenyl(biphenylyl)triazinyl](phenyldibenzothiophenyl)benzene; [phenyl(biphenylyl)triazinyl](phenyldibenzoselenophenyl)benzene; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; (diphenyltriazinyl)(biphenylyl)dibenzofuran (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl](biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)(biphenylyl)dibenzofuran; (diphenyltriazinyl)(biphenylyl)dibenzothiophene; (diphenyltriazinyl)(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl][(biphenylyl)dibenzoselenophene; [phenyl(biphenylyl)triazinyl](biphenylyl)dibenzofuran; [phenyl(biphenylyl)triazinyl](biphenylyl)dibenzothiophene; [phenyl(biphenylyl)triazinyl][(biphenylyl)dibenzoselenophene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; [phenyl(biphenylyl)triazinyl][(biphenylyl)dibenzofuranyl]benzene; [phenyl(biphenylyl)triazinyl][(biphenylyl)dibenzothiophenyl]benzene; [phenyl(biphenylyl)triazinyl][(biphenylyl)dibenzoselenophenyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; phenyl[(biphenylyl)(dimethylfluorenyl)triazinyl]dibenzofuran; phenyl[(biphenylyl)(dimethylfluorenyl)triazinyl]dibenzothiophene; phenyl[(biphenylyl)(dimethylfluorenyl)triazinyl]dibenzoselenophene; [phenyl(dimethylfluorenyl)triazinyl](phenyldibenzofuranyl)benzene; [phenyl(dimethylfluorenyl)triazinyl](phenyldibenzothiophenyl)benzene; [phenyl(dimethylfluorenyl)triazinyl](phenyldibenzoselenophenyl)benzene; [bis(dimethylfluorenyl)triazinyl](phenyldibenzofuranyl)benzene; [bis(dimethylfluorenyl)triazinyl](phenyldibenzothiophenyl)benzene; [bis(dimethylfluorenyl)triazinyl](phenyldibenzoselenophenyl)benzene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; phenyl[phenyl(phenyldimethylfluorenyl)triazinyl]dibenzofuran; phenyl[phenyl(phenyldimethylfluorenyl)triazinyl]dibenzothiophene; phenyl[phenyl(phenyldimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; (biphenylyl)[phenyl(dimethylfluorenyl)triazinyl]dibenzofuran; (biphenylyl)[phenyl(dimethylfluorenyl)triazinyl]dibenzothiophene; (biphenylyl)[phenyl(dimethylfluorenyl)triazinyl]dibenzoselenophene; [phenyl(dimethylfluorenyl)triazinyl][(biphenylyl)dibenzofuranyl]benzene; [phenyl(dimethylfluorenyl)triazinyl][(biphenylyl)dibenzothiophenyl]benzene; [phenyl(dimethylfluorenyl)triazinyl][(biphenylyl)dibenzoselenophenyl]benzene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl[phenyl(dimethylfluorenyl)triazinyl]dibenzofuran; phenyl[phenyl(dimethylfluorenyl)triazinyl]dibenzothiophene; phenyl[phenyl(dimethylfluorenyl)triazinyl]dibenzoselenophene; phenyl(diphenyltriazinyl)dibenzofuran; phenyl(diphenyltriazinyl)dibenzothiophene; phenyl(diphenyltriazinyl)dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)(diphenyldibenzofuranyl)benzene; (diphenyltriazinyl)(diphenyldibenzothiophenyl)benzene; (diphenyltriazinyl)(diphenyldibenzoselenophenyl)benzene; phenyl(diphenyltriazinyl)dibenzofuran; phenyl(diphenyltriazinyl)dibenzothiophene; phenyl(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (biphenylyl)(diphenyltriazinyl)dibenzofuran; (biphenylyl)(diphenyltriazinyl)dibenzothiophene; (biphenylyl)(diphenyltriazinyl)dibenzoselenophene; (diphenyltriazinyl)(diphenyldibenzofuranyl)benzene; (diphenyltriazinyl)(diphenyldibenzothiophenyl)benzene; (diphenyltriazinyl)(diphenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; phenyl(diphenyltriazinyl)dibenzofuran; phenyl(diphenyltriazinyl)dibenzothiophene; phenyl(diphenyltriazinyl)dibenzoselenophene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)[(biphenylyl)dibenzofuranyl]benzene; (diphenyltriazinyl)[(biphenylyl)dibenzothiophenyl]benzene; (diphenyltriazinyl)[(biphenylyl)dibenzoselenophenyl]benzene; (diphenyltriazinyl)(phenyldibenzofuranyl)benzene; (diphenyltriazinyl)(phenyldibenzothiophenyl)benzene; (diphenyltriazinyl)(phenyldibenzoselenophenyl)benzene; (diphenyltriazinyl)(phenyldibenzofuranyl)pyridine; (diphenyltriazinyl)(phenyldibenzothiophenyl)pyridine; (diphenyltriazinyl)(phenyldibenzoselenophenyl)pyridine; [phenyl(phenylpyridinyl)triazinyl](phenyldibenzofuranyl)pyridine; [phenyl(phenylpyridinyl)triazinyl](phenyldibenzothiophenyl)pyridine; [phenyl(phenylpyridinyl)triazinyl](phenyldibenzoselenophenyl)pyridine; [phenyl(phenylpyridinyl)triazinyl](phenyldibenzofuranyl)benzene; [phenyl(phenylpyridinyl)triazinyl](phenyldibenzothiophenyl)benzene; [phenyl(phenylpyridinyl)triazinyl](phenyldibenzoselenophenyl)benzene; (diphenyltriazinyl)[(biphenylyl)dibenzofuranyl]pyridine; (diphenyltriazinyl)[(biphenylyl)dibenzothiophenyl]pyridine; (diphenyltriazinyl)[(biphenylyl)dibenzoselenophenyl]pyridine; phenyl[phenyl(dimethylbenzofuropyridine)triazinyl]dibenzofuran; phenyl[phenyl(dimethylbenzothienopyridine)triazinyl]dibenzothiophene; phenyl[phenyl(dimethylbenzselenopyridine)triazinyl]dibenzoselenophene; [(biphenylyl)(dimethylbenzofuropyridine)triazinyl]dibenzofuran; [(biphenylyl)(dimethylbenzothienopyridine)triazinyl]dibenzothiophene; [(biphenylyl)(dimethylbenzselenopyridine)triazinyl]dibenzoselenophene; phenyl[phenyl(dimethylbenzofuropyridine)triazinyl]dibenzofuran; phenyl[phenyl(dimethylbenzothienopyridine)triazinyl]dibenzothiophene; phenyl[phenyl(dimethylbenzselenopyridine)triazinyl]dibenzoselenophene; phenyl[phenyl(spiro[cyclohexanefluorene]yl)triazinyl]dibenzofuran; phenyl[phenyl(spiro[cyclohexanefluorene]yl)triazinyl]dibenzothiophene; phenyl[phenyl(spiro[cyclohexanefluorene]yl)triazinyl]dibenzoselenophene; phenyl[phenyl(spirobi[fluorene]yl)triazinyl]dibenzofuran; phenyl[phenyl(spirobi[fluorene]yl)triazinyl]dibenzothiophene; phenyl[phenyl(spirobi[fluorene]yl)triazinyl]dibenzoselenophene; benzene-d₃[(diphenyl-d₁₀)triazinyl][(phenyl-d₅)dibenzofuranyl-d₆]; benzene-d₃[(diphenyl-d₁₀)triazinyl][(phenyl-d₅)dibenzothiophenyl-d₆]; benzene-d₃[(diphenyl-d₁₀)triazinyl][(phenyl-d₅)dibenzoselenophenyl-d₆]; benzene-d₃[(diphenyl-d₁₀)triazinyl][(biphenylyl-de)dibenzofuranyl-d₆]; benzene-d₃[(diphenyl-d₁₀)triazinyl][(biphenylyl-d₉)dibenzothiophenyl-d₆]; benzene-d₃[(diphenyl-d₁₀)triazinyl][(biphenylyl-d₅)dibenzoselenophenyl-d₆]; phenyl{phenyl[(dimethyl-d₆)fluorenyl]triazinyl}dibenzofuran; phenyl{phenyl[(dimethyl-d₆)fluorenyl]triazinyl}dibenzothiophene; phenyl{phenyl[(dimethyl-d₆)fluorenyl]triazinyl}dibenzoselenophene; benzene-d₃[(diphenyl-d₁₀)triazinyl][(biphenylyl-d₉)dibenzofuranyl-d₆]; benzene-d₃[(diphenyl-d₁₀)triazinyl][(biphenylyl-de)dibenzothiophenyl-d₆]; benzene-d₃[(diphenyl-d₁₀)triazinyl][(biphenylyl-d₉)dibenzoselenophenyl-d₆]; [(diphenyl-d₁₀)triazinyl][(biphenylyl)dibenzofuranyl]benzene; [(diphenyl-d₁₀)triazinyl][(biphenylyl)dibenzothiophenyl]benzene; [(diphenyl-d₁₀)triazinyl][(biphenylyl)dibenzoselenophenyl]benzene; (diphenyltriazinyl)[(biphenylyl)dibenzofuranyl]biphenyl; (diphenyltriazinyl)[(biphenylyl)dibenzothiophenyl]biphenyl; (diphenyltriazinyl)[(biphenylyl)dibenzoselenophenyl]biphenyl; (difluorophenyltriazinyl)[(biphenylyl)dibenzofuranyl]benzene; (difluorophenyltriazinyl)[(biphenylyl)dibenzothiophenyl]benzene; (difluorophenyltriazinyl)[(biphenylyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; (diphenyltriazinyl)[(dimethylfluorenyl)dibenzofuranyl]pyridine; (diphenyltriazinyl)[(dimethylfluorenyl)dibenzothiophenyl]pyridine; (diphenyltriazinyl)[(dimethylfluorenyl)dibenzoselenophenyl]pyridine; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]biphenyl; (diphenyltriazinyl)[(dimethylfluorenyl)dibenzothiophenyl]biphenyl; (diphenyltriazinyl)[(dimethylfluorenyl)dibenzoselenophenyl]biphenyl; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(biphenylyl)triazinyl][(dimethylfluorenyl)dibenzofuranyl]benzene; [phenyl(biphenylyl)triazinyl][(dimethylfluorenyl)dibenzothiophenyl]benzene; [phenyl(biphenylyl)triazinyl][(dimethylfluorenyl)dibenzoselenophenyl]benzene; [phenyl(dimethylfluorenyl)triazinyl][(dimethylfluorenyl)dibenzofuranyl]benzene; [phenyl(dimethylfluorenyl)triazinyl][(dimethylfluorenyl)dibenzothiophenyl]benzene; [phenyl(dimethylfluorenyl)triazinyl][(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[bis(dimethylfluorenyl)dibenzofuranyl]benzene; (diphenyltriazinyl)[bis(dimethylfluorenyl)dibenzothiophenyl]benzene; (diphenyltriazinyl)[bis(dimethylfluorenyl)dibenzoselenophenyl]benzene; [phenyl(terphenylyl)triazinyl][(dimethylfluorenyl)dibenzofuranyl]benzene; [phenyl(terphenylyl)triazinyl][(dimethylfluorenyl)dibenzothiophenyl]benzene; [phenyl(terphenylyl)triazinyl][(dimethylfluorenyl)dibenzoselenophenyl]benzene; (diphenyltriazinyl)[(spiro[cyclopentanefluorene]yl)dibenzofuranyl]benzene; (diphenyltriazinyl)[(spiro[cyclopentanefluorene]yl)dibenzothiophenyl]benzene; (diphenyltriazinyl)[(spiro[cyclopentanefluorene]yl)dibenzoselenophenyl]benzene; (diphenyltriazinyl)[(diphenylfluorenyl)dibenzofuranyl]benzene; (diphenyltriazinyl)[(diphenylfluorenyl)dibenzothiophenyl]benzene; (diphenyltriazinyl)[(diphenylfluorenyl)dibenzoselenophenyl]benzene; (diphenyltriazinyl)[(spirobi[fluorene]yl)dibenzofuranyl]benzene; (diphenyltriazinyl)[(spirobi[fluorene]yl)dibenzothiophenyl]benzene; (diphenyltriazinyl)[(spirobi[fluorene]yl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(phenyldimethylfluorenyl)dibenzofuranyl]benzene; (diphenyltriazinyl)[(phenyldimethylfluorenyl)dibenzothiophenyl]benzene; (diphenyltriazinyl)[(phenyldimethylfluorenyl)dibenzoselenophenyl]benzene; (diphenyltriazinyl){[(dimethyl-d₆)fluorenyl]dibenzofuranyl}benzene; (diphenyltriazinyl){[(dimethyl-d₆)fluorenyl]dibenzothiophenyl}benzene; (diphenyltriazinyl){[(dimethyl-d₆)fluorenyl]dibenzoselenophenyl}benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[phenyl(dimethylfluorenyl)dibenzofuranyl]benzene; (diphenyltriazinyl)[phenyl(dimethylfluorenyl)dibenzothiophenyl]benzene; (diphenyltriazinyl)[phenyl(dimethylfluorenyl)dibenzoselenophenyl]benzene; (diphenyltriazinyl)[(dimethylfluorenyl)dibenzofuranyl]benzene; (diphenyltriazinyl)[(dimethylfluorenyl)dibenzothiophenyl]benzene; (diphenyltriazinyl)[(dimethylfluorenyl)dibenzoselenophenyl]benzene; [(diphenyl-d₁₀)triazinyl][(dimethylfluorenyl)dibenzofuranyl]benzene; [(diphenyl-d₁₀)triazinyl][(dimethylfluorenyl)dibenzothiophenyl]benzene; [(diphenyl-d₁₀)triazinyl][(dimethylfluorenyl)dibenzoselenophenyl]benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)dibenzoselenophenyl]; [(diphenyl-d₁₀)triazinyl]{[(dimethyl-d₆)fluorenyl]dibenzofuranyl}benzene; [(diphenyl-d₁₀)triazinyl]{[(dimethyl-d₆)fluorenyl]dibenzothiophenyl}benzene; [(diphenyl-d₁₀)triazinyl]{[(dimethyl-d₆)fluorenyl]dibenzoselenophenyl}benzene; benzene-d₄[(diphenyl-d₁₀)triazinyl][(dimethylfluorenyl)dibenzofuranyl]; benzene-d₄[(diphenyl-d₁₀)triazinyl][(dimethylfluorenyl)dibenzothiophenyl]; benzene-d₄[(diphenyl-d₁₀)triazinyl][(dimethylfluorenyl)dibenzoselenophenyl]; [bis(carbazole)yl]benzofuropyridine; [bis(carbazole)yl]benzothienopyridine; [bis(carbazole)yl]benzselenopyridine; [bis(carbazole)yl]benzofuropyridine; [bis(carbazole)yl]benzothienopyridine; [bis(carbazole)yl]benzselenopyridine; [bis(carbazole)yl]benzofuropyridine; [bis(carbazole)yl]benzothienopyridine; [bis(carbazole)yl]benzselenopyridine; [bis(carbazole)yl]benzofuropyridine; [bis(carbazole)yl]benzothienopyridine; [bis(carbazole)yl]benzselenopyridine; (triphenylenyl)(carbazolyl)benzofuropyridine; (triphenylenyl)(carbazolyl)benzothienopyridine; (triphenylenyl)(carbazolyl)benzselenopyridine; (dibenzothiophenyl)(carbazolyl)benzofuropyridine; (dibenzothiophenyl)(carbazolyl)benzothienopyridine; (dibenzothiophenyl)(carbazolyl)benzselenopyridine; phenyl(triphenylenyl)benzofuropyridine; phenyl(triphenylenyl)benzothienopyridine; phenyl(triphenylenyl)benzselenopyridine; phenyl(triphenylenyl)benzofuropyridine; phenyl(triphenylenyl)benzothienopyridine; phenyl(triphenylenyl)benzselenopyridine; phenyl(triphenylenyl)bi[carbazole]; phenyl(triphenylenyl)bi[carbazole]; phenyl(triphenylenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; phenyl(dimethylfluorenyl)bi[carbazole]; (biphenylyl)(dimethylfluorenyl)bi[carbazole]; (biphenylyl)(dimethylfluorenyl)bi[carbazole]; (terphenylyl)(dimethylfluorenyl)bi[carbazole]; diphenyl(ter[carbazole]); diphenyl(ter[carbazole]); diphenyl(ter[carbazole]); bi(phenylcarbazole); phenyl(biphenylyl)bi[carbazole]; phenyl(biphenylyl)bi[carbazole]; bi[(biphenylyl)carbazole]; bi[(biphenylyl)carbazole]; triphenylbi[carbazole]; bi[diphenylcarbazole]; diphenyl(biphenylyl)bi[carbazole]:bi[phenylcarbazole]; phenyl(biphenylyl)bi[carbazole]; phenyl(biphenylyl)bi[carbazole]; bi[(biphenylyl)carbazole]; bi[(biphenylyl)carbazole]; triphenylbi[carbazole]; bi[diphenylcarbazole]; diphenyl(biphenylyl)bi[carbazole]:phenyl(terphenylyl)bi[carbazole]; phenyl(terphenylyl)bi[carbazole]; phenyl(terphenylyl)bi[carbazole]; phenyl(diphenylpyridinyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (phenylcarbazolyl)(dibenzofuranyl)fluorene; (phenylcarbazolyl)(dibenzothiophenyl)fluorene; (phenylcarbazolyl)(dibenzoselenophenyl)fluorene; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; (biphenylyl)(dibenzofuranyl)bi[carbazole]; (biphenylyl)(dibenzothiophenyl)bi[carbazole]; (biphenylyl)(dibenzoselenophenyl)bi[carbazole]; phenyl(phenyldibenzofuranyl)bi[carbazole]; phenyl(phenyldibenzothiophenyl)bi[carbazole]; phenyl(phenyldibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; phenyl(dibenzofuranyl)bi[carbazole]; phenyl(dibenzothiophenyl)bi[carbazole]; phenyl(dibenzoselenophenyl)bi[carbazole]; (naphthalenyl)(dibenzofuranyl)bi[carbazole]; (naphthalenyl)(dibenzothiophenyl)bi[carbazole]; (naphthalenyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (dimethylfluorenyl)(dibenzofuranyl)bi[carbazole]; (dimethylfluorenyl)(dibenzothiophenyl)bi[carbazole]; (dimethylfluorenyl)(dibenzoselenophenyl)bi[carbazole]; (triphenylenyl)dibenzofuran; (triphenylenyl)dibenzothiophene; (triphenylenyl)dibenzoselenophene; (triphenylenyl)(dibenzofuranyl)benzene; (triphenylenyl)(dibenzothiophenyl)benzene; (triphenylenyl)(dibenzoselenophenyl)benzene; (triphenylenyl)(phenyldibenzofuranyl)benzene; (triphenylenyl)(phenyldibenzothiophenyl)benzene; (triphenylenyl)(phenyldibenzoselenophenyl)benzene; (triphenylenyl)(dibenzofuranyl)biphenyl; (triphenylenyl)(dibenzothiophenyl)biphenyl; (triphenylenyl)(dibenzoselenophenyl)biphenyl; phenyl(triphenylenyl)dibenzofuran; phenyl(triphenylenyl)dibenzothiophene; phenyl(triphenylenyl)dibenzoselenophene; (biphenylyl)(triphenylenyl)dibenzofuran; (biphenylyl)(triphenylenyl)dibenzothiophene; (biphenylyl)(triphenylenyl)dibenzoselenophene; (terphenylyl)(triphenylenyl)dibenzofuran; (terphenylyl)(triphenylenyl)dibenzothiophene; (terphenylyl)(triphenylenyl)dibenzoselenophene; (biphenylyl)[(triphenylenyl)phenyl]dibenzofuran; (biphenylyl)[(triphenylenyl)phenyl]dibenzothiophene; (biphenylyl)[(triphenylenyl)phenyl]dibenzoselenophene; (carbazolyl)(triphenylenyl)dibenzofuran; (carbazolyl)(triphenylenyl)dibenzothiophene; (carbazolyl)(triphenylenyl)dibenzoselenophene; (carbazolyl)(triphenylenyl)biphenyl; (carbazolyl)(triphenylenyl)biphenyl; iridium(III)tris[phenylpyridine-N,C′]; iridium(III)tris[methyl(phenyl)pyridine-N,C′]; iridium(III)tris[(methyl-d₃)(phenyl)pyridine-N,C′]; iridium(III)tris[(dimethyl-d₆)(phenyl)pyridine-N,C′]; iridium(III)tris[(methyl-d₆)(diphenyl)pyridine-N,C′]; iridium(III)tris[(pyridinyl)biphenyl-N,C′]; iridium(III)tris[(methylpyridinyl)biphenyl-N,C′]; iridium(III)bis(phenylpyridine-N,C′[(pyridinyl)biphenyl-N,C′]; iridium(III)bis(phenylpyridine-N,C′[(pyridinyl)biphenyl-N,C′]; iridium(III)bis(phenylpyridine-N,C′[(methylpyridinyl)biphenyl-N,C′]; iridium(III)bis(phenylpyridine-N,C′[(methylpyridinyl)biphenyl-N,C′]; iridium(III)bis(phenylpyridine-N,C′{[(methyl-d₃)pyridinyl]biphenyl-N,C′}; iridium(III)bis(phenylpyridine-N,C′[(methyl)(diphenyl)pyridine-N,C′]; iridium(III)bis(phenylpyridine-N,C′[(methyl-d₃)(diphenyl)pyridine-N,C′]; iridium(III)bis(phenylpyridine-N,C′[ethane-d₃-(diphenyl)pyridine-N,C′]; iridium(III)bis(phenylpyridine-N,C′[(methyl)(diphenyl)pyridine-N,C′]; iridium(III)bis[(methyl)(phenyl)pyridine-N,C′][(methyl)(phenyl)(naphthalenyl)pyridine-N,C′]; iridium(III)bis[(methyl)(phenyl)pyridine-N,C′][(methyl)(diphenyl)pyridine-N,C′]; iridium(II)bis[(methyl)(phenyl)pyridine-N,C′][diphenylpyridine-N,C′]; iridium(III)bis{[(methylphenyl-d₃)pyridine-d₄]—N,C′}{[(diphenyl-d₉)pyridine-d₄]—N,C′}; iridium(III)bis[(methyl)(phenyl)pyridine-N,C′][diphenylpyridine-N,C′]; iridium(III)bis[(methyl-d₃)(phenyl)pyridine-N,C′][diphenylpyridine-N,C′]; iridium(III)bis[phenylpyridine-N,C′][(methyl)(diphenyl)pyridine-N,C′]; iridium(III)bis[phenylpyridine-N,C′][(methyl-d₃)(diphenyl)pyridine-N,C′]; iridium(III)bis[phenylpyridine-N,C′][(ethyl)(diphenyl)pyridine-N,C′]; iridium(III)bis[phenylpyridine-N,C′][(methyl)(phenyl)(fluorophenyl)pyridine-N,C′]; iridium(III)bis[phenylpyridine-N,C′][(dibenzofuranyl)pyridine-N,C′]; iridium(III)bis[phenylpyridine-N,C′][(isopropyl)(dibenzofuranyl)pyridine-N,C′]; iridium(III)bis[(methyl)(phenyl)pyridine-N,C′][(isopropyl)(dibenzofuranyl)pyridine-N,C′]; iridium(III)bis[phenylpyridine-N,C′][(isopropyl-d₇)(dibenzofuranyl)pyridine-N,C′]; iridium(III)bis[(methyl-d₃)(phenyl)pyridine-N,C′][(isopropyl-d₇)(dibenzofuranyl)pyridine-N,C′]; iridium(III)bis[(methyl-d₃)(phenyl)pyridine-N,C′][(methyl-d₃)(diphenyl)pyridine-N,C′]; iridium(III)bis[phenylpyridine-N,C′][(isopropyl)(isopropylbenzofuropyridinyl)pyridine-N,C′]; iridium(III)bis[phenylpyridine-N,C′][(benzofuropyridinyl)pyridine-N,C′]; iridium(III)bis[phenylpyridine-N,C′][(benzofuropyridinyl)pyridine-N,C′]; iridium(III)bis[phenylpyridine-N,C′][(methylbenzofuropy ridinyl)pyridine-N,C′]; iridium(III)bis[phenylpyridine-N,C′]{[(methyl-d₃)benzofuropy ridinyl]pyridine-N,C′}; iridium(III)bis[phenylpyridine-N,C′][(methylbenzofuropyridinyl)pyridine-N,C′]; iridium(III)bis[phenylpyridine-N,C′]{[(methyl-d₃)benzofuropyridinyl]pyridine-N,C′}; iridium(III)bis[(methyl-d₃)(phenyl)pyridine-N,C′]{[(methyl-d₃)benzofuropyridinyl]pyridine-N,C′}; iridium(III)bis[(methyl-d₃)(phenyl)pyridine-N,C′][(isopropyl-d₇)(benzofuropyridinyl)pyridine-N,C′]; iridium(III)bis[(methyl-d₃)(phenyl)pyridine-N,C′]{(isopropyl-d₇)[(methyl-d₃)benzofuropyridinyl]pyridine-N,C′}; iridium(III)bis[(isopropyl-d₇)(phenyl)pyridine-N,C′]{(isopropyl-d₇)[(methyl-d₃)benzofuropyridinyl]pyridine-N,C′}; iridium(III)bis[(methyl-d₃)(phenyl)pyridine-N,C′][(isopropyl-di)(benzofuropyridinyl)pyridine-N,C′]; iridium(III)bis[(methyl-d₃)(phenyl)pyridine-N,C′]{(isopropyl-d₁)[(methyl-d₃)benzofuropyridinyl]pyridine-N,C′}; iridium(III)bis[(methyl-d₃)(phenyl)pyridine-N,C′][(isopropyl)(methyl-d₃)(benzofuropyridinyl)pyridine-N,C′]; iridium(III)bis[(methyl-d₃)(phenyl)pyridine-N,C′][(isopropyl-d₁)(methyl-d₃)(benzofuropyridinyl)pyridine-N,C′]; iridium(III)bis[(dimethyl-d₆)(phenyl)pyridine-N,C′]{(isopropyl-d₇)[(methyl-d₃)benzofuropyridinyl]pyridine-N,C′}; iridium(III)bis[(dimethyl-d₆)(phenyl)pyridine-N,C′]{(isopropyl)(methyl-d₃)[(methyl-d₃)benzofuropyridinyl]pyridine-N,C′}; iridium(III)bis[(dimethyl-d₆)(phenyl)pyridine-N,C′]{(isopropyl-d₇)(methyl-d₃)[(methyl-d₃)benzofuropyridinyl]pyridine-N,C′}; iridium(III)bis[(dimethyl-d₆)(phenyl)pyridine-N,C′]{(isopropyl-d₇)(methyl-d₃)[(methyl-d₃)benzofuropyridinyl]pyridine-N,C′}; iridium(III)bis[(methyl-d₃)(phenyl)pyridine-N,C′]{(isopropyl-d₇)(methyl-d₃)[(methyl-d₃)benzofuropyridinyl]pyridine-N,C′}; iridium(III)bis(phenylpyridine-N,C′{[(dimethyl-d₆)benzofuropyridinyl]pyridine-N,C′}; iridium(III)bis[(dimethyl-d₆)(phenyl)pyridine-N,C′]{(isopropyl)[(isopropyl)benzofuropy ridinyl]pyridine-N,C′}; iridium(III)bis[(dimethyl-d₆)(phenyl)pyridine-N,C′]{(isopropyl-d₁)[(isopropyl-d₁)benzofuropy ridinyl]pyridine-N,C′}; iridium(III)bis[(methyl-d₃)(phenyl)pyridine-N,C′]{(isopropyl-d₁)[(isopropyl-d₁)benzofuropyridinyl]pyridine-N,C′}; iridium(III)bis[(phenyl)pyridine-N,C′]{[(dimethyl-d₆)benzofuropyridinyl]pyridine-N,C′}; iridium(III)bis[(phenyl)pyridine-N,C′]{[(dimethyl-d₆)benzofuropyridinyl]pyridine-N,C′}; iridium(III)bis[(methyl-d₃)(phenyl)pyridine-N,C′][diphenylpyridine-N,C′]; iridium(III)bis[phenylpyridine-N,C′][diphenylpyridine-N,C′]; iridium(III)bis{[methyl(phenyl-d₃)](pyridine-d₄)—N,C′]{[(diphenyl-d₉)(pyridine-d₃)]—N,C′}; iridium(III)bis[phenylpyridine-N,C′]{phenyl[(methyl-d₃)phenyl]pyridine-N,C′]; iridium(III)bis[(methyl)(phenyl)pyridine-N,C′][diphenylpyridine-N,C′]; iridium(III)bis[(dimethyl)(phenyl)pyridine-N,C′][diphenylpyridine-N,C′]; iridium(III)bis[(dimethyl)(phenyl)pyridine-N,C′]{phenyl[(methyl-d₃)phenyl]pyridine-N,C′]; iridium(III)bis[(dimethyl-d₆)(phenyl)pyridine-N,C′][diphenylpyridine-N,C′]; iridium(III)bis[(methyl)(phenyl)pyridine-N,C′][diphenylpyridine-N,C′]; iridium(III)bis[(phenyl)pyridine-N,C′][(fluorophenyl)(methylbenzofuropyridinyl)pyridine-N,C′]; iridium(III)bis[(phenyl)pyridine-N,C′][(fluorophenyl)(methylbenzofuropyridinyl)pyridine-N,C′]; iridium(III)bis[(phenyl)pyridine-N,C′]{(fluorophenyl)[(methyl-d₃)benzofuropyridinyl]pyridine-N,C′}; iridium(III)bis[(phenyl)pyridine-N,C′]{(fluorophenyl)[(methyl-d₃)benzofuropyridinyl]pyridine-N,C′}; iridium(III)bis[(phenyl)pyridine-N,C′]{(phenyl)[(methyl-d₃)benzofuropyridinyl]pyridine-N,C′}; iridium(II)bis[(phenyl)pyridine-N,C′][phenylbipyridine-N,C′]; iridium(III)bis[(isopropylphenyl)pyridine-N,C′][(fluorophenyl)(methylbenzofuropyridinyl)pyridine-N,C′]; iridium(III)bis{[(isopropyl-d₇)phenyl]pyridine-N,C′}{(fluorophenyl)[(methyl-d₃)benzofuropyridinyl]pyridine-N,C′}; iridium(III)bis{[(isopropyl-d₇)phenyl]pyridine-N,C′}{(fluorophenyl)[(methyl-d₃)benzofuropyridinyl]pyridine-N,C′}; iridium(III)bis{[(methylphenyltriazinyl)phenyl]pyridine-N,C′}iridium(III)bis[phenylquinoline-N,C′](acetylacetonate); iridium(III)bis[(methyl)(methylphenyl)quinoline-N,C′](acetylacetonate); iridium(III)bis[(methyl)(methylphenyl)quinoline-N,C′](diethylnonanedionate); iridium(III)bis[(methyl)(methylphenyl)quinoline-N,C′](methyldiethylnonanedionate); iridium(III)bis[(dimethylphenyl)quinoline-N,C′](acetylacetonate); iridium(III)bis[(isobutyl)(dimethylphenyl)quinoline-N,C′](acetylacetonate); iridium(III)bis[(isobutyl)(methylphenyl)quinoline-N,C′](dimethylnonanedionate); iridium(III)bis[(isobutyl)(methylphenyl)quinoline-N,C′](dimethylheptanedionate); iridium(II)bis[(isobutyl)(dimethylphenyl)quinoline-N,C′](acetylacetonate); iridium(II)bis[(isobutyl)(dimethylphenyl)quinoline-N,C′](dimethylnonanedionate); iridium(III)bis[(phenyl)quinoline-N,C′](diethylnonanedionate); iridium(II)bis[(Isopentyl)(dimethylphenyl)quinoline-N,C′](diethylnonanedionate); iridium(II)bis[(isobutyl)(dimethylphenyl)quinoline-N,C′](diethylnonanedionate); iridium(II)bis[(isobutyl)(dimethylphenyl)quinoline-N,C′](bis[cyclopentyl]acetylacetonate); iridium(II)bis[(isobutyl)(dimethylphenyl)quinoline-N,C′](bis[cyclohexyl]acetylacetonate); iridium(II)bis[(diisobutyl)(dimethylphenyl)quinoline-N,C′](acetylacetonate); iridium(II)bis[(dimethyl)(dimethylphenyl)quinoline-N,C′](ethylmethyldecanedionate); iridium(II)bis[(dimethyl)(dimethylphenyl)quinoline-N,C′](dimethylnonanedionate); iridium(III)bis[(dimethyl)[(dimethyl-d₆)phenyl]quinoline-N,C′](acetylacetonate); iridium(III)bis[methyl(diphenyl)dibenzoquinoxaline-N,C′](acetylacetonate); iridium(III)bis[(phenyl)quinoline-N,C′](acetylacetonate); iridium(II)bis[(phenyl)isoquinoline-N,C′](acetylacetonate); iridium(III)bis[(cyclobutyl)(dimethylphenyl)quinoline-N,C′](diethylnonanedionate); iridium(III)bis[(cyclopentyl)(dimethylphenyl)quinoline-N,C′](diethylnonanedionate); iridium(III)bis[(cyclobutyl)(dimethylphenyl)quinoline-N,C′](methyldiethylnonanedionate); iridium(III)bis[(cyclopentyl)(dimethylphenyl)quinoline-N,C′](methyldiethylnonanedionate); iridium(III)bis[(cyclohexyl)(methylphenyl)quinoline-N,C′](acetylacetonate); iridium(III)bis[(methylphenyl)(dimethylphenyl)quinoline-N,C′](diethylnonanedionate); iridium(III)bis[(trifluoropropyl)(dimethylphenyl)quinoline-N,C′](diethylnonanedionate); iridium(IIII)bis[(trifluoropropyl)(dimethylphenyl)quinoline-N,C′](acetylacetonate); iridium(II)bis[(trifluoropropyl)(dimethylphenyl)quinoline-N,C′][bis(cyclopentyl)acetylacetonate]; iridium(III)bis[(trifluoropropyl)(dimethylphenyl)quinoline-N,C′][bis(cyclohexyl)acetylacetonate]; iridium(III)bis[(trifluoropropyl)(dimethylphenyl)quinoline-N,C′](diethylnonanedionate); iridium(III)bis[(trifluoropropyl)(dimethylphenyl)quinoline-N,C′](acetylacetonate); iridium(II)bis[(trifluoropropyl)(dimethylphenyl)quinoline-N,C′][bis(cyclopentyl)acetylacetonate]; iridium(III)bis[(trifluoropropyl)(dimethylphenyl)quinoline-N,C′][bis(cyclohexyl)acetylacetonate]; iridium(III)bis[(trifluorodimethylbutyl)(dimethylphenyl)quinoline-N,C′](diethylnonanedionate); iridium(III)bis[(trifluorodimethylbutyl)(dimethylphenyl)quinoline-N,C′](acetylacetonate); iridium(III)bis[(trifluorodimethylbutyl)(dimethylphenyl)quinoline-N,C′][bis(cyclohexyl)acetylacetonate]; iridium(III)bis[(trifluorodimethylbutyl)(dimethylphenyl)quinoline-N,C′][bis(cyclopentyl)acetylacetonate]; iridium(III)bis[(trifluorodimethylbutyl)(dimethylphenyl)quinoline-N,C′][diethylnonanedionate]; iridium(III)bis[(trifluorodimethylbutyl)(dimethylphenyl)quinoline-N,C′][acetylacetonate]; iridium(III)bis[(trifluorodimethylbutyl)(dimethylphenyl)quinoline-N,C′][bis(cyclopentyl)acetylacetonate]; iridium(III)bis[(trifluorodimethylbutyl)(dimethylphenyl)quinoline-N,C′][bis(cyclohexyl)acetylacetonate]; iridium(III)bis[(trifluoropropyl)(dimethylphenyl)quinoline-N,C′][bis(ethylmethylisopropylnonanedionate]; iridium(III)bis[(trifluorodimethylbutyl)(dimethylphenyl)quinoline-N,C′][dimethyldiisopropylnonanedionate]; iridium(III)bis[(trifluorodimethylbutyl)(dimethylphenyl)quinoline-N,C′][dimethyldiisopropylnonanedionate]; iridium(III)bis[(isobutyl)(dimethylbenzofuropyridinyl)quinoline-N,C′][dimethyldiisopropylnonanedionate]; iridium(III)bis[(isobutyl)(dimethylbenzofuropyridinyl)quinoline-N,C′][diethylnonanedionate]; iridium(III)bis[(trifluorodimethylbutyl)(dimethylbenzofuropyridinyl)quinoline-N,C′][diethylmethylnonanedionate]; iridium(III)bis[(isobutyl)(dimethylphenyl)quinoline-N,C′][dimethyldiisopropylnonanedionate]; iridium(III)bis[(isopropylphenyl)quinoline-N,C′]{[di(isopropyl)triazinyl](methylbenzofuropyridinyl)pyridine-N,C′}; iridium(III)bis[(isopropyl)(dimethylphenyl)isoquinoline-N,C′][diethylnonanedionate]; iridium(III)bis[(isopropyl)(dimethylphenyl)isoquinoline-N,C′][diethylnonanedionate]; iridium(II)bis[di(isopropyl)(dimethylphenyl)isoquinoline-N,C′][acetylacetonate]; iridium(II)tris[dimethyldibenzoquinoline-N,C′]; iridium(III)bis[(tert-butylphenyl)thienoisoquinoline-N,C′][acetylacetonate]; iridium(III)bis[(phenyl) thienopyridine-N,C′][acetylacetonate]; iridium(III)bis[(dimethylfluorenyl)quinoline-N,C′][acetylacetonate]; iridium(III)bis[(methylnaphthalenyl)pyridine-N,C′][acetylacetonate]; iridium(III)bis{[(methyl)(fluoro)phenyl]isoquinoline-N,C′}[acetylacetonate]; iridium(III)bis[(methyl)(fluoro)(dimethylphenyl)quinoline-N,C′][acetylacetonate]

### (Group 22A)

phenyl(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; bis(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spiro[cyclopentanefluorene]yl)(terphenylyl)indolocarbazole; (spiro[cyclohexanefluorene]yl)(terphenylyl)indolocarbazole; (dimethylfluorenyl)(terphenylyl)indolocarbazole; (spirobi[fluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (phenylcarbazolyl)(terphenylyl)indolocarbazole; [(carbazolyl)phenyl](terphenylyl)indolocarbazole; (benzothienopyridinyl)(terphenylyl)indolocarbazole; (benzothienopyrimidinyl)(terphenylyl)indolocarbazole; (benzothienopyrimidinyl)(terphenylyl)indolocarbazole; (phenylbenzothienopyrimidinyl)(terphenylyl)indolocarbazole; (diphenyltriazinyl)(terphenylyl)indolocarbazole; (phenylquinazolinyl)(terphenylyl)indolocarbazole; (dibenzoquinazolinyl)(terphenylyl)indolocarbazole; (dibenzoquinoxalinyl)(terphenylyl)indolocarbazole; [(phenyl-d₅)biphenylyl](biphenylyl)indolocarbazole; [(phenyl-d₅)biphenylyl](phenyl-d₅)indolocarbazole; [(dimethyl-d₆)fluorenyl](terphenylyl)indolocarbazole; [(dibenzofuranyl)phenyl](terphenylyl)indolocarbazole; [(dibenzothiophenyl)phenyl](terphenylyl)indolocarbazole; [(triphenylenyl)phenyl](terphenylyl)indolocarbazole; [(diphenyltriazinyl)phenyl](terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spiro[cyclohexanefluorene]yl)(terphenylyl)indolocarbazole; (spiro[cyclopentanefluorene]yl)(terphenylyl)indolocarbazole; (spirobi[fluorene]yl)(terphenylyl)indolocarbazole; (dimethylfluorenyl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (dibenzoselenophenyl)(terphenylyl)indolocarbazole; (phenylcarbazolyl)(terphenylyl)indolocarbazole; [(carbazolyl)phenyl](terphenylyl)indolocarbazole; (benzothienopyridinyl)(terphenylyl)indolocarbazole; (benzothienopyrimidinyl)(terphenylyl)indolocarbazole; (benzothienopyrimidinyl)(terphenylyl)indolocarbazole; (phenylbenzothienopyrimidinyl)(terphenylyl)indolocarbazole; (diphenylbenzothienopyrimidinyl)(terphenylyl)indolocarbazole; (diphenylbenzothienopyrimidinyl)(terphenylyl)indolocarbazole; (diphenyltriazinyl)(terphenylyl)indolocarbazole (phenylpyridotriazinyl)(terphenylyl)indolocarbazole; (dibenzopyrimidinyl)(terphenylyl)indolocarbazole; (dibenzoquinoxalinyl)(terphenylyl)indolocarbazole; [(dimethyl-d₆)fluorenyl](terphenylyl)indolocarbazole; [(diphenyltriazinyl)phenyl](terphenylyl)indolocarbazole; [(phenyl-d₅)biphenylyl](biphenylyl)indolocarbazole; [(phenyl-d₅)biphenylyl](phenyl-d₅)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spirobi[fluorene]yl)(terphenylyl)indolocarbazole; (spiro[cyclopentanefluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (diphenyltriazinyl)(terphenylyl)indolocarbazole; (phenylquinazolinyl)(terphenylyl)indolocarbazole; (benzothienopyrimidinyl)(terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; bis(terphenylyl)indolocarbazole; (triphenylenyl)(terphenylyl)indolocarbazole; (dimethylfluorenyl)(terphenylyl)indolocarbazole; (spirobi[fluorene]yl)(terphenylyl)indolocarbazole; (spiro[cyclopentanefluorene]yl)(terphenylyl)indolocarbazole; (dibenzofuranyl)(terphenylyl)indolocarbazole; (dibenzofuranyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (dibenzothiophenyl)(terphenylyl)indolocarbazole; (diphenyltriazinyl)(terphenylyl)indolocarbazole; (phenylquinazolinyl)(terphenylyl)indolocarbazole; (benzothienopyrimidinyl)(terphenylyl)indolocarbazole; (phenyl)(terphenylyl)indolocarbazole; (biphenylyl)(terphenylyl)indolocarbazole; (biphenylyl)(terphenylyl)indolocarbazole; bis(terphenylyl)indolocarbazole; (dimethylfluorenyl)(terphenylyl)indolocarbazole; (dibenzofuranyl)(terphenylyl)indolocarbazole; (dibenzothiophenyl)(terphenylyl)indolocarbazole; (dibenzothiophenyl)(terphenylyl)indolocarbazole; (benzothienopyridinyl)(terphenylyl)indolocarbazole; (benzothienopyrimidinyl)(terphenylyl)indolocarbazole; (diphenyltriazinyl)(terphenylyl)indolocarbazole; (phenylquinazolinyl)(terphenylyl)indolocarbazole; [(phenyl-d₅)biphenylyl](biphenylyl)indolocarbazole; [(cyclohexyl-d₅)biphenylyl](phenyl-d₅)indolocarbazole; (phenyl)(terphenylyl)indolocarbazole; (biphenylyl)(terphenylyl)indolocarbazole; (biphenylyl)(terphenylyl)indolocarbazole; (dibenzothiophenyl)(terphenylyl)indolocarbazole; (dibenzothiophenyl)(terphenylyl)indolocarbazole; (dibenzofuranyl)(diphenyltriazinyl)biphenyl; (dibenzothiophenyl)(diphenyltriazinyl)biphenyl; (dibenzoselenophenyl)(diphenyltriazinyl)biphenyl; (dibenzofuranyl)(diphenyltriazinyl)terbenzene; (dibenzothiophenyl)(diphenyltriazinyl)terbenzene; (dibenzoselenophenyl)(diphenyltriazinyl)terbenzene; (phenyldibenzofuranyl)(diphenyltriazinyl)biphenyl; (phenyldibenzothiophenyl)(diphenyltriazinyl)biphenyl; (phenyldibenzoselenophenyl)(diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; [(biphenylyl)dibenzofuranyl](diphenyltriazinyl)biphenyl; [(biphenylyl)dibenzothiophenyl](diphenyltriazinyl)biphenyl; [(biphenylyl)dibenzoselenophenyl](diphenyltriazinyl)biphenyl; (phenyldibenzofuranyl)(diphenyltriazinyl)terphenyl; (phenyldibenzothiophenyl)(diphenyltriazinyl)terphenyl; (phenyldibenzoselenophenyl)(diphenyltriazinyl)terphenyl; (phenyldibenzofuranyl)(diphenyltriazinyl)terphenyl; (phenyldibenzothiophenyl)(diphenyltriazinyl)terphenyl; (phenyldibenzoselenophenyl)(diphenyltriazinyl)terphenyl; [(biphenylyl)dibenzofuranyl](diphenyltriazinyl)terphenyl; [(biphenylyl)dibenzothiophenyl](diphenyltriazinyl)terphenyl; [(biphenylyl)dibenzoselenophenyl](diphenyltriazinyl)terphenyl; [phenyl(biphenylyl)triazinyl](dibenzofuranyl)biphenyl; [phenyl(biphenylyl)triazinyl](dibenzothiophenyl)biphenyl; [phenyl(biphenylyl)triazinyl](dibenzoselenophenyl)biphenyl; [phenyl(biphenylyl)triazinyl](dibenzofuranyl)biphenyl; [phenyl(biphenylyl)triazinyl](dibenzothiophenyl)biphenyl; [phenyl(biphenylyl)triazinyl](dibenzoselenophenyl)biphenyl; [bis(biphenylyl)triazinyl](dibenzofuranyl)biphenyl; [bis(biphenylyl)triazinyl](dibenzothiophenyl)biphenyl; [bis(biphenylyl)triazinyl](dibenzoselenophenyl)biphenyl; [phenyl(dimethylfluorenyl)triazinyl](dibenzofuranyl)biphenyl; [phenyl(dimethylfluorenyl)triazinyl](dibenzothiophenyl)biphenyl; [phenyl(dimethylfluorenyl)triazinyl](dibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(biphenylyl)triazinyl](phenyldibenzofuranyl)biphenyl; [phenyl(biphenylyl)triazinyl](phenyldibenzothiophenyl)biphenyl; [phenyl(biphenylyl)triazinyl](phenyldibenzoselenophenyl)biphenyl; [phenyl(dimethylfluorenyl)triazinyl](phenyldibenzofuranyl)biphenyl; [phenyl(dimethylfluorenyl)triazinyl](phenyldibenzothiophenyl)biphenyl; [phenyl(dimethylfluorenyl)triazinyl](phenyldibenzoselenophenyl)biphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; [phenyl(dimethylfluorenyl)triazinyl](dibenzofuranyl)terphenyl; [phenyl(dimethylfluorenyl)triazinyl](dibenzothiophenyl)terphenyl; [phenyl(dimethylfluorenyl)triazinyl](dibenzoselenophenyl)terphenyl; [phenyl(biphenylyl)triazinyl][(biphenylyl)dibenzofuranyl)]biphenyl; [phenyl(biphenylyl)triazinyl][(biphenylyl)dibenzothiophenyl)]biphenyl; [phenyl(biphenylyl)triazinyl][(biphenylyl)dibenzoselenophenyl)]biphenyl; [phenyl(biphenylyl)triazinyl][(biphenylyl)dibenzofuranyl)]biphenyl; [phenyl(biphenylyl)triazinyl][(biphenylyl)dibenzothiophenyl)]biphenyl; [phenyl(biphenylyl)triazinyl][(biphenylyl)dibenzoselenophenyl)]biphenyl; [phenyl(dimethylfluorenyl)triazinyl][(biphenylyl)dibenzofuranyl)]biphenyl; [phenyl(dimethylfluorenyl)triazinyl][(biphenylyl)dibenzothiophenyl]biphenyl; [phenyl(dimethylfluorenyl)triazinyl][(biphenylyl)dibenzoselenophenyl]biphenyl; [phenyl(biphenylyl)triazinyl](dibenzofuranyl)terphenyl; [phenyl(biphenylyl)triazinyl](dibenzothiophenyl)terphenyl; [phenyl(biphenylyl)triazinyl](dibenzoselenophenyl)terphenyl; (dibenzofuranyl)[phenyl(biphenylyl)triazinyl]terphenyl; (dibenzothiophenyl)[phenyl(biphenylyl)triazinyl]terphenyl; (dibenzoselenophenyl)[phenyl(biphenylyl)triazinyl]terphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)biphenyl; (diphenyltriazinyl)(dibenzothiophenyl)biphenyl; (diphenyltriazinyl)(dibenzoselenophenyl)biphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(diphenyldibenzofuranyl)biphenyl; (diphenyltriazinyl)(diphenyldibenzothiophenyl)biphenyl; (diphenyltriazinyl)(diphenyldibenzoselenophenyl)biphenyl; (diphenyltriazinyl)(phenyldibenzofuranyl)biphenyl; (diphenyltriazinyl)(phenyldibenzothiophenyl)biphenyl; (diphenyltriazinyl)(phenyldibenzoselenophenyl)biphenyl; (diphenyltriazinyl)(phenyldibenzofuranyl)(pyridinyl)phenyl; (diphenyltriazinyl)(phenyldibenzothiophenyl)(pyridinyl)phenyl; (diphenyltriazinyl)(phenyldibenzoselenophenyl)(pyridinyl)phenyl; (diphenyltriazinyl)(phenyldibenzofuranyl)(pyridinyl)phenyl; (diphenyltriazinyl)(phenyldibenzothiophenyl)(pyridinyl)phenyl; (diphenyltriazinyl)(phenyldibenzoselenophenyl)(pyridinyl)phenyl; (diphenyltriazinyl)[(pyridinyl)dibenzofuranyl]biphenyl; (diphenyltriazinyl)[(pyridinyl)dibenzothiophenyl]biphenyl; (diphenyltriazinyl)[(pyridinyl)dibenzoselenophenyl]biphenyl; (diphenyltriazinyl)(dibenzofuranyl)terphenyl; (diphenyltriazinyl)(dibenzothiophenyl)terphenyl; (diphenyltriazinyl)(dibenzoselenophenyl)terphenyl; (dibenzofuranyl)(diphenyltriazinyl)terphenyl; (dibenzothiophenyl)(diphenyltriazinyl)terphenyl; (dibenzoselenophenyl)(diphenyltriazinyl)terphenyl; (diphenyltriazinyl)(dibenzofuranyl)(dimethylfluorenyl)benzene; (diphenyltriazinyl)(dibenzothiophenyl)(dimethylfluorenyl)benzene; (diphenyltriazinyl)(dibenzoselenophenyl)(dimethylfluorenyl)benzene; (diphenyltriazinyl)(dimethylfluorenyl)biphenyl; (diphenyltriazinyl)(spiro[cyclopentanefluorene]yl)biphenyl; (diphenyltriazinyl)(dimethylfluorenyl)terphenyl; (diphenyltriazinyl)(diphenylfluorenyl)biphenyl; [phenyl(biphenylyl)triazinyl](dimethylfluorenyl)biphenyl; [phenyl(dimethylfluorenyl)triazinyl](dimethylfluorenyl)terphenyl; (diphenyltriazinyl)[bis(diphenylfluorenyl)]benzene; (diphenyltriazinyl)(diphenylfluorenyl)terbenzene; (diphenyltriazinyl)(triphenylenyl)biphenyl; phenyl[(diphenyltriazinyl)phenyl]indolocarbazole; (biphenylyl)[(diphenyltriazinyl)phenyl]indolocarbazole; (biphenylyl)[(diphenyltriazinyl)phenyl]indolocarbazole; (dimethylfluorenyl)[(diphenyltriazinyl)phenyl]indolocarbazole; (dibenzothiophenyl)[(diphenyltriazinyl)phenyl]indolocarbazole; (dibenzofuranyl)[(diphenyltriazinyl)phenyl]indolocarbazole; (dibenzothiophenyl)[(diphenyltriazinyl)phenyl]indolocarbazole; (phenyl)[(diphenyltriazinyl)biphenyl]indolocarbazole; (phenyl)[(diphenyltriazinyl)terphenyl]indolocarbazole; (phenyl)[(diphenyltriazinyl)terphenyl]indolocarbazole; (phenyl)[((phenyl)(biphenyl)triazinyl)phenyl]indolocarbazole; (phenyl)[(di(biphenyl)triazinyl)phenyl]indolocarbazole; (phenyl)[((phenyl)(biphenyl)triazinyl)phenyl]indolocarbazole; (phenyl)[((phenyl)(naphthyl)triazinyl)phenyl]indolocarbazole; (phenylcarbazolyl)[(diphenyltriazinyl)phenyl]indolocarbazole; (phenylcarbazolyl)[(diphenyltriazinyl)phenyl]indolocarbazole; (phenylcarbazolyl)[(diphenyltriazinyl)phenyl]indolocarbazole; di(phenyl)(triphenylenylbiphenyl)triazine; (phenyl)(biphenyl)(triphenylenylphenyl)triazine; (phenyl)(biphenyl)(triphenylenylphenyl)triazine; di(biphenyl)(triphenylenylphenyl)triazine; di(phenyl)(triphenylenylbiphenyl)triazine; di(biphenyl)(triphenylenyl)triazine; di(biphenyl)(triphenylenyl)triazine; (phenyl)(biphenyl)(triphenylenyl)triazine; (phenyl)(biphenyl)(triphenylenyl)triazine; (naphthyl)[(diphenyltriazinyl)phenyl]indolocarbazole; (phenyl)(diphenyltriazinyl)dibenzofuran; (phenyl)(diphenyltriazinyl)dibenzothiophene; (phenyl)(diphenyltriazinyl)dibenzoselenophene; (phenyl)[(phenyl)(biphenyl)triazinyl]dibenzofuran; (phenyl)[(phenyl)(biphenyl)triazinyl]dibenzothiophene; (phenyl)[(phenyl)(biphenyl)triazinyl]dibenzoselenophene; (phenyl)[(phenyl)(biphenyl)triazinyl]dibenzofuran; (phenyl)[(phenyl)(biphenyl)triazinyl]dibenzothiophene; (phenyl)[(phenyl)(biphenyl)triazinyl]dibenzoselenophene; (phenyl)[di(biphenyl)triazinyl]dibenzofuran; (phenyl)[di(biphenyl)triazinyl]dibenzothiophene; (phenyl)[di(biphenyl)triazinyl]dibenzoselenophene; (phenyl)[di(biphenyl)triazinyl]dibenzofuran; (phenyl)[di(biphenyl)triazinyl]dibenzothiophene; (phenyl)[di(biphenyl)triazinyl]dibenzoselenophene; (phenyl)[di(biphenyl)triazinyl]dibenzofuran; (phenyl)[di(biphenyl)triazinyl]dibenzothiophene; (phenyl)[di(biphenyl)triazinyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (phenyl)[(phenyl)(biphenyl)triazinylphenyl]dibenzofuran; (phenyl)[(phenyl)(biphenyl)triazinylphenyl]dibenzothiophene; (phenyl)[(phenyl)(biphenyl)triazinylphenyl]dibenzoselenophene; (phenyl)[(phenyl)(biphenyl)triazinylphenyl]dibenzofuran; (phenyl)[(phenyl)(biphenyl)triazinylphenyl]dibenzothiophene; (phenyl)[(phenyl)(biphenyl)triazinylphenyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (phenyl)[(phenyl)(biphenyl)triazinylphenyl]dibenzofuran; (phenyl)[(phenyl)(biphenyl)triazinylphenyl]dibenzothiophene; (phenyl)[(phenyl)(biphenyl)triazinylphenyl]dibenzoselenophene; (phenyl)[(phenyl)(biphenyl)triazinylphenyl]dibenzofuran; (phenyl)[(phenyl)(biphenyl)triazinylphenyl]dibenzothiophene; (phenyl)[(phenyl)(biphenyl)triazinylphenyl]dibenzoselenophene; (phenyl)[(diphenyltriazinyl)biphenyl]dibenzofuran; (phenyl)[(diphenyltriazinyl)biphenyl]dibenzothiophene; (phenyl)[(diphenyltriazinyl)biphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (phenyl)[(diphenyltriazinyl)biphenyl]dibenzofuran; (phenyl)[(diphenyltriazinyl)biphenyl]dibenzothiophene; (phenyl)[(diphenyltriazinyl)biphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (phenyl)[(diphenyltriazinyl)biphenyl]dibenzofuran; (phenyl)[(diphenyltriazinyl)biphenyl]dibenzothiophene; (phenyl)[(diphenyltriazinyl)biphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (phenyl)[(phenyl)(biphenyl)triazinylbiphenyl]dibenzofuran; (phenyl)[(phenyl)(biphenyl)triazinylbiphenyl]dibenzothiophene; (phenyl)[(phenyl)(biphenyl)triazinylbiphenyl]dibenzoselenophene; (biphenyl)(diphenyltriazinyl)dibenzofuran; (biphenyl)(diphenyltriazinyl)dibenzothiophene; (biphenyl)(diphenyltriazinyl)dibenzoselenophene; (biphenyl)[(phenyl)(biphenyl)triazinyl]dibenzofuran; (biphenyl)[(phenyl)(biphenyl)triazinyl]dibenzothiophene; (biphenyl)[(phenyl)(biphenyl)triazinyl]dibenzoselenophene; (biphenyl)[(phenyl)(biphenyl)triazinyl]dibenzofuran; (biphenyl)[(phenyl)(biphenyl)triazinyl]dibenzothiophene; (biphenyl)[(phenyl)(biphenyl)triazinyl]dibenzoselenophene; (phenyl)[(diphenyltriazinyl)phenyl]dibenzofuran; (phenyl)[(diphenyltriazinyl)phenyl]dibenzothiophene; (phenyl)[(diphenyltriazinyl)phenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[di(phenyl)triazinyl]dibenzofuran; (biphenyl)[di(phenyl)triazinyl]dibenzothiophene; (biphenyl)[di(phenyl)triazinyl]dibenzoselenophene; (biphenyl)[(phenyl)(biphenyl)triazinyl]dibenzofuran; (biphenyl)[(phenyl)(biphenyl)triazinyl]dibenzothiophene; (biphenyl)[(phenyl)(biphenyl)triazinyl]dibenzoselenophene; (biphenyl)[(phenyl)(biphenyl)triazinyl]dibenzofuran; (biphenyl)[(phenyl)(biphenyl)triazinyl]dibenzothiophene; (biphenyl)[(phenyl)(biphenyl)triazinyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (biphenyl)[(phenyl)(biphenyl)triazinylphenyl]dibenzofuran; (biphenyl)[(phenyl)(biphenyl)triazinylphenyl]dibenzothiophene; (biphenyl)[(phenyl)(biphenyl)triazinylphenyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (phenyl)[(biphenyl)(dimethylfluorenyl)triazinyl]dibenzofuran; (phenyl)[(biphenyl)(dimethylfluorenyl)triazinyl]dibenzothiophene; (phenyl)[(biphenyl)(dimethylfluorenyl)triazinyl]dibenzoselenophene; (phenyl)[(biphenyl)(dimethylfluorenyl)triazinyl]dibenzofuran; (phenyl)[(biphenyl)(dimethylfluorenyl)triazinyl]dibenzothiophene; (phenyl)[(biphenyl)(dimethylfluorenyl)triazinyl]dibenzoselenophene; (phenyl)[(phenyl)(dimethylfluorenyl)triazinylphenyl]dibenzofuran; (phenyl)[(phenyl)(dimethylfluorenyl)triazinylphenyl]dibenzothiophene; (phenyl)[(phenyl)(dimethylfluorenyl)triazinylphenyl]dibenzoselenophene; (phenyl)[bis(dimethylfluorenyl)triazinylphenyl]dibenzofuran; (phenyl)[bis(dimethylfluorenyl)triazinylphenyl]dibenzothiophene; (phenyl)[bis(dimethylfluorenyl)triazinylphenyl]dibenzoselenophene; (biphenyl)[(phenyl)(dimethylfluorenyl)triazinyl]dibenzofuran; (biphenyl)[(phenyl)(dimethylfluorenyl)triazinyl]dibenzothiophene; (biphenyl)[(phenyl)(dimethylfluorenyl)triazinyl]dibenzoselenophene; (biphenyl)[(phenyl)(dimethylfluorenyl)triazinyl]dibenzofuran; (biphenyl)[(phenyl)(dimethylfluorenyl)triazinyl]dibenzothiophene; (biphenyl)[(phenyl)(dimethylfluorenyl)triazinyl]dibenzoselenophene; (biphenyl)[(phenyl)(dimethylfluorenyl)triazinylphenyl]dibenzofuran; (biphenyl)[(phenyl)(dimethylfluorenyl)triazinylphenyl]dibenzothiophene; (biphenyl)[(phenyl)(dimethylfluorenyl)triazinylphenyl]dibenzoselenophene; (biphenyl)[(phenyl)(dimethylfluorenyl)triazinylphenyl]dibenzofuran; (biphenyl)[(phenyl)(dimethylfluorenyl)triazinylphenyl]dibenzothiophene; (biphenyl)[(phenyl)(dimethylfluorenyl)triazinylphenyl]dibenzoselenophene; (phenyl)[(phenyl)(dimethylfluorenylphenyl)triazinyl]dibenzofuran; (phenyl)[(phenyl)(dimethylfluorenylphenyl)triazinyl]dibenzothiophene; (phenyl)[(phenyl)(dimethylfluorenylphenyl)triazinyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (biphenyl)[(phenyl)(dimethylfluorenyl)triazinyl]dibenzofuran; (biphenyl)[(phenyl)(dimethylfluorenyl)triazinyl]dibenzothiophene; (biphenyl)[(phenyl)(dimethylfluorenyl)triazinyl]dibenzoselenophene; (biphenyl)[(phenyl)(dimethylfluorenyl)triazinylphenyl]dibenzofuran; (biphenyl)[(phenyl)(dimethylfluorenyl)triazinylphenyl]dibenzothiophene; (biphenyl)[(phenyl)(dimethylfluorenyl)triazinylphenyl]dibenzoselenophene; (phenyl)[(dimethylfluorenyl)terphenyl]dibenzofuran; (phenyl)[(dimethylfluorenyl)terphenyl]dibenzothiophene; (phenyl)[(dimethylfluorenyl)terphenyl]dibenzoselenophene; (phenyl)[(phenyl)(dimethylfluorenyl)triazinyl]dibenzofuran; (phenyl)[(phenyl)(dimethylfluorenyl)triazinyl]dibenzothiophene; (phenyl)[(phenyl)(dimethylfluorenyl)triazinyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; di(phenyl)[di(phenyl)triazinylphenyl]dibenzofuran; di(phenyl)[di(phenyl)triazinylphenyl]dibenzothiophene; di(phenyl)[di(phenyl)triazinylphenyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (biphenyl)[di(phenyl)triazinyl]dibenzofuran; (biphenyl)[di(phenyl)triazinyl]dibenzothiophene; (biphenyl)[di(phenyl)triazinyl]dibenzoselenophene; (biphenyl)[di(phenyl)triazinyl]dibenzofuran; (biphenyl)[di(phenyl)triazinyl]dibenzothiophene; (biphenyl)[di(phenyl)triazinyl]dibenzoselenophene; di(phenyl)[di(phenyl)triazinylphenyl]dibenzofuran; di(phenyl)[di(phenyl)triazinylphenyl]dibenzothiophene; di(phenyl)[di(phenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (phenyl)[di(phenyl)triazinyl]dibenzofuran; (phenyl)[di(phenyl)triazinyl]dibenzothiophene; (phenyl)[di(phenyl)triazinyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (biphenyl)[di(phenyl)triazinylphenyl]dibenzofuran; (biphenyl)[di(phenyl)triazinylphenyl]dibenzothiophene; (biphenyl)[di(phenyl)triazinylphenyl]dibenzoselenophene; (phenyl)[di(phenyl)triazinylphenyl]dibenzofuran; (phenyl)[di(phenyl)triazinylphenyl]dibenzothiophene; (phenyl)[di(phenyl)triazinylphenyl]dibenzoselenophene; (phenyl)[di(phenyl)triazinylpyridyl]dibenzofuran; (phenyl)[di(phenyl)triazinylpyridyl]dibenzothiophene; (phenyl)[di(phenyl)triazinylpyridyl]dibenzoselenophene; (phenyl)[(phenyl)(phenylpyridyl)triazinylpyridyl]dibenzofuran; (phenyl)[(phenyl)(phenylpyridyl)triazinylpyridyl]dibenzothiophene; (phenyl)[(phenyl)(phenylpyridyl)triazinylpyridyl]dibenzoselenophene; (phenyl)[(phenyl)(phenylpyridyl)triazinylpyridyl]dibenzofuran; (phenyl)[(phenyl)(phenylpyridyl)triazinylpyridyl]dibenzothiophene; (phenyl)[(phenyl)(phenylpyridyl)triazinylpyridyl]dibenzoselenophene; (biphenyl)[(phenyl)(pyridyl)triazinylpyridyl]dibenzofuran; (biphenyl)[(phenyl)(pyridyl)triazinylpyridyl]dibenzothiophene; (biphenyl)[(phenyl)(pyridyl)triazinylpyridyl]dibenzoselenophene; (phenyl)[(phenyl)(dimethylindenopyridyl)triazinyl]dibenzofuran; (phenyl)[(phenyl)(dimethylindenopyridyl)triazinyl]dibenzothiophene; (phenyl)[(phenyl)(dimethylindenopyridyl)triazinyl]dibenzoselenophene; (phenyl)[(biphenyl)(dimethylindenopyridyl)triazinyl]dibenzofuran; (phenyl)[(biphenyl)(dimethylindenopyridyl)triazinyl]dibenzothiophene; (phenyl)[(biphenyl)(dimethylindenopyridyl)triazinyl]dibenzoselenophene; (phenyl)[(phenyl)(dimethylindenopyridyl)triazinyl]dibenzofuran; (phenyl)[(phenyl)(dimethylindenopyridyl)triazinyl]dibenzothiophene; (phenyl)[(phenyl)(dimethylindenopyridyl)triazinyl]dibenzoselenophene; (phenyl)[(phenyl)(spirocyclohexanefluorenyl)triazinyl]dibenzofuran; (phenyl)[(phenyl)(spirocyclohexanefluorenyl)triazinyl]dibenzothiophene; (phenyl)[(phenyl)(spirocyclohexanefluorenyl)triazinyl]dibenzoselenophene; (phenyl)[(phenyl)(spirobifluorenyl)triazinyl]dibenzofuran; (phenyl)[(phenyl)(spirobifluorenyl)triazinyl]dibenzothiophene; (phenyl)[(phenyl)(spirobifluorenyl)triazinyl]dibenzoselenophene; (phenyl-d₅)[(diphenyl-d₁₀)triazinylphenyl-d₉]dibenzofuran; (phenyl-d₅)[(diphenyl-d₁₀)triazinylphenyl-d₉]dibenzothiophene; (phenyl-d₅)[(diphenyl-d₁₀)triazinylphenyl-d₉]dibenzoselenophene; (biphenyl-d₉)[(diphenyl-d₁₀)triazinylphenyl-d₉]dibenzofuran; (biphenyl-d₉)[(diphenyl-d₁₀)triazinylphenyl-d₉]dibenzothiophene; (biphenyl-d₉)[(diphenyl-d₁₀)triazinylphenyl-d₉]dibenzoselenophene; (phenyl)[(phenyl)(dimethyl-d₆)fluorenyl)triazinyl]dibenzofuran; (phenyl)[(phenyl)(dimethyl-d₆)fluorenyl)triazinyl]dibenzothiophene; (phenyl)[(phenyl)(dimethyl-d₆)fluorenyl)triazinyl]dibenzoselenophene; (biphenyl-d₉)[(diphenyl-d₁₀)triazinylphenyl-d₉]dibenzofuran; (biphenyl-d₉)[(diphenyl-d₁₀)triazinylphenyl-d₉]dibenzothiophene; (biphenyl-d₉)[(diphenyl-d₁₀)triazinylphenyl-d₉]dibenzoselenophene; (biphenyl)[(diphenyl-d₁₀)triazinylphenyl]dibenzofuran; (biphenyl)[(diphenyl-d₁₀)triazinylphenyl]dibenzothiophene; (biphenyl)[(diphenyl-d₁₀)triazinylphenyl]dibenzoselenophene; (biphenyl)[di(phenyl)triazinylbiphenyl]dibenzofuran; (biphenyl)[di(phenyl)triazinylbiphenyl]dibenzothiophene; (biphenyl)[di(phenyl)triazinylbiphenyl]dibenzoselenophene; (biphenyl)[bis(fluorophenyl)triazinylphenyl]dibenzofuran; (biphenyl)[bis(fluorophenyl)triazinylphenyl]dibenzothiophene; (biphenyl)[bis(fluorophenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylbiphenyl]dibenzofuran; (dimethylfluorenyl)[di(phenyl)triazinylbiphenyl]dibenzothiophene; (dimethylfluorenyl)[di(phenyl)triazinylbiphenyl]dibenzoselenophene; (dimethylfluorenyl)[di(phenyl)triazinylbiphenyl]dibenzofuran; (dimethylfluorenyl)[di(phenyl)triazinylbiphenyl]dibenzothiophene; (dimethylfluorenyl)[di(phenyl)triazinylbiphenyl]dibenzoselenophene; (dimethylfluorenyl)[di(phenyl)triazinylbiphenyl]dibenzofuran; (dimethylfluorenyl)[di(phenyl)triazinylbiphenyl]dibenzothiophene; (dimethylfluorenyl)[di(phenyl)triazinylbiphenyl]dibenzoselenophene; (dimethylfluorenyl)[di(phenyl)triazinylpyridyl]dibenzofuran; (dimethylfluorenyl)[di(phenyl)triazinylpyridyl]dibenzothiophene; (dimethylfluorenyl)[di(phenyl)triazinylpyridyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylbiphenyl]dibenzofuran; (dimethylfluorenyl)[di(phenyl)triazinylbiphenyl]dibenzothiophene; (dimethylfluorenyl)[di(phenyl)triazinylbiphenyl]dibenzoselenophene; (dimethylfluorenyl)[(phenyl)(biphenyl)triazinylphenyl]dibenzofuran; (dimethylfluorenyl)[(phenyl)(biphenyl)triazinylphenyl]dibenzothiophene; (dimethylfluorenyl)[(phenyl)(biphenyl)triazinylphenyl]dibenzoselenophene; (dimethylfluorenyl)[(phenyl)(dimethylfluorenyl)triazinylphenyl]dibenzofuran; (dimethylfluorenyl)[(phenyl)(dimethylfluorenyl)triazinylphenyl]dibenzothiophene; (dimethylfluorenyl)[(phenyl)(dimethylfluorenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; bis(dimethylfluorenyl)[di(phenyl)triazinylphenyl]dibenzofuran; bis(dimethylfluorenyl)[di(phenyl)triazinylphenyl]dibenzothiophene; bis(dimethylfluorenyl)[di(phenyl)triazinylphenyl]dibenzoselenophene; (dimethylfluorenyl)[(phenyl)(terphenyl)triazinylphenyl]dibenzofuran; (dimethylfluorenyl)[(phenyl)(terphenyl)triazinylphenyl]dibenzothiophene; (dimethylfluorenyl)[(phenyl)(terphenyl)triazinylphenyl]dibenzoselenophene; (spirocyclopentanefluorenyl)[di(phenyl)triazinylphenyl]dibenzofuran; (spirocyclopentanefluorenyl)[di(phenyl)triazinylphenyl]dibenzothiophene; (spirocyclopentanefluorenyl)[di(phenyl)triazinylphenyl]dibenzoselenophene; (diphenylfluorenyl)[di(phenyl)triazinylphenyl]dibenzofuran; (diphenylfluorenyl)[di(phenyl)triazinylphenyl]dibenzothiophene; (diphenylfluorenyl)[di(phenyl)triazinylphenyl]dibenzoselenophene; (spirobifluorenyl)[di(phenyl)triazinylphenyl]dibenzofuran; (spirobifluorenyl)[di(phenyl)triazinylphenyl]dibenzothiophene; (spirobifluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; [di(methyl)(phenyl)fluorenyl][di(phenyl)triazinylphenyl]dibenzofuran; [di(methyl)(phenyl)fluorenyl][di(phenyl)triazinylphenyl]dibenzothiophene; [di(methyl)(phenyl)fluorenyl][di(phenyl)triazinylphenyl]dibenzoselenophene; [(dimethyl-d₆)fluorenyl][di(phenyl)triazinylphenyl]dibenzofuran; [(dimethyl-d₆)fluorenyl][di(phenyl)triazinylphenyl]dibenzothiophene; [(dimethyl-d₆)fluorenyl][di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (phenyl)(dimethylfluorenyl)[di(phenyl)triazinylphenyl]dibenzofuran; (phenyl)(dimethylfluorenyl)[di(phenyl)triazinylphenyl]dibenzothiophene; (phenyl)(dimethylfluorenyl)[di(phenyl)triazinylphenyl]dibenzoselenophene; (dimethylfluorenyl)[di(phenyl)triazinylphenyl]dibenzofuran; (dimethylfluorenyl)[di(phenyl)triazinylphenyl]dibenzothiophene; (dimethylfluorenyl)[di(phenyl)triazinylphenyl]dibenzoselenophene; (dimethylfluorenyl)[(diphenyl-d₁₀)triazinylphenyl]dibenzofuran; (dimethylfluorenyl)[(diphenyl-d₁₀)triazinylphenyl]dibenzothiophene; (dimethylfluorenyl)[(diphenyl-d₁₀)triazinylphenyl]dibenzoselenophene; (dimethylfluorenyl)[(diphenyl-d₁₀)triazinylphenyl-d₄]dibenzofuran; (dimethylfluorenyl)[(diphenyl-d₁₀)triazinylphenyl-d₄]dibenzothiophene; (dimethylfluorenyl)[(diphenyl-d₁₀)triazinylphenyl-d₄]dibenzoselenophene; [(dimethyl-d₆)fluorenyl][(diphenyl-d₁₀)triazinylphenyl]dibenzofuran; [(dimethyl-d₆)fluorenyl][(diphenyl-d₁₀)triazinylphenyl]dibenzothiophene; [(dimethyl-d₆)fluorenyl][(diphenyl-d₁₀)triazinylphenyl]dibenzoselenophene; (dimethylfluorenyl)[(diphenyl-d₁₀)triazinylphenyl-d₄]dibenzofuran; (dimethylfluorenyl)[(diphenyl-d₁₀)triazinylphenyl-d₄]dibenzothiophene; (dimethylfluorenyl)[(diphenyl-d₁₀)triazinylphenyl-d₄]dibenzoselenophene; (terphenyl)[(phenyl)(biphenyl)triazinyl]dibenzofuran; (terphenyl)[(phenyl)(biphenyl)triazinyl]dibenzothiophene; (terphenyl)[(phenyl)(biphenyl)triazinyl]dibenzoselenophene; (terphenyl)[(phenyl)(biphenyl)triazinyl]dibenzofuran; (terphenyl)[(phenyl)(biphenyl)triazinyl]dibenzothiophene; (terphenyl)[(phenyl)(biphenyl)triazinyl]dibenzoselenophene; (terphenyl)[di(phenyl)triazinyl]dibenzofuran; (terphenyl)[di(phenyl)triazinyl]dibenzothiophene; (terphenyl)[di(phenyl)triazinyl]dibenzoselenophene; (terphenyl)[di(biphenyl)triazinyl]dibenzofuran; (terphenyl)[di(biphenyl)triazinyl]dibenzothiophene; (terphenyl)[di(biphenyl)triazinyl]dibenzoselenophene; (terphenyl)[(phenyl)(biphenyl)triazinyl]dibenzofuran; (terphenyl)[(phenyl)(biphenyl)triazinyl]dibenzothiophene; (terphenyl)[(phenyl)(biphenyl)triazinyl]dibenzoselenophene; (terphenyl)[(phenyl)(biphenyl)triazinyl]dibenzofuran; (terphenyl)[(phenyl)(biphenyl)triazinyl]dibenzothiophene; (terphenyl)[(phenyl)(biphenyl)triazinyl]dibenzoselenophene; (terphenyl)[di(phenyl)triazinyl]dibenzofuran; (terphenyl)[di(phenyl)triazinyl]dibenzothiophene; (terphenyl)[di(phenyl)triazinyl]dibenzoselenophene; (terphenyl)[(phenyl)(dibenzothiophenyl)triazinyl]dibenzofuran; (terphenyl)[(phenyl)(dibenzothiophenyl)triazinyl]dibenzothiophene; (terphenyl)[(phenyl)(dibenzothiophenyl)triazinyl]dibenzoselenophene; (terphenyl)[(phenyl)(dibenzofuranyl)triazinyl]dibenzofuran; (terphenyl)[(phenyl)(dibenzofuranyl)triazinyl]dibenzothiophene; (terphenyl)[(phenyl)(dibenzofuranyl)triazinyl]dibenzoselenophene; (terphenyl)[(phenyl)(dimethylfluorenyl)triazinyl]dibenzofuran; (terphenyl)[(phenyl)(dimethylfluorenyl)triazinyl]dibenzothiophene; (terphenyl)[(phenyl)(dimethylfluorenyl)triazinyl]dibenzoselenophene; (terphenyl)[(phenyl)(dibenzothiophenyl)triazinyl]dibenzofuran; (terphenyl)[(phenyl)(dibenzothiophenyl)triazinyl]dibenzothiophene; (terphenyl)[(phenyl)(dibenzothiophenyl)triazinyl]dibenzoselenophene; (terphenyl)[(phenyl)(dibenzofuranyl)triazinyl]dibenzofuran; (terphenyl)[(phenyl)(dibenzofuranyl)triazinyl]dibenzothiophene; (terphenyl)[(phenyl)(dibenzofuranyl)triazinyl]dibenzoselenophene; (terphenyl)[(phenyl)(dimethylfluorenyl)triazinyl]dibenzofuran; (terphenyl)[(phenyl)(dimethylfluorenyl)triazinyl]dibenzothiophene; (terphenyl)[(phenyl)(dimethylfluorenyl)triazinyl]dibenzoselenophene; (terphenyl)[di(phenyl)triazinylphenyl]dibenzofuran; (terphenyl)[di(phenyl)triazinylphenyl]dibenzothiophene; (terphenyl)[di(phenyl)triazinylphenyl]dibenzoselenophene; (terphenyl)[di(phenyl)triazinylphenyl]dibenzofuran; (terphenyl)[di(phenyl)triazinylphenyl]dibenzothiophene; (terphenyl)[di(phenyl)triazinylphenyl]dibenzoselenophene; (terphenyld₁₃)[(diphenyl-d₁₀)triazinylphenyl-d₃]dibenzofuran-d₆; (terphenyld₁₃)[(diphenyl-d₁₀)triazinylphenyl-d₃]dibenzothiophened₆; (terphenyld₁₃)[(diphenyl-d₁₀)triazinylphenyl-d₃]dibenzoselenophene-d₆; (terphenyl)[(diphenyl-d₁₀)triazinylphenyl]dibenzofuran; (terphenyl)[(diphenyl-d₁₀)triazinylphenyl]dibenzothiophene; (terphenyl)[(diphenyl-d₁₀)triazinylphenyl]dibenzoselenophene; (terphenyl)[(diphenyl-d₁₀)triazinylphenyl]dibenzofuran; (terphenyl)[(diphenyl-d₁₀)triazinylphenyl]dibenzothiophene; (terphenyl)[(diphenyl-d₁₀)triazinylphenyl]dibenzoselenophene

### (Group 23A)

di(phenyl)[(phenyl)indoloindolyl]triazine; di(phenyl)[(phenyl)indoloindolyl]pyridine; di(phenyl)[(phenyl)indoloindolyl]pyrimidine; di(phenyl)[(phenyl)indoloindolyl]pyrimidine; di(biphenyl)[(phenyl)indoloindolyl]triazine; di(phenyl)[(diphenyltriazinyl)indoloindolyl]triazine; di(phenyl)[(phenyl)indoloindolylphenyl]triazine; (phenyl)[(phenyl)indoloindolyl]quinazoline; bis(phenylcarbazolyl)indoloindole; (phenyl)(phenylcarbazolyl)indoloindole; (phenyl)(dibenzofuranyl)indoloindole; (phenyl)(dibenzothiophenyl)indoloindole; (phenyl)(carbazolylphenyl)indoloindole; di(phenyl)(benzothienoindolyl)triazine; (phenyl)(biphenyl)(benzothienoindolyl)triazine; di(biphenyl)(benzothienoindolyl)triazine; (phenyl)(carbazolylphenyl)(benzothienoindolyl)triazine; (phenylquinzolyl)benzothienoindole; (phenylcarbazolyl)benzothienoindole; (naphthylcarbazolyl)benzothienoindole; (triphenylenylcarbazolyl)benzothienoindole; (biphenylcarbazolyl)benzothienoindole; (terphenylcarbazolyl)benzothienoindole; (diphenylpyridyl)benzofuroindole; (diphenylpyrimidinyl)benzofuroindole; di(phenyl)(benzofuroindolyl)triazine; (phenyl)(biphenyl)(benzofuroindolyl)triazine; di(biphenyl)(benzofuroindolyl)triazine; (biphenyl)(benzofuroindolyl)quinazoline; (carbazolyl)(benzofuroindolyl)dibenzofuran; (phenylcarbazolyl)benzofuroindole; (naphthylcarbazolyl)benzofuroindole; (terphenylcarbazolyl)benzofuroindole; di(phenyl)(phenylbenzofuroindolyl)triazine; di(phenyl)(carbazolylbenzofuroindolyl)triazine; di(phenyl)bicarbazole; di(biphenyl)bicarbazole; (phenyl)(biphenyl)bicarbazole; di(biphenyl)bicarbazole; (phenyl)(biphenyl)bicarbazole; di(biphenyl)bicarbazole; (phenyl)(naphthylphenyl)bicarbazole; (phenyl)(naphthylphenyl)bicarbazole; (phenyl)(naphthyl)bicarbazole; di(naphthyl)bicarbazole; (naphthyl)(biphenyl)bicarbazole; (naphthyl)(biphenyl)bicarbazole; (naphthyl)(terphenyl)bicarbazole; (naphthyl)(naphthylphenyl)bicarbazole; di(naphthyl)bicarbazole; (naphthyl)(phenanthryl)bicarbazole; (naphthyl)(phenylanthryl)bicarbazole; (phenyl)(naphthyl)bicarbazole; di(naphthyl)bicarbazole; (naphthyl)(biphenyl)bicarbazole; (naphthyl)(biphenyl)bicarbazole; (naphthyl)(terphenyl)bicarbazole; (naphthyl)(naphthylphenyl)bicarbazole; di(naphthyl)bicarbazole; (naphthyl)(phenanthryl)bicarbazole; (naphthyl)(phenylanthryl)bicarbazole; (phenyl)(phenanthryl)bicarbazole; (biphenyl)(phenanthryl)bicarbazole; (biphenyl)(phenanthryl)bicarbazole; (terphenyl)(phenanthryl)bicarbazole; (naphthylphenyl)(phenanthryl)bicarbazole; di(phenanthryl)bicarbazole; (phenylanthryl)(phenanthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(anthryl)bicarbazole; di(anthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(anthryl)bicarbazole; di(anthryl)bicarbazole; (phenyl)(naphthyl)bicarbazole; di(naphthyl)bicarbazole; (phenyl)(naphthyl)bicarbazole; di(naphthyl)bicarbazole; (phenyl)(phenanthryl)bicarbazole; di(phenanthryl)bicarbazole; (phenyl)(naphthyl)bicarbazole; di(naphthyl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(phenanthryl)bicarbazole; di(phenanthryl)bicarbazole; (phenyl)(phenanthryl)bicarbazole; (phenyl)(anthryl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(phenanthryl)bicarbazole; (phenyl)(anthryl)bicarbazole; (phenyl)(naphthyl)bicarbazole; (phenyl)(naphthyl)bicarbazole; di(naphthyl)bicarbazole; (phenyl)(naphthyl)bicarbazole; (phenyl)(naphthyl)bicarbazole; di(naphthyl)bicarbazole; (phenyl)(phenanthryl)bicarbazole; (phenyl)(phenanthryl)bicarbazole; di(phenanthryl)bicarbazole; (phenyl)(anthryl)bicarbazole; (phenyl)(anthryl)bicarbazole; di(anthryl)bicarbazole; (phenyl)(pyrenyl)bicarbazole; (phenyl)(triphenylenyl)bicarbazole; (biphenyl)(dibenzofuranyl)carbazole; (biphenyl)(dibenzofuranyl)carbazole; (terphenyl)(dibenzofuranyl)carbazole; (naphthylphenyl)(dibenzofuranyl)carbazole; (naphthylphenyl)(dibenzofuranyl)carbazole; (naphthyl)(dibenzofuranyl)carbazole; (phenanthryl)(dibenzofuranyl)carbazole; (triphenylenyl)(dibenzofuranyl)carbazole; (naphthyl)(dibenzofuranyl)carbazole; (biphenyl)(dibenzothiophenyl)carbazole; (terphenyl)(dibenzothiophenyl)carbazole; (naphthylphenyl)(dibenzothiophenyl)carbazole; (naphthylphenyl)(dibenzothiophenyl)carbazole; (naphthyl)(dibenzothiophenyl)carbazole; (phenanthryl)(dibenzothiophenyl)carbazole; (triphenylenyl)(dibenzothiophenyl)carbazole; (naphthyl)(dibenzothiophenyl)carbazole; (phenyl)(phenylpyridyl)bicarbazole; (phenylpyridyl)(dibenzofuranyl)carbazole; (phenylpyridyl)(dibenzothiophenyl)carbazole; (phenyl)(diphenylpyrimidinyl)bicarbazole; (diphenylpyrimidinyl)(dibenzofuranyl)carbazole; (diphenylpyrimidinyl)(dibenzothiophenyl)carbazole; (phenyl)(diphenyltriazinyl)bicarbazole; (diphenyltriazinyl)(dibenzofuranyl)carbazole; (diphenyltriazinyl)(dibenzothiophenyl)carbazole; (phenyl)(phenylquinzolyl)bicarbazole; (phenylquinzolyl)(dibenzofuranyl)carbazole; (phenylquinzolyl)(dibenzothiophenyl)carbazole

### (Group 24A)

(phenyl)(biphenyl)[(phenyl)indolocarbazolyl]triazine; (phenyl)(biphenyl)[(phenyl)indolocarbazolyl]triazine; di(phenyl)[(biphenyl)indolocarbazolyl]triazine; di(phenyl)[(biphenyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(phenyl)[(terphenyl)indolocarbazolyl]triazine; di(phenyl)[(terphenyl)indolocarbazolyl]triazine; di(phenyl)[(terphenyl)indolocarbazolyl]triazine; di(phenyl)[(terphenyl)indolocarbazolyl]triazine; di(biphenyl)[(phenyl)indolocarbazolyl]triazine; di(biphenyl)[(phenyl)indolocarbazolyl]triazine; di(biphenyl)[(phenyl)indolocarbazolyl]triazine; di(phenyl)[(phenyl)(biphenyl)indolocarbazolyl]triazine; di(phenyl)[(phenyl)(biphenyl)indolocarbazolyl]triazine; di(phenyl)[tri(phenyl)indolocarbazolyl]triazine; di(phenyl)[tri(phenyl)indolocarbazolyl]triazine; di(phenyl)[(phenyl)(biphenyl)indolocarbazolyl]triazine; di(phenyl)[(phenyl)(biphenyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(butyl)indolocarbazolyl]triazine; (phenyl)(terphenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(tert-butyl)indolocarbazolyl]triazine; (phenyl)(terphenyl)[(phenyl)di(butyl)indolocarbazolyl]triazine; (biphenyl)(terphenyl)[(phenyl)di(butyl)indolocarbazolyl]triazine; (phenyl)(biphenyl)[(phenyl)indolocarbazolyl]triazine; (phenyl)(biphenyl)[(phenyl)indolocarbazolyl]triazine; di(phenyl)[(biphenyl)indolocarbazolyl]triazine; di(phenyl)[(biphenyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(phenyl)[(terphenyl)indolocarbazolyl]triazine; di(phenyl)[(terphenyl)indolocarbazolyl]triazine; di(phenyl)[(terphenyl)indolocarbazolyl]triazine; di(biphenyl)[(phenyl)indolocarbazolyl]triazine; di(biphenyl)[(phenyl)indolocarbazolyl]triazine; di(biphenyl)[(phenyl)indolocarbazolyl]triazine; di(biphenyl)[(phenyl)indolocarbazolyl]triazine; di(phenyl)[(phenyl)(biphenyl)indolocarbazolyl]triazine; di(phenyl)[(phenyl)(biphenyl)indolocarbazolyl]triazine; di(phenyl)[tri(phenyl)indolocarbazolyl]triazine; di(phenyl)[tri(phenyl)indolocarbazolyl]triazine; di(phenyl)[di(phenyl)(biphenyl)indolocarbazolyl]triazine; di(phenyl)[di(phenyl)(biphenyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(butyl)indolocarbazolyl]triazine; (phenyl)(terphenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(tert-butyl)indolocarbazolyl]triazine; (phenyl)(terphenyl)[(phenyl)di(butyl)indolocarbazolyl]triazine; (biphenyl)(terphenyl)[(phenyl)di(butyl)indolocarbazolyl]triazine; (phenyl)(biphenyl)[(phenyl)indolocarbazolyl]triazine; (phenyl)(biphenyl)[(phenyl)indolocarbazolyl]triazine; di(phenyl)[(biphenyl)indolocarbazolyl]triazine; di(phenyl)[(biphenyl)indolocarbazolyl]triazine; di(phenyl)[di(phenyl)indolocarbazolyl]triazine; di(phenyl)[di(phenyl)indolocarbazolyl]triazine; di(phenyl)[di(phenyl)indolocarbazolyl]triazine; di(phenyl)[(phenyl)(naphthyl)indolocarbazolyl]triazine; di(phenyl)[(phenyl)(quinolyl)indolocarbazolyl]triazine; di(phenyl)[(phenyl)(naphthyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(phenyl)[(terphenyl)indolocarbazolyl]triazine; di(phenyl)[(terphenyl)indolocarbazolyl]triazine; di(phenyl)[(terphenyl)indolocarbazolyl]triazine; di(phenyl)[(terphenyl)indolocarbazolyl]triazine; di(biphenyl)[(phenyl)indolocarbazolyl]triazine; di(biphenyl)[(phenyl)indolocarbazolyl]triazine; di(biphenyl)[(phenyl)indolocarbazolyl]triazine; di(phenyl)[(phenyl)(biphenyl)indolocarbazolyl]triazine; di(phenyl)[(phenyl)(biphenyl)indolocarbazolyl]triazine; di(phenyl)[tri(phenyl)indolocarbazolyl]triazine; di(phenyl)[tri(phenyl)indolocarbazolyl]triazine; di(phenyl)[di(phenyl)(biphenyl)indolocarbazolyl]triazine; di(phenyl)[di(phenyl)(biphenyl)indolocarbazolyl]triazine; di(phenyl)[(phenyl)di(pyridyl)indolocarbazolyl]triazine; di(phenyl)[(phenyl)di(methyl)indolocarbazolyl]triazine; di(phenyl)[(phenyl)di(butyl)indolocarbazolyl]triazine; di(phenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(butyl)indolocarbazolyl]triazine; (phenyl)(terphenyl)[(phenyl)di(tert-butyl)indolocarbazolyl]triazine; (phenyl)(biphenyl)[(phenyl)di(butyl)indolocarbazolyl]triazine; (phenyl)(biphenyl)[(phenyl)di(tert-butyl)indolocarbazolyl]triazine; (phenyl)(terphenyl)[(phenyl)di(butyl)indolocarbazolyl]triazine; (phenyl)(terphenyl)[(phenyl)di(tert-butyl)indolocarbazolyl]triazine; (biphenyl)(terphenyl)[(phenyl)di(tert-butyl)indolocarbazolyl]triazine; (phenyl)(biphenyl)[(phenyl)indolocarbazolyl]triazine; (phenyl)(biphenyl)[(phenyl)indolocarbazolyl]triazine; di(phenyl)[(biphenyl)indolocarbazolyl]triazine; di(phenyl)[(biphenyl)indolocarbazolyl]triazine; di(phenyl)[tri(phenyl)indolocarbazolyl]triazine; di(phenyl)[(phenyl)di(butyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(biphenyl)[(phenyl)indolocarbazolyl]triazine; di(biphenyl)[(phenyl)indolocarbazolyl]triazine; (phenyl)(biphenyl)[(phenyl)indolocarbazolyl]triazine; (phenyl)(biphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(biphenyl)[(phenyl)indolocarbazolyl]triazine; di(biphenyl)[(phenyl)indolocarbazolyl]triazine; (phenyl)(biphenyl)[(phenyl)indolocarbazolyl]triazine; (phenyl)(biphenyl)[(phenyl)indolocarbazolyl]triazine; di(phenyl)[(biphenyl)indolocarbazolyl]triazine; di(phenyl)[(biphenyl)indolocarbazolyl]triazine; di(phenyl)[tri(phenyl)indolocarbazolyl]triazine; di(phenyl)[(phenyl)di(butyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; (phenyl)(terphenyl)[(phenyl)indolocarbazolyl]triazine; di(biphenyl)[(phenyl)indolocarbazolyl]triazine; di(biphenyl)[(phenyl)indolocarbazolyl]triazine; di(terphenyl)[(phenyl)indolocarbazolyl]triazine; di(terphenyl)[(phenyl)indolocarbazolyl]triazine; di(terphenyl)[(phenyl)indolocarbazolyl]triazine; di(terphenyl)[(phenyl)indolocarbazolyl]triazine; (phenyl)(biphenyl)[(phenyl)(dibenzofuranyl)indolocarbazolyl]triazine; (phenyl)(biphenyl)[(phenyl)(dibenzothiophenyl)indolocarbazolyl]triazine; (phenyl)(terphenyl)[(phenyl)(dibenzofuranyl)indolocarbazolyl]triazine; (phenyl)(terphenyl)[(phenyl)(dibenzothiophenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; di(phenyl)[(phenyl)indolocarbazolyl]triazine; (naphthyl)(biphenyl)bicarbazole; di(biphenyl)bicarbazole; di(biphenyl)bicarbazole; di(biphenyl)bicarbazole; (biphenyl)(phenanthryl)bicarbazole; (biphenyl)(anthryl)bicarbazole; (biphenyl)(naphthylphenyl)bicarbazole; (biphenyl)(naphthylphenyl)bicarbazole; (biphenyl)(terphenyl)bicarbazole; (biphenyl)(anthrylphenyl)bicarbazole; (biphenyl)(naphthylphenyl)bicarbazole; (biphenyl)(anthrylphenyl)bicarbazole; (biphenyl)(naphthylphenyl)bicarbazole; (biphenyl)(terphenyl)bicarbazole; (biphenyl)(terphenyl)bicarbazole; (biphenyl)(terphenyl)bicarbazole; (biphenyl)(terphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (phenyl)(biphenyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenyl)bicarbazole; (phenyl)(terphenyl)bicarbazole; (phenyl)(terphenyl)bicarbazole; (phenyl)(naphthylbiphenyl)bicarbazole; (phenyl)(naphthylbiphenyl)bicarbazole; (naphthyl)(biphenyl)bicarbazole; di(biphenyl)bicarbazole; di(biphenyl)bicarbazole; di(biphenyl)bicarbazole; (biphenyl)(phenanthryl)bicarbazole; (biphenyl)(anthryl)bicarbazole; (biphenyl)(naphthylphenyl)bicarbazole; (biphenyl)(naphthylphenyl)bicarbazole; (biphenyl)(terphenyl)bicarbazole; (biphenyl)(anthrylphenyl)bicarbazole; (biphenyl)(naphthylphenyl)bicarbazole; (biphenyl)(anthrylphenyl)bicarbazole; (biphenyl)(naphthylphenyl)bicarbazole; (biphenyl)(terphenyl)bicarbazole; (biphenyl)(terphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (phenyl)(biphenyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenyl)bicarbazole; (phenyl)(terphenyl)bicarbazole; (phenyl)(terphenyl)bicarbazole; (phenyl)(naphthylbiphenyl)bicarbazole; (phenyl)(naphthylbiphenyl)bicarbazole; (naphthyl)(biphenyl)bicarbazole; di(biphenyl)bicarbazole; di(biphenyl)bicarbazole; di(biphenyl)bicarbazole; (biphenyl)(phenanthryl)bicarbazole; (biphenyl)(anthryl)bicarbazole; (biphenyl)(naphthylphenyl)bicarbazole; (biphenyl)(naphthylphenyl)bicarbazole; (biphenyl)(terphenyl)bicarbazole; (biphenyl)(anthrylphenyl)bicarbazole; (biphenyl)(naphthylphenyl)bicarbazole; (biphenyl)(anthrylphenyl)bicarbazole; (biphenyl)(naphthylphenyl)bicarbazole; (biphenyl)(terphenyl)bicarbazole; (biphenyl)(terphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (naphthyl)(biphenyl)bicarbazole; di(biphenyl)bicarbazole; di(biphenyl)bicarbazole; di(biphenyl)bicarbazole; (biphenyl)(phenanthryl)bicarbazole; (biphenyl)(anthryl)bicarbazole; (biphenyl)(naphthylphenyl)bicarbazole; (biphenyl)(naphthylphenyl)bicarbazole; (biphenyl)(terphenyl)bicarbazole; (biphenyl)(anthrylphenyl)bicarbazole; (biphenyl)(naphthylphenyl)bicarbazole; (biphenyl)(anthrylphenyl)bicarbazole; (biphenyl)(naphthylphenyl)bicarbazole; (biphenyl)(terphenyl)bicarbazole; (biphenyl)(terphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (biphenyl)(terphenyl)bicarbazole; (biphenyl)(naphthylbiphenyl)bicarbazole; (biphenyl)(naphthylphenyl)bicarbazole; (biphenyl)(naphthylphenyl)bicarbazole; (biphenyl)(phenanthrylphenyl)bicarbazole; (phenyl)(biphenyl)bicarbazole; (phenyl)(naphthylphenyl)bicarbazole; (phenyl)(naphthylphenyl)bicarbazole; (phenyl)(phenanthrylphenyl)bicarbazole; (phenyl)(terphenyl)bicarbazole; (phenyl)(terphenyl)bicarbazole; (phenyl)(terphenyl)bicarbazole; (phenyl)(naphthylbiphenyl)bicarbazole; (phenyl)(naphthylbiphenyl)bicarbazole

### (Group 25A)

di(bipyridinyl)triphenylene; di(bipyridinyl)triphenylene; bis(dipyridinylphenyl)phenylpyrimidine; (phenylquinquephenyl)diphenylpyrimidine; (phenylquarterphenyl)diphenylpyrimidine; bis[(biphenylpyrimidinyl)phenyl]ether; di(terphenyl)sulfone; bis(diphenylterphenyl)sulfone; phenyl(diphenylquinquephenyl)sulfone; di(spirobifluorenyl)ketone; bis(diphenylfluorenyl)ketone; bis(dimethylfluorenyl)naphthyltriazine; bis(dimethylfluorenyl)biphenyltriazine; bis(dimethylfluorenyl)terphenyltriazine; biphenyl(spirobifluorenyl)phenylpyridine; biphenyl(spirobifluorenyl)phenylpyridine; biphenyl(spirobifluorenyl)naphthylpyridine; di(terphenyl)(spirobifluorenyl)pyridine; biphenyl(spirobifluorenyl)phenylpyridine; biphenyl(spirobifluorenyl)phenylpyridine; biphenyl(spirobifluorenyl)naphthylpyridine; di(terphenyl)(spirobifluorenyl)pyridine; biphenyl(spirobifluorenyl)phenylpyridine; biphenyl(spirobifluorenyl)phenylpyridine; biphenyl(spirobifluorenyl)naphthylpyridine; biphenyl(spirobifluorenyl)phenylpyrimidine; biphenyl(spirobifluorenyl)phenylpyrimidine; di(biphenyl)(spirobifluorenyl)phenylpyrimidine; biphenyl(spirobifluorenyl)naphthylpyrimidine; terphenyl(spirobifluorenyl)phenylpyrimidine; biphenyl(spirobifluorenyl)phenylpyrimidine; biphenyl(spirobifluorenyl)phenylpyrimidine; biphenyl(spirobifluorenyl)naphthylpyrimidine; biphenyl(spirobifluorenyl)naphthylpyrimidine; terphenyl(spirobifluorenyl)phenylpyrimidine; biphenyl(spirobifluorenyl)phenyltriazine; biphenyl(spirobifluorenyl)phenyltriazine; (biphenyl-di)(spirobifluorenyl)phenyltriazine; (biphenyl-d₅)(spirobifluorenyl)phenyltriazine; biphenyl(spirobifluorenyl)(phenyl-d₅)triazine; terphenyl(spirobifluorenyl)phenyltriazine; terphenyl(spirobifluorenyl)naphthyltriazine; biphenyl(spirobifluorenyl)quinazoline; biphenyl(spirobifluorenyl)quinazoline; terphenyl(spirobifluorenyl)quinazoline; terphenyl(spirobifluorenyl)quinazoline; (biphenyl-di)(spirobifluorenyl)quinazoline; terphenyl(spirobifluorenyl)quinazoline; di(terphenyl)diboraoxanaphthoanthracene; di(terphenyl)diboraoxanaphthoanthracene; [(triphenylenyl)biphenyl]diboraoxanaphthoanthracene; (quarterphenyl)diboraoxanaphthoanthracene; (phenylquarterphenyl)diboraoxanaphthoanthracene; di(dibenzofuranyl)diboraoxanaphthoanthracene; di(dibenzofuranyl)diboraoxanaphthoanthracene; di(biphenyl)(dimethylfluorenyl)triazine; (terphenyl)(biphenyl)(dimethylfluorenyl)triazine; di(terphenyl)(dimethylfluorenyl)triazine; (biphenyl)(diphenylfluorenyl)phenyltriazine; (biphenyl)(diphenylfluorenyl)phenyltriazine; bis(diphenylphosphoryl)dibenzothiophene; bis(diphenylphosphoryl)dibenzofuran; diphenyl(triphenylenylterphenyl)amine; diphenyl(quinquephenyl)amine; diphenyl(phenylquinquephenyl)amine; diphenyl[(spirobifluorenyl)biphenyl]amine; bis[(diphenylamino)phenyl]dibenzofuran; [(triphenylenyl)terphenyl]indole; tris(indolylphenyl)benzene; (diphenylquinquephenyl)carbazole; [(triphenylenyl)terphenyl]carbazole; [(triphenylenyl)biphenyl]carbazole; di(carbazolyl)quarterbenzene; (carbazolylbiphenyl)[di(biphenyl)]amine; terphenylbicarbazole; quarterphenylbicarbazole; bis(diphenylcarbazolyl)benzene; di(carbazolyl)terbenzene; di(carbazolyl)quarterbenzene; di(carbazolyl)quarterbenzene; di(carbazolyl)spirobifluorene; [(triphenylenyl)biphenyl]carbazolyldibenzothiophene; di(carbazolyl)dibenzothiophene; di(carbazolyl)dibenzofuran; di(carbazolyl)(diphenylfluorene); di(carbazolyl)(biphenyl)carbazole; (quarterphenyl)bicarbazole; bis(bicarbazolyl)benzene; bis(bicarbazolyl)benzene; bis(bicarbazolyl)biphenyl; bis[di(carbazolyl)carbazolyl]benzene; bis[di(carbazolyl)carbazolyl]biphenyl; tris(carbazolyl)benzene; dimethyl(phenylquarterphenyl)acridone; (phenylquarterphenyl)phenoxazine; (phenylquarterphenyl)phenothiazine; phenyl(phenylquarterphenyl)fenadine; dimethyl[(terphenyl)carbazolyl]acridone; dimethyl[(terphenyl)carbazolyl]phenoxazine; dimethyl[(terphenyl)carbazolyl]phenothiazine; phenyl(spirobifluorenyl)fenadine; bis(dimethylacridinyl)terbenzene; di(phenoxazinyl)terbenzene; di(phenoxazinyl)biphenyl; di(phenothiazinyl)terbenzene; bis(dimethylacridinyl)biphenyl; di(biphenyl)bicarbazole; di(biphenyl)bicarbazole; phenyl(terphenyl)bicarbazole; di(biphenyl)bicarbazole-d₂; phenyl(triphenylenyl)bicarbazole; biphenyl(terphenyl)bicarbazole; diphenyltercarbazole; phenyl(dibenzothiophenyl)bicarbazole; phenyl(dimethylfluorenyl)bicarbazole; di(biphenyl)bicarbazole; phenyl(triphenylenyl)bicarbazole; di(biphenyl)bicarbazole-d₂; di(biphenyl)bicarbazole-d₂; phenyl(terphenyl)bicarbazole; phenyl(triphenylenyl)bicarbazole; di(biphenyl)bicarbazole; diphenyltercarbazole; phenyl(triphenylenyl)bicarbazole-d₁; di(biphenyl)bicarbazole; phenyl(triphenylenyl)bicarbazole; di(biphenyl)bicarbazole; phenyl(triphenylenyl)bicarbazole; phenyl(dibenzofuranyl)bicarbazole; phenyl(terphenyl)bicarbazole-d₂; di(biphenyl)bicarbazole; phenyl(triphenylenyl)bicarbazole; (phenylcarbazolyl)[(triphenylenyl)carbazolyl]benzene; (phenylcarbazolyl)[(biphenyl)carbazolyl]benzene; (phenylcarbazolyl)[(biphenyl)carbazolyl]benzene; (phenylcarbazolyl)[(terphenyl)carbazolyl]benzene; bis(phenylcarbazolyl)biphenyl; bis[(biphenyl)carbazolyl]biphenyl; (phenylcarbazolyl)[(triphenylenyl)carbazolyl]biphenyl; (phenylcarbazolyl)[(terphenyl)carbazolyl]biphenyl; bis(phenylcarbazolyl)biphenyl-d₂; terphenyl(dimethylfluorenyl)carbazole; quarterphenyl(dimethylfluorenyl)carbazole; terphenyl(dimethylfluorenyl)carbazole; terphenyl(diphenylfluorenyl)carbazole; quarterphenyl(dibenzothiophenyl)carbazole; terphenyl(dibenzofuranyl)carbazole; biphenyl(dibenzofuranyl)bicarbazole; terphenyl(dibenzothiophenyl)carbazole; di(biphenyl)indolocarbazole; di(biphenyl)indolocarbazole; phenyl(terphenyl)indolocarbazole-d₂; bis(phenylindolocarbazolyl)benzene; di(biphenyl)indolocarbazole; phenyl(terphenyl)indolocarbazole; phenyl(terphenyl)indolocarbazole-d₁; bis(phenylindolocarbazolyl)benzene; bis(phenylindolocarbazolyl)biphenyl; phenyl(dinaphthylphenyl)indolocarbazole; phenyl(spirobifluorenyl)indolocarbazole; di(biphenyl)indolocarbazole; bis(phenylindolocarbazolyl)biphenyl; phenyl(terphenyl)indolocarbazole; di(biphenyl)indolocarbazole; bis(phenylindolocarbazolyl)biphenyl; di(terphenyl)indolocarbazole; phenyl(quarterphenyl)indolocarbazole; phenyl(terphenyl)indolocarbazole-d₂; bis(phenylindolocarbazolyl)benzene; (quarterphenyl)dimethylindenocarbazole; (quarterphenyl)dimethylindenocarbazole; [(terphenyl)carbazolyl]dimethylindenocarbazole; (terphenyl)oxazaindenofluorene; bis(oxazaindenofluorenylbiphenyl); (quarterphenyl)oxazaindenofluorene; (quinquephenyl)benzothienocarbazole; (terphenyl)benzothienocarbazole; phenyl(terphenyl)indolophenoxazine; phenyl(terphenyl)indoloacridone; phenyl(terphenyl)indolophenothiazine di(biphenyl)indolophenoxazine; di(biphenyl)indolophenothiazine; di(biphenyl)indoloacridone; phenyl(terphenyl)indolophenoxazine; phenyl(terphenyl)indolophenothiazine; phenyl(terphenyl)indoloacridone phenyl(terphenyl)spiroindolo(acridinefluorene); phenyl(quarterphenyl)indolophenothiazine; phenyl(terphenyl)indolophenoxazine; phenyl(terphenyl)indoloacridone; phenyl(biphenyl)spiroindolo(phenothiazinefluorene); phenyl(terphenyl)benzindolocarbazole

### (Group 26A)

(phenyl)(biphenyl)[(phenylbicarbazolyl)phenyl]triazine; di(phenyl)[(phenylbicarbazolyl)biphenyl]triazine; di(phenyl)[(biphenylbicarbazolyl)phenyl]triazine; di(phenyl)[(diphenylbicarbazolyl)phenyl]triazine; (phenyl)(cyanotriphenylenyl)bicarbazole; (methylphenyl)(cyanotriphenylenyl)bicarbazole; (tert-butylphenyl)(cyanotriphenylenyl)bicarbazole

### (Group 27A)

CBP(dicarbazolebiphenyl); PVK(poly(n-vinylcarbazone)); ADN(di(naphthalenyl)anthracene); TCTA; TPBI(tris(phenylbenzimidazolyl)benzene)); Ir(pq)₂(acac); PtOEP; Ir(piq)₃; Btp₂; Ir(acac); Ir(ppy)₃; Ir(ppy)₂(acac); Ir(mpyp)₃; Firpic; (F2ppy)₂Irtmd); Ir(dfppz)₃; mCP(dicarbazolebenzene); mCBP(di(carbazolyl)biphenyl); CBP(bis(carbazolyl)biphenyl); TPBI(tris(phenylbenzimidazolyl)benzene)); BmPyPb(tri[(pyridyl)phenyl]benzene); TSPO1(diphenylphosphine oxidetriphenylsilylphenyl); Alq3(tris(quinolinolato)aluminum; COT(octa-substituted cyclooctatetraene); TAZ; Bphen(diphenylphenanthroline)); BCP; Balq

### (Group 28A)

tris[(methylindolocarbazolyl)phenyl]amine; tris[(azaoxaindenofluorenyl)phenyl]amine; tris[(thiaazaindenobenzofluorenyl)phenyl]amine; tris[(indenocarbazolyl)phenyl]amine; bis[(methylindolocarbazolyl)phenyl][(azaoxaindenofluorenyl)phenyl]amine; tris[(azaoxaindenobenzofluorenyl)phenyl]amine; tris[(azaselenaindenobenzofluorenyl)phenyl]amine; tris[(thiaazaindenofluorenyl)phenyl]amine; [(methylindolocarbazolyl)phenyl]bis[(azaoxaindenofluorenyl)phenyl]amine; tris[(azaoxaindenonaphthofluorenyl)phenyl]amine; tris[(azaselenaindenobenzofluorenyl)phenyl]amine; tris[(phenylindolocarbazolyl)phenyl]amine; tris[(dimethylindolophenazinyl)phenyl]amine; [(dihydroindoloanthracenyl)phenyl]bis[(indolothioxanthenyl)phenyl]amine; tris[(indolophenoxathiinyl)phenyl]amine; tris[(indoloxanthenyl)phenyl]amine; tris[(methylindolobenzophenoxazinyl)phenyl]amine; tris[(indenoacridinyl)phenyl]amine; tris[(benzofuroacridinyl)phenyl]amine; tris[(benzothiophenothiazinyl)phenyl]amine; tris[(phenylbenzothiophenazinyl)phenyl]amine; tris[(dihydrobenzofurophenanthridinyl)phenyl]amine; tetrakis[(methylindolocarbazolyl)phenyl]silane; tetrakis[(azaoxaindenofluorenyl)phenyl]silane; tetrakis[(azaselenaindenofluorenyl)phenyl]silane; tetrakis[(azaoxaindenofluorenyl)phenyl]silane; tetrakis[(azaoxaindenofluorenyl)phenyl]silane; tetrakis[((azaoxadithiapentacenyl)phenyl]silane; tetrakis[(azaoxaindenofluorenyl)phenyl]germane; tetrakis[(methylindolocarbazolyl)phenyl]germane; tetrakis[(methyldi(azaoxathiapentacenyl)phenyl]germane; bis[(benzofurophenoxazinyl)phenyl]bis[(benzothienophenoxazinyl)phenyl]germane; (phenyl)(benzofurocarbazolyl)[(benzofurocarbazolyl)phenyl]phosphine oxide; (phenyl)(benzothienocarbazolyl)[(benzothienocarbazolyl)pyridyl]phosphine oxide; (pyridyl)(methylindolocarbazolyl)[(methylindolocarbazolyl)phenyl]phosphine oxide; (phenyl)(benzothienocarbazolyl)[(benzothienocarbazolyl)phenyl]phosphine oxide; (phenyl)(benzselenocarbazolyl)[(benzselenocarbazolyl)phenyl]phosphine oxide; (phenyl)(azaoxaindenobenzofluorenyl)[(azaoxaindenobenzofluorenyl)phenyl]phosphine oxide; (phenyl)(dimethylindolophenazinyl)[(dimethylindolophenazinyl)phenyl]phosphine oxide; (phenyl)(indolothioxanthenyl)[(indolothioxanthenyl)pyridyl]phosphine oxide; (phenyl)(methylindolophenothiazinyl)[(methylindolophenothiazinyl)pyridyl]phosphine oxide; bis[(azaoxaindenofluorenyl)phenyl]furan; bis[(methylindolophenothiazinyl)phenyl]furan; bis[(thiaazaindenofluorenyl)phenyl]thiophene; bis[(azaselenaindenofluorenyl)pyridyl]thiophene; bis[(thiaazaindenofluorenyl)phenyl]selenophene; bis[(phenylindoloacridinyl)phenyl]selenophene; dimethylbis[(thiaazaindenofluorenyl)phenyl]cyclopentadiene; dimethylbis[(phenylindolobenzocarbazolyl)pyridyl]cyclopentadiene; bis[(benzothienophenothiazinyl)phenyl]oxazole; bis[(benzofurophenoxazinyl)phenyl]oxadiazole; bis[(benzothienophenoxazinyl)phenyl]thiadiazole

### (Group 29A)

di(phenyl)[(phenylbicarbazolyl)phenyl]triazine; di(phenyl)[(phenylbicarbazolyl)phenyl]triazine; di(phenyl)[(phenylbicarbazolyl)phenyl]triazine; di(phenyl)(biphenylbicarbazolyl)triazine; di(phenyl)(biphenylbicarbazolyl)triazine; di(phenyl)(biphenylbicarbazolyl)triazine; (phenyl)(biphenyl)(phenylbicarbazolyl)triazine; (phenyl)(biphenyl)(phenylbicarbazolyl)triazine; (phenyl)(biphenyl)(phenylbicarbazolyl)triazine; (phenyl)(biphenyl)(phenylbicarbazolyl)triazine; (phenyl)(biphenyl)(phenylbicarbazolyl)triazine; (phenyl)(biphenyl)(phenylbicarbazolyl)triazine; di(phenyl)(biphenylbicarbazolyl)triazine; di(phenyl)(biphenylbicarbazolyl)triazine; di(phenyl)(biphenylbicarbazolyl)triazine; di(phenyl)[(methylphenylbicarbazolyl)phenyl]triazine; di(phenyl)[(methylphenylbicarbazolyl)phenyl]triazine; di(phenyl)[methyl(phenylbicarbazolyl)phenyl]triazine; di(phenyl)[(fluorophenylbicarbazolyl)phenyl]triazine; di(phenyl)[fluoro(phenylbicarbazolyl)phenyl]triazine; (phenyl)(fluorophenyl)[(phenylbicarbazolyl)phenyl]triazine; di(phenyl)[(cyclohexylphenylbicarbazolyl)phenyl]triazine; di(phenyl)[(trimethylsilylphenylbicarbazolyl)phenyl]triazine; phenyl(cyanophenanthryl)bicarbazole

### (Group 30A)

dicarbazolylbenzene; dicarbazolylbiphenyl; bis[(oxodiphenylphosphino)phenyl]ether; bis[(dimethyldihydroacridinyl)phenyl]sulfone; di(carbazolyl)benzophosphine; bis(dimethoxycarbazolyl)benzophosphine

### (Group 31A)

(phenyl)(biphenyl)(phenylindolocarbazolyl)triazine; (phenyl)(biphenyl)(phenylindolocarbazolyl)triazine; di(phenyl)(biphenylindolocarbazolyl)triazine; di(phenyl)(biphenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(phenyl)(terphenylindolocarbazolyl)triazine; di(phenyl)(terphenylindolocarbazolyl)triazine; di(phenyl)(terphenylindolocarbazolyl)triazine; di(phenyl)(terphenylindolocarbazolyl)triazine; di(biphenyl)(phenylindolocarbazolyl)triazine; di(biphenyl)(phenylindolocarbazolyl)triazine; di(biphenyl)(phenylindolocarbazolyl)triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)(dibutylphenylindolocarbazolyl)triazine; (phenyl)(terphenyl)[di(tert-butyl)phenylindolocarbazolyl]triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)[di(tert-butyl)phenylindolocarbazolyl]triazine; (phenyl)(terphenyl)(dibutylphenylindolocarbazolyl)triazine; (biphenyl)(biphenyl)(dibutylphenylindolocarbazolyl)triazine; (phenyl)(biphenyl)(phenylindolocarbazolyl)triazine; (phenyl)(biphenyl)(phenylindolocarbazolyl)triazine; di(phenyl)(biphenylindolocarbazolyl)triazine; di(phenyl)(biphenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(phenyl)(terphenylindolocarbazolyl)triazine; di(phenyl)(terphenylindolocarbazolyl)triazine; di(phenyl)(terphenylindolocarbazolyl)triazine; di(biphenyl)(phenylindolocarbazolyl)triazine; di(biphenyl)(phenylindolocarbazolyl)triazine; di(biphenyl)(phenylindolocarbazolyl)triazine; di(biphenyl)(phenylindolocarbazolyl)triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)(dibutylphenylindolocarbazolyl)triazine; (phenyl)(terphenyl)[di(tert-butyl)phenylindolocarbazolyl]triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)[di(tert-butyl)phenylindolocarbazolyl]triazine; (phenyl)(terphenyl)(dibutylphenylindolocarbazolyl)triazine; (biphenyl)(terphenyl)(dibutylphenylindolocarbazolyl)triazine; (phenyl)(biphenyl)(phenylindolocarbazolyl)triazine; (phenyl)(biphenyl)(phenylindolocarbazolyl)triazine; di(phenyl)(biphenylindolocarbazolyl)triazine; di(phenyl)(biphenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(phenyl)(terphenylindolocarbazolyl)triazine; di(phenyl)(terphenylindolocarbazolyl)triazine; di(phenyl)(terphenylindolocarbazolyl)triazine; di(phenyl)(terphenylindolocarbazolyl)triazine; di(biphenyl)(phenylindolocarbazolyl)triazine; di(biphenyl)(phenylindolocarbazolyl)triazine; di(biphenyl)(phenylindolocarbazolyl)triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)(dibutylphenylindolocarbazolyl)triazine; (phenyl)(terphenyl)[di(tert-butyl)phenylindolocarbazolyl]triazine; (phenyl)(biphenyl)(dibutylphenylindolocarbazolyl)triazine; (phenyl)(biphenyl)[di(tert-butyl)phenylindolocarbazolyl]triazine; (phenyl)(terphenyl)(dibutylphenylindolocarbazolyl)triazine; (phenyl)(terphenyl)[di(tert-butyl)phenylindolocarbazolyl]triazine; (biphenyl)(terphenyl)[di(tert-butyl)phenylindolocarbazolyl]triazine; (phenyl)(biphenyl)(phenylindolocarbazolyl)triazine; (phenyl)(biphenyl)(phenylindolocarbazolyl)triazine; di(phenyl)(biphenylindolocarbazolyl)triazine; di(phenyl)(biphenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(biphenyl)(phenylindolocarbazolyl)triazine; di(biphenyl)(phenylindolocarbazolyl)triazine; (phenyl)(biphenyl)(phenylindolocarbazolyl)triazine; (phenyl)(biphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(biphenyl)(phenylindolocarbazolyl)triazine; di(biphenyl)(phenylindolocarbazolyl)triazine; (phenyl)(biphenyl)(phenylindolocarbazolyl)triazine; (phenyl)(biphenyl)(phenylindolocarbazolyl)triazine; di(phenyl)(biphenylindolocarbazolyl)triazine; di(phenyl)(biphenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; (phenyl)(terphenyl)(phenylindolocarbazolyl)triazine; di(biphenyl)(phenylindolocarbazolyl)triazine; di(biphenyl)(phenylindolocarbazolyl)triazine; di(terphenyl)(phenylindolocarbazolyl)triazine; di(terphenyl)(phenylindolocarbazolyl)triazine; di(terphenyl)(phenylindolocarbazolyl)triazine; di(terphenyl)(phenylindolocarbazolyl)triazine; (phenyl)(biphenyl)[phenyl(dibenzofuranyl)indolocarbazolyl]triazine; (phenyl)(biphenyl)[phenyl(dibenzothiophenyl)indolocarbazolyl]triazine; (phenyl)(terphenyl)[phenyl(dibenzofuranyl)indolocarbazolyl]triazine; (phenyl)(terphenyl)[phenyl(dibenzothiophenyl)indolocarbazolyl]triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(biphenyl)(biphenylindolocarbazolyl)triazine; (phenyl)(terphenyl)(biphenylindolocarbazolyl)triazine; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; di(biphenyl)bicarbazole; (phenyl)(biphenyl)bicarbazole; (phenyl)(biphenyl)bicarbazole; (phenyl)(biphenyl)bicarbazole; (phenyl)(biphenyl)bicarbazole; (phenyl)(biphenyl)bicarbazole; di(biphenyl)bicarbazole; (phenyl)(terphenyl)bicarbazole; (phenyl)(terphenyl)bicarbazole; (biphenyl)(terphenyl)bicarbazole; (phenyl)(terphenyl)bicarbazole; (phenyl)(terphenyl)bicarbazole; (biphenyl)(terphenyl)bicarbazole; di(biphenyl)bicarbazole; di(biphenyl)bicarbazole

### (Group 32A)

(phenyl)(carbazolylphenyl)(dibenzofuranyl)triazine; (biphenyl)(carbazolylphenyl)(dibenzofuranyl)triazine; (terphenyl)(carbazolylphenyl)(dibenzofuranyl)triazine; (biphenyl)(carbazolylphenyl)(dibenzofuranyl)triazine; (terphenyl)(carbazolylphenyl)(dibenzofuranyl)triazine; (phenyl)(phenylcarbazolylphenyl)(dibenzofuranyl)triazine; (terphenyl)(carbazolylphenyl)(dibenzofuranyl)triazine; (terphenyl)(carbazolylphenyl)(dibenzofuranyl)triazine; (phenyl)(phenylcarbazolylphenyl)(dibenzofuranyl)triazine; (phenyl)(phenylcarbazolylphenyl)(dibenzofuranyl)triazine; (phenyl)(diphenylcarbazolylphenyl)(dibenzofuranyl)triazine; (phenyl)(biphenylcarbazolylphenyl)(dibenzofuranyl)triazine; (phenyl)(biphenylcarbazolylphenyl)(dibenzofuranyl)triazine; (phenyl)(biphenylcarbazolylphenyl)(dibenzofuranyl)triazine; (biphenyl)(phenylcarbazolylphenyl)(dibenzofuranyl)triazine; (phenyl)(carbazolylbiphenyl)(dibenzofuranyl)triazine; (phenyl)(phenylcarbazolylbiphenyl)(dibenzofuranyl)triazine; (phenyl)(carbazolylterphenyl)(dibenzofuranyl)triazine; (biphenyl)(carbazolylbiphenyl)(dibenzofuranyl)triazine; (phenyl)(phenylcarbazolylbiphenyl)(dibenzofuranyl)triazine; (phenyl)(carbazolylbiphenyl)(dibenzofuranyl)triazine; (biphenyl)(carbazolylbiphenyl)(dibenzofuranyl)triazine; (biphenyl)(carbazolylbiphenyl)(dibenzofuranyl)triazine; (terphenyl)(carbazolylbiphenyl)(dibenzofuranyl)triazine; (phenyl)(carbazolylterphenyl)(dibenzofuranyl)triazine; (phenyl)(phenylcarbazolylbiphenyl)(dibenzofuranyl)triazine; (phenyl)(phenylcarbazolylbiphenyl)(dibenzofuranyl)triazine; (phenyl)(phenylcarbazolylbiphenyl)(dibenzofuranyl)triazine; (biphenyl)(carbazolylbiphenyl)(dibenzofuranyl)triazine; (terphenyl)(carbazolylbiphenyl)(dibenzofuranyl)triazine; (phenyl)(diphenylcarbazolylbiphenyl)(dibenzofuranyl)triazine; (phenyl)(carbazolylbiphenyl)(dibenzofuranyl)triazine; (biphenyl)(carbazolylbiphenyl)(dibenzofuranyl)triazine; (phenyl)(phenylcarbazolylbiphenyl)(dibenzofuranyl)triazine; (phenyl)(phenylcarbazolylbiphenyl)(dibenzofuranyl)triazine; (biphenyl)(phenylcarbazolylbiphenyl)(dibenzofuranyl)triazine; (phenyl)(carbazolylterphenyl)(dibenzofuranyl)triazine; (phenyl)(carbazolylterphenyl)(dibenzofuranyl)triazine; (carbazolylphenyl)bis(dibenzofuranyl)triazine; (carbazolylbiphenyl)bis(dibenzofuranyl)triazine; (phenyl)(carbazolylphenyl)(dibenzothiophenyl)triazine; (biphenyl)(carbazolylphenyl)(dibenzothiophenyl)triazine; (terphenyl)(carbazolylphenyl)(dibenzothiophenyl)triazine; (biphenyl)(carbazolylphenyl)(dibenzothiophenyl)triazine; (terphenyl)(carbazolylphenyl)(dibenzothiophenyl)triazine; (terphenyl)(carbazolylphenyl)(dibenzothiophenyl)triazine; (terphenyl)(carbazolylphenyl)(dibenzothiophenyl)triazine; (phenyl)(phenylcarbazolylphenyl)(dibenzothiophenyl)triazine; (phenyl)(phenylcarbazolylphenyl)(dibenzothiophenyl)triazine; (biphenyl)(phenylcarbazolylphenyl)(dibenzothiophenyl)triazine; (phenyl)(diphenylcarbazolylphenyl)(dibenzothiophenyl)triazine; (phenyl)(biphenylcarbazolylphenyl)(dibenzothiophenyl)triazine; (phenyl)(biphenylcarbazolylphenyl)(dibenzothiophenyl)triazine; (phenyl)(biphenylcarbazolylphenyl)(dibenzothiophenyl)triazine; (biphenyl)(phenylcarbazolylphenyl)(dibenzothiophenyl)triazine; (phenyl)(carbazolylbiphenyl)(dibenzothiophenyl)triazine; (biphenyl)(carbazolylbiphenyl)(dibenzothiophenyl)triazine; (phenyl)(carbazolylbiphenyl)(dibenzothiophenyl)triazine; (phenyl)(carbazolylbiphenyl)(dibenzothiophenyl)triazine; (phenyl)(carbazolylterphenyl)(dibenzothiophenyl)triazine; (phenyl)(carbazolylbiphenyl)(dibenzothiophenyl)triazine; (biphenyl)(carbazolylbiphenyl)(dibenzothiophenyl)triazine; (biphenyl)(carbazolylbiphenyl)(dibenzothiophenyl)triazine; (terphenyl)(carbazolylbiphenyl)(dibenzothiophenyl)triazine; (phenyl)(carbazolylterphenyl)(dibenzothiophenyl)triazine; (phenyl)(phenylcarbazolylbiphenyl)(dibenzothiophenyl)triazine; (phenyl)(carbazolylbiphenyl)(dibenzothiophenyl)triazine; (biphenyl)(carbazolylbiphenyl)(dibenzothiophenyl)triazine; (terphenyl)(carbazolylbiphenyl)(dibenzothiophenyl)triazine; (phenyl)(carbazolylterphenyl)(dibenzothiophenyl)triazine; (phenyl)(phenylcarbazolylbiphenyl)(dibenzothiophenyl)triazine; (phenyl)(phenylcarbazolylbiphenyl)(dibenzothiophenyl)triazine; (phenyl)(phenylcarbazolylbiphenyl)(dibenzothiophenyl)triazine; (phenyl)(diphenylcarbazolylbiphenyl)(dibenzothiophenyl)triazine; (phenyl)(carbazolylbiphenyl)(dibenzothiophenyl)triazine; (biphenyl)(carbazolylbiphenyl)(dibenzothiophenyl)triazine; (terphenyl)(carbazolylbiphenyl)(dibenzothiophenyl)triazine; (biphenyl)(carbazolylbiphenyl)(dibenzothiophenyl)triazine; (phenyl)(phenylcarbazolylbiphenyl)(dibenzothiophenyl)triazine; (phenyl)(phenylcarbazolylbiphenyl)(dibenzothiophenyl)triazine; (biphenyl)(phenylcarbazolylbiphenyl)(dibenzothiophenyl)triazine; (phenyl)(carbazolylterphenyl)(dibenzothiophenyl)triazine; (phenyl)(carbazolylterphenyl)(dibenzothiophenyl)triazine; (carbazolylphenyl)bis(dibenzothiophenyl)triazine; (carbazolylbiphenyl)bis(dibenzothiophenyl)triazine; (diphenylpyridyl)(phenyl)bicarbazole; (diphenylpyridyl)(phenyl)bicarbazole; (diphenylpyridyl)(biphenyl)bicarbazole; (diphenylpyridyl)(terphenyl)bicarbazole; (terphenyl)(phenyl)bicarbazole; (diphenylpyridyl)(naphthyl)bicarbazole; (diphenylpyridyl)(naphthyl)bicarbazole; (diphenylpyridyl)(triphenylenyl)bicarbazole; (diphenylpyridyl)(triphenylenyl)bicarbazole; bis(diphenylpyridyl)bicarbazole; bis(diphenylpyridyl)bicarbazole; bis(diphenylpyridyl)bicarbazole; (dimethylfluorenyl)(phenyl)bicarbazole; (dimethylfluorenyl)(biphenyl)bicarbazole; (dimethylfluorenyl)(terphenyl)bicarbazole; (dibenzofuranyl)(phenyl)bicarbazole; (dibenzofuranyl)(biphenyl)bicarbazole; (dibenzofuranyl)(terphenyl)bicarbazole; (dibenzothiophenyl)(phenyl)bicarbazole; (dibenzothiophenyl)(biphenyl)bicarbazole; (dibenzothiophenyl)(terphenyl)bicarbazole; diphenylbicarbazole; dipyridylbicarbazole; dipyrimidylbicarbazole (triphenylenyl)(phenyl)bicarbazole; (pyridyl)(triphenylenyl)bicarbazole; (phenyl)(triphenylenyl)bicarbazole; (pyridyl)(triphenylenyl)bicarbazole; (phenyl)(triphenylenyl)bicarbazole; (pyridyl)(triphenylenyl)bicarbazole; di(biphenyl)bicarbazole; (biphenyl)(terphenyl)bicarbazole; (biphenyl)(terphenyl)bicarbazole; (dimethylfluorenyl)(phenyl)bicarbazole; (dimethylfluorenyl)(biphenyl)bicarbazole; (dimethylfluorenyl)(biphenyl)bicarbazole; (dimethylfluorenyl)(terphenyl)bicarbazole; (dibenzofuranyl)(biphenyl)bicarbazole; (dibenzothiophenyl)(biphenyl)bicarbazole; diphenyltercarbazole; (dibenzofuranyl)(phenyl)bicarbazole; (dibenzofuranyl)(biphenyl)bicarbazole; (dibenzofuranyl)(terphenyl)bicarbazole; (dibenzofuranyl)(biphenyl)bicarbazole; (dibenzothiophenyl)(phenyl)bicarbazole; (dibenzothiophenyl)(biphenyl)bicarbazole; (dibenzothiophenyl)(terphenyl)bicarbazole; (dibenzothiophenyl)(biphenyl)bicarbazole; (dimethylfluorenyl)(diphenylpyridyl)bicarbazole; (dimethylfluorenyl)(diphenylpyridyl)bicarbazole; (dimethylfluorenyl)(pyridylbiphenyl)bicarbazole; (dimethylfluorenyl)(pyridylbiphenyl)bicarbazole; (dimethylfluorenyl)(pyridylbiphenyl)bicarbazole; (dibenzofuranyl)(diphenylpyridyl)bicarbazole; (dibenzofuranyl)(pyridylbiphenyl)bicarbazole; (dibenzofuranyl)(pyridylbiphenyl)bicarbazole; (dibenzofuranyl)(pyridylbiphenyl)bicarbazole; (dibenzothiophenyl)(diphenylpyridyl)bicarbazole; (dibenzothiophenyl)(pyridylbiphenyl)bicarbazole; (dibenzothiophenyl)(pyridylbiphenyl)bicarbazole; (dibenzothiophenyl)(pyridylbiphenyl)bicarbazole; (diphenylpyridyl)(phenyl)bicarbazole; (pyridylbiphenyl)(phenyl)bicarbazole; (diphenylpyridyl)(phenyl)bicarbazole; (diphenylpyridyl)(biphenyl)bicarbazole; (pyridylbiphenyl)(biphenyl)bicarbazole; (diphenylpyridyl)(biphenyl)bicarbazole; (diphenylpyridyl)(biphenyl)bicarbazole; (diphenylpyridyl)(biphenyl)bicarbazole; (pyridylbiphenyl)(biphenyl)bicarbazole; (diphenylpyridyl)(phenyl)bicarbazole; (diphenylpyridyl)(phenyl)bicarbazole; (pyridylbiphenyl)(phenyl)bicarbazole; (diphenylpyridyl)(biphenyl)bicarbazole; (diphenylpyridyl)(biphenyl)bicarbazole; (pyridylbiphenyl)(biphenyl)bicarbazole; (diphenylpyridyl)(biphenyl)bicarbazole; (diphenylpyridyl)(biphenyl)bicarbazole; (pyridylbiphenyl)(biphenyl)bicarbazole; (dibenzofuranyl)(terphenyl)bicarbazole; (dibenzofuranyl)(biphenyl)bicarbazole; (dibenzofuranyl)(phenyl)bicarbazole; (dibenzofuranyl)(biphenyl)bicarbazole; (dibenzothiophenyl)(terphenyl)bicarbazole; (dibenzothiophenyl)(biphenyl)bicarbazole; (dibenzothiophenyl)(phenyl)bicarbazole; (dibenzothiophenyl)(biphenyl)bicarbazole; (diphenylpyridyl)(biphenyl)bicarbazole; (diphenylpyridyl)(biphenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(biphenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(phenyl)bicarbazole; (diphenylpyridyl)(biphenyl)bicarbazole; (diphenylpyridyl)(phenyl)bicarbazole; di(biphenyl)bicarbazole; di(biphenyl)bicarbazole; (biphenyl)(phenyl)bicarbazole; bis(phenylcarbazolyl)benzene; (phenylcarbazolyl)(biphenylcarbazolyl)benzene; bis(biphenylcarbazolyl)benzene; bis(phenylcarbazolyl)benzene; (phenylcarbazolyl)(terphenylcarbazolyl)benzene; bis(biphenylcarbazolyl)benzene; (phenylcarbazolyl)(dimethylfluorenylcarbazolyl)benzene; (dibenzofuranyl)(phenylcarbazolyl)benzene; (dibenzothiophenyl)(phenylcarbazolyl)benzene; bis(phenylcarbazolyl)biphenyl; (phenylcarbazolyl)(biphenylcarbazolyl)benzene; (biphenylcarbazolyl)(terphenylcarbazolyl)benzene; bis(phenylcarbazolyl)benzene; (phenylcarbazolyl)(terphenylcarbazolyl)benzene; bis(biphenylcarbazolyl)benzene; (phenylcarbazolyl)(dimethylfluorenylcarbazolyl)benzene; (phenylcarbazolyl)(terphenylcarbazolyl)benzene; (dibenzothiophenyl)(phenylcarbazolyl)benzene; (biphenyl)(terphenyl)bicarbazole; (biphenyl)(quarterphenyl)bicarbazole; (terphenyl)(quarterphenyl)bicarbazole; (biphenyl)(terphenyl)bicarbazole; (terphenyl)(quarterphenyl)bicarbazole; di(quarterphenyl)bicarbazole; (biphenyl)(quarterphenyl)bicarbazole; (phenyl)(quarterphenyl)bicarbazole; (phenyl)(terphenyl)bicarbazole; di(phenyl)(biphenyl)bicarbazole; di(phenyl)(biphenyl)bicarbazole; tri(phenyl)bicarbazole; tri(phenyl)bicarbazole; di(phenyl)(biphenyl)bicarbazole; di(phenyl)(biphenyl)bicarbazole; di(phenyl)(biphenyl)bicarbazole; (phenyl)(biphenyl)bicarbazole; (dibenzofuranylphenyl)(phenyl)bicarbazole; (dibenzothiophenylphenyl)(phenyl)bicarbazole; diphenylindolocarbazole; (biphenyl)(phenyl)indolocarbazole (biphenyl)(phenyl)indolocarbazole; di(biphenyl)indolocarbazole; di(biphenyl)indolocarbazole; (biphenyl)(terphenyl)indolocarbazole; (biphenyl)(terphenyl)indolocarbazole; di(terphenyl)indolocarbazole; (terphenyl)(phenyl)indolocarbazole; (biphenyl)(terphenyl)indolocarbazole; (biphenyl)(terphenyl)indolocarbazole; di(terphenyl)indolocarbazole; di(biphenyl)(phenyl)indolocarbazole; di(phenyl)(biphenyl)indolocarbazole; di(biphenyl)(phenyl)indolocarbazole; di(biphenyl)(phenyl)indolocarbazole; di(biphenyl)(phenyl)indolocarbazole; di(phenyl)(biphenyl)indolocarbazole; di(biphenyl)(phenyl)indolocarbazole; di(biphenyl)(phenyl)indolocarbazole; di(naphthyl)indolocarbazole; di(naphthyl)indolocarbazole; (naphthyl)(biphenyl)indolocarbazole; (naphthyl)(biphenyl)indolocarbazole; (naphthyl)(terphenyl)indolocarbazole; (naphthyl)(terphenyl)indolocarbazole; (naphthyl)(terphenyl)indolocarbazole; (naphthyl)(terphenyl)indolocarbazole; (naphthylphenyl)(phenyl)indolocarbazole; (naphthylphenyl)(phenyl)indolocarbazole; (naphthylphenyl)(phenyl)indolocarbazole; (naphthylphenyl)(phenyl)indolocarbazole; (naphthylphenyl)(biphenyl)indolocarbazole; (naphthylphenyl)(biphenyl)indolocarbazole; (naphthylphenyl)(biphenyl)indolocarbazole; (naphthylphenyl)(biphenyl)indolocarbazole; (phenylnaphthyl)(biphenyl)indolocarbazole; (phenylnaphthyl)(biphenyl)indolocarbazole; (phenylnaphthyl)(biphenyl)indolocarbazole; (phenylnaphthyl)(biphenyl)indolocarbazole; di(phenyl)(phenylnaphthyl)indolocarbazole; di(phenyl)(phenylnaphthyl)indolocarbazole; di(phenyl)(phenylnaphthyl)indolocarbazole; di(phenyl)(phenylnaphthyl)indolocarbazole; di(phenyl)(naphthylphenyl)indolocarbazole; di(phenyl)(naphthylphenyl)indolocarbazole; di(phenyl)(naphthylphenyl)indolocarbazole; di(phenyl)(naphthylphenyl)indolocarbazole; (phenyl)(naphthyl)(naphthylphenyl)indolocarbazole; (phenyl)(biphenyl)(naphthylphenyl)indolocarbazole; (phenyl)(naphthyl)(naphthylphenyl)indolocarbazole; (phenyl)(biphenyl)(naphthylphenyl)indolocarbazole

### (Group 33A)

[bis(ditrifluoromethylphenyl)indenofluorenediylidene]bis(malononitrile); (diindenothiophenediylidene)bis(malononitrile); [bis(trifluoromethoxyphenyl)indenofluorenediylidene]bis(malononitrile); [bis(trifluoromethoxyphenyl)indenofluorenediylidene]bis(malononitrile); [bis[fluoro(trifluoromethyl)phenyl]diazaindenofluorenediylidene]bis(malononitrile); [bis(trifluoromethylphenyl)diazaindenofluorenediylidene]bis(malononitrile); [bis(trifluoromethylphenyl)diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis(pentafluorophenyl)diazaindenofluorenediylidene]bis(malononitrile); [bis(pentafluorophenyl)diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[bis(trifluoromethyl)phenyl]diazaindenofluorenediylidene]bis(malononitrile); [bis[bis(trifluoromethyl)phenyl]diazaindenofluorenediylidene]bis(aminonitrile); [bis(trifluorophenyl)diazaindenofluorenediylidene]bis(malononitrile); [bis(trifluorophenyl)diazaindenofluorenediylidene]bis(aminonitrile); [bis[(trifluoromethoxy)phenyl]diazaindenofluorenediylidene]bis(malononitrile); [bis[(trifluoromethoxy)phenyl]diazaindenofluorenediylidene]bis(aminonitrile); [bis[(trifluoroacetyl)phenyl]diazaindenofluorenediylidene]bis(malononitrile); [bis[(trifluoroacetyl)phenyl]diazaindenofluorenediylidene]bis(aminonitrile); [bis[cyano(trifluoromethyl)phenyl]diazaindenofluorenediylidene]bis(malononitrile); [bis[cyano(trifluoromethyl)phenyl]diazaindenofluorenediylidene]bis(aminonitrile); [bis(trifluoromethyl)diazaindenofluorenediylidene]bis(malononitrile); [bis(trifluoromethyl)diazaindenofluorenediylidene]bis(aminonitrile); (difluorodiazaindenofluorenediylidene)bis(malononitrile); (difluorodiazaindenofluorenediylidene)bis(aminonitrile); (hexafluorodiazaindenofluorenediylidene)bis(malononitrile); (hexafluorodiazaindenofluorenediylidene)bis(aminonitrile); (tetrafluorodiazaindenofluorenediylidene)bis(malononitrile); (tetrafluorodiazaindenofluorenediylidene)bis(aminonitrile); [bis(trifluoromethyl)azaindenofluorenediylidene]bis(malononitrile); (diphenyldiazaindenofluorenediylidene)bis(malononitrile); (difluorodiazaindenofluorenediylidene)bis[(trifluoromethyl)ethyl acrylate]; (difluorodiazaindenofluorenediylidene)bis(methyleneindandione); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[bis(trifluoromethyl)phenyl]diazaindenofluorenediylidene]bis(malononitrile); [bis[bis(trifluoromethyl)phenyl]diazaindenofluorenediylidene]bis(aminonitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethoxy)phenyl]diazaindenofluorenediylidene]bis(malononitrile); [bis[(trifluoromethoxy)phenyl]diazaindenofluorenediylidene]bis(aminonitrile); [bis[cyano(fluoro)phenyl]diazaindenofluorenediylidene]bis(malononitrile); [bis[cyano(fluoro)phenyl]diazaindenofluorenediylidene]bis(aminonitrile); [bis(fluoropyridyl)diazaindenofluorenediylidene]bis(malononitrile); [bis(fluoropyridyl)diazaindenofluorenediylidene]bis(aminonitrile); [bis(difluoropyridyl)diazaindenofluorenediylidene]bis(malononitrile); [bis(difluoropyridyl)diazaindenofluorenediylidene]bis(aminonitrile); [bis[(trifluoromethyl)thiophenyl]diazaindenofluorenediylidene]bis(malononitrile); [bis[(trifluoromethyl)thiophenyl]diazaindenofluorenediylidene]bis(aminonitrile); (dinaphthyldiazaindenofluorenediylidene)bis(malononitrile); (dinaphthyldiazaindenofluorenediylidene)bis(aminonitrile); [bis(heptafluoronaphthyl)diazaindenofluorenediylidene]bis(malononitrile); [bis(heptafluoronaphthyl)diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [tetrakis[(trifluoromethyl)phenyl]diazaindenofluorenediylidene]bis(malononitrile); [tetrakis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]diazaindenofluorenediylidene]bis(aminonitrile); [bis[(trifluoromethyl)phenyl]diazaindenofluorenediylidene]bis(malononitrile); [bis[(trifluoromethyl)phenyl]indenofluorenediylidene]bis(aminonitrile); [bis[(trifluoromethyl)phenyl]indenofluorenediylidene]bis(malononitrile); [bis[bis(trifluoromethyl)phenyl]indenofluorenediylidene]bis(aminonitrile); [bis[bis(trifluoromethyl)phenyl]indenofluorenediylidene]bis(malononitrile); [bis(trifluorophenyl)indenofluorenediylidene]bis(aminonitrile); [bis(trifluorophenyl)indenofluorenediylidene]bis(malononitrile); [bis(pentafluorophenyl)indenofluorenediylidene]bis(aminonitrile); [bis(pentafluorophenyl)indenofluorenediylidene]bis(malononitrile); [bis(cyanophenyl)indenofluorenediylidene]bis(aminonitrile); [bis(cyanophenyl)indenofluorenediylidene]bis(malononitrile); (diphenylindenofluorenediylidene)bis(aminonitrile); (diphenylindenofluorenediylidene]bis(malononitrile); (dinaphthylindenofluorenediylidene)bis(aminonitrile); (dinaphthylindenofluorenediylidene]bis(malononitrile); (difluoroindenofluorenediylidene)bis(aminonitrile); (difluoroindenofluorenediylidene]bis(malononitrile); (hexafluoroindenofluorenediylidene)bis(aminonitrile); (hexafluoroindenofluorenediylidene]bis(malononitrile); (tetrafluoroindenofluorenediylidene)bis(aminonitrile); (tetrafluoroindenofluorenediylidene]bis(malononitrile); [tetrakis(trifluoromethyl)indenofluorenediylidene]bis(aminonitrile); [tetrakis(trifluoromethyl)indenofluorenediylidene]bis(malononitrile); (phenylindenofluorenediylidene)bis(aminonitrile); [phenyl(trifluoromethyl)indenofluorenediylidene]bis(aminonitrile); (diphenylindenofluorenediylidene)bis(aminonitrile); [diphenylbis(trifluoromethyl)indenofluorenediylidene]bis(aminonitrile); [diphenyl(difluoro)indenofluorenediylidene]bis(aminonitrile); [bis(trifluoromethylphenyl)indenofluorenediylidene]bis(aminonitrile); [dimethylbis(trifluoromethyl)indenofluorenediylidene]bis(malononitrile); [bis[(trifluoromethyl)phenyl]indenofluorenediylidene]bis(malononitrile); [bis[(trifluoromethyl)phenyl]indenofluorenediylidene]bis(aminonitrile); [bis(fluoropyridyl)indenofluorenediylidene]bis(malononitrile); [bis(fluoropyridyl)indenofluorenediylidene]bis(aminonitrile); [bis(difluoropyridyl)indenofluorenediylidene]bis(malononitrile); [bis(difluoropyridyl)indenofluorenediylidene]bis(aminonitrile); [bis(cyanofluorophenyl)indenofluorenediylidene]bis(malononitrile); [bis(cyanofluorophenyl)indenofluorenediylidene]bis(aminonitrile); [bis(cyanophenyl)indenofluorenediylidene]bis(malononitrile); [bis(cyanophenyl)indenofluorenediylidene]bis(aminonitrile); [[(trifluoromethyl)phenyl]indenofluorenediylidene]bis(malononitrile); [[(trifluoromethyl)phenyl]indenofluorenediylidene]bis(aminonitrile); [fluoro[(trifluoromethyl)phenyl]indenofluorenediylidene]bis(malononitrile); [fluoro[(trifluoromethyl)phenyl]indenofluorenediylidene]bis(aminonitrile); [(cyanophenyl)indenofluorenediylidene]bis(malononitrile); [(cyanophenyl)indenofluorenediylidene]bis(aminonitrile); [fluoro(cyanophenyl)indenofluorenediylidene]bis(malononitrile); [fluoro(cyanophenyl)indenofluorenediylidene]bis(aminonitrile); [tetrafluoro[(trifluoromethyl)phenyl]indenofluorenediylidene]bis(malononitrile); [tetrafluoro[(trifluoromethyl)phenyl]indenofluorenediylidene]bis(aminonitrile); [[fluoro(trifluoromethyl)phenyl]indenofluorenediylidene]bis(malononitrile); [[fluoro(trifluoromethyl)phenyl]indenofluorenediylidene]bis(aminonitrile); [[bis(trifluoromethyl)phenyl]indenofluorenediylidene]bis(malononitrile); [[bis(trifluoromethyl)phenyl]indenofluorenediylidene]bis(aminonitrile); [biphenyl(trifluoromethyl)indenofluorenediylidene]bis(malononitrile); [biphenyl(trifluoromethyl)indenofluorenediylidene]bis(aminonitrile); [naphthyl(trifluoromethyl)indenofluorenediylidene]bis(malononitrile); [naphthyl(trifluoromethyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis(difluorophenyl)indenofluorenediylidene]bis(malononitrile); [bis(difluorophenyl)indenofluorenediylidene]bis(aminonitrile); [bis(difluorophenyl)indenofluorenediylidene]bis(malononitrile); [bis(difluorophenyl)indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[(trifluoromethyl)phenyl]indenofluorenediylidene]bis(malononitrile); [bis[(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[bis(trifluoromethyl)phenyl]indenofluorenediylidene]bis(malononitrile); [bis[bis(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis(trifluorophenyl)indenofluorenediylidene]bis(malononitrile); [bis(trifluorophenyl)indenofluorenediylidene]bis(aminonitrile); [bis(fluorophenyl)indenofluorenediylidene]bis(malononitrile); [bis(fluorophenyl)indenofluorenediylidene]bis(aminonitrile); [bis[(trifluoromethyl)phenyl]indenofluorenediylidene]bis(malononitrile); [bis[(trifluoromethyl)phenyl]indenofluorenediylidene]bis(aminonitrile); [bis[fluoro(trifluoromethyl)phenyl]indenofluorenediylidene]bis(malononitrile); [bis[fluoro(trifluoromethyl)phenyl]indenofluorenediylidene]bis(aminonitrile); [bis[difluoro(trifluoromethyl)phenyl]indenofluorenediylidene]bis(malononitrile); [bis[difluoro(trifluoromethyl)phenyl]indenofluorenediylidene]bis(aminonitrile); [bis[difluoro(trifluoromethyl)phenyl]indenofluorenediylidene]bis(malononitrile); [bis[difluoro(trifluoromethyl)phenyl]indenofluorenediylidene]bis(aminonitrile); (dinaphthylindenofluorenediylidene)bis(malononitrile); (dinaphthylindenofluorenediylidene)bis(aminonitrile); (difluoroindenofluorenediylidene)bis(malononitrile); (difluoroindenofluorenediylidene)bis(aminonitrile); [bis(trifluoromethyl)indenofluorenediylidene]bis(malononitrile); [bis(trifluoromethyl)indenofluorenediylidene]bis(aminonitrile); (dicyanoindenofluorenediylidene)bis(malononitrile); (dicyanoindenofluorenediylidene)bis(aminonitrile); (hexafluoroindenofluorenediylidene)bis(malononitrile); (hexafluoroindenofluorenediylidene)bis(aminonitrile); [dicyanobis(trifluoromethyl)indenofluorenediylidene]bis(malononitrile); [dicyanobis(trifluoromethyl)indenofluorenediylidene]bis(aminonitrile); [tetrakis[(trifluoromethyl)phenyl]indenofluorenediylidene]bis(malononitrile); [tetrakis[(trifluoromethyl)phenyl]indenofluorenediylidene]bis(malononitrile); [tetrakis[(trifluoromethyl)phenyl]indenofluorenediylidene]bis(malononitrile); [bis[bis(trifluoromethyl)phenyl]azaindenofluorenediylidene]bis(malononitrile); [bis[bis(trifluoromethyl)phenyl]diazaindenofluorenediylidene]bis(malononitrile); [bis[fluoro(trifluoromethyl)phenyl]diazaindenofluorenediylidene]bis(malononitrile); [bis[fluoro(trifluoromethyl)phenyl]diazaindenofluorenediylidene]bis(malononitrile); [bis[(trifluoromethyl)phenyl]indenofluorenediylidene]bis(trifluoromethylacrylonitrile); [bis(trifluoromethoxy)indenofluorenediylidene]bis(malononitrile); [fluorobis(trifluoromethoxy)indenofluorenediylidene]bis(malononitrile); [bis[(trifluoromethoxy)phenyl]indenofluorenediylidene]bis(malononitrile); [bis[fluoro(trifluoromethoxy)phenyl]indenofluorenediylidene]bis(malononitrile); [(trifluoroethoxy)bis[(trifluoromethoxy)phenyl]indenofluorenediylidene]bis(malononitrile); [bis[(pentafluoroethoxy)phenyl]indenofluorenediylidene]bis(malononitrile); [bis[(pentafluoropropoxy)phenyl]indenofluorenediylidene]bis(malononitrile); [bis[(hexafluoroisopropoxy)phenyl]indenofluorenediylidene]bis(malononitrile); [(pentafluoropropoxy)bis(trifluoromethoxy)indenofluorenediylidene]bis(malononitrile); [(trifluoromethoxy)[fluoro(trifluoromethyl)phenyl]indenofluorenediylidene]bis(malononitrile); [(trifluoromethoxy)[(trifluoromethoxy)phenyl]indenofluorenediylidene]bis(malononitrile); [fluoro[(trifluoromethoxy)phenyl]indenofluorenediylidene]bis(malononitrile); (dibenzindenofluorenediylidene)bis(malononitrile); (azadibenzindenofluorenediylidene)bis(malononitrile); (diazadibenzindenofluorenediylidene)bis(malononitrile); [(trifluoromethoxy)benzindenofluorenediylidene]bis(malononitrile); [[(trifluoromethoxy)phenyl]bis(trifluoromethoxy)indenofluorenediylidene]bis(malononitrile); [dithiophenylindenofluorenediylidene]bis(malononitrile); [bis(trifluoromethoxy)diazaindenofluorenediylidene]bis(malononitrile); [bis(trifluoromethoxy)hexaazaindenofluorenediylidene]bis(malononitrile); [tetrakis(trifluoromethoxy)indenofluorenediylidene]bis(malononitrile); [tetrakis(trifluoromethoxy)indenofluorenediylidene]bis(malononitrile); hexacyanohexaazatriphenylene; tris[cyano(cyanotetrafluorophenyl)methylene]cyclopropane; di(biphenyl)(phenylspiroacridinefluorenyl)amine; (biphenyl)(dimethylfluorenyl)(spiroindoloacridinefluorenyl)amine; (biphenyl)(dibenzofuranyl)(phenylspiroacridinefluorenyl)amine; di(biphenyl)(spirobenzanthracenefluorenyl)amine; (biphenyl)[(dibenzothiophenyl)phenyl](spirobenzanthracenefluorenyl)amine; di(biphenyl)(dibenzofuranyl)amine; (biphenyl)(terphenyl)(dibenzofuranyl)amine; (phenyl)(terphenyl)(dibenzofuranyl)amine; (biphenyl)(dibenzofuranyl)[(carbazolyl)phenyl]amine; (terphenyl)(naphthyl)(dibenzofuranyl)amine; (phenyl)(dibenzofuranyl)[(dibenzofuranyl)phenyl]amine; (terphenyl)(biphenyl)(dibenzofuranyl)amine; (biphenyl)(dibenzofuranyl)(dimethylfluorenyl)amine; (naphthyl)(biphenyl)(dibenzofuranyl)amine; di(biphenyl)[(phenyldibenzofuranyl)phenyl]amine; (naphthyl)(naphthylphenyl)[(phenyldibenzofuranyl)phenyl]amine; (naphthyl)(naphthylphenyl)[(phenyldibenzofuranyl)phenyl]amine; (biphenyl)[(dimethylfluorenyl)phenyl][(dibenzofuranyl)phenyl]amine; (naphthyl)(biphenyl)[(phenyldibenzofuranyl)biphenyl]amine; (naphthyl)(biphenyl)[(dibenzofuranyl)phenyl]amine; (phenyl)(naphthylphenyl)[(phenyldibenzofuranyl)phenyl]amine; (naphthylphenyl)bis[(dibenzofuranyl)phenyl]amine; di(terphenyl)[(dibenzofuranyl)phenyl]amine; (phenyl)(biphenyl)[(dibenzofuranyl)dimethylfluorenyl]amine; (phenyl)[(triphenylsilyl)phenyl](diphenylfluorenyl)amine; (phenyl)[(triphenylsilyl)phenyl](triphenylfluorenyl)amine; (diphenylfluorenyl)di(biphenyl)amine; (diphenylfluorenyl)(biphenyl)(naphthylphenyl)amine; (diphenylfluorenyl)(biphenyl)(terphenyl)amine; (diphenylfluorenyl)(biphenyl)(phenyldibenzofuranyl)amine; (phenyl)[(triphenylsilyl)phenyl](naphthylphenylfluorenyl)amine; (diphenylfluorenyl)(biphenyl)(dibenzofuranyl)amine; (triphenylsilyldibenzothiophenyl)(phenyl)(diphenylfluorenyl)amine; (diphenylnaphthylsilylbiphenyl)(phenyl)(diphenyl)amine; (triphenylsilylphenyl)(phenyl)(naphthylphenylfluorenyl)amine; (diphenylfluorenyl)(biphenyl)(phenyldibenzothiophenyl)amine; (diphenylfluorenyl)(biphenyl)(dibenzothiophenyl)amine; (diphenylfluorenyl)(biphenyl)(dibenzofuranylphenyl)amine; (diphenylfluorenyl)(biphenyl)(phenyldibenzofuranylphenyl)amine; (diphenylfluorenyl)(biphenyl)(phenyldibenzothiophenyl)amine; (dimethylfluorenyl)di(biphenyl)amine; (dimethylfluorenyl)(terphenyl)(biphenyl)amine; (dimethylfluorenyl)(biphenyl)(dibenzofuranylphenyl)amine; (dimethylfluorenyl)(biphenyl)(dibenzothiophenylphenyl)amine; (dimethylfluorenyl)(biphenyl)(phenyldibenzofuranyl)amine; (diphenylfluorenyl)bis(methylbiphenyl)amine; (dimethylfluorenyl)di(biphenyl)amine; (dimethylfluorenyl)di(biphenyl)amine; (dibenzofuranylphenyl)(biphenyl)(dimethylfluorenyl)amine; (quarterphenyl)(dibenzofuranylphenyl)(phenylcarbazolylphenyl)amine; (quarterphenyl)(dibenzofuranylphenyl)(phenylcarbazolylphenyl)amine; (quarterphenyl)(dibenzofuranylphenyl)(phenylcarbazolylphenyl)amine; (quarterphenyl)(dibenzofuranylphenyl)(phenylcarbazolylphenyl)amine; (quarterphenyl)bis(dibenzofuranylphenyl)amine; (quarterphenyl)bis(dibenzofuranylphenyl)amine; (quarterphenyl)(dibenzofuranylphenyl)(phenylcarbazolylphenyl)amine; (quarterphenyl)(dibenzofuranylphenyl)(phenylcarbazolylphenyl)amine; (quarterphenyl)(biphenyl)(dibenzofuranylphenyl)amine; (quarterphenyl)(biphenyl)(dibenzofuranylphenyl)amine; (terphenyl)(naphthylphenyl)(dibenzofuranylbiphenyl)amine; (terphenyl)(phenylnaphthyl)(dibenzofuranylbiphenyl)amine; (terphenyl)(naphthyl)(dibenzofuranylbiphenyl)amine; (dimethylfluorenyl)bis(spirobifluorenyl)amine; (biphenyl)bis(spirobifluorenyl)amine; (dimethylfluorenyl)bis(spirobifluorenyl)amine; (spirobifluorenyl)(biphenyl)(dimethylfluorenyl)amine; (spirobifluorenyl)di(biphenyl)amine; (spirobifluorenyl)bis(dimethylfluorenyl)amine; (spirobifluorenyl)(biphenyl)(dimethylfluorenyl)amine; (spirobifluorenyl)(terphenyl)(dimethylfluorenyl)amine; (spirobifluorenyl)(biphenyl)(dimethylfluorenyl)amine; (spirobifluorenyl)bis(dimethylfluorenyl)amine; (spirobifluorenyl)(biphenyl)(dimethylfluorenyl)amine; (spirobifluorenyl)di(biphenyl)amine; (spirobifluorenylphenyl)di(biphenyl)amine; (spirobifluorenyl)di(biphenyl)amine; (spirobifluorenyl)(biphenyl)(dibenzofuranyl)amine; (spirobifluorenyl)(biphenyl)(dibenzofuranyl)amine; (spirobifluorenyl)(dibenzofuranyl)(dimethylfluorenyl)amine; (spirobifluorenyl)(biphenyl)(phenylcarbazolyl)amine; (spirobifluorenyl)(diphenylfluorenyl)(dibenzothiophenylphenyl)amine; (spirobifluorenyl)(dimethylfluorenyl)(dibenzothiophenyl)amine; (spirobifluorenyl)(biphenyl)(phenylcarbazolyl)amine; (spirobifluorenyl)(biphenyl)(diphenylfluorenyl)amine; (spirobifluorenyl)(biphenyl)(dibenzofuranylphenyl)amine; (spirobifluorenyl)(biphenyl)(dibenzothiophenylphenyl)amine; (spirobifluorenyl)(biphenyl)(diphenylfluorenyl)amine; (biphenyl)bis(dibenzofuranylphenyl)amine; (terphenyl)bis(dibenzofuranylphenyl)amine; (dimethylfluorenyl)bis(dibenzofuranylphenyl)amine; (terphenyl)bis(dibenzofuranylphenyl)amine; (quarterphenyl)bis(dibenzofuranylphenyl)amine; (diphenylfluorenyl)(dibenzofuranylphenyl)(phenyl)amine; (diphenylfluorenyl)(dibenzofuranylphenyl)(biphenyl)amine; (diphenylfluorenyl)(dibenzofuranylphenyl)(biphenyl)amine; (diphenylfluorenyl)(dibenzofuranylphenyl)(biphenyl)amine; (diphenylfluorenyl)(dibenzofuranylphenyl)(terphenyl)amine; (diphenylfluorenyl)(dibenzofuranylphenyl)(terphenyl)amine; (diphenylfluorenyl)(dibenzofuranylphenyl)(terphenyl)amine; (diphenylfluorenyl)(dibenzofuranylphenyl)(terphenyl)amine; (diphenylfluorenyl)(dibenzofuranylphenyl)(naphthyl)amine; (diphenylfluorenyl)(dibenzofuranylphenyl)(naphthyl)amine; (diphenylfluorenyl)(dibenzofuranylphenyl)(naphthylphenyl)amine; (diphenylfluorenyl)(dibenzofuranylphenyl)(naphthylphenyl)amine; (diphenylfluorenyl)(dibenzofuranylphenyl)(dimethylfluorenyl)amine; (diphenylfluorenyl)(dibenzofuranylphenyl)(phenylmethylfluorenyl)amine; bis(diphenylfluorenyl)(dibenzofuranylphenyl)amine; (diphenylfluorenyl)(dibenzothiophenylphenyl)(phenyl)amine; (diphenylfluorenyl)(dibenzothiophenylphenyl)(biphenyl)amine; (diphenylfluorenyl)(dibenzothiophenylphenyl)(biphenyl)amine; (diphenylfluorenyl)(dibenzothiophenylphenyl)(terphenyl)amine; (diphenylfluorenyl)(dibenzothiophenylphenyl)(naphthyl)amine; (diphenylfluorenyl)(dibenzothiophenylphenyl)(naphthyl)amine; (diphenylfluorenyl)(dibenzothiophenylphenyl)(naphthylphenyl)amine; (diphenylfluorenyl)(dibenzothiophenylphenyl)(naphthylphenyl)amine; (phenyl)(diphenylfluorenyl)(dibenzofuranylphenyl)amine; (biphenyl)(diphenylfluorenyl)(dibenzofuranylphenyl)amine; (biphenyl)(diphenylfluorenyl)(dibenzofuranylphenyl)amine; (naphthylphenyl)(diphenylfluorenyl)(dibenzofuranylphenyl)amine; (naphthylphenyl)(diphenylfluorenyl)(dibenzofuranylphenyl)amine; (dimethylfluorenyl)(diphenylfluorenyl)(dibenzofuranylphenyl)amine; bis(diphenylfluorenyl)(dibenzofuranylphenyl)amine; (phenyl)(diphenylfluorenyl)(dibenzothiophenylphenyl)amine; (biphenyl)(diphenylfluorenyl)(dibenzothiophenylphenyl)amine; (biphenyl)(diphenylfluorenyl)(dibenzothiophenylphenyl)amine; (terphenyl)(diphenylfluorenyl)(dibenzothiophenylphenyl)amine; (naphthylphenyl)(diphenylfluorenyl)(dibenzothiophenylphenyl)amine; (naphthylphenyl)(diphenylfluorenyl)(dibenzothiophenylphenyl)amine; (dimethylfluorenyl)(diphenylfluorenyl)(dibenzothiophenylphenyl)amine; (biphenyl)(diphenylfluorenyl)(carbazolylphenyl)amine; (biphenyl)(diphenylfluorenyl)(carbazolylphenyl)amine; (terphenyl)(diphenylfluorenyl)(carbazolylphenyl)amine; (naphthylphenyl)(diphenylfluorenyl)(carbazolylphenyl)amine; (naphthylphenyl)(diphenylfluorenyl)(carbazolylphenyl)amine; (dimethylfluorenyl)(diphenylfluorenyl)(carbazolylphenyl)amine; (biphenyl)(dibenzofuranyl)(diphenylfluorenyl)amine; (dibenzofuranyl)(dimethylfluorenyl)(diphenylfluorenyl)amine; (biphenyl)(dibenzothiophenyl)(diphenylfluorenyl)amine; (dimethylfluorenyl)(dibenzothiophenyl)(diphenylfluorenyl)amine; (biphenyl)(dibenzofuranyl)(diphenylfluorenyl)amine; (biphenyl)(dibenzofuranyl)(diphenylfluorenyl)amine; (dimethylfluorenyl)(dibenzofuranyl)(diphenylfluorenyl)amine; (biphenyl)(dibenzothiophenyl)(diphenylfluorenyl)amine; (biphenyl)(dibenzothiophenyl)(diphenylfluorenyl)amine; (dimethylfluorenyl)(dibenzothiophenyl)(diphenylfluorenyl)amine; bis(dibenzofuranylphenyl)(diphenylfluorenyl)amine; bis(dibenzofuranylphenyl)(diphenylfluorenyl)amine; (dibenzofuranylphenyl)(dibenzothiophenylphenyl)(diphenylfluorenyl)amine; (dibenzofuranylphenyl)(carbazolylphenyl)(diphenylfluorenyl)amine; bis(dibenzofuranylphenyl)(diphenylfluorenyl)amine; (dibenzofuranylphenyl)(dibenzothiophenylphenyl)(diphenylfluorenyl)amine; (dibenzofuranylphenyl)(carbazolylphenyl)(diphenylfluorenyl)amine; (dibenzothiophenylphenyl)(carbazolylphenyl)(diphenylfluorenyl)amine; (methylbiphenyl)(dibenzofuranylphenyl)(diphenylfluorenyl)amine; (tert-butylbiphenyl)(dibenzofuranylphenyl)(diphenylfluorenyl)amine; (dimethylbiphenyl)(dibenzofuranylphenyl)(diphenylfluorenyl)amine; (dimethylbiphenyl)(dibenzofuranylphenyl)(diphenylfluorenyl)amine; (methylbiphenyl)(dibenzofuranylphenyl)(diphenylfluorenyl)amine; (tert-butylbiphenyl)(dibenzofuranylphenyl)(diphenylfluorenyl)amine; (methoxybiphenyl)(dibenzofuranylphenyl)(diphenylfluorenyl)amine; (phenyl)(dimethylfluorenyl)(diphenylfluorenyl)amine; (biphenyl)(dimethylfluorenyl)(diphenylfluorenyl)amine; (biphenyl)(dimethylfluorenyl)(diphenylfluorenyl)amine; (biphenyl)(dimethylfluorenyl)(diphenylfluorenyl)amine; (terphenyl)(dimethylfluorenyl)(diphenylfluorenyl)amine; (terphenyl)(dimethylfluorenyl)(diphenylfluorenyl)amine; (terphenyl)(dimethylfluorenyl)(diphenylfluorenyl)amine; (terphenyl)(dimethylfluorenyl)(diphenylfluorenyl)amine; (terphenyl)(dimethylfluorenyl)(diphenylfluorenyl)amine; (naphthyl)(dimethylfluorenyl)(diphenylfluorenyl)amine; (naphthyl)(dimethylfluorenyl)(diphenylfluorenyl)amine; (naphthylphenyl)(dimethylfluorenyl)(diphenylfluorenyl)amine; (naphthylphenyl)(dimethylfluorenyl)(diphenylfluorenyl)amine; bis(dimethylfluorenyl)(diphenylfluorenyl)amine; (phenylmethylfluorenyl)(dimethylfluorenyl)(diphenylfluorenyl)amine; (dimethylfluorenyl)bis(diphenylfluorenyl)amine; (terphenyl)(dimethylfluorenyl)(diphenylfluorenyl)amine; (terphenyl)(dimethylfluorenyl)(diphenylfluorenyl)amine; (fluorophenyl)(dimethylfluorenyl)(diphenylfluorenyl)amine; (methylphenyl)(dimethylfluorenyl)(diphenylfluorenyl)amine; (tert-butylphenyl)(dimethylfluorenyl)(diphenylfluorenyl)amine; (methylbiphenyl)(dimethylfluorenyl)(diphenylfluorenyl)amine; (tert-butylbiphenyl)(dimethylfluorenyl)(diphenylfluorenyl)amine; (dimethylbiphenyl)(dimethylfluorenyl)(diphenylfluorenyl)amine; (dimethylbiphenyl)(dimethylfluorenyl)(diphenylfluorenyl)amine; (methylbiphenyl)(dimethylfluorenyl)(diphenylfluorenyl)amine; (tert-butylbiphenyl)(dimethylfluorenyl)(diphenylfluorenyl)amine; (methoxybiphenyl)(dimethylfluorenyl)(diphenylfluorenyl)amine; (phenyl)bis(diphenylfluorenyl)amine; (biphenyl)bis(diphenylfluorenyl)amine; (biphenyl)bis(diphenylfluorenyl)amine; (biphenyl)bis(diphenylfluorenyl)amine; (terphenyl)bis(diphenylfluorenyl)amine; (terphenyl)bis(diphenylfluorenyl)amine; (terphenyl)bis(diphenylfluorenyl)amine; (terphenyl)bis(diphenylfluorenyl)amine; (terphenyl)bis(diphenylfluorenyl)amine; (terphenyl)bis(diphenylfluorenyl)amine; (naphthyl)bis(diphenylfluorenyl)amine; (naphthyl)bis(diphenylfluorenyl)amine; (naphthylphenyl)bis(diphenylfluorenyl)amine; (naphthylphenyl)bis(diphenylfluorenyl)amine; (dimethylfluorenyl)bis(diphenylfluorenyl)amine; (phenylmethylfluorenyl)bis(diphenylfluorenyl)amine; tris(diphenylfluorenyl)amine; (terphenyl)bis(diphenylfluorenyl)amine; (terphenyl)bis(diphenylfluorenyl)amine; (methylbiphenyl)bis(diphenylfluorenyl)amine; (tert-butylbiphenyl)bis(diphenylfluorenyl)amine; (dimethylbiphenyl)bis(diphenylfluorenyl)amine; (dimethylbiphenyl)bis(diphenylfluorenyl)amine; (methylbiphenyl)bis(diphenylfluorenyl)amine; (tert-butylbiphenyl)bis(diphenylfluorenyl)amine; (methoxybiphenyl)bis(diphenylfluorenyl)amine; (phenyl)(dimethylfluorenyl)(diphenylfluorenyl)amine; (biphenyl)(dimethylfluorenyl)(diphenylfluorenyl)amine; (biphenyl)(dimethylfluorenyl)(diphenylfluorenyl)amine; (phenyl)(dibenzofuranylphenyl)(diphenylfluorenyl)amine; (biphenyl)(dibenzofuranylphenyl)(diphenylfluorenyl)amine; (biphenyl)(dibenzofuranylphenyl)(diphenylfluorenyl)amine; (biphenyl)(dibenzofuranylphenyl)[di(biphenyl)fluorenyl]amine; (biphenyl)(dimethylfluorenyl)[di(methylphenyl)fluorenyl]amine; (biphenyl)(dimethylfluorenyl)[di(methylphenyl)fluorenyl]amine; (biphenyl)(dimethylfluorenyl)[di(tert-butylphenyl)fluorenyl]amine; (biphenyl)(dibenzofuranylphenyl)[di(methylphenyl)fluorenyl]amine; (biphenyl)(dibenzofuranylphenyl)[di(methylphenyl)fluorenyl]amine; (biphenyl)(dibenzofuranylphenyl)[di(tert-butylphenyl)fluorenyl]amine; (biphenyl)(dimethylfluorenyl)(methyldiphenylfluorenyl)amine; (biphenyl)(dimethylfluorenyl)(methyldiphenylfluorenyl)amine; (biphenyl)(dimethylfluorenyl)(tert-butyldiphenylfluorenyl)amine; (biphenyl)(dimethylfluorenyl)(tert-butyldiphenylfluorenyl)amine; (biphenyl)(dibenzofuranylphenyl)(methyldiphenylfluorenyl)amine; (biphenyl)(dibenzofuranylphenyl)(methyldiphenylfluorenyl)amine; (biphenyl)(dibenzofuranylphenyl)(tert-butyldiphenylfluorenyl)amine; (biphenyl)(dibenzofuranylphenyl)(tert-butyldiphenylfluorenyl)amine; (biphenyl)(dimethylfluorenyl)(triphenylfluorenyl)amine; (biphenyl)(dimethylfluorenyl)(triphenylfluorenyl)amine; (biphenyl)(dibenzofuranylphenyl)(triphenylfluorenyl)amine; (biphenyl)(dibenzofuranylphenyl)(triphenylfluorenyl)amine; (biphenyl)(methyldibenzofuranylphenyl)(diphenylfluorenyl)amine; (biphenyl)(methyldibenzofuranylphenyl)(diphenylfluorenyl)amine; (biphenyl)(phenyldibenzofuranylphenyl)(diphenylfluorenyl)amine; (biphenyl)(phenyldibenzofuranylphenyl)(diphenylfluorenyl)amine; (biphenyl)(methyldibenzofuranyl)(diphenylfluorenyl)amine; (biphenyl)(methyldibenzofuranyl)(diphenylfluorenyl)amine; (biphenyl)(phenyldibenzofuranyl)(diphenylfluorenyl)amine; (biphenyl)(phenyldibenzofuranyl)(diphenylfluorenyl)amine; (dibenzofuranyl)bis(diphenylfluorenyl)amine; (dibenzothiophenyl)bis(diphenylfluorenyl)amine; (dibenzofuranylphenyl)bis(diphenylfluorenyl)amine; (dibenzothiophenylphenyl)bis(diphenylfluorenyl)amine; (dibenzofuranyl)bis(diphenylfluorenyl)amine; (dibenzothiophenyl)bis(diphenylfluorenyl)amine; (dibenzofuranylphenyl)bis(diphenylfluorenyl)amine; (dibenzothiophenylphenyl)bis(diphenylfluorenyl)amine; (dibenzothiophenyl)bis(diphenylfluorenyl)amine; (quarterphenyl)bis(diphenylfluorenyl)amine; (dibenzothiophenylphenyl)(dimethylfluorenyl)(diphenylfluorenyl)amine; (quarterphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(dimethylfluorenyl)(diphenylfluorenyl)amine; (dibenzothiophenylphenyl)(dimethylfluorenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(biphenyl)(diphenylfluorenyl)amine; (dibenzothiophenylphenyl)(biphenyl)(diphenylfluorenyl)amine; (dibenzofuranylphenyl)(terphenyl)(diphenylfluorenyl)amine; (dibenzothiophenylphenyl)(terphenyl)(diphenylfluorenyl)amine; (dibenzothiophenylphenyl)(terphenyl)(diphenylfluorenyl)amine; (dibenzofuranylphenyl)(terphenyl)(diphenylfluorenyl)amine; (dibenzothiophenylphenyl)(terphenyl)(diphenylfluorenyl)amine; (dibenzofuranylphenyl)(terphenyl)(diphenylfluorenyl)amine; (dibenzothiophenylphenyl)(terphenyl)(diphenylfluorenyl)amine; (phenyl)(dibenzofuranyl)(diphenylfluorenyl)amine; (phenyl)(dibenzothiophenyl)(diphenylfluorenyl)amine; (phenyl)(dibenzofuranyl)(diphenylfluorenyl)amine; (phenyl)(dibenzothiophenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; (phenyl)(dibenzofuranylphenyl)(diphenylfluorenyl)amine; (phenyl)(dibenzothiophenylphenyl)(diphenylfluorenyl)amine; bis(dibenzofuranyl)(diphenylfluorenyl)amine; bis(dibenzothiophenyl)(diphenylfluorenyl)amine; (biphenyldimethylfluorenyl)(phenyl)(diphenylfluorenyl)amine; (naphthyldimethylfluorenyl)(phenyl)(diphenylfluorenyl)amine; (naphthyldimethylfluorenyl)(phenyl)(diphenylfluorenyl)amine; (biphenyldimethylfluorenyl)(biphenyl)(diphenylfluorenyl)amine; (naphthyldimethylfluorenyl)(biphenyl)(diphenylfluorenyl)amine; (naphthyldimethylfluorenyl)(biphenyl)(diphenylfluorenyl)amine; (naphthyldimethylfluorenyl)(biphenyl)(diphenylfluorenyl)amine; (phenyl)(dimethylfluorenylphenyl)(diphenylfluorenyl)amine; (phenyl)(dimethylfluorenylphenyl)(diphenylfluorenyl)amine; (biphenyl)(dimethylfluorenylphenyl)(diphenylfluorenyl)amine; (biphenyl)(dimethylfluorenylphenyl)(diphenylfluorenyl)amine; (biphenyl)(dimethylfluorenylphenyl)(diphenylfluorenyl)amine; (biphenyl)(dimethylfluorenylphenyl)(diphenylfluorenyl)amine; (biphenyl)(dimethylfluorenylphenyl)(diphenylfluorenyl)amine; (biphenyl)(dimethylfluorenylphenyl)(diphenylfluorenyl)amine; (dimethylfluorenylphenyl)bis(diphenylfluorenyl)amine; (dimethylfluorenylphenyl)bis(diphenylfluorenyl)amine; di(biphenyl)(diphenylfluorenyl)amine; (biphenyl)(methylbiphenyl)(diphenylfluorenyl)amine; (methylphenyl)(biphenyl)(diphenylfluorenyl)amine; di(biphenyl)(diphenylfluorenyl)amine; bis(dimethylphenyl)(diphenylfluorenyl)amine; (biphenyl)(terphenyl)(diphenylfluorenyl)amine; bis(methylbiphenyl)(diphenylfluorenyl)amine; (biphenyl)(dimethylbiphenyl)(diphenylfluorenyl)amine; (phenyl)(dibenzofuranylphenyl)(spirobifluorenyl)amine; (biphenyl)(dibenzofuranylphenyl)(spirobifluorenyl)amine; (biphenyl)(dibenzofuranylphenyl)(spirobifluorenyl)amine; (biphenyl)(dibenzofuranylphenyl)(spirobifluorenyl)amine; (terphenyl)(dibenzofuranylphenyl)(spirobifluorenyl)amine; (terphenyl)(dibenzofuranylphenyl)(spirobifluorenyl)amine; (terphenyl)(dibenzofuranylphenyl)(spirobifluorenyl)amine; (terphenyl)(dibenzofuranylphenyl)(spirobifluorenyl)amine; (terphenyl)(dibenzofuranylphenyl)(spirobifluorenyl)amine; (naphthyl)(dibenzofuranylphenyl)(spirobifluorenyl)amine; (naphthyl)(dibenzofuranylphenyl)(spirobifluorenyl)amine; (naphthylphenyl)(dibenzofuranylphenyl)(spirobifluorenyl)amine; (naphthylphenyl)(dibenzofuranylphenyl)(spirobifluorenyl)amine; (dimethylfluorenyl)(dibenzofuranylphenyl)(spirobifluorenyl)amine; (phenylmethylfluorenyl)(dibenzofuranylphenyl)(spirobifluorenyl)amine; (dibenzofuranylphenyl)(diphenylfluorenyl)(spirobifluorenyl)amine; (phenyl)(dibenzothiophenylphenyl)(spirobifluorenyl)amine; (biphenyl)(dibenzothiophenylphenyl)(spirobifluorenyl)amine; (biphenyl)(dibenzothiophenylphenyl)(spirobifluorenyl)amine; (terphenyl)(dibenzothiophenylphenyl)(spirobifluorenyl)amine; (naphthyl)(dibenzothiophenylphenyl)(spirobifluorenyl)amine; (naphthyl)(dibenzothiophenylphenyl)(spirobifluorenyl)amine; (naphthylphenyl)(dibenzothiophenylphenyl)(spirobifluorenyl)amine; (naphthylphenyl)(dibenzothiophenylphenyl)(spirobifluorenyl)amine; (phenyl)(dibenzofuranylphenyl)(spirobifluorenyl)amine; (biphenyl)(dibenzofuranylphenyl)(spirobifluorenyl)amine; (biphenyl)(dibenzofuranylphenyl)(spirobifluorenyl)amine; (dibenzofuranylphenyl)(diphenylfluorenyl)(spirobifluorenyl)amine; (biphenyl)(dibenzothiophenylphenyl)(spirobifluorenyl)amine; (biphenyl)(dibenzothiophenylphenyl)(spirobifluorenyl)amine; (biphenyl)(carbazolylphenyl)(spirobifluorenyl)amine; (biphenyl)(carbazolylphenyl)(spirobifluorenyl)amine; (biphenyl)(dibenzofuranyl)(spirobifluorenyl)amine; (biphenyl)(dibenzofuranyl)(spirobifluorenyl)amine; (biphenyl)(dibenzofuranyl)(spirobifluorenyl)amine; (dimethylfluorenyl)(dibenzofuranyl)(spirobifluorenyl)amine; (biphenyl)(dibenzothiophenyl)(spirobifluorenyl)amine; (biphenyl)(dibenzothiophenyl)(spirobifluorenyl)amine; (biphenyl)(dibenzothiophenyl)(spirobifluorenyl)amine; (dimethylfluorenyl)(dibenzothiophenyl)(spirobifluorenyl)amine; (biphenyl)(dibenzofuranyl)(spirobifluorenyl)amine; (biphenyl)(dibenzofuranyl)(spirobifluorenyl)amine; (biphenyl)(dibenzofuranyl)(spirobifluorenyl)amine; (dimethylfluorenyl)(dibenzofuranyl)(spirobifluorenyl)amine; (biphenyl)(dibenzothiophenyl)(spirobifluorenyl)amine; (biphenyl)(dibenzothiophenyl)(spirobifluorenyl)amine; (biphenyl)(dibenzothiophenyl)(spirobifluorenyl)amine; (dimethylfluorenyl)(dibenzothiophenyl)(spirobifluorenyl)amine; bis(dibenzofuranylphenyl)(spirobifluorenyl)amine; (dibenzofuranylphenyl)(carbazolylphenyl)(spirobifluorenyl)amine; bis(dibenzofuranylphenyl)(spirobifluorenyl)amine; (dibenzofuranylphenyl)(carbazolylphenyl)(spirobifluorenyl)amine; (methylphenyl)(dibenzofuranylphenyl)(spirobifluorenyl)amine; (tert-butylphenyl)(dibenzofuranylphenyl)(spirobifluorenyl)amine; (methylbiphenyl)(dibenzofuranylphenyl)(spirobifluorenyl)amine; (tert-butylbiphenyl)(dibenzofuranylphenyl)(spirobifluorenyl)amine; (dimethylbiphenyl)(dibenzofuranylphenyl)(spirobifluorenyl)amine; (dimethylbiphenyl)(dibenzofuranylphenyl)(spirobifluorenyl)amine; (methylbiphenyl)(dibenzofuranylphenyl)(spirobifluorenyl)amine; (tert-butylbiphenyl)(dibenzofuranylphenyl)(spirobifluorenyl)amine; (phenyl)(dimethylfluorenyl)(spirobifluorenyl)amine; (biphenyl)(dimethylfluorenyl)(spirobifluorenyl)amine; (biphenyl)(dimethylfluorenyl)(spirobifluorenyl)amine; (biphenyl)(dimethylfluorenyl)(spirobifluorenyl)amine; (terphenyl)(dimethylfluorenyl)(spirobifluorenyl)amine; (terphenyl)(dimethylfluorenyl)(spirobifluorenyl)amine; (terphenyl)(dimethylfluorenyl)(spirobifluorenyl)amine; (terphenyl)(dimethylfluorenyl)(spirobifluorenyl)amine; (terphenyl)(dimethylfluorenyl)(spirobifluorenyl)amine; (naphthyl)(dimethylfluorenyl)(spirobifluorenyl)amine; (naphthyl)(dimethylfluorenyl)(spirobifluorenyl)amine; (naphthylphenyl)(dimethylfluorenyl)(spirobifluorenyl)amine; (naphthylphenyl)(dimethylfluorenyl)(spirobifluorenyl)amine; bis(dimethylfluorenyl)(spirobifluorenyl)amine; (phenylmethylfluorenyl)(dimethylfluorenyl)(spirobifluorenyl)amine; (diphenylfluorenyl)(dimethylfluorenyl)(spirobifluorenyl)amine; (terphenyl)(dimethylfluorenyl)(spirobifluorenyl)amine; (terphenyl)(dimethylfluorenyl)(spirobifluorenyl)amine; (methylphenyl)(dimethylfluorenyl)(spirobifluorenyl)amine; (tert-butylphenyl)(dimethylfluorenyl)(spirobifluorenyl)amine; (methylbiphenyl)(dimethylfluorenyl)(spirobifluorenyl)amine; (tert-butylbiphenyl)(dimethylfluorenyl)(spirobifluorenyl)amine; (dimethylbiphenyl)(dimethylfluorenyl)(spirobifluorenyl)amine; (dimethylbiphenyl)(dimethylfluorenyl)(spirobifluorenyl)amine; (methylbiphenyl)(dimethylfluorenyl)(spirobifluorenyl)amine; (tert-butylbiphenyl)(dimethylfluorenyl)(spirobifluorenyl)amine; (phenyl)(diphenylfluorenyl)(spirobifluorenyl)amine; (biphenyl)(diphenylfluorenyl)(spirobifluorenyl)amine; (biphenyl)(diphenylfluorenyl)(spirobifluorenyl)amine; (biphenyl)(diphenylfluorenyl)(spirobifluorenyl)amine; (terphenyl)(diphenylfluorenyl)(spirobifluorenyl)amine; (terphenyl)(diphenylfluorenyl)(spirobifluorenyl)amine; (terphenyl)(diphenylfluorenyl)(spirobifluorenyl)amine; (naphthyl)(diphenylfluorenyl)(spirobifluorenyl)amine; (naphthyl)(diphenylfluorenyl)(spirobifluorenyl)amine; (naphthylphenyl)(diphenylfluorenyl)(spirobifluorenyl)amine; (naphthylphenyl)(diphenylfluorenyl)(spirobifluorenyl)amine; (dimethylfluorenyl)(diphenylfluorenyl)(spirobifluorenyl)amine; (methylphenylfluorenyl)(diphenylfluorenyl)(spirobifluorenyl)amine; bis(diphenylfluorenyl)(spirobifluorenyl)amine; (terphenyl)(diphenylfluorenyl)(spirobifluorenyl)amine; (terphenyl)(diphenylfluorenyl)(spirobifluorenyl)amine; (methylphenyl)(diphenylfluorenyl)(spirobifluorenyl)amine; (tert-butylphenyl)(diphenylfluorenyl)(spirobifluorenyl)amine; (methylbiphenyl)(diphenylfluorenyl)(spirobifluorenyl)amine; (tert-butylbiphenyl)(diphenylfluorenyl)(spirobifluorenyl)amine; (dimethylbiphenyl)(diphenylfluorenyl)(spirobifluorenyl)amine; (dimethylbiphenyl)(diphenylfluorenyl)(spirobifluorenyl)amine; (methylbiphenyl)(diphenylfluorenyl)(spirobifluorenyl)amine; (tert-butylbiphenyl)(diphenylfluorenyl)(spirobifluorenyl)amine; (phenyl)(dimethylfluorenyl)(spirobifluorenyl)amine; (biphenyl)(dimethylfluorenyl)(spirobifluorenyl)amine; (biphenyl)(dimethylfluorenyl)(spirobifluorenyl)amine; (phenyl)(dibenzofuranylphenyl)(spirobifluorenyl)amine; (biphenyl)(dibenzofuranylphenyl)(spirobifluorenyl)amine; (biphenyl)(dibenzofuranylphenyl)(spirobifluorenyl)amine; (phenyl)(dimethylfluorenyl)(spirobifluorenyl)amine; (biphenyl)(dimethylfluorenyl)(spirobifluorenyl)amine; (biphenyl)(dimethylfluorenyl)(spirobifluorenyl)amine; (phenyl)(dimethylfluorenyl)(phenylspirobifluorenyl)amine; (biphenyl)(dimethylfluorenyl)(phenylspirobifluorenyl)amine; (biphenyl)(dimethylfluorenyl)(phenylspirobifluorenyl)amine; (biphenyl)(dimethylfluorenyl)(phenylspirobifluorenyl)amine; (biphenyl)(dimethylfluorenyl)(methylspirobifluorenyl)amine; (biphenyl)(dimethylfluorenyl)(methylspirobifluorenyl)amine; (biphenyl)(dimethylfluorenyl)(tert-butylspirobifluorenyl)amine; (biphenyl)(dimethylfluorenyl)(tert-butylspirobifluorenyl)amine; (biphenyl)(dimethylfluorenyl)(methylspirobifluorenyl)amine; (biphenyl)(dimethylfluorenyl)(tert-butylspirobifluorenyl)amine; (biphenyl)(dimethylfluorenyl)(methylspirobifluorenyl)amine; (biphenyl)(dimethylfluorenyl)(methylspirobifluorenyl)amine; (biphenyl)(dimethylfluorenyl)(tert-butylspirobifluorenyl)amine; (biphenyl)(dimethylfluorenyl)(tert-butylspirobifluorenyl)amine; (biphenyl)(dibenzofuranylphenyl)(methylspirobifluorenyl)amine; (biphenyl)(dibenzofuranylphenyl)(methylspirobifluorenyl)amine; (biphenyl)(dibenzofuranylphenyl)(tert-butylspirobifluorenyl)amine; (biphenyl)(dibenzofuranylphenyl)(tert-butylspirobifluorenyl)amine; (biphenyl)(dimethylfluorenyl)(phenylspirobifluorenyl)amine; (biphenyl)(dimethylfluorenyl)(phenylspirobifluorenyl)amine; (biphenyl)(dibenzofuranylphenyl)(phenylspirobifluorenyl)amine; (biphenyl)(dibenzofuranylphenyl)(phenylspirobifluorenyl)amine; (biphenyl)(methyldibenzofuranylphenyl)(spirobifluorenyl)amine; (biphenyl)(methyldibenzofuranylphenyl)(spirobifluorenyl)amine; (biphenyl)(phenyldibenzofuranylphenyl)(spirobifluorenyl)amine; (biphenyl)(phenyldibenzofuranylphenyl)(spirobifluorenyl)amine; (biphenyl)(methyldibenzofuranyl)(spirobifluorenyl)amine; (biphenyl)(methyldibenzofuranyl)(spirobifluorenyl)amine; (biphenyl)(phenyldibenzofuranyl)(spirobifluorenyl)amine; (biphenyl)(phenyldibenzofuranyl)(spirobifluorenyl)amine; (dibenzofuranylphenyl)bis(spirobifluorenyl)amine; (dibenzothiophenylphenyl)bis(spirobifluorenyl)amine; (dibenzofuranyl)bis(spirobifluorenyl)amine; (dibenzothiophenyl)bis(spirobifluorenyl)amine; (dibenzofuranylphenyl)bis(spirobifluorenyl)amine; (dibenzothiophenylphenyl)bis(spirobifluorenyl)amine; (dibenzofuranylphenyl)bis(spirobifluorenyl)amine; (dibenzothiophenylphenyl)bis(spirobifluorenyl)amine; (dibenzofuranylphenyl)bis(spirobifluorenyl)amine; (dibenzothiophenylphenyl)bis(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)ami; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(dimethylfluorenyl)(spirobifluorenyl)amine; (dibenzothiophenylphenyl)(dimethylfluorenyl)(spirobifluorenyl)amine; (dibenzofuranylphenyl)(biphenyl)(spirobifluorenyl)amine; (dibenzothiophenylphenyl)(biphenyl)(spirobifluorenyl)amine; (dibenzofuranylphenyl)(biphenyl)(spirobifluorenyl)amine; (dibenzothiophenylphenyl)(biphenyl)(spirobifluorenyl)amine; (dibenzofuranylphenyl)(biphenyl)(spirobifluorenyl)amine; (dibenzothiophenylphenyl)(biphenyl)(spirobifluorenyl)amine; (dibenzofuranylphenyl)(phenyl)(spirobifluorenyl)amine; (dibenzothiophenylphenyl)(phenyl)(spirobifluorenyl)amine; bis(dibenzofuranyl)(spirobifluorenyl)amine; bis(dibenzothiophenyl)(spirobifluorenyl)amine; (phenyl)(biphenyldimethylfluorenyl)(spirobifluorenyl)amine; (phenyl)(naphthyldimethylfluorenyl)(spirobifluorenyl)amine; (phenyl)(naphthyldimethylfluorenyl)(spirobifluorenyl)amine; (biphenyl)(biphenyldimethylfluorenyl)(spirobifluorenyl)amine; (biphenyl)(naphthyldimethylfluorenyl)(spirobifluorenyl)amine; (biphenyl)(biphenyldimethylfluorenyl)(spirobifluorenyl)amine; (biphenyl)(naphthyldimethylfluorenyl)(spirobifluorenyl)amine; (dimethylfluorenyl)(biphenyldimethylfluorenyl)(spirobifluorenyl)amine; (dimethylfluorenyl)(naphthyldimethylfluorenyl)(spirobifluorenyl)amine; (dimethylfluorenyl)(naphthyldimethylfluorenyl)(spirobifluorenyl)amine; (phenyl)(dimethylfluorenylphenyl)(spirobifluorenyl)amine; (biphenyl)(dimethylfluorenylphenyl)(spirobifluorenyl)amine; (biphenyl)(dimethylfluorenylphenyl)(spirobifluorenyl)amine; (biphenyl)(dimethylfluorenylphenyl)(spirobifluorenyl)amine; (biphenyl)(dimethylfluorenylphenyl)(spirobifluorenyl)amine; (terphenyl)(dimethylfluorenylphenyl)(spirobifluorenyl)amine; (terphenyl)(dimethylfluorenylphenyl)(spirobifluorenyl)amine; (dimethylfluorenyl)(dimethylfluorenylphenyl)(spirobifluorenyl)amine; (dimethylfluorenyl)(dimethylfluorenylphenyl)(spirobifluorenyl)amine; di(biphenyl)(spirobifluorenyl)amine; (biphenyl)(methylbiphenyl)(spirobifluorenyl)amine; (methylphenyl)(biphenyl)(spirobifluorenyl)amine; di(biphenyl)(spirobifluorenyl)amine; (biphenyl)(terphenyl)(spirobifluorenyl)amine; bis(methylbiphenyl)(spirobifluorenyl)amine; (biphenyl)(dimethylbiphenyl)(spirobifluorenyl)amine; (phenyl)(naphthyl)(biphenyldimethylfluorenyl)amine; (phenyl)(naphthyl)(biphenyldimethylfluorenyl)amine; (phenyl)(phenanthrenyl)(biphenyldimethylfluorenyl)amine; (phenyl)(biphenyl)(biphenyldimethylfluorenyl)amine; (phenyl)(naphthylphenyl)(biphenyldimethylfluorenyl)amine; (phenyl)(naphthylphenyl)(biphenyldimethylfluorenyl)amine; (phenyl)(terphenyl)(biphenyldimethylfluorenyl)amine; (phenyl)(terphenyl)(biphenyldimethylfluorenyl)amine; bis(methylphenyl)(biphenyldimethylfluorenyl)amine; bis(methylphenyl)(biphenyldimethylfluorenyl)amine; (naphthyl)(methylphenyl)(biphenyldimethylfluorenyl)amine; (naphthyl)(methylphenyl)(biphenyldimethylfluorenyl)amine; (phenanthrenyl)(methylphenyl)(biphenyldimethylfluorenyl)amine; (biphenyl)(methylphenyl)(biphenyldimethylfluorenyl)amine; (naphthylphenyl)(methylphenyl)(biphenyldimethylfluorenyl)amine; bis(methylphenyl)(biphenyldimethylfluorenyl)amine; (naphthyl)(methylphenyl)(biphenyldimethylfluorenyl)amine; (naphthyl)(methylphenyl)(biphenyldimethylfluorenyl)amine; (phenanthrenyl)(methylphenyl)(biphenyldimethylfluorenyl)amine; (biphenyl)(methylphenyl)(biphenyldimethylfluorenyl)amine; (naphthylphenyl)(methylphenyl)(biphenyldimethylfluorenyl)amine; di(naphthyl)(biphenyldimethylfluorenyl)amine; di(naphthyl)(biphenyldimethylfluorenyl)amine; (naphthyl)(phenanthrenyl)(biphenyldimethylfluorenyl)amine; (naphthyl)(biphenyl)(biphenyldimethylfluorenyl)amine; (naphthyl)(naphthylphenyl)(biphenyldimethylfluorenyl)amine; (naphthyl)(naphthylphenyl)(biphenyldimethylfluorenyl)amine; (naphthyl)(terphenyl)(biphenyldimethylfluorenyl)amine; (naphthyl)(terphenyl)(biphenyldimethylfluorenyl)amine; di(naphthyl)(biphenyldimethylfluorenyl)amine; (naphthyl)(phenanthrenyl)(biphenyldimethylfluorenyl)amine; (naphthyl)(biphenyl)(biphenyldimethylfluorenyl)amine; (naphthyl)(naphthylphenyl)(biphenyldimethylfluorenyl)amine; (naphthyl)(naphthylphenyl)(biphenyldimethylfluorenyl)amine; (naphthyl)(terphenyl)(biphenyldimethylfluorenyl)amine; (naphthyl)(terphenyl)(biphenyldimethylfluorenyl)amine; di(phenanthrenyl)(biphenyldimethylfluorenyl)amine; (biphenyl)(phenanthrenyl)(biphenyldimethylfluorenyl)amine; (naphthylphenyl)(phenanthrenyl)(biphenyldimethylfluorenyl)amine; (naphthylphenyl)(phenanthrenyl)(biphenyldimethylfluorenyl)amine; (terphenyl)(phenanthrenyl)(biphenyldimethylfluorenyl)amine; (terphenyl)(phenanthrenyl)(biphenyldimethylfluorenyl)amine; di(biphenyl)(biphenyldimethylfluorenyl)amine; (phenyl)(dimethylfluorenyl)(biphenyldimethylfluorenyl)amine; (methylphenyl)(dimethylfluorenyl)(biphenyldimethylfluorenyl)amine; (methylphenyl)(dimethylfluorenyl)(biphenyldimethylfluorenyl)amine; (naphthyl)(dimethylfluorenyl)(biphenyldimethylfluorenyl)amine; (naphthyl)(dimethylfluorenyl)(biphenyldimethylfluorenyl)amine; (phenanthrenyl)(dimethylfluorenyl)(biphenyldimethylfluorenyl)amine; (biphenyl)(dimethylfluorenyl)(biphenyldimethylfluorenyl)amine; (naphthylphenyl)(dimethylfluorenyl)(biphenyldimethylfluorenyl)amine; (naphthylphenyl)(dimethylfluorenyl)(biphenyldimethylfluorenyl)amine; bis(dimethylfluorenyl)(biphenyldimethylfluorenyl)amine; di(biphenyl)(biphenyldimethylbenzofluorenyl)amine; di(biphenyl)(biphenyldimethylbenzofluorenyl)amine; di(biphenyl)(biphenyldimethyldibenzofluorenyl)amine; di(biphenyl)(biphenyldiphenylfluorenyl)amine; di(biphenyl)(biphenylphenylmethylfluorenyl)amine; (phenyl)(naphthyl)(biphenylspirobifluorenyl)amine; (phenyl)(biphenyl)(biphenylspirobifluorenyl)amine; di(biphenyl)(biphenylspirobifluorenyl)amine; di(phenyl)(biphenylspirobifluorenyl)amine; (phenyl)(methylphenyl)(biphenylspirobifluorenyl)amine; di(methylphenyl)(biphenylspirobifluorenyl)amine; (phenyl)(triphenylenyl)(biphenyldimethylfluorenyl)amine; (naphthyl)(triphenylenyl)(biphenyldimethylfluorenyl)amine; (phenyl)(naphthyl)(terphenyldimethylfluorenyl)amine; (phenyl)(naphthyl)(terphenyldimethylfluorenyl)amine; (phenyl)(biphenyl)(terphenyldimethylfluorenyl)amine; (phenyl)(naphthylphenyl)(terphenyldimethylfluorenyl)amine; (phenyl)(naphthylphenyl)(terphenyldimethylfluorenyl)amine; di(phenyl)bis(phenylthiophenylphenyl)biphenyldiamine; di(biphenyl)bis(phenylthiophenylphenyl)biphenyldiamine; di(phenyl)bis(phenylthiophenylbiphenyl)biphenyldiamine; di(phenyl)bis(phenylthiophenyldimethylfluorenyl)biphenyldiamine; di(phenyl)bis(phenylthiophenylphenyl)terphenyldiamine; di(phenyl)bis(phenylthiophenylphenyl)dimethylfluorenyldiamine; bis(dimethylfluorenyl)bis(phenylthiophenylphenyl)biphenyldiamine; di(naphthyl)bis(phenylthiophenylphenyl)biphenyldiamine; di(phenyl)bis(naphthylthiophenylphenyl)biphenyldiamine; di(phenyl)bis(phenylthiophenylnaphthyl)biphenyldiamine; tri(biphenyl)(phenylthiophenylphenyl)biphenyldiamine; (phenyl)di(biphenyl)(phenylthiophenylphenyl)biphenyldiamine; di(biphenyl)(naphthyl)(phenylthiophenylphenyl)biphenyldiamine; di(biphenyl)bis(phenylthiophenylphenyl)biphenyldiamine; (phenylthiophenylphenyl)bis(diphenylaminobiphenyl)amine; (phenylthiophenylphenyl)bis(diphenylaminoterphenyl)amine; (phenylthiophenylphenyl)bis(diphenylaminodimethylfluorenyl)amine; (terphenyl)bis[phenyl(phenylthiophenylphenyl)aminobiphenyl]amine; (phenylthiophenylphenyl)bis(phenylnaphthylaminobiphenyl)amine; (phenyl)bis(diphenylaminophenyl)(phenylthiophenylphenyl)biphenyldiamine; bis(phenylthiophenylphenyl)bis(diphenylaminophenyl)biphenyldiamine; di(phenyl)bis[phenyl(phenylthiophenylphenyl)aminophenyl]biphenyldiamine; di(phenyl)bis[phenyl(phenylthiophenylphenyl)aminophenyl]terphenyldiamine; bis(phenylthiophenylphenyl)bis(diphenylaminobiphenyl)biphenyldiamine; tris[phenyl(phenylthiophenylphenyl)aminobiphenyl]amine; tris[phenyl(phenylthiophenylphenyl)aminophenyl]amine; ( )( )( )amine; (phenyl)bis(diphenylaminophenyl)(phenylthiophenylphenyl)biphenyldiamine; (phenyl)(naphthyl)[(phenylcarbazolyl)dimethylfluorenyl]amine; (phenyl)(naphthyl)[(phenylcarbazolyl)biphenyl]amine; (phenyl)(naphthyl)[(phenylcarbazolyl)phenyl]amine; di(biphenyl)[(phenylcarbazolyl)dimethylfluorenyl]amine; (phenyl)(naphthyl)[(diphenylcarbazolyl)dimethylfluorenyl]amine; di(biphenyl)[(phenylcarbazolyl)phenyl]amine; (biphenyl)(diphenylaminophenyl)[(phenylcarbazolyl)phenyl]amine; bis(diphenylaminophenyl)[(phenylcarbazolyl)phenyl]amine; (phenyl)(biphenyl)[(phenylcarbazolyl)biphenyl]amine; (phenyl)(naphthyl)[(phenylcarbazolyl)terphenyl]amine; di(phenyl)[(phenylcarbazolyl)phenanthrenyl]amine; di(phenyl)[(phenylcarbazolyl)biphenyl]amine; di(biphenyl)[(phenylcarbazolyl)naphthyl]amine; bis(naphthylphenyl)[(phenylcarbazolyl)phenyl]amine; (phenyl)(biphenyl)[(diphenylcarbazolyl)phenyl]amine; di(biphenyl)[(phenylcarbazolyl)thiophenylphenyl]amine; di(biphenyl)[(phenylcarbazolyl)dibenzothiophenylphenyl]amine; di(biphenyl)[(phenylcarbazolyl)furanylphenyl]amine; (biphenyl)(phenanthrenyl)[(phenylcarbazolyl)phenyl]amine; di(biphenyl)[(naphthylmethylcarbazolyl)phenyl]amine; (phenyl)(biphenyl)[(phenylcarbazolyl)dibenzofuranylphenyl]amine; di(biphenyl)[(phenylbiphenylcarbazolyl)phenyl]amine; (phenyl)(terphenyl)[(phenylbiphenylcarbazolyl)phenyl]amine; (phenyl)(terphenyl)[(phenylbiphenylcarbazolyl)phenyl]amine; bis(methylbiphenyl)[(tert-butylphenylcarbazolyl)phenyl]amine; (biphenyl)(diphenylaminobiphenyl)[(phenylcarbazolyl)phenyl]amine; (phenyl)(phenyldimethylfluorenylaminobiphenyl)[(phenylcarbazolyl)phenyl]amine; (phenyl)(phenylbiphenylaminobiphenyl)[(phenylcarbazolyl)biphenyl]amine; (phenyl)[phenyl(diphenylaminophenyl)aminobiphenyl][(phenylcarbazolyl)phenyl]amine; (diphenylaminophenyl)(diphenylaminobiphenyl)[(phenylcarbazolyl)phenyl]amine; (diphenylaminophenyl)[phenyl(dimethylfluorenyl)aminophenyl][(phenylcarbazolyl)phenyl]amine; bis(dibenzofuranylphenyl)[(phenylcarbazolyl)phenyl]amine; bis(phenylthiophenylphenyl)[(diphenylcarbazolyl)phenyl]amine; bis(dibenzothiophenylphenyl)[(phenylcarbazolyl)phenyl]amine; bis(dibenzothiophenylphenyl)[(biphenylcarbazolyl)phenyl]amine; di(terphenyl)[(phenylcarbazolyl)phenyl]amine; di(biphenyl)[(biphenylcarbazolyl)phenyl]amine; di(biphenyl)[(naphthylcarbazolyl)phenyl]amine; (naphthyl)(biphenyl)[(phenylcarbazolyl)phenyl]amine; tri(phenyl)[(phenylcarbazolyl)phenyl]biphenyldiamine; (phenyl)bis[(phenylcarbazolyl)phenyl]amine; (biphenyl)bis[(phenylcarbazolyl)phenyl]amine; (naphthyl)bis[(phenylcarbazolyl)phenyl]amine; di(biphenyl)[(phenylcarbazolyl)biphenyl]amine; di(phenyl)(carbazolylbiphenyl)amine; (phenyl)(biphenyl)(carbazolylbiphenyl)amine; (phenyl)(biphenyl)(carbazolylbiphenyl)amine; (phenyl)(biphenyl)(carbazolylbiphenyl)amine; di(biphenyl)(carbazolylbiphenyl)amine; (phenyl)(naphthyl)(carbazolylbiphenyl)amine; (naphthyl)(biphenyl)(carbazolylbiphenyl)amine; (phenyl)(naphthyl)(diphenylcarbazolylbiphenyl)amine; di(biphenyl)(carbazolyldimethylfluorenyl)amine; (phenyl)(naphthyl)(carbazolyldimethylfluorenyl)amine; (phenyl)(phenanthrenyl)(carbazolyldimethylfluorenyl)amine; (biphenyl)(naphthyl)(carbazolyldimethylfluorenyl)amine; (phenyl)(naphthyl)(carbazolyldimethylfluorenyl)amine; di(naphthyl)(carbazolyldimethylfluorenyl)amine; (phenyl)(naphthyl)(diphenylcarbazolyldimethylfluorenyl)amine; (phenyl)(biphenyl)(carbazolyldimethylfluorenyl)amine; (phenyl)(biphenyl)(carbazolylbiphenyl)amine; (phenyl)(biphenyl)(carbazolylbiphenyl)amine; (phenyl)(biphenyl)(carbazolylbiphenyl)amine; di(biphenyl)(carbazolylbiphenyl)amine; di(biphenyl)(carbazolylbiphenyl)amine; di(biphenyl)(carbazolylbiphenyl)amine; (phenyl)bis(carbazolylbiphenyl)amine; (phenyl)bis(carbazolyldimethylfluorenyl)amine; phenylbis[(diphenylamino)phenyl]carbazole; phenylbis[(phenyl(naphthyl)amino)phenyl]carbazole; di(terphenyl)(carbazolyldimethylfluorenyl)amine; bis(naphthylphenyl)(carbazolyldimethylfluorenyl)amine; di(biphenyl)(diphenylcarbazolyldimethylfluorenyl)amine; (phenyl)(biphenyl)(carbazolyldimethylfluorenyl)amine; (phenyl)(dimethylfluorenyl)(carbazolyldimethylfluorenyl)amine; (biphenyl)(dimethylfluorenyl)(carbazolyldimethylfluorenyl)amine; bis(dimethylfluorenyl)(carbazolyldimethylfluorenyl)amine; (naphthyl)(dimethylfluorenyl)(carbazolyldimethylfluorenyl)amine; di(biphenyl)(carbazolylphenyl)amine; di(biphenyl)(carbazolylphenyl)amine; di(naphthyl)(carbazolylphenyl)amine; (phenyl)(naphthyl)(carbazolylbiphenyl)amine; di(biphenyl)(carbazolyldimethylbiphenyl)amine; (phenyl)(naphthyl)(carbazolylterphenyl)amine; (phenyl)(naphthyl)(carbazolylterphenyl)amine; tetra(biphenyl)biphenyldiamine; di(phenyl)di(naphthyl)biphenyldiamine; di(naphthyl)di(biphenyl)biphenyldiamine; (phenyl)(biphenyl)di(naphthyl)biphenyldiamine; (phenyl)(naphthyl)di(biphenyl)biphenyldiamine; di(biphenyl)di(terphenyl)biphenyldiamine; di(biphenyl)di(terphenyl)biphenyldiamine; di(phenyl)di(terphenyl)biphenyldiamine; di(phenyl)di(terphenyl)biphenyldiamine; (phenyl)di(biphenyl)(terphenyl)biphenyldiamine; tri(biphenyl)(terphenyl)biphenyldiamine; (phenyl)di(biphenyl)(terphenyl)biphenyldiamine; tri(biphenyl)(terphenyl)biphenyldiamine; di(biphenyl)bis(naphthylphenyl)biphenyldiamine; tri(biphenyl)(naphthylphenyl)biphenyldiamine; di(biphenyl)bis(naphthylphenyl)biphenyldiamine; tri(biphenyl)(naphthylphenyl)biphenyldiamine; di(biphenyl)bis(dimethylfluorenyl)biphenyldiamine; tetrakis(dimethylfluorenyl)biphenyldiamine; tetrakis(dimethylfluorenyl)dimethylfluorenyldiamine; di(phenyl)bis(dimethylfluorenyl)biphenyldiamine; di(phenyl)di(naphthyl)dimethylfluorenyldiamine; (phenyl)bis(diphenylaminobiphenyl)amine; (phenyl)bis[phenyl(biphenyl)aminobiphenyl]amine; (phenyl)bis[phenyl(naphthyl)aminobiphenyl]amine; (biphenyl)bis[diphenylaminobiphenyl]amine; (biphenyl)bis[diphenylaminoterphenyl]amine; di(phenyl)bis(diphenylaminobiphenyl)biphenyldiamine; di(phenyl)bis[phenyl(naphthyl)aminophenyl]biphenyldiamine; di(naphthyl)bis(diphenylaminobiphenyl)biphenyldiamine; di(phenyl)bis(phenylthiophenylphenyl)biphenyldiamine; (biphenyl)(dimethylfluorenyl)(phenylcarbazolylphenyl)amine; (phenyl)(diphenylfluorenyl)(phenylcarbazolylphenyl)amine; (phenyl)(dimethylfluorenyl)(phenylcarbazolylbiphenyl)amine; (phenyl)(terphenyl)(biphenyldimethylfluorenyl)amine; di(biphenyl)(biphenyldimethylfluorenyl)amine; di(biphenyl)(naphthyldimethylfluorenyl)amine; (biphenyl)(dimethylfluorenyl)(phenylcarbazolylphenyl)amine; di(biphenyl)(phenylcarbazolylphenyl)amine; (biphenyl)(terphenyl)(phenylcarbazolylphenyl)amine; (naphthyl)(dimethylfluorenyl)(phenylcarbazolylbiphenyl)amine; (biphenyl)(dibenzothiophenyl)(phenylcarbazolylbiphenyl)amine; bis(naphthylphenyl)(phenanthrenylphenyl)amine; (biphenyl)(phenylnaphthylphenyl)(naphthylphenyl)amine; (biphenyl)(dibenzofuranylbiphenyl)(naphthylphenyl)amine; di(biphenyl)(dibenzofuranylbiphenyl)amine; di(biphenyl)(dibenzothiophenylbiphenyl)amine; di(biphenyl)(triphenylsilylbiphenyl)amine; di(biphenyl)(triphenylsilylbiphenyl)amine; (phenyl)(diphenylfluorenyl)(triphenylsilylbiphenyl)amine; (biphenyl)bis(naphthylphenyl)amine; tris(naphthylphenyl)amine; (phenyl)bis(carbazolylbiphenyl)amine; bis(dibenzofuranylphenyl)(carbazolylbiphenyl)amine; (biphenyl)(dibenzofuranylphenyl)(carbazolylbiphenyl)amine; (terphenyl)(dibenzofuranylphenyl)(carbazolylbiphenyl)amine; (biphenyl)(dibenzofuranylphenyl)(carbazolylbiphenyl)amine; (biphenyl)(dimethylfluorenyl)(carbazolylbiphenyl)amine; (biphenyl)(dibenzofuranyl)(carbazolylbiphenyl)amine; (phenyl)(biphenyl)(carbazolylbiphenyl)amine; di(biphenyl)(carbazolylbiphenyl)amine; (phenyl)(diphenylfluorenyl)(triphenylsilylbiphenyl)amine; (dimethylfluorenyl)(biphenyl)(carbazolylphenyl)amine; (biphenyl)bis(diphenylfluorenyl)amine; (biphenyl)bis(spirobifluorenyl)amine

### (Group 34A)

phenyl(naphthylphenyl)anthracene; phenyl(biphenyl)anthracene; phenyl(naphthylphenyl)anthracene; phenyl(biphenyl)anthracene; diphenylanthracene; phenyl(naphthyl)anthracene; phenyl(phenanthrenyl)anthracene; phenyl(naphthylphenyl)anthracene; phenyl(phenylnaphthyl)anthracene; phenyl(biphenyl)anthracene; phenyl(naphthylphenyl)anthracene; phenyl(phenylnaphthyl)anthracene; phenyl(naphthyl)anthracene-d₈; phenyl(naphthylphenyl)anthracene-d₈; phenyl(naphthyl)anthracene-d₈; phenyl(naphthylphenyl)anthracene-d₈; phenyl(naphthylphenyl)anthracene-d₈; phenyl(biphenyl)anthracene-d₈; phenyl(phenylnaphthyl)anthracene-d₈; diphenyl(naphthyl)anthracene; diphenyl(naphthylphenyl)anthracene; dinaphthyl(phenyl)anthracene; diphenyl(naphthyl)anthracene; diphenyl(biphenyl)anthracene; phenyl(naphthyl)(naphthylphenyl)anthracene; phenyl(naphthyl)(naphthylphenyl)anthracene; diphenyl(naphthylphenyl)anthracene; diphenyl(naphthylphenyl)anthracene; dinaphthyl(phenyl)anthracene; phenyl(naphthyl)(biphenyl)anthracene; diphenyl(naphthylphenyl)anthracene-d₇; diphenyl(naphthylphenyl)anthracene-d₇; naphthyl(naphthylphenyl)anthracene; naphthyl(biphenyl)anthracene; dinaphthylanthracene; naphthyl(naphthylphenyl)anthracene; naphthyl(biphenyl)anthracene; dinaphthylanthracene; naphthyl(biphenyl)anthracene; naphthyl(phenanthrenyl)anthracene; naphthyl(naphthylphenyl)anthracene; naphthyl(phenylnaphthyl)anthracene; naphthyl(naphthylphenyl)anthracene; phenyl(naphthyl)anthracene; naphthyl(phenylnaphthyl)anthracene; naphthyl(naphthylphenyl)anthracene-d₈; dinaphthylanthracene-d₈; naphthyl(naphthylphenyl)anthracene-d₈; dinaphthylanthracene-d₈; naphthyl(naphthylphenyl)anthracene-d₈; naphthyl(biphenyl)anthracene-d₈; naphthyl(phenylnaphthyl)anthracene-d₈; phenyl(naphthyl)anthracene-d₈; dinaphthyl(phenyl)anthracene; dinaphthyl(phenyl)anthracene; phenyl(naphthyl)(naphthylphenyl)anthracene; phenyl(naphthyl)(naphthylphenyl)anthracene; trinaphthylanthracene; phenyl(naphthyl)(biphenyl)anthracene; trinaphthylanthracene; dinaphthyl(biphenyl)anthracene; phenyl(naphthyl)(naphthylphenyl)anthracene; dinaphthyl(naphthylphenyl)anthracene; phenyl(naphthyl)(naphthylphenyl)anthracene; dinaphthyl(naphthylphenyl)anthracene; dinaphthyl(naphthylphenyl)anthracene; phenyl(naphthyl)(naphthylphenyl)anthracene-d₇; phenyl(naphthyl)(naphthylphenyl)anthracene-d₇; naphthyl(naphthylphenyl)anthracene; naphthyl(biphenyl)anthracene; dinaphthylanthracene; naphthyl(naphthylphenyl)anthracene; naphthyl(biphenyl)anthracene; naphthyl(phenanthrenyl)anthracene; naphthyl(biphenyl)anthracene; naphthyl(naphthylphenyl)anthracene; naphthyl(naphthylphenyl)anthracene; naphthyl(phenylnaphthyl)anthracene; naphthyl(naphthylphenyl)anthracene-d₈; naphthyl(naphthylphenyl)anthracene-d₈; naphthyl(naphthylphenyl)anthracene-d₈; naphthyl(biphenyl)anthracene-d₈; naphthyl(phenylnaphthyl)anthracene-d₈; dinaphthyl(phenyl)anthracene; phenyl(naphthyl)(naphthylphenyl)anthracene; phenyl(naphthyl)(naphthylphenyl)anthracene; phenyl(naphthyl)(biphenyl)anthracene; trinaphthylanthracene; phenyl(naphthyl)(naphthylphenyl)anthracene; phenyl(naphthyl)(naphthylphenyl)anthracene; dinaphthyl(naphthylphenyl)anthracene; dinaphthyl(naphthylphenyl)anthracene; dinaphthyl(naphthylphenyl)anthracene; dinaphthyl(naphthylphenyl)anthracene; phenyl(naphthyl)(naphthylphenyl)anthracene-d₇; phenyl(naphthyl)(naphthylphenyl)anthracene-d₇; phenanthrenyl(biphenyl)anthracene; phenanthrenyl(naphthylphenyl)anthracene; phenanthrenyl(biphenyl)anthracene; phenyl(phenanthrenyl)anthracene; phenanthrenyl(naphthylphenyl)anthracene; phenanthrenyl(biphenyl)anthracene; diphenanthrenylanthracene; phenanthrenyl(naphthylphenyl)anthracene; phenanthrenyl(naphthylphenyl)anthracene-d₈; phenyl(phenanthrenyl)anthracene-d₈; phenanthrenyl(naphthylphenyl)anthracene-d₈; phenanthrenyl(naphthylphenyl)anthracene-d₈; (phenylnaphthyl)(naphthylphenyl)anthracene; biphenyl(phenylnaphthyl)anthracene; (phenylnaphthyl)(naphthylphenyl)anthracene; biphenyl(phenylnaphthyl)anthracene; (phenylnaphthyl)(naphthylphenyl)anthracene; (phenylnaphthyl)(naphthylphenyl)anthracene; (phenylnaphthyl)(naphthylphenyl)anthracene; (phenylnaphthyl)(naphthylphenyl)anthracene-d₈; (phenylnaphthyl)(naphthylphenyl)anthracene-d₈; (phenylnaphthyl)(naphthylphenyl)anthracene-d₈; benzophenanthrenyl(naphthylphenyl)anthracene; biphenyl[(benzophenanthrenyl)phenyl]anthracene; benzophenanthrenyl(biphenyl)anthracene; benzophenanthrenyl(naphthyl)anthracene; [(benzophenanthrenyl)phenyl](naphthyl)anthracene; [(benzophenanthrenyl)phenyl](naphthylphenyl)anthracene; benzophenanthrenyl(naphthylphenyl)anthracene; benzophenanthrenyl(biphenyl)anthracene; [(benzophenanthrenyl)phenyl](biphenyl)anthracene; benzophenanthrenyl(phenyl)anthracene; [(benzophenanthrenyl)phenyl](phenyl)anthracene; benzophenanthrenyl(biphenyl)anthracene; [(benzophenanthrenyl)phenyl](naphthyl)anthracene; benzophenanthrenyl(phenylnaphthyl)anthracene; benzophenanthrenyl(naphthyl)anthracene; [(benzophenanthrenyl)phenyl](biphenyl)anthracene; [(benzophenanthrenyl)phenyl](naphthylphenyl)anthracene; benzophenanthrenyl(naphthylphenyl)anthracene; benzophenanthrenyl(naphthylphenyl)anthracene; benzotriphenylenyl(naphthyl)anthracene; benzotriphenylenyl(phenyl)anthracene; benzotriphenylenyl(biphenyl)anthracene; benzotriphenylenyl(phenylnaphthyl)anthracene; benzotriphenylenyl(naphthylphenyl)anthracene; benzotriphenylenyl(phenanthrenyl)anthracene; benzotriphenylenyl(naphthylphenyl)anthracene; benzotriphenylenyl(naphthylphenyl)anthracene; benzotriphenylenyl(biphenyl)anthracene; benzotriphenylenyl(naphthylphenyl)anthracene; benzotriphenylenyl(biphenyl)anthracene; phenyl(benzanthracenyl)anthracene; naphthyl(benzanthracenyl)anthracene; (naphthylphenyl)(benzanthracenyl)anthracene; biphenyl(benzanthracenyl)anthracene; naphthyl(benzanthracenyl)anthracene; (naphthylphenyl)(benzanthracenyl)anthracene; (phenylnaphthyl)(benzanthracenyl)anthracene; biphenyl(benzanthracenyl)anthracene; (naphthylphenyl)(benzanthracenyl)anthracene; (naphthylphenyl)(benzanthracenyl)anthracene; biphenyl(benzanthracenyl)anthracene; naphthyl(benzophenanthrenyl)anthracene-d₈; naphthyl(benzophenanthrenyl)anthracene-d₈; phenyl(benzophenanthrenyl)anthracene-d₈; naphthyl[(benzophenanthrenyl)phenyl]anthracene-d₈; (naphthylphenyl)(benzophenanthrenyl)anthracene-d₈; (naphthylphenyl)[(benzophenanthrenyl)phenyl]anthracene-d₈; (naphthylphenyl)(benzophenanthrenyl)anthracene-d₈; naphthyl[(benzophenanthrenyl)phenyl]anthracene-d₈; (phenylnaphthyl)(benzophenanthrenyl)anthracene-d₈; (naphthylphenyl)(benzophenanthrenyl)anthracene-d₈; biphenyl(benzophenanthrenyl)anthracene-d₈; naphthyl(benzotriphenylenyl)anthracene-d₈; naphthyl(benzotriphenylenyl)anthracene-d₈; phenyl(benzotriphenylenyl)anthracene-d₈; phenyl(benzanthracenyl)anthracene-d₈; naphthyl(benzanthracenyl)anthracene-d₈; naphthyl(benzanthracenyl)anthracene-d₈; (naphthylphenyl)(benzanthracenyl)anthracene-d₈; biphenyl(dimethylfluorenyl)anthracene; naphthyl(dimethylfluorenyl)anthracene; (naphthylphenyl)(dimethylfluorenyl)anthracene; biphenyl(dimethylfluorenyl)anthracene; phenyl(dimethylfluorenyl)anthracene; (phenylnaphthyl)(dimethylfluorenyl)anthracene; naphthyl(dimethylfluorenyl)anthracene; phenanthrenyl(dimethylfluorenyl)anthracene; biphenyl(dimethylfluorenyl)anthracene; (naphthylphenyl)(dimethylfluorenyl)anthracene; (naphthylphenyl)(dimethylfluorenyl)anthracene; naphthyl(dimethylfluorenyl)anthracene-d₈; phenyl(dimethylfluorenyl)anthracene-d₈; biphenyl(dimethylfluorenyl)anthracene-d₈; naphthyl(dimethylfluorenyl)anthracene-d₈; diphenyl(dimethylfluorenyl)anthracene; biphenyl[(dimethylfluorenyl)phenyl]anthracene; (phenylnaphthyl)[(dimethylfluorenyl)phenyl]anthracene; naphthyl[(dimethylfluorenyl)phenyl]anthracene; phenyl[(dimethylfluorenyl)phenyl]anthracene; biphenyl[(dimethylfluorenyl)phenyl]anthracene; (phenylnaphthyl)[(dimethylfluorenyl)phenyl]anthracene; naphthyl[(dimethylfluorenyl)phenyl]anthracene; biphenyl[(dimethylfluorenyl)phenyl]anthracene; phenanthrenyl[(dimethylfluorenyl)phenyl]anthracene; (naphthylphenyl)[(dimethylfluorenyl)phenyl]anthracene; (naphthylphenyl)[(dimethylfluorenyl)phenyl]anthracene; phenyl[(dimethylfluorenyl)phenyl]anthracene-d₈; naphthyl[(dimethylfluorenyl)phenyl]anthracene-d₈; naphthyl[(dimethylfluorenyl)phenyl]anthracene-d₈; biphenyl[(dimethylfluorenyl)phenyl]anthracene-d₈; diphenyl[(dimethylfluorenyl)phenyl]anthracene; naphthyl(naphthylphenyl)anthracene-d₂₆; naphthyl(naphthylphenyl)anthracene-d₂₆; naphthyl(naphthylphenyl)anthracene-d₂₆; naphthyl(naphthylphenyl)anthracene-d₂₆; phenyl(naphthylphenyl)anthracene-d₂₄; dinaphthylanthracene-d₂₂; dinaphthylanthracene-d₂₂; phenyl(naphthobenzofuranyl)anthracene; biphenyl(naphthobenzofuranyl)anthracene; biphenyl(naphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; phenyl[(naphthobenzofuranyl)phenyl]anthracene; phenyl[(naphthobenzofuranyl)phenyl]anthracene; biphenyl[(naphthobenzofuranyl)phenyl]anthracene; biphenyl[(naphthobenzofuranyl)phenyl]anthracene; (dimethylfluorenyl)(naphthobenzofuranyl)anthracene; (dimethylfluorenyl)(naphthobenzofuranyl)anthracene; (dimethylfluorenyl)(naphthobenzofuranyl)anthracene; [(dimethylfluorenyl)phenyl](naphthobenzofuranyl)anthracene; [(dibenzofuranyl)phenyl](naphthobenzofuranyl)anthracene; [(dimethylfluorenyl)phenyl](naphthobenzofuranyl)anthracene; (dimethylfluorenyl)[(naphthobenzofuranyl)phenyl]anthracene; (dimethylfluorenyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; (dibenzofuranyl)(naphthobenzofuranyl)anthracene; (dibenzofuranyl)(naphthobenzofuranyl)anthracene; (dibenzofuranyl)(naphthobenzofuranyl)anthracene; [(dibenzofuranyl)phenyl](naphthobenzofuranyl)anthracene; [(dimethylfluorenyl)phenyl](naphthobenzofuranyl)anthracene; (naphthylphenyl)(naphthobenzofuranyl)anthracene; (dibenzofuranyl)[(naphthobenzofuranyl)phenyl]anthracene; (dibenzofuranyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; (benzanthracenyl)(naphthobenzofuranyl)anthracene; (benzophenanthrenyl)[(naphthobenzofuranyl)phenyl]anthracene; (phenylcarbazolyl)(naphthobenzofuranyl)anthracene; [(carbazolyl)phenyl](naphthobenzofuranyl)anthracene; (phenanthrenyl)(naphthobenzofuranyl)anthracene; (phenanthrenyl)[(naphthobenzofuranyl)phenyl]anthracene; (phenanthrenyl)[(naphthobenzofuranyl)phenyl]anthracene; (spirobifluorenyl)[(naphthobenzofuranyl)phenyl]anthracene; (spirobifluorenyl)[(naphthobenzofuranyl)phenyl]anthracene; (benzophenanthrenyl)(naphthobenzofuranyl)anthracene; (benzotriphenylenyl)(naphthobenzofuranyl)anthracene; (triphenylenyl)(naphthobenzofuranyl)anthracene; (benzotriphenylenyl)(naphthobenzofuranyl)anthracene; (benzophenanthrenyl)(naphthobenzofuranyl)anthracene; (phenanthrenyl)(naphthobenzofuranyl)anthracene (dibenzothiophenyl)(naphthobenzofuranyl)anthracene; (benzophenanthrenyl)[(naphthobenzofuranyl)phenyl]anthracene; (diphenylfluorenyl)[(naphthobenzofuranyl)phenyl]anthracene; (diphenylfluorenyl)[(naphthobenzofuranyl)phenyl]anthracene; (phenyl-d₅)(naphthobenzofuranyl)anthracene; (biphenyl-d₅)(naphthobenzofuranyl)anthracene; (biphenyl-d₅)(naphthobenzofuranyl)anthracene; (fluorophenyl)(naphthobenzofuranyl)anthracene; (cyanophenyl)(naphthobenzofuranyl)anthracene; di(naphthobenzofuranyl)anthracene; [(naphthobenzofuranyl)phenyl](naphthobenzofuranyl)anthracene; [(naphthobenzofuranyl)phenyl](naphthobenzofuranyl)anthracene; bis[(naphthobenzofuranyl)phenyl]anthracene; bis[(naphthobenzofuranyl)phenyl]anthracene; [(phenylnaphthyl)phenyl](naphthobenzofuranyl)anthracene; (phenylphenanthrenyl)(naphthobenzofuranyl)anthracene; (phenylbenzocarbazolyl)(naphthobenzofuranyl)anthracene; di(naphthobenzofuranyl)anthracene; [(triphenylsilyl)phenyl](naphthobenzofuranyl)anthracene; di(naphthobenzofuranyl)anthracene; [(naphthobenzofuranyl)phenyl](naphthobenzofuranyl)anthracene; (dimethylbenzofluorenyl)(naphthobenzofuranyl)anthracene; [(benzanthracenyl)phenyl](naphthobenzofuranyl)anthracene; bis[(naphthobenzofuranyl)phenyl]anthracene; bis[(naphthobenzofuranyl)phenyl]anthracene; (terphenyl)(naphthobenzofuranyl)anthracene; (terphenyl)(naphthobenzofuranyl)anthracene; (terphenyl)(naphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; [(naphthobenzofuranyl)phenyl](biphenyl)anthracene; [(naphthobenzofuranyl)phenyl](biphenyl)anthracene; [(naphthobenzofuranyl)phenyl](biphenyl)anthracene; [(naphthobenzofuranyl)phenyl](biphenyl)anthracene; naphthyl(naphthobenzofuranyl)anthracene; naphthyl(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; naphthyl[(naphthobenzofuranyl)phenyl]anthracene; naphthyl[(naphthobenzofuranyl)phenyl]anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; naphthyl[(naphthobenzofuranyl)phenyl]anthracene; naphthyl[(naphthobenzofuranyl)phenyl]anthracene; (naphthylphenyl)(naphthobenzofuranyl)anthracene; (naphthylphenyl)(naphthobenzofuranyl)anthracene; (phenanthrenyl)(naphthobenzofuranyl)anthracene; phenyl(naphthobenzothiophenyl)anthracene; biphenyl(naphthobenzothiophenyl)anthracene; biphenyl(naphthobenzothiophenyl)anthracene; naphthyl(naphthobenzothiophenyl)anthracene; naphthyl(naphthobenzothiophenyl)anthracene; phenyl(phenylnaphthobenzothiophenyl)anthracene; phenyl(phenylnaphthobenzothiophenyl)anthracene; phenyl[(naphthobenzothiophenyl)phenyl]anthracene; phenyl[(naphthobenzothiophenyl)phenyl]anthracene; biphenyl[(naphthobenzothiophenyl)phenyl]anthracene; biphenyl[(naphthobenzothiophenyl)phenyl]anthracene; naphthyl[(naphthobenzothiophenyl)phenyl]anthracene; naphthyl[(naphthobenzothiophenyl)phenyl]anthracene; terphenyl(naphthobenzothiophenyl)anthracene; terphenyl(naphthobenzothiophenyl)anthracene; terphenyl(naphthobenzothiophenyl)anthracene; (phenylnaphthyl)(naphthobenzothiophenyl)anthracene; (naphthylphenyl)(naphthobenzothiophenyl)anthracene; (naphthylphenyl)(naphthobenzothiophenyl)anthracene; biphenyl[(naphthobenzothiophenyl)phenyl]anthracene; biphenyl[(naphthobenzothiophenyl)phenyl]anthracene; biphenyl[(naphthobenzothiophenyl)phenyl]anthracene; biphenyl[(naphthobenzothiophenyl)phenyl]anthracene; (phenylnaphthyl)[(naphthobenzothiophenyl)phenyl]anthracene; (phenylnaphthyl)[(naphthobenzothiophenyl)phenyl]anthracene; (fluorophenyl)(naphthobenzofuranyl)anthracene; (fluorophenyl)(naphthobenzofuranyl)anthracene; (fluorophenyl)(naphthobenzofuranyl)anthracene; (fluorobiphenyl)(naphthobenzofuranyl)anthracene; (cyanobiphenyl)(naphthobenzofuranyl)anthracene; (terphenyl)(naphthobenzofuranyl)anthracene-d₃₀; (binaphthyl)(naphthobenzofuranyl)anthracene-d₃₀; (phenylnaphthyl)(naphthobenzofuranyl)anthracene-d₂₈; phenyl(naphthobenzofuranyl)anthracene-d₂₂; (terphenyl)(naphthobenzofuranyl)anthracene-d₃₀; (biphenyl)(naphthobenzofuranyl)anthracene-d₂₆; (phenylnaphthyl)(naphthobenzofuranyl)anthracene-d₂₈; (naphthyl)(naphthobenzofuranyl)anthracene-d₂₄; (terphenyl)(naphthobenzofuranyl)anthracene-d₃₀; (biphenyl)(naphthobenzofuranyl)anthracene-d₂₆; (phenylnaphthyl)(naphthobenzofuranyl)anthracene-d₂₈; (naphthyl)(naphthobenzofuranyl)anthracene-d₂₄; (terphenyl)(naphthobenzofuranyl)anthracene-d₃₀; (biphenyl)(naphthobenzofuranyl)anthracene-d₂₆; (binaphthyl)(naphthobenzofuranyl)anthracene-d₃₀; (phenylnaphthyl)(naphthobenzofuranyl)anthracene-d₂₈; (phenanthrenylphenyl)(naphthobenzofuranyl)anthracene-d₃₀; (naphthylphenyl)(naphthobenzofuranyl)anthracene-d₂₈; (phenanthrenylphenyl)(naphthobenzofuranyl)anthracene-d₃₀; (naphthylphenyl)(naphthobenzofuranyl)anthracene-d₂₈; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (naphthylphenyl)(naphthobenzofuranyl)anthracene-d₂₈; (phenanthrenyl)(naphthobenzofuranyl)anthracene-d₂₆; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenyl)(naphthobenzofuranyl)anthracene-d₂₆; (phenanthrenylphenyl)(naphthobenzofuranyl)anthracene-d₃₀; (naphthylphenyl)(naphthobenzofuranyl)anthracene-d₂₈; (phenanthrenylphenyl)(naphthobenzofuranyl)anthracene-d₃₀; naphthyl(naphthobenzofuranyl)anthracene-d₈; phenyl(naphthobenzofuranyl)anthracene-d₂; phenyl(naphthobenzofuranyl)anthracene-d₁₃; phenyl(naphthobenzofuranyl)anthracene-d₁; biphenyl(naphthobenzofuranyl)anthracene-d₈; phenyl(naphthobenzofuranyl)anthracene-d₂; phenyl(naphthobenzofuranyl)anthracene-d₈; phenyl(naphthobenzofuranyl)anthracene-d₁; phenyl(naphthobenzofuranyl)anthracene-d₂; biphenyl(naphthobenzofuranyl)anthracene-d₈; phenyl(naphthobenzofuranyl)anthracene-d₁; phenyl(naphthobenzofuranyl)anthracene-d₂; biphenyl(naphthobenzofuranyl)anthracene-d₈; phenyl(naphthobenzofuranyl)anthracene-d₁; phenyl(naphthobenzofuranyl)anthracene-d₄; phenyl[(naphthobenzofuranyl)phenyl]anthracene-d₈; biphenyl[(naphthobenzofuranyl)phenyl]anthracene-d₃₀; naphthyl[(naphthobenzofuranyl)phenyl]anthracene-d₂₈; terphenyl(naphthobenzofuranyl)anthracene-d₈; biphenyl[(naphthobenzofuranyl)phenyl]anthracene-d₈; phenyl[(naphthobenzofuranyl)phenyl]anthracene-d₈; biphenyl[(naphthobenzofuranyl)phenyl]anthracene-d₃₀; naphthyl[(naphthobenzofuranyl)phenyl]anthracene-d₂₈; (naphthylphenyl)(naphthobenzofuranyl)anthracene-d₈; phenyl[(naphthobenzofuranyl)phenyl]anthracene-d₈; phenanthrenyl[(naphthobenzofuranyl)phenyl]anthracene-d₃₀; phenanthrenyl[(naphthobenzofuranyl)phenyl]anthracene-d₃₀; terphenyl(naphthobenzofuranyl)anthracene-d₈; phenyl(naphthobenzofuranyl)anthracene; biphenyl(naphthobenzofuranyl)anthracene; biphenyl(naphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; phenyl[(naphthobenzofuranyl)phenyl]anthracene; phenyl[(naphthobenzofuranyl)phenyl]anthracene; biphenyl[(naphthobenzofuranyl)phenyl]anthracene; biphenyl[(naphthobenzofuranyl)phenyl]anthracene; terphenyl(naphthobenzofuranyl)anthracene; terphenyl(naphthobenzofuranyl)anthracene; terphenyl(naphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; biphenyl[(naphthobenzofuranyl)phenyl]anthracene; biphenyl[(naphthobenzofuranyl)phenyl]anthracene; phenyl(phenylnaphthobenzofuranyl)anthracene; biphenyl(phenylnaphthobenzofuranyl)anthracene; biphenyl(phenylnaphthobenzofuranyl)anthracene; naphthyl(phenylnaphthobenzofuranyl)anthracene; naphthyl(phenylnaphthobenzofuranyl)anthracene; (phenylnaphthyl)(phenylnaphthobenzofuranyl)anthracene; (phenylnaphthyl)(phenylnaphthobenzofuranyl)anthracene; (phenylnaphthyl)(phenylnaphthobenzofuranyl)anthracene; (phenylnaphthyl)(phenylnaphthobenzofuranyl)anthracene; (phenylnaphthyl)(phenylnaphthobenzofuranyl)anthracene; (phenylnaphthyl)(phenylnaphthobenzofuranyl)anthracene; (phenylnaphthyl)(phenylnaphthobenzofuranyl)anthracene; naphthyl[(naphthobenzofuranyl)phenyl]anthracene; naphthyl[(naphthobenzofuranyl)phenyl]anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; (phenylnaphthyl)(naphthobenzofuranyl)anthracene; naphthyl[(naphthobenzofuranyl)phenyl]anthracene; naphthyl[(naphthobenzofuranyl)phenyl]anthracene; (naphthylphenyl)(naphthobenzofuranyl)anthracene; (naphthylphenyl)(naphthobenzofuranyl)anthracene; (phenanthrenyl)(naphthobenzofuranyl)anthracene; phenyl(naphthobenzofuranyl)anthracene; biphenyl(naphthobenzofuranyl)anthracene; biphenyl(naphthobenzofuranyl)anthracene; terphenyl(naphthobenzofuranyl)anthracene; terphenyl(naphthobenzofuranyl)anthracene; phenyl(phenylnaphthobenzofuranyl)anthracene; phenyl(phenylnaphthobenzofuranyl)anthracene; phenyl(phenylnaphthobenzofuranyl)anthracene; phenyl[(naphthobenzofuranyl)phenyl]anthracene; biphenyl[(naphthobenzofuranyl)phenyl]anthracene; biphenyl[(naphthobenzofuranyl)phenyl]anthracene; biphenyl(naphthobenzofuranyl)anthracene; terphenyl(naphthobenzofuranyl)anthracene; phenyl(phenylnaphthobenzofuranyl)anthracene; phenyl(phenylnaphthobenzofuranyl)anthracene; phenyl[(naphthobenzofuranyl)phenyl]anthracene; biphenyl[(naphthobenzofuranyl)phenyl]anthracene; biphenyl[(naphthobenzofuranyl)phenyl]anthracene; biphenyl[(naphthobenzofuranyl)phenyl]anthracene; biphenyl[(naphthobenzofuranyl)phenyl]anthracene; (dibenzofuranyl)[(naphthobenzofuranyl)phenyl]anthracene; (dibenzofuranyl)[(naphthobenzofuranyl)phenyl]anthracene; (dimethylfluorenyl)[(naphthobenzofuranyl)phenyl]anthracene; [(dibenzofuranyl)phenyl](naphthobenzofuranyl)anthracene; [(dimethylfluorenyl)phenyl](naphthobenzofuranyl)anthracene; (dibenzofuranyl)(naphthobenzofuranyl)anthracene; (naphthylphenyl)(naphthobenzofuranyl)anthracene; (dibenzofuranyl)[(naphthobenzofuranyl)phenyl]anthracene; (dibenzofuranyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; (dimethylfluorenyl)(naphthobenzofuranyl)anthracene; (dimethylfluorenyl)(naphthobenzofuranyl)anthracene; (dimethylfluorenyl)(naphthobenzofuranyl)anthracene; [(dibenzofuranyl)phenyl](naphthobenzofuranyl)anthracene; [(dimethylfluorenyl)phenyl](naphthobenzofuranyl)anthracene; (dimethylfluorenyl)[(naphthobenzofuranyl)phenyl]anthracene; (dimethylfluorenyl)[(naphthobenzofuranyl)phenyl]anthracene; [(dibenzofuranyl)phenyl][(naphthobenzofuranyl)phenyl]anthracene; (dimethylfluorenyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; (dimethylfluorenyl)(naphthobenzofuranyl)anthracene; (dimethylfluorenyl)(naphthobenzofuranyl)anthracene; [(dimethylfluorenyl)phenyl](naphthobenzofuranyl)anthracene; [(dimethylfluorenyl)phenyl](naphthobenzofuranyl)anthracene; [(dibenzofuranyl)phenyl](naphthobenzofuranyl)anthracene; (dimethylfluorenyl)[(naphthobenzofuranyl)phenyl]anthracene; (dimethylfluorenyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; (dibenzofuranyl)(naphthobenzofuranyl)anthracene; (dibenzofuranyl)(naphthobenzofuranyl)anthracene; (dimethylfluorenyl)(naphthobenzofuranyl)anthracene; [(dibenzofuranyl)phenyl](naphthobenzofuranyl)anthracene; [(dimethylfluorenyl)phenyl](naphthobenzofuranyl)anthracene; (naphthylphenyl)(naphthobenzofuranyl)anthracene; (dibenzofuranyl)[(naphthobenzofuranyl)phenyl]anthracene; (dibenzofuranyl)[(naphthobenzofuranyl)phenyl]anthracene; [(dibenzofuranyl)phenyl][(naphthobenzofuranyl)phenyl]anthracene; [(dibenzofuranyl)phenyl][(naphthobenzofuranyl)phenyl]anthracene; [(carbazolyl)phenyl][(naphthobenzofuranyl)phenyl]anthracene; (benzophenanthrenyl)[(naphthobenzofuranyl)phenyl]anthracene; (phenanthrenyl)(naphthobenzofuranyl)anthracene; (phenylcarbazolyl)(naphthobenzofuranyl)anthracene; (benzanthracenyl)(naphthobenzofuranyl)anthracene; (phenanthrenyl)[(naphthobenzofuranyl)phenyl]anthracene; (phenanthrenyl)[(naphthobenzofuranyl)phenyl]anthracene; (spirobifluorenyl)[(naphthobenzofuranyl)phenyl]anthracene; (spirobifluorenyl)[(naphthobenzofuranyl)phenyl]anthracene; (benzophenanthrenyl)(naphthobenzofuranyl)anthracene; (benzotriphenylenyl)(naphthobenzofuranyl)anthracene; (triphenylenyl)(naphthobenzofuranyl)anthracene; (benzotriphenylenyl)(naphthobenzofuranyl)anthracene; (benzophenanthrenyl)(naphthobenzofuranyl)anthracene; (phenanthrenyl)(naphthobenzofuranyl)anthracene (dibenzothiophenyl)(naphthobenzofuranyl)anthracene; (benzophenanthrenyl)[(naphthobenzofuranyl)phenyl]anthracene; (benzophenanthrenyl)[(naphthobenzofuranyl)phenyl]anthracene; (diphenylfluorenyl)[(naphthobenzofuranyl)phenyl]anthracene; (diphenylfluorenyl)[(naphthobenzofuranyl)phenyl]anthracene; (benzanthracenyl)(naphthobenzofuranyl)anthracene; (phenanthrenyl)(naphthobenzofuranyl)anthracene; (phenylcarbazolyl)(naphthobenzofuranyl)anthracene; [(carbazolyl)phenyl](naphthobenzofuranyl)anthracene (phenanthrenyl)[(naphthobenzofuranyl)phenyl]anthracene; (phenanthrenyl)[(naphthobenzofuranyl)phenyl]anthracene; (spirobifluorenyl)[(naphthobenzofuranyl)phenyl]anthracene; (spirobifluorenyl)[(naphthobenzofuranyl)phenyl]anthracene; phenyl(naphthobenzofuranyl)anthracene-d₅; biphenyl(naphthobenzofuranyl)anthracene-d₅; biphenyl(naphthobenzofuranyl)anthracene-d₅; fluorophenyl(naphthobenzofuranyl)anthracene; cyanophenyl(naphthobenzofuranyl)anthracene; di(naphthobenzofuranyl)anthracene; (dibenzofuranyl)[(naphthobenzofuranyl)phenyl]anthracene; (naphthobenzofuranyl)[(naphthobenzofuranyl)phenyl]anthracene; bis[(naphthobenzofuranyl)phenyl]anthracene; bis[(naphthobenzofuranyl)phenyl]anthracene; [(phenylnaphthyl)phenyl](naphthobenzofuranyl)anthracene; (phenylphenanthrenyl)(naphthobenzofuranyl)anthracene; (phenylbenzocarbazolyl)(naphthobenzofuranyl)anthracene; di(naphthobenzofuranyl)anthracene; [(triphenylsilyl)phenyl](naphthobenzofuranyl)anthracene; di(naphthobenzofuranyl)anthracene; (naphthobenzofuranyl)[(naphthobenzofuranyl)phenyl]anthracene; (dimethylbenzofluorenyl)(naphthobenzofuranyl)anthracene; [(benzanthracenyl)phenyl](naphthobenzofuranyl)anthracene; bis[(naphthobenzofuranyl)phenyl]anthracene; bis[(naphthobenzofuranyl)phenyl]anthracene; phenyl(naphthobenzothiophenyl)anthracene; biphenyl(naphthobenzothiophenyl)anthracene; biphenyl(naphthobenzothiophenyl)anthracene; naphthyl(naphthobenzothiophenyl)anthracene; naphthyl(naphthobenzothiophenyl)anthracene; phenyl(phenylnaphthobenzothiophenyl)anthracene; phenyl(naphthobenzothiophenyl)anthracene; phenyl[(naphthobenzothiophenyl)phenyl]anthracene; phenyl[(naphthobenzothiophenyl)phenyl]anthracene; biphenyl[(naphthobenzothiophenyl)phenyl]anthracene; biphenyl[(naphthobenzothiophenyl)phenyl]anthracene; naphthyl[(naphthobenzothiophenyl)phenyl]anthracene; naphthyl[(naphthobenzothiophenyl)phenyl]anthracene; terphenyl(naphthobenzothiophenyl)anthracene; terphenyl(naphthobenzothiophenyl)anthracene; terphenyl(naphthobenzothiophenyl)anthracene; (phenylnaphthyl)(naphthobenzothiophenyl)anthracene; (naphthylphenyl)(naphthobenzothiophenyl)anthracene; (naphthylphenyl)(naphthobenzothiophenyl)anthracene; biphenyl[(naphthobenzothiophenyl)phenyl]anthracene; biphenyl[(naphthobenzothiophenyl)phenyl]anthracene; biphenyl[(naphthobenzothiophenyl)phenyl]anthracene; biphenyl[(naphthobenzothiophenyl)phenyl]anthracene; (phenylnaphthyl)[(naphthobenzothiophenyl)phenyl]anthracene; (phenylnaphthyl)[(naphthobenzothiophenyl)phenyl]anthracene; (fluorophenyl)(naphthobenzofuranyl)anthracene; (fluorophenyl)(naphthobenzofuranyl)anthracene; (fluorophenyl)(naphthobenzofuranyl)anthracene; (fluorobiphenyl)(naphthobenzofuranyl)anthracene; (cyanobiphenyl)(naphthobenzofuranyl)anthracene; phenyl(naphthobenzofuranyl)anthracene-d₂₂; naphthyl(naphthobenzofuranyl)anthracene-d₂₄; naphthyl(naphthobenzofuranyl)anthracene-d₂₄; (phenylnaphthyl)(naphthobenzofuranyl)anthracene-d₂₈; (phenylnaphthyl)(naphthobenzofuranyl)anthracene-d₂₈; (phenylnaphthyl)(naphthobenzofuranyl)anthracene-d₂₈; (phenylnaphthyl)(naphthobenzofuranyl)anthracene-d₂₈; binaphthyl(naphthobenzofuranyl)anthracene-d₃₀; binaphthyl(naphthobenzofuranyl)anthracene-d₃₀; biphenyl(naphthobenzofuranyl)anthracene-d₂₄; biphenyl(naphthobenzofuranyl)anthracene-d₂₄; biphenyl(naphthobenzofuranyl)anthracene-d₂₄; terphenyl(naphthobenzofuranyl)anthracene-d₂₈; terphenyl(naphthobenzofuranyl)anthracene-d₂₈; terphenyl(naphthobenzofuranyl)anthracene-d₂₈; terphenyl(naphthobenzofuranyl)anthracene-d₂₈; (phenylnaphthyl)(naphthobenzofuranyl)anthracene-d₂₈; (naphthylphenyl)(naphthobenzofuranyl)anthracene-d₂₈; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (naphthylphenyl)(naphthobenzofuranyl)anthracene-d₂₈; (naphthylphenyl)(naphthobenzofuranyl)anthracene-d₂₈; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenyl)(naphthobenzofuranyl)anthracene-d₂₆; (phenanthrenyl)(naphthobenzofuranyl)anthracene-d₂₆; phenyl(naphthobenzofuranyl)anthracene-d₁₃; naphthyl(naphthobenzofuranyl)anthracene-d₂₄; naphthyl(naphthobenzofuranyl)anthracene-d₂₄; (phenylnaphthyl)(naphthobenzofuranyl)anthracene-d₂₈; (phenylnaphthyl)(naphthobenzofuranyl)anthracene-d₂₈; (phenylnaphthyl)(naphthobenzofuranyl)anthracene-d₂₈; (phenylnaphthyl)(naphthobenzofuranyl)anthracene-d₂₈; binaphthyl(naphthobenzofuranyl)anthracene-d₃₀; binaphthyl(naphthobenzofuranyl)anthracene-d₃₀; biphenyl(naphthobenzofuranyl)anthracene-d₂₆; biphenyl(naphthobenzofuranyl)anthracene-d₂₆; biphenyl(naphthobenzofuranyl)anthracene-d₂₆; terphenyl(naphthobenzofuranyl)anthracene-d₂₈; terphenyl(naphthobenzofuranyl)anthracene-d₂₈; terphenyl(naphthobenzofuranyl)anthracene-d₂₈; terphenyl(naphthobenzofuranyl)anthracene-d₂₈; (naphthylphenyl)(naphthobenzofuranyl)anthracene-d₂₈; (naphthylphenyl)(naphthobenzofuranyl)anthracene-d₂₈; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (naphthylphenyl)(naphthobenzofuranyl)anthracene-d₂₈; (naphthylphenyl)(naphthobenzofuranyl)anthracene-d₂₈; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; (phenanthrenylphenyl)(naphthobenzofuranyl)anthracene-d₃₀; phenanthrenyl(naphthobenzofuranyl)anthracene-d₂₆; phenanthrenyl(naphthobenzofuranyl)anthracene-d₂₆; phenyl(naphthobenzofuranyl)anthracene-d₁₃; phenyl(naphthobenzofuranyl)anthracene-d₈; phenyl(naphthobenzofuranyl)anthracene-d₂; phenyl(naphthobenzofuranyl)anthracene-d₂; phenyl(naphthobenzofuranyl)anthracene-d₄; phenyl(naphthobenzofuranyl)anthracene-d₂; phenyl(naphthobenzofuranyl)anthracene-d₁; phenyl(naphthobenzofuranyl)anthracene-d₂; phenyl(naphthobenzofuranyl)anthracene-d₁; phenyl(naphthobenzofuranyl)anthracene-d₁; phenyl(naphthobenzofuranyl)anthracene-d₁; naphthyl(naphthobenzofuranyl)anthracene-d₉; biphenyl(naphthobenzofuranyl)anthracene-d₈; biphenyl(naphthobenzofuranyl)anthracene-d₈; biphenyl(naphthobenzofuranyl)anthracene-d₈; terphenyl(naphthobenzofuranyl)anthracene-d₈; terphenyl(naphthobenzofuranyl)anthracene-d₈; (naphthylphenyl)(naphthobenzofuranyl)anthracene-d₈; terphenyl(naphthobenzofuranyl)anthracene-d₈; phenyl[(naphthobenzofuranyl)phenyl]anthracene-d₂₆; naphthyl[(naphthobenzofuranyl)phenyl]anthracene-d₂₈; naphthyl[(naphthobenzofuranyl)phenyl]anthracene-d₂₈; phenanthrenyl[(naphthobenzofuranyl)phenyl]anthracene-d₃₀; biphenyl[(naphthobenzofuranyl)phenyl]anthracene-d₃₀; biphenyl[(naphthobenzofuranyl)phenyl]anthracene-d₃₀; biphenyl[(naphthobenzofuranyl)phenyl]anthracene-d₃₀; phenanthrenyl[(naphthobenzofuranyl)phenyl]anthracene-d₃₀; phenyl[(naphthobenzofuranyl)phenyl]anthracene-d₈; phenyl[(naphthobenzofuranyl)phenyl]anthracene-d₈; biphenyl[(naphthobenzofuranyl)phenyl]anthracene-d₈; phenyl[(naphthobenzofuranyl)phenyl]anthracene-d₁₃; phenyl[(naphthobenzofuranyl)phenyl]anthracene-d₁₃; phenyl(naphthobenzofuranyl)anthracene-d₅; phenyl[(naphthobenzofuranyl)phenyl]anthracene-d₅; phenyl[(naphthobenzofuranyl)phenyl]anthracene-d₅; phenyl[(naphthobenzofuranyl)phenyl]anthracene-d₅; phenyl[(naphthobenzofuranyl)naphthyl]anthracene-d₅; phenyl[(naphthobenzofuranyl)naphthyl]anthracene-d₅; phenyl[(naphthobenzofuranyl)naphthyl]anthracene-d₅; phenyl[(naphthobenzofuranyl)naphthyl]anthracene-d₅; phenyl[(naphthobenzofuranyl)naphthyl]anthracene-d₅; phenyl(naphthobenzothiophenyl)anthracene-d₅; phenyl[(naphthobenzothiophenyl)phenyl]anthracene-d₅; phenyl[(naphthobenzothiophenyl)phenyl]anthracene-d₅; phenyl[(naphthobenzothiophenyl)phenyl]anthracene-d₅; phenyl[(naphthobenzothiophenyl)naphthyl]anthracene-d₅; phenyl[(naphthobenzothiophenyl)naphthyl]anthracene-d₅; phenyl[(naphthobenzothiophenyl)naphthyl]anthracene-d₅; phenyl[(naphthobenzothiophenyl)naphthyl]anthracene-d₅; phenyl[(naphthobenzothiophenyl)naphthyl]anthracene-d₅

### (Group 35A)

diphenylanthracene; phenyl(naphthyl)anthracene; phenyl(phenanthrenyl)anthracene; dinaphthylanthracene; dinaphthylanthracene; naphthyl(phenanthrenyl)anthracene; dinaphthylanthracene; naphthyl(phenanthrenyl)anthracene; phenyl(phenanthrenyl)anthracene; phenyl(naphthyl)anthracene; diphenanthrenylanthracene; phenyl(benzanthracenyl)anthracene; naphthyl(benzanthracenyl)anthracene; naphthyl(benzotriphenylenyl)anthracene; phenyl(benzophenanthrenyl)anthracene; naphthyl(benzanthracenyl)anthracene; phenyl(benzotriphenylenyl)anthracene; naphthyl(benzophenanthrenyl)anthracene; phenyl(naphthylphenyl)anthracene; phenyl(biphenyl)anthracene; phenyl(naphthylphenyl)anthracene; phenyl(biphenyl)anthracene; phenyl(naphthylphenyl)anthracene; naphthyl(biphenyl)anthracene; naphthyl(biphenyl)anthracene; phenyl(phenylnaphthyl)anthracene; phenyl(biphenyl)anthracene; phenyl(naphthylphenyl)anthracene; phenyl(phenylnaphthyl)anthracene; naphthyl(naphthylphenyl)anthracene; naphthyl(biphenyl)anthracene; dinaphthylanthracene; naphthyl(naphthylphenyl)anthracene; naphthyl(naphthylphenyl)anthracene; naphthyl(phenylnaphthyl)anthracene; naphthyl(naphthylphenyl)anthracene; naphthyl(phenylnaphthyl)anthracene; naphthyl(naphthylphenyl)anthracene; naphthyl(biphenyl)anthracene; naphthyl(naphthylphenyl)anthracene; naphthyl(biphenyl)anthracene; naphthyl(biphenyl)anthracene; naphthyl(naphthylphenyl)anthracene; naphthyl(naphthylphenyl)anthracene; phenanthrenyl(biphenyl)anthracene; phenanthrenyl(naphthylphenyl)anthracene; phenanthrenyl(biphenyl)anthracene; phenanthrenyl(naphthylphenyl)anthracene; naphthyl(naphthylphenyl)anthracene; (phenylnaphthyl)(naphthylphenyl)anthracene; (phenylnaphthyl)(biphenyl)anthracene; (phenylnaphthyl)(naphthylphenyl)anthracene; (phenylnaphthyl)(biphenyl)anthracene; (phenylnaphthyl)(naphthylphenyl)anthracene; (phenylnaphthyl)(naphthylphenyl)anthracene; (phenylnaphthyl)(naphthylphenyl)anthracene; benzophenanthrenyl(phenylnaphthyl)anthracene; (benzophenanthrenylphenyl)(biphenyl)anthracene; benzophenanthrenyl(biphenyl)anthracene; naphthyl(benzophenanthrenylphenyl)anthracene; benzophenanthrenyl(naphthylphenyl)anthracene; benzophenanthrenyl(biphenyl)anthracene; (benzophenanthrenylphenyl)(biphenyl)anthracene; benzophenanthrenyl(phenylnaphthyl)anthracene; phenyl(benzophenanthrenylphenyl)anthracene; benzophenanthrenyl(biphenyl)anthracene; naphthyl(benzophenanthrenylphenyl)anthracene; benzotriphenylenyl(biphenyl)anthracene; benzotriphenylenyl(phenylnaphthyl)anthracene; (benzotriphenylenylphenyl)(naphthylphenyl)anthracene; benzophenanthrenyl(naphthylphenyl)anthracene; benzotriphenylenyl(naphthylphenyl)anthracene; benzotriphenylenyl(phenanthrenyl)anthracene; benzotriphenylenyl(naphthylphenyl)anthracene; benzotriphenylenyl(naphthylphenyl)anthracene; benzotriphenylenyl(biphenyl)anthracene; benzotriphenylenyl(naphthylphenyl)anthracene; benzotriphenylenyl(biphenyl)anthracene; benzanthracenyl(naphthylphenyl)anthracene; benzanthracenyl(biphenyl)anthracene; naphthyl(phenanthrenyl)anthracene-d₂₄; phenyl(naphthyl)anthracene-d₂₀; dinaphthylanthracene-d₂₂; naphthyl(biphenyl)anthracene-d₂₄; naphthyl(phenanthrenyl)anthracene-d₂₄; naphthyl(biphenyl)anthracene-d₂₄; naphthyl(phenanthrenyl)anthracene-d₂₄; naphthyl(phenanthrenyl)anthracene-d₂₄; naphthyl(phenanthrenyl)anthracene-d₂₄; naphthyl(biphenyl)anthracene-d₂₄; naphthyl(phenanthrenylphenyl)anthracene-d₂₈; naphthyl(phenanthrenylphenyl)anthracene-d₂₈; naphthyl(phenanthrenylphenyl)anthracene-d₂₈; naphthyl(terphenyl)anthracene-d₂₈; naphthyl(naphthylphenyl)anthracene-d₂₆; naphthyl(phenanthrenylphenyl)anthracene-d₂₈; naphthyl(terphenyl)anthracene-d₂₈; naphthyl(terphenyl)anthracene-d₂₈; naphthyl(naphthylphenyl)anthracene-d₂₆; naphthyl(naphthylphenyl)anthracene-d₂₆; naphthyl(phenanthrenylphenyl)anthracene-d₂₈; naphthyl(terphenyl)anthracene-d₂₈; naphthyl(naphthylphenyl)anthracene-d₂₆; naphthyl(phenanthrenylphenyl)anthracene-d₂₈; naphthyl(binaphthyl)anthracene-d₂₈; naphthyl(phenylnaphthyl)anthracene-d₂₆; naphthyl(phenylnaphthyl)anthracene-d₂₆; naphthyl(binaphthyl)anthracene-d₂₈; naphthyl(phenanthrenyl)anthracene-d₂₄; phenyl(naphthyl)anthracene-d₂₀; dinaphthylanthracene-d₂₂; dinaphthylanthracene-d₂₂; naphthyl(biphenyl)anthracene-d₂₄; naphthyl(phenanthrenyl)anthracene-d₂₄; naphthyl(biphenyl)anthracene-d₂₄; naphthyl(phenanthrenyl)anthracene-d₂₄; naphthyl(phenanthrenyl)anthracene-d₂₄; naphthyl(biphenyl)anthracene-d₂₄; naphthyl(phenanthrenylphenyl)anthracene-d₂₈; naphthyl(terphenyl)anthracene-d₂₈; naphthyl(naphthylphenyl)anthracene-d₂₆; naphthyl(phenanthrenylphenyl)anthracene-d₂₈; naphthyl(terphenyl)anthracene-d₂₈; naphthyl(terphenyl)anthracene-d₂₈; naphthyl(naphthylphenyl)anthracene-d₂₆; naphthyl(naphthylphenyl)anthracene-d₂₆; naphthyl(phenanthrenylphenyl)anthracene-d₂₈; naphthyl(terphenyl)anthracene-d₂₈; naphthyl(naphthylphenyl)anthracene-d₂₆; naphthyl(phenanthrenylphenyl)anthracene-d₂₈; phenanthrenyl(phenanthrenylphenyl)anthracene-d₃₀; phenyl(phenanthrenyl)anthracene-d₂₂; phenanthrenyl(naphthylphenyl)anthracene-d₂₈; diphenanthrenylanthracene-d₂₆; phenanthrenyl(biphenyl)anthracene-d₂₆; diphenanthrenylanthracene-d₂₆; phenanthrenyl(naphthylphenyl)anthracene-d₂₈; phenanthrenyl(phenanthrenylphenyl)anthracene-d₃₀; phenyl(phenanthrenyl)anthracene-d₂₂; phenanthrenyl(naphthylphenyl)anthracene-d₂₈; diphenanthrenylanthracene-d₂₆; phenanthrenyl(biphenyl)anthracene-d₂₆; diphenylanthracene-d₁₈; bis(naphthylphenyl)anthracene-d₃₀; phenyl(naphthylphenyl)anthracene-d₂₄; phenyl(phenylnaphthyl)anthracene-d₂₄; naphthyl(phenylphenyl)anthracene-d₂₆; phenyl(phenylnaphthyl)anthracene-d₂₄; naphthyl(naphthylphenyl)anthracene-d₈; phenyl(naphthylphenyl)anthracene-d₈; naphthyl(naphthylphenyl)anthracene-d₈; naphthyl(phenanthrenylphenyl)anthracene-d₈; phenyl(phenanthrenylphenyl)anthracene-d₈; naphthyl(phenanthrenylphenyl)anthracene-d₈; naphthyl(biphenyl)anthracene-d₈; phenyl(biphenyl)anthracene-d₈; naphthyl(biphenyl)anthracene-d₈; naphthyl(phenanthrenylphenyl)anthracene-d₈; phenyl(phenanthrenylphenyl)anthracene-d₈; naphthyl(phenanthrenylphenyl)anthracene-d₈; naphthyl(phenanthrenyl)anthracene-d₈; phenyl(phenanthrenyl)anthracene-d₈; naphthyl(phenanthrenyl)anthracene-d₈; naphthyl(biphenyl)anthracene-d₈; phenyl(biphenyl)anthracene-d₈; naphthyl(biphenyl)anthracene-d₈; naphthyl(naphthylphenyl)anthracene-d₈; naphthyl(naphthylphenyl)anthracene-d₈; naphthyl(naphthylphenyl)anthracene-d₈; naphthyl(phenyl)anthracene-d₈; diphenylanthracene-d₈; naphthyl(phenyl)anthracene-d₈; phenyl(phenylnaphthyl)anthracene-d₈; naphthyl(naphthylphenyl)anthracene-d₈; naphthyl(naphthylphenyl)anthracene-d₈; naphthyl(phenanthrenylphenyl)anthracene-d₈; phenyl(phenylnaphthyl)anthracene-d₈; phenyl(phenylnaphthyl)anthracene-d₈; naphthyl(naphthylphenyl)anthracene-d₈; dinaphthylanthracene-d₁₅; naphthyl(biphenyl)anthracene-d₁₅; naphthyl(phenanthrenyl)anthracene-d₁₅; naphthyl(naphthylphenyl)anthracene-d₁₅; naphthyl(naphthylphenyl)anthracene-d₁₅; naphthyl(naphthylphenyl)anthracene-d₁₅; naphthyl(phenanthrenylphenyl)anthracene-d₁₅; naphthyl(naphthylphenyl)anthracene-d₁₅; naphthyl(naphthylphenyl)anthracene-d₁₉; naphthyl(naphthylphenyl)anthracene-d₁₉; naphthyl(naphthylphenyl)anthracene-d₁₉; naphthyl(naphthylphenyl)anthracene-d₁₉; naphthyl(naphthylphenyl)anthracene-d₁₇; naphthyl(naphthylphenyl)anthracene-d₁₇; naphthyl(phenanthrenylphenyl)anthracene-d₁₇; naphthyl(naphthylphenyl)anthracene-d₁₉; naphthyl(naphthylphenyl)anthracene-d₁₉; dinaphthylanthracene-d₁₄; naphthyl(biphenyl)anthracene-d₄; dinaphthylanthracene-d₁₄; naphthyl(biphenyl)anthracene-d₄; phenyl(triphenylenyl)anthracene-d₈; phenyl(benzophenanthrenyl)anthracene-d₈; phenyl(benzanthracenyl)anthracene-d₈; phenyl(benzotriphenylenyl)anthracene-d₈; triphenylenyl(naphthylphenyl)anthracene-d₈; benzophenanthrenyl(naphthylphenyl)anthracene-d₈; benzanthracenyl(naphthylphenyl)anthracene-d₈; benzotriphenylenyl(naphthylphenyl)anthracene-d₈; triphenylenyl(naphthylphenyl)anthracene-d₈; benzophenanthrenyl(naphthylphenyl)anthracene-d₈; benzanthracenyl(naphthylphenyl)anthracene-d₈; benzotriphenylenyl(naphthylphenyl)anthracene-d₈; triphenylenyl(biphenyl)anthracene-d₈; benzophenanthrenyl(biphenyl)anthracene-d₈; benzanthracenyl(biphenyl)anthracene-d₈; benzotriphenylenyl(biphenyl)anthracene-d₈; naphthyl(benzophenanthrenyl)anthracene-d₂₆; naphthyl(benzophenanthrenyl)anthracene-d₁₅; phenyl(benzophenanthrenyl)anthracene-d₂₄; phenyl(benzophenanthrenyl)anthracene-d₁₃

In one embodiment, as the first organic compound and the second organic compound, one or more compounds corresponding to the compounds C1 to C3 in compounds selected from compounds included in each group of the following (Group 1B) to (Group 35B) can be independently used. The first organic compound and the second organic compound in the present specification may not independently be one or more compounds selected from compounds included in each group of the following (Group 1B) to (Group 35B).

### (Group 1B)

9,10-di(2-naphthyl)anthracene)(ADN); 2-tert-butyl-9,10-di(2-naphthyl)anthracene(TBADN); 5,6,11,12-tetraphenyltetracene(rubrene); 2,5,8,11-tetra-tert-butylperylene(TBP)

### (Group 2B)

4,4′-bis[(1-naphthyl)-N-phenylamino]biphenyl(NBP); 5,6,11,12-tetraphenyltetracene(rubrene); 9,10-bis[N-(1-phenylamino)biphenyl]; 2,5,8,11-tetra-tert-butylperylene(TBP); tris(8-quinolinolato-N1,O8)aluminum(Alq); coumarinC545T

### (Group 3B)

N,N′-di(1-naphthyl)-N,N′-diphenyl-(1,1′-biphenyl)-4,4′-diamine(NPD); Alq3; 10-(2-benzothiazolyl)-1,1,7,7-tetramethyl-2,3,6,7-tetrahydro-1H,5H,11H-[1]benzopyrano[6,7,8-ij]quinolizine-11-one(C545T); rubrene(5,6,11,12-tetraphenyltetracene); 4,4′-bis(2,2-diphenylvinyl)biphenyl(DPVBi)

### (Group 4B)

TBADN; TBP

### (Group 5B)

TBADN; Alq3; TBP; 5,6,11,12-tetraphenyltetracene(rubrene); 4-(dicyanomethylene)-2-tert-butyl-6-(1,1,7,7-tetramethyljulolidine-4-yl-vinyl)-4H-pyran(DCJTB)

### (Group 6B)

tetracene; tetrafluoro-tetracyano-quinodimethane(F4-TCNQ); 4,4′,4″-tris[phenyl(m-tolyl)amino]triphenylamine; naphthalenetetracarboxylic anhydride(NTCDA); leuco crystal violet(LCV); N,N′-bis(3-methylphenyl)-N,N′-bis(phenyl)-benzidine(TPD)

### (Group 9B)

1-(2,2′-binaphthalene-6-yl)-3-(phenanthrene-9-yl)benzene; iridium(III)bis(2-phenylquinolyl-N,C²′)acetylacetonate; 9-{3-[6-phenyl-2-phenylpyrimidine-4-yl]-5-(9H-carbazole-9-yl)phenyl}-9H-carbazole; tris[2-phenylpyridinate-C²,N]iridium(III)

### (Group 10B)

1,3-di(9H-carbazole-9-yl)benzene; [2,2′-bis(2′,4′-difluoro-2,3′-bipyridinato-2-yl)propane-C,N,N,C]platinum(II); 4,4′,4″-tris(N,N-(2-naphthyl)-phenylamino)triphenylamine(2-TNATA); 2,3,5,6-tetrafluoro-7,7,8,8-tetracyano-quinodimethane(F4-TCNQ); 3,3′-di(9H-carbazole-9-yl)-1,1′-biphenyl; [2-(2′,4′-difluoro-2,3′-bipyridinato-2-yl)-2-{6-(5-trifluoromethyl-1H-pyrazole-1-yl)pyridinato-2-yl-C,N,N,C}propane-C,N,N,C]platinum(II); [2,2′-bis(2,3′-bipyridinato-2-yl)propane-C,N,N,C]platinum(II); iridium(III)bis(2-phenylquinolyl-N,C²′)acetylacetonate; 9,10-di(2-naphthyl)anthracene; 2,5,8,11-tetra-tert-butylperylene; 10-(2-benzothiazolyl)-1,1,7,7-tetramethyl-11-oxo-1,2,3,5,6,7-hexahydro-11H-[1]benzopyrano[6,7,8-ij]quinolizine-9-id; 2-[6-[2-[(2,3,6,7-tetrahydro-1H,5H-benzo[ij]quinolizine)-9-yl]ethenyl]-2-methyl-4H-pyran-4-ylidene]propanedinitrile

### (Group 12B)

2-{4′-triphenylenyl-[1,1′-biphenyl]-3-yl}-4,6-diphenyl-1,3,5-triazine; 9-[4,6-diphenyl-2-pyridyl]-9′-phenyl-3,3′-bis[9H-carbazole]; 9-(1,1′-biphenyl-3-yl)-9′-(1,1′-biphenyl-4-yl)-3,3′-bis[9H-carbazole]

### (Group 13B)

9-[3′-(triphenylene-2-yl)-1,1′-biphenyl]-9H-carbazole; 11-(4,6-diphenyl-1,3,5-triazine-2-yl)-12-(4′-phenyl-1,1′-biphenyl-4-yl)-11H,12H-indolo[2,3-a]carbazole

### (Group 14B)

2-(1-(1,1′-biphenyl-4-yl)-9H-carbazole-9-yl)-4,6-diphenyl-1,3,5-triazine; iridium(III)bis(2-(3,5-dimethylphenyl)-5-(2-methylpropyl)quinolyl-N,C²′)acetylacetonate; 2-(1-(9,9′-dimethylfluorene-2-yl)-9H-carbazole-9-yl)-4,6-diphenyl-1,3,5-triazine; iridium(III)bis(2-(3,5-dimethylphenyl)quinolyl-N,C²′)acetylacetonate; 2-(1-phenyl-9H-carbazole-9-yl)-4-(9,9′-dimethylfluorene-2-yl)-6-phenyl-1,3,5-triazine; iridium(III)bis(2-(3,5-dimethylphenyl)quinolyl-N,C²′)2,2,8,8-tetramethyl-4,6-nonanedionate; 2-(1-(1,1′-biphenyl-4-yl)-9H-carbazole-9-yl)-4,6-diphenyl-1,3,5-triazine; iridium(III)bis(2-(3,5-dimethylphenyl)-7-(2-methylpropyl)quinolyl-N,C²′)acetylacetonate; 2-(1-phenyl-9H-carbazole-9-yl)-4-(9,9′-dimethylfluorene-2-yl)-6-phenyl-1,3,5-triazine; iridium(III)bis(2-(3,5-dimethylphenyl)-5-cyclopentylquinolyl-N,C²′)acetylacetonate; 2-(1-(1,1′-biphenyl-3-yl)-9H-carbazole-9-yl)-4,6-diphenyl-1,3,5-triazine; iridium(III)bis(2-(3,5-dimethylphenyl)-6-(2-methylpropyl)quinolyl-N,C²′)acetylacetonate; 11-(1,1′-biphenyl-4-yl)-12-(4,6-diphenyl-1,3,5-triazine-2-yl)-11H,12H-indolo[2,3-a]carbazole; iridium(III)bis(2-phenylpyridyl-N,C²′)(4-methyl-5-(4-fluorophenyl)-2-phenylpyridyl-N,C2′); 11-phenyl-12-(4-(1,1′-biphenyl-4-yl)-6-phenyl-1,3,5-triazine-2-yl)-11H,12H-indolo[2,3-a]carbazole; iridium(III)bis(2-phenylpyridyl-N,C²′)(2,5-diphenylpyridyl-N,C2′); 12-(4,6-diphenyl-1,3,5-triazine-2-yl)-12H-[1]benzothieno[2,3-a]carbazole; iridium(III)bis(2-phenylpyridyl-N,C²′)(4-isopropyl-2,5-diphenylpyridyl-N,C2′); 11-phenyl-12-(4-(9,9-dimethylfluorene-2-yl)-6-phenyl-1,3,5-triazine-2-yl)-11H,12H-indolo[2,3-a]carbazole; iridium(III)bis(2-phenylpyridyl-N,C²′)(5-(4-fluorophenyl)-2-phenylpyridyl-N,C2′); 5-phenyl-11-(4,6-diphenyl-1,3,5-triazine-2-yl)-5H,11H-indolo[3,2-b]carbazole; iridium(III)bis(2-phenylpyridyl-N,C²′)(4-methyl-2,5-diphenylpyridyl-N,C2′); iridium(III)bis(2-phenylpyridyl-N,C²′)(4-(methyl-d₃)-2,5-diphenylpyridyl-N,C2′); 5-phenyl-11-(4-(9,9-dimethylfluorene-2-yl)-6-phenyl-1,3,5-triazine-2-yl)-5H,11H-indolo[3,2-b]carbazole; iridium(III)bis(2-phenylpyridyl-N,C²′)(4-(4-methylphenyl)-2-phenylpyridyl-N,C2′); 2-(7,7-dimethylindeno[2,1-b]carbazole-5-yl)-4-(1,1′-biphenyl-4-yl)-6-phenyl-1,3,5-triazine; iridium(III)bis(2-phenylpyridyl-N,C²′)(4-(4-fluorophenyl)-2-phenylpyridyl-N,C2′); 5-phenyl-12-(4,6-diphenyl-1,3,5-triazine-2-yl)-5H,12H-indolo[3,2-a]carbazole; iridium(III)bis(5-methyl-2-phenylpyridyl-N,C²′)(4-methyl-2,5-diphenylpyridyl-N,C2′); iridium(III)bis(5-(methyl-d₃)-2-phenylpyridyl-N,C²′)(4-(methyl-d₃)-5-phenyl-2-phenylpyridyl-N,C2′)

### (Group 15B)

4-[3-(triphenylene-2-yl)phenyl]-6-phenyldibenzothiophene; 2-(6-(1,1′-biphenyl-4-yl)-dibenzothiophene4-yl)-4,6-diphenyl-1,3,5-triazine; iridium(III)bis(2-phenylpyridyl-N,C²′)(4-methyl-2,5-diphenylpyridyl-N,C2′); 2-(6-(4′-phenyl-1,1′-biphenyl-3-yl)-dibenzothiophene4-yl)-4,6-diphenyl-1,3,5-triazine; 2-{3-(6-(4′-phenyl-1,1′-biphenyl-3-yl)-dibenzothiophene4-yl)phenyl}-4,6-diphenyl-1,3,5-triazine; 2-{3-(6-(1,1′-biphenyl-3-yl)-dibenzothiophene4-yl)phenyl}-4,6-diphenyl-1,3,5-triazine; 2-{3-(dibenzothiophene4-yl)phenyl}-4,6-diphenyl-1,3,5-triazine; 2-{3-(dibenzothiophene4-yl)-5-(1,1′-biphenyl-4-yl)-phenyl}-4,6-diphenyl-1,3,5-triazine; 2-{3-(dibenzothiophene4-yl)-5-(9,9-dimethylfluorene-2-yl)-phenyl}-4,6-diphenyl-1,3,5-triazine; 2-{3-(6-(1,1′-biphenyl-4-yl)-dibenzothiophene4-yl)phenyl}-4,6-diphenyl-1,3,5-triazine; 2,4,6-tri(1,1′-biphenyl-4-yl)-1,3,5-triazine; 2,4-bis(triphenyl4-yl)-6-phenyl-1,3,5-triazine; 2-(3-(3-pyridyl)-5-(phenanthrene-9-yl)-phenyl)-4,6-diphenyl-1,3,5-triazine; 2-(9,9-dimethylfluorene-2-yl)-4,6-bis(1,1′-biphenyl-3-yl)-1,3,5-triazine; 2-(3-(dibenzothiophene4-yl)-phenyl)-4,6-bis(1,1′-biphenyl-3-yl)-1,3,5-triazine; 2-(3-(9-(2-pyridyl)-9H-carbazole-3-yl)-5-(dibenzothiophene4-yl)-phenyl)-4,6-diphenyl-1,3,5-triazine; 2-(9H-carbazole-9-yl)-4-phenyl-6-(triphenylene-2-yl)-1,3,5-triazine; 2-{5-(6-phenyl-dibenzofuran-4-yl)-1,1′-biphenyl3-yl}-4,6-diphenyl-1,3,5-triazine; 2-{5-(6-phenyldibenzothiophene4-yl)-1,1′-biphenyl-3-yl}-4,6-diphenyl-1,3,5-triazine; 2-{5-(6-(1,1′-biphenyl-4-yl)-dibenzothiophene4-yl)-1,1′-biphenyl-3-yl}-4,6-diphenyl-1,3,5-triazine; 2-{5-(6-(1,1′-biphenyl-3-yl)-dibenzothiophene4-yl)-1,1′-biphenyl3-yl}-4,6-diphenyl-1,3,5-triazine; 2-(5-(dibenzothiophene4-yl)-1,1′-biphenyl-3-yl)-4-(1,1′-biphenyl-4-yl)-6-phenyl-1,3,5-triazine; 2-(5-(dibenzothiophene4-yl)-1,1′-biphenyl-3-yl)-4-(9,9-dimethylfluorene-2-yl)-6-phenyl-1,3,5-triazine; 2-(5-(6-phenyldibenzothiophene4-yl)-1,1′-biphenyl-3-yl)-4-(9,9-dimethylfluorene-2-yl)-6-phenyl-1,3,5-triazine; 2-{3′-phenyl-5′-(dibenzothiophene4-yl)-1,1′-biphenyl-3-yl}-4,6-diphenyl-1,3,5-triazine; 2-{5-phenyl-5′-(dibenzothiophene4-yl)-1,1′-biphenyl-3-yl}-4,6-diphenyl-1,3,5-triazine; 2-{5-(9,9-dimethylfluorene-2-yl)-4′-phenyl-1,1′-biphenyl-3-yl}-4,6-diphenyl-1,3,5-triazine; 2-{3,5-bis(9,9-dimethylfluorene-2-yl)-phenyl}-4,6-diphenyl-1,3,5-triazine; 2-(3-(6-phenyldibenzothiophene4-yl)-phenyl)-4-(1,1′-biphenyl-3-yl)-6-phenyl-1,3,5-triazine; 2-{4-(6-phenyldibenzothiophene4-yl)-phenyl}-4,6-diphenyl-1,3,5-triazine; 2-{3′-(6-phenyldibenzothiophene4-yl)-1,1′-biphenyl-4-yl}-4,6-diphenyl-1,3,5-triazine; 2-{4′-(6-phenyldibenzothiophene4-yl)-1,1′-biphenyl-3-yl}-4,6-diphenyl-1,3,5-triazine; 2-(6-(1,1′-biphenyl-4-yl)-dibenzothiophene4-yl)-4-(1,1′-biphenyl-3-yl)-6-phenyl-1,3,5-triazine; 2-{4-(6-(1,1′-biphenyl-4-yl)-dibenzothiophene4-yl)-phenyl}-4,6-diphenyl-1,3,5-triazine; 2-{4-(6-(1,1′-biphenyl-3-yl)-dibenzothiophene4-yl)-phenyl}-4,6-diphenyl-1,3,5-triazine; 2-(6-phenyldibenzothiophene4-yl)-4-(9,9-dimethylfluorene-2-yl)-6-phenyl-1,3,5-triazine; 2-{(6-(1,1′-biphenyl-4-yl)-dibenzothiophene4-yl}-4-(9,9-dimethylfluorene-2-yl)-6-phenyl-1,3,5-triazine; 2-{3-(6-(1,1′-biphenyl-4-yl)-dibenzothiophene4-yl)-phenyl}-4-(9,9-dimethylfluorene-2-yl)-6-phenyl-1,3,5-triazine; 2-{3-(2,7-diphenyldibenzothiophene4-yl)-phenyl}-4,6-diphenyl-1,3,5-triazine; 2-{4′-(6-(1,1′-biphenyl-4-yl)-dibenzothiophene4-yl)-1,1′-biphenyl-3-yl}-4,6-diphenyl-1,3,5-triazine; 2-(9,9-dimethylfluorene-2-yl)-4,6-bis(4′-phenyl-1,1′-biphenyl-3-yl)-1,3,5-triazine; 2-(dibenzothiophene4-yl)-4-(9,9-dimethylfluorene-2-yl)-6-(4′-phenyl-1,1′-biphenyl-3-yl)-1,3,5-triazine; 2-[3′-(triphenylene-2-yl)-1,1′-biphenyl-4-yl]-4,6-diphenyl-1,3,5-triazine; 2-[4′-(dibenzofuran-4-yl)-1,1′-biphenyl-3-yl]-4,6-diphenyl-1,3,5-triazine; 4-(triphenylene-2-yl)-dibenzofuran; 4-(triphenylene-2-yl)-dibenzothiophene; 4-(3-(triphenylene-2-yl)phenyl)-dibenzothiophene; 4-(3-phenyl-5-(triphenylene-2-yl)phenyl)-dibenzothiophene; 4-(1,1′-biphenyl-4-yl)-5-(triphenylene-2-yl)-dibenzothiophene; 4-(9H-carbazole-9-yl)-5-(triphenylene-2-yl)-dibenzofuran; 4-(9H-carbazole-9-yl)-5-(triphenylene-2-yl)-dibenzothiophene; 9-(3′-(triphenylene-2-yl)-1,1′-biphenyl-3-yl)-9H-carbazole; 9-(3′-(triphenylene-2-yl)-1,1′-biphenyl-4-yl)-9H-carbazole; [2-{3-(triphenylene-2-yl)phenyl}pyridine-3-yl]-9H-carbazole; 2-(6-phenyldibenzofuran-4-yl)-4,6-diphenyl-1,3,5-triazine; 2-(6-phenyldibenzothiophene4-yl)-4,6-diphenyl-1,3,5-triazine; 2-(6-(1,1′-biphenyl-4-yl)dibenzothiophene4-yl)-4,6-diphenyl-1,3,5-triazine; 2-[3-(6-(1,1′-biphenyl-4-yl)dibenzofuran-4-yl)phenyl]-4,6-diphenyl-1,3,5-triazine; 2-(6-phenyldibenzothiophene4-yl)-4,6-bis(1,1′-biphenyl-3-yl)-1,3,5-triazine; 2-[3-(6-(1,1′-biphenyl-4-yl)dibenzofuran-4-yl)phenyl]-4,6-bis(phenyl-d5)-1,3,5-triazine; 2-{3-(dibenzothiophene4-yl)-5-(1,1′-biphenyl-4-yl)phenyl}-4,6-diphenyl-1,3,5-triazine; 9-[3-(9-(4′-phenyl-1,1′-biphenyl-3-yl)-9H-carbazole-3-yl)phenyl]-9H-carbazole; 9-[3-(9-(4′-phenyl-1,1′-biphenyl-3-yl)-9H-carbazole-2-yl)phenyl]-9H-carbazole; 9-[3-(9-(triphenylene-2-yl)-9H-carbazole-3-yl)phenyl]-9H-carbazole; 9-[3-(9-(triphenylene-2-yl)-9H-carbazole-2-yl)phenyl]-9H-carbazole; 9-[3-(9-(dibenzothiophene4-yl)-9H-carbazole-3-yl)phenyl]-9H-carbazole; 2-(dibenzofuran-4-yl)-4-(1,1′-biphenyl-4-yl)-6-(4′-phenyl-1,1′-biphenyl-3-yl)-1,3,5-triazine; 2-(dibenzothiophene4-yl)-4-(1,1′-biphenyl-4-yl)-6-(4′-phenyl-1,1′-biphenyl-3-yl)-1,3,5-triazine; 2-(dibenzothiophene4-yl)-4-(9,9-dimethylfluorene-2-yl)-6-(4′-phenyl-1,1′-biphenyl-3-yl)-1,3,5-triazine; 2-(biphenylene-3-yl)-4-(9,9-dimethylfluorene-2-yl)-6-(4′-phenyl-1,1′-biphenyl-3-yl)-1,3,5-triazine

### (Group 16B)

11-(4-(1,1′-biphenyl-4-yl)-6-phenyl-1,3,5-triazine-2-yl)-12-phenyl-11H,12H-indolo[2,3-a]carbazole; 5-phenyl-12-(6-(9H-carbazole-9-yl)pyridine-2-yl)-5H,12H-indolo[3,2-a]carbazole; 5-(9-phenylcarbazole-3-yl)-12-phenyl-5H,12H-indolo[3,2-a]carbazole; 2-(3-(triphenylene-2-yl)phenyl)-dibenzothiophene; 5,11-bis(2-phenyl-pyridinyl-6-yl)-5H,11H-indolo[3,2-b]carbazole; 3,3′-di(9H-carbazole-9-yl)-1,1′-biphenyl

### (Group 17B)

9-(dibenzothiophene4-yl)-9′-phenyl-3,3′-bi[9H-carbazole]; 2-[3-(6-(1,1′-biphenyl-4-yl)dibenzofuran-4-yl)phenyl]-4,6-diphenyl-1,3,5-triazine; 2-[3-(6-(1,1′-biphenyl-4-yl)dibenzofuran-4-yl)phenyl]-4,6-bis(phenyl-d5)-1,3,5-triazine

### (Group 18B)

5-(1,1′-biphenyl-4-yl)-8-(4′-phenyl-1,1′-biphenyl-4-yl)-5H,8H-indolo[2,3-c]carbazole; iridium(III)bis(2-phenylpyridyl-N,C²′)(4-methyl-2,5-diphenylpyridyl-N,C2′); 5,8-bis(1,1′-biphenyl-4-yl)-5H,8H-indolo[2,3-c]carbazole; 5-(4′-phenyl-1,1′-biphenyl-3-yl)-12-(9,9-dimethylfluorene-2-yl)-5H,12H-indolo[3,2-a]carbazole; 5-(1,1′-biphenyl-4-yl)-12-(9,9-dimethylfluorene-2-yl)-5H,12H-indolo[3,2-a]carbazole; 2-{3-(dibenzothiophene4-yl)-5-(1,1′-biphenyl-4-yl)-phenyl}-4,6-diphenyl-1,3,5-triazine; 5-(1,1′-biphenyl-4-yl)-8-(4′-phenyl-1,1′-biphenyl-3-yl)-5H,8H-indolo[2,3-c]carbazole; 5-(4′-phenyl-1,1′-biphenyl-4-yl)-8-(1,1′-biphenyl-3-yl)-5H,8H-indolo[2,3-c]carbazole; 2-{5-(6-phenyldibenzothiophene4-yl)-1,1′-biphenyl-3-yl}-4,6-diphenyl-1,3,5-triazine; 5-(4′-phenyl-1,1′-biphenyl-4-yl)-12-(1,1′-biphenyl-4-yl)-5H,12H-indolo[3,2-a]carbazole; 5-(4′-phenyl-1,1′-biphenyl-3-yl)-8-(dibenzothiophene4-yl)-5H,8H-indolo[2,3-c]carbazole; 2-{5-(6-(1,1′-biphenyl-4-yl)dibenzothiophene4-yl)-1,1′-biphenyl-3-yl}-4,6-diphenyl-1,3,5-triazine; 5-(4′-phenyl-1,1′-biphenyl-4-yl)-8-(triphenylene-2-yl)-5H,8H-indolo[2,3-c]carbazole; 5-(4′-phenyl-1,1′-biphenyl-4-yl)-8-(3-(dibenzothiophene4-yl)phenyl)-5H,8H-indolo[2,3-c]carbazole; 5-(4′-phenyl-1,1′-biphenyl-3-yl)-8-(3-(9H-carbazole-9-yl)phenyl)-5H,8H-indolo[2,3-c]carbazole; 5-(4′-phenyl-1,1′-biphenyl-4-yl)-8-(dibenzofuran-2-yl)-5H,8H-indolo[2,3-c]carbazole; 5-(4′-phenyl-1,1′-biphenyl-4-yl)-12-(4′-phenyl-1,1′-biphenyl-3-yl)-5H,12H-indolo[3,2-a]carbazole; 2-{3-(6-(1,1′-biphenyl-4-yl)dibenzothiophene4-yl)phenyl}-4,6-diphenyl-1,3,5-triazine; 5-(4′-(phenyl-d5)-1,1′-biphenyl-4-yl)-8-(phenyl-d5)-5H,8H-indolo[2,3-c]carbazole; 5-(4′-phenyl-1,1′-biphenyl-3-yl)-12-phenyl-5H,12H-indolo[3,2-a]carbazole; 2-{4-(6-(1,1′-biphenyl-4-yl)dibenzothiophene4-yl)phenyl}-4,6-diphenyl-1,3,5-triazine; 2-{3-(6-(1,1′-biphenyl-4-yl)dibenzothiophene4-yl)phenyl}-4,6-bis(phenyl-d5)-1,3,5-triazine; 5-(3′-(phenyl-d5)-1,1′-biphenyl-4-yl)-8-(phenyl-d5)-5H,8H-indolo[2,3-c]carbazole; 2-{3-(6-(9,9-dimethylfluorene-2-yl)dibenzothiophene4-yl)phenyl}-4,6-diphenyl-1,3,5-triazine; 5-(4′-phenyl-1,1′-biphenyl-4-yl)-12-phenyl-5H,12H-indolo[3,2-a]carbazole; 2-{5-(6-(9,9-dimethylfluorene-2-yl)dibenzothiophene4-yl)-1,1′-biphenyl-3-yl}-4,6-diphenyl-1,3,5-triazine; 5-(4′-phenyl-1,1′-biphenyl-3-yl)-12-(triphenylene-2-yl)-5H,12H-indolo[3,2-a]carbazole

### (Group 19B)

11-(4-(1,1′-biphenyl-4-yl)-6-phenyl-1,3,5-triazine-2-yl)-12-phenyl-11H,12H-indolo[2,3-a]carbazole; 9-(2-naphthyl)-9′-phenyl-3,3′-bis[9H-carbazole]; 11-(4,6,-bis(1,1′-biphenyl-4-yl)-1,3,5-triazine-2-yl)-12-phenyl-11H,12H-indolo[2,3-a]carbazole; 9-(9-phenanthrenyl)-9′-phenyl-3,3′-bis[9H-carbazole]

### (Group 20B)

2-{5-(dibenzothiophene4-yl)-4′-phenyl-1,1′-biphenyl-3-yl}-4,6-diphenyl-1,3,5-triazine; 2-{5-(6-phenyldibenzothiophene4-yl)-1,1′-biphenyl-3-yl}-4,6-diphenyl-1,3,5-triazine; 2-{5-(6-(1,1′-biphenyl-4-yl)dibenzothiophene4-yl)-1,1′-biphenyl-3-yl}-4,6-diphenyl-1,3,5-triazine; 2-{5-(6-(1,1′-biphenyl-3-yl)dibenzothiophene4-yl)-1,1′-biphenyl-3-yl}-4,6-diphenyl-1,3,5-triazine; 2-{3-(6-(1,1′-biphenyl-4-yl)dibenzothiophene4-yl)phenyl}-4,6-diphenyl-1,3,5-triazine; 2-{4-(6-(1,1′-biphenyl-4-yl)dibenzothiophene4-yl)phenyl}-4,6-diphenyl-1,3,5-triazine; 2-{3-(6-(1,1′-biphenyl-4-yl)dibenzothiophene4-yl)phenyl}-4,6-bis(phenyl-d₅)-1,3,5-triazine; 2-{3-(6-(9,9-dimethylfluorene-2-yl)dibenzothiophene4-yl)phenyl}-4,6-diphenyl-1,3,5-triazine; 2-{5-(6-(9,9-dimethylfluorene-2-yl)dibenzothiophene4-yl)-1,1′-biphenyl-3-yl}-4,6-diphenyl-1,3,5-triazine; 6,6′,9,9′-tetraphenyl-3,3′-bis[9H-carbazole]; 9-(9,9-dimethylfluorene-2-yl)-9′-phenyl-3,3′-bis[9H-carbazole]; 9-(1,1′-biphenyl-4-yl)-9′-phenyl-3,3′-bis[9H-carbazole]; 9-phenyl-9′-(triphenylene-2-yl)-3,3′-bis[9H-carbazole]; 9-(1,1′-biphenyl-4-yl)-9′-(dibenzothiophene2-yl)-3,3′-bis[9H-carbazole]; 9-(dibenzothiophene2-yl)-9′-(9,9-dimethylfluorene-2-yl)-3,3′-bis[9H-carbazole]; 9,9′-bis(1,1′-biphenyl-4-yl)-3,3′-bis[9H-carbazole]; 9-(dibenzothiophene2-yl)-9′-phenyl-3,3′-bis[9H-carbazole]; 9-(dibenzothiophene4-yl)-9′-phenyl-3,3′-bis[9H-carbazole]; 9-(dibenzothiophene4-yl)-9′-phenyl-3,4′-bis[9H-carbazole]

### (Group 21B)

4-{3-(1,1′-biphenyl-4-yl)phenyl}-6-phenyl-dibenzothiophene; 2-{3-(6-(1,1′-biphenyl-4-yl)dibenzothiophene4-yl)phenyl}-4,6-diphenyl-1,3,5-triazine; 4-(triphenylene-2-yl)-6-(1,1′-biphenyl-4-yl)-dibenzothiophene; 4-{3-(1,1′-biphenyl-4-yl)phenyl}-dibenzothiophene; 1,6-bis(9H-carbazole-9-yl)-[1]benzothieno[2,3-c]pyridine; iridium(III)bis(2-phenylpyridyl-N,C²′)(4-ethyl-2,5-diphenylpyridyl-N,C2′)

### (Group 22B)

2-{5-(dibenzothiophene4-yl)-1,1′-biphenyl-3-yl}-4,6-diphenyl-1,3,5-triazine; 2-{5-(6-phenyldibenzothiophene4-yl)-1,1′-biphenyl-3-yl}-4,6-diphenyl-1,3,5-triazine; 2-{5-(6-(1,1′-biphenyl-4-yl)dibenzothiophene4-yl)-1,1′-biphenyl-3-yl}-4,6-diphenyl-1,3,5-triazine; 2-{5-(6-(1,1′-biphenyl-3-yl)dibenzothiophene4-yl)-1,1′-biphenyl-3-yl}-4,6-diphenyl-1,3,5-triazine; 2-{5-(dibenzothiophene3-yl)-1,1′-biphenyl-3-yl}-4,6-diphenyl-1,3,5-triazine; 2-{5-(dibenzothiophene3-yl)-4′-phenyl-1,1′-biphenyl-3-yl}-4,6-diphenyl-1,3,5-triazine; 2-{3-(6-(1,1′-biphenyl-4-yl)dibenzothiophene4-yl)phenyl}-4,6-bis(phenyl-d5)-1,3,5-triazine; 2-{3-(6-(9,9-dimethylfluorene-2-yl)dibenzothiophene4-yl)phenyl}-4,6-diphenyl-1,3,5-triazine; 2-{5-(6-(9,9-dimethylfluorene-2-yl)dibenzothiophene4-yl)-1,1′-biphenyl-3-yl}-4,6-diphenyl-1,3,5-triazine; 2-{3′-triphenylenyl-[1,1′-biphenyl]-3-yl}-4,6-diphenyl-1,3,5-triazine; 2-(6-(4′-phenyl-1,1′-biphenyl-4-yl)dibenzothiophene4-yl)-4-(1,1′-biphenyl-3-yl)-6-phenyl-1,3,5-triazine; 5-{4-(4,6-diphenyl-1,3,5-triazine-2-yl)phenyl}-8-phenyl-5H,8H-indolo[2,3-c]carbazole; 5-(1,1′-biphenyl-4-yl)-8-(4′-phenyl-1,1′-biphenyl-3-yl)-5H,8H-indolo[2,3-c]carbazole; 5-(1,1′-biphenyl-3-yl)-8-(4′-phenyl-1,1′-biphenyl-4-yl)-5H,8H-indolo[2,3-c]carbazole; 5-(4′-phenyl-1,1′-biphenyl-4-yl)-12-(1,1′-biphenyl-4-yl)-5H,12H-indolo[3,2-a]carbazole; 5-(dibenzothiophene4-yl)-8-(4′-phenyl-1,1′-biphenyl-3-yl)-5H,8H-indolo[2,3-c]carbazole; 5-(triphenylene-2-yl)-8-(4′-phenyl-1,1′-biphenyl-4-yl)-5H,8H-indolo[2,3-c]carbazole; 5-{3-(dibenzothiophene4-yl)phenyl}-8-(4′-phenyl-1,1′-biphenyl-4-yl)-5H,8H-indolo[2,3-c]carbazole; 5-{3-(9H-carbazole-9-yl)phenyl}-8-(4′-phenyl-1,1′-biphenyl-3-yl)-5H,8H-indolo[2,3-c]carbazole; 5-(4′-phenyl-1,1′-biphenyl-4-yl)-12-(4′-phenyl-1,1′-biphenyl-3-yl)-5H,12H-indolo[3,2-a]carbazole; 5-(4′-(phenyl-d5)-1,1′-biphenyl-4-yl)-8-(phenyl-d5)-5H,8H-indolo[2,3-c]carbazole; 5-(4′-phenyl-1,1′-biphenyl-3-yl)-12-phenyl-5H,12H-indolo[3,2-a]carbazole; 5-(3′-(phenyl-d5)-1,1′-biphenyl-4-yl)-8-(phenyl-d5)-5H,8H-indolo[2,3-c]carbazole; 5-(4′-phenyl-1,1′-biphenyl-4-yl)-12-phenyl-5H,12H-indolo[3,2-a]carbazole; 5-(4′-phenyl-1,1′-biphenyl-3-yl)-12-(triphenylene-2-yl)-5H,12H-indolo[3,2-a]carbazole; 5-{3-phenyl(1,1′-biphenyl-3-yl)}-8-(4′-phenyl-1,1′-biphenyl-3-yl)-5H,8H-indolo[2,3-c]carbazole

### (Group 23B)

2,4-bis(1,1′-biphenyl-3-yl)-6-(10H-[1]benzothieno[3,2-b]indole-10-yl)-1,3,5-triazine; 3-(10-phenyl-5,10-dimethyl-5,10-dihydroindolo[3,2-b]indole-5-yl)phenyl-1,3,5-triazine; 2-(1,1′-biphenyl-3-yl)-4-(10H-benzofuro[3,2-b]indole-10-yl)-6-phenyl-1,3,5-triazine; 9-(2-naphthyl)-9′-phenyl-3,3′-bis[9H-carbazole]; 9-(1,1′-biphenyl-3-yl)-9′-phenyl-3,3′-bis[9H-carbazole]; 3-(dibenzofuran-2-yl)-9-(5-phenyl(1,1′-biphenyl-3-yl))-9H-carbazole; 3-(dibenzothiophene2-yl)-9-(2-naphthylbenzene-3-yl)-9H-carbazole; 11-(4,6-diphenyl-1,3,5-triazine-2-yl)-12-phenyl-11H,12H-indolo[2,3-a]carbazole; 9,9′-diphenyl-3,3′-bis[9H-carbazole]

### (Group 24B)

11-(4-(1,1′:3′,1″-terbenzene-3-yl)-6-phenyl-1,3,5-triazine-2-yl)-12-phenyl-11H,12H-indolo[2,3-a]carbazole; 11-(4-(1,1′-biphenyl-3-yl)-6-phenyl-1,3,5-triazine-2-yl)-12-phenyl-11H,12H-indolo[2,3-a]carbazole; 11-(4-(1,1′-biphenyl-4-yl)-6-phenyl-1,3,5-triazine-2-yl)-12-phenyl-11H,12H-indolo[2,3-a]carbazole; 9-(1,1′-biphenyl-2-yl)-9′-(1,1′-biphenyl-3-yl)-3,3′-bis[9H-carbazole]; 9,9′-bis(1,1′-biphenyl-2-yl)-3,3′-bis[9H-carbazole]

### (Group 25B)

2-(1,1′-biphenyl-4-yl)-4-phenyl-6-(9,9′-spirobifluorene-4-yl)-1,3,5-triazine; 9-(1,1′-biphenyl-3-yl)-9′-(1,1′-biphenyl-4-yl)-3,3′-bis[9H-carbazole]; 9-phenyl-9′-(triphenylene-2-yl)-3,3′-bis[9H-carbazole]; 2-(1,1′-biphenyl-3-yl)-4-phenyl-6-(9,9′-spirobifluorene-4-yl)-1,3,5-triazine; 2,4,6-tri(1,1′-biphenyl-3-yl)-1,3,5-triazine; N,N′-diphenyl-N,N′-bis(1-naphthyl)benzidine; 4,7-diphenyl-1,10-phenanthroline; (9,9-dimethylfluorene-3-yl)(9-phenyl-9H-carbazole-3-yl)(1,1′:3′,1″-terbenzene-5′-yl)amine

### (Group 26B)

9-(7-cyanotriphenylene-2-yl)-9′-phenyl-3,3′-bis[9H-carbazole]; 9-(4′-cyano-1,1′-biphenyl-4-yl)-9′-phenyl-3,3′-bis[9H-carbazole]; 9-(5-(4,6-diphenyl-1,3,5-triazine-2-yl)-1,1′-biphenyl-3-yl)-9′-phenyl-2,3′-bis[9H-carbazole]; 9-(3-(4-(1,1′-biphenyl-3-yl)-6-phenyl-1,3,5-triazine-2-yl)phenyl)-9′-phenyl-2,3′-bis[9H-carbazole]; 9-(3′-(4,6-diphenyl-1,3,5-triazine-2-yl)-1,1′-biphenyl-3-yl)-9′-phenyl-2,3′-bis[9H-carbazole]; 9-(3-(4,6-diphenyl-1,3,5-triazine-2-yl)phenyl)-9′-phenyl-2,3′-bis[9H-carbazole]

### (Group 28B)

tris(4-(6H-6-aza-12-oxaindeno[1,2-b]fluorene-6-yl)phenyl)amine; 5-methyl-8-((4-(5-methyl-5H,8H-indolo[2,3-c]carbazole-8-yl)-phenyl)(2-pyridyl)phosphoryl)-5H,8H-indolo[2,3-c]carbazole; tetrakis(4-(6H-6-aza-8-oxaindeno[2,3-b]fluorene-6-yl)-phenyl)silane; 2,5-bis(4-(6H-6-aza-12-oxaindeno[1,2-b]fluorene-6-yl)phenyl)furan; tetrakis(4-(6H-6-aza-8-oxaindeno[2,3-b]fluorene-6-yl)-phenyl)germane; 1,4-bis(4-(7-aza-7H-12-thiaindeno[1,2-a]fluorene-7-yl)phenyl)-5,5-dimethyl-1,3-cyclopentadiene

### (Group 29B)

9-(7-cyanotriphenylene-2-yl)-9′-phenyl-3,3′-bis[9H-carbazole]; 9-(3-(4,6-diphenyl-1,3,5-triazine-2-yl)phenyl)-9′-phenyl-2,3′-bis[9H-carbazole]; 9-(4′-cyano-1,1′-biphenyl-4-yl)-9′-phenyl-3,3′-bis[9H-carbazole]

### (Group 30B)

1,3-bis(9H-carbazole-9-yl)benzene; bis[4-[9,9-dimethylacridine-10(9H)-yl]phenyl]sulfone; 4,4′-bis(9-carbazolyl)-1,1′-biphenyl; 4,4′-bis(9-carbazolyl)-1,1′-benzophenone; bis(2-((oxo)diphenylphosphino)phenyl)ether; 4,4′-bis(9-dimethoxycarbazole)-1,1′-benzophenone

### (Group 31B)

11-(4-(1,1′-biphenyl-4-yl)-6-phenyl-1,3,5-triazine-2-yl)-12-phenyl-11H,12H-indolo[2,3-a]carbazole; 11-(4-(3′-phenyl-1,1′-biphenyl-3-yl)-6-phenyl-1,3,5-triazine-2-yl)-12-phenyl-11H,12H-indolo[2,3-a]carbazole; 11-(4-(3′-phenyl-1,1′-biphenyl-4-yl)-6-phenyl-1,3,5-triazine-2-yl)-12-phenyl-11H,12H-indolo[2,3-a]carbazole; 11-(4,6-diphenyl-1,3,5-triazine-2-yl)-12-(4′-phenyl-1,1′-biphenyl-4-yl)-11H,12H-indolo[2,3-a]carbazole; 11-(4,6-bis(1,1′-biphenyl-4-yl)-1,3,5-triazine-2-yl)-12-phenyl-11H,12H-indolo[2,3-a]carbazole; 11-(4-(1,1′-biphenyl-4-yl)-6-phenyl-1,3,5-triazine-2-yl)-12-(1,1′-biphenyl-3-yl)-11H,12H-indolo[2,3-a]carbazole; 9-(1,1′-biphenyl-3-yl)-9′-phenyl-3,3′-bis[9H-carbazole]; 9-(1,1′-biphenyl-4-yl)-9′-phenyl-3,3′-bis[9H-carbazole]; 9-(1,1′-biphenyl-3-yl)-9′-(1,1′-biphenyl-4-yl)-3,3′-bis[9H-carbazole]

### (Group 32B)

2-(1,1′-biphenyl-3-yl)-4-[3-(9H-carbazole-9-yl)phenyl]-6-(dibenzofuran-3-yl)-1,3,5-triazine; iridium(III)tris(5′-phenyl-2-phenylpyridyl-N,C2′); 8-(4-(4,6-di(naphthalene-2-yl)-1,3,5-triazine-2-yl)phenyl)quinoline; Liq; 2-(1,1′-biphenyl-3-yl)-4-[3-(9H-carbazole-9-yl)phenyl]-6-(dibenzofuran-4-yl)-1,3,5-triazine; 2-[3′-(9H-carbazole-9-yl)-1,1′-biphenyl-4-yl]-4-(dibenzofuran-3-yl)-6-phenyl-1,3,5-triazine; 2-[4′-(9H-carbazole-9-yl)-1,1′-biphenyl-3-yl]-4-(dibenzofuran-3-yl)-6-phenyl-1,3,5-triazine; 2-(1,1′-biphenyl-4-yl)-4-[3-(9H-carbazole-9-yl)phenyl]-6-(dibenzofuran-3-yl)-1,3,5-triazine; 2-(1,1′-biphenyl-4-yl)-4-[4-(9H-carbazole-9-yl)phenyl]-6-(dibenzofuran-3-yl)-1,3,5-triazine; 2-[3-(9H-carbazole-9-yl)phenyl]-4-(dibenzofuran-3-yl)-6-phenyl-1,3,5-triazine; 2-[4-(9H-carbazole-9-yl)phenyl]-4-(dibenzofuran-3-yl)-6-phenyl-1,3,5-triazine; 2-[3-(3-phenyl-9H-carbazole-9-yl)phenyl]-4-(dibenzofuran-3-yl)-6-phenyl-1,3,5-triazine; 2-[4-(3-phenyl-9H-carbazole-9-yl)phenyl]-4-(dibenzofuran-3-yl)-6-phenyl-1,3,5-triazine; 9,9′-bis(1,1′-biphenyl-4-yl)-3,3′-bis[9H-carbazole]; 5,8-bis(1,1′-biphenyl-4-yl)-5H,8H-indolo[2,3-c]carbazole; 2-(3-phenyl-9H-carbazole-9-yl)-4-(dibenzofuran-3-yl)-6-phenyl-1,3,5-triazine; 2-[3-(9H-carbazole-9-yl)phenyl]-4-phenyl-6-(dibenzofuran-3-yl)-pyrimidine

### (Group 33B)

2,8-bis(trifluoromethoxy)-10,12-bis(dicyanomethylene)-10,12-dihydroindeno[2,1-b]fluorene; N-phenyl-N-(1,1′:4′,1″-terphenyl4-yl)-N′,N′-bis(1,1′-biphenyl-4-yl)-1,1′-biphenyl-4,4′-diamine; N,N-bis(4-(dibenzofuran-4-yl)phenyl)[1,1′:4′,1″-terphenyl]-4-amine; biphenyl-2-ylbis(9,9′-spirobi[9H-fluorene]-2-yl)amine; 2,8-bis(3,5-bis(trifluoromethyl)phenyl)-10,12-bis(dicyanomethylene)-10,12-dihydroindeno[1,2-b]fluorene; N-(naphthalene-1-yl)-N-phenyl-N′,N′-bis(1,1′-biphenyl-4-yl)-1,1′-biphenyl-4,4′-diamine; N,N-bis(1,1′-biphenyl-4-yl)-4-(9-phenyl-9H-carbazole-3-yl)aniline; N,N-bis(biphenyl-4-yl)-3′-(9H-carbazole-9-yl)-1,1′-biphenyl-4-amine; N-biphenyl-2-yl-N-9,9-dimethylfluorene-2-yl-(9,9′-spirobi[9H-fluorene]-2-yl)amine; 6,12-bis(dicyanomethylene)-2,8-bis(3-trifluoromethyl-4-fluorophenyl)-5,11-diazaindeno[1,2-b]fluorene; biphenyl-2-ylbis(9,9′-diphenyl-9H-fluorene-2-yl)amine; N-(1,1′-biphenyl-4-yl)-N-(9,9-dimethylfluorene-2-yl)-4-(9-phenyl-9H-carbazole-3-yl)aniline

### (Group 34B)

9-(1-naphthyl)-10-(2-naphthyl)anthracene; 9-(benzo[b]naphtho[2,3-d]furan-7-yl)-10-phenylanthracene; 9-(benzo[b]naphtho[2,3-d]furan-7-yl)-10-phenylanthracene-d8; 9-(benzo[b]naphtho[2,3-d]furan-7-yl-d9)-10-(phenyl-d5)anthracene-d8; 9-(benzo[b]naphtho[2,1-d]furan-7-yl)-10-(phenyl-d5)anthracene; 9-(1-naphthyl)-10-(4-(2-naphthyl)phenyl)anthracene; 9-(benzo[b]naphtho[2,1-d]furan-7-yl)-10-(1,1′-biphenyl-3-yl)anthracene-d8; 9-(1-naphthyl-d7)-10-(4-(2-naphthyl)phenyl-d11)anthracene-d8; 9-(benzo[b]naphtho[2,3-d]furan-7-yl)-10-(phenyl-d5)anthracene; 9-(benzo[b]naphtho[2,1-d]furan-7-yl)-10-phenylanthracene; 9-(benzo[b]naphtho[2,1-d]furan-7-yl)-10-(1,1′-biphenyl)anthracene; 9-(benzo[b]naphtho[2,3-d]furan-7-yl)-10-(1-naphthyl)anthracene; 9-(benzo[b]naphtho[2,3-d]furan-7-yl)-10-(1,1′-biphenyl-3-yl)anthracene

### (Group 35B)

9-(1-naphthyl)-10-(4-(2-naphthyl)phenyl)anthracene; 9-(1-naphthyl)-10-(3-(2-naphthyl)phenyl)anthracene; 9-(2-naphthyl)-10-(3-(2-naphthyl)phenyl)anthracene

In one embodiment, as the first organic compound and the second organic compound, one or more compounds selected from compounds corresponding to the first compound and the second compound in the mixture A can be independently used. The first organic compound and the second organic compound in the present specification may not be independently the first compound and the second compound in the mixture A.

### <Other Component, and the Like>

The mixed powder according to an aspect of the present invention may or may not include a component other than the first component and the second component.

In one embodiment, the mixed powder consists of the first component and the second component, or substantially consists of the first component and the second component. In the latter case, unavoidable impurities may be included therein.

In one embodiment, 80% by mass or more, 85% by mass or more, 90% by mass or more, 95% by mass or more, 99% by mass or more, 99.5% by mass or more, 99.9% by mass or more, 99.99% by mass or more, or 100% by mass of the mixed powder is the first component and the second component.

In one embodiment, 80 mol % or more, 90 mol % or more, 95 mol % or more, 99 mol % or more, 99.5 mol % or more, 99.9 mol % or more, 99.99 mol % or more, or 100 mol % of the mixed powder is the first component and the second component.

In one embodiment, the mixed powder consists of the first component, the second component and a third component, or substantially consists of the first component, the second component and a third component. In the latter case, unavoidable impurities may be included therein. Here, the third component is an arbitrary organic compound (third organic compound).

In one embodiment, 80% by mass or more, 85% by mass or more, 90% by mass or more, 95% by mass or more, 99% by mass or more, 99.5% by mass or more, 99.9% by mass or more, or 99.99% by mass or more of the mixed powder is the first component and the second component, and the remaining thereof is the third component. Here, the third component is an arbitrary organic compound (third organic compound).

In one embodiment, 80 mol % or more, 90 mol % or more, 95 mol % or more, 99 mol % or more, 99.5 mol % or more, 99.9 mol % or more, or 99.99 mol % or more of the mixed powder is the first component and the second component, and the remaining thereof is the third component. Here, the third component is an arbitrary organic compound (third organic compound).

In one embodiment, 80% by mass or more, 85% by mass or more, 90% by mass or more, 95% by mass or more, 99% by mass or more, 99.5% by mass or more, 99.9% by mass or more, or 99.99% by mass or more of the mixed powder is the first component, the second component and the third component. Here, the third component is an arbitrary organic compound (third organic compound).

In one embodiment, 80 mol % or more, 90 mol % or more, 95 mol % or more, 99 mol % or more, 99.5 mol % or more, 99.9 mol % or more, or 99.99 mol % or more of the mixed powder is the first component, the second component and the third component. Here, the third component is an arbitrary organic compound (third organic compound).

The above-described third organic compound (third component) is not particularly limited as long as it is an organic compound.

In one embodiment, the third component is a compound selected from the group consisting of the compound C1, the compound C2 and the compound C3.

In the first embodiment, the mixed powder may, for example, include the compound C3 as the first component, include the compound C2 as the second component, and further include the compound C1 as the third component.

In the second embodiment, the mixed powder may, for example, include the compound C3 as the first component, include the compound C1 as the second component, and further include the compound C2 as the third component.

In the third embodiment, the mixed powder may, for example, include the compound C2 as the first component, include the compound C1 as the second component, and further include the compound C3 as the third component.

In the fourth embodiment, the mixed powder may, for example, include the compound C2 as the first component, include the compound C3 as the second component, and further include the compound C1 as the third component.

### <Method for Selecting First Organic Compound and Second Organic Compound>

A method for selecting the organic compounds in an aspect of the present invention is expressed as follows:
a method for selecting a first organic compound and a second organic compound in a mixed powder which includes the first organic compound and the second organic compound and which is solid at ordinary temperatures and pressures,
wherein the organic electroluminescence device includes a cathode, an anode, and an emitting layer arranged between the cathode and the anode, and including a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the first organic compound and the second organic compound are selected so that the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)}
satisfy the following formula (2):

$$\\ \begin{matrix}0 < MOL 2 / ( MOL 1 + MOL 2 ) ≦ 0.45 & ( 1 )\end{matrix}$$

$$\\ \begin{matrix}- 20 ° C . ≦ T 1 - T 2 ≦ 40 ° C . . & ( 2 )\end{matrix}$$

Each condition and each component in the method for selecting them is the same as described in those of the above-described mixed powder according to an aspect of the present invention.

In the method for selecting the organic compounds in an aspect of the present invention, the second component in which the deposition characteristic curve thereof (temperature and P/M^{1/2}) is observed to a certain extent farther away from the higher temperature side than that of the first component is generally selected and used in combination with the first component having a certain deposition characteristic, Specifically, they may be appropriately selected in consideration of the molar ratio of both and the formula (2).

### <Mixed Powder and Method for Producing the Same>

A mixed powder according to an aspect of the present invention may contain the first component and the second component in one particle, or may be a mixture of a particle composed of the first component and a particle composed of the second component.

A method for producing mixed powder according to an aspect of the present invention, for example, may include pulverizing and mixing the first component and the second component by using a mortar and the like. In the case of pulverization and mixing, when the amount of material used is large, such as when used in a large-scale deposition machine, pulverization and mixing using a pulverizer may be used.

Further, it may include putting the first component and the second component in a container and the like, heating and melting them under a chemically inert environment, subsequently, cooling them to the ambient temperature, and pulverizing the obtained mixture by using a mixer and the like to obtain powder. The latter method can lead mixing the first component and the second component at the molecular level. As a result, it can prevent problems such as mix unevenness which can be caused during transport of the mixed powder.

The mixed powder may be compressed and formed to be pellet-like.

### Method for Deposition

A method for deposition according to an aspect of the present invention includes: heating and vaporizing the mixed powder according to an aspect of the present invention described above or a mixture obtained by heating and melting the mixed powder and by solidifying it in the same deposition source to form a film on the deposition surface of the opposing substrate arranged thereabove. In the method for deposition, other conditions are not particularly limited, and general apparatus and conditions can be used as a deposition apparatus and a deposition condition.

The deposition is normally conducted under vacuum (at a pressure lower than pressure of the atmosphere). The pressure inside the apparatus during deposition is preferably 5.0 Pa or less, and more preferably 1.0 Pa or less. The heating temperature during deposition is generally 150° C. to 400° C., and is preferably 200 to 350° C.

The method for deposition according to an aspect of the present invention may include: using, for the deposition, the mixture (solidified material) formed by melting and mixing the mixed powder which is the mixture of a particle composed of the first component and a particle composed of the second component. Further, it may include: using the mixed powder obtained by crushing the mixture (solidified material) for the deposition.

Further, the mixed powder may be compressed in advance to form pellets as described above, and the pellets may be introduced into the deposition source to conduct the deposition.

In one embodiment, the method for deposition includes:
heating and vaporizing the mixed powder according to an aspect of the present invention or a mixture obtained by heating and melting the mixed powder and by solidifying it in a first deposition source, and
heating and vaporizing a single compound, or a composition different from the mixed powder or the mixture in a second deposition source different from the first deposition source,
to form a deposited film including the components (including the first component and the second component) heated and vaporized in the first deposition source and the component heated and vaporized in the second deposition source on the deposition surface of the opposing substrate arranged thereabove.

The “single compound” used in the second deposition source may be a compound different from the plurality of compounds included in the mixed powder or the mixture used in the first deposition source, or may be the same compound as any of the plurality of compounds included in the mixed powder or the mixture. The “single compound” is an arbitrary organic compound, and can be, for example, the above-described third organic compound (third component).

The composition used in the second deposition source can include two or more kinds of arbitrary organic compounds. The two or more kinds of arbitrary organic compounds may be independently a compound different from the plurality of compounds included in the mixed powder or the mixture, or may be the same compound as any of the plurality of compounds included in the mixed powder or the mixture. One kind of the two or more kinds of arbitrary organic compounds can be, for example, the above-described third organic compound (third component).

When the third component is used in the second deposition source, the deposited film including the first component, the second component and the third component can be formed. The first component, the second component and the third component can be independently selected so as to the deposited film including the compound C1, the compound C2 and the compound C3.

In one embodiment, the mixed powder used in the first deposition source includes the compound C3 as the first component, and includes the compound C2 as the second component, and
the single compound used in the second deposition source is the compound C1, or the composition used in the second deposition source includes the compound C1.

In one embodiment, the mixed powder used in the first deposition source includes the compound C3 as the first component, and includes the compound C1 as the second component, and
the single compound used in the second deposition source is the compound C2, or the composition used in the second deposition source includes the compound C2.

In one embodiment, the mixed powder used in the first deposition source includes the compound C2 as the first component, and includes the compound C1 as the second component, and
the single compound used in the second deposition source is the compound C3, or the composition used in the second deposition source includes the compound C3.

In one embodiment, the mixed powder used in the first deposition source includes the compound C2 as the first component, and includes the compound C3 as the second component, and
the single compound used in the second deposition source is the compound C1, or the composition used in the second deposition source includes the compound C1.

In one embodiment, the mixed powder including the first component and the second component is used in the first deposition source without using the second deposition source to form the deposited film. As a result, the deposited film including the first component and the second component as a main component can be formed. According to the present embodiment, the emitting layer according to the sixth embodiment and the seventh embodiment described later can be formed, for example, as the mixed powder.

### Applicable Technical Field

In terms of the mixed powder and the method for deposition according to an aspect of the present invention, the term “for an organic electroluminescence device” means use for fabricating an organic EL device, specifically, the organic EL device (organic EL device with thermally activated delayed fluorescence) including a cathode, an anode, and an emitting layer arranged between the cathode and the anode, and including a compound C2 having delayed fluorescence. A method for fabricating an organic EL device using the mixed powder according to an aspect of the present invention will be described below.

### Method for Fabricating Organic EL Device

A method for fabricating an organic EL device in an aspect of the present invention can also be expressed as follows:
a method for fabricating an organic electroluminescence device, wherein the organic electroluminescence device includes a cathode, an anode, and an emitting layer arranged between the cathode and the anode, and including a compound C2 having delayed fluorescence, and
the method includes: heating and vaporizing a mixed powder or a mixture obtained by heating and melting the mixed powder and by solidifying it in a deposition source to form the emitting layer,
wherein the mixed powder includes a first organic compound and a second organic compound, and is solid at ordinary temperatures and pressures,
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound, and
when MOL2 [mol %] is used as the molar concentration of the second organic compound,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$\\ \begin{matrix}0 < MOL 2 / ( MOL 1 + MOL 2 ) ≦ 0.45 & ( 1 )\end{matrix}$$

$$\\ \begin{matrix}- 20 ° C . ≦ T 1 - T 2 ≦ 40 ° C . . & ( 2 )\end{matrix}$$

A mixed powder and a method for deposition in the method for the fabrication are the same as described in those of the mixed powder and the method for deposition in an aspect of the present invention described above.

As the device configuration of the organic EL device, structures in which structures of the following (1) to (4) and the like are stacked on a substrate can be given:
(1) an anode/an emitting layer/a cathode,
(2) an anode/a hole-transporting region/an emitting layer/a cathode,
(3) an anode/an emitting layer/an electron-transporting region/a cathode,
(4) an anode/a hole-transporting region/an emitting layer/an electron-transporting region/a cathode,
wherein “/” indicates that the layers are stacked adjacent to each other.

An electron-transporting region is a region composed of one or two or more organic layers (also referred to as “electron-transporting layer” and/or “electron-injecting layer”) including the electron-transporting compound, and a hole-transporting region is a region composed of one or two or more organic layers (also referred to as “hole-transporting layer” and/or “hole-injecting layer”) including the hole-transporting compound.

FIG. 4 shows a schematic configuration of an example of an organic EL device fabricated by the present invention.

The organic EL device 1 includes a transparent substrate 2, an anode 3, a cathode 4, and an organic layer 10 arranged between the anode 3 and the cathode 4. The organic layer 10 is constituted by stacking a hole-injecting layer 6, a hole-transporting layer 7, an emitting layer 5 as a first organic layer, an electron-transporting layer 8, and an electron-injecting layer 9 in this order from the anode 3 side.

### Emitting Layer

In the method for fabricating an organic EL device in an aspect of the present invention, the emitting layer 5 of the organic EL device 1 can be formed by the deposition method using the mixed powder or the mixture.

### Fifth Embodiment

In one embodiment, the emitting layer 5 of the organic EL device 1 includes the compound C1, the compound C2 and the compound C3. In the following description, an embodiment in which the emitting layer 5 of the organic EL device 1 includes the compound C1, the compound C2 and the compound C3 is also referred to as a fifth embodiment. In this case, the compound C1 is preferably a dopant material, the compound C2 is preferably a host material, and the compound C3 is preferably a dispersed material (matrix) dispersing the dopant material into the emitting layer.

In the present embodiment, the singlet energy S₁ (C1) of the compound C1, the singlet energy S₁ (C2) of the compound C2, and the singlet energy S₁ (C3) of the compound C3 preferably satisfy the following formula.

S₁(C3)>S₁(C2)>S₁ (C1)

The energy gap T_{77K} (C3) of the compound C3 at 77 [K] is preferably greater than the energy gap T_{77K} (C2) of the compound C2 at 77 [K]. That is, the following formula is preferably satisfied.

T77K(C3)>T77K (C2)

### Relationship Between Triplet Energy and Energy Gap at 77 [K]

Here, the relationship between the triplet energy and the energy gap at 77 [K] will be described. In the present embodiment (and the sixth embodiment and the seventh embodiment described later), the energy gap at 77 [K] has some differences from the triplet energy defined normally.

The triplet energy is measured as follows. First, a solution in which a compound being a measurement target is dissolved in an appropriate solvent is sealed in a quartz glass tube to prepare a sample. For this sample, the phosphorescence spectrum (vertical axis: phosphorescent emission intensity, horizontal axis: wavelength) is measured at low temperature (77 [K]), a tangent line is drawn to the rapidly increasing part on the short wavelength side in this phosphorescence spectrum, the triplet energy is calculated from a predetermined conversion formula, using the wavelength value at the intersection of the tangent and the horizontal axis.

Here, the compound having thermally activated delayed fluorescence is preferably a compound with small ΔST in the compound according to the present embodiment. When ΔST is small, intersystem crossing and reverse intersystem crossing are likely to occur even at low temperature (77 [K]), and an excited singlet state and an excited triplet state coexist. As a result, the spectrum measured in the same manner as above includes emission from both the excited singlet state and the excited triplet state, and it is difficult to clearly distinguish from which state the light is emitted. Basically, the value of triplet energy is considered to be dominant.

Therefore, in the present embodiment, the measurement method is the same as that of the normal triplet energy T, and so as to distinguish them strictly in terms of their difference, the value measured as follows is referred to as the energy gap T_{77K}. The compound being a measurement target is dissolved in EPA (diethylether: isopentane: ethanol=5:5:2 (volume ratio)) so that the concentration thereof is 10 μmol/L, and this solution is placed in a quartz cell, and it is used as a measurement sample. For this measurement sample, the phosphorescence spectrum (vertical axis: phosphorescent emission intensity, horizontal axis: wavelength) is measured at low temperature (77 [K]), a tangent line is drawn to the rapidly increasing part on the short wavelength side in this phosphorescence spectrum, the energy amount calculated from the following conversion formula (F1) is defined as the energy gap T_{77K} at 77 [K], using the wavelength value λedge [nm] at the intersection of the tangent and the horizontal axis.

$$\\ Conversion formula ( F 1 ) : {T}_{77 K} [ eV ] = 1239.85 / {λ}_{edge}$$

The tangent line is drawn as follows to the rapidly increasing part on the short wavelength side in this phosphorescence spectrum. Among the maximum values of the spectrum, the tangent line at each point to the long wavelength direction on the curve is considered when moving from the short wavelength side of the phosphorescence spectrum to the maximum value on the shortest wavelength side on the spectrum curve. Regarding this tangent line, the curve is increased (that is, as the vertical value is increased), and then the slope is increased. The tangent line (that is, the tangent line at inflection point) drawn at the point where the value of the slope takes the maximum value is used as the tangent line to the increasing edge on the short wavelength side of the phosphorescence spectrum.

A maximum point with a peak intensity of 15% or less of the maximum peak intensity of the spectrum is not included in the maximum value on the shortest wavelength side mentioned above, and the tangent line closest to the maximum value on the shortest wavelength side and drawn at the point where the slope value takes the maximum value is defined as the tangent line to the rapidly increasing part of the short wavelength side of the phosphorescence spectrum.

The main unit of the Fluorescence Spectrophotometer F-4500 manufactured by Hitachi High-Tech Corporation can be used for measuring phosphorescence. The measurement apparatus is not limited to this, and a cooling apparatus, a low-temperature container, an excitation light source, and a light receiving apparatus may be used in combination to measure it.

### Singlet Energy S₁

As a method for measuring singlet energy S₁ using a solution (sometimes referred to as a solution method), the following methods can be given.

10 μmol/L of a toluene solution of compound being a measurement target is prepared as a sample, it is put in a quartz cell, and then an absorption spectrum of the sample is measured at room temperature (300 K) (vertical axis: absorption strength and horizonal axis: wavelength). A tangent line is drawn to the fall on the long wavelength side of this absorption spectrum, and then the wavelength value λedge [nm] at the intersection of the tangent line and the horizontal axis is substituted into the following conversion formula (F2) to calculate the singlet energy.

$$\\ Conversion formula ( F 2 ) : {S}_{1} [ eV ] = 1239.85 / λ edge$$

As an absorption spectrum measuring apparatus, for example, a spectrophotometer (apparatus name: U3310) manufactured by Hitachi High-Tech Science Corporation can be used, but it is not limited to this.

A tangent to the fall on the long wavelength side of the absorption spectrum is drawn as follows. Among the maximum values of the absorption spectrum, the tangent line at each point on the curve is considered when moving from the maximum value on the longest wavelength side to the long wavelength direction on the spectrum curve. Regarding this tangent line, the slope repeats decreasing and then increasing as the curve falls (that is, as the vertical value decreases). The tangent line drawn at the point where the value of the slope takes the minimum value on the long wavelength side (provided that the case where the absorbance is 0.1 or less is excluded) is taken as the tangent line to the falling edge on the long wavelength side of the absorption spectrum.

A maximum point with an absorbance value of 0.2 or less is not included in the maximum value on the longest wavelength side.

In the present embodiment, the difference (S₁-T_{77K}) between the singlet energy S₁ and the energy gap T_{77K} at 77 [K] is defined as ΔST.

In the present embodiment, the difference ΔST (C2) between the singlet energy S₁ (C2) of the compound C2 and the energy gap T_{77K} (C2) of the compound C2 at 77 [K] is preferably less than 0.3 eV, more preferably less than 0.2 eV, still more preferably less than 0.1 eV, and still more preferably less than 0.01 eV. That is, ΔST (C2) preferably satisfy any of the following formulas.

$$\\ Δ ST ( C 2 ) = {S}_{1} ( C 2 ) - {T}_{77 K} ( C 2 ) < 0.3 eV$$

$$\\ Δ ST ( C 2 ) = {S}_{1} ( C 2 ) - {T}_{77 K} ( C 2 ) < 0.2 eV$$

$$\\ Δ ST ( C 2 ) = {S}_{1} ( C 2 ) - {T}_{77 K} ( C 2 ) < 0.1 eV$$

$$\\ Δ ST ( C 2 ) = {S}_{1} ( C 2 ) - {T}_{77 K} ( C 2 ) < 0.01 eV$$

When the organic EL device of the present embodiment emits light, it is preferable that the compound C3 do not primarily emit light in the emitting layer.

When the organic EL device of the present embodiment emits light, it is preferable that the fluorescent emitting compound C1 primarily emit light in the emitting layer.

The organic EL device of the present embodiment preferably emits red or green light, and more preferably green light.

In the present embodiment, the amount of the compound C3, the compound C2, and the compound C1 included in the emitting layer 5 is preferably, for example, within the following range.

The amount of the compound C3 is preferably 10% by mass or more and 80% by mass or less.

The amount of the compound C2 is preferably 10% by mass or more and 80% by mass or less, more preferably 10% by mass or more and 60% by mass or less, and still more preferably 20% by mass or more and 60% by mass.

The amount of the compound C1 is preferably 0.01% by mass or more and 10% by mass or less, more preferably 0.01% by mass or more and 5% by mass or less, and still more preferably 0.01% by mass or more and 1% by mass or less.

The upper limit of the total amount of the compound C1, the compound C2, and the compound C3 in the emitting layer is 100% by mass. In the present embodiment, it is excluded that a material other than the compound C1, the compound C2, and the compound C3 is included in the emitting layer.

In one embodiment, 70% by mass or more, 80% by mass or more, 90% by mass or more, 95% by mass or more, 97% by mass or more, 99% by mass or more, or substantially 100% by mass of the emitting layer is the compound C1, the compound C2, and the compound C3. In the case of the term “substantially 100% by mass”, unavoidable impurities may be included therein.

The emitting layer may include one kind of the compound C3 alone, or may include two or more kinds thereof in combination. The emitting layer may include one kind of the compound C2 alone, or may include two or more kinds thereof in combination. The emitting layer may include one kind of the compound C1 alone, or may include two or more kinds thereof in combination.

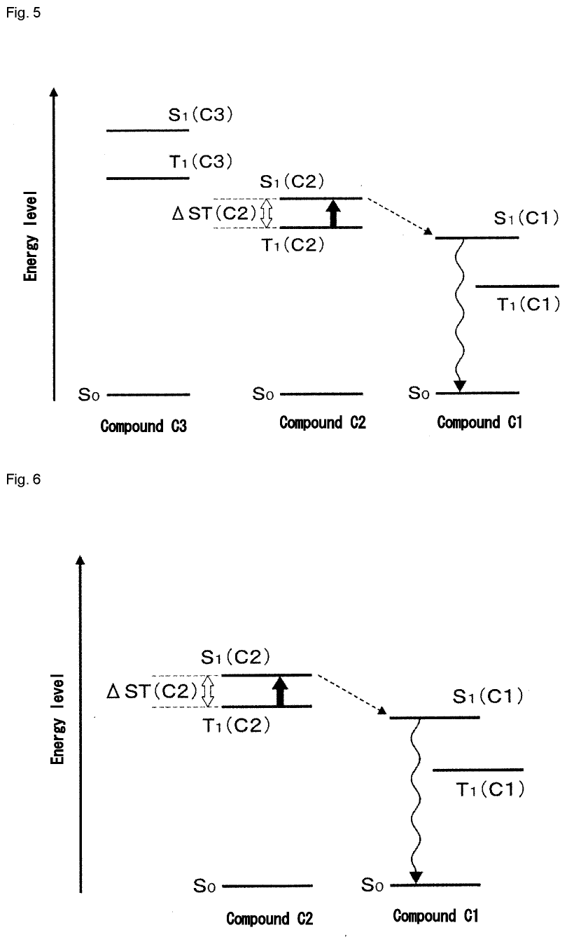

FIG. 5 is a diagram showing an example of the relationship between the energy levels of the compound C1, the compound C2 and the compound C3 in the emitting layer.

In FIG. 5, S₀ represents the ground state.

S₁ (C1) represents the lowest excited singlet state of the compound C1, and T₁ (C1) represents the lowest excited triplet state of the compound C1.

S₁ (C2) represents the lowest excited singlet state of the compound C2, and T₁ (C2) represents the lowest excited triplet state of the compound C1.

S₁ (C3) represents the lowest excited singlet state of the compound C3, and T₁ (C3) represents the lowest excited triplet state of the compound C3.

A dashed arrow pointing from S₁ (C2) to S₁ (C1) in FIG. 5 represents Förster type energy transfer from the lowest excited singlet state of the compound C2 to the lowest excited singlet state of the compound C1.

As shown in FIG. 5, when a compound with small ΔST (C2) is used as the compound C2, the reverse intersystem crossing can be performed from the lowest excited triplet state T₁ (C2) to the lowest excited singlet state S₁ (C2) by thermal energy. And then, the Förster type energy transfer occurs from the lowest excited singlet state S₁ (C2) of the compound C2 to that of the compound C1 to generate the lowest excited singlet state S₁ (C1). As a result, a fluorescent emission from the lowest excited singlet state S₁ (C1) of the compound C1 can be observed. When the delayed fluorescence due to this TADF mechanism is used, it is believed that the internal quantum efficiency can be theoretically increased to 100%.

### Sixth Embodiment

In one embodiment, the emitting layer 5 of the organic EL device 1 includes the compound C1 and the compound C2. In the following description, an embodiment in which the emitting layer 5 of the organic EL device 1 includes the compound C1 and the compound C2 is also referred to as a sixth embodiment. In this case, the compound C1 is preferably a dopant material, and the compound C2 is preferably a host material.

In the present embodiment, the singlet energy S₁ (C1) of the compound C1, and the singlet energy S₁ (C2) of the compound C2 preferably satisfy the following formula.

S₁(C2)>S₁ (C1)

The energy gap T_{77K} (C2) of the compound C2 at 77 [K] is preferably greater than the energy gap T_{77K} (C1) of the compound C1 at 77 [K]. That is, the following formula is preferably satisfied.

T_{77K}(C2)>T_{77K} (C1)

In the present embodiment, the difference ΔST (C2) between the singlet energy S₁ (C2) of the compound C2 and the energy gap T_{77K} (C1) of the compound C1 at 77 [K] is preferably less than 0.3 eV, more preferably less than 0.2 eV, and still more preferably less than 0.1 eV. That is, ΔST (C2) preferably satisfy any of the following formulas.

$$\\ Δ ST ( C 2 ) = {S}_{1} ( C 2 ) - {T}_{77 K} ( C 2 ) < 0.3 eV$$

$$\\ Δ ST ( C 2 ) = {S}_{1} ( C 2 ) - {T}_{77 K} ( C 2 ) < 0.2 eV$$

$$\\ Δ ST ( C 2 ) = {S}_{1} ( C 2 ) - {T}_{77 K} ( C 2 ) < 0.1 eV$$

$$\\ Δ ST ( C 2 ) = {S}_{1} ( C 2 ) - {T}_{77 K} ( C 2 ) < 0.01 eV$$

When the organic EL device of the present embodiment emits light, it is preferable that the compound C1 primarily emit light in the emitting layer.

The organic EL device of the present embodiment preferably emits red or green light, and more preferably green light.

In the present embodiment, the amount of the compound C1 and the compound C2 included in the emitting layer 5 is preferably, for example, within the following range.

The amount of the compound C2 is preferably 10% by mass or more and 80% by mass or less, more preferably 10% by mass or more and 60% by mass or less, and still more preferably 20% by mass or more and 60% by mass or less.

The amount of the compound C1 is preferably 0.01% by mass or more and 10% by mass or less, more preferably 0.01% by mass or more and 5% by mass or less, and still more preferably 0.01% by mass or more and 1% by mass or less.

The upper limit of the total amount of the compound C1 and the compound C2 in the emitting layer is 100% by mass. In the present embodiment, it is excluded that a material other than the first compound and the second compound is included in the emitting layer.

In one embodiment, 70% by mass or more, 80% by mass or more, 90% by mass or more, 95% by mass or more, 97% by mass or more, 99% by mass or more, or substantially 100% by mass of the emitting layer is the compound C1 and the compound C2. In the case of the term “substantially 100% by mass”, unavoidable impurities may be included therein.

The emitting layer may include one kind of the compound C2 alone, or may include two or more kinds thereof in combination. The emitting layer may include one kind of the compound C1 alone, or may include two or more kinds thereof in combination.

FIG. 6 is a diagram showing an example of the relationship between the energy levels of the compound C1 and the compound C2 in the emitting layer.

In FIG. 6, S₀ represents the ground state.

S₁ (C1) represents the lowest excited singlet state of the compound C1, and T₁ (C1) represents the lowest excited triplet state of the compound C1.

S₁ (C2) represents the lowest excited singlet state of the compound C2, and T₁ (C2) represents the lowest excited triplet state of the compound C2.

A dashed arrow pointing from S₁ (C2) to S₁ (C1) in FIG. 6 represents Förster type energy transfer from the lowest excited singlet state of the compound C2 to that of the compound C1.

As shown in FIG. 6, when a compound with small ΔST (C2) is used as the compound C2, the reverse intersystem crossing can be performed from the lowest excited triplet state T₁ (C2) to the lowest excited singlet state S₁ (C2) by thermal energy. And then, the Förster type energy transfer occurs from the lowest excited singlet state S₁ (C2) of the compound C2 to that of the compound C1 to generate the lowest excited singlet state S₁ (C1). As a result, a fluorescent emission from the lowest excited singlet state S₁ (C1) of the compound C1 can be observed. Even when the delayed fluorescence due to this TADF mechanism is used, it is believed that the internal efficiency can be theoretically increased to 100%.

### Seventh Embodiment

In one embodiment, the emitting layer 5 of the organic EL device 1 includes the compound C2 and the compound C3. In the following description, an embodiment in which the emitting layer 5 of the organic EL device 1 includes the compound C2 and the compound C3 is also referred to as a seventh embodiment. In this case, the compound C2 is preferably a dopant material, and the compound C3 is preferably a host material.

The compound C2 (dopant material) of the present embodiment is not particularly limited, and, for example, the above-mentioned compound used as the compound C2 (host material) in the fifth embodiment and the sixth embodiment can be used as the compound C2 (dopant material) of the present embodiment.

The compound C3 (host material) of the present embodiment is not particularly limited, and, for example, the above-mentioned compound used as the compound C3 (matrix material) in the fifth embodiment can be used as the compound C3 (host material) of the present embodiment.

In the organic EL device 1 of the present embodiment, the singlet energy S₁ (C2) of the compound C2, and the singlet energy S₁ (C3) of the compound C3 preferably satisfy the following formula.

S₁(C3)>S₁ (C2)

The energy gap T_{77K} (C3) of the compound C3 at 77 [K] is preferably greater than the energy gap T_{77K} (C2) of the compound C2 at 77 [K]. That is, the following formula is preferably satisfied.

T_{77K}(C3)>T_{77K} (C2)

When the organic EL device of the present embodiment emits light, it is preferable that the compound C2 primarily emit light in the emitting layer.

The amount of the compound C2 and the compound C3 included in the emitting layer is preferably, for example, within the following range.

The amount of the compound C2 is preferably 10% by mass or more and 80% by mass or less, more preferably 10% by mass or more and 60% by mass or less, and still more preferably 20% by mass or more and 60% by mass or less.

The amount of the compound C3 is preferably 20% by mass or more and 90% by mass or less, more preferably 40% by mass or more and 90% by mass or less, and still more preferably 40% by mass or more and 80% by mass or less.

The upper limit of the total amount of the compound C2 and the compound C3 in the emitting layer is 100% by mass. In the present embodiment, it is excluded that a material other than the compound C2 and the compound C3 is included in the emitting layer.

In one embodiment, 70% by mass or more, 80% by mass or more, 90% by mass or more, 95% by mass or more, 97% by mass or more, 99% by mass or more, or substantially 100% by mass of the emitting layer is the compound C2 and the compound C3. In the case of the term “substantially 100% by mass”, unavoidable impurities may be included therein.

The emitting layer may include one kind of the compound C2 alone, or may include two or more kinds thereof in combination. The emitting layer may include one kind of the compound C3 alone, or may include two or more kinds thereof in combination.

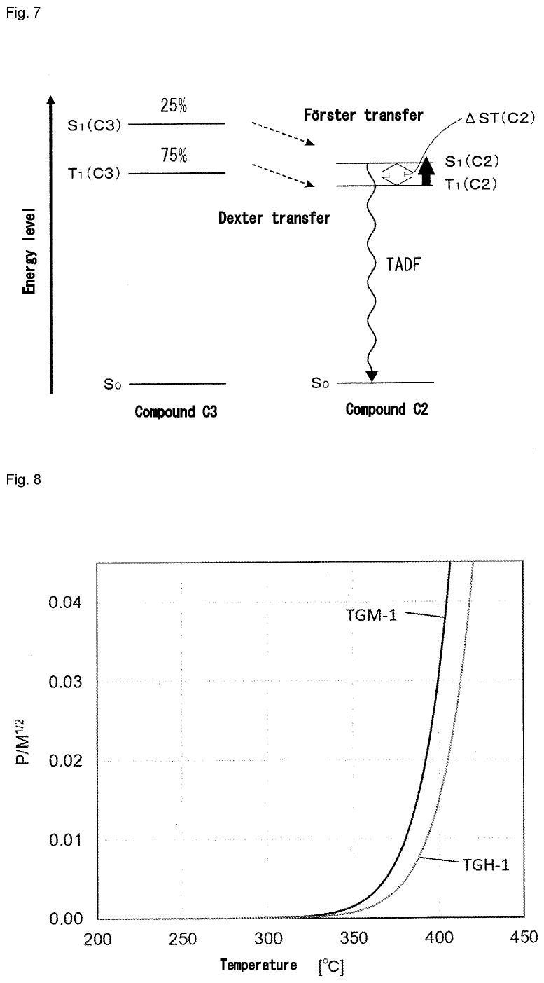

FIG. 7 is a diagram showing an example of the relationship between the energy levels of the compound C2 and the compound C3 in the emitting layer.

In FIG. 7, S₀ represents the ground state.

S₁ (C2) represents the lowest excited singlet state of the compound C2, and T₁ (C2) represents the lowest excited triplet state of the compound C2.

S₁ (C3) represents the lowest excited singlet state of the compound C3, and T₁ (C3) represents the lowest excited triplet state of the compound C3.

A dashed arrow in FIG. 7 represents energy transfer each between excited states. Each energy is transferred to the lowest excited singlet state S₁ (C2) of the compound C2 or the lowest excited triplet state T₁ (C2) thereof, using Förster transfer from the lowest excited singlet state S₁ (C3) of the compound C3 or using Dexter transfer from the lowest excited triplet state T₁ (C3) thereof. Further, when a material with small ΔST (C2) is used as the compound C2, the reverse intersystem crossing can be performed from the lowest excited triplet state T₁ (C2) of the compound C2 to the lowest excited singlet state S₁ (C2) thereof by thermal energy. As a result, a fluorescent emission from the lowest excited singlet state S₁ (C2) of the compound C2 can be observed. Even when the delayed fluorescence due to this TADF mechanism is used, it is believed that the internal efficiency can be theoretically increased to 100%.

In each embodiment of the emitting layer described above, the emitting layer may or may not include a phosphorescent emitting material (dopant material).

The emitting layer does not preferably include a heavy metal complex and a phosphorescent emitting rare earth metal complex. Here, examples of the heavy metal complex include an iridium complex, an osmium complex, a platinum complexes, and the like.

Further, it is also preferable that the emitting layer do not include a metal complex.

In one embodiment, the emitting layer in the organic EL device preferably has the film thickness of 5 nm or more and 50 nm or less, more preferably 7 nm or more and 50 nm or less, and most preferably 10 nm or more and 50 nm or less. When it has the film thickness of 5 nm or more, it is likely to be easy to form the emitting layer and adjust the chromaticity coordinate, and when it has the film thickness of 50 nm or less, it is likely to suppress increase of the driving voltage.

The organic EL device 1 can be used for an electronic apparatus such as a display device and an emitting device.

Configurations of the organic EL device 1 will be further described. Hereinafter, the description for the symbol is frequently abbreviated.

### Substrate

The substrate is used as a support of the organic EL device. As the substrate, for example, glass, quartz, plastic and the like can be used. Further, a flexible substrate may be used. The term “flexible substrate” means a bendable (flexible) substrate, and examples thereof include a plastic substrate or the like. Examples of the material for forming the plastic substrate include polycarbonate, polyallylate, polyether sulfone, polypropylene, polyester, polyvinyl fluoride, polyvinyl chloride, polyimide, polyethylene naphthalate and the like. Also, an inorganic vapor deposited film can be used.

### Anode

For the anode formed on the substrate, metals, alloys, electrically conductive compounds, mixtures thereof, and the like, which have large work function (specifically 4.0 eV or more) are preferably used. Specific examples thereof include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition thereto, specific examples thereof include gold (Au), platinum (Pt), nickel (Ni), tungsten (W), chromium (Cr), molybdenum (Mo), iron (Fe), cobalt (Co), copper (Cu), palladium (Pd), titanium (Ti), a nitride of a metallic material (for example, titanium nitride), or the like.

A film is normally formed using these materials by a sputtering method. For example, indium oxide-zinc oxide can be formed by a sputtering method using a target in which 1% by mass or more and 10% by mass or less zinc oxide is added to indium oxide. Further, indium oxide containing tungsten oxide, and zinc oxide can be formed by a sputtering method using a target in which 0.5% by mass or more and 5% by mass or less of tungsten oxide or 0.1% by mass or more and 1% by mass or less of zinc oxide is added to indium oxide. In addition, the film may be formed by a vacuum deposition method, a coating method, an inkjet method, a spin coating method or the like.

Since the hole-injecting layer formed in contact with the anode is formed in EL layers formed on the anode using a composite material that allows easy hole-injection regardless of the work function of the anode, a composite material (which also includes for example, metals, alloys, electrically conductive compounds, mixtures thereof, in addition, an element belonging to Group 1 or Group 2 of the Periodic Table of the Elements) being able to be used as an electrode material can be used.

An element belonging to Group 1 or Group 2 of the Periodic Table of the Elements which is a material having small work function, i.e., an alkali metal such as lithium (Li) and cesium (Cs), an alkaline earth metal such as magnesium (Mg), calcium (Ca) and strontium (Sr), and an alloy containing these (e.g., MgAg and AILi); a rare earth metal such as europium (Eu) and ytterbium (Yb), and an alloy containing these can also be used. When the anode is formed using an alkali metal, an alkaline earth metal, and an alloy containing these, a vacuum deposition method and a sputtering method can be used. Further, when silver paste or the like is used, it is possible to use the coating method, the inkjet method or the like.

### Cathode

For the cathode, metals, alloys, electrically conductive compounds, mixtures thereof, and the like, which have small work function (specifically 3.8 eV or less) are preferably used. Specific examples of such a cathode material include an element belonging to Group 1 or Group 2 of the Periodic Table of the Elements, i.e., an alkali metal such as lithium (Li) and cesium (Cs), an alkaline earth metal such as magnesium (Mg), calcium (Ca) and strontium (Sr), and an alloy containing these (e.g., MgAg and AILi); a rare earth metal such as europium (Eu) and ytterbium (Yb), and an alloy containing these.

When the cathode is formed using an alkali metal, an alkaline earth metal, and an alloy containing these, a vacuum deposition method and a sputtering method can be used. Further, when silver paste or the like is used, it is possible to use the coating method, the inkjet method or the like.

When the electron-injecting layer is provided, the cathode can be formed using various conductive materials such as Al, Ag, ITO, graphene, indium oxide-tin oxide containing silicon or silicon oxide, regardless of the work function value. The film can be formed using these conductive materials and by using a sputtering method, an inkjet method, a spin coating method, or the like.

### Hole-Injecting Layer

The hole-injecting layer is a layer containing a substance having high hole-injecting property. As the substance having high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, or the like can be given.

Further, as the substance having high hole-injecting property, an aromatic amine compound such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), dipyrazino[2,3-f:20,30-h]quinoxaline-2,3,6,7,10,11-hexacarbonitrile (HAT-CN), and the like being a low molecular organic compound can also be given.

Further, as the substance having high hole-injecting property, a polymer compound (oligomers, dendrimers, polymers, and the like) can also be given. Examples thereof include a polymer compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), poly[N,N′-bis(4-butylphenyl)-N,N′-bis(phenyl)benzidine] (abbreviation: Poly-TPD). Further, a polymer compound with added acid such as poly(3,4-ethylenedioxythiophene)/poly(styrene sulfonic acid) (PEDOT/PSS) and polyaniline/poly(styrene sulfonic acid) (PAni/PSS) can also be used.

### Hole-Transporting Layer

The hole-transporting layer is a layer containing a substance having high hole-transporting property. For the hole-transporting layer, an aromatic amine compound, a carbazole derivative, an anthracene derivative, or the like can be used. Specifically, an aromatic amine compound such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluoren-9-yl)triphenylamine (abbreviation: BAFLP), 4,4′-bis[N-(9,9-dimethylfluoren-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA) and 4,4′-bis[N-(spiro-9,9′-bifluoren-2-yl)-N-phenylamino]biphenyl (abbreviation: BSPB), and the like can be used. The substances described above is mainly a substance having a hole mobility of 10⁻⁶ cm²/(V·s) or more.

As the hole-transporting layer, a carbazole derivative such as CBP, 9-[4-(N-carbazolyl)]phenyl-10-phenylanthracene (CzPA) and 9-phenyl-3-[4-(10-phenyl-9-anthryl)phenyl]-9H-carbazole (PCzPA), ann an anthracene derivative such as t-BuDNA, DNA and DPAnth can be used. A polymer compound such as poly(N-vinylcarbazole) (abbreviation: PVK) and poly(4-vinyltriphenylamine) (abbreviation: PVTPA) can also be used.

Provided that a substance other than the above-described substances may be used as long as the substance has higher hole-transporting property than electron-transporting property. The layer containing the substance having high hole-transporting property may be not only a single layer, but also layers in which two or more layers formed of the above-described substances are stacked.

When two or more hole-transporting layers are arranged, a material having greater energy gap is preferably arranged near the emitting layer side.

### Electron-Transporting Layer

The electron-transporting layer is a layer containing a substance having high electron-transporting property. For the electron-transporting layer, 1) a metal complex such as an aluminum complex, a beryllium complex, and a zinc complex; 2) a heteroaromatic compound such as an imidazole derivative, a benzimidazole derivative, an azine derivative, carbazole derivative, and a phenanthroline derivative; and 3) a polymer compound can be used. Specific examples of an aromatic amine compound include a metal complex such as Alq, tris (4-methyl-8-quinolinolato) aluminum (abbreviation: Almq₃), bis (10-hydroxybenzo [h]quinolino) beryllium (abbreviation: BeBq₂), BAlq, Znq, ZnPBO and ZnBTZ, and the like. Further, in addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP) and 4,4′-bis(5-methylbenzoxazol-2-yl) stilbene (abbreviation: BzOs). In the present embodiment, an imidazole compound can be suitably used. The substances described above is mainly a substance having an electron mobility of 10⁻⁶ cm²/(V·s) or more. A substance other than those described above may be used as the electron-transporting layer, as long as the substance has higher electron-transporting property than hole-transporting property. Further, the electron-transporting layer may be constituted by a single layer, or may be constituted by stacking two or more layers composed of the substances described above.

Further, a polymer compound can also be used for the electron-transporting layer. Examples thereof include poly[(9,9-dihexylfluoren-2,7-diyl)-co-(pyridine-3,5-diyl)] (abbreviation: PF-Py), poly[(9,9-dioctylfluoren-2,7-diyl)-co-(2,2′-bipyridin-6,6′-diyl)] (abbreviation: PF-BPy), and the like.

### Electron-Injecting Layer

The electron-injecting layer is a layer containing a substance having high electron-injecting property. For the electron-injecting layer, an alkali metal, an alkaline earth metal, or a compound thereof such as lithium (Li), cesium (Cs), calcium (Ca), lithium fluoride (LiF), cesium fluoride (CsF), calcium fluoride (CaF₂), lithium oxide (LiOx), can be used. In addition, a material in which an alkali metal, an alkaline earth metal, or a compound thereof is included in a substance having electron-transporting property, specifically, a material in which magnesium (Mg) is included in Alq, and the like may also be used. In such a case, the electron-injection from the cathode can be performed more efficiently.

Alternatively, a composite material formed by mixing the organic compound and an electron donor (donor) may be used for the electron-injecting layer. In, since electrons are generated in the organic compounds by the electron donor, such a composite material has excellent electron-injecting property and electron-transporting property. In this case, the organic compound is preferably a material having excellent property in transporting the generated electrons, and specific examples thereof include a substance (complex, a heteroaromatic compound, and the like) constituting the electron-transporting layer described above. The electron donor is not limited as long as it exhibits electron donating property for the organic compound. Specifically, it is preferably an alkali metal, an alkaline earth metal and a rare earth metal, and examples thereof include lithium, cesium, magnesium, calcium, erbium, ytterbium, and the like. Further, an alkali metal oxide and an alkaline earth metal oxide are preferable, and examples thereof include lithium oxide, calcium oxide, barium oxide, and the like. Further, a lewis base such as magnesium oxide can also be used. Alternatively, an organic compound such as tetrathiafulvalene (abbreviation: TTF) can also be used.

### Method for Forming Layer

The method for forming each layer of the organic EL device of the present embodiment is not limited except as specifically mentioned above, but a conventional method such as a dry film-forming method such as a vacuum deposition method, a sputtering method, a plasma method and an ion plating method, and a wet film-forming method such as a spin coating method, a dipping method, a flow coating method, and an inkjet method can be used.

### Film Thickness

The film thickness of each organic layer of the organic EL device of the present embodiment is not limited except as specifically mentioned above. When the film thickness is too thin, defects such as pinholes are likely to occur generally. On the other hand, when the film thickness is too thick, high applied voltage is required thereby decreasing efficiency thereof. Therefore, the film thickness thereof is normally preferable several nm to 1 μm.

### Composition

A composition according to an aspect of the present invention is expressed as follows:
a composition for a deposition in an organic electroluminescence device, including a first organic compound and a second organic compound,
wherein the organic electroluminescence device includes a cathode, an anode, and an emitting layer arranged between the cathode and the anode, and including a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the composition, and
when MOL2 [mol %] is used as the molar concentration of the second organic compound in the composition,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$\\ \begin{matrix}0 < MOL 2 / ( MOL 1 + MOL 2 ) ≦ 0.45 & ( 1 )\end{matrix}$$

$$\\ \begin{matrix}- 20 ° C . ≦ T 1 - T 2 ≦ 40 ° C . . & ( 2 )\end{matrix}$$

In the composition, the mixed powder described in the mixed powder of an aspect of the present invention described above can be used, but it is not limited thereto. That is, a form other than the mixed powder is also sometimes used in the composition.

The composition is a composition for a deposition. The term “for a deposition” can be also referred to as “can be used for a deposition method”, that is, the composition can be used for any technical field including depositing an organic compound to form a film. Further, the deposition method includes a vacuum deposition method. That is, the term “composition for a deposition” includes the term “composition for a vacuum deposition”.

The composition is the same as the above-described mixed powder according to an aspect of the present invention, except that the shape thereof is not specific to the mixed powder. That is, the shape of the composition may be the mixed powder, or may not be the mixed powder. Those described above in the mixed powder according to an aspect of the present invention can be used also for the composition, and those described above in the mixed powder according to an aspect of the present invention can be used for those regarding the shape in the case where the composition is the mixed powder.

The composition (hereinafter, also referred to as a “composition (2)”) in an aspect of the present invention can be expressed as follows:
a composition for an organic electroluminescence device, including a first organic compound and a second organic compound,
wherein the organic electroluminescence device includes a cathode, an anode, and an emitting layer arranged between the cathode and the anode, and including a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the composition, and
when MOL2 [mol %] is used as the molar concentration of the second organic compound in the composition,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M1^{1/2}=0.04×{MOL1/(MOL1+MOL2)} and
the temperature T2 [° C.] of the second organic compound in the case of P2/M2^{1/2}=0.04×{MOL2/(MOL1+MOL2)} satisfy the following formula (2):

$$\\ \begin{matrix}0 < MOL 2 / ( MOL 1 + MOL 2 ) ≦ 0.45 & ( 1 )\end{matrix}$$

$$\\ \begin{matrix}- 20 ° C . ≦ T 1 - T 2 ≦ 40 ° C . . & ( 2 )\end{matrix}$$

The composition (2) is the same as the above-described composition, except that it does not have the specifying matter “for a deposition”. The others described in the composition can be used also for the composition (2).

### Method for Deposition Using Composition

A method for deposition according to an aspect of the present invention includes: heating and vaporizing the composition according to an aspect of the present invention described above in the same deposition source to form a film on the deposition surface of the opposing substrate arranged thereabove. In the method for deposition, other conditions are not particularly limited, and general apparatus and conditions can be used as a deposition apparatus and a deposition condition.

The term “method for deposition using a composition” is the same as the above-described method for deposition according to an aspect of the present invention, except that the shape of the used composition is not specific to the mixed powder. That is, the shape of the composition used in the “method for deposition using a composition” may be the mixed powder, or may not be the mixed powder. Those described above in the method for deposition according to an aspect of the present invention can be used also for the “method for deposition using a composition”, and those described above in the method for deposition according to an aspect of the present invention can be used for those regarding the shape in the case where the used composition is the mixed powder.

### Applicable Technical Field

As described above, the composition according to an aspect of the present invention can be used in fabricating an organic EL device, specifically, the organic EL device including a cathode, an anode, and an emitting layer arranged between the cathode and the anode, and including a compound C2 having delayed fluorescence.

### EXAMPLES

Hereinafter, Examples according to the present invention will be described. The present invention is not limited to these Examples. All of TGM-1, TGM-2, TGM-3, TRM-1 and TRM-2 are matrix materials (compounds C3) used in the emitting layer of the organic EL device, TGH-1 and TRH-1 are compounds (host materials: compounds C2) having delayed fluorescence used in Examples and Comparative Examples, and TGD-1 is a fluorescent emitting compound (compound C1) used in the emitting layer of the organic EL device.

### <Compound>

Compounds used in Examples and Comparative Example are shown below.

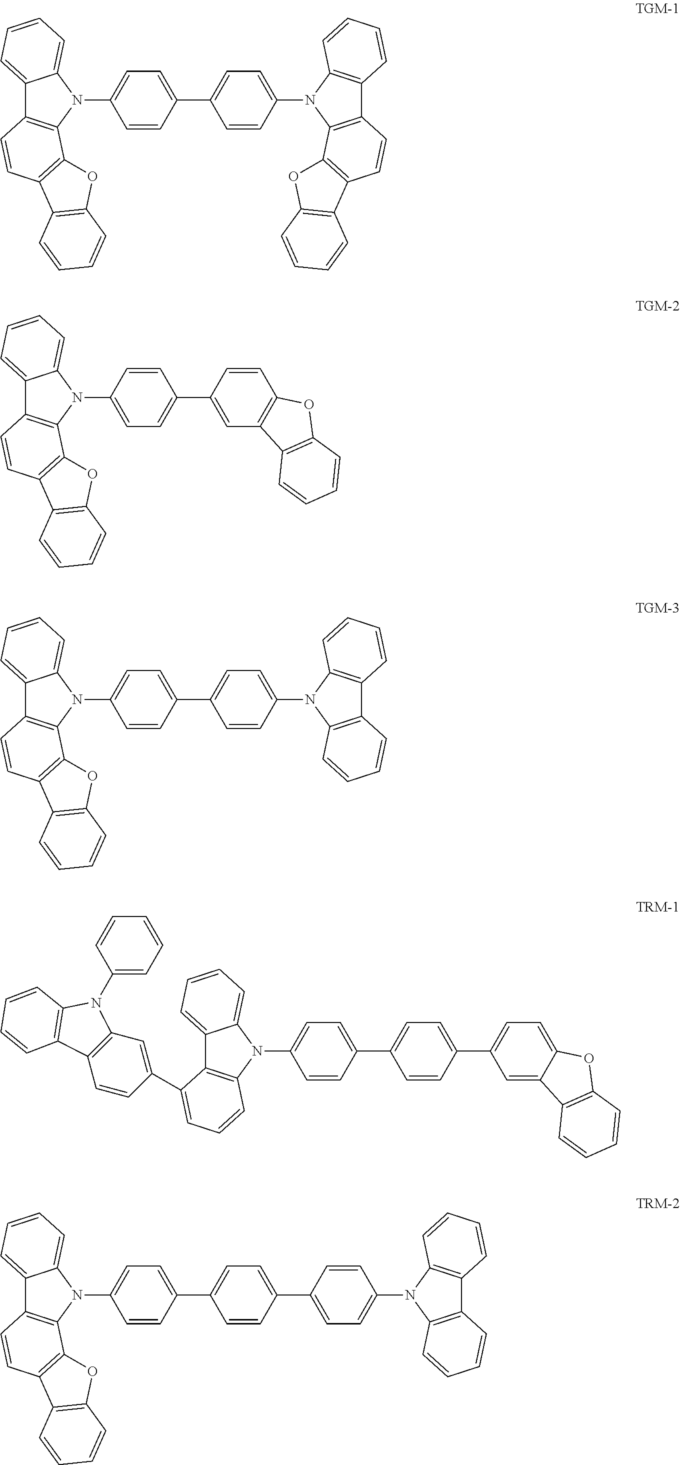 [SMILES: c1ccc2c(c1)oc1c2ccc2c3ccccc3n(-c3ccc(-c4ccc(-n5c6ccccc6c6ccc7c8ccccc8oc7c65)cc4)cc3)c21 ; c1ccc2c(c1)oc1ccc(-c3ccc(-n4c5ccccc5c5ccc6c7ccccc7oc6c54)cc3)cc12 ; c1ccc2c(c1)oc1c2ccc2c3ccccc3n(-c3ccc(-c4ccc(-n5c6ccccc6c6ccccc65)cc4)cc3)c21 ; c1ccc(-n2c3ccccc3c3ccc(-c4cccc5c4c4ccccc4n5-c4ccc(-c5ccc(-c6ccc7oc8ccccc8c7c6)cc5)cc4)cc32)cc1 ; c1ccc2c(c1)oc1c2ccc2c3ccccc3n(-c3ccc(-c4ccc(-c5ccc(-n6c7ccccc7c7ccccc76)cc5)cc4)cc3)c21]

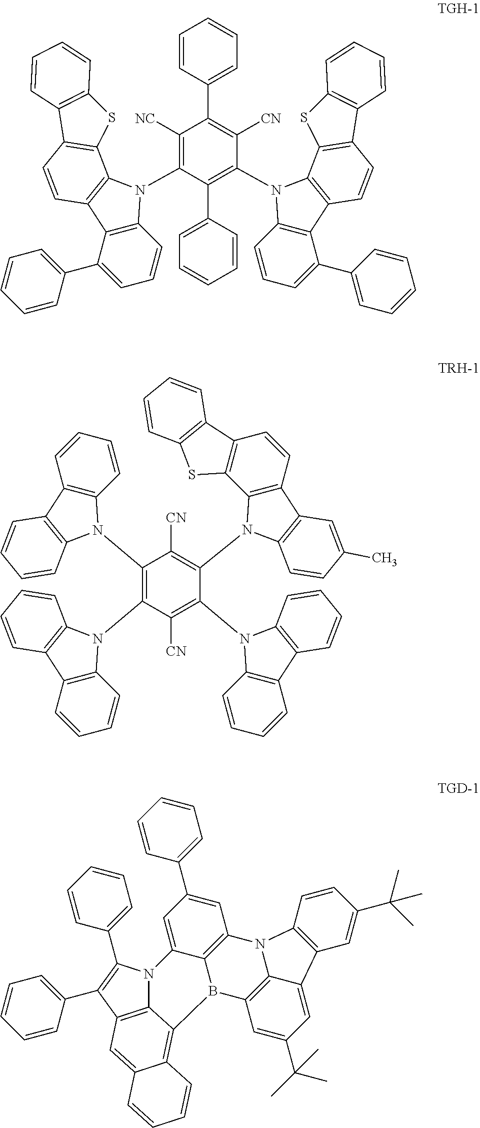 [SMILES: N#Cc1c(-c2ccccc2)c(C#N)c(-n2c3cccc(-c4ccccc4)c3c3ccc4c5ccccc5sc4c32)c(-c2ccccc2)c1-n1c2cccc(-c3ccccc3)c2c2ccc3c4ccccc4sc3c21 ; Cc1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21 ; CC(C)(C)c1ccc2c(c1)c1cc(C(C)(C)C)cc3c1n2-c1cc(-c2ccccc2)cc2c1B3c1c3ccccc3cc3c(-c4ccccc4)c(-c4ccccc4)n-2c13]

The singlet energy of each of the above compounds is as follows.
TGM-1: 3.42 eV
TGM-2: 3.43 eV
TGM-3: 3.42 eV
TRM-1: 3.36 eV
TRM-2: 3.40 eV
TGH-1: 2.61 eV
TRH-1: 2.32 eV
TGD-1: 2.39 eV

### <Method for Producing Mixed Powder>

The mixed powders in Examples and Comparative Example were produced by weighing each compound of the first component and the second component so that the total amount of them was 0.2 to 2.0 g in a solid state with satisfying the desired molar ratio, and by mixing them while pulverizing in a mortar.

### Example 1-1

### <Production of Mixed Powder and Measurements of T1 and T2>

The compounds shown in Table 1 were mixed in the amounts shown in Table 1 to obtain mixed powders. The deposition characteristic curve of the temperature and P1/M1^{1/2} of TGM-1 and the deposition characteristic curve of the temperature and P2/M2^{1/2} of TGH-1, obtained by the method described above, were used to obtain each of the temperature T1 in the case where P1/M1^{1/2} was 0.04×{MOL1/(MOL1+MOL2)} and the temperature T2 in the case where P2/M2^{1/2} was 0.04×{MOL2/(MOL1+MOL2)}. T1, T2, and the value “T1-T2” are shown in Table 1. Further, the deposition characteristic curves of temperature and P/M^{1/2} of TGM-1 and TGH-1 are shown in FIG. 8.

In the above case, P1 is the saturated vapor pressure of TGM-1 at arbitrary temperature, P2 is the saturated vapor pressure of TGH-1 at arbitrary temperature, M1 is the molecular weight of TGM-1, M2 is the molecular weight of TGH-1, MOL1 is the molar concentration [mol %] of TGM-1 in the mixed powder, and MOL2 is the molar concentration [mol %] of TGH-1 in the mixed powder.

An apparatus for ThermoGravimetry-Differential Thermal Analysis (model number “STA2500/HV”) manufactured by NETZSCH Japan K. K. was used as a measuring apparatus of ThermoGravimetry-Differential Thermal Analysis.

TABLE 1

| First component | TGM-1 | |
|---|---|---|
| Second component | TGH-1 | |
| MOL1 | 67.86 | mol % |
| MOL2 | 32.14 | mol % |
| M1 | 664.76 | |
| M2 | 975.2 | |
| T1 | 398° | C. |
| T2 | 397° | C. |
| T1 − T2 | 1° | C. |

### <Evaluation of Continuous Deposition>

Evaluation of continuous deposition was conducted as follows using the obtained mixed powder.

A crucible containing the mixed powder having the total amount of 0.6 g was heated in a vacuum deposition apparatus under vacuum at 1×10⁻⁴ Pa or less, the temperature thereof was adjusted so that the film formation rate was 2 Å/sec, and the film was formed by deposition on a glass substrate. The glass substrate was appropriately replaced, and then the film formation was continued. The first substrate on which a film was formed was refferred to as the substrate “No. 1”, and then they after that were referred to as “No. 2”, “No. 3”, etc.

The following matters were evaluated. The results are shown in Table 2.

### Component Ratio in Deposited Film

The molar mixing ratio of the first component and the second component was measured as follows for each deposited film formed on each substrate. The film area of the deposited film formed on the glass substrate, and the mass obtained from the film thickness in the case where the specific gravity was assumed as 1 were calculated, a solution was prepared with tetrahydrofuran (THF) solvent so that the total concentration of the mixture of the first component and the second component is 100 ppm, and the obtained solution was subjected to HPLC measurement using a high performance liquid chromatography (HPLC) apparatus (apparatus name: “LC-2040C Plus” manufactured by SHIMADZU CORPORATION) to calculate the HPLC area of each of the first component and the second component.

Separately, create a standard solution prepared with THE solvent so that the first component had a concentration of 100 ppm and the second component had a concentration of 100 ppm was obtained to calculate each peak area by HPLC measurement. The mass concentration in the solution of the first component and second component in the mixed film was calculated using the peak area value of the standard solution, and then the mass mixing ratio contained in the film was calculated using it. The mass mixing ratio was calculated using the molecular weight of each component to calculate the molar mixing ratio of each component in the mixed film.

In the column of the second component in Table 2, the numerical value shown in parentheses indicates the ratio of the molar ratio of the second component in the deposited film based on the molar ratio of the second component in the mixed powder.

### Deposition Ratio Stability

In the case where the molar ratio of the first component in the substrate No. 1 was used as the standard value, the molar ratio of the first component in each substrate after the substrate No. 2 was calculated using the molar ratio of the first component in the substrate No. 1 as 100.0%, and it was evaluated as the deposition ratio stability. The second component was also evaluated in the same manner. That is, in the case where the molar ratio of the second component in the substrate No. 1 was used as the standard value, the molar ratio of the second component in each substrate after the substrate No. 2 was calculated using the molar ratio of the second component in the substrate No. 1 as 100.0%, and it was evaluated as the deposition ratio stability. The total film thickness deposited on the substrates No. 1 to No. 6 was 800 nm.

TABLE 2

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0% | 67.86% | 32.14% | — | — |
| deposition | | | | | |
| (mixed powder) | | | | | |
| No. 1 | 0~16% | 71.03% | 28.97% (0.90) | 100.0% | 100.0% |
| No. 2 | 16~33% | 73.23% | 26.77% (0.83) | 103.1% | 92.4% |
| No. 3 | 33~52% | 71.12% | 28.88% (0.90) | 100.1% | 99.7% |
| No. 4 | 52~70% | 69.02% | 30.98% (0.96) | 97.2% | 106.9% |
| No. 5 | 70~86% | 69.11% | 30.89% (0.96) | 97.3% | 106.6% |
| No. 6 | 86~100% | 67.90% | 32.10% (1.00) | 95.6% | 110.8% |

### Example 1-2

The same compounds as those used in Example 1-1 were mixed in the amounts shown in Table 3 to obtain mixed powders. T1, T2, and the value “T1-T2” in the Example are shown in Table 3.

TABLE 3

| First component | TGM-1 | |
|---|---|---|
| Second component | TGH-1 | |
| MOL1 | 81.48 | mol % |
| MOL2 | 18.52 | mol % |
| M1 | 664.76 | |
| M2 | 975.2 | |
| T1 | 401° | C. |
| T2 | 388° | C. |
| T1 − T2 | 13° | C. |

The continuous deposition was conducted and evaluated using the obtained powder in the same manner as in Example 1-1. The results are shown in Table 4. The total film thickness deposited on the substrates No. 1 to No. 4 was 800 nm.

TABLE 4

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0 | 81.48% | 18.52% | — | — |
| deposition | | | | | |
| (mixed powder) | | | | | |
| No. 1 | 0~47% | 84.83% | 15.17% (0.82) | 100.0% | 100.0% |
| No. 2 | 47~66% | 84.46% | 15.54% (0.84) | 99.6% | 102.4% |
| No. 3 | 66~85% | 87.74% | 12.26% (0.66) | 103.4% | 80.8% |
| No. 4 | 85~100% | 89.08% | 10.92% (0.59) | 105.0% | 72.0% |

### Example 2

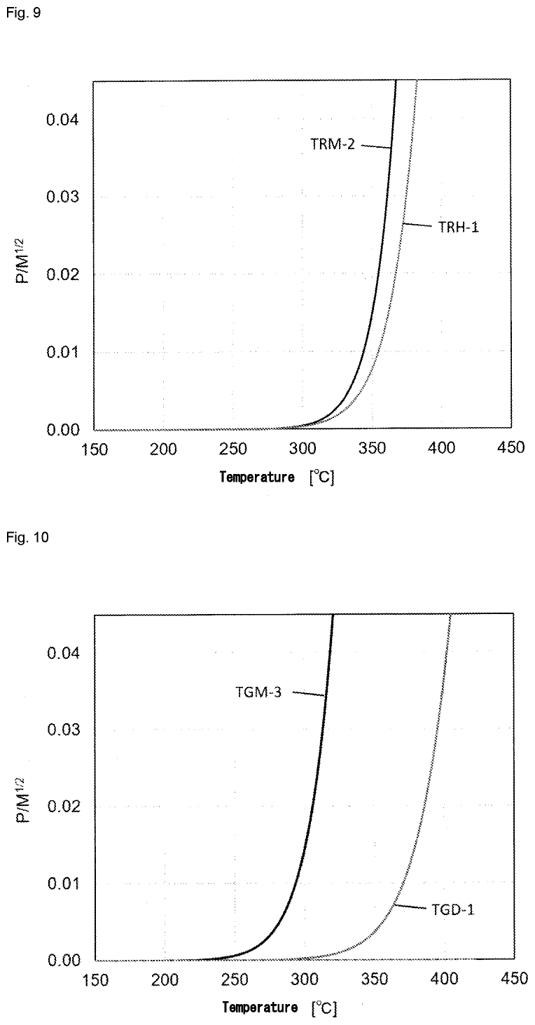

The compounds shown in Table 5 were mixed in the amounts shown in Table 5 to obtain mixed powders. T1, T2, and the value “T1-T2” in the Example are shown in Table 5. Further, the deposition characteristic curves of temperature and P/M^{1/2} of TRM-2 and TRH-1 are shown in FIG. 9.

TABLE 5

| First component | TRM-2 | |
|---|---|---|
| Second component | TRH-1 | |
| MOL1 | 57.40 | mol % |
| MOL2 | 42.60 | mol % |
| M1 | 650.78 | |
| M2 | 909.08 | |
| T1 | 357° | C. |
| T2 | 364° | C. |
| T1 − T2 | −7° | C. |

The continuous deposition was conducted and evaluated using the obtained powder in the same manner as in Example 1-1. The results are shown in Table 6. The total film thickness deposited on the substrates No. 1 to No. 4 was 800 nm.

TABLE 6

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0 | 57.40% | 42.60% | — | — |
| deposition | | | | | |
| (mixed powder) | | | | | |
| No. 1 | 0~28% | 58.18% | 41.82% (0.98) | 100.0% | 100.0% |
| No. 2 | 28~45% | 61.16% | 38.84% (0.91) | 105.1% | 92.9% |
| No. 3 | 45~61% | 60.73% | 39.27% (0.92) | 104.4% | 93.9% |
| No. 4 | 61~100% | 58.86% | 41.14% (0.97) | 101.2% | 98.4% |

### Example 3

The compounds shown in Table 7 were mixed in the amounts shown in Table 7 to obtain mixed powders. T1, T2, and the value “T1-T2” in the Example are shown in Table 7. Further, the deposition characteristic curves of temperature and P/M^{1/2} of TGM-3 and TGD-1 are shown in FIG. 10.

TABLE 7

| First component | TGM-3 | |
|---|---|---|
| Second component | TGD-1 | |
| MOL1 | 98.71 | mol % |
| MOL2 | 1.29 | mol % |
| M1 | 574.68 | |
| M2 | 756.8 | |
| T1 | 318° | C. |
| T2 | 312° | C. |
| T1 − T2 | 6° | C. |

The continuous deposition was conducted and evaluated using the obtained powder in the same manner as in Example 1-1. The results are shown in Table 8. The total film thickness deposited on the substrates No. 1 to No. 6 was 210 nm.

TABLE 8

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0 | 98.71% | 1.29% | — | — |
| deposition | | | | | |
| (mixed powder) | | | | | |
| No. 1 | 0~8.6% | 99.44% | 0.56% (43.4) | 100.0% | 100.0% |
| No. 2 | 8.6~17% | 99.57% | 0.43% (33.3) | 100.1% | 76.8% |
| No. 3 | 17~25% | 99.54% | 0.46% (35.7) | 100.1% | 82.1% |
| No. 4 | 25~34% | 99.47% | 0.53% (41.1) | 100.0% | 94.6% |
| No. 5 | 34~42% | 99.43% | 0.57% (44.2) | 100.0% | 101.8% |
| No. 6 | 42~51% | 99.41% | 0.59% (45.7) | 100.0% | 105.3% |

### Comparative Example 1

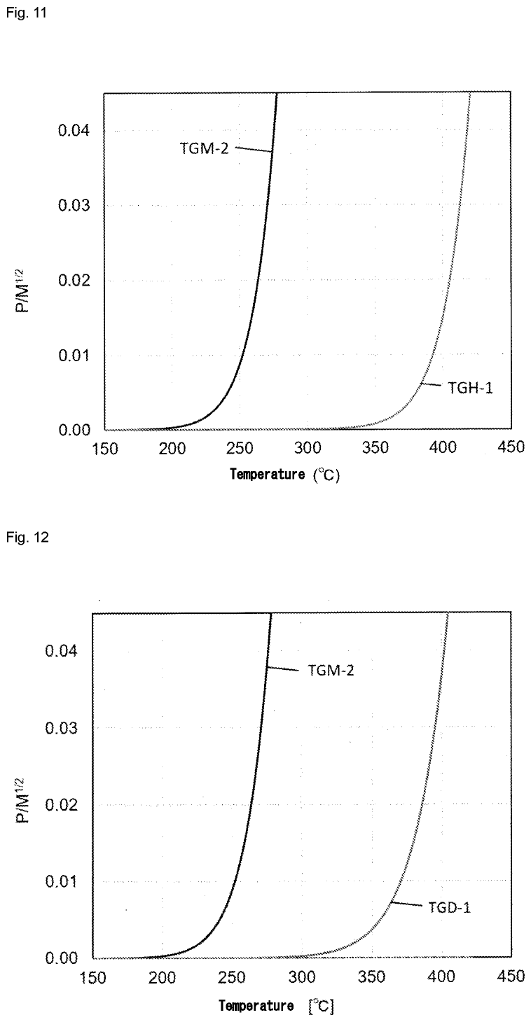

The compounds shown in Table 9 were mixed in the amounts shown in Table 9 to obtain mixed powders. T1, T2, and the value “T1-T2” in the Comparative Example are shown in Table 9. Further, the deposition characteristic curves of temperature and P/M^{1/2} of TGM-2 and TGH-1 are shown in FIG. 11.

TABLE 9

| First component | TGM-2 | |
|---|---|---|
| Second component | TGH-1 | |
| MOL1 | 58.57 | mol % |
| MOL2 | 41.43 | mol % |
| M1 | 499.57 | |
| M2 | 975.2 | |
| T1 | 267° | C. |
| T2 | 395° | C. |
| T1 − T2 | −128° | C. |

The continuous deposition was conducted and evaluated using the obtained powder in the same manner as in Example 1-1. The results are shown in Table 10. The total film thickness deposited on the substrates No. 1 to No. 5 was 150 nm.

TABLE 10

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0 | 58.57% | 41.43% | — | — |
| deposition | | | | | |
| (mixed powder) | | | | | |
| No. 1 | 0~9.2% | 99.98% | 0.02% (0.00) | 100.0% | 100.0% |
| No. 2 | 9.2~18.4% | 99.97% | 0.03% (0.00) | 100.0% | 150.0% |
| No. 3 | 18.4~27.6% | 99.96% | 0.04% (0.00) | 100.0% | 200.0% |
| No. 4 | 27.6~36.8% | 99.96% | 0.04% (0.00) | 100.0% | 200.0% |
| No. 5 | 36.8~46% | 99.96% | 0.04% (0.00) | 100.0% | 200.0% |

### Comparative Example 2

The compounds shown in Table 11 were mixed in the amounts shown in Table 11 to obtain mixed powders. T1, T2, and the value “T1-T2” in the Comparative Example are shown in Table 11. Further, the deposition characteristic curves of temperature and P/M^{1/2} of TGM-2 and TGD-1 are shown in FIG. 12.

TABLE 11

| First component | TGM-2 | |
|---|---|---|
| Second component | TGD-1 | |
| MOL1 | 99.29 | mol % |
| MOL2 | 0.71 | mol % |
| M1 | 499.57 | |
| M2 | 756.8 | |
| T1 | 276° | C. |
| T2 | 302° | C. |
| T1 — T2 | —26° | C. |

The continuous deposition was conducted and evaluated using the obtained powder in the same manner as in Example 1-1. The results are shown in Table 12. The total film thickness deposited on the substrates No. 1 to No. 4 was 210 nm.

TABLE 12

| | Cumulative | Molar ratio | | Deposition ratio | Deposition ratio |
|---|---|---|---|---|---|
| | used amount | First | Second | stability of first | stability of second |
| Substrate No. | (% by mass) | component | component | component | component |
| Before | 0 | 99.29% | 0.71% | — | — |
| deposition | | | | | |
| (mixed powder) | | | | | |
| No. 1 | 0~11% | 99.99% | 0.01% (0.01) | 100.0% | 100.0% |
| No. 2 | 11~32% | 99.97% | 0.03% (0.04) | 100.0% | 300.0% |
| No. 3 | 32~54% | 99.93% | 0.07% (0.10) | 100.0% | 700.0% |
| No. 4 | 54~75% | 99.91% | 0.09% (0.13) | 100.0% | 900.0% |

(1) As seen from Examples 1-1, 1-2, 2 and 3, it was found that the component ratio in the deposited film on each substrate was not varied greatly to achieve the stable deposition with the desired component ratio over a long period of time. On the other hand, it was found that in Comparative Examples 1 and 2, the second component was hardly vaporized at the initial stage of the continuous deposition process, and the deposited film was composed almost only of the first component. Further, in Comparative Example 1, it was predicted that the amount of vaporization of the second component was increased after the substrate No. 6. On the other hand, the amount of vaporization of the first component was decreased to obtain only a few deposited films with the desired component ratio, and as a result, it was predicted that the yield thereof was extremely decreased. Also in Comparative Example 2, the same as those described above occurred after the substrate No. 5.
(2) When the deposition was conducted using a mixed powder composed of two components with different vaporization characteristics, the start of vaporization of the component (component difficult to be vaporized) having the deposition characteristic curve on the higher temperature side was delayed in the two components. As a result, it was predicted that the amount of the component in the deposited film was significantly lower than the desired amount thereof especially in the early stages of continuous deposition. However, against the prediction, it was found that in Examples 1-1, 1-2, 2 and 3, the second component (component difficult to be vaporized) is stably vaporized from the beginning (the substrate No. 1). In particular, the vaporization characteristics of the two components used in Example 3 were significantly different, it was predicted that the start of vaporization of TGD-1 was delayed. However, against the prediction, the amount of the component of TGD-1 was high enough in the substrate No. 1. It was believed that it was caused by appropriate amount of difference in deposition characteristics between the first component and second component.

### Definition

In this specification, a hydrogen atom includes its isotopes different in the number of neutro ns, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group“is a” ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

### “Substituted or Unsubstituted Aryl Group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group“is an” aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

### Unsubstituted Aryl Group (Specific Example Group G1A):

a phenyl group,
a p-biphenyl group,
a m-biphenyl group,
an o-biphenyl group,
a p-terphenyl-4-yl group,
a p-terphenyl-3-yl group,
a p-terphenyl-2-yl group,
a m-terphenyl-4-yl group,
a m-terphenyl-3-yl group,
a m-terphenyl-2-yl group,
an o-terphenyl-4-yl group,
an o-terphenyl-3-yl group,
an o-terphenyl-2-yl group,
a 1-naphthyl group,
a 2-naphthyl group,
an anthryl group,
a benzanthryl group,
a phenanthryl group,
a benzophenanthryl group,
a phenalenyl group,
a pyrenyl group,
a chrysenyl group,
a benzochrysenyl group,
a triphenylenyl group,
a benzotriphenylenyl group,
a tetracenyl group,
a pentacenyl group,
a fluorenyl group,
a 9,9′-spirobifluorenyl group,
a benzofluorenyl group,
a dibenzofluorenyl group,
a fluoranthenyl group,
a benzofluoranthenyl group,
a perylenyl group, and
a monovalent aryl group derived by removing one hydrogen atom from the ring structures represented by any of the following general formulas (TEMP-1) to (TEMP-15).

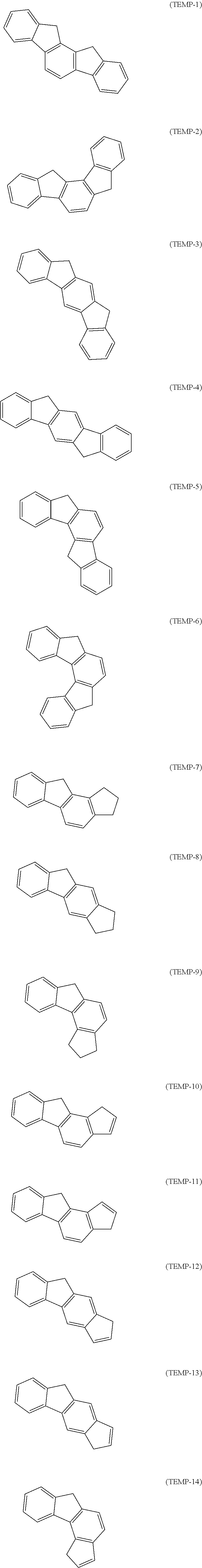

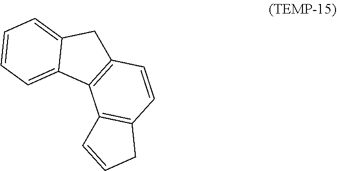

### Substituted Aryl Group (Specific Example Group G1B):

an o-tolyl group,
a m-tolyl group,
a p-tolyl group,
a p-xylyl group,
a m-xylyl group,
an o-xylyl group,
a p-isopropylphenyl group,
a m-isopropylphenyl group,
an o-isopropylphenyl group,
a p-t-butylphenyl group,
a m-t-butylphenyl group,
an o-t-butylphenyl group,
a 3,4,5-trimethylphenyl group,
a 9,9-dimethylfluorenyl group,
a 9,9-diphenylfluorenyl group,
a 9,9-bis(4-methylphenyl)fluorenyl group,
a 9,9-bis(4-isopropylphenyl)fluorenyl group,
a 9,9-bis(4-t-butylphenyl)fluorenyl group,
a cyanophenyl group,
a triphenylsilylphenyl group,
a trimethylsilylphenyl group,
a phenylnaphthyl group,
a naphthylphenyl group, and
a group in which one or more hydrogen atoms of a monovalent group derived from the ring structures represented by any of the general formulas (TEMP-1) to (TEMP-15) are substituted by a substituent.

### “Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group“is a” heterocyclic group unsubstituted by a substituent”, and the substituted heterocyclic group refers to the case where the “substituted or unsubstituted heterocyclic group” is a “heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).

### Unsubstituted Heterocyclic Group Containing a Nitrogen Atom (Specific Example Group G2A1):

a pyrrolyl group,
an imidazolyl group,
a pyrazolyl group,
a triazolyl group,
a tetrazolyl group,
an oxazolyl group,
an isoxazolyl group,
an oxadiazolyl group,
a thiazolyl group,
an isothiazolyl group,
a thiadiazolyl group,
a pyridyl group,
a pyridazinyl group,
a pyrimidinyl group,
a pyrazinyl group,
a triazinyl group,
an indolyl group,
an isoindolyl group,
an indolizinyl group,
a quinolizinyl group,
a quinolyl group,
an isoquinolyl group,
a cinnolyl group,
a phthalazinyl group,
a quinazolinyl group,
a quinoxalinyl group,
a benzimidazolyl group,
an indazolyl group,
a phenanthrolinyl group,
a phenanthridinyl group,
an acridinyl group,
a phenazinyl group,
a carbazolyl group,
a benzocarbazolyl group,
a morpholino group,
a phenoxazinyl group,
a phenothiazinyl group,
an azacarbazolyl group, and
a diazacarbazolyl group.

### Unsubstituted Heterocyclic Group Containing an Oxygen Atom (Specific Example Group G2A2):

a furyl group,
an oxazolyl group,
an isoxazolyl group,
an oxadiazolyl group,
a xanthenyl group,
a benzofuranyl group,
an isobenzofuranyl group,
a dibenzofuranyl group,
a naphthobenzofuranyl group,
a benzoxazolyl group,
a benzisoxazolyl group,
a phenoxazinyl group,
a morpholino group,
a dinaphthofuranyl group,
an azadibenzofuranyl group,
a diazadibenzofuranyl group,
an azanaphthobenzofuranyl group, and
a diazanaphthobenzofuranyl group.

### Unsubstituted Heterocyclic Group Containing a Sulfur Atom (Specific Example Group G2A3):

a thienyl group,
a thiazolyl group,
an isothiazolyl group,
a thiadiazolyl group,
a benzothiophenyl group (benzothienyl group),
an isobenzothiophenyl group (isobenzothienyl group),
a dibenzothiophenyl group (dibenzothienyl group),
a naphthobenzothiophenyl group (naphthobenzothienyl group),
a benzothiazolyl group,
a benzisothiazolyl group,
a phenothiazinyl group,
a dinaphthothiophenyl group (dinaphthothienyl group),
an azadibenzothiophenyl group (azadibenzothienyl group),
a diazadibenzothiophenyl group (diazadibenzothienyl group),
an azanaphthobenzothiophenyl group (azanaphthobenzothienyl group), and
a diazanaphthobenzothiophenyl group (diazanaphthobenzothienyl group).
   Monovalent heterocyclic group derived by removing one hydrogen atom from the ring structures represented by any of the following general formulas (TEMP-16) to (TEMP-33) (specific example group G2A4):

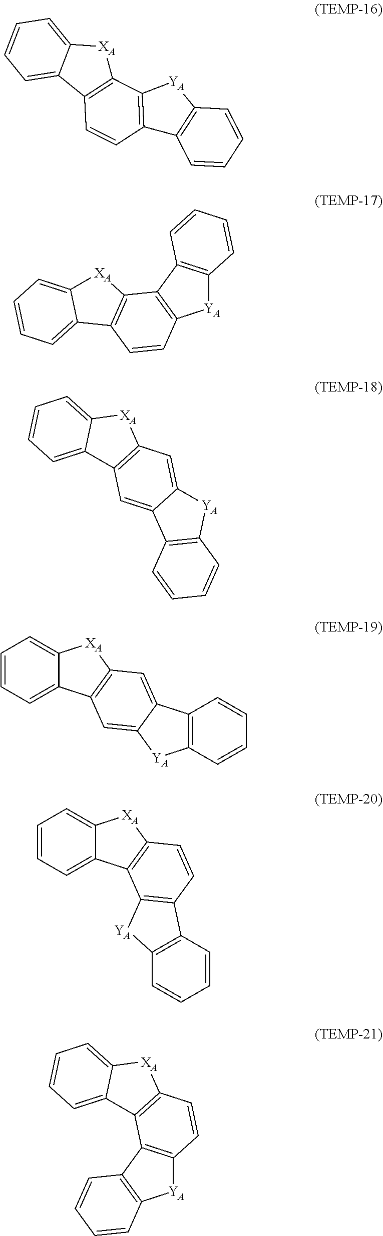

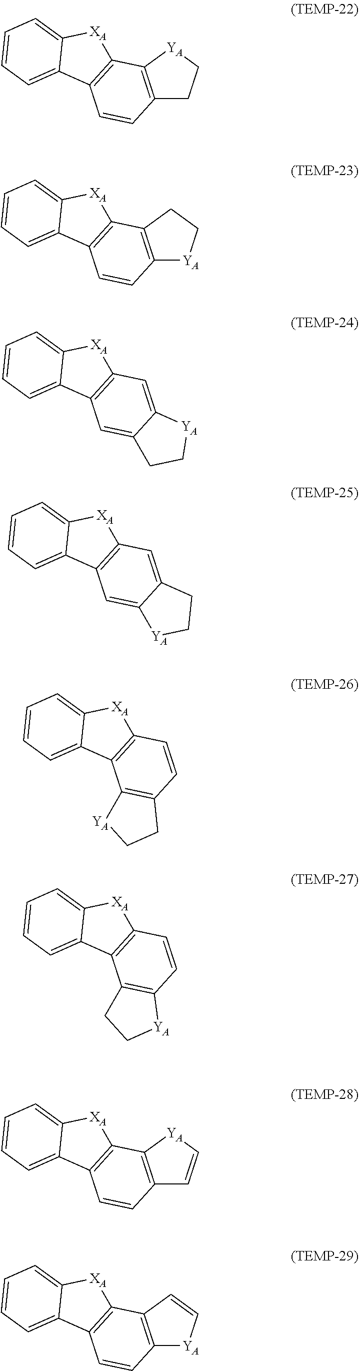

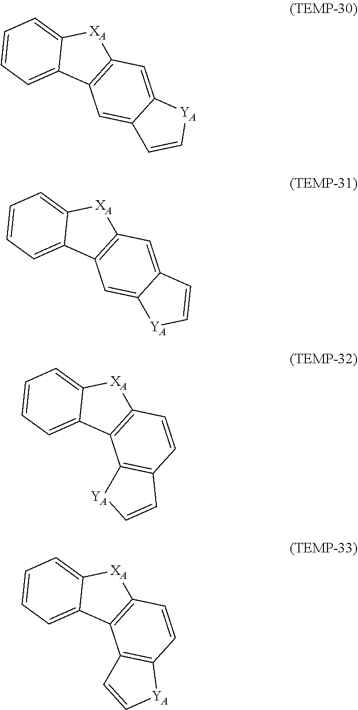

In the general formulas (TEMP-16) to (TEMP-33), XA and YA are independently an oxygen atom, a sulfur atom, NH, or CH₂. Provided that at least one of XA and YA is an oxygen atom, a sulfur atom, or NH.

In the general formulas (TEMP-16) to (TEMP-33), when at least one of XA and YA is NH or CH₂, the monovalent heterocyclic group derived from the ring structures represented by any of the general formulas (TEMP-16) to (TEMP-33) includes a monovalent group derived by removing one hydrogen atom from these NH or CH₂.

### Substituted Heterocyclic Group Containing a Nitrogen Atom (Specific Example Group G2B1):

a (9-phenyl)carbazolyl group,
a (9-biphenylyl)carbazolyl group,
a (9-phenyl)phenylcarbazolyl group,
a (9-naphthyl)carbazolyl group,
a diphenylcarbazol-9-yl group,
a phenylcarbazol-9-yl group,
a methylbenzimidazolyl group,
an ethylbenzimidazolyl group,
a phenyltriazinyl group,
a biphenylyltriazinyl group,
a diphenyltriazinyl group,
a phenylquinazolinyl group, and
a biphenylylquinazolinyl group.

### Substituted Heterocyclic Group Containing an Oxygen Atom (Specific Example Group G2B2):

a phenyldibenzofuranyl group,
a methyldibenzofuranyl group,
a t-butyldibenzofuranyl group, and
a monovalent residue of spiro[9H-xanthene-9,9′-[9H]fluorene].

### Substituted Heterocyclic Group Containing a Sulfur Atom (Specific Example Group G2B3):

a phenyldibenzothiophenyl group,
a methyldibenzothiophenyl group,
a t-butyldibenzothiophenyl group, and
a monovalent residue of spiro[9H-thioxanthene-9,9′-[9H]fluorene].
   Group in which one or more hydrogen atoms of the monovalent heterocyclic group derived from the ring structures represented by any of the following general formulas (TEMP-16) to (TEMP-33) are substituted by a substituent (specific example group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of XA and YA is NH, and hydrogen atoms of a methylene group when one of XA and YA is CH₂.

### “Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group“is an” alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

### Unsubstituted Alkyl Group (Specific Example Group G3A):

a methyl group,
an ethyl group,
a n-propyl group,
an isopropyl group,
a n-butyl group,
an isobutyl group,
a s-butyl group, and
a t-butyl group.

### Substituted Alkyl Group (Specific Example Group G3B):

a heptafluoropropyl group (including isomers),
a pentafluoroethyl group,
a 2,2,2-trifluoroethyl group, and
a trifluoromethyl group.

### “Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

### Unsubstituted Alkenyl Group (Specific Example Group G4A):

a vinyl group,
an allyl group,
a 1-butenyl group,
a 2-butenyl group, and
a 3-butenyl group.

### Substituted Alkenyl Group (Specific Example Group G4B):

a 1,3-butanedienyl group,
a 1-methylvinyl group,
a 1-methylallyl group,
a 1,1-dimethylallyl group,
a 2-methylally group, and
a 1,2-dimethylallyl group.

### “Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group“is an” alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

### Unsubstituted Alkynyl Group (Specific Example Group G5A):

an ethynyl group.

### “Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group“is a” cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent.

### Unsubstituted Cycloalkyl Group (Specific Example Group G6A):

a cyclopropyl group,
a cyclobutyl group,
a cyclopentyl group,
a cyclohexyl group,
a 1-adamantyl group,
a 2-adamantyl group,
a 1-norbornyl group, and
a 2-norbornyl group.

### Substituted Cycloalkyl Group (Specific Example Group G6B):

a 4-methylcyclohexyl group.
   “Group Represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:
Si(G1)(G1)(G1),
—Si(G1)(G2)(G2),
—Si(G1)(G1)(G2),
—Si(G2)(G2)(G2),
—Si(G3)(G3)(G3), and
—Si(G6)(G6)(G6).
G1 is the “substituted or unsubstituted aryl group” described in the specific example group G1.
G2 is the “substituted or unsubstituted heterocyclic group” described in the specific example group G2.
G3 is the “substituted or unsubstituted alkyl group” described in the specific example group G3.
G6 is the “substituted or unsubstituted cycloalkyl group” described in the specific example group G6.
Plural G1's in —Si(G1)(G1)(G1) are the same or different.
Plural G2's in —Si(G1)(G2)(G2) are the same or different.
Plural G1's in —Si(G1)(G1)(G2) are the same or different.
Plural G2's in —Si(G2)(G2)(G2) are be the same or different.
Plural G3's in —Si(G3)(G3)(G3) are the same or different.
Plural G6's in —Si(G6)(G6)(G6) are be the same or different.

### “Group Represented by —O—(R₉₀₄)”

Specific examples of the group represented by —O—(R₉₀₄) in this specification (specific example group G8) include:
—O(G1),
—O(G2),
—O(G3), and
—O(G6).
G1 is the “substituted or unsubstituted aryl group” described in the specific example group G1.
G2 is the “substituted or unsubstituted heterocyclic group” described in the specific example group G2.
G3 is the “substituted or unsubstituted alkyl group” described in the specific example group G3.
G6 is the “substituted or unsubstituted cycloalkyl group” described in the specific example group G6.

### “Group Represented by —S—(R₉₀₅)”

Specific examples of the group represented by —S—(R₉₀₅) in this specification (specific example group G9) include:
—S(G1),
—S(G2),
—S(G3), and
—S(G6).
G1 is the “substituted or unsubstituted aryl group” described in the specific example group G1.
G2 is the “substituted or unsubstituted heterocyclic group” described in the specific example group G2.
G3 is the “substituted or unsubstituted alkyl group” described in the specific example group G3.
G6 is the “substituted or unsubstituted cycloalkyl group” described in the specific example group G6.
   “Group Represented by —N(R₉₀₆)(R₉₀₇)”

Specific examples of the group represented by —N(R₉₀₆)(R₉₀₇) in this specification (specific example group G10) include:
—N(G1)(G1),
—N(G2)(G2),
—N(G1)(G2),
—N(G3)(G3), and
—N(G6)(G6).
G1 is the “substituted or unsubstituted aryl group” described in the specific example group G1.
G2 is the “substituted or unsubstituted heterocyclic group” described in the specific example group G2.
G3 is the “substituted or unsubstituted alkyl group” described in the specific example group G3.
G6 is the “substituted or unsubstituted cycloalkyl group” described in the specific example group G6.
Plural G1's in —N(G1)(G1) are the same or different.
Plural G2's in —N(G2)(G2) are the same or different.
Plural G3's in —N(G3)(G3) are the same or different.
Plural G6's in —N(G6)(G6) are the same or different.

### “Halogen Atom”

Specific examples of the “halogen atom” described in this specification (specific example group G11) include a fluorine atom, a chlorine atom, a bromine atom, an iodine atom, and the like.

### “Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

### “Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

### “Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

### “Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

### “Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

### “Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

### “Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

### “Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

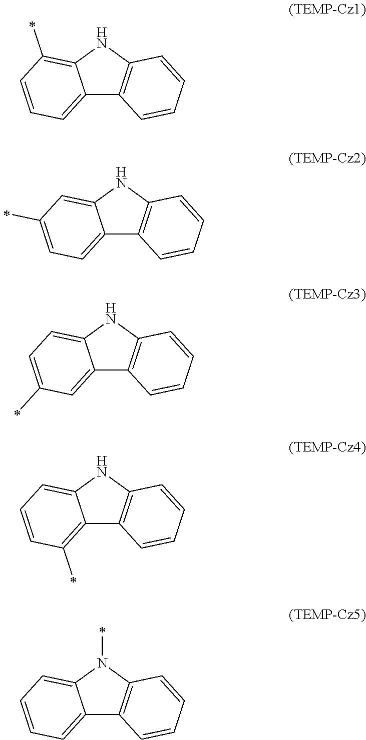

In this specification, the (9-phenyl)carbazolyl group is specifically any of the following groups, unless otherwise specified in this specification.

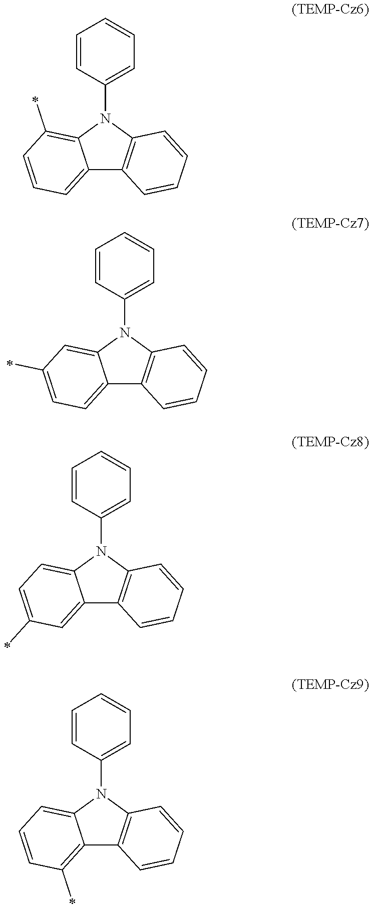

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

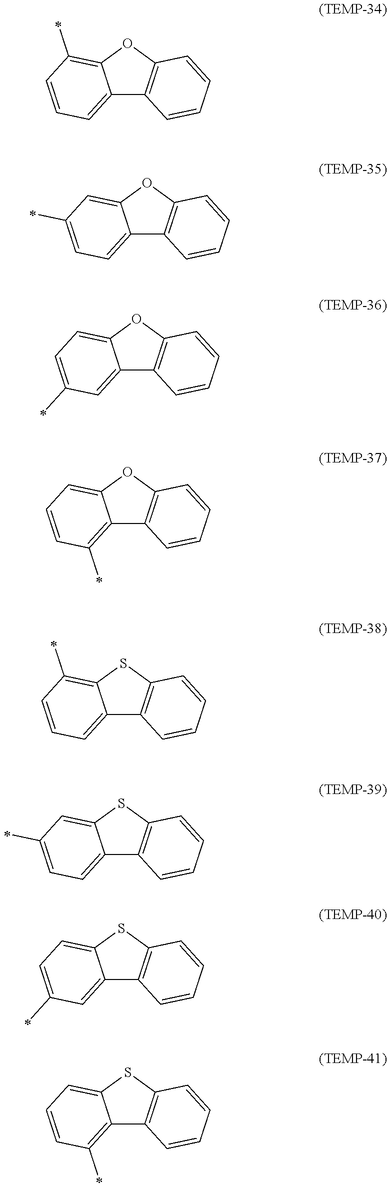

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

### “Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

### “Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

### “Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

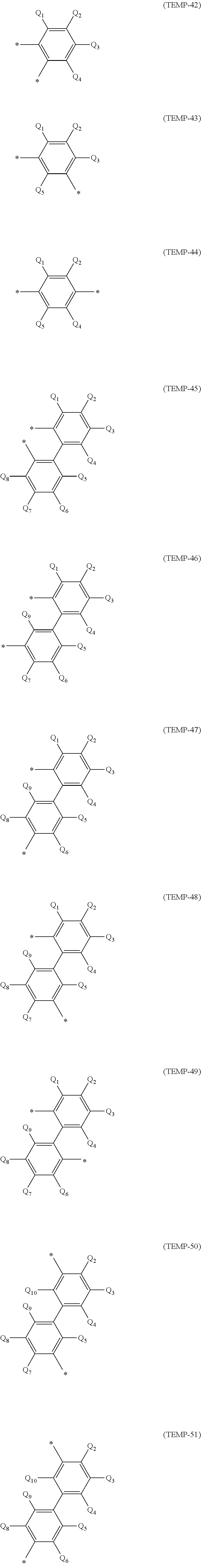

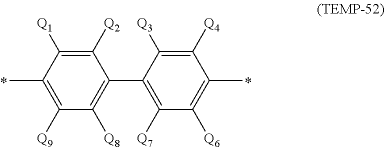

In the general formulas (TEMP-42) to (TEMP-52), Q₁ to Q₁₀ are independently a hydrogen atom or a substituent.

In the general formulas (TEMP-42) to (TEMP-52), * represents a bonding site.

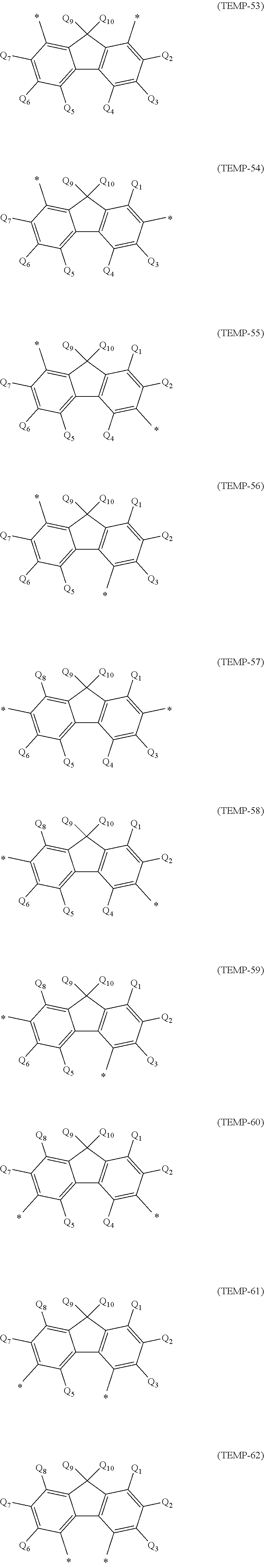

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

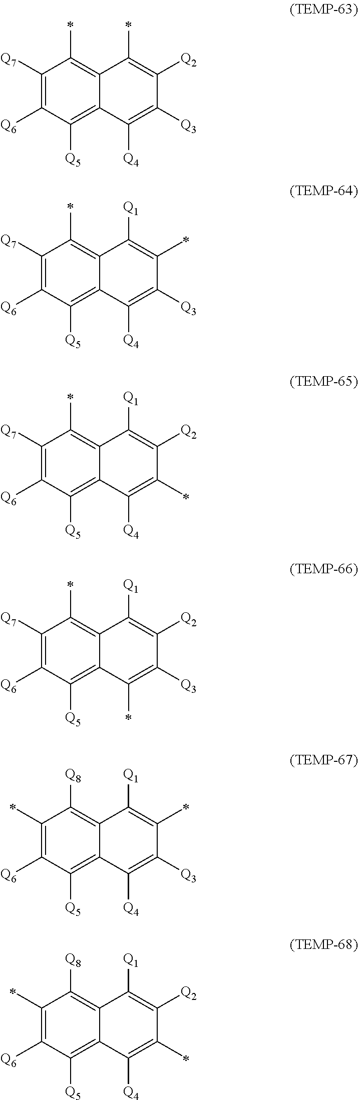

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

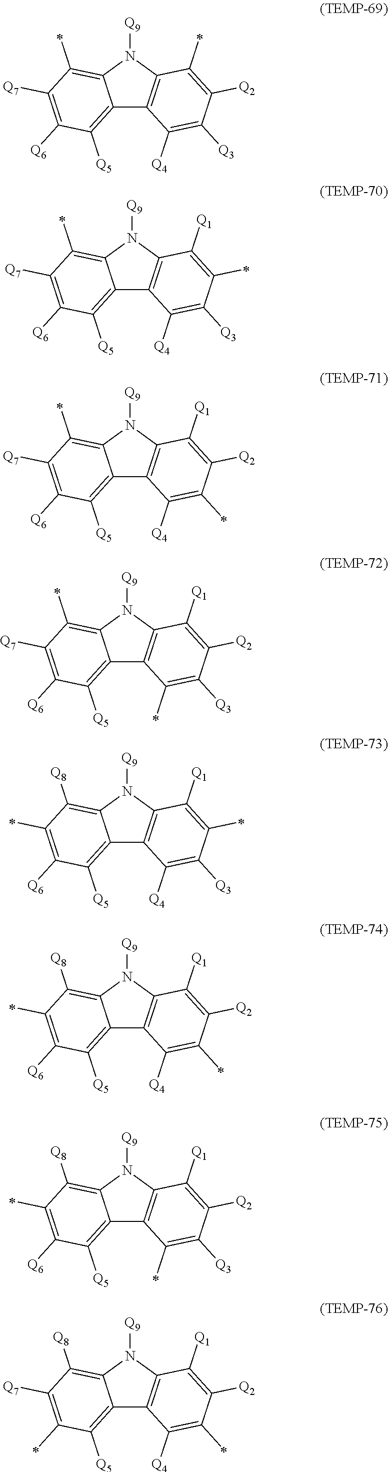

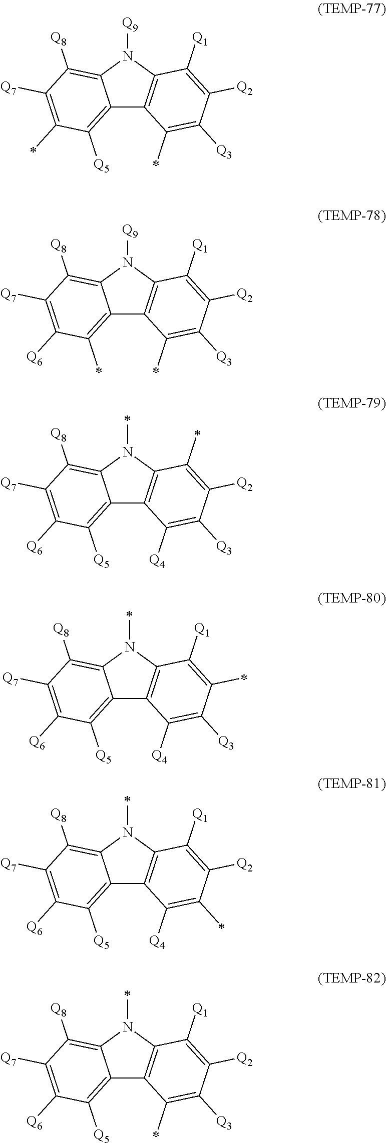

In the general formulas (TEMP-69) to (TEMP-82), Q₁ to Q₉ are independently a hydrogen atom or a substituent.

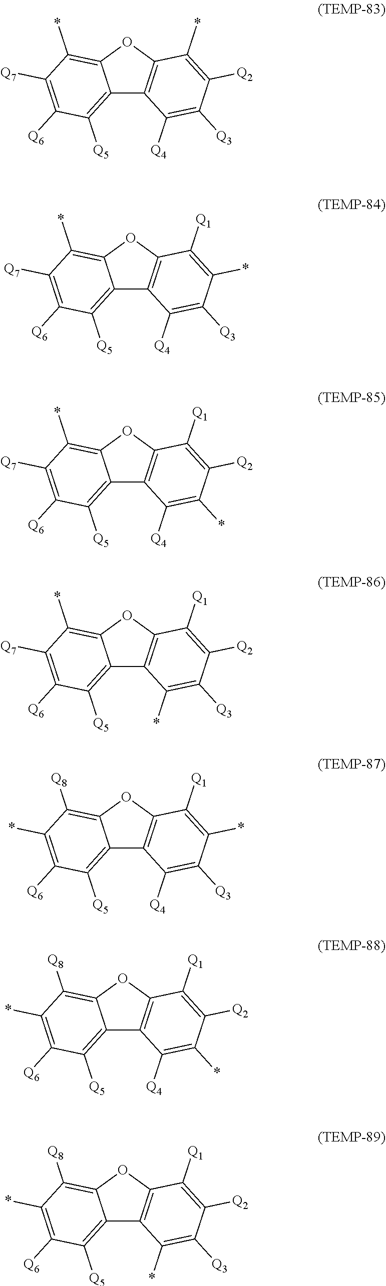

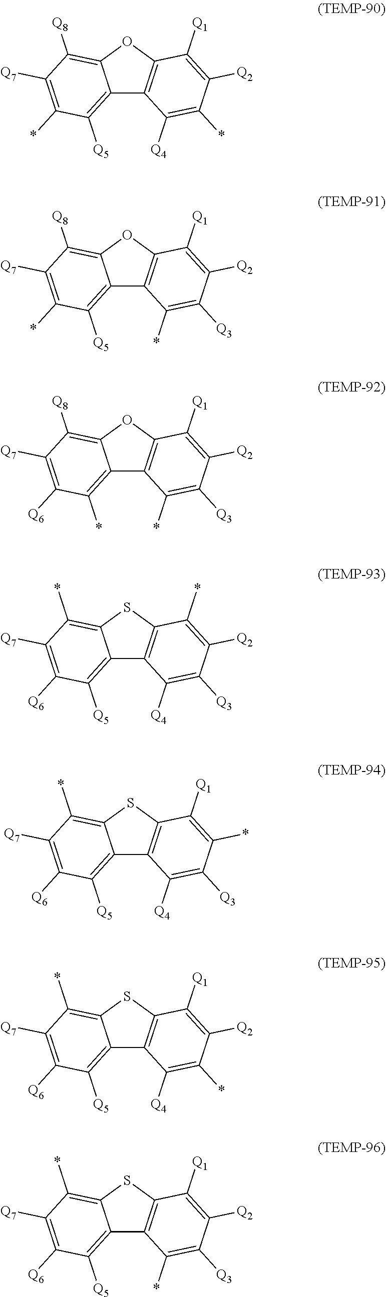

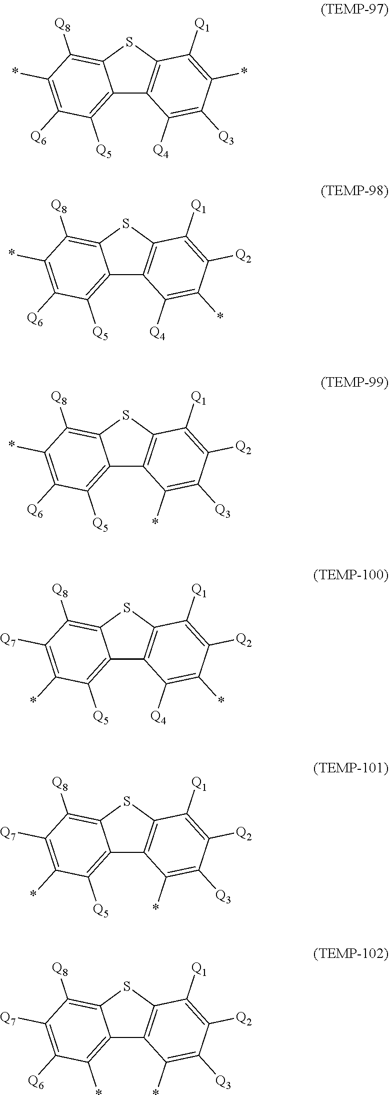

In the general formulas (TEMP-83) to (TEMP-102), Q₁ to Q₈ are independently a hydrogen atom or a substituent.

The above is the explanation of the “Substituent described in this specification.”

“The Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

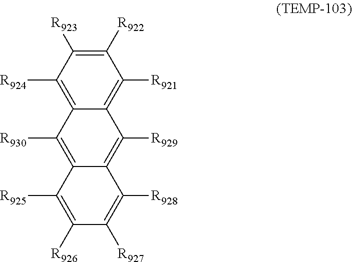

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring QA by bonding with each other, and at the same, time R₉₂₅ and R₉₂₆ form a ring Q_{B} by bonding with each other, the anthracene compound represented by the general formula (TEMP-103) is represented by the following general formula (TEMP-104).

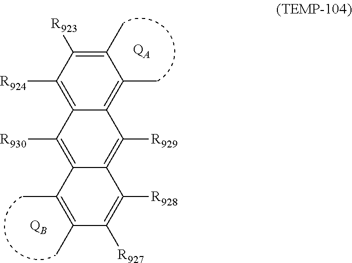

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring QA by bonding with each other, and R₉₂₂ and R₉₂₃ form a ring Qc by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring QA and the ring Qc share R₉₂₂.

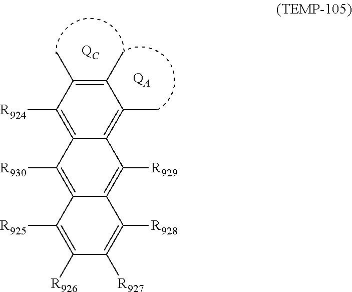

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring QA and the ring Q_{B} formed in the general formula (TEMP-104) are independently a “monocycle” or a “fused ring.” The ring QA and the ring Qc formed in the general formula (TEMP-105) are “fused ring.” The ring QA and ring Qc of the general formula (TEMP-105) are fused ring by fusing the ring QA and the ring Qc together. When the ring QA of the general formula (TMEP-104) is a benzene ring, the ring QA is a monocycle. When the ring QA of the general formula (TMEP-104) is a naphthalene ring, the ring QA is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring QA shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring QA is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

### Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:
an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
an unsubstituted aryl group including 6 to 50 ring carbon atoms, and
an unsubstituted heterocyclic group including 5 to 50 ring atoms,
wherein, R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:
an alkyl group including 1 to 50 carbon atoms,
an aryl group including 6 to 50 ring carbon atoms, and
a heterocyclic group including 5 to 50 ring atoms.

In one embodiment, the substituent in the case of “substituted or unsubstituted” is a group selected from the group consisting of:
an alkyl group including 1 to 18 carbon atoms,
an aryl group including 6 to 18 ring carbon atoms, and
a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

In the present specification, the term “ordinary temperatures and pressures” means the environment of 1 bar and 0° C.

In the present specification, the term “AA BB” means that the numerical value AA is the same as the numerical value BB or greater than the numerical value BB, and the term “AA BB” means that the numerical value AA is the same as the numerical value BB or lower than the numerical value BB.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1: A mixed powder for an organic electroluminescence device, comprising a first organic compound and a second organic compound, and being solid at ordinary temperatures and pressures,
wherein the organic electroluminescence device comprises a cathode, an anode, and an emitting layer arranged between the cathode and the anode, and the emitting layer comprises a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder and MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M^{1/2}=0.04×{MOL1/(MOL1+MOL2)} and
the temperature T2 [° C.] of the second organic compound in the case of P2/M^{1/2}=0.04×{MOL2/(MOL1+MOL2)} satisfy the following formula (2):
$$\\ \begin{matrix}0 < MOL 2 / ( MOL 1 + MOL 2 ) ≦ 0.45 & ( 1 )\end{matrix}$$
$$\\ \begin{matrix}- 20 ° C . ≦ T 1 - T 2 ≦ 40 ° C . . & ( 2 )\end{matrix}$$

2: The mixed powder according to claim 1, wherein the singlet energy of the compound C3 is greater than the singlet energy of the compound C2.

3: The mixed powder according to claim 1, wherein 99.9 mol % or more thereof is the first organic compound and the second organic compound.

4: The mixed powder according to claim 1, which substantially consists of the first organic compound and the second organic compound.

5: The mixed powder according to claim 1, which consists of the first organic compound and the second organic compound.

6: The mixed powder according to claim 1, wherein the compound C1 is a green fluorescent emitting compound.

7: The mixed powder according to claim 1, wherein the singlet energy of the compound C2 is greater than the singlet energy of the compound C1.

8: The mixed powder according to claim 1, wherein the first organic compound is the compound C3, and the second organic compound is the compound C2.

9: The mixed powder according to claim 8, wherein the following formula is satisfied:
$$\\ 0.2 ≦ MOL 2 / ( MOL 1 + MOL 2 ) ≦ 0.45 .$$

10: The mixed powder according to claim 8, wherein the following formula is satisfied:
$$\\ 0.2 ≦ MOL 2 / ( MOL 1 + MOL 2 ) ≦ 0.4 .$$

11: The mixed powder according to claim 8, wherein the following formula is satisfied:
$$\\ 0.2 ≦ MOL 2 / ( MOL 1 + MOL 2 ) ≦ 0.35 .$$

12: The mixed powder according to claim 8, wherein the following formula is satisfied:
$$\\ 0.2 ≦ MOL 2 / ( MOL 1 + MOL 2 ) ≦ 0.3 .$$

13: The mixed powder according to claim 1, wherein the first organic compound is the compound C3, and the second organic compound is the compound C1.

14: The mixed powder according to claim 13, wherein the following formula is satisfied:
$$\\ 0 < MOL 2 / ( MOL 1 + MOL 2 ) ≦ 0.2 .$$

15: The mixed powder according to claim 13, wherein the following formula is satisfied:
$$\\ 0 < MOL 2 / ( MOL 1 + MOL 2 ) ≦ 0.15 .$$

16: The mixed powder according to claim 13, wherein the following formula is satisfied:
$$0 < MOL 2 / ( MOL 1 + MOL 2 ) ≦ 0.10 .$$

17: The mixed powder according to claim 13, wherein the following formula is satisfied:
$$0 < MOL 2 / ( MOL 1 + MOL 2 ) ≦ 0.05 .$$

18: The mixed powder according to claim 1, wherein the first organic compound is the compound C2, and the second organic compound is the compound C1.

19: The mixed powder according to claim 18, wherein the following formula is satisfied:
$$0 < MOL 2 / ( MOL 1 + MOL 2 ) ≦ 0.2 .$$

20: The mixed powder according to claim 18, wherein the following formula is satisfied:
$$0 < MOL 2 / ( MOL 1 + MOL 2 ) ≦ 0.15 .$$

21: The mixed powder according to claim 18, wherein the following formula is satisfied:
$$0 < MOL 2 / ( MOL 1 + MOL 2 ) ≦ 0.10 .$$

22: The mixed powder according to claim 18, wherein the following formula is satisfied:
$$0 < MOL 2 / ( MOL 1 + MOL 2 ) ≦ 0.05 .$$

23: The mixed powder according to claim 1, wherein the first organic compound is the compound C2, and the second organic compound is the compound C3.

24: The mixed powder according to claim 23, wherein the following formula is satisfied:
$$0.20 ≦ MOL 2 / ( MOL 1 + MOL 2 ) ≦ 0.45 .$$

25: The mixed powder according to claim 23, wherein the following formula is satisfied:
$$0.20 ≦ MOL 2 / ( MOL 1 + MOL 2 ) ≦ 0.40 .$$

26: The mixed powder according to claim 23, wherein the following formula is satisfied:
$$0.20 ≦ MOL 2 / ( MOL 1 + MOL 2 ) ≦ 0.35 .$$

27: The mixed powder according to claim 23, wherein the following formula is satisfied:
$$0.20 ≦ MOL 2 / ( MOL 1 + MOL 2 ) ≦ 0.30 .$$

28: The mixed powder according to claim 1, wherein T₁ and T₂ satisfy the following formula:
$$- 20 ° C . ≦ T 1 - T 2 ≦ 20 ° C .$$

29: The mixed powder according to claim 1, which is solid-like.

30: The mixed powder according to claim 1, which is pellet-like.

31: A mixture obtained by heating and melting the mixed powder according to claim 1, and by solidifying it.

32: A method for fabricating an organic electroluminescence device, wherein the organic electroluminescence device comprises a cathode, an anode, and an emitting layer arranged between the cathode and the anode, and comprising a compound C2 having delayed fluorescence, and
the method comprises: depositing a mixed powder or a mixture obtained by heating and melting the mixed powder and by solidifying it, by heating and vaporizing the mixed powder or the mixture in a deposition source to form the emitting layer,
wherein the mixed powder comprises a first organic compound and a second organic compound, and is solid at ordinary temperatures and pressures,
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M^{1/2}=0.04×{MOL1/(MOL1+MOL2)} and
the temperature T2 [° C.] of the second organic compound in the case of P2/M^{1/2}=0.04×{MOL2/(MOL1+MOL2)} satisfy the following formula (2):
$$0 < MOL 2 / ( MOL 1 + MOL 2 ) ≦ 0 \text{.45} \qquad ( 1 )$$
$$- 20 ° C . ≦ T 1 - T 2 ≦ 40 ° C . \qquad ( 2 ) .$$

33: The method for fabricating an organic electroluminescence device according to claim 32, wherein the singlet energy of the compound C3 is greater than the singlet energy of the compound C2.

34: A method for selecting a first organic compound and a second organic compound in a mixed powder for an organic electroluminescence device, which comprises the first organic compound and the second organic compound and which is solid at ordinary temperatures and pressures,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and when P2 [Pa] is used as the vapor pressure obtained by ThermoGravimetry-Differential Thermal Analysis of the second organic compound at arbitrary temperature,
the first organic compound and the second organic compound are selected so that the temperature T1 [° C.] of the first organic compound in the case of P1/M^{1/2}=0.04×{MOL1/(MOL1+MOL2)} and
the temperature T2 [° C.] of the second organic compound in the case of P2/M^{1/2}=0.04×{MOL2/(MOL1+MOL2)} satisfy the following formula (2):
$$0 < MOL 2 / ( MOL 1 + MOL 2 ) ≦ 0 \text{.45} \qquad ( 1 )$$
$$- 20 ° C . ≦ T 1 - T 2 ≦ 40 ° C . \qquad ( 2 ) .$$

35: The method according to claim 34, wherein the singlet energy of the compound C3 is greater than the singlet energy of the compound C2.

36: A method for producing a mixed powder for an organic electroluminescence device, comprising a first organic compound and a second organic compound, and being solid at ordinary temperatures and pressures,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the mixed powder, and
when MOL2 [mol %] is used as the molar concentration of the second organic compound in the mixed powder,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M^{1/2}=0.04×{MOL1/(MOL1+MOL2)} and
the temperature T2 [° C.] of the second organic compound in the case of P2/M^{1/2}=0.04×{MOL2/(MOL1+MOL2)} satisfy the following formula (2):
$$0 < MOL 2 / ( MOL 1 + MOL 2 ) ≦ 0 \text{.45} \qquad ( 1 )$$
$$- 20 ° C . ≦ T 1 - T 2 ≦ 40 ° C . \qquad ( 2 ) .$$

37: The method for producing a mixed powder according to claim 36, wherein the singlet energy of the compound C3 is greater than the singlet energy of the compound C2.

38: A composition for a deposition in an organic electroluminescence device, comprising a first organic compound and a second organic compound,
wherein the organic electroluminescence device comprises a cathode, an anode, and an emitting layer arranged between the cathode and the anode, and comprising a compound C2 having delayed fluorescence, and
each of the first organic compound and the second organic compound is a compound selected from the group consisting of a fluorescent emitting compound C1, the compound C2, and a compound C3 different from both the compound C1 and the compound C2,
wherein the first organic compound is the compound C3, and the second organic compound is the compound C2,
the first organic compound is the compound C3, and the second organic compound is the compound C1,
the first organic compound is the compound C2, and the second organic compound is the compound C1, or
the first organic compound is the compound C2, and the second organic compound is the compound C3,
wherein when MOL1 [mol %] is used as the molar concentration of the first organic compound in the composition, and
when MOL2 [mol %] is used as the molar concentration of the second organic compound in the composition,
MOL1 [mol %] and MOL2 [mol %] satisfy the following formula (1),
wherein when M1 [kg/mol] is used as the molecular weight of the first organic compound,
when P1 [Pa] is used as the vapor pressure obtained by ThermoGravimetry-Differential Thermal Analysis of the first organic compound at arbitrary temperature,
when M2 [kg/mol] is used as the molecular weight of the second organic compound, and
when P2 [Pa] is used as the vapor pressure obtained by ThermoGravimetry-Differential Thermal Analysis of the second organic compound at arbitrary temperature,
the temperature T1 [° C.] of the first organic compound in the case of P1/M^{1/2}=0.04×{MOL1/(MOL1+MOL2)} and
the temperature T2 [° C.] of the second organic compound in the case of P2/M^{1/2}=0.04×{MOL2/(MOL1+MOL2)} satisfy the following formula (2):
$$0 < MOL 2 / ( MOL 1 + MOL 2 ) ≦ 0 \text{.45} \qquad ( 1 )$$
$$- 20 ° C . ≦ T 1 - T 2 ≦ 40 ° C . \qquad ( 2 ) .$$

39: The composition for a deposition according to claim 38, wherein the singlet energy of the compound C3 is greater than the singlet energy of the compound C2.
